(19) United States
(12) Patent Application Publication
(10) Pub. No.: US 2022/0077398 A1
(43) Pub. Date: Mar. 10, 2022

(54) POLYCYCLIC AROMATIC COMPOUND

(71) Applicants: KWANSEI GAKUIN EDUCATIONAL FOUNDATION, Nishinomiya-shi (JP); SK Materials JNC Co., Ltd., Hwaseong-si (KR)

(72) Inventors: Takuji HATAKEYAMA, Sanda-shi (JP); Kohei MATSUI, Hwaseong-sI (KR); Kazuki SHIGEMATSU, Ichihara-shi (JP)

(21) Appl. No.: 17/446,055

(22) Filed: Aug. 26, 2021

(30) Foreign Application Priority Data
Aug. 28, 2020 (JP) 2020-144948

(51) Int. Cl. H01L 51/00; C07F 5/02; C09K 11/06; C07F 7/08

(52) U.S. Cl. CPC H01L 51/0061; C07F 5/027; C09K 11/06; C07F 7/0812; H01L 51/5012; C09K 2211/1018; H01L 51/0069; C09K 2211/1007; H01L 51/0072; H01L 51/0094

(57) ABSTRACT

A polycyclic aromatic compound having a structure consisting of one or two or more of structural units represented by Formula (1) is useful as a material for an organic device such as an organic electroluminescent element such as an organic electroluminescent element;

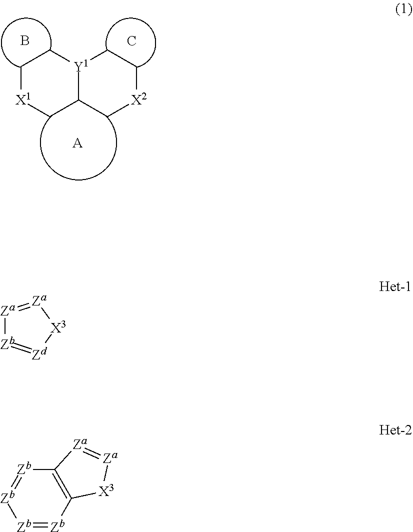

wherein A, B, and C rings are an optionally substituted aryl or heteroaryl ring, at least one ring selected from the group consisting of A, B, and C rings in the structure is a ring represented by Formula (Het-1) or (Het-2), Y¹ is B, X¹ and X² are each independently >O or >N—R(R is a substituted or unsubstituted aryl), X³ is >O or >S, one of Z^{a} is N and the other is N or C—R^{Z}, Z^{b}s are carbons directly bonded to Y¹, X¹, and X², N or C—R^{Z}, R^{Z} is hydrogen or a substituent, and at least one hydrogen in the structure may be substituted with cyano, a halogen, or deuterium.

### CROSS-REFERENCE TO RELATED APPLICATIONS

This application is related to and claims priority under 35 U.S.C § 119 to Japanese Patent Application No. 2020-144948 filed on Aug. 28, 2020, the disclosure of which is expressly incorporated by reference herein in its entirety.

### TECHNICAL FIELD

The present invention relates to a polycyclic aromatic compound. The present invention particularly relates to a polycyclic aromatic compound containing nitrogen and boron. The present invention also relates to a material for an organic device, the organic electroluminescent element, a display device and a lighting device, each of which contains the polycyclic aromatic compound.

### BACKGROUND ART

A display apparatus using a luminescent element causing electroluminescence can achieve power saving or thickness reduction, and therefore various studies have been conducted so far thereon. Further, an organic electroluminescent element formed of an organic material has been actively studied because weight reduction or large size is easily achieved. In particular, active studies have been conducted so far on development of an organic material having luminescence characteristics for blue light which is one of primary colors of light, or the like, and development of organic materials with charge transporting ability such as holes and electrons (which have the potential to become semiconductors and superconductors), irrespective of whether the organic material is a high-molecular-weight compound or a low-molecular-weight compound.

The organic electroluminescent element has a structure configured of a pair of electrodes formed of an anode and a cathode, and a single layer or a plurality of layers containing an organic compound arranged between the pair of electrodes. The layer including the organic compound includes a luminescent layer, a charge transport and injection layer for transporting or injecting a charge such as a hole and an electron, and various organic materials suitable for the layers have been developed.

Among them, Patent Document 1 discloses that a polycyclic aromatic compound containing boron is useful as a material for an organic electroluminescent element or the like. Patent Document 1 reports that the organic electroluminescent element containing the polycyclic aromatic compound has good external quantum efficiency.

### CITATION LIST

### Patent Literature

Patent literature No. 1: Chinese Patent Application Publication No. 106467554

### SUMMARY OF INVENTION

### Technical Problem

As described above, various materials have been developed as materials used in an organic EL element, but in order to increase the choice of a material for an organic EL element, development of a material made of a compound different from a conventional one is desired.

It is an object of the present invention to provide a novel compound useful as a material for an organic device such as an organic EL element.

### Solution to Problem

The present inventors have intensively studied to solve the above problem and have succeeded in producing a novel polycyclic aromatic compound having a structure similar to that of a compound described in Patent Document 1, which is more excellent in luminescence characteristics. Further, it has been found that an excellent organic EL element can be obtained by arranging a layer containing the polycyclic aromatic compound between a pair of electrodes to constitute an organic EL element, thereby completing the present invention. That is, the present invention provides a polycyclic aromatic compound as follows, and further a. material for an organic device or the like including the polycyclic aromatic compound.
<1> A polycyclic aromatic compound having a structure consisting of one or two or more of structural units represented by Formula (1):

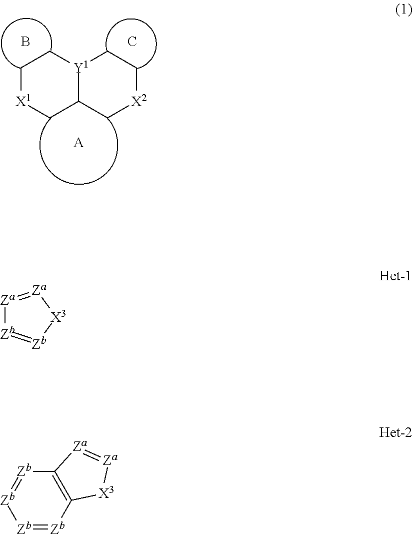

In formula (1),
A ring, B ring, and C ring are each independently an optionally substituted aryl ring or an optionally substituted heteroaryl ring, and at least one ring selected from the group consisting of A ring, B ring and C ring in the structure is a ring represented by Formula (Het-1) or Formula (Het-2), provided that the A ring is not a ring represented by Formula (Het-1);
Y¹ is B, P, P═O, P═S, Al, Ga, As, Si—R, or Ge—R, R in Si—R and Ge—R is a substituted or unsubstituted aryl, a substituted or unsubstituted heteroaryl, a substituted or unsubstituted alkyl, or a substituted or unsubstituted cycloalkyl;
X¹ and X² are each independently >O, >N—R, >C(—R)₂, >Si(—R)₂, >S, or >Se, wherein R in >N—R is hydrogen, a substituted or unsubstituted aryl, a substituted or unsubstituted heteroaryl, a substituted or unsubstituted alkyl, or a substituted or unsubstituted cycloalkyl, and R's in >C(—R)₂ are each independently hydrogen, a substituted or unsubstituted a substituted or unsubstituted heteroaryl, a substituted or unsubstituted alkyl, or a substituted or unsubstituted cycloalkyl, two R's in >C(—R₂ and two R's in >Si(—R)₂ may be bonded to each other to form a ring, wherein R in >N—R, >C(—R)₂ and >Si(—R)₂ may be bonded to A and/or B rings, or A and/or C rings;
in formula (Het-1) and formula (Het-2),
X³ is >O, >N—R, >C(—R₂, >S, or >Se, wherein R in >N—R is hydrogen, a substituted or unsubstituted aryl. a substituted or unsubstituted heteroaryl, a substituted or unsubstituted a substituted or unsubstituted cycloalkyl, R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl, and
one of Z is N and the other is N or C—R^{Z};
in Formula (Het-1),
Z^{b}s are carbons directly bonded to Y¹ and X¹, or Y¹ and X₂;
in Formula (Het-2),
any two or three consecutive Z^{b}s are carbons that directly bonded to Y¹, and X¹ and/or X² in Formula (I),
the remaining Z^{b}s are each independently N or C—R^{Z}, or
Z^{b}═Z^{b} may be >O, >N—R, >C—(R)₂, >Si(—R)₂, >S, or >Se, wherein R in >N—R and R's C—(R)₂ and >Si(—R)₂ are each independently hydrogen, a substituted or unsubstituted aryl, a substituted or unsubstituted heteroaryl, a substituted or unsubstituted alkyl, a substituted or unsubstituted cycloalkyl, and two R's in >C(—R₂ and >Si(—R)₂ may be bonded to each other to form a ring,
R^{Z} is hydrogen or a substituent;
in Formula (Het-2),
two adjacent R^{Z}s may be bonded to each other to form a ring, and the ring formed may be substituted;
at least one of aryl ring or heteroaryl ring in the structure may be fused with at least one cycloalkane, at least one hydrogen in the cycloalkane may be substituted, and at least one —CH₂— in the cycloalkane may be replaced with —O—; and
at least one hydrogen in the structure may be substituted with cyano, a halogen, or deuterium,
<2> The polycyclic aromatic compound according to <1>, wherein Y¹ is B.
<3> The polycyclic aromatic compound according to <1> or <2>, wherein one of X¹ and X² is >N—R and the other is >O, S, >N—R, or >C(—R)₂.
<4> The polycyclic aromatic compound according to any one of <1> to <3>, wherein at least one ring selected from the group consisting of B ring and C ring in the structure is a ring represented by Formula (Het-1).
<5> The polycyclic aromatic compound according to <4>, wherein the structural unit represented by Formula (1) is a structural unit represented by Formula (1-a), Formula (1-b), Formula (1-i), or Formula (1-j).

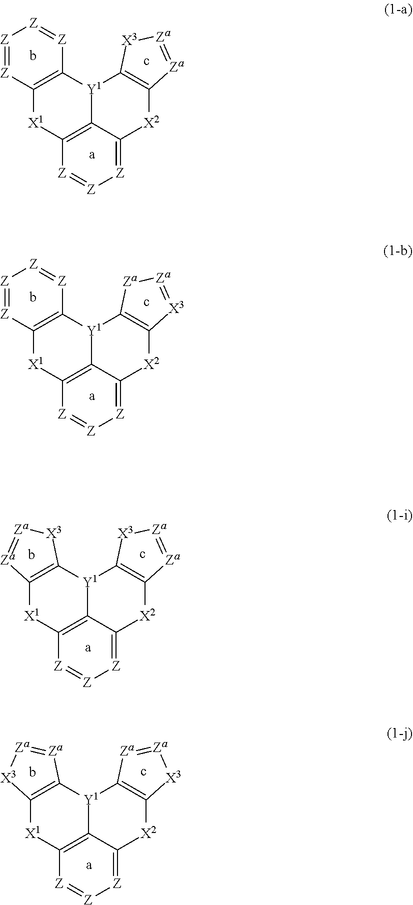

In Formula (1-a), Formula (1-h), Formula (1-i), and Formula (1-j),
Z^{a} and Z are each independently N or C—R^{Z}, provided that at least one of the two Z^{a} constituting one ring is N,
each R^{Z} is hydrogen, an aryl, a heteroaryl, a diarylamino, a diheteroarylamino, an arylheteroarylamino, a diarylboryl (the two aryls may be bonded via single bond or a linking group), an alkyl, a cycloalkyl, an alkoxy, an aryloxy, or a substituted silyl, wherein at least one hydrogen in these may be replaced with an aryl, a heteroaryl, an alkyl, or a cycloalkyl, two adjacent R^{Z}'s may be bonded to each other to form an aryl ring or a heteroryl ring, wherein the aryl ring and the heteroryl ring formed may each be substituted with an aryl, a heteroaryl, a diarylamino, a diheteroarylamino, an arylheteroarylamino, a diarylboryl (the two aryl may be bonded via a single bond or linking group), an alkyl, a cycloalkyl, an alkoxy, an aryloxy, or a substituted silyl, wherein at least one hydrogen in these may be replaced with an aryl, a heteroaryl, an alkyl, or a cycloalkyl,
Z═Z may each independently be >O, >N—R, >C—(R)₂, >Si(—R)₂, >S, or >Se, wherein R in >N—R and R's in >C—(R)₂ and >Si(—R)₂ are independently hydrogen, a substituted or unsubstituted aryl, a substituted or unsubstituted heteroaryl, a substituted or unsubstituted alkyl or a substituted or unsubstituted cycloalkyl, the two R's C(—R₂ and Si(—R)₂ may he bonded to each other to form a ring;
is >O, >N—R, >C(—R)₂, >S, or >Se, wherein R in >N—R is hydrogen, a substituted or unsubstituted aryl, a substituted or unsubstituted heteroaryl, a substituted or unsubstituted a substituted or unsubstituted cycloalkyl, and R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl;
Y¹ is B, P, P═O, P═S, Al, Ga, As, Si—R, or Ge—R, wherein R in Si—R and Ge—R is a substituted or unsubstituted aryl, a substituted or unsubstituted heteroaryl, a substituted or unsubstituted.
or a substituted or unsubstituted cycloalkyl;
X¹ and X² are each independently >O, >N—R, >C(—R)₂, >Si(—R)₂, >S, or >Se, wherein R in >N—R is hydrogen, a substituted or unsubstituted aryl, a substituted or unsubstituted heteroaryl, a substituted or unsubstituted alkyl, or a substituted or unsubstituted cycloalkyl, and R's in >C(—R)₂ and >Si(—R)₂ are each independently hydrogen, a substituted or unsubstituted aryl, a substituted or unsubstituted heteroaryl, a substituted or unsubstituted alkyl, or a substituted or unsubstituted cycloalkyl, the two R's in >O(—R)₂ and >Si(—R)₂ may be bonded to each other to form a ring, and R in >N—R, >C(—R)₂, and >Si(—R)₂ may be bonded to one or two of R^{z} in Z as C—R^{z} by a linking group or single bond;
at least one of aryl ring or heteroaryl ring in the structure may be fused with at least one cycloalkane, at least one hydrogen in the cycloalkane may be substituted, and at least one —CH₂— in the cycloalkane may be replaced with —O—; and
at least one hydrogen in the structure may be replaced with cyano, a halogen, or deuterium.
<6> The polycyclic aromatic compound according to <5> represented by any one of the following formulas;

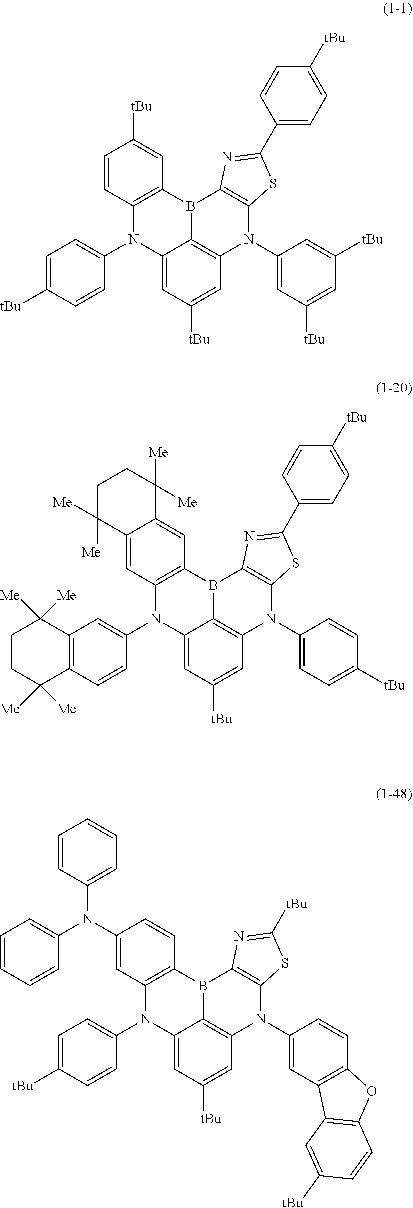

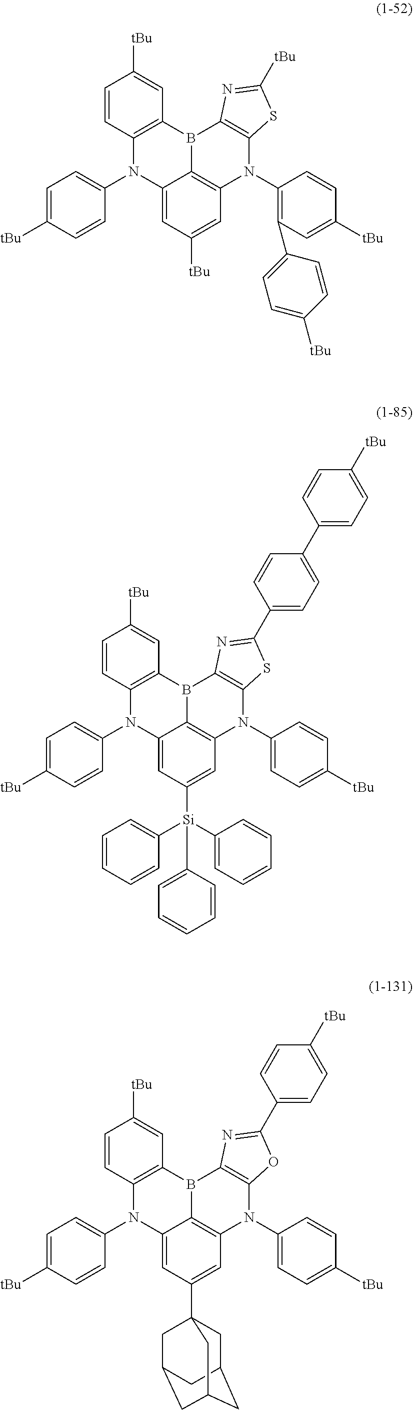

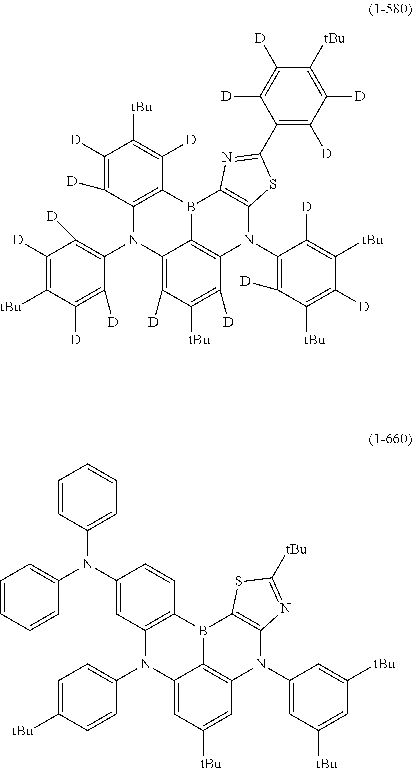

wherein Me is methyl, tBu is t-butyl, and D is deuterium,
<7> The polycyclic aromatic compound according to any one of <1> to <3>, wherein at least one ring selected from the group consisting of A ring, B ring, and C ring in the structure is a ring represented by Formula (Het-2).
<8> The polycyclic aromatic compound according to <7>, wherein the structural unit represented by Formula (1) is any one of Formula (1-c), Formula (1-d), Formula (1-e), Formula (1-f), Formula (1-g), Formula (1-h), Formula (1-k), Formula (1-l), Formula (1-m), or Formula (1-o).

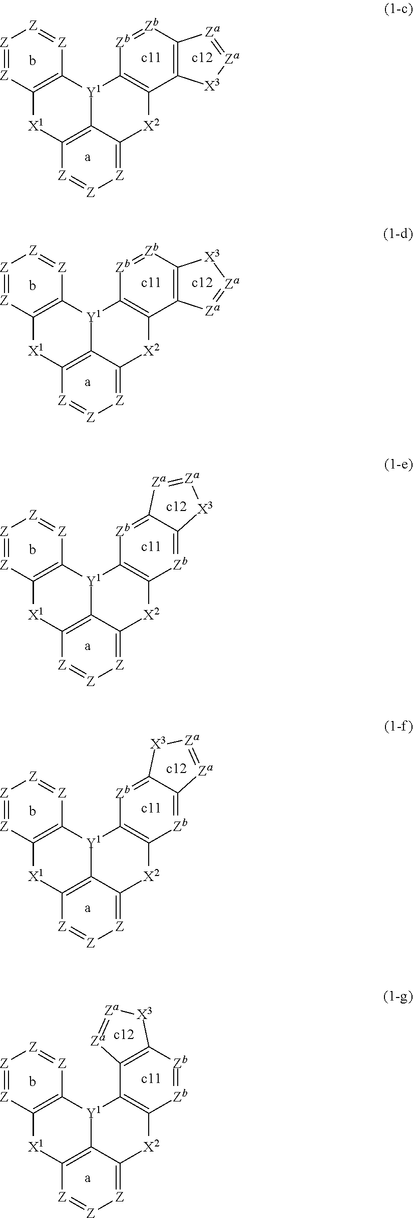

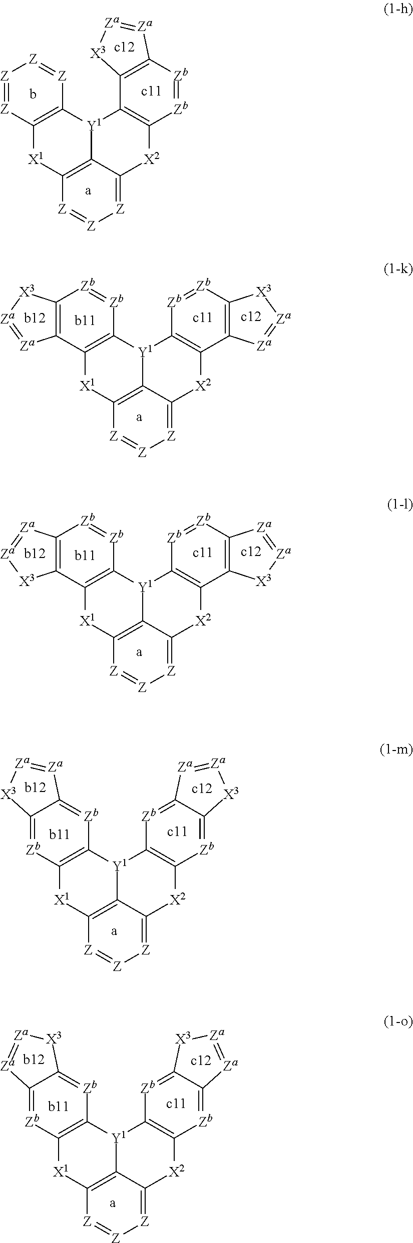

In Formula (1-c), Formula (1-d Formula (1-e), Formula (1-f), Formula (1-g), Formula (1-h), Formula (1-k), Formula (1-l), Formula (1-m), and Formula (1-o),

Z^{a}, Z^{b} and Z are each independently N or C—R′, provided that at least one of the two Z^{a} is N, each R^{Z} is independently hydrogen, an aryl, a heteroaryl, a diarylamino, a diheteroarylamino, an arylheteroarylamino, a diarylboryl (the two aryls may be bonded via single bond or a linking group), an alkyl, a cycloalkyl, an alkoxy, an aryloxy, or a substituted silyl, wherein at least one hydrogen in these may be replaced with an aryl, a heteroaryl, an alkyl, or a cycloalkyl, two adjacent R^{Z}'s may be bonded to each other to form an aryl ring or a heteroryl ring, wherein the aryl ring and heteroryl ring formed may each be substituted with an aryl, a heteroaryl, a diarylamino, a diheteroarylamino, an arylheteroarylamino, a diarylboryl (two aryls may be bonded via a single bond or a linking group), an alkyl, a cycloalkyl, an alkoxy, an aryloxy, or a substituted silyl, wherein at least one hydrogen in these may be replaced with an aryl, a heteroaryl, an alkyl, or a cycloalkyl,
Z^{b}═Z^{b} may be >O, >N—R, >C—(R)₂, >Si(—R)₂ >S, or >Se, wherein R in >N—R and R's in >C—(R)₂ and >Si(—R)₂ are each independently hydrogen, a substituted or unsubstituted aryl, a substituted or unsubstituted heteroaryl, a substituted or unsubstituted alkyl, or a substituted or unsubstituted cycloalkyl, and two R's in >C(—R₂ and >Si(—R)₂ may be bonded to each other to form a ring, Z═Z may each independently be >O, >N—R, >C—(R)₂, >S, or >Se, wherein R in >N—R and R's in >C—(R)₂ and >Si(—R)₂ are each independently hydrogen, a substituted or unsubstituted aryl, a substituted or unsubstituted heteroaryl, a substituted or unsubstituted alkyl, a substituted. or unsubstituted cycloalkyl, and the two R's C(—R₂ and >Si(—R)₂ may be bonded to each other to form a ring;
X³ is >O, >N—R, >C(—R)₂, >S, or >Se, wherein R in >N—R is hydrogen, a substituted or unsubstituted aryl, a substituted or unsubstituted heteroaryl, a substituted or unsubstituted alkyl, a substituted or unsubstituted cycloalkyl, and R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl;
Y¹ is B, P, P═O, P═S, Al, Ga, As, Si—R, or Ge—R, wherein R in Si—R and Ge—R is a substituted or unsubstituted aryl, a substituted or unsubstituted heteroaryl, a substituted or unsubstituted or a substituted or unsubstituted cycloalkyl;
X¹ and X² are independently >O, >N—R, >C(—R)₂, >Si(—R)₂, >S, or >Se, wherein R in >N—R is hydrogen, a substituted or unsubstituted aryl, a substituted or unsubstituted heteroaryl, a substituted or unsubstituted alkyl, a substituted or unsubstituted cycloalkyl, R's in >C(—R)₂ and >Si(—R)₂ are each independently hydrogen, a substituted or unsubstituted aryl, a substituted or unsubstituted heteroaryl, a substituted or unsubstituted alkyl, a substituted or unsubstituted cycloalkyl, the two R's in >C(—R)₂ and >Si(—R)₂ may be bonded to each other to form a ring, and R in >N—R, >C(—R)₂, >Si(—R)₂ may be bonded to one or two of Win Z as C—R^{z} by a linking group or single bond;
at least one of aryl ring or heteroaryl ring in the structure may be fused with at least one cycloalkane, at least one hydrogen in the cycloalkane may be substituted, at least one —CH₂— in the cycloalkane may be replaced with —O—; and
at least one hydrogen in the structure may be replaced with cyano, a halogen, or deuterium.
<9> The polycyclic aromatic compound according to <8> represented by any one of the following formulas;

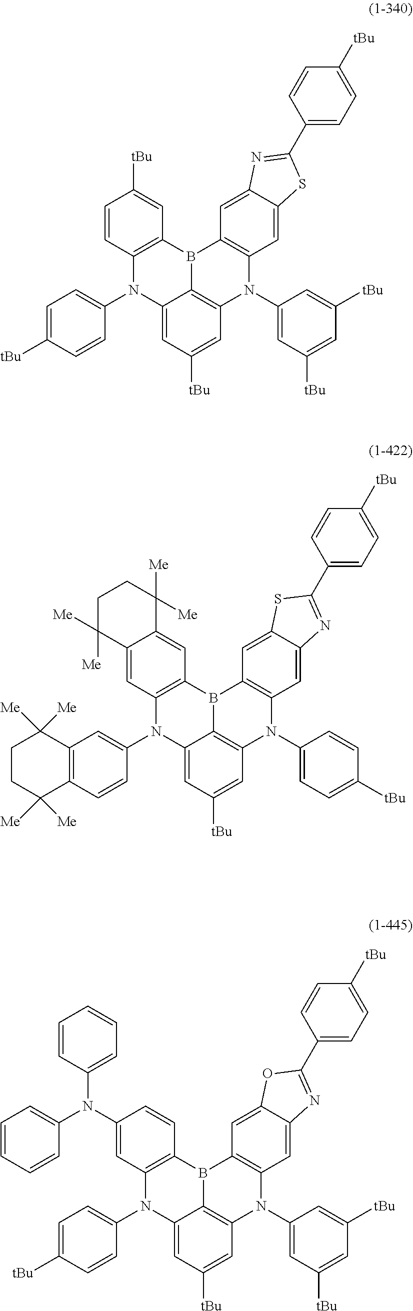

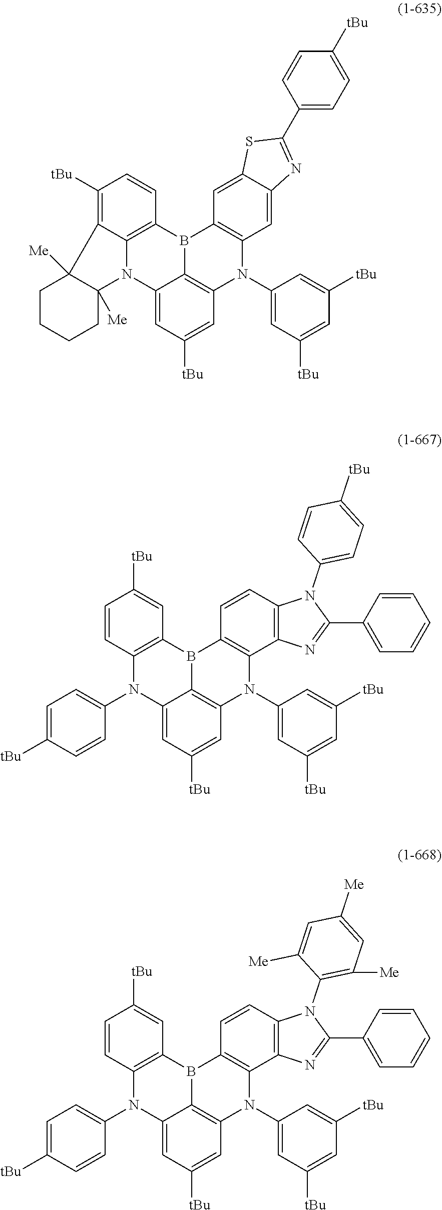

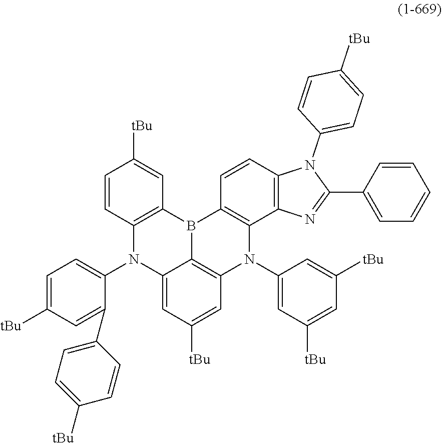

wherein Me is methyl, and tBu is t-butyl.
<10> A material for an organic device, comprising the polycyclic aromatic compound according to any one of <1> to <9>.
<11> An organic electroluminescent element, comprising a pair of electrodes consisting of an anode and a cathode, and a light emitting layer disposed between the pair of electrodes, wherein the light-emitting layer comprises the polycyclic aromatic compound according to any one of <1> to <9>.
<12> The organic electroluminescent element according to <11>, wherein the light emitting layer comprises a host and the polycyclic aromatic compound as a dopant.
<13> The organic electroluminescent element according to <12>, wherein the host is an anthracene-based compound, a fluorene-based compound, or a dibenzocrysene-based compound.
<14> A display device or a lighting device, comprising the organic electroluminescent element according to any one of <11> to <13>.

### Effect of the Invention

According to the present invention, there is provided a novel polycyclic aromatic compound useful as a material for an organic device such as an organic electroluminescent element. The polycyclic aromatic compound of the present invention can be used for manufacturing an organic device such as an organic electroluminescent element.

### BRIEF DESCRIPTION OF DRAWING

FIG. 1 is a schematic cross-sectional view showing an organic EL element.

FIG. 2 is an energy level diagram showing the energy relationship among the host, assisting dopant and emitting dopant of a TAF element using a common fluorescent dopant.

FIG. 3 is an energy level diagram showing an example of an energy relationship among a host, an assisting dopant, and an emitting dopant in an organic electroluminescent element according to one embodiment of the present invention.

### DESCRIPTION OF EMBODIMENTS

Hereinafter, the invention will be described in detail. Description of constituent features described below is made on the basis of typified embodiments or specific examples in several cases, but the invention is not limited to such embodiments. The numerical range represented by using “to” in the specification means a range including numerical values described before and after “to” as a lower limit and an upper limit. Moreover, “hydrogen” as used herein in description of a structural formula means a “hydrogen atom (H).”

Hereinafter, organic electroluminescent element is referred to as an organic EL device in several cases.

A chemical structure or a substituent is represented herein by using the number of carbon atoms in several cases. However, the number of carbon atoms when an atom of the chemical structure is replaced with the substituent in, when an atom of the substituent is further replaced with a substituent, or the like means the number of carbon atoms of each chemical structure or each substituent and does not mean the total number of carbon atoms of each chemical structure and the substituent thereof or the total number of carbon atoms of each substituent and the substituent thereof For example, an expression “substituent B having Y carbons which is subjected to substitution for substituent A having X carbos” means that hydrogen of “substituent B having Y carbons” is replaced with “substituent A having X carbons,” and the Y carbons do not represent the number of carbon atoms of a total of the substituent A and the substituent B. For example, an expression “substituent B having Y carbons which is subjected to substitution for substituent A” means that hydrogen of “substituent B having Y carbons” is replaced with “substituent A (in which the number of carbon atoms is not specified), and the Y carbons do not mean the number of carbon atoms of a total of the substituent A and the substituent B.

### 1.Polycycle Aromatic Compound

The polycyclic aromatic compound of the present invention is a polycyclic aromatic compound having a structure consisting of one or two or more of structural units represented by Formula (1). The polycyclic aromatic compound of the present invention has at least one ring represented by Formula (Het-1) or Formula (Het-2) as A ring, B ring, or a C ring in Formula (1). The polycyclic aromatic compound of the present invention has high emission quantum yield (PLQY), narrow emission half width, and excellent color purity.

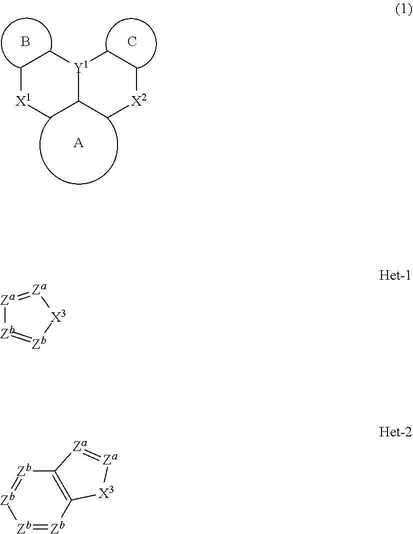

At least one ring selected from the group consisting of A ring, B ring and C ring in a structure consisting of one or two or more of structural units represented by Formula, (1) is a ring represented by Formula (Het-1) or Formula (Het-2). However, A ring is not a ring represented by Formula (Het-1). It is preferable that at least one ring selected from the group consisting of B ring and C ring in a structure consisting of one or two or more of the structural units represented by Formula (1) is a ring represented by Formula (Het-1) or Formula (Het-2).

In the structure consisting of one of the structural units represented by Formula (1), it is preferable that one or two rings selected from the group consisting of B ring and C ring are rings represented by Formula (Het-1) or Formula (Het-2), and it is more preferable that one ring selected from the group consisting of B ring and C ring is a ring represented by Formula (Het-1) or Formula (Het-2).

In the structure consisting of two or more structural units represented by Formula (I), at least one ring represented by Formula (Het-1) or Formula (Het-2) may or may not he included in each structural unit represented by Formula (1). In other words, even when at least one of A ring, B ring, or C ring is two or more, it is sufficient that at least one ring is a ring represented by Formula (Het-1) or Formula (Het-2).

In Formula (Het-1), Z^{b}s are carbons directly bonded to Y¹ and X¹, or Y¹ and X², respectively. That is, if Formula (Het-1) is B ring, then two consecutive Z^{b} will be carbons directly bonded to Y¹ and X¹, respectively, and if Formula (Het-1) is C ring, the two consecutive Z^{b} will be carbons directly bonded to Y¹ and X², respectively.

In Formula Het-2), any two or three consecutive Z^{b}s are carbons directly bonded to Y¹ and X¹ and/or X² in Formula (1). That is, if Formula (Het-2) is A ring, then the three consecutive Z^{b} are carbons directly bonded to Y¹, X¹ and X², and if Formula (Het-2) is B ring, the two consecutive Z^{b} are carbons directly bonded to Y¹ and X¹, and if Formula (Het-2) is C ring, the two consecutive Z^{b} are carbons directly bonded to Y¹ and X².

Each of the remaining Z^{b}s in Formula (Het-2) is independently N or C—R^{z}, and R^{Z} is hydrogen or a substituent. Alternatively, if Formula(Het-2) is B or C ring and Z^{b}s other than carbons directly bonded to Y¹ and X¹ or Y¹ and X² are adjacent to each other, Z^{b}═Z^{b} may be >O, >N—R, >C(—R)₂, >Si(—R)₂, >S, or >Se. Rs in >N—R, >C(—R) ₂, and >Si(—R)₂ are each independently hydrogen, a substituted or unsubstituted aryl, a substituted or unsubstituted heteroaryl, a substituted or unsubstituted alkyl, or a. substituted or unsubstituted cycloalkyl, and the two Rs of >C(—R)₂ and >Si(—R)₂ may be bonded to each other to form a ring. For details of the “substituted or unsubstituted aryl”, “substituted or unsubstituted heteroaryl”, “substituted or unsubstituted alkyl” and “substituted or unsubstituted cycloalkyl”, reference may be made to the description of the first substituent and the second substituent described below. Examples of rings resulting from replacing Z^{b}═Z^{b} with >O, >N—R, >C(—R)₂, >Si(—R)₂, >S, or >Se include pyrrole ring, furan ring, thiophene ring, and the like.

In Formulas (Het-1) and (Het-2), one Z^{a} is N and the other is N or C—R^{Z}. It is preferred that either one is N and the other is C—R^{Z}. When only one of Z^{a} is N, it is preferred that Z^{a} that is not adjacent to X³ is N.

Any other Z^{b}'s (Z^{b}'s other than the carbons that directly bonded to Y¹ and X¹ and/or X²) in Formula (Het-2) are preferably C—R^{Z}.

Each R^{Z} when Z^{a} or Z^{b} is C—R^{Z} is independently hydrogen or a substituent. Substituents here include a substituted or unsubstituted aryl, a substituted or unsubstituted heteroaryl, a substituted or unsubstituted diarylamino, a substituted or unsubstituted diheteroarylamino, a substituted or unsubstituted arylheteroarylamino, a substituted or unsubstituted diarylboryl (the two aryls may be bonded via a single bond or linking group), a substituted or unsubstituted alkyl, a substituted or unsubstituted cycloalkyl, a substituted or unsubstituted alkoxy, a substituted or unsubstituted aryloxy, and a substituted. For details of each substituent, reference may be made to the description of the first substituent described below.

Two adjacent R^{Z}'s in Formula (Het-2) may be bonded to each other to form a ring. In this specification, the term “adjacent” to a group such as R^{Z} means groups bonded to atoms adjacent to each other. A ring in which R^{Z}'s are bonded to each other means a ring formed together with the atoms to which R^{Z}s are bonded to. Such rings include aryl rings and heteroaryl rings, and for details reference may be made to the following description of these rings in A ring, B ring, or C ring. For details of substituents when the ring is substituted, reference may be made to the description of the first substituent and the second substituent described below.

R^{Z} in C—R^{Z} as a Z^{a} (sometimes referred to herein as R^{Za}) is preferably a substituent, and more preferably a substituted or unsubstituted alkyl, a substituted or unsubstituted cycloalkyl, unsubstituted aryl or a substituted or unsubstituted heteroaryl. By introducing a bulky substituent, it can be expected to improve the fluorescence quantum yield by increasing the distance between molecules and preventing association.

In this respect, it is particularly preferred that R^{Za} is a tertiary alkyl, an aryl substituted with tertiary alkyl, or a heteroaryl substituted with a tertiary alkyl. It is also preferred that R^{Za} is an unsubstituted aryl or an unsubstituted heteroaryl when X³ is >N—R and R in >N—R is an aryl substituted with a tertiary alkyl or an heteroaryl substituted with a tertiary alkyl. Examples of the tertiary alkyl include tent-butyl and 1,1-dimethylpropyl.

In Formula (Het-2), R^{Z} in C—R^{Z} as Z^{b} (sometimes referred to herein as R^{Zb}) is preferably hydrogen or unsubstituted (particularly, methyl) and more preferably hydrogen. It is particularly preferred that all other Z^{b}'s other than carbons directly bonded to Y¹ and X¹ and/or X² are C—H.

In Formulas (Het-1) and (Het-2), X¹ is >O, >N—R, >C(—R)₂, >S, or >Se, wherein R in >N—R is hydrogen, a substituted or unsubstituted aryl, a substituted or unsubstituted heteroaryl, a substituted or unsubstituted alkyl, or a substituted or unsubstituted cycloalkyl, and Rs in >C(—R)₂ are each independently hydrogen, a substituted or unsubstituted a substituted or unsubstituted heteroaryl, a substituted or unsubstituted alkyl, or a substituted or unsubstituted cycloalkyl. For details of each substituent, reference may be made to the description of the first substituent described below.

>R in N—R is a substituted or unsubstituted aryl, a substituted or unsubstituted heteroaryl, a substituted or unsubstituted alkyl., a substituted or unsubstituted cycloalkyl, and Rs in >C(—R₂ are each independently hydrogen, a substituted or unsubstituted aryl, a substituted or unsubstituted heteroaryl, a substituted or unsubstituted alkyl, or a substituted. or unsubstituted cycloalkyl. Preferably, it is an optionally substituted aryl, and more preferably an optionally substituted phenyl. R in >C(—R)₂ is preferably an optionally substituted alkyl, more preferably an unsubstituted alkyl, and more preferably ⁻unsubstituted methyl.

X³ is preferably >O, >C(—R₂, >S, or >Se, more preferably >O, >S. or >Se, and even more preferably >O or >S. However, when each of Formulas (Het-1) and (Het-2) does not have C—H as Z^{a}, X³ is preferably >O, >N—R, >C(—R)₂, or >S, and more preferably >O, >S, or >N—R. The absence of a C—H as Z^{a} is either when the two Z^{a}s are N, or one is N and the other is C_R^{Z} in which R^{Z} is a substituent.

Specific examples of the ring represented by Formula (Het-1) include the following structures.

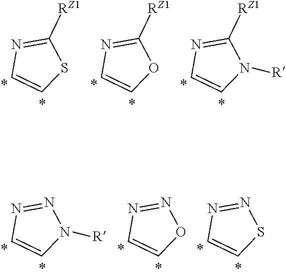

In Formula, the two * denote the positions directly bonded to Y¹ and X¹, or Y¹ and X². It may be bonded to Y¹ at whichever of the two * positions. R^{Z1} is synonymous with the above R^{Z} and is preferably a substituted or unsubstituted aryl, a substituted or unsubstituted heteroaryl, a substituted or unsubstituted diarylamino, or a substituted or unsubstituted alkyl. R′ is synonymous with R in >N—R as X³ and is preferably phenyl. The more specific examples of the ring represented by Formula (Het-1) are as follows.

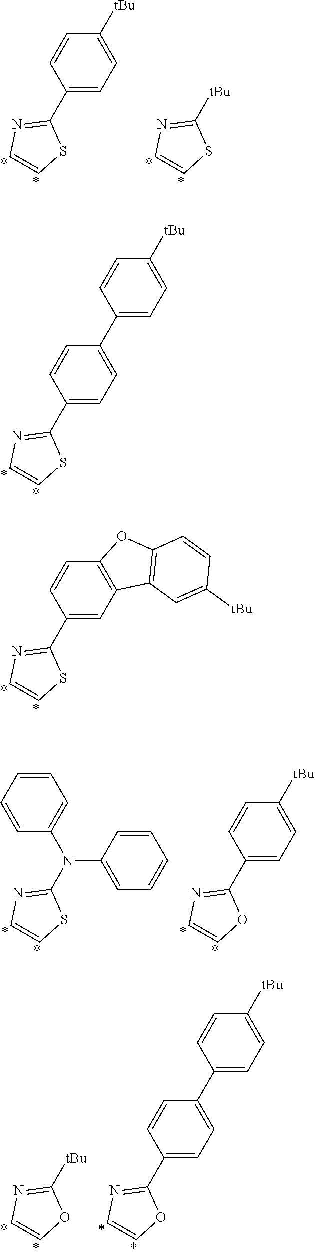

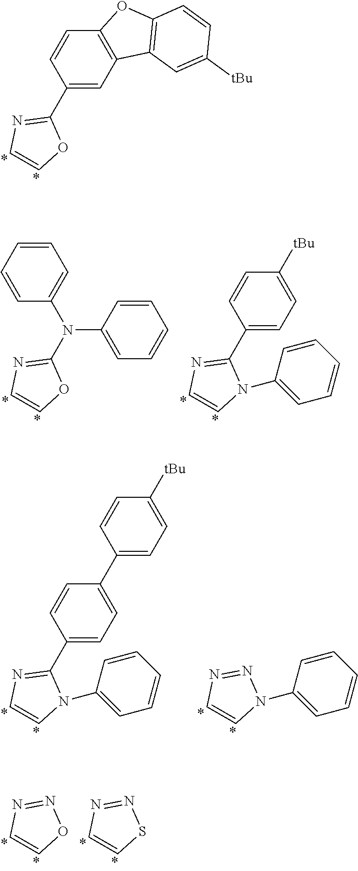

In the above Formulas, the two * denote the positions directly bonded with Y¹ and X¹, or Y¹ and X². The ring may be bonded to Y¹ at whichever of the two * positions. tBu represents t-butyl.

Specific examples of the case where the ring represented by Formula (Het-2) is B ring or C ring include the following structures.

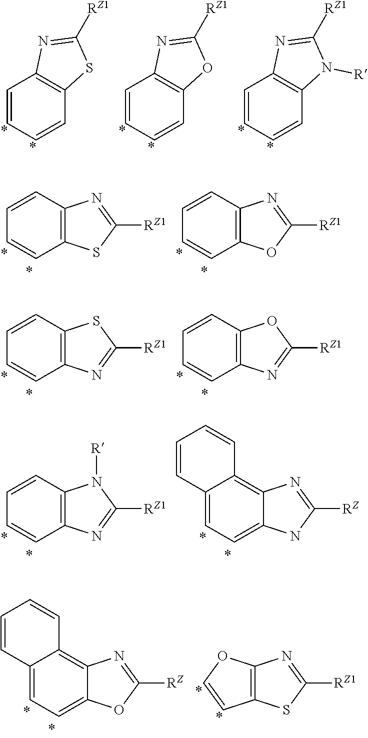

In Formula, the two * denote the positions directly bonded to Y¹ and X¹ or Y¹ and X². The ring may be bonded to Y¹ at whichever of the two * positions, R^{Z1} is synonymous with the above R^{Z} and is preferably a substituted or unsubstituted aryl, a substituted or unsubstituted heteroaryl, a substituted or unsubstituted diarylamino, or a substituted or unsubstituted alkyl. R′ is synonymous with R in >N—R as X³ and is preferably phenyl. The more specific examples of the ring represented by Formula (Het-2) are as follows.

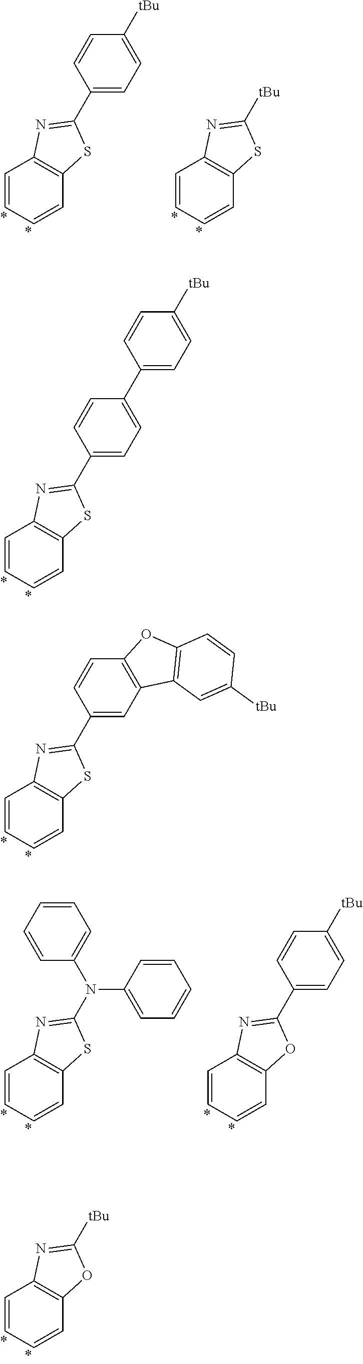

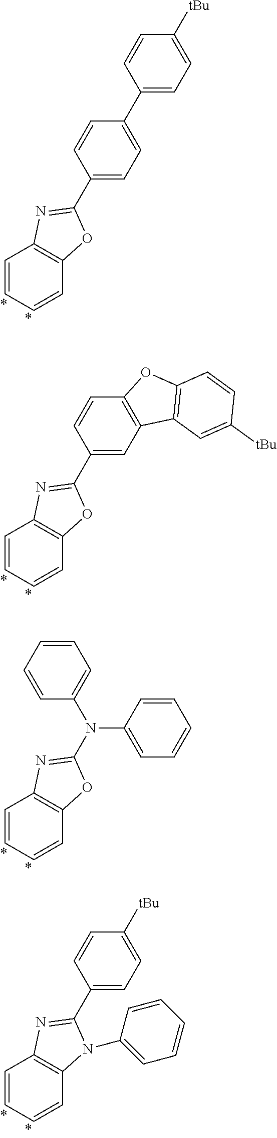 [SMILES: CC(C)(C)c1ccc(-c2ccc(-c3nc4ccccc4o3)cc2)cc1 ; CC(C)(C)c1ccc2oc3ccc(-c4nc5ccccc5o4)cc3c2c1 ; c1ccc(N(c2ccccc2)c2nc3ccccc3o2)cc1 ; CC(C)(C)c1ccc(-c2nc3ccccc3n2-c2ccccc2)cc1]

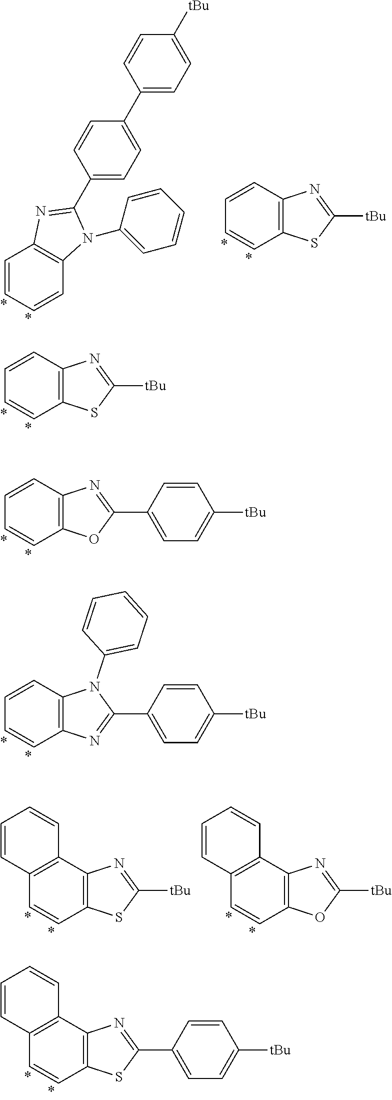

In the above Formula, the two * denote the positions directly bonded with Y¹ and X¹, or Y¹ and X². The ring may be bonded to Y¹ at whichever of the two positions. tBu represents t-butyl.

As the ring represented by Formula (I-let- l) or Formula (Het-2), any of the following rings is preferred. This is because a compound having any one of these structures provides an EL element having particularly high luminescent efficiency and high external quantum efficiency.

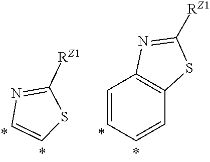

In Formula (1), each of A ring, B ring, and C ring is independently an optionally substituted aryl ring or an optionally substituted heteroaryl ring. Note that all of the rings represented by Formula (Het-1) and Formula (Het-2) described above correspond to heteroaryl rings which may be substituted.

The aryl or heteroaryl rings in the A, B and C rings are preferably bonded to Y¹ and X¹ and/or X² with its 5-or 6-membered ring. “ Bonded to and X¹ and/or X² with its 5-or 6-membered rings” means that a ring is formed with only this 5-or 6-membered ring, or that another ring(s) is fused to form a ring with the 5-or 6-membered ring. In other words, it means that the 5-or 6-membered rings constituting all or part of the ring are bonded to Y¹, and to X¹ and/or X². In an aryl or heteroaryl ring in A, B and C ring, two or three consecutive ring constituent atoms (carbon atoms) may be directly bonded to Y¹ and X¹ and/or X². That is, two of any set of consecutive ring constituent atoms (carbon atoms) are directly bonded to Y¹ and X¹ in an aryl or heteroaryl ring in B ring, two of any set of consecutive ring constituent atoms (carbon atoms) are directly bonded to Y¹ and X² in an aryl or heteroaryl ring in C ring, and three of any set of consecutive ring constituent atoms (carbon atoms) are directly bonded to Y¹, X¹ and X² in an aryl or heteroaryl ring in A ring.

As the “aryl ring” in A ring, B ring, or C ring in Formula (1), an aryl ring having 6 to 30 carbons is exemplified, an aryl ring having 6 to 16 carbons is preferable, an aryl ring having 6 to 12 carbons is more preferable, and an aryl ring having 6 to 10 carbons is particularly preferable.

Specific examples of the “aryl ring” include benzene ring as a monocyclic ring, biphenyl ring as a bicyclic ring, naphthalene ring and indene ring as a fused bicyclic ring, terphenyl ring (m-terphenyl, o-terphenyl, p-terphenyl) as a tricyclic ring, acenaphthylene ring, fluorene ring, phenalene ring, phenanthrene ring and anthracene ring as a fused tricyclic ring, triphenylene ring, pyrene ring. naphthacene ring and chrysene ring as a fused tetracyclic ring, perylene ring and pentacene ring as a fused pentacyclic ring. Further, the fluorene ring, the benzofluorene ring, and the indene ring also include a structure in which another fluorene ring, benzofluorene ring, and cyclopentane ring, and the like are spiro-bonded, respectively. The fluorene ring, benzofluorene ring and indene ring also include a dimethylfluorene ring, a dimethylbenzofluorene ring and a dimethylindene ring, in which two of the two hydrogens of methylene in the fluorene ring, benzofluorene ring and indene ring are each substituted with methyl (it may be another alkyl) as the first substituent described below,

As the “heteroaryl ring” in A¹ ring, B¹ ring, or C ring in Formula (1), a heteroaryl ring having 2 to 30 carbons is exemplified, a heteroaryl ring having 2 to 25 carbons is preferable, a heteroaryl ring having 2 to 20 carbons is more preferable, a heteroaryl ring having 2 to 15 carbons is further preferable, and a heteroaryl ring having 2 to 10 carbons is particularly preferable. Moreover, specific examples of the “heteroaryl ring” include a heterocyclic ring containing, in addition to carbons, 1 to 5 hetero atoms selected from oxygen, sulfur and nitrogen as a ring-forming atom.

Specific examples of the “heteroaryl ring” include a pyrrole ring, an oxazole ring, an isoxazol ring, a thiazole ring, an isothiazole ring, an imidazole ring, an oxadiazole ring, a thiadiazole ring, a triazole ring, a tetrazole ring, a pyrazole ring, a pyridine ring, a pyrimidine ring, a pyridazine ring, a pyrazine ring, a triazine ring, an indole ring, an isoindole ring, a 1H-indazole ring, a benzimidazole ring, a benzooxazole ring, a benzothiazole ring, a 1H-benzotriazol ring, a quinoline ring, an isoquinoline ring, a cinnoline ring, a quinazoline ring, a quinoxaline ring, a phthalazine ring, a naphthyridine ring, a purine ring, a pteridine ring, a carbazole ring, an acridine ring, a phenoxathiin ring, a phenoxazine ring, a phenothiazine ring, a phenazine ring, an indolizine ring, a furan ring, a benzofuran ring, an isobenzofuran ring, a dibenzofuran ring, a thiophene ring, a benzothiophene ring, a dibenzothiophene ring, a furazan ring, a thianthrene ring, indolocarbazole ring, benzoindrocarbazole ring, dibenzoindrocarbazole ring, naphthobenzofuran ring, dioxine ring, dihydroacridine ring, xanthene ring, thioxanthene ring, dibenzodioxin ring. Further, a dimethyldihydroacridine ring, a dimethylxanthene ring, a dimethylthioxanthene ring and the like are also preferable. These are obtained by substituting two of the two hydrogens of methylene in dihydroacridine ring, xanthene ring, and thioxanthene ring with methyl (it may be another alkyl) as the first substituent described later. Further, bipyridine ring, phenylpyridine ring, and pyridylphenyl ring which are bicyclic, terpyridyl ring, bispyridylphenyl ring, and pyridylbiphenyl ring which are a tricyclic can be also exemplified as a “heteroaryl ring.” Further, the “heteroaryl ring” shall also include pyran ring.

At least one of the hydrogens in the “aryl ring” or “heteroaryl ring” above may be replaced with a first substituent, which is a substituted or unsubstituted “aryl”, a substituted or unsubstituted “heteroaryl”, a substituted or unsubstituted “diarylamino”, a substituted or unsubstituted “diheteroarylamino”, a substituted or unsubstituted “arylheteroarylamino”, a substituted or unsubstituted “diarylboryl”, a substituted or unsubstituted “alkyl”, a substituted or unsubstituted “cycloalkyl”, a substituted or unsubstituted “alkoxy”, a substituted or unsubstituted “aryloxy”, or a substituted “silyl”, and examples of “aryl” or “heteroaryl”, as the first substituent, aryl in “diarylmino”, heteroaryl in “diheteroarylamino”, aryl and heteroaryl in “arylheteroarylamino”, aryl in “diarylboryl”, and aryl in “aryloxy” include the above-mentioned monovalent groups of “aryl ring” or “heteroaryl ring”.

Specific examples of the “aryl” include an aryl having 6 to 30 carbons, and an aryl having 6 to 20 carbons is preferred, an aryl having 6 to 16 carbons is further preferred, an aryl having 6 to 12 carbons is particularly preferred, and an aryl having 6 to 10 carbons is most preferred.

Specific examples of aryl include phenyl as monocyclic aryl, (2-,3-,4-)biphenylyl as bicyclic aryl, (1-,2-)naphthyl and (2-,3-,4-,5-,6-,7-)indenyl as fused bicyclic aryl, terphenylyl(m-terphenyl-2′-yl, m-terphenyl-4′-yl, m-terphenyl-5′-yl, o-terphenyl-3′-yl, o-terphenyl-4′-yl, p-terphenyl-2′-yl, m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl) as tricyclic aryl, acenaphthylen-(1-,3-,4-,5-)yl phenalen-(1-,2-)yl, (1-,2-,3-,4-,9-)phenanthryl as fused tricyclic aryl, quaterphenylyl (5′-phenyl-m-terphenyl-2-yl, 5′-phenyl-m-terphenyl-3-yl, 5 -phenyl-m-terphenyl-4-yl, m-quaterphenylyl) as tetracyclic aryl, triphenylen-(1-,2-)yl, pyren-(1-,2-,4-)yl, naphthacen-(1-,2-,5-)yl as fused tetracyclic aryl, pentacen-(1-,2-,5-,6-)yl as fused pentacyclic aryl.

Specific examples of the “heteroaryl” include heteroaryl having 2 to 30 carbons or heteroaryl having 2 to 25 carbons is preferred, heteroaryl having 2 to 20 carbons is further preferred, heteroaryl having 2 to 15 carbons is still further preferred, and heteroaryl having 2 to 10 carbons is particularly preferred. Moreover, specific examples of heteroaryl include a heterocyclic ring containing, in addition to carbon, 1 to 5 hetero atoms selected from oxygen, sulfur and nitrogen as a ring-forming atom.

Specific examples of the heteroaryl include furyl, thienyl, pyrrolyl, oxazolyl, isoxazolyl, thiazolyl, isothiazolyl, imidazolyl, pyrazolyl, oxadiazolyl, furazanyl, thiadiazolyl, triazoryl, tetrazolyl, pyridyl, pyrimidinyl, pyridazinyl, pyrazinyl, triazinyl, benzofuranyl, isobenzofuranyl, dibenzofuranyl, benzo[b]thienyl, dibenzothienyl, indolyl, isoindolyl, 1H-indazolyl, benzimidazolyl, benzoxazolyl, benzothiazolyl, 1H-benzotriazoryl, isoquinolyl, cinnolyl, quinazolyl, quinoxalinyl, phthazinyl, naphthyridinyl, purinyl, pteridinyl, carbazolyl, acridinyl, phenoxazinyl, phenothiazinyl, phenazinyl, phenoxathiinyl, thianthrenyl and indrizinyl.

“Alkyl” as a first substituent may be either a straight chain or a branched chain, and specific examples thereof include a straight-chain alkyl having 1 to 24 carbons or a branched-chain alkyl having 3 to 24 carbons. An alkyl having 1 to 18 carbons (a branched-chain alkyl having 3 to 18 carbons) is preferred, and an alkyl having 1 to 12 carbons (a branched-chain alkyl having 3 to 12 carbons) is further preferred, and an alkyl having 1 to 6 carbons (a branched-chain alkyl having 3 to 6 carbons) is still further preferred, and an alkyl having 1 to 5 carbons (a branched-chain alkyl having 3 to 5 carbons) is particularly preferred.

Specific examples of the “alkyl” include methyl, ethyl, n-propyl, isopropyl, n-butyl, isobutyl, s-butyl, t-butyl, isopentyl, neopentyl, t-pentyl(t-amyl), n-hexyl, 1-methylpentyl, 4-methyl-2-pentyl, 3,3-dimethylbutyl, 2-ethylbutyl, n-heptyl, 1-methylhexyl, n-octyl, t-octyl (1,1,3,3-tetramethylbutyl), 1-methylheptyl, 2-ethylhexyl, 2-propylpentyl, n-nonyl, 2,2-dimethylheptyl, 2,6-dimethyl-4-heptyl, 3,5,5-trimethylhexyl, n-decyl, n-undecyl, 1-methyldecyl, n-dodecyl, n-tridecyl, -hexylheptyl, n-tetradecyl, n-pentadecyl, n-hexadecyl, n-heptadecyl, n-octadecyl and n-eicosyl.

The examples further include 1-ethyl-1-methylpropyl, 1,1-diethylpropyl, 1,1-dimethylbutyl, 1-ethyl-1-methylbutyl, 1,1,4-trimethylpentyl, 1,1,2-trimethylpropyl, 1,1-dimethyloctyl, 1,1-dimethypentyl, 1,1-dimethylheptyl, 1,1,5-trimethylhexyl, 1-ethyl-1-methylhexy, 1-ethyl-1,3-dimethylbutyl, 1,1,2,2-tetramethylpropyl, 1-butyl -1-methylpentyl, 1,1-diethylbutyl, 1-ethyl-1-methylpentyl, 1,1,3-trimethylbutyl, 1-propyl-1-methylpentyl, 1,1,2-trimethylpropyl, 1-ethyl-1,2,2-trimethylpropyl, 1-propyl-1-methylbutyl, and 1,1-dimethylhexyl.

As a substituent containing “alkyl” described above, a tertiary-alkyl represented by the following formula (tR) is one of particularly preferred as a substituent to an aryl ring or a heteroaryl ring in A ring, B ring and C ring. This is because the emission quantum yield (PLQY) is improved as the intermolecular distance is increased by such a bulky substituent. Also preferred is a substituent in which a tertiary-alkyl represented by formula (tR) is substituted to another substituent as a second substituent. Specific examples thereof include a diarylamino substituted with a tertiary-alkyl represented by (tR), a carbazolyl substituted with a tertiary alkyl represented by (tR) (preferably, N-carbazolyl) or a benzocarbazolyl substituted with a tertiary-alkyl represented by (tR) (preferably, N-benzocarbazolyl). For “diarylamino”, there may be mentioned the group which is described as “first substituent” below. Substituted forms of groups of formula (tR) to diarylamino, carbazolyl and benzocarbazolyl include examples in which some or all hydrogens of the aryl ring or the benzene ring in these groups are replaced with groups of Formula (tR).

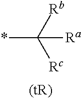

In Formula (tR), R^{a}, R^{b} and R^{c} are each independently an alkyl having 1 to 24 carbons, any —CH₂— in the alkyl may be replaced with —O—, and the group represented by Formula (tR) replaces at least one hydrogen in the compound including the structure unit represented by Formula (1) at *.

“Alkyl having 1 to 24 carbons” as R^{a}, R^{b}, and R^{c} may be either a straight chain or a branched chain, for example, a straight chain alkyl haying 1-24 carbons or a branch chain alkyl having 3 to 24 carbons. Examples include an alkyl haying 1 to 18 carbons (a branch chain alkyl having of 3-18 carbons), an alkyl having 1 to 12 carbons (a branch chain alkyl haying 3-12 carbons), an alkyl having 1 to 6 carbons (a branch chain alkyl having 3 to 6 carbons), or an alkyl having 1 to 4 carbons (a branch chain alkyl having 3 to 4 carbons).

The sum of the number of carbons in R^{a}, R^{b}, and Rc in Formula (tR) is preferably from 3 to 20, and particularly preferably from 3 to 10.

Specific alkyls of R^{a}, R^{b} and R^{c} include methyl, ethyl, n-propyl, isopropyl, n-butyl, s-butyl, t-butyl, n-pentyl, isopentyl, neopentyl, t-pentyl, n-hexyl, 1-methylpentyl, 4-methyl-2-pentyl, 3,3-dimethylbutyl, 2-ethylbutyl, 2-heptyl, 1-methylhexyl, n-octyl, t-octyl, 1-methylheptyl, 2-ethylhexyl, 2-propylpentyl, n-nonyl, 2,2-dimethylheptyl, 2,6-dimethyl-4-heptyl, 3,5,5-trimethylhexyl, n-decyl, n-undecyl, 1-methyldecyl, n-dodecyl, n-tridecyl, 1-hexylheptyl, n-tetradecyl, n-pentadecyl, n-hexadecyl, n-heptadecyl, n-octadecyl, n-eicosyl, and the like.

Examples of a group represented by Formula (tR) include t-butyl, t-amyl, 1-ethyl-1-methylpropyl, 1,1-diethylpropyl, 1,1-diethylbutyl, 1-ethyl-1-methylbutyl, 1,1,3,3-tetramethylbutyl, 1,1,4-trimethylpentyl, 1,1,2-trimethylpropyl, 1,1-dimethyloctyl, 1,1-dimethylpentyl, 1,1-dimethylheptyl, 1,1,5-trimethylhexyl, 1-ethyl-1-methylhexyl, 1-ethyl-1,3-dimethylbutyl, 1,1,2,2-tetramethylpropyl, 1-butyl-1-methylpentyl, 1,1-diethylbutyl, 1-ethyl-1-methylpentyl, 1,1,3-trimethylbutyl, 1-propyl-1-methylpentyl, 1,1,2-trimethylpropyl, 1-ethyl-1,2,2-trimethylpropyl, 1-propyl-1-methylbutyl, 1,1-dimethylhexyl, and the like. Of these, t-butyl and t-amyl are preferred.

Moreover, specific examples of “cycloalkyl” as a first substituent include a cycloalkyl having 3 to 24 carbons, a cycloalkyl haying 3 to 20 carbons, a cycloalkyl having 3 to 16 carbons, a cycloalkyl having 3 to 14 carbons, a cycloalkyl having 5 to 10 carbons, a cycloalkyl having 5 to 8 carbons, a cycloalkyl haying 5 to 6 carbons, a cycloalkyl having 5 carbons, and the like.

Specific examples of the cycloalkyl include cyclopropyl, cyclobutyl, cyclopentyl, cyciohexyl, cycloheptyl, cyclooctyl, cyclononyl, cyclodecyl, and an alkyl (especially methyl) substituents thereof having 1 to 5 carbons, norbornyl(bicyclo[2.2.1]heptyl), bicyclo[1.1.0]butyl, bicyclo[1.1.1]pentyl, bicyclo[2.1.0]pentyl, bicyclo[2.1.1]hexyl, bicyclo[3.1.0]hexyl, bicyclo[2.2.2]octyl, adamanthyl, diamantyl, decahydronaphthalenyl, and decahydroazulenyl,

Moreover, specific examples of “alkoxy” as a first substituent include a straight-chain alkoxy having 1 to 24 carbons or a branched-chain alkoxy having 3 to 24 carbons. An alkoxy having 1 to 18 carbons (a. branched-chain alkoxy having 3 to 18 carbons) is preferred, and an alkoxy having 1 to 12 carbons (a branched-chain alkoxy having 3 to 12 carbons) is more preferred, and an alkoxy having 1 to 6 carbons (a branched-chain alkoxy having 3 to 6 carbons) is further preferred, and an alkoxy having 1 to 5 carbons (a branched-chain alkoxy having 3 to 5 carbons) is particularly preferred.

Specific examples of the alkoxy include methoxy, ethoxy, propoxy, isopropoxy, butoxy, isobutoxy, s-butoxy, t-butoxy, t-amyloxy, pentyloxy, hexyloxy, heptyloxy and octyloxy.

Examples of the “substituted silyl” as the first substituent include silyl substituted with 3 substituents selected from the group consisting of alkyl, cycloalkyl, and aryl. Examples thereof include trialkvlsilyl, alkyldicycloalkylsilyl, triarylsilyl, dialkylarylsilyl, and alkyldiarylsilyl.

Examples of “trialkylsilyl” include a group in which 3 hydrogens in silyl are each independently replaced with an alkyl. As this alkyl, the groups described as “alkyl” in the first substituent described above can be referred to. An alkyl by which hydrogen is preferably replaced is an alkyl having 1 to 5 carbons, and specific examples thereof include methyl, ethyl, propyl, isopropyl, butyl, sec-butyl, t-butyl and t-amyl.

Specific examples of the trialkylsilyl include trimethylsilyl, triethylsilyl, tripropylsilyl, triisopropylsilyl, tributylsilyl, trisec-butylsilyl, ethyldimethylsilyl, propyldimethylsilyl, i-propyldimethylsilyl, butyldimethylsilyl, sec-butyldimethylsilyl, t-butyldimethylsilyl, t-amyldimethylsilyl, ethyldiethylsilyl, propyldiethylsilyl, propyldiethylsilyl, butyldiethylsilyl, sec-butyldiethylsilyl, t-butyldiethylsilyl, t-amyldiethylsilyl, methyldipropylsilyl, ethyldipropylsilyl, butyldipropylsilyl, sec-butyldipropylsilyl, t-butyldipropylsilyl, t-amyldipropylsilyl, methyldiisopropylsilyl, ethyldiisopropylsilyl, butyldiisopropylsilyl, sec-butyldiisopropylsilylt-butyldiisopropylsilyl and t-amyldiisopropylsilyl.

Examples of “tricycloalkylsilyl” include a group in which 3 hydrogens in silyl are each independently replaced with cycloalkyl. As this cycloalkyl, the groups described as “cycloalkyl” in the first substituent described above can be referred to. A preferred example of a cycloalkyl for substitution includes a cycloalkyl having 5 to 10 carbons. Specific examples include cyclopentyl, cyclohexyl, cycloheptyl, cyclooctyl, cyclononyl, cyclodecyl, bicyclo[1.1.1]pentyl, bicyclo[2.1.0]pentyl, bicyclo[2.1. bicyclo[3.1.0]hexyl, bicyclo[2.2.1]heptyl], bicyclo[2.2.2]octyl, adamantyl, decahydronaphthalenenyl, decahydroazurenyl, and the like.

Specific examples of tricycloalkylsilyl include tricyclopentylsilyl, tricyclohexylsilyl, and the like.

Specific examples of dialkylcycloalkylsilyl in which two alkyls and one cycloalkyl are substituted and alkyldicycloalkylsilyl in which one alkyl and two cycloalkyls are substituted include silyl in which groups selected from the specific alkyl and cycloalkyl described above are substituted.

Specific examples of diaklarylsilyl substituted with two alkyls and one aryl, alkyldialylsilyl substituted with one alkyl and two aryls, and triarylsilyl substituted with three aryls include silyl substituted with groups selected from the specific alkyl and aryl described above. A specific example of the triarylsilyl includes triphenylsilyl.

Also, as “aryl” in “diarylboryl” of the first substituent, the description of aryl described above can be quoted. The two aryls may also be bonded via a single bond or a linking group (e.g., >C(—R)₂, >O, >S, or >N—R), Here, R in >C(—R)₂ and >N—R is an aryl, a heteroaryl, a diarylamino, an alkyl, a cycloalkyl, an alkoxy or an aryloxy (the first substituent), and further an aryl, a heteroaryl, an alkyl, or a cycloalkyl (the second substituent) may be substituted to the first substituent. For specific examples of these groups, the description of the aryl, heteroaryl, diarylamino, alkyl, cycloalkyl, alkoxy, or aryloxy as the first substituent described above can be quoted.

In substituted or unsubstituted “aryl,” substituted or unsubstituted “heteroaryl,” substituted or unsubstituted “dialylamino,” substituted or unsubstituted “diheteroarylamino,” substituted or unsubstituted “arylheteroarylamino,” substituted or unsubstituted “diarylbolyl, (the two aryls may be bonded via a single bond or a linking group)” a substituted or unsubstituted “alkyl,” substituted or unsubstituted “cycloalkyl,” substituted or unsubstituted “alkoxy,” substituted or unsubstituted “aryloxy” or substituted “silyl” as the first substituent, at least one hydrogen therein may be replaced with the second substituent as described as “substituted or unsubstituted.” Examples of the second substituent include aryl, heteroaryl, alkyl or cycloalkyl, and specific examples thereof can be referred to the above-described description for the monovalent group of the “aryl ring” and the “heteroaryl ring,” and the “alkyl” or the “cycloalkyl” as the first substituent. Moreover, aryl or heteroaryl as the second substituent also includes a group in which, at least one hydrogen therein is replaced with an aryl such as phenyl (specific examples include the above-described groups), or an alkyl such as methyl or t-butyl (specific examples include the above-described groups), or a cycloalkyl such as cyclohexyl (specific examples include the above-described groups). As one example, when the second substituent is a carbazolyl, a carbazolyl group in which, at least one hydrogen in the 9-position is replaced with an aryl such as phenyl, an alkyl such as methyl, or a cycloalkyl such as cyclohexyl is also included in heteroaryl as the second substituent.

The emission wavelength can be tuned by the steric hindrance, electron-donating and electron-withdrawing nature of the structure of the first substituent. Preferable examples are the groups represented by the following structural formulas. Among them, methyl, t-butyl, t-amyl, t-octyl, neopentyl, adamantyl, phenyl, o-tolyl, p-tolyl, 2,4-xylyl, 2,6-xylyl, diphenylamino, di-p-tolylamino, bis(p-(t-butyl)phenyl)amino, carbazolyl, 3,6-dimethylcarbazolyl, 3,6-di-t-butylcarbazolyl and phenoxy are more preferred, and methyl, t-butyl, t-amyl, t-octyl, neopentyl, adamantyl, phenyl, o-tolyl, 2,6-xylyl, 2,4,6-mesityl, diphenylamino, di-p-tolylami no, bis(p-(t-butyl)pheny)amino, carbazolyl, 3,6-dimethylcarbazolyl and 3,6-di-t-butylcarbazolyl are further preferred. From the viewpoint of ease of synthesis, a larger steric hindrance is preferred for selective synthesis, and specifically, t-butyl, t-amyl, t-octyl, adamanthyl, o-tolyl, 2,4-xylyl, 2,5-xylyl, 2,6-xylyl, 2,4,6-mesityl, di-p-tolylamino, bis(p-(t-butyl)phenyl)amino, 3,6-dimethylcarbazolyl and 3,6-di-t-butylcarbazolyl are preferred.

In the following structural formulas, “Me” represents methyl, “tBu” represents t-butyl, “tAm” represents t-amyl, “tOct” represents t-octyl, and * represents a bonding position.

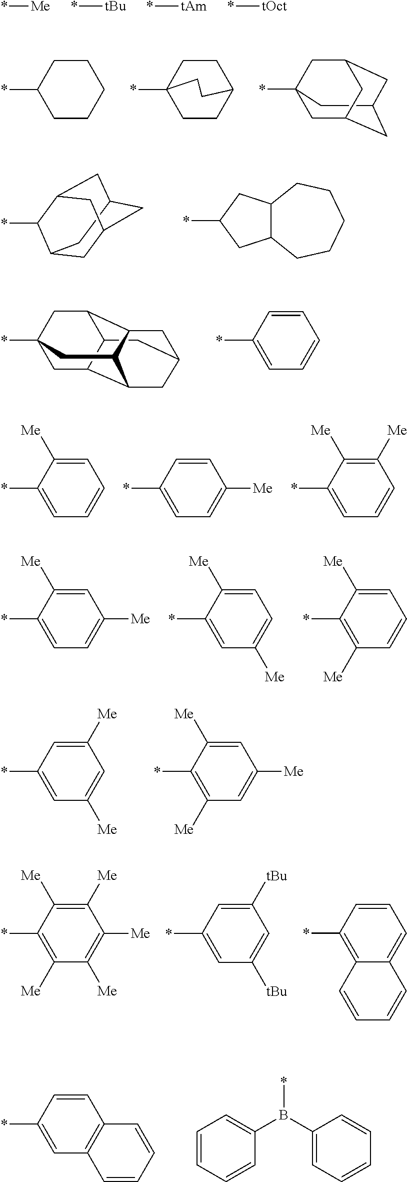

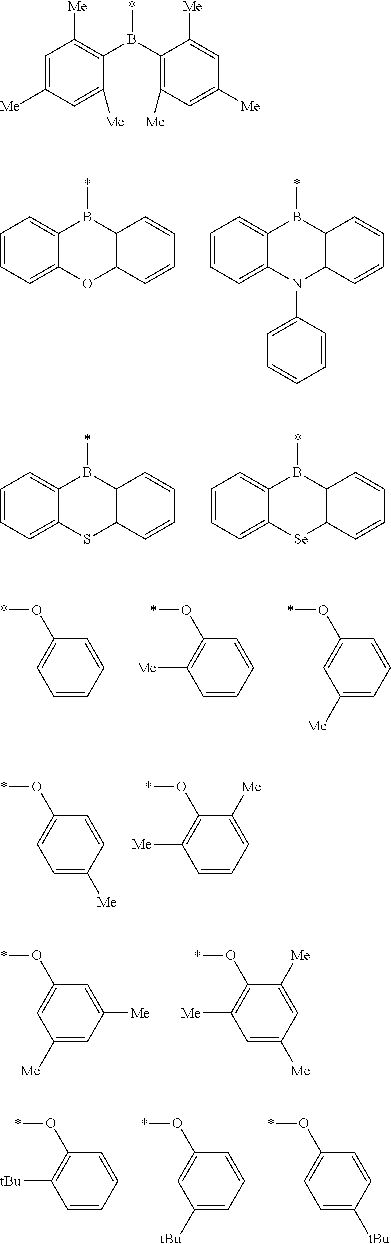

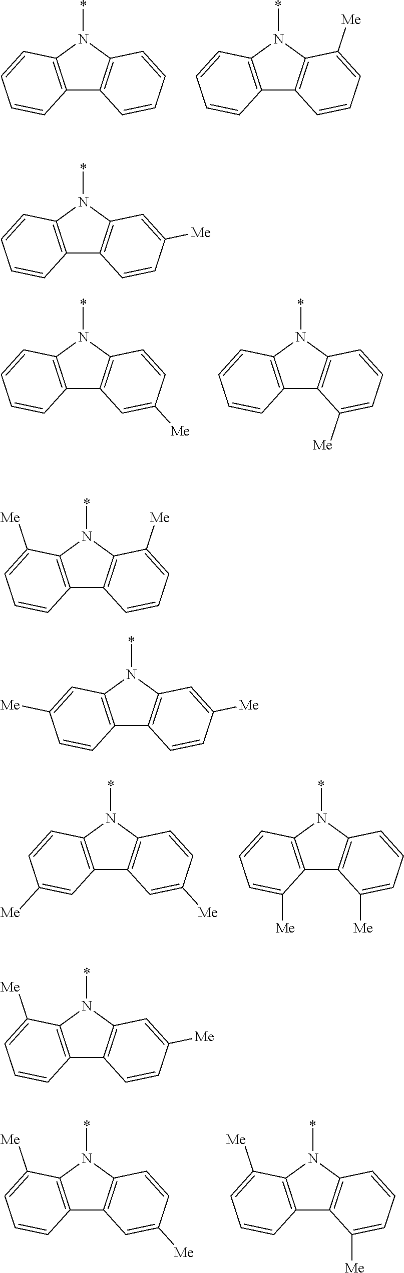

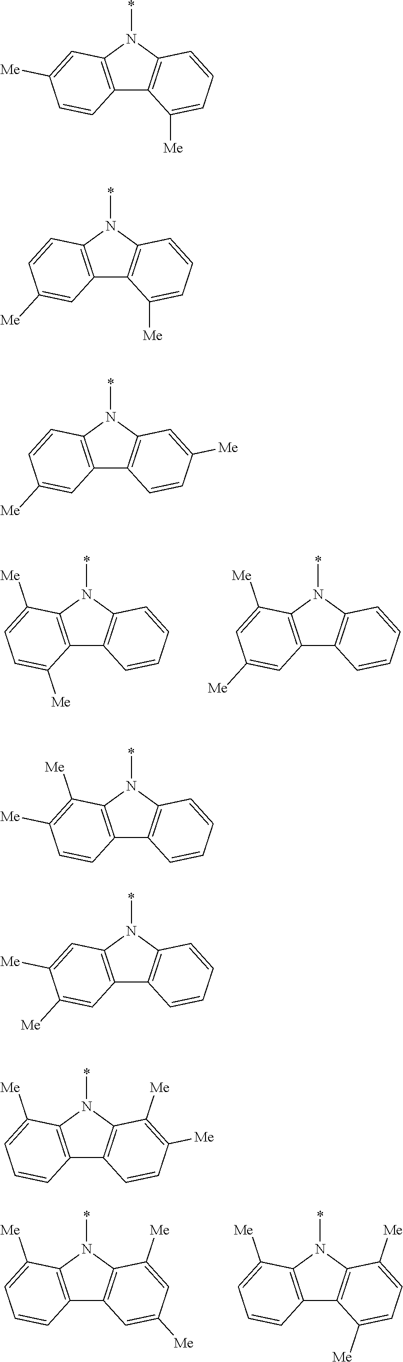

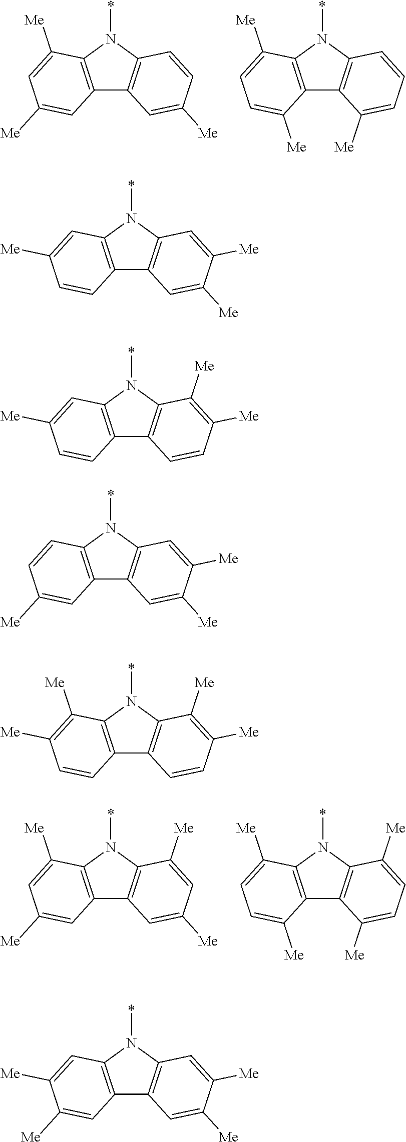

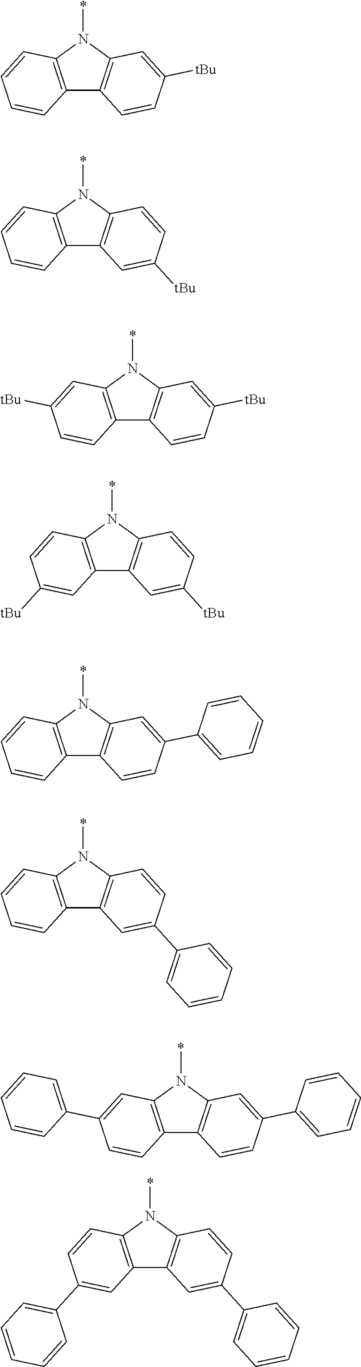

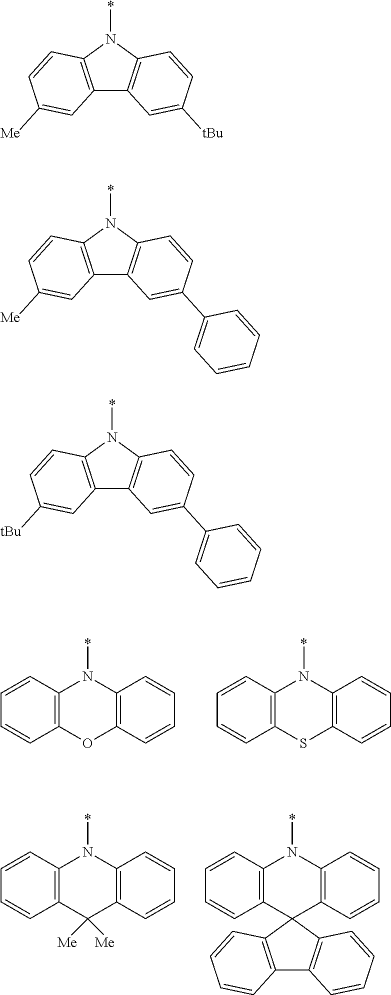

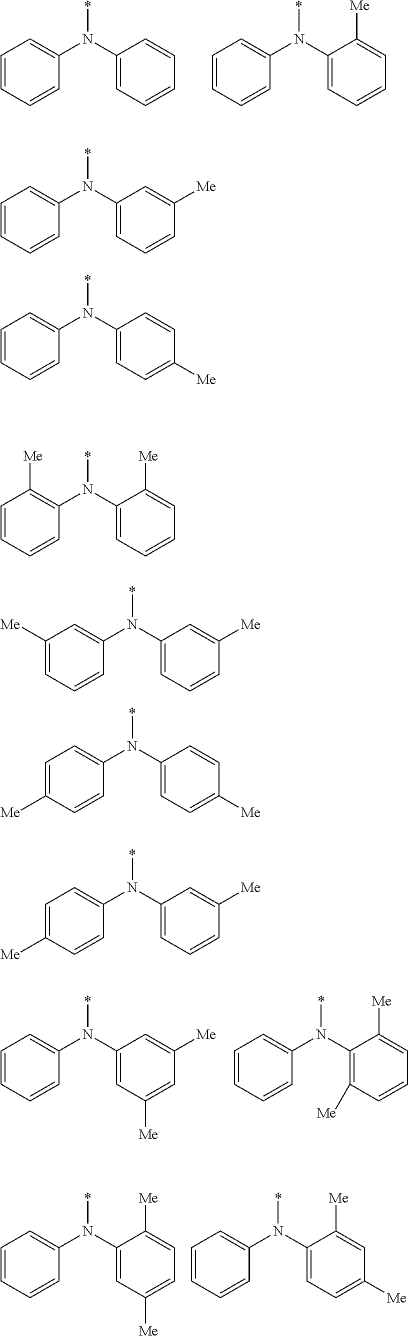

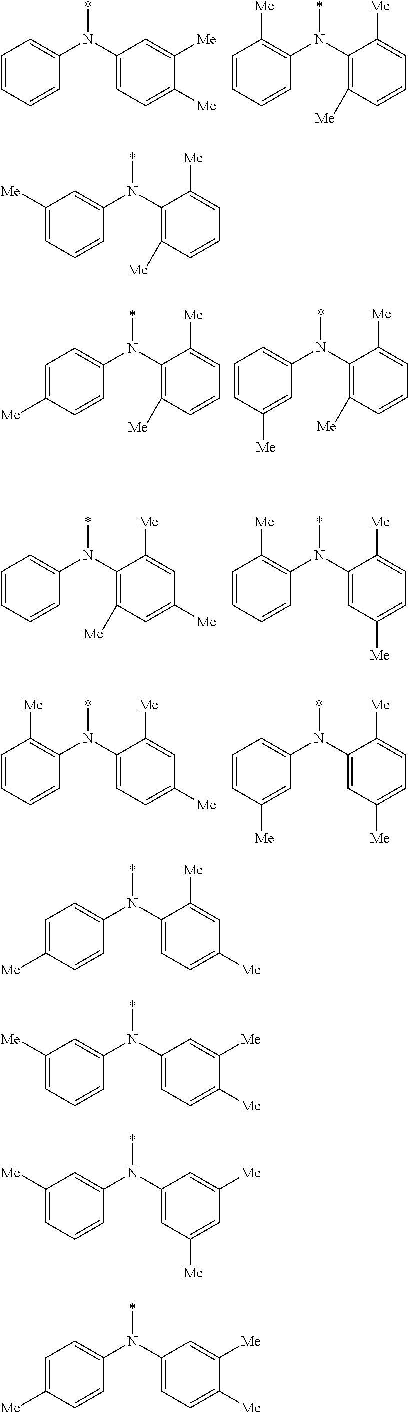

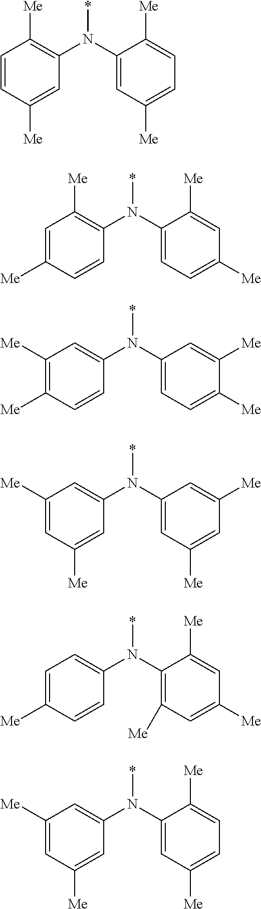

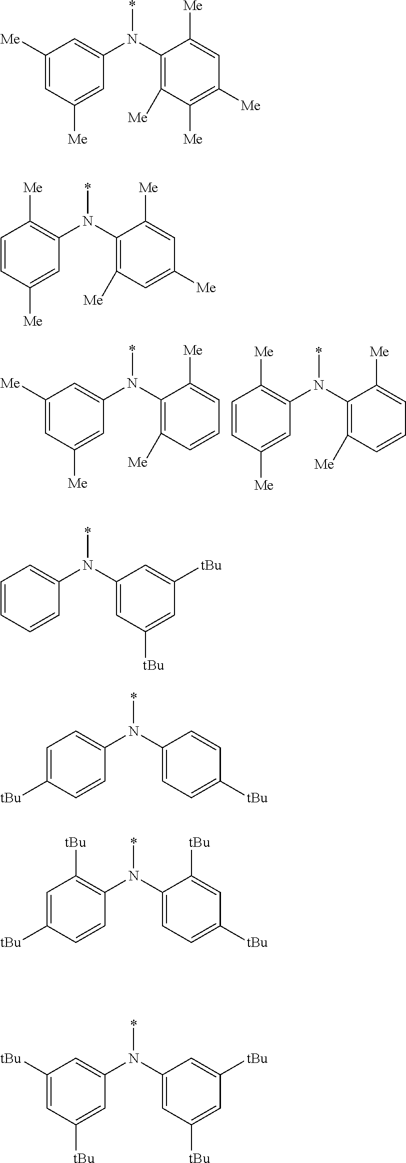

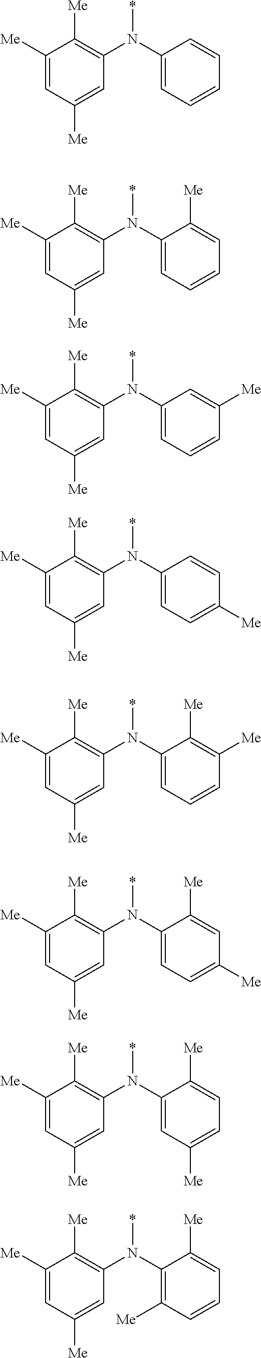

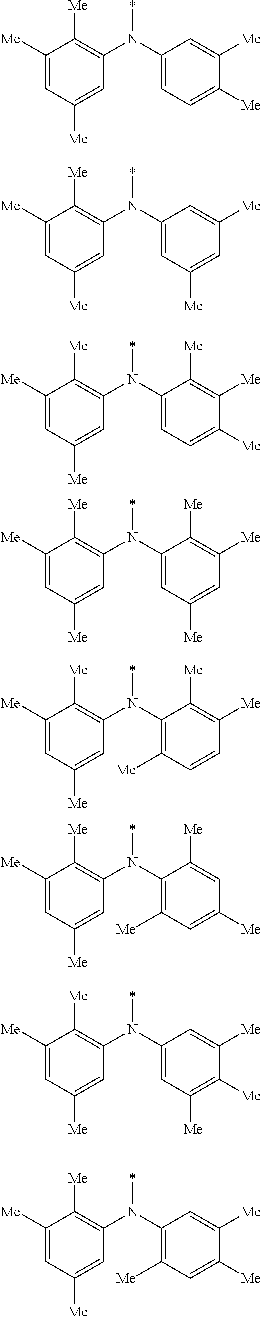

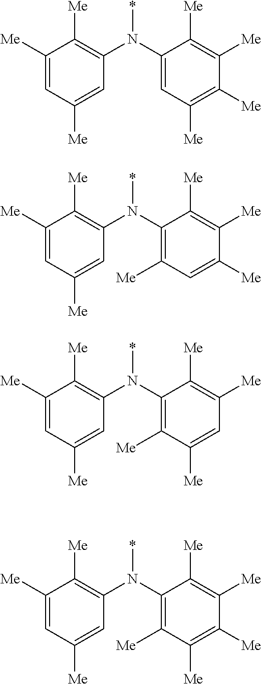

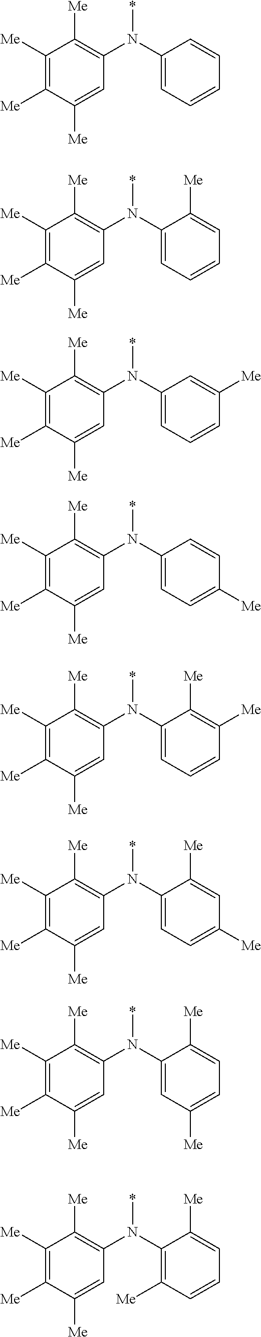

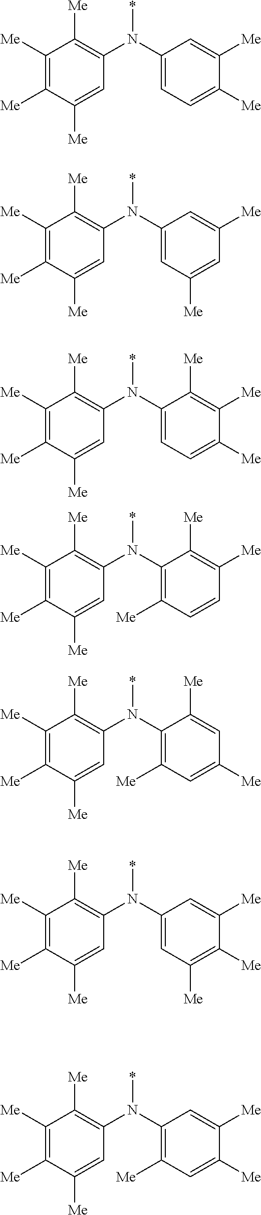

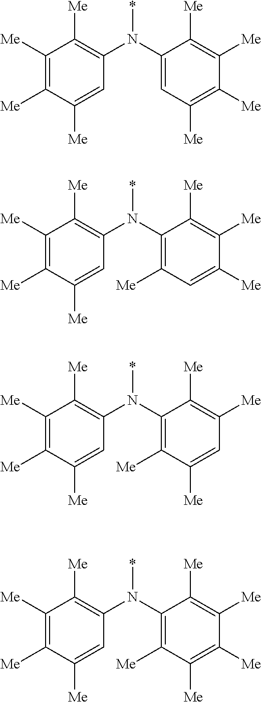

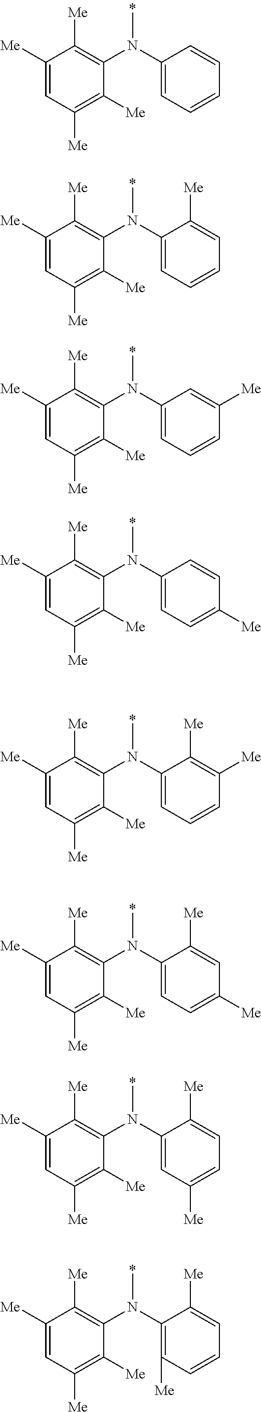

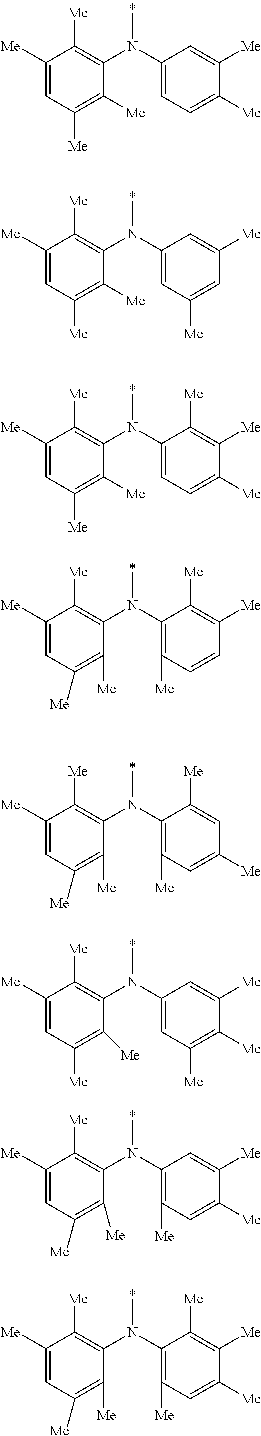

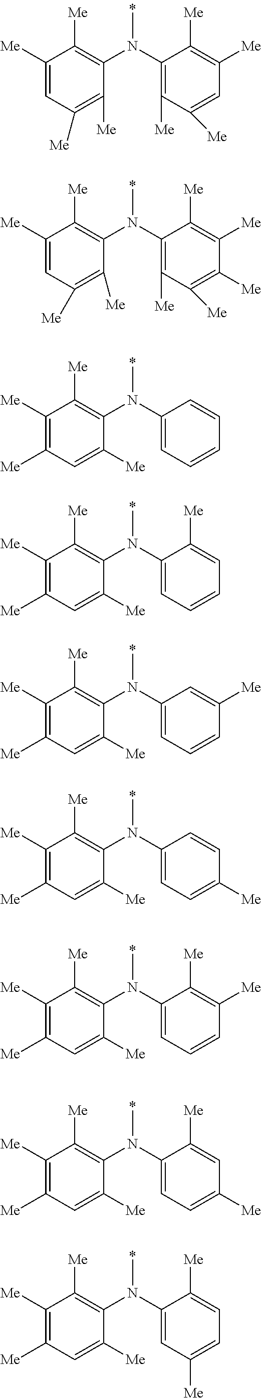

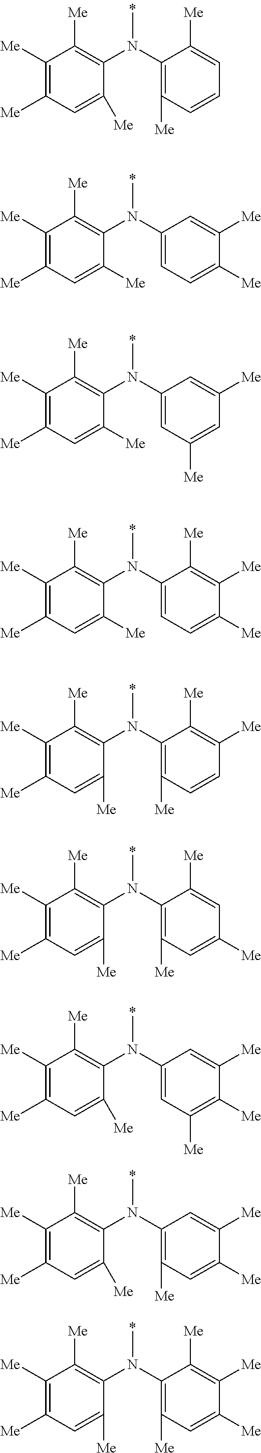

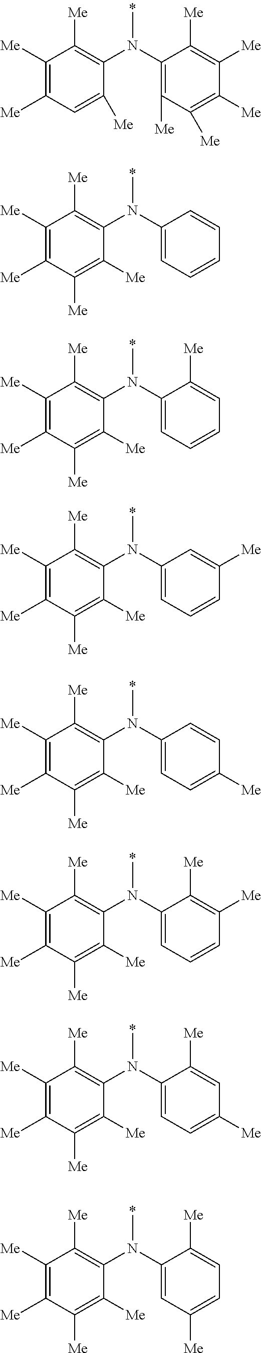

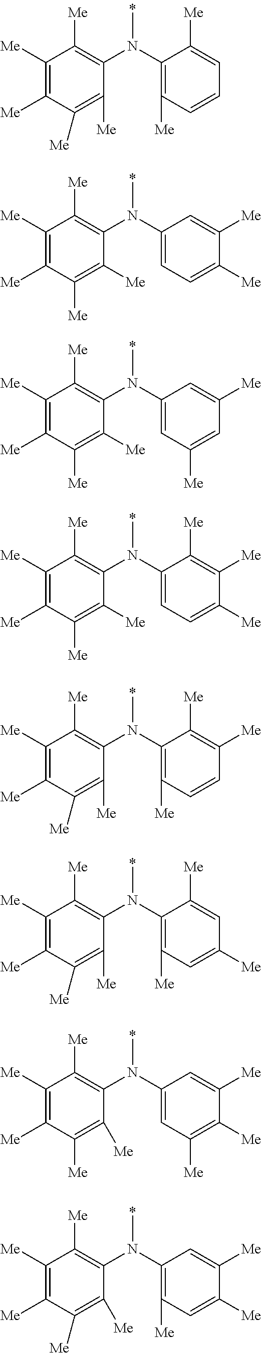

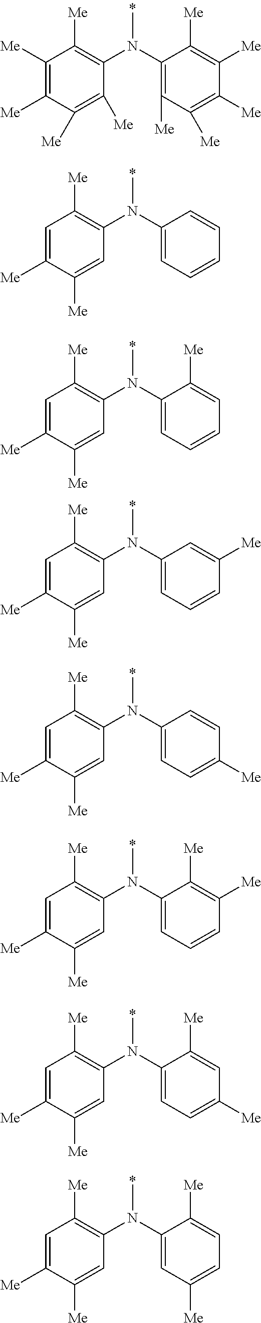

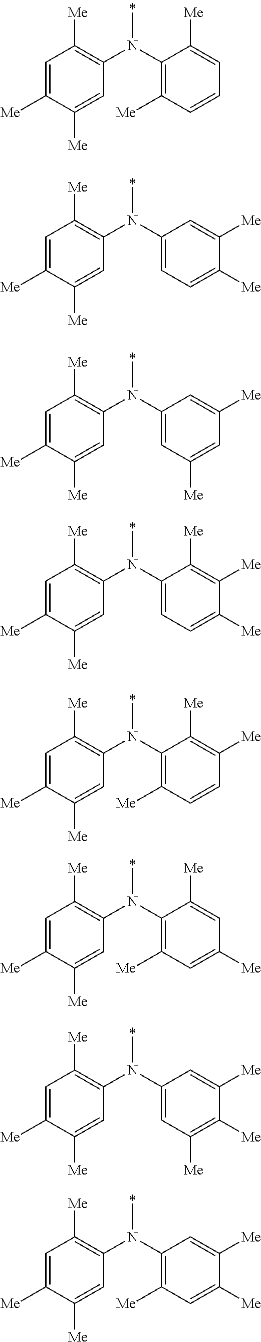

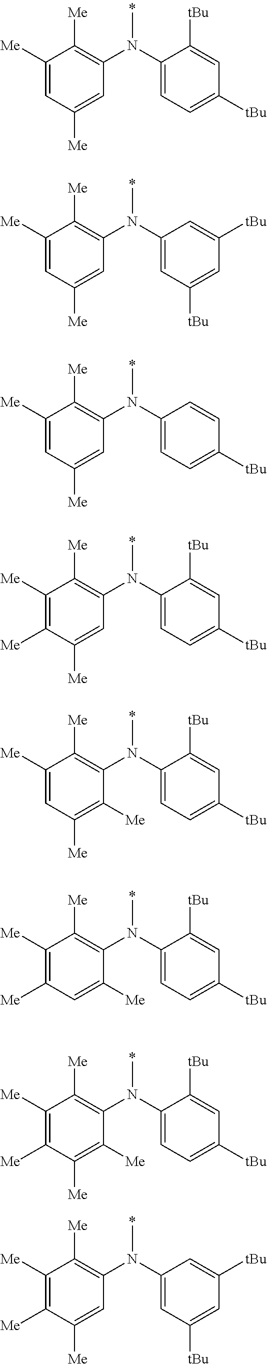

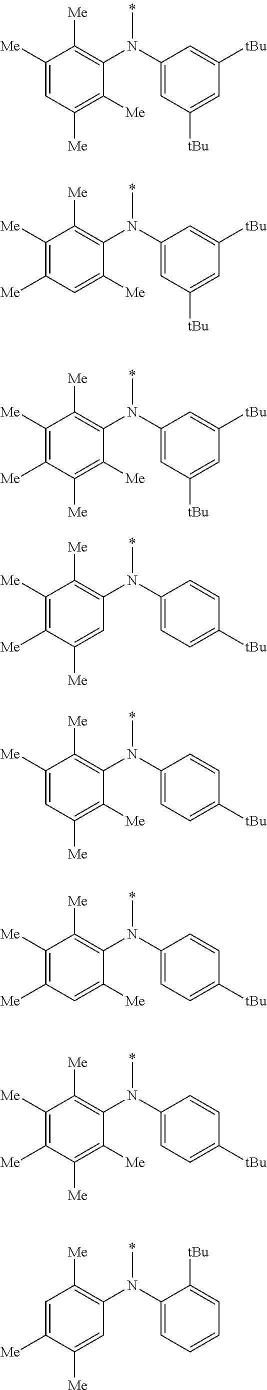

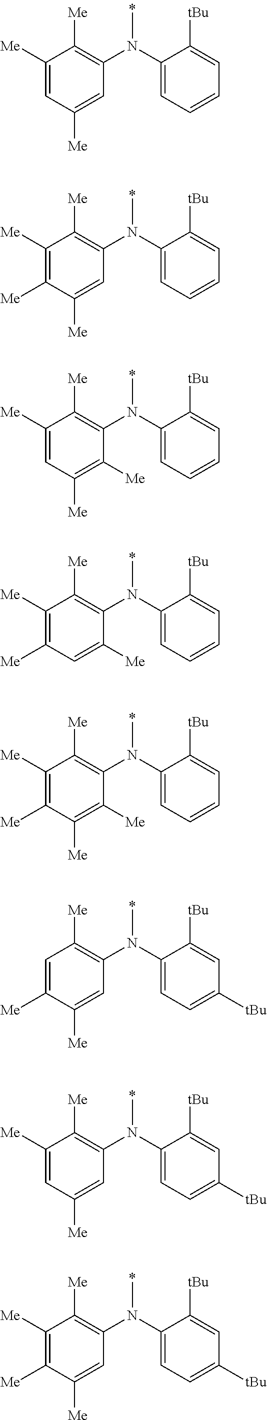

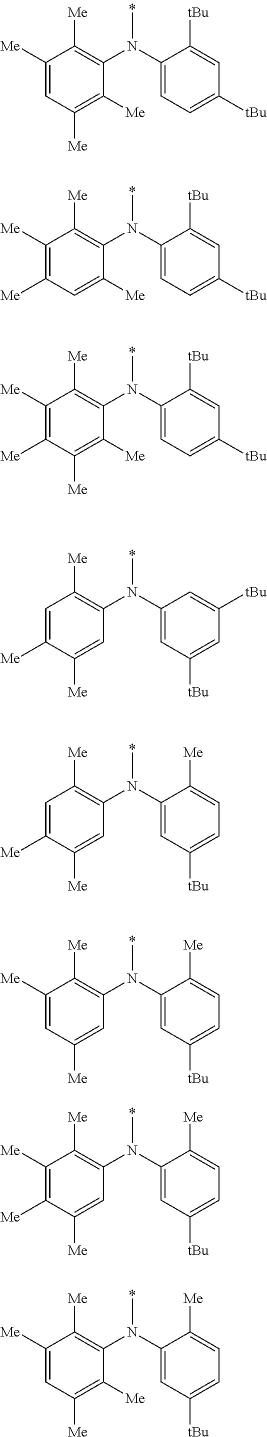

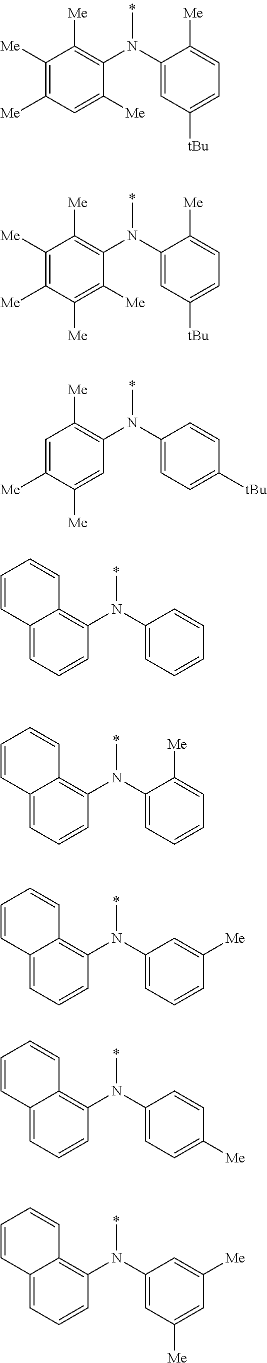

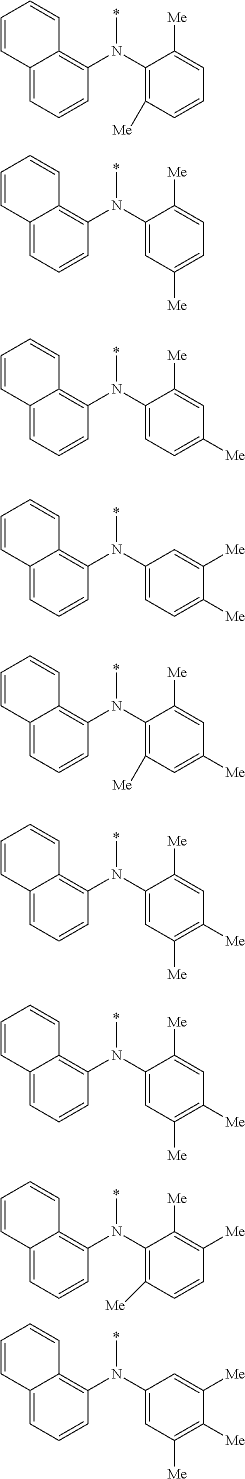

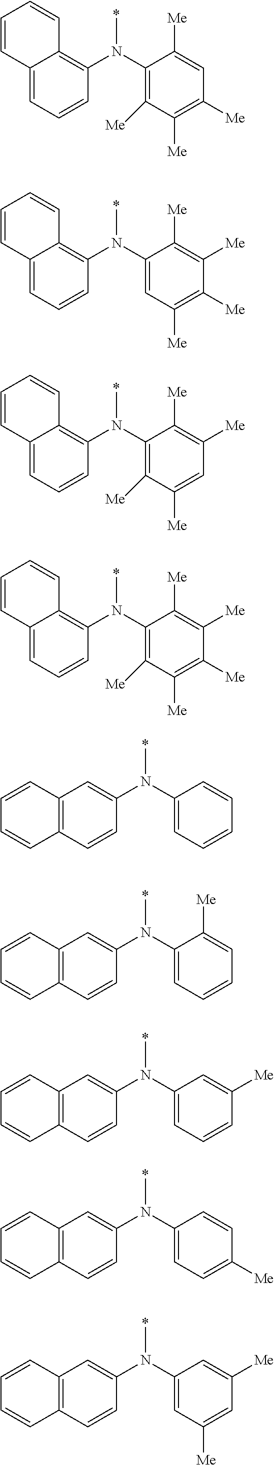

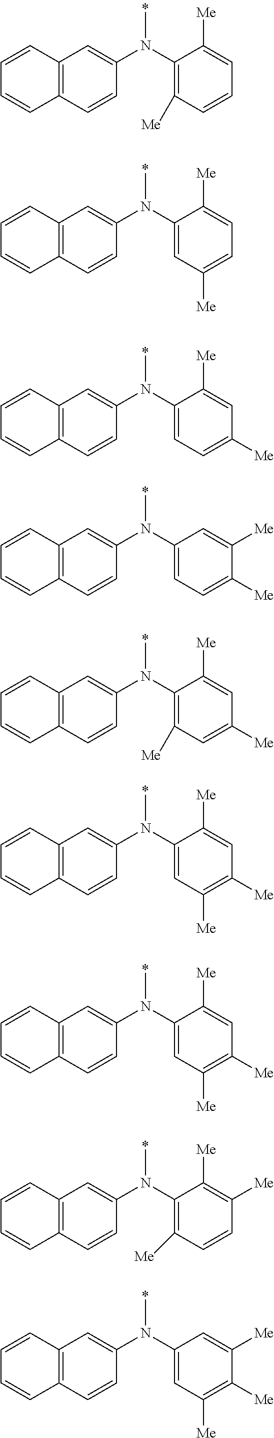

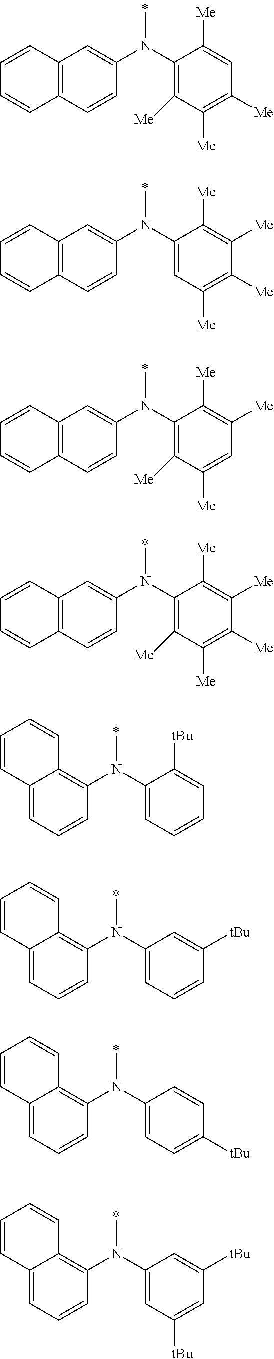

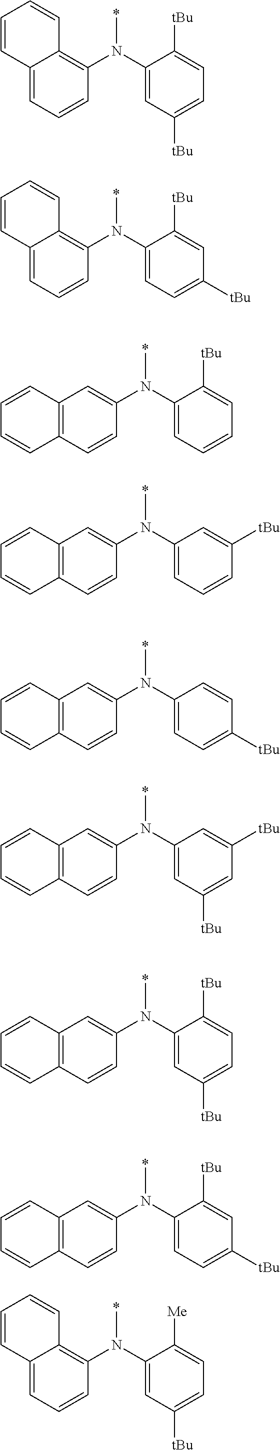

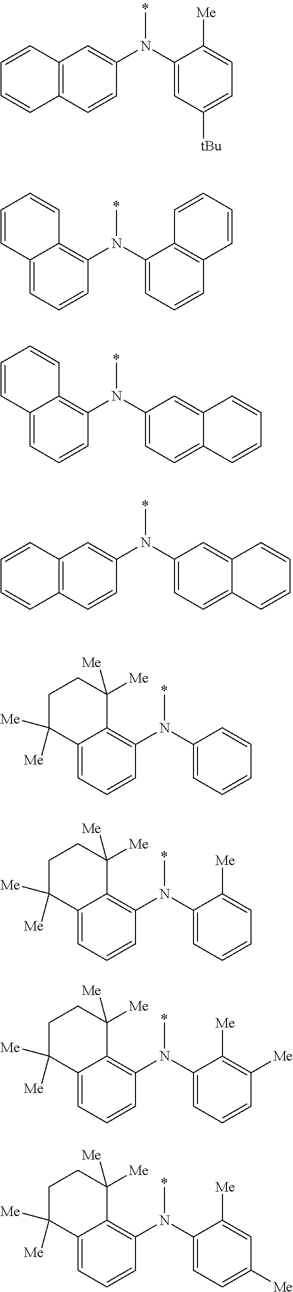

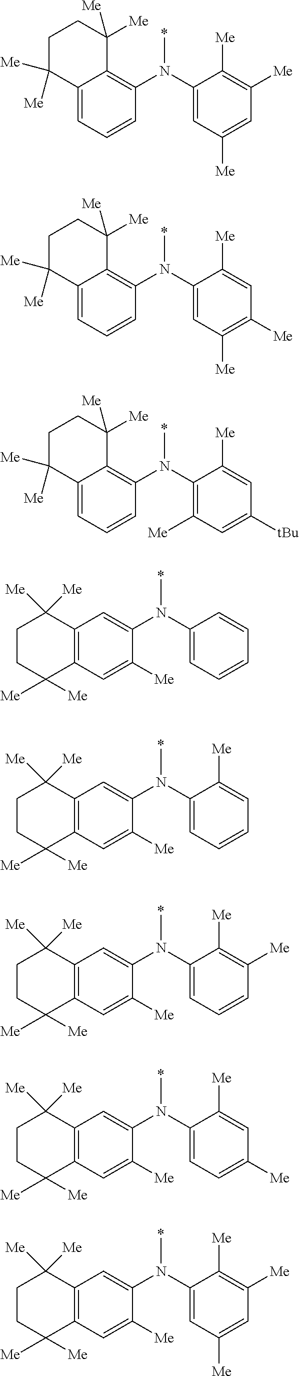

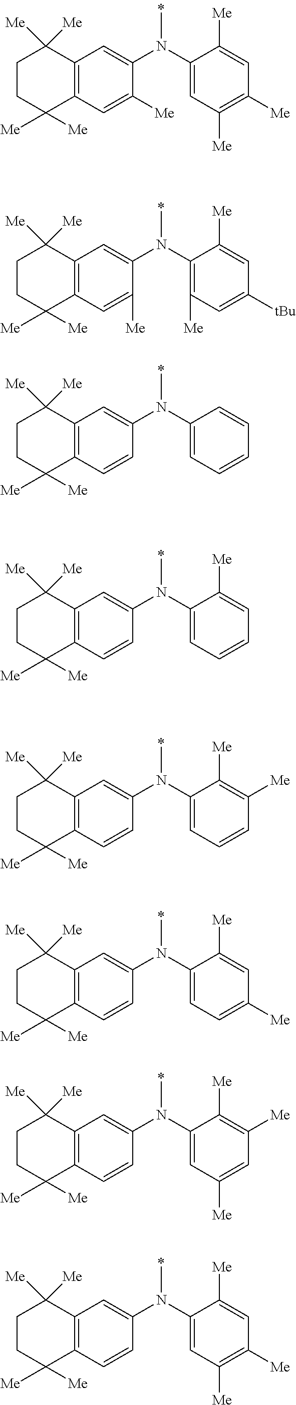

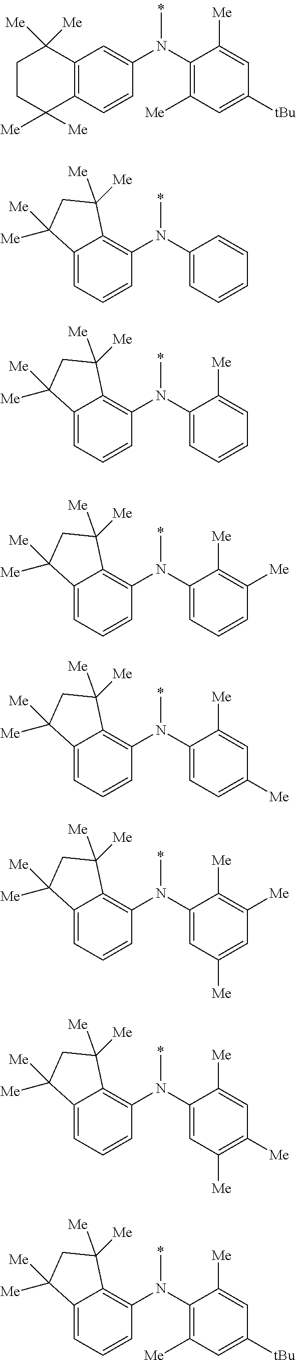

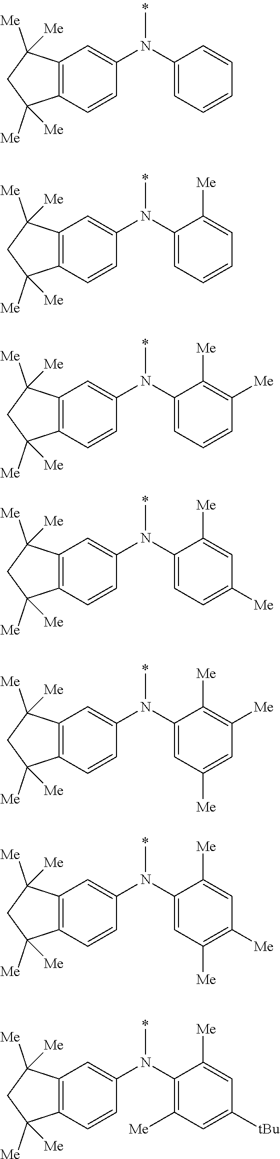

The polycyclic aromatic compound having a structure consisting of one or two or more of the structural units represented by Formula (1) is preferably a structure containing at least one tertiary-alkyl (t-butyl or t-amyl or the like) represented by Formula (tR) described above, neopentyl or adamanthyl, and preferably contains a tertiary-alkyl (t-butyl or t-amyl or the like) represented by Formula (tR) The emission quantum yield (PLQY) is improved because the intermolecular distance is increased by such a bulky substituent. A diarylamino is also preferred as the substituent. Further, a diarylamino substituted with a group of formula (tR), a carbazolyl substituted with a group of formula (tR) (preferably N-carbazolyl) or a benzocarbazolyl substituted with a group of formula (tR) (preferably N-benzocarbazolyl) are also preferred. Substituted forms of groups of formula (tR) to diarylamino, carbazolyl and benzocarbazolyl include examples in which some or all hydrogens of an aryl ring or a benzene ring in these groups are substituted with groups of Formula (tR).

In Formula (1), a substituent to the aryl ring or heteroaryl ring in A ring, B ring, and C ring may be a substituent represented by the following formula (A20).

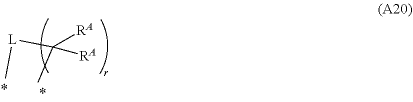

A substituent represented by formula (A20) is bonded to two atoms adjacent to each other on a ring of an aryl ring or a heteroaryl ring with two *, respectively, in Formula (A20),

L is >N—R, >O, >Si(—R)₂ or >S, wherein R of >N—R is an optionally substituted aryl, an optionally substituted heteroaryl, an optionally substituted alkyl or an optionally substituted cycloalkyl, wherein R of >Si(—R)₂ is hydrogen, an optionally substituted aryl, an optionally substituted alkyl or an optionally substituted cycloalkyl, and may be bonded to each other by a linking group, and wherein at least one of Rs in >N—R and said >Si(—R)₂ may be bonded to at least one selected from the group consisting of A ring, B ring, R^{XC} and R^{A} by a linking group or a single bond, r is an integer between 1 and 4, each R^{A} is independently hydrogen, an optionally substituted alkyl or an optionally substituted cycloalkyl, and any R^{A} may be bonded to any other R^{A} by a linking group or a single bond.

Examples of the above substituent include a substituent represented by Formula (A20-a-1).

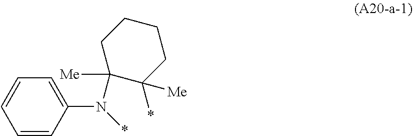 [SMILES: *N(c1ccccc1)C1(C)CCCCC1(*)C]

In Formula (1), the substituent of the aryl ring or the heteroaryl ring in A ring, B ring, and C ring is preferably a substituent other than the substituent represented by (A20). In particular, in a compound in which C ring or B ring is a ring represented by Formula (Het-1), the substituent possessed by C ring and B ring is preferably a substituent other than the substituent represented by Formula (A20), Among them, when one of C ring and B ring is at-butyl substituted oxazole ring or a t-butyl substituted thiazole ring, the substituent possessed by the other of C ring and B ring is preferably a substituent other than a substituent represented by Formula (A20-a-1).

In Formula (1), Y¹ is independently B, P, P═O. P═S, Al, Ga, As, Si—R, or Ge—R, and R in Si—R and Ge—R is an aryl having 6 to 12 carbons, an alkyl having 1 to 6 carbons, or a cycloalkyl having 3 to 14 carbons. R in Si—R and Ge—R in Y¹ of Formula (1) is an aryl, an alkyl or a cycloalkyl, examples of which include the groups described above. Particularly preferred are an aryl haying 6 to 10 carbons (e.g., phenyl, naphthyl, etc.), an alkyl haying 1 to 5 carbons (e.g., methyl, ethyl, etc.) or a cycloalkyl having 5 to 10 carbons (preferably cyclohexyl or adamantyl).

The above description of Y¹ in Formula (1) also applies to Y¹ in the following Formulas (1-a), (1-b) (1-c), (1-d), (1-e), (1-f), (1-g), (1-h), (1-i), (1-j), (1-l), (1-m), and (1-o),

X¹ and X² in Formula (1) are each independently >O, >N—R, >Si(—R)₂, >C(—R)₂, >S, or >Se. For X¹ and X² in Formula (1), it is preferred that at least one of them is >N—R, it is more preferred that both of them are >N—R, one of them is >N—R and the other is >C(—R)₂, or one of them is >N—R and the other is >O, and it is further preferred that both of them are >N—R.

R in >N—R as X¹ or X² is hydrogen, an optionally substituted aryl (except amino as a substituent), an optionally substituted heteroaryl, an optionally substituted alkyl or an optionally substituted cycloalkyl. Rs in >Si(—R)₂ as X¹ and X² are each independently hydrogen, an optionally substituted aryl, an optionally substituted heteroaryl, an optionally substituted alkyl or an optionally substituted cycloalkyl.

R's in >Si(—R)₂ and >C(—R)₂ as X¹ or X², are each independently hydrogen, an optionally substituted aryl, an optionally substituted heteroaryl, an optionally substituted alkyl, or an optionally substituted cycloalkyl, preferably the two R's are the same, and the two R's may be bonded to form a ring.

For the aryl, heteroaryl, alkyl, and cycloalkyl in R in >N—R and R's in >Si(—R)₂ and >C(—R)₂ as X¹ or X², the explanations of those as the first substituents described above can be referred to.

R in >N—R as X¹ or X², is preferably an optionally substituted aryl, an optionally substituted heteroaryl, or an optionally substituted cycloalkyl, more preferably an optionally substituted aryl or an optionally substituted heteroaryl. Examples of the cycloalkyl include the examples described below. As the aryl, phenyl, biphenylyl (particularly 2-biphenylyl), and terphenylyl (particularly terphenyl-2′-yl) are preferred. For the heteroaryl, benzothienyl (2-benzothienyl, 6-benzothienyl, etc.), benzofuranyl (2-benzofuranyl, 3-benzofuranyl, 5-benzofuranyl, etc.), dibenzofuranyl (4-dibenzofuranyl, etc.), dimethylxanthenyl (2-dimethylxanthenyl, etc.), dibenzodioxynyl, and the like are preferred. As the substituent, a tertiary-alkyl represented by the above formula (tR) (particularly, t-butyl), or a cycloalkyl (particularly, adamanthyl) is preferred. The number of substituents in one aryl or heteroaryl is preferably 0 to 2, more preferably 1 or 2, and still more preferably 1. It is also preferred if an aryl ring in an aryl is fused with a cycloalkane which may he substituted as described below As a specific cycloalkane, those described below can be referred to.

Particularly preferred examples of R in >N—R as X¹ or X² include an optionally substituted 2-biphenylyl, an optionally substituted terphenyl-2′-yl, and an optionally substituted aryl fused with a cycloalkane. As the optionally substituted 2-biphenylyl, a 2-biphenylyl substituted with 1 to 3 t-butyl is particularly preferred. As the optionally substituted terphenyl-2′-yl, unsubstituted [1,1′:3′,1″-terphenyl]-2′-yl is particularly preferred. As the aryl fused with a cycloalkane, the following groups are particularly preferred.

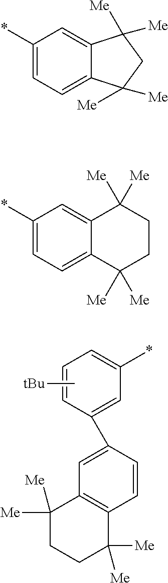

(Me represents methyl, tBu represents t-butyl, and * represents the bonding position.)

When both X¹ and X² are >N—R, it is further preferred that only one R is an optionally substituted 2-biphenylyl, or only one R or both R's is an optionally substituted terphenyl-2′-yl. As the terphenyl-2′-yl, [1,1′:3′,1″-terphenyl]-2′-yl is preferred. When one R is an optionally substituted 2-biphenylyl or an optionally substituted terphenyl-2′-yl, the other R is preferably an optionally substituted phenyl. Examples of such a compound include Compound (1-21), Compounds (1-22), or Compound (1-22-2) as follows.

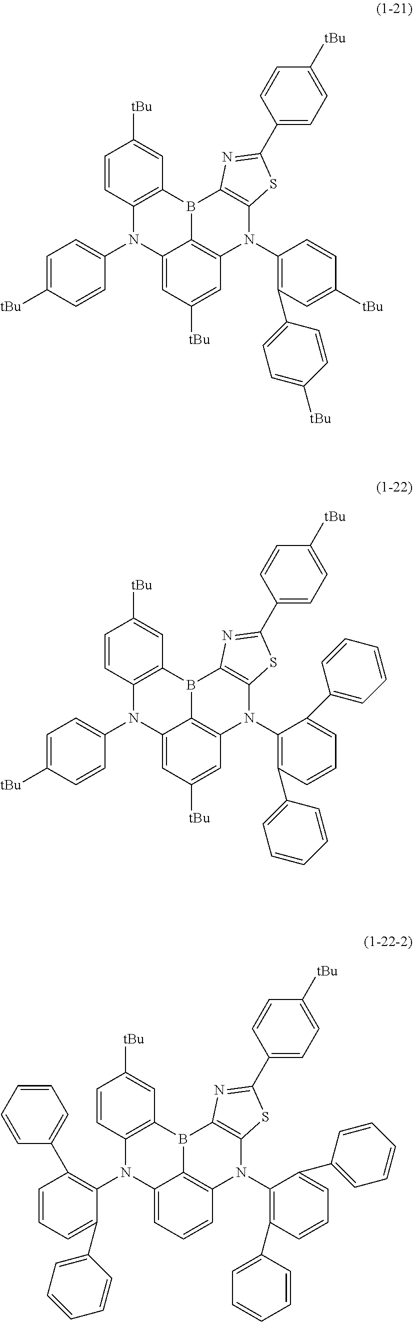 [SMILES: CC(C)(C)c1ccc(-c2nc3c(s2)N(c2ccc(C(C)(C)C)cc2-c2ccc(C(C)(C)C)cc2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2c(-c4ccccc4)cccc2-c2ccccc2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2c(-c4ccccc4)cccc2-c2ccccc2)c2cccc4c2B3c2cc(C(C)(C)C)ccc2N4c2c(-c3ccccc3)cccc2-c2ccccc2)cc1]

When both X¹ and X² are >N—R, it is also preferred that only one R is an aryl fused with a cycloalkane (which may be substituted). it is also preferred that one R is an optionally substituted 2-biphenylyl and the other R is an optionally substituted aryl fused with cycloalkanes.

At least one R in >N—R, >Si(—R)₂ and >C(—R)₂ as X¹ or X² may be bonded to A and/or B rings or A and/or C rings by a linking group or single bond. That is, at least one R in a >N—R, >Si(—R) ₂ and >C(—R₂ as X¹ may he bonded to A ring and/or B ring by a linking group or a single bond, and at least one R in a >N—R, >Si(—R) 2 and >C(—R₂ as X¹ may be bonded to A ring and/or C ring by a linking group or a single bond. As the linking group, —O—, —S—, or —C(—R)₂— is preferred. R in “—C(—R)₂—” is hydrogen, an alkyl or cycloalky. This definition can be expressed by a compound represented by the following formula (1-3-1), which has a ring structure in which X¹ or X² is incorporated into a fused ring B′ and a fused ring C′. That is, for example, a compound having B′-ring (or C′-ring) formed by condensation of another ring with B-ring (or C-ring), which is a benzene-ring, such that X¹ (or X²) is incorporated. The fused ring B′ (or fused ring C′) formed is, for example, a carbazole ring, a phenoxazine ring, a phenothiazine ring or an acridine ring.

The above definition can also be expressed by a compound represented by Formula (1-3-2) or Formula (1-3-3) below, which has a ring structure in which X¹ and/or X² are incorporated into a fused ring A′. That is, for example, a compound having A′ ring formed by condensation of another ring with A ring, which is a benzene ring, such that X¹ (and/or X²) is incorporated. The fused ring A′ formed is, for example, a carbazole ring, a phenoxazine ring, a phenothiazine ring, or an acridine ring.

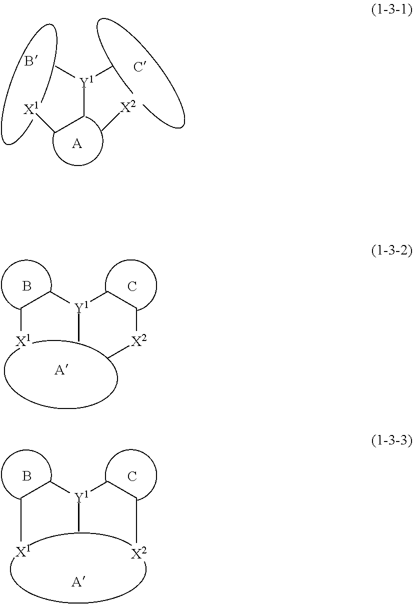

As an example, an embodiment in which R in >N—R is an optionally substituted cycloalkyl and is bonded to A ring, B ring, or C ring via a single bond is also preferred. As the cycloalkyl, an optionally substituted cyclopentyl or an optionally substituted cyclohexyl is preferred.

Particularly preferred examples thereof include a structure represented by Formula (A11).

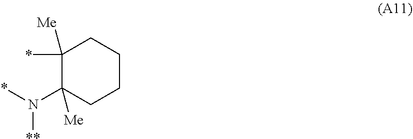

In Formula (A11), Me is methyl and the group represented by Formula (A11) is bonded to one of the two rings to which X¹ or X² is bonded at the two * positions and bonded to the other ring at ** position.

Examples of such structures include structures of compounds represented by any of Formulas (1-620) to (1-646) described below

When the compound of the present invention having >N—R, with R in the above preferable ranges, as a X¹ or a X² is used for manufacturing an element as a light-emitting material, the light-emitting efficiency and the element lifetime can be further improved.

R in >Si(—R)₂ as X¹ or X¹ of Formula (1) is hydrogen, an optionally substituted aryl, an optionally substituted heteroaryl, an optionally substituted alkyl or an optionally substituted cycloalkyl. Here, as a substituent when substituted, the above-mentioned second substituent can be exemplified. Examples of the aryl, heteroaryl, alkyl or cycloalkyl include the groups described above as the first substituent. Particularly preferred are an aryl having 6 to 10 carbons (e.g., phenyl, naphthyl, etc.), a heteroaryl having 2 to 15 carbons (e.g., carbazolyl, etc.), an alkyl having 1 to 5 carbons (e.g., methyl, ethyl, etc.) or a cycloalkyl having 5 to 10 carbons (preferably cyclohexyl or adamantyl).

R in >C(—R)₂ as X¹ or X² of Formula (1) is hydrogen, an optionally substituted aryl, an optionally substituted heteroaryl, an optionally substituted alkyl or an optionally substituted cycloalkyl. The substituent when substituted can include the above-mentioned second substituent. Examples of the aryl, heteroaryl, alkyl or cycloalkyl include the groups described above as the first substituent. Particularly preferred are an aryl having 6 to 10 carbons (e.g., phenyl, naphthyl, etc.), a heteroaryl haying 2 to 15 carbons (e.g,, carbazolyl, etc.), an alkyl having Ito 5 carbons (e.g., methyl, ethyl, etc.) or a cycloalkyl having 5 to 10 carbons (preferably cyclohexyl or adamnanty),

When X¹, X² is bonded to A and/or B ring or A and/or C ring in Formula (1), the linking group may be, for example, —O—, —S—, or —C(—R)₂—, in Which R in “—C(—R)₂—” is hydrogen, an alkyl, or a cycloalkyl. Examples of the alkyl or cycloalkyl include the groups described above as the first substituent, respectively, an alkyl having 1 to 5 carbons (e.g., methyl, ethyl, etc.) or a cycloalkyl having 5 to 10 carbons (preferably cyclohexyl or adamantyl) are particularly preferred.

The polycyclic aromatic compound according to the present invention can be used as a material for an organic device. Examples of the organic element include an organic electroluminescent element, an organic field effect transistor, and an organic thin film solar cell. In particular, in an organic electroluminescent element, a compound in which Y¹ is B and X¹ and X² are each independently >N—R or >O in any of the above formulas is preferable, a compound in which Y¹ is B and one of X and X² is >N—R and the other is >N—R or >O is more preferable, a compound in which Y¹ is B and X¹ and X² are each independently >N—R is most preferable to be used as a dopant material of the light-emitting layer; a compound in which Y¹ is B and one of and X² is >O and the other is >N—R or >O is preferable, a compound in which Y¹ is B and X¹ and X² are >O is more preferable to be used as a host material of the light-emitting layer; a compound in which Y¹ is B and and X² are >O or a compound in which Y¹ is P═O and X¹ and X² are >O is preferable to be used as an electron-transporting material.

The polycyclic aromatic compound of the present invention is a polycyclic aromatic compound having a structure consisting of one or two or more of structural units represented by Formula (1) Examples of the polycyclic aromatic compound haying a structure consisting of one of the above structural units include a polycyclic aromatic compound represented by the formula described above as a structural unit represented by Formula (1). Examples of the polycyclic aromatic compound having a structure consisting of two or more of the structural units represented by Formula (1) include a compound corresponding to a multimer of a compound represented by the formula described above as a structural unit represented by Formula (I). The multimer is preferably a dimer-hexamer, more preferably a dimer-trimer, and particularly preferably a dimer. The multimer may be an embodiment having a plurality of unit structures described above in one compound and may be an embodiment in which an arbitrary ring (A ring, B ring or C ring) contained in the above structural unit is shared by a plurality of unit structures and may be an embodiment in which any ring (A ring, B ring or C ring) contained in the above unit structure is bonded so as to be fused together. In addition, the above unit structure may be an embodiment in which a plurality of the above unit structures are bonded by a single bond, or a linking group such as an alkylene having 1 to 3 carbons, a phenylene, naphthylene, or the like. Among them, an embodiment in which a ring is shared is preferred.

At least one selected from the group consisting of aryl rings and heteroaryl rings in a polycyclic aromatic compound having a structure consisting of one or two or more of the structural units represented by Formula (1) may be fused with at least one cycloalkane. The same applies to the polycyclic aromatic compounds represented by Formulas (1-a), (1-b), (1-c), (1-d), (1-e), (1-f), (1-g), (1-h), (1-i), (1-j), (1-k), (1-l), (1-m) or (1-o) as follows, and the following description applies to the polycyclic aromatic compounds represented by any of these formulas.

As the cycloalkane, any cycloalkane having 3 to 24 carbons may be used. At least one hydrogen in the cycloalkane may be replaced with an aryl having 6 to 30 carbons, a heteroaryl having 2 to 30 carbons, an alkyl having l to 24 carbons or a cycloalkyl having 3 to 24 carbons, and at least one —CH₂— in the cycloalkane may be replaced with —O—.

When at least one selected from the group consisting of aryl rings and heteroaryl rings in a structure consisting of one or two or more of the structural units represented by formula (1) is fused with at least one cycloalkane, the at least one cycloalkane is preferably a cycloalkane having 3 to 20 carbons, wherein at least one hydrogen in the cycloalkane may be replaced with an aryl having 6 to 16 carbons, a heteroaryl having 2 to 22 carbons, an alkyl having I to 12 carbons or a cycloalkyl having 3 to 16 carbons.

“Cycloalkanes” include cycloalkanes having 3 to 24 carbons, cycloalkanes having 3 to 20 carbons, cycloalkanes having 3 to 16 carbons, cycloalkanes having 3 to 14 carbons, cycloalkanes having 5 to 10 carbons, cycloalkanes having 5 to 8 carbons, cycloalkanes having 5 to 6 carbons, and cycloalkanes having 5 carbons.

Specific examples of cycloalkanes include cyclopropane, cyclobutane, cyclopentane, cyclohexane, cycloheptane, cyclooctane, cyclononane, cyclodecane, norbonrane (bicyclo[2.2.1]heptane), bicyclo[1.1.0]butane, bicyclo[1.1.1]pentane, bicyclo[2.1.0]pentane, bicyclo[2.1.1]hexane, bicyclo[3.1.0]hexane, bicyclo[2.2.2]octane, adamantane, diamantine, decahydronaphthalene and decahydroazulene, and a C1-5 alkyl (particularly methyl) substituent thereof, a halogen (especially fluorine) substituent thereof, and a deuterium substituent thereof.

Among these, a structure in which at least one hydrogen is substituted at a carbon at the α-position of a cycloalkane (in a cycloalkyl which is fused to an aryl ring or a heteroaryl ring, a carbon at the position adjacent to a carbon at the fused site) is preferred, and a structure in which two hydrogens at a carbon at an α-position are substituted is more preferred, and a structure in which a total of 4 hydrogens at a carbon at two a-positions are substituted, as shown in the following structural formulas, is further preferred. Examples of the substituent include an alkyl (particularly methyl) having 1 to 5 carbons, a halogen (particularly fluorine), and deuterium. In particular, it is preferable to have a structure in which a partial structure represented by the following formula (B) is bonded to carbon atoms adjacent to each other on an aryl ring or a heteroaryl ring.

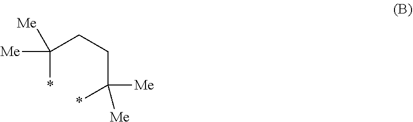 [SMILES: *C(C)(C)CCC(*)(C)C]

In Formula(B), Me represents methyl and * represents a bonding position. Example of such a structure include the structures of the compounds represented. by any of Formula(1-19), Formula (1-20), Formula (1-50), Formula (1-51). Formula (1-81), Formula (1-82), Formula (1-111), Formula (1-112), Formula (1-141), Formula (1-142), Formula (1-201), Formula. (1-202), Formula (1-231), Formula (1-232), Formula (1-261), Formula (1-262), Formula (1-316), Formula (1-317), Formula (1-361), Formula (1-362), Formula (1-391), Formula (1-392), Formula (1-421), Formula (1-422), Formula (1-451), Formula (1-452), Formula (1-481), Formula (1-482), Formula (1-503), Formula (1-504), Formula (1-523), Formula (1-524), Formula (1-543), Formula (1-544), Formula (1-563), Formula (1-564), Formula (1-573), Formula (1-574). Formula (1-623) to Formula (1-625). Formula (1-629) to Formula (1-631), Formula (1-638) to Formula (1-640), and Formula (1-644) to Formula (1-646), which are described below.

The number of cycloalkanes to be fused to one aryl ring or heteroaryl ring is preferably 1 to 3, more preferably 1 or 2, and still more preferably 1. Examples of the structures in which one or more cycloalkanes are fused to one benzene ring (phenyl) are shown below * represents a bonding position, and the position may be any of the carbons constituting the benzene ring and not constituting the cycloalkane. Cycloalkanes fused may be further fused to each other as shown in Formula (Cy-1-4) and Formula. (Cy-2-4). The same applies, when the ring (group) to be fused is an aryl ring other than the benzene ring (phenyl) or a heteroaryl ring, and when the cycloalkane to be fused is a cycloalkane other than cyclopentane or cyclohexane.

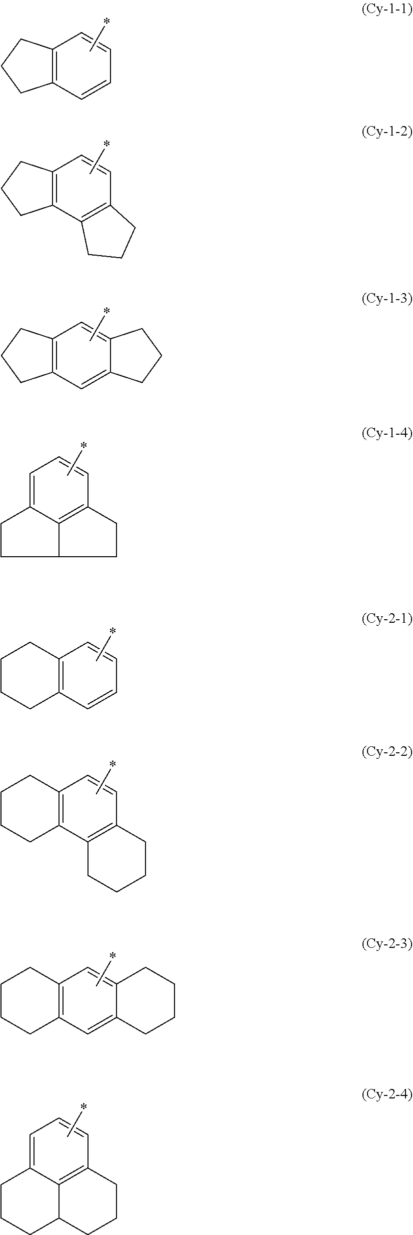

At least one —CH₂— in the cycloalkane may be replaced with —O—. Examples of the structures in which one or more —CH₂—(s) in a cycloalkane fused to a benzene ring (phenyl) are replaced with —O— are shown below. The same applies, when the ring (group) to be fused is an aryl ring other than the benzene ring (phenyl) or a heteroaryl ring, and when the cycloalkane to be fused is a cycloalkane other than cyclopentane or cyclohexane.

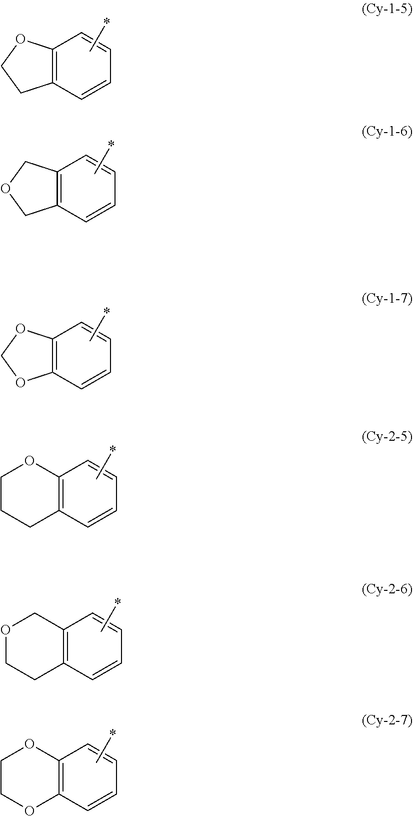

At least one hydrogen in the cycloalkane may be substituted. The examples of the substituent include an aryl, a heteroaryl, a diarylamino, a diheteroarylamino, an arylheteroarylamino, a diarylboryl (two aryls may be bonded via single bond or a linking group), an alkyl, a cycloalkyl, an alkoxy, an aryloxy, a substituted silyl, deuterium, cyano or a halogen. For the details of the substituent, the description of the first substituent described above can be referred to. Among these substituents, an alkyl (e.g., an alkyl having 1 to 6 carbons), a cycloalkyl (e.g., a cycloalkyl having 3 to 14 carbons), a halogen (e.g., fluorine), and deuterium are preferred. In addition, a cycloalkyl as a substituent may be in a form forming a spiro structure, examples of which are shown below.

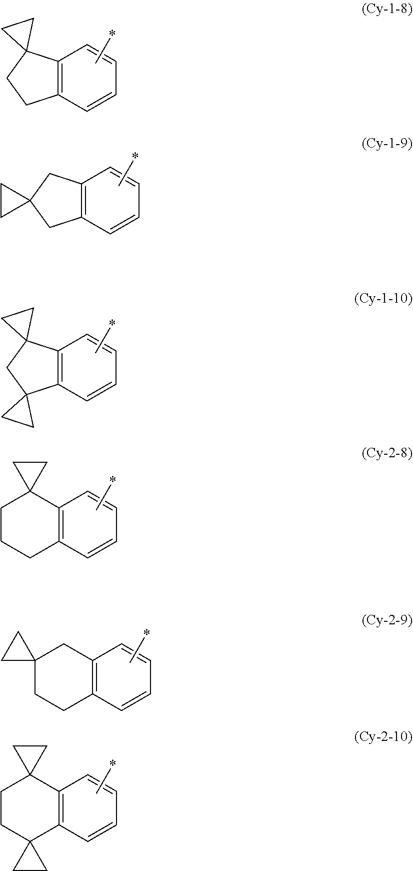

The first embodiment of cycloalkane condensation is a structure in which the aryl or heteroaryl ring in each of A, B and C rings in a polycyclic aromatic compound having one or two or more of the structural units represented by Formula (1) (the aryl or heteroaryl ring in each of a, b, c, b11, c11, b12 and c12 ring in Formula (1-a), (1-b), (1-c), (1-d), (1-e), (1-f) (1-g), (1-h), (1-i), (1-j), (1-k), (1-l), (1-m) or (1-o), or an aryl and heteroaryl rings in a fused ring formed is fused with cycloalkane.

Another embodiment of cycloalkane condensation is such a structure that a polycyclic aromatic compounds haying a structure consisting of one or two or more of the structural units represented by Formula (1), or a polycyclic aromatic compound represented by Formula (1-a), (1-b), (1-c), (1-d), (1-e), (1-f), (1-g), (1-h), (1-i), (1-j), (1-k), (1-l), (1-m) or (1-o) has >N—R, in which R is an aryl fused with a cycloalkane, a diaiylamino fused with a cycloalkane (a cycloalkane is fused to this aryl moiety), a carbazolyl fused with a cycloalkane cycloalkane is fused to this benzene moiety), or a benzocarbazolyl fused with a cycloalkane (a cycloalkane is fused to this benzene ring moiety). As for “diarylamino”, the group described as the above “first substituent” can be exemplified.

Further specific examples include a structure in which R^{Z}, at para position with respect to Y¹ in A ring in a polycyclic aromatic compound represented by Formula (1-a), (1-b), (1-c), (1-d), (1-e), (1-f), (1-g), (1-h), (1-i), (1-j), (1-k), (1-l), (1-m) or (1-o), is a diarylamino fused with a cycloalkane (a cycloalkane is fused to this aryl moiety), a carbazolyl fused with a cycloalkane (a cycloalkane is fused to this benzene moiety).

By introducing a cycloalkane structure into the polycyclic aromatic compound of the present invention, a decrease in melting point and sublimation temperature can be expected. This means that, in sublimation purification, which is almost essential as a method for purifying a material for an organic device such as an organic EL element for which high purity of materials is required, thermal decomposition of a material or the like can be avoided because it can be purified at a relatively low temperature. This also applies to the vacuum deposition process, which is an effective means for manufacturing an organic device such as an organic EL element, and since the process can be performed at a relatively low temperature, thermal decomposition of the material can be avoided, and as a result, a high-performance organic device can be obtained. Further, since solubility in an organic solvent is improved by introduction of a cycloalkane structure, it is also possible to apply it to fabrication of an element utilizing a coating process. However, the present invention is not particularly limited to these principles.

All or a part of hydrogens in a structure consisting of one or two or more of the structural units represented by Formula (1) may be deuterium, cyano, or a halogen. The same applies to the polycyclic aromatic compounds represented by Formula (1-a), (1-b), (1-c), (1-d), (1-e), (1-f), (1-g), (1-h), (1-i), (1-j), (1-k), (1-l), (1-m) or (1-o) described below, and thus the following explanation also applies to the polycyclic aromatic compounds represented by Formula (1-a), (1-b), (1-c), (1-d), (1-e), (1-f), (1-g), (1-h), (1-i), (1-j), (1-k), (1-l), (1-m) or (1-o).

For example, in a structure consisting of one or two or more of the structural units represented by Formula (1), A ring, B ring, C ring (A-C ring is an aryl ring or a heteroaryl a substituent to A-C ring, R (=an alkyl, a cycloalkyl, an aryl or a heteroaryl) when Y¹ is Si—R or Ge—R, and R (=an alkyl, a cycloalkyl, an aryl or a heteroaryl) when X¹ and X² are >N—R, >C(—R)₂, or >Si(—R)₂ may be replaced with deuterium, cyano or a halogen. Among them, an embodiment in which all or some hydrogens in the aryl or heteroaryl are deuterium, cyano, or a halogen can be exemplified. The halogen is fluorine, chlorine, bromine or iodine, preferably fluorine, chlorine, or bromine, more preferably fluorine or chlorine, and further preferably fluorine. In addition, from the viewpoint of durability, it is also preferable that all or a part of hydrogens in a structure consisting of one or two or more of the structural units represented by Formula (1) is deuterated.

Preferable examples of the polycyclic aromatic compound having a structure consisting of one or two or more structural units represented by Formula (1) include polycyclic aromatic compounds represented by any of Formula (1-a), (1-b), (1-c), (1-d), (1-e), (1-f), (1-g), (1-h), (1-i), (1-j), (1-k), (1-l), (1-m) and (1-o) below For the substituent, the ring structures and preferable ranges of Formula (1-a), (1-b), (1-c), (1-d), (1-e), (1-f), (1-g), (1-h), (1-i), (1-j), (1-k), (1-l), (1-m) and (1-o), the corresponding explanation in Formula (1) can be referred to.

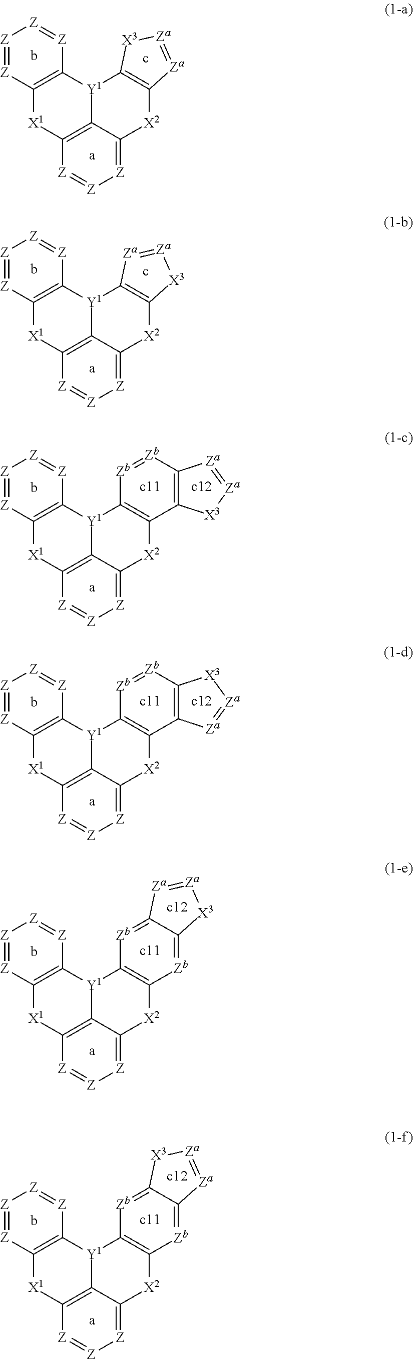

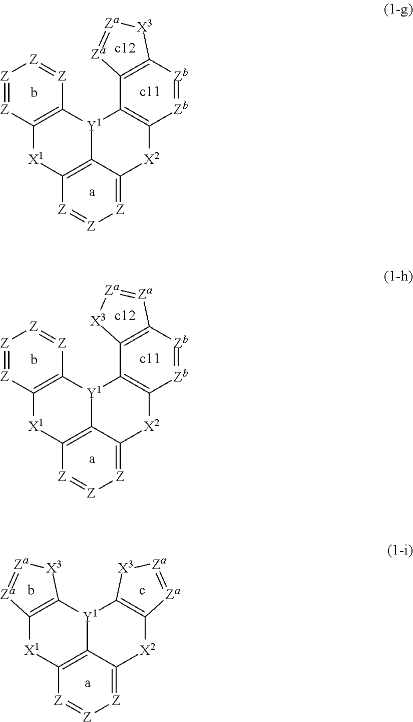

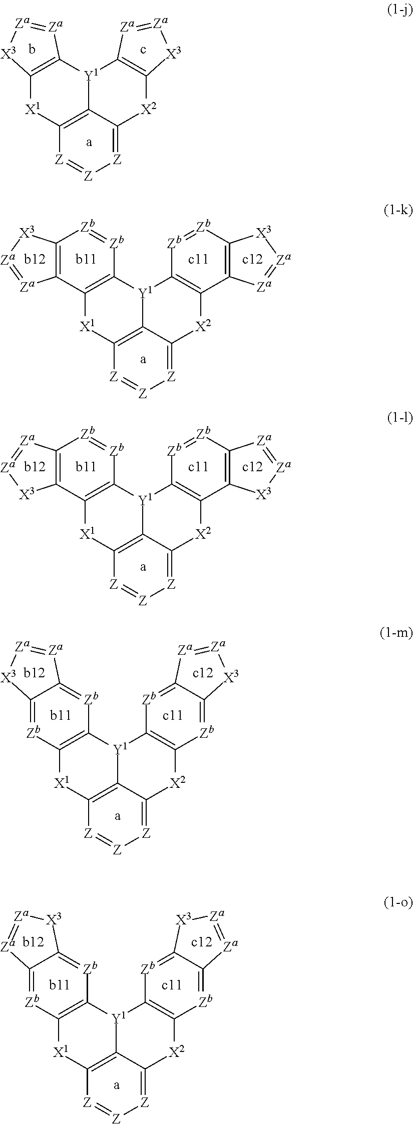

In Formulas (1-a), (1-b), (1-c), (1-d), (1-e), (1-f), (1-g), (1-h), (1-i), (1-j), (1-k), (1-l), (1-m) or (1-o), Y¹, X¹X², X³, Z^{a} and Z^{b} are synonymous with Y¹, X¹, X², X³, Z^{a} and Z^{b} in Formula (1), respectively.

In Formulas (1-a), (1-b), (1-c), (1-d), (1-e), (1-f), (1-g), (1-h), (1-i), (1-j), (1-k), (1-l), (1-m) or (1-o), each Z is independently N or C—R^{Z}, and each R^{Z} is independently hydrogen, an aryl, a heteroaryl, a diarylamino, a diheteroarylamino, an arylheteroarylamino,a diarylboryl (the two aryls may be bonded via single bond or a linking groups), an alkyl, a cycloalkyl, an alkoxy, an aryloxy or a substituted silyl, in which at least one hydrogen may be replaced with an aryl, a heteroaryl, an alkyl, an alkyl or a cycloalkyl. For details of the substituents listed here, the description of the first substituent and the second substituent described above can be referred to.

The adjacent two R^{Z}'s may be bonded to each other to form an aryl ring or a heteroryl ring, wherein the aryl ring and heteroaryl ring formed may be substituted with an aryl, a heteroarylamino, a diheteroarylamino, an arylheteroarylamino, a diarylboryl (two aryls may be bonded via single bond or a linking group), an alkyl, a cycloalkyl, an alkoxy, an aryloxy, or a substituted silyl, and at least one hydrogen in the substituent may be replaced with an aryl, a heteroaryl, an alkyl, or a cycloalkyl. For details of the substituents listed here, the description of the first substituent and the second substituent described above can he referred to.

In Formulas (1-a), (1-b), (1-c), (1-d), (1-e), (1-f), (1-g), (1-h), (1-i), (1-j), (1-k), (1-l) (1-m) or (1-o), Z═Z may independently be >O, >N—R, >C(—R)₂, >Si(—R)², >S or >Se. The above Z═Z may more preferably be >O, >N—R, >C(—R)₂ or >S. Here, R in >N—R and R's in >C(—R)₂ and >Si(—R)₂ are each independently hydrogen, a substituted or unsubstituted aryl, a substituted. or unsubstituted heteroaryl, a substituted or unsubstituted alkyl, or a substituted or unsubstituted cycloalkyl, and the two R's in >C(—R)₂ and >Si(—R)₂ may be bonded to each other to form a ring. For details of the substituents listed here, the description of the first substituent described above can be referred to.

As rings obtained by replacing “Z═Z” with >O, >N—R, >C (—R)₂, >Si(—R)₂, >S, or >Se in a ring, b ring, etc., pyrrole ring, furan ring, thiophene ring, and the like can be exemplified. in addition, if the remaining Z's which are C—R^{Z} are contiguous and bonded to each other to form a benzene ring, an indole ring, a benzofuran ring, or a benzothiophene ring may be formed. The ring formed may have a substituent.

The description “R in >N—R, >C(—R)₂ and >Si(—R)₂ as X¹ or X² may be bonded to A and/or B rings, or A and/or C rings via a linking group or single linking group” in Formula (1), corresponds to the description “R in >N—R, >C(—R)₂ and >Si(—R)₂ may be bonded to one or two of R^{z} in Z which are C—R^{z} by —O—, —S—, —C(—R)₂— or a single bond” in Formulas (1-a), (1-b), (1-c), (1-d), (1-e), (1-f), (1-g), (1-h), (1-i), (1-j), (1-k), (1-l), (1-m) or (1-o). Specifically, R may be bonded to Z as C—R^{Z}, which is the spatially closest in each ring shown below
Formula (1-a): R in X¹ may be bonded to a and/or b ring, and R in X² may be bonded to a and/or c ring,
Formula (1-b): R in X¹ may be bonded to a and/or h ring, and R in X² may be bonded to a ring.
Formula (1-c): R in X¹ may be bonded to a and/or b ring, and R in X² may be bonded to a ring.
Formula (1-d): R in X¹ may be bonded to a and/or h ring, and R in X² may be bonded to a ring.
Formula (1-e): R in X¹ may be bonded to a and/or b ring, and R in X² may be bonded to a and/or c ring.
Formula (1-f): R in X¹ may be bonded to a and/or h ring, and R in X² may be bonded to a and/or c11 ring.
Formula (1-a): R in X¹ may be bonded to a and/or b ring, and R in X² may be bonded to a and/or c11 ring.
Formula. (R in X¹ may be bonded to a and/or h ring, and R in X² may be bonded to a and/or c11 ring,
Formula (1-i): R in X¹ may be bonded to a ring, R in X² may be bonded to a ring and/or c ring.
Formula (1-j): R in X¹ may be bonded to a ring, R in X² may be bonded to a ring.
Formula (1-k): R in X¹ may be bonded to a ring, R in X² may be bonded to a. ring.
Formula (1-l): R in X¹ may be bonded to a ring, R in X² may be bonded to a ring.
Formula (1-m): R in X¹ may be bonded to a and/or b11 ring, and R in X² may be bonded to a and/or c11 ring.
Formula (1-o): R in X¹ may be bonded to a and/or b11 ring, and R in X² may be bonded to a and/or c11 ring.

In each of Formulas (1-a), (1-b), (1-c), (1-d), (1-e), (1-f), (1-g), (1-h), (1-i), (1-j), (1-k), (1-l), (1-m) or (1-o), the number of rings containing Z as N (single rings) is 0 to 4, preferably 0 to 3, more preferably 0 to 2, and particularly preferably 0 to 1. In each of the above formulas, preferably every Z is C—R^{Z}.

In the ring including Z as N (single ring) in Formula(1-a), (1-b), (1-e), (1-d), (1-e), (1-f), (1-g), (1-h), (1-i), (1-j), (1-k), (1-l), (1-m) or (1-o), one or two of the plurality of Z are preferably N, and when two are N, it is preferable that the two N are not adjacent to each other. When a 6-membered ring is a ring containing Z as N, a pyridine ring, a pyrimidine ring, a pyridazine ring, or a 1,2,3-triazine ring is preferred, and a pyridine ring or a pyrimidine ring is more preferred. When a 5-membered ring is a ring containing Z as N, a thiazole ring and or oxazole ring is preferred.

Among Formulas (1-a), (1-b), (1-c), (1-d), (1-e), (1-f), (1-g), (1-h), (1-i), (1-j), (1-k), (1-l), (1-m) and (1-o), a compound represented by Formula(1-a) or (1-e) is preferable. In the compound represented by Formula (1-a) or Formula (1-e), a compound in which X³ and Z^{a} as N are not adjacent to each other is more preferred.

Further specific examples of the polycyclic aromatic compound represented by Formula (1) of the present invention include the following compounds. In the following structural formula, “Me” represents methyl, “tBu” represents t-butyl, “tAm” represents t-amyl, and “D” represents deuterium. The following structure is merely an example.

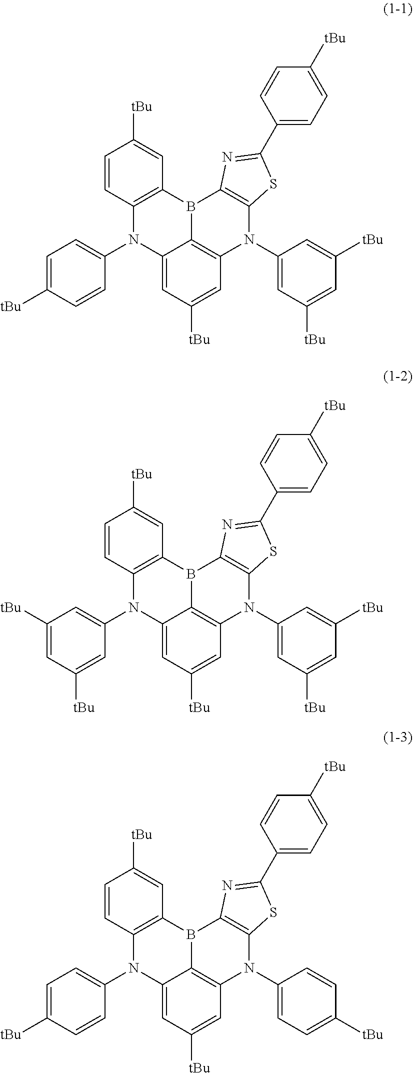 [SMILES: CC(C)(C)c1ccc(-c2nc3c(s2)N(c2cc(C(C)(C)C)cc(C(C)(C)C)c2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C(C)(C)C)cc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C(C)(C)C)cc4c2B3c2cc(C(C)(C)C)ccc2N4c2ccc(C(C)(C)C)cc2)cc1]

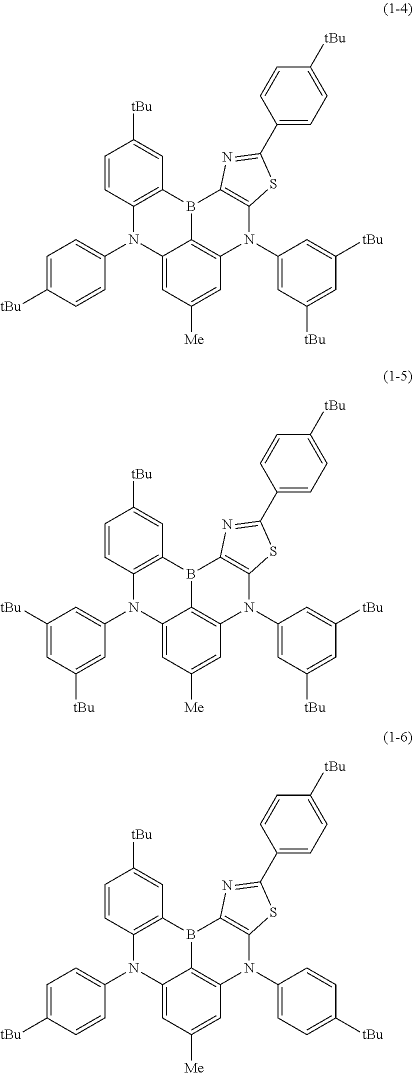 [SMILES: Cc1cc2c3c(c1)N(c1cc(C(C)(C)C)cc(C(C)(C)C)c1)c1sc(-c4ccc(C(C)(C)C)cc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(-c4ccc(C(C)(C)C)cc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(-c4ccc(C(C)(C)C)cc4)nc1B3c1cc(C(C)(C)C)ccc1N2c1ccc(C(C)(C)C)cc1]

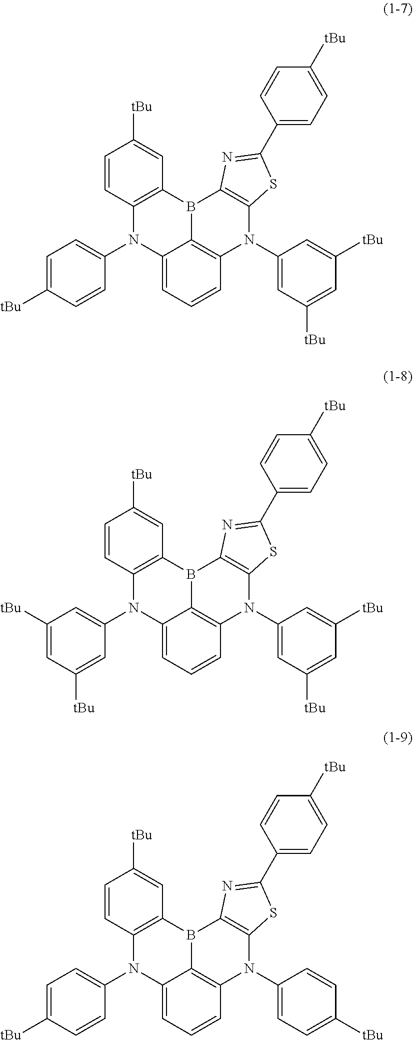 [SMILES: CC(C)(C)c1ccc(-c2nc3c(s2)N(c2cc(C(C)(C)C)cc(C(C)(C)C)c2)c2cccc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cccc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cccc4c2B3c2cc(C(C)(C)C)ccc2N4c2ccc(C(C)(C)C)cc2)cc1]

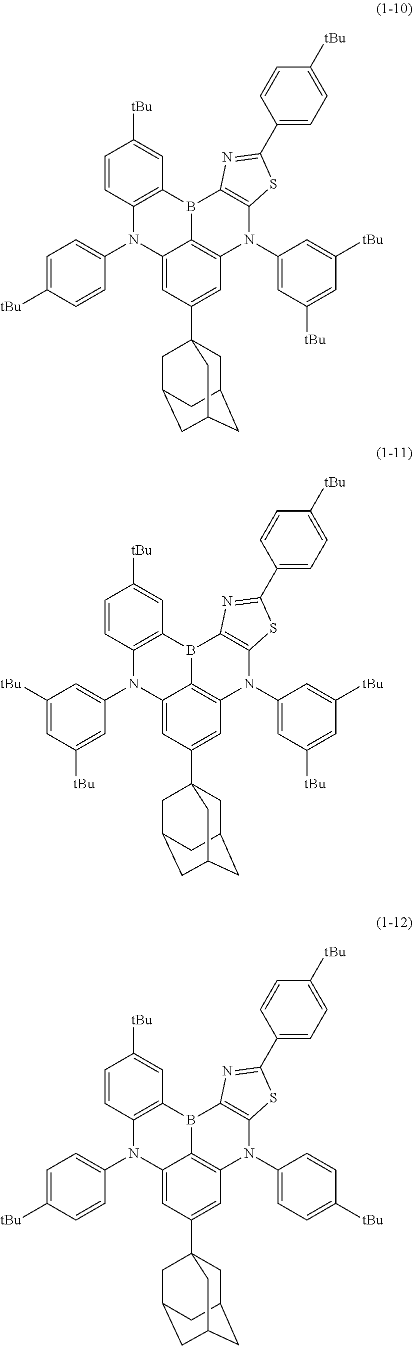 [SMILES: CC(C)(C)c1ccc(-c2nc3c(s2)N(c2cc(C(C)(C)C)cc(C(C)(C)C)c2)c2cc(C45CC6CC(CC(C6)C4)C5)cc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C45CC6CC(CC(C6)C4)C5)cc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C45CC6CC(CC(C6)C4)C5)cc4c2B3c2cc(C(C)(C)C)ccc2N4c2ccc(C(C)(C)C)cc2)cc1]

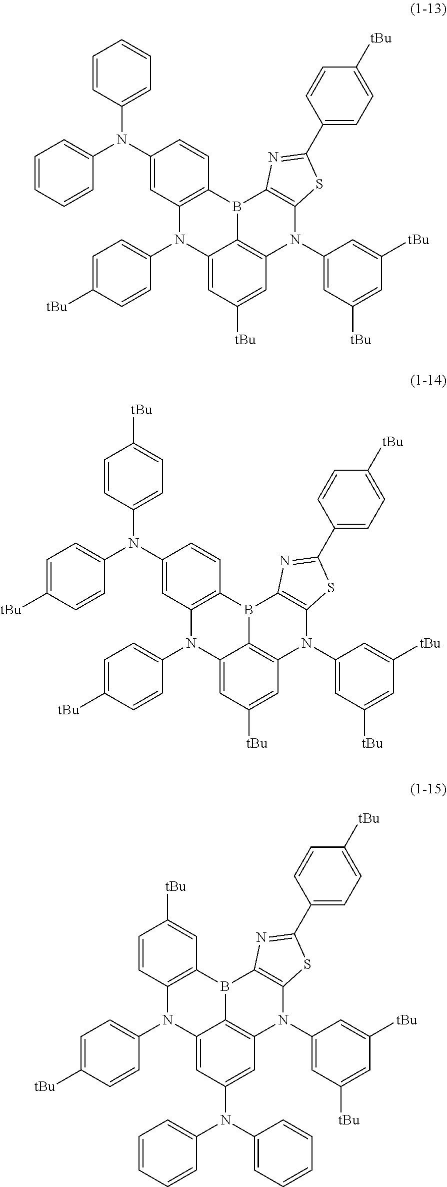 [SMILES: CC(C)(C)c1ccc(-c2nc3c(s2)N(c2cc(C(C)(C)C)cc(C(C)(C)C)c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C(C)(C)C)cc4c2B3c2ccc(N(c3ccc(C(C)(C)C)cc3)c3ccc(C(C)(C)C)cc3)cc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(N(c4ccccc4)c4ccccc4)cc4c2B3c2cc(C(C)(C)C)ccc2N4c2ccc(C(C)(C)C)cc2)cc1]

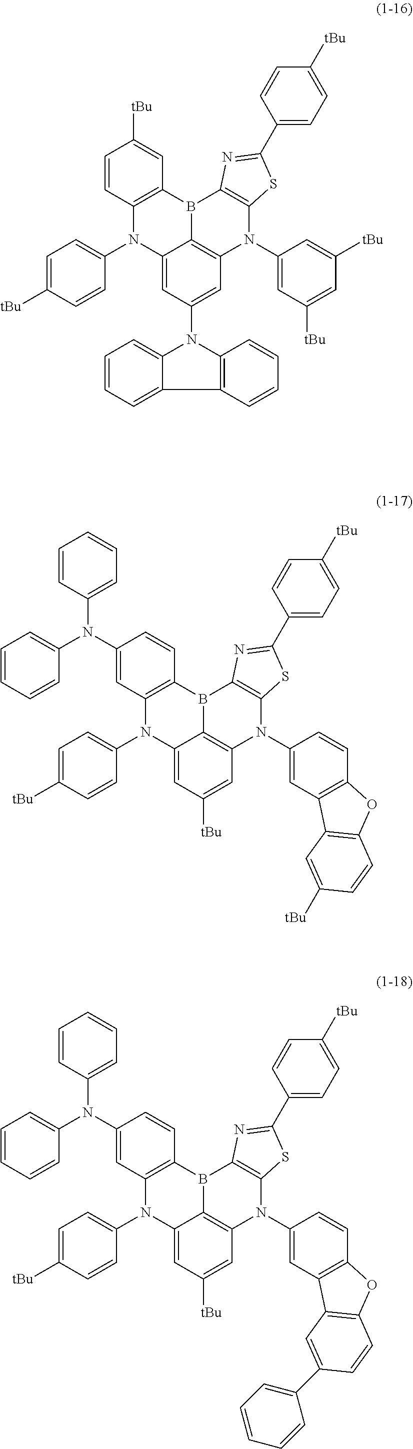 [SMILES: CC(C)(C)c1ccc(-c2nc3c(s2)N(c2cc(C(C)(C)C)cc(C(C)(C)C)c2)c2cc(-n4c5ccccc5c5ccccc54)cc4c2B3c2cc(C(C)(C)C)ccc2N4c2ccc(C(C)(C)C)cc2)cc1 ; CC(C)(C)c1ccc(-c2nc3c(s2)N(c2ccc4oc5ccc(C(C)(C)C)cc5c4c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(s2)N(c2ccc4oc5ccc(-c6ccccc6)cc5c4c2)c2cc(C(C)(C)C)cc4c2B3c2ccc(N(c3ccccc3)c3ccccc3)cc2N4c2ccc(C(C)(C)C)cc2)cc1]

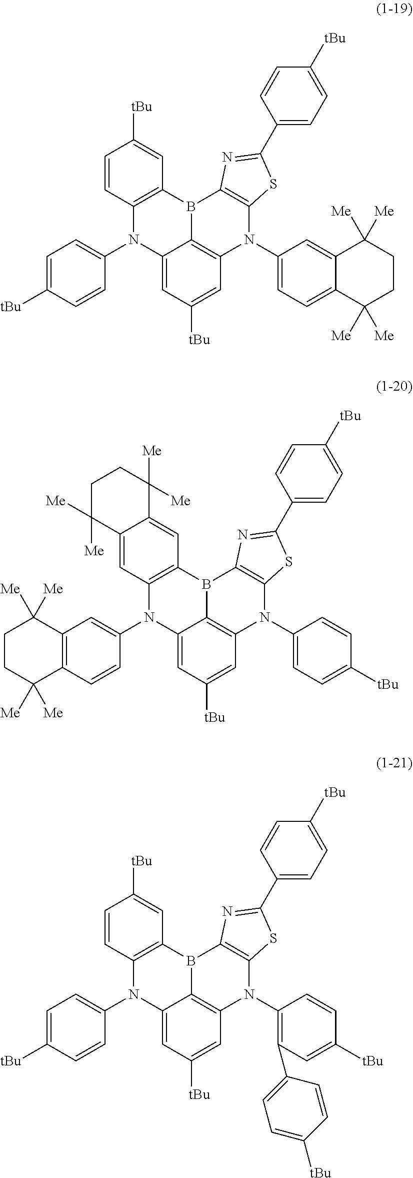 [SMILES: CC(C)(C)c1ccc(-c2nc3c(s2)N(c2ccc4c(c2)C(C)(C)CCC4(C)C)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2ccc(C(C)(C)C)cc2)c2cc(C(C)(C)C)cc4c2B3c2cc3c(cc2N4c2ccc4c(c2)C(C)(C)CCC4(C)C)C(C)(C)CCC3(C)C)cc1 ; CC(C)(C)c1ccc(-c2nc3c(s2)N(c2ccc(C(C)(C)C)cc2-c2ccc(C(C)(C)C)cc2)c2cc(C(C)(C)C)cc4c2B3c2cc(C(C)(C)C)ccc2N4c2ccc(C(C)(C)C)cc2)cc1]

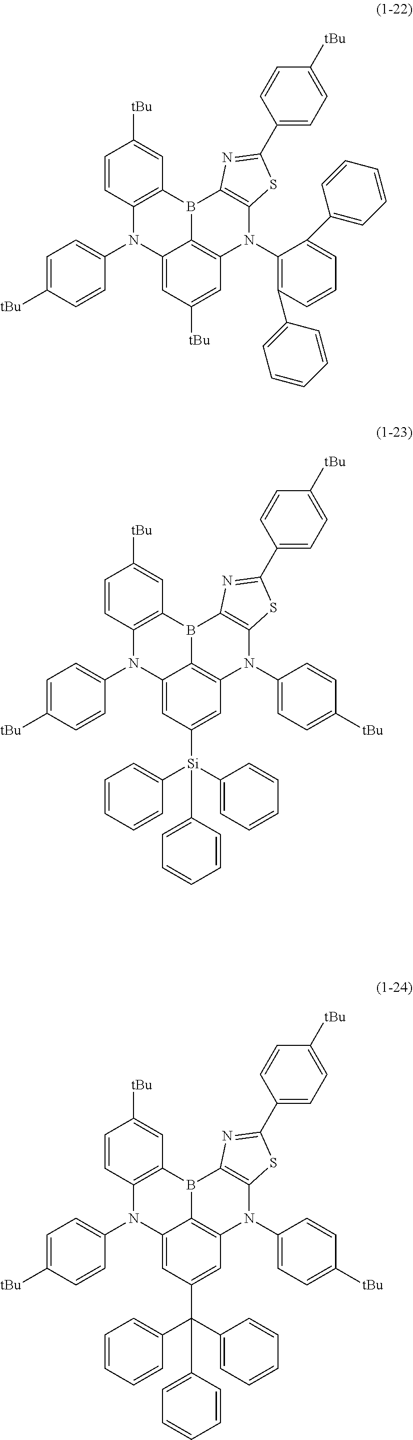 [SMILES: CC(C)(C)c1ccc(-c2nc3c(s2)N(c2c(-c4ccccc4)cccc2-c2ccccc2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2ccc(C(C)(C)C)cc2)c2cc([Si](c4ccccc4)(c4ccccc4)c4ccccc4)cc4c2B3c2cc(C(C)(C)C)ccc2N4c2ccc(C(C)(C)C)cc2)cc1 ; CC(C)(C)c1ccc(-c2nc3c(s2)N(c2ccc(C(C)(C)C)cc2)c2cc(C(c4ccccc4)(c4ccccc4)c4ccccc4)cc4c2B3c2cc(C(C)(C)C)ccc2N4c2ccc(C(C)(C)C)cc2)cc1]

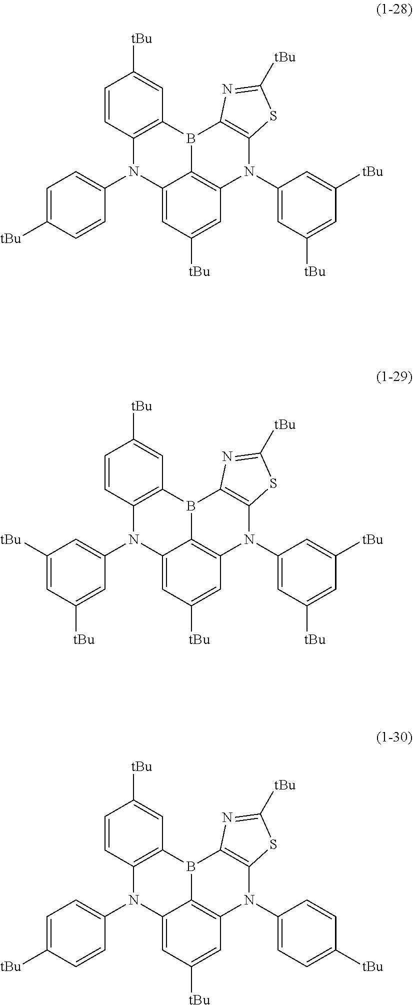 [SMILES: CC(C)(C)c1ccc(N2c3ccc(C(C)(C)C)cc3B3c4nc(C(C)(C)C)sc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(C(C)(C)C)sc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(C(C)(C)C)sc4N(c4ccc(C(C)(C)C)cc4)c4cc(C(C)(C)C)cc2c43)cc1]

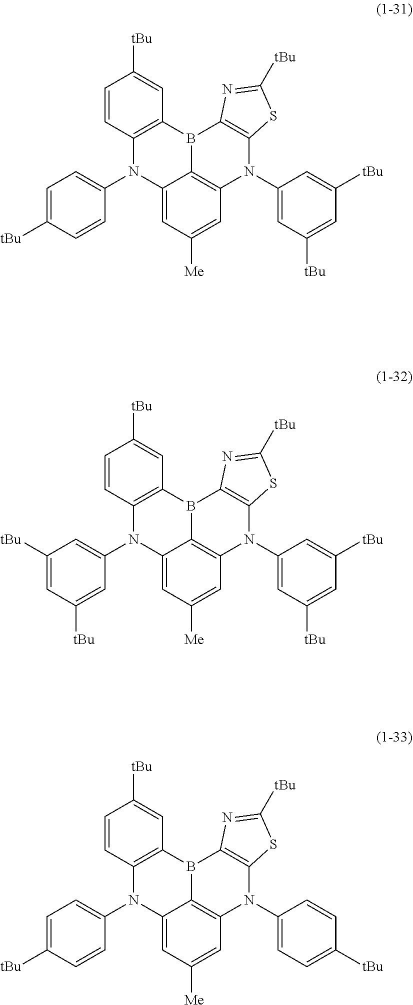 [SMILES: Cc1cc2c3c(c1)N(c1cc(C(C)(C)C)cc(C(C)(C)C)c1)c1sc(C(C)(C)C)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(C(C)(C)C)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(C(C)(C)C)nc1B3c1cc(C(C)(C)C)ccc1N2c1ccc(C(C)(C)C)cc1]

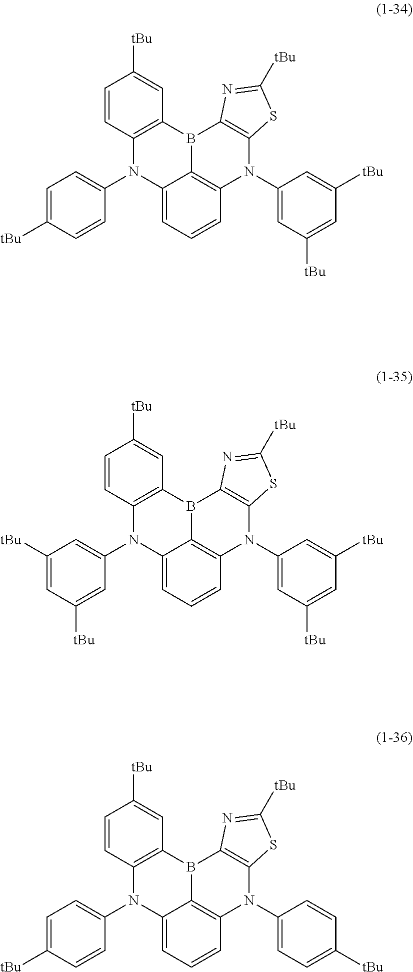 [SMILES: CC(C)(C)c1ccc(N2c3ccc(C(C)(C)C)cc3B3c4nc(C(C)(C)C)sc4N(c4cc(C(C)(C)C)cc(C(C)(C)C)c4)c4cccc2c43)cc1 ; CC(C)(C)c1cc(N2c3ccc(C(C)(C)C)cc3B3c4nc(C(C)(C)C)sc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(C(C)(C)C)sc4N(c4ccc(C(C)(C)C)cc4)c4cccc2c43)cc1]

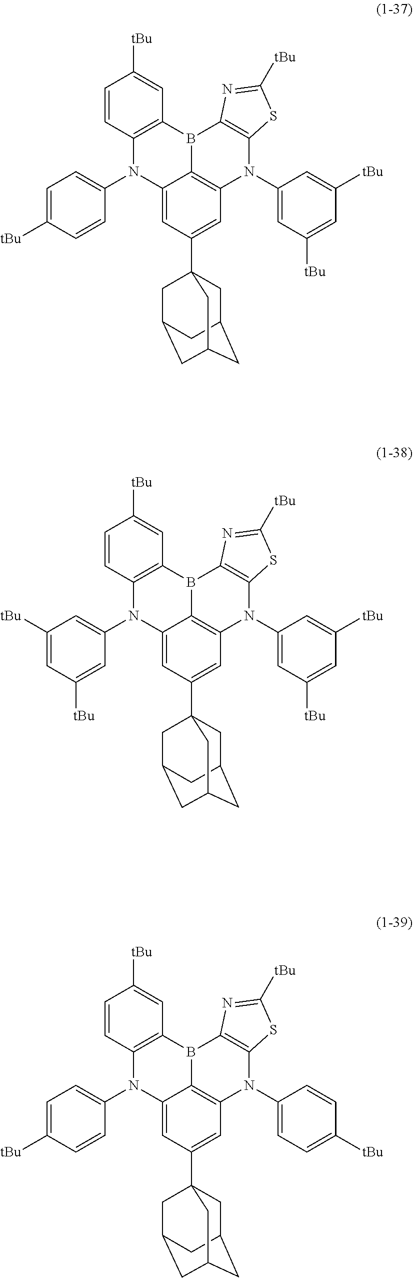 [SMILES: CC(C)(C)c1ccc(N2c3ccc(C(C)(C)C)cc3B3c4nc(C(C)(C)C)sc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(C(C)(C)C)sc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(C(C)(C)C)sc4N(c4ccc(C(C)(C)C)cc4)c4cc(C56CC7CC(CC(C7)C5)C6)cc2c43)cc1]

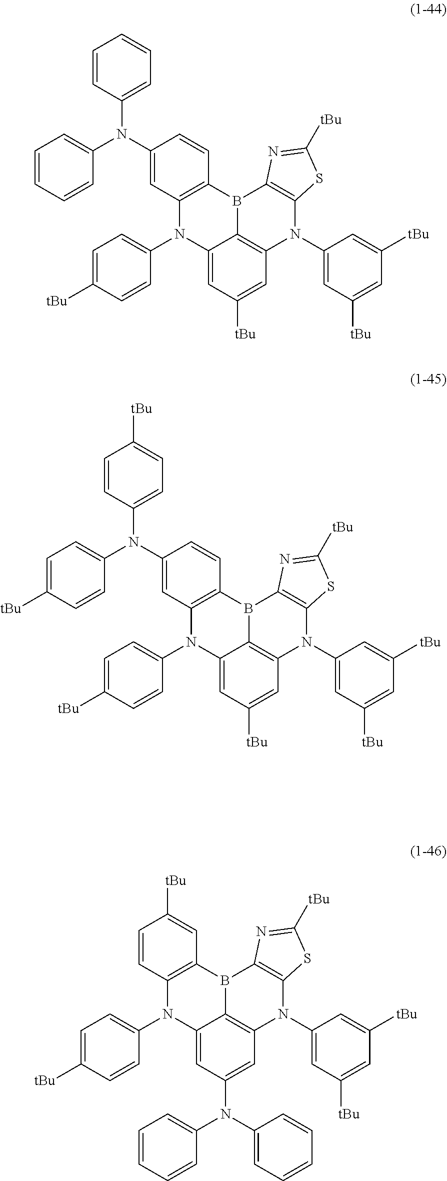 [SMILES: CC(C)(C)c1ccc(N2c3cc(N(c4ccccc4)c4ccccc4)ccc3B3c4nc(C(C)(C)C)sc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2nc(C(C)(C)C)sc2N4c2cc(C(C)(C)C)cc(C(C)(C)C)c2)cc1 ; CC(C)(C)c1ccc(N2c3ccc(C(C)(C)C)cc3B3c4nc(C(C)(C)C)sc4N(c4cc(C(C)(C)C)cc(C(C)(C)C)c4)c4cc(N(c5ccccc5)c5ccccc5)cc2c43)cc1]

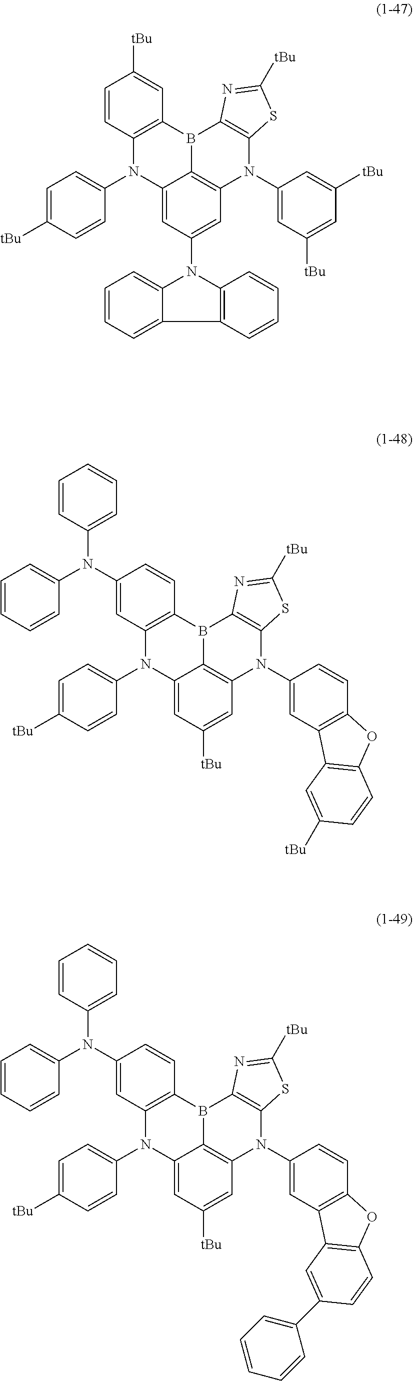 [SMILES: CC(C)(C)c1ccc(N2c3ccc(C(C)(C)C)cc3B3c4nc(C(C)(C)C)sc4N(c4cc(C(C)(C)C)cc(C(C)(C)C)c4)c4cc(-n5c6ccccc6c6ccccc65)cc2c43)cc1 ; CC(C)(C)c1ccc(N2c3cc(N(c4ccccc4)c4ccccc4)ccc3B3c4nc(C(C)(C)C)sc4N(c4ccc5oc6ccc(C(C)(C)C)cc6c5c4)c4cc(C(C)(C)C)cc2c43)cc1 ; CC(C)(C)c1ccc(N2c3cc(N(c4ccccc4)c4ccccc4)ccc3B3c4nc(C(C)(C)C)sc4N(c4ccc5oc6ccc(-c7ccccc7)cc6c5c4)c4cc(C(C)(C)C)cc2c43)cc1]

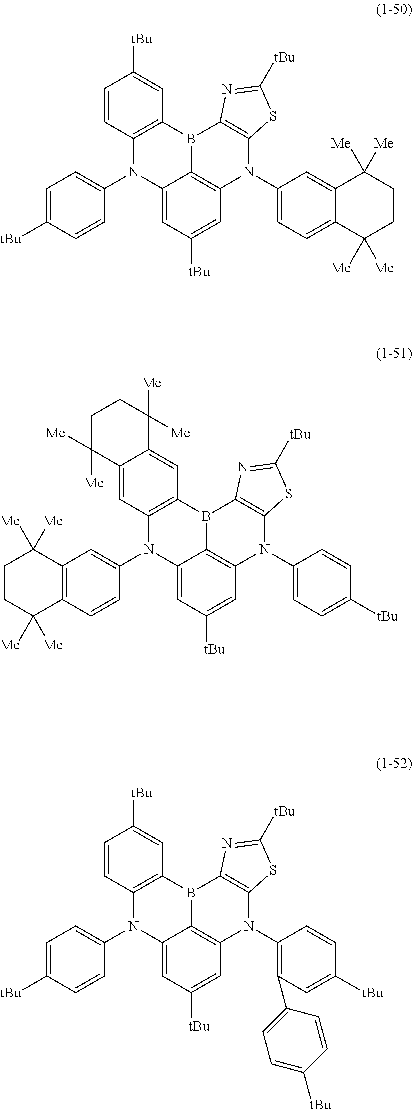 [SMILES: CC(C)(C)c1ccc(N2c3ccc(C(C)(C)C)cc3B3c4nc(C(C)(C)C)sc4N(c4ccc5c(c4)C(C)(C)CCC5(C)C)c4cc(C(C)(C)C)cc2c43)cc1 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3nc(C(C)(C)C)sc32)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(C(C)(C)C)sc32)cc1]

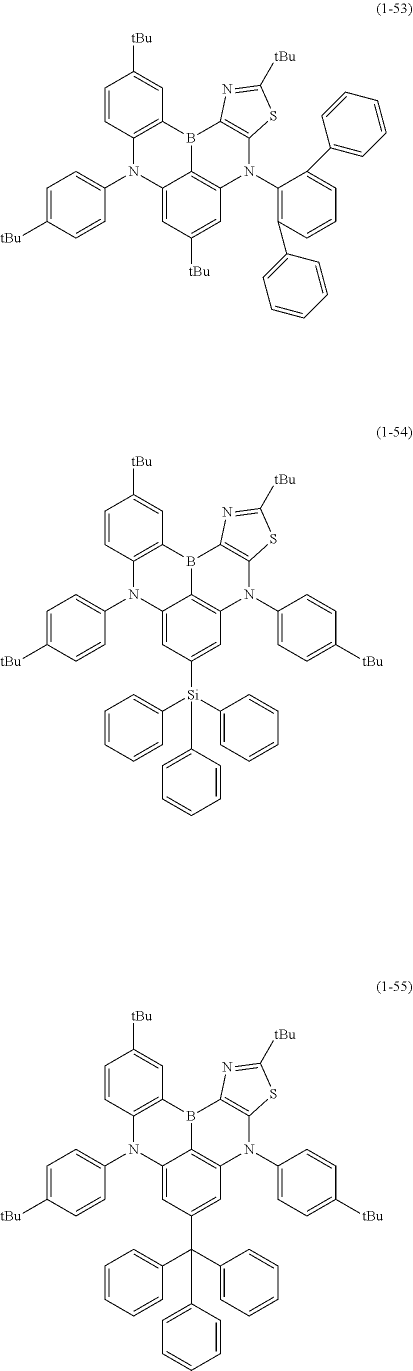 [SMILES: CC(C)(C)c1ccc(N2c3ccc(C(C)(C)C)cc3B3c4nc(C(C)(C)C)sc4N(c4c(-c5ccccc5)cccc4-c4ccccc4)c4cc(C(C)(C)C)cc2c43)cc1 ; CC(C)(C)c1ccc(N2c3ccc(C(C)(C)C)cc3B3c4nc(C(C)(C)C)sc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4nc(C(C)(C)C)sc4N(c4ccc(C(C)(C)C)cc4)c4cc(C(c5ccccc5)(c5ccccc5)c5ccccc5)cc2c43)cc1]

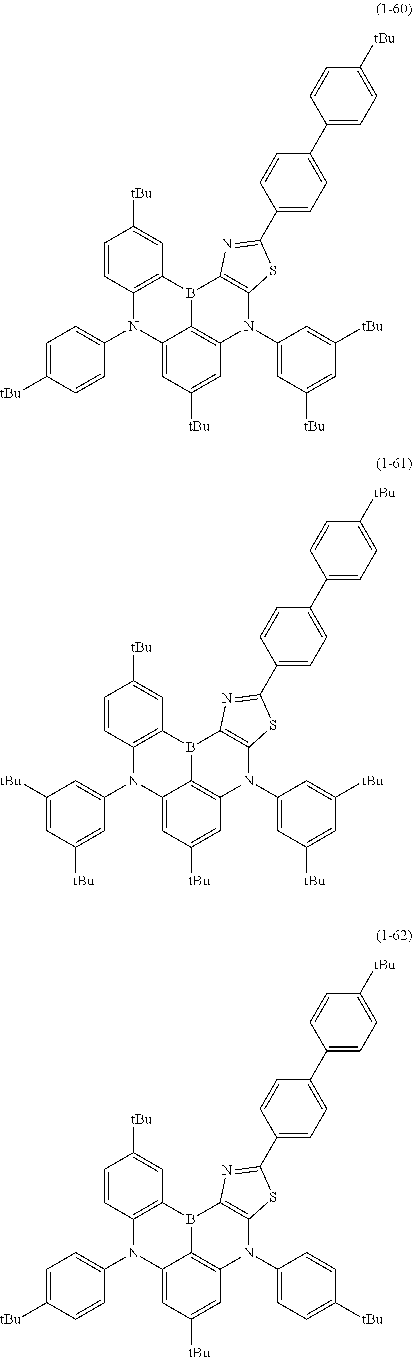 [SMILES: CC(C)(C)c1ccc(-c2ccc(-c3nc4c(s3)N(c3cc(C(C)(C)C)cc(C(C)(C)C)c3)c3cc(C(C)(C)C)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3cc(C(C)(C)C)cc(C(C)(C)C)c3)c3cc(C(C)(C)C)cc5c3B4c3cc(C(C)(C)C)ccc3N5c3cc(C(C)(C)C)cc(C(C)(C)C)c3)cc2)cc1 ; CC(C)(C)c1ccc(-c2ccc(-c3nc4c(s3)N(c3ccc(C(C)(C)C)cc3)c3cc(C(C)(C)C)cc5c3B4c3cc(C(C)(C)C)ccc3N5c3ccc(C(C)(C)C)cc3)cc2)cc1]

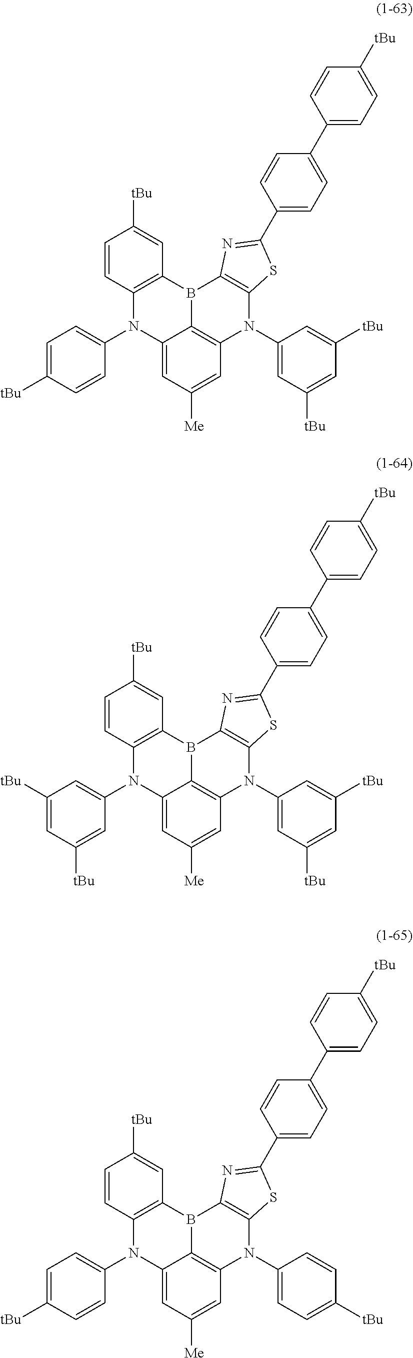 [SMILES: Cc1cc2c3c(c1)N(c1cc(C(C)(C)C)cc(C(C)(C)C)c1)c1sc(-c4ccc(-c5ccc(C(C)(C)C)cc5)cc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(-c4ccc(-c5ccc(C(C)(C)C)cc5)cc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(-c4ccc(-c5ccc(C(C)(C)C)cc5)cc4)nc1B3c1cc(C(C)(C)C)ccc1N2c1ccc(C(C)(C)C)cc1]

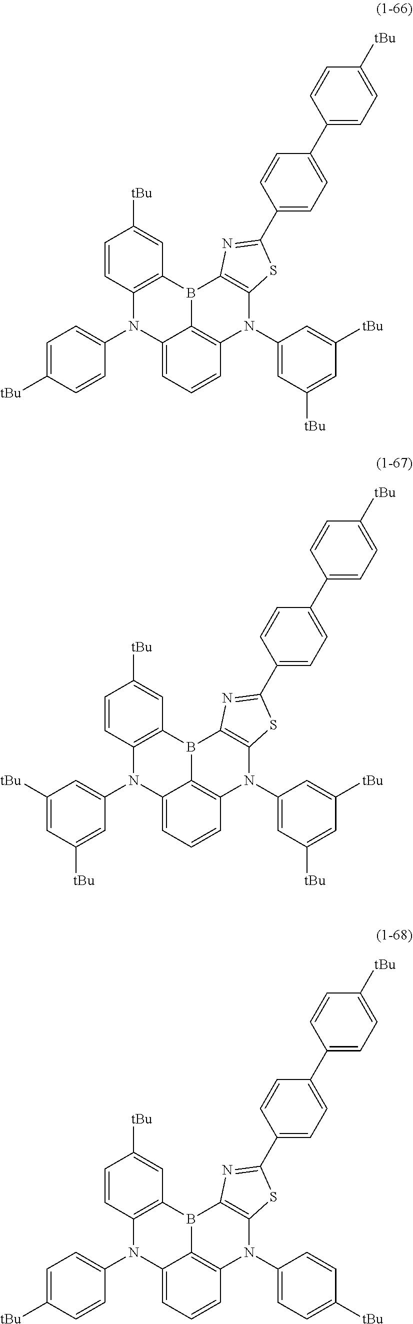 [SMILES: CC(C)(C)c1ccc(-c2ccc(-c3nc4c(s3)N(c3cc(C(C)(C)C)cc(C(C)(C)C)c3)c3cccc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3cc(C(C)(C)C)cc(C(C)(C)C)c3)c3cccc5c3B4c3cc(C(C)(C)C)ccc3N5c3cc(C(C)(C)C)cc(C(C)(C)C)c3)cc2)cc1 ; CC(C)(C)c1ccc(-c2ccc(-c3nc4c(s3)N(c3ccc(C(C)(C)C)cc3)c3cccc5c3B4c3cc(C(C)(C)C)ccc3N5c3ccc(C(C)(C)C)cc3)cc2)cc1]

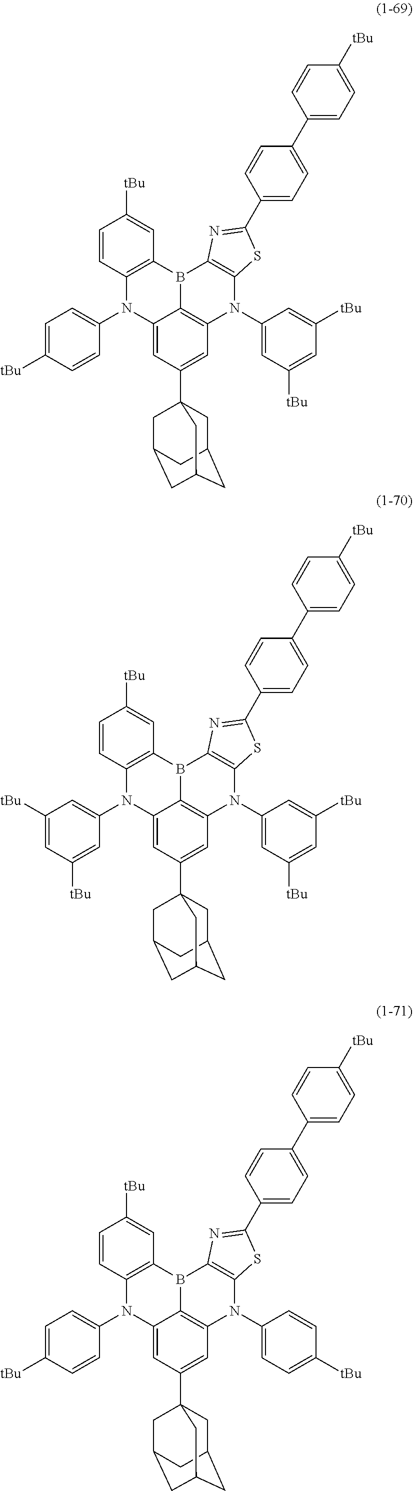 [SMILES: CC(C)(C)c1ccc(-c2ccc(-c3nc4c(s3)N(c3cc(C(C)(C)C)cc(C(C)(C)C)c3)c3cc(C56CC7CC(CC(C7)C5)C6)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3cc(C(C)(C)C)cc(C(C)(C)C)c3)c3cc(C56CC7CC(CC(C7)C5)C6)cc5c3B4c3cc(C(C)(C)C)ccc3N5c3cc(C(C)(C)C)cc(C(C)(C)C)c3)cc2)cc1 ; CC(C)(C)c1ccc(-c2ccc(-c3nc4c(s3)N(c3ccc(C(C)(C)C)cc3)c3cc(C56CC7CC(CC(C7)C5)C6)cc5c3B4c3cc(C(C)(C)C)ccc3N5c3ccc(C(C)(C)C)cc3)cc2)cc1]

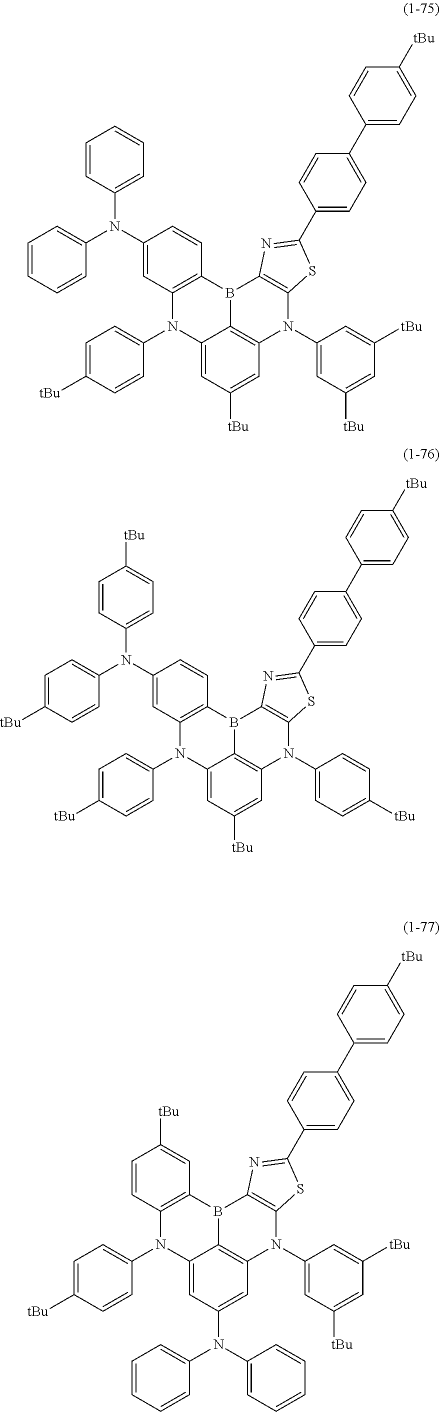 [SMILES: CC(C)(C)c1ccc(-c2ccc(-c3nc4c(s3)N(c3cc(C(C)(C)C)cc(C(C)(C)C)c3)c3cc(C(C)(C)C)cc5c3B4c3ccc(N(c4ccccc4)c4ccccc4)cc3N5c3ccc(C(C)(C)C)cc3)cc2)cc1 ; CC(C)(C)c1ccc(-c2ccc(-c3nc4c(s3)N(c3ccc(C(C)(C)C)cc3)c3cc(C(C)(C)C)cc5c3B4c3ccc(N(c4ccc(C(C)(C)C)cc4)c4ccc(C(C)(C)C)cc4)cc3N5c3ccc(C(C)(C)C)cc3)cc2)cc1 ; CC(C)(C)c1ccc(-c2ccc(-c3nc4c(s3)N(c3cc(C(C)(C)C)cc(C(C)(C)C)c3)c3cc(N(c5ccccc5)c5ccccc5)cc5c3B4c3cc(C(C)(C)C)ccc3N5c3ccc(C(C)(C)C)cc3)cc2)cc1]

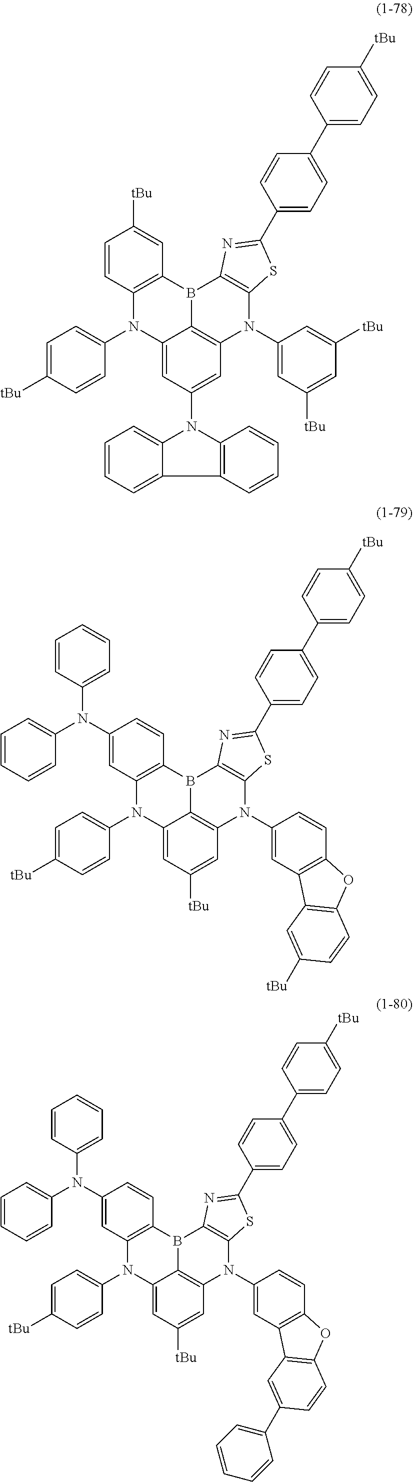 [SMILES: CC(C)(C)c1ccc(-c2ccc(-c3nc4c(s3)N(c3cc(C(C)(C)C)cc(C(C)(C)C)c3)c3cc(-n5c6ccccc6c6ccccc65)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3ccc5oc6ccc(C(C)(C)C)cc6c5c3)c3cc(C(C)(C)C)cc5c3B4c3ccc(N(c4ccccc4)c4ccccc4)cc3N5c3ccc(C(C)(C)C)cc3)cc2)cc1 ; CC(C)(C)c1ccc(-c2ccc(-c3nc4c(s3)N(c3ccc5oc6ccc(-c7ccccc7)cc6c5c3)c3cc(C(C)(C)C)cc5c3B4c3ccc(N(c4ccccc4)c4ccccc4)cc3N5c3ccc(C(C)(C)C)cc3)cc2)cc1]

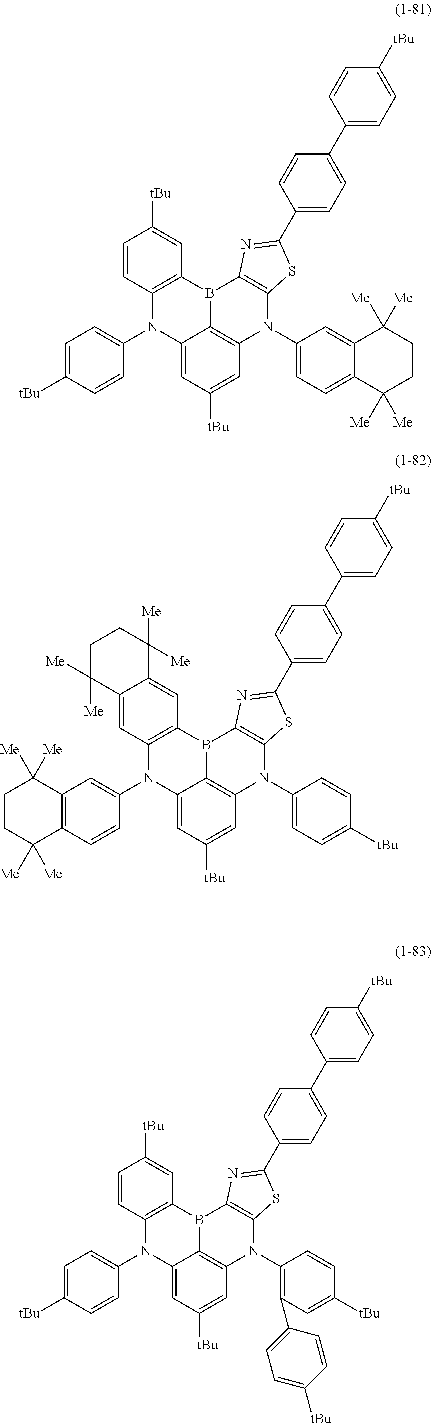 [SMILES: CC(C)(C)c1ccc(-c2ccc(-c3nc4c(s3)N(c3ccc5c(c3)C(C)(C)CCC5(C)C)c3cc(C(C)(C)C)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3ccc(C(C)(C)C)cc3)c3cc(C(C)(C)C)cc5c3B4c3cc4c(cc3N5c3ccc5c(c3)C(C)(C)CCC5(C)C)C(C)(C)CCC4(C)C)cc2)cc1 ; CC(C)(C)c1ccc(-c2ccc(-c3nc4c(s3)N(c3ccc(C(C)(C)C)cc3-c3ccc(C(C)(C)C)cc3)c3cc(C(C)(C)C)cc5c3B4c3cc(C(C)(C)C)ccc3N5c3ccc(C(C)(C)C)cc3)cc2)cc1]

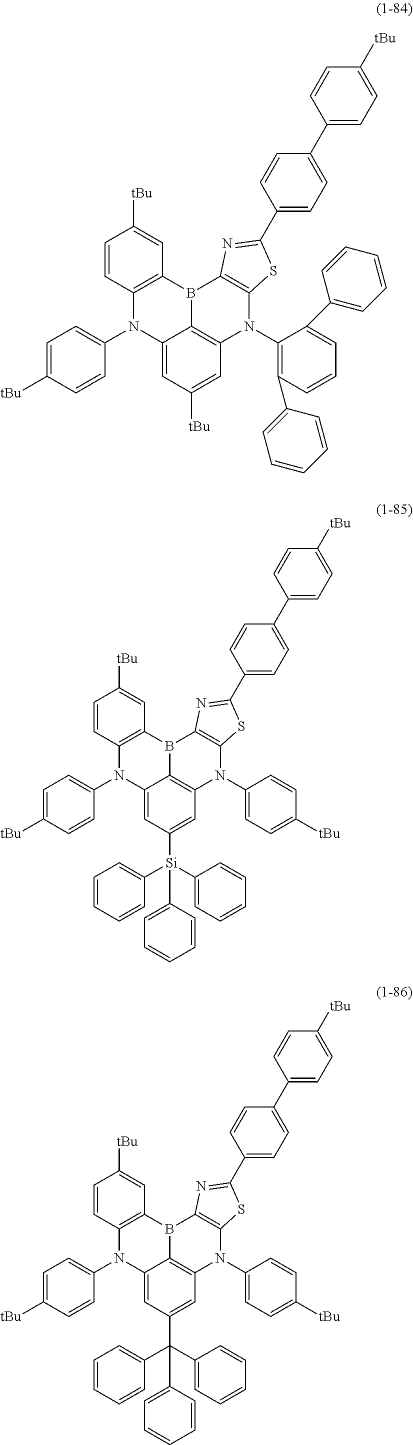 [SMILES: CC(C)(C)c1ccc(-c2ccc(-c3nc4c(s3)N(c3c(-c5ccccc5)cccc3-c3ccccc3)c3cc(C(C)(C)C)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3ccc(C(C)(C)C)cc3)c3cc([Si](c5ccccc5)(c5ccccc5)c5ccccc5)cc5c3B4c3cc(C(C)(C)C)ccc3N5c3ccc(C(C)(C)C)cc3)cc2)cc1 ; CC(C)(C)c1ccc(-c2ccc(-c3nc4c(s3)N(c3ccc(C(C)(C)C)cc3)c3cc(C(c5ccccc5)(c5ccccc5)c5ccccc5)cc5c3B4c3cc(C(C)(C)C)ccc3N5c3ccc(C(C)(C)C)cc3)cc2)cc1]

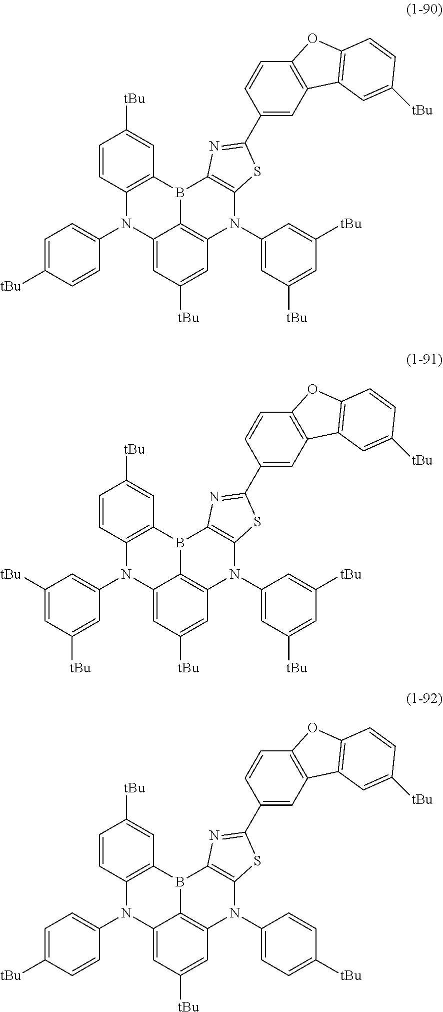 [SMILES: CC(C)(C)c1ccc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)sc4N(c4ccc(C(C)(C)C)cc4)c4cc(C(C)(C)C)cc2c43)cc1]

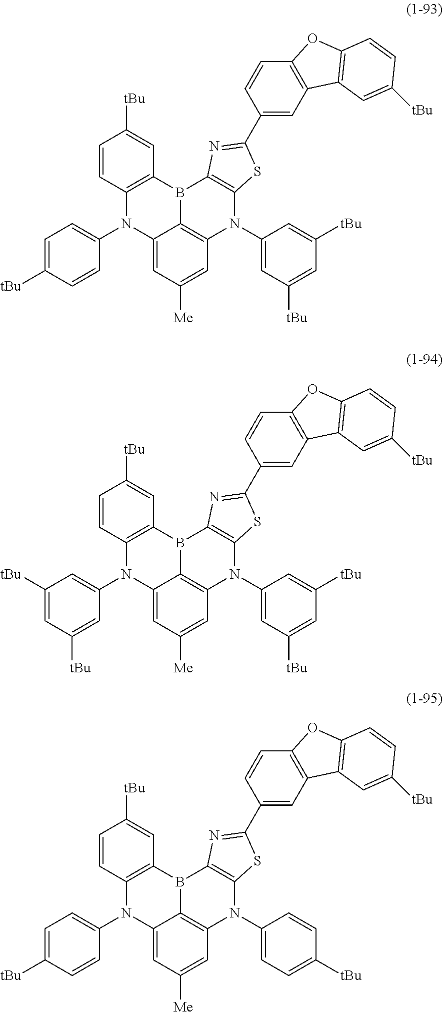 [SMILES: Cc1cc2c3c(c1)N(c1cc(C(C)(C)C)cc(C(C)(C)C)c1)c1sc(-c4ccc5oc6ccc(C(C)(C)C)cc6c5c4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(-c4ccc5oc6ccc(C(C)(C)C)cc6c5c4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(-c4ccc5oc6ccc(C(C)(C)C)cc6c5c4)nc1B3c1cc(C(C)(C)C)ccc1N2c1ccc(C(C)(C)C)cc1]

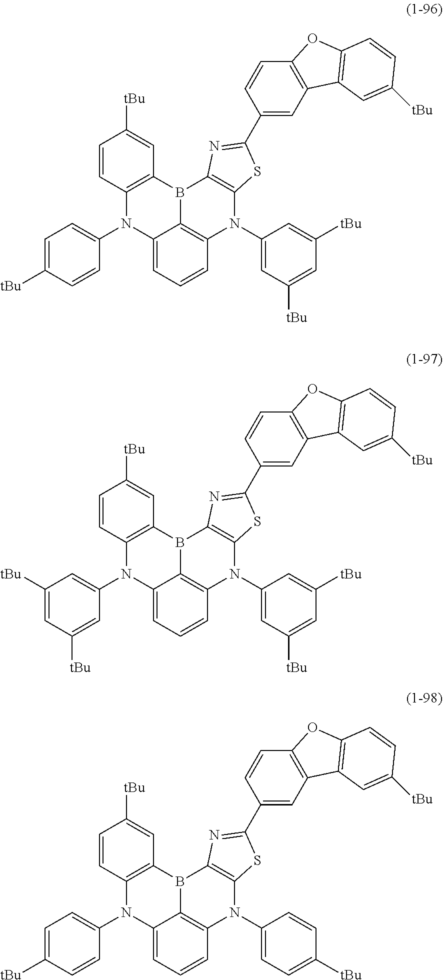 [SMILES: CC(C)(C)c1ccc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cccc2c43)cc1 ; CC(C)(C)c1cc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)sc4N(c4ccc(C(C)(C)C)cc4)c4cccc2c43)cc1]

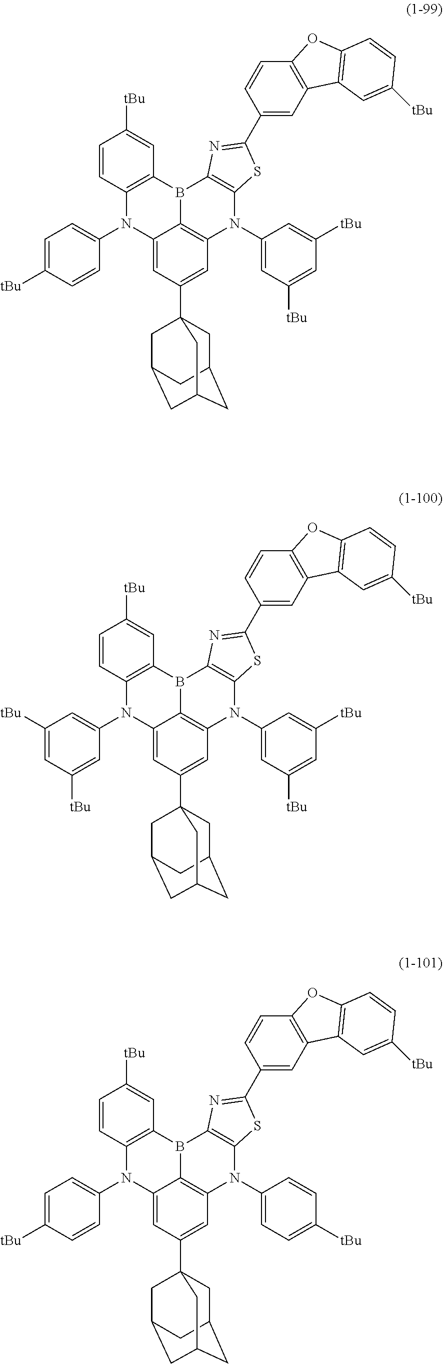 [SMILES: CC(C)(C)c1ccc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)sc4N(c4ccc(C(C)(C)C)cc4)c4cc(C56CC7CC(CC(C7)C5)C6)cc2c43)cc1]

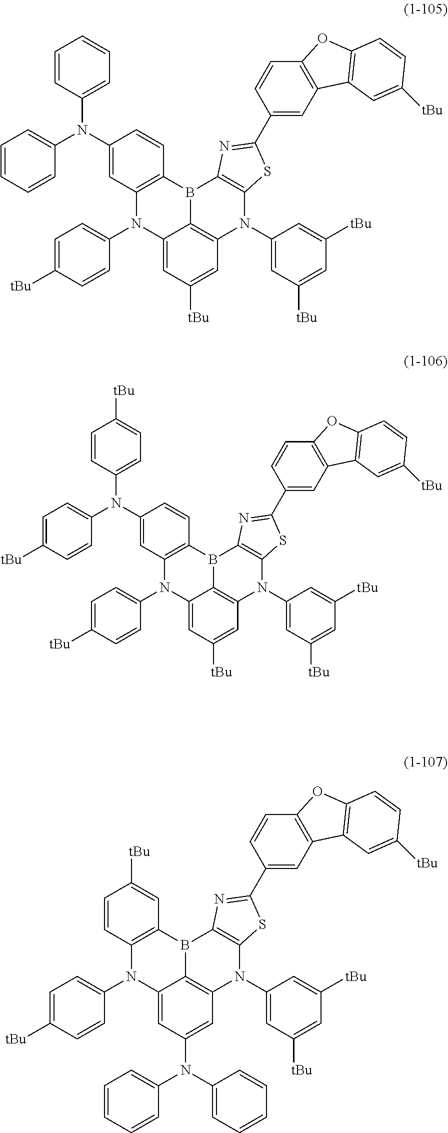 [SMILES: CC(C)(C)c1ccc(N2c3cc(N(c4ccccc4)c4ccccc4)ccc3B3c4nc(-c5ccc6oc7ccc(C(C)(C)C)cc7c6c5)sc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2nc(-c3ccc5oc6ccc(C(C)(C)C)cc6c5c3)sc2N4c2cc(C(C)(C)C)cc(C(C)(C)C)c2)cc1 ; CC(C)(C)c1ccc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(N(c5ccccc5)c5ccccc5)cc2c43)cc1]

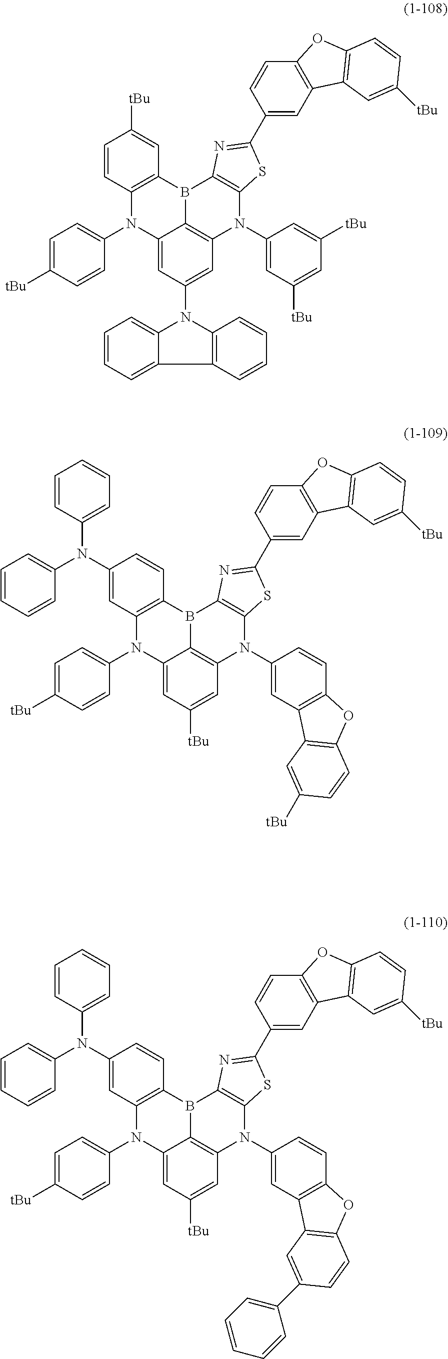 [SMILES: CC(C)(C)c1ccc(N2c3ccc(C(C)(C)C)cc3B3c4nc(-c5ccc6oc7ccc(C(C)(C)C)cc7c6c5)sc4N(c4cc(C(C)(C)C)cc(C(C)(C)C)c4)c4cc(-n5c6ccccc6c6ccccc65)cc2c43)cc1 ; CC(C)(C)c1ccc(N2c3cc(N(c4ccccc4)c4ccccc4)ccc3B3c4nc(-c5ccc6oc7ccc(C(C)(C)C)cc7c6c5)sc4N(c4ccc5oc6ccc(C(C)(C)C)cc6c5c4)c4cc(C(C)(C)C)cc2c43)cc1 ; CC(C)(C)c1ccc(N2c3cc(N(c4ccccc4)c4ccccc4)ccc3B3c4nc(-c5ccc6oc7ccc(C(C)(C)C)cc7c6c5)sc4N(c4ccc5oc6ccc(-c7ccccc7)cc6c5c4)c4cc(C(C)(C)C)cc2c43)cc1]

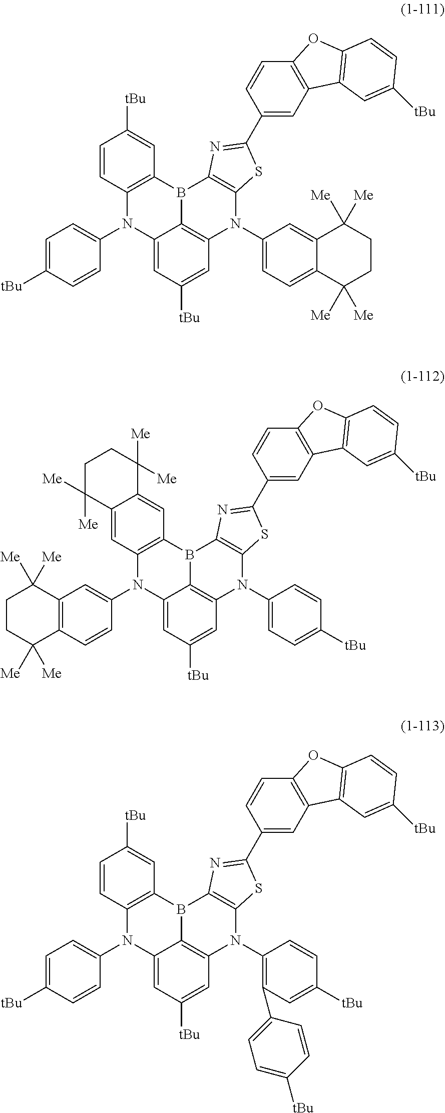 [SMILES: CC(C)(C)c1ccc(N2c3ccc(C(C)(C)C)cc3B3c4nc(-c5ccc6oc7ccc(C(C)(C)C)cc7c6c5)sc4N(c4ccc5c(c4)C(C)(C)CCC5(C)C)c4cc(C(C)(C)C)cc2c43)cc1 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3nc(-c4ccc5oc6ccc(C(C)(C)C)cc6c5c4)sc32)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(-c4ccc5oc6ccc(C(C)(C)C)cc6c5c4)sc32)cc1]

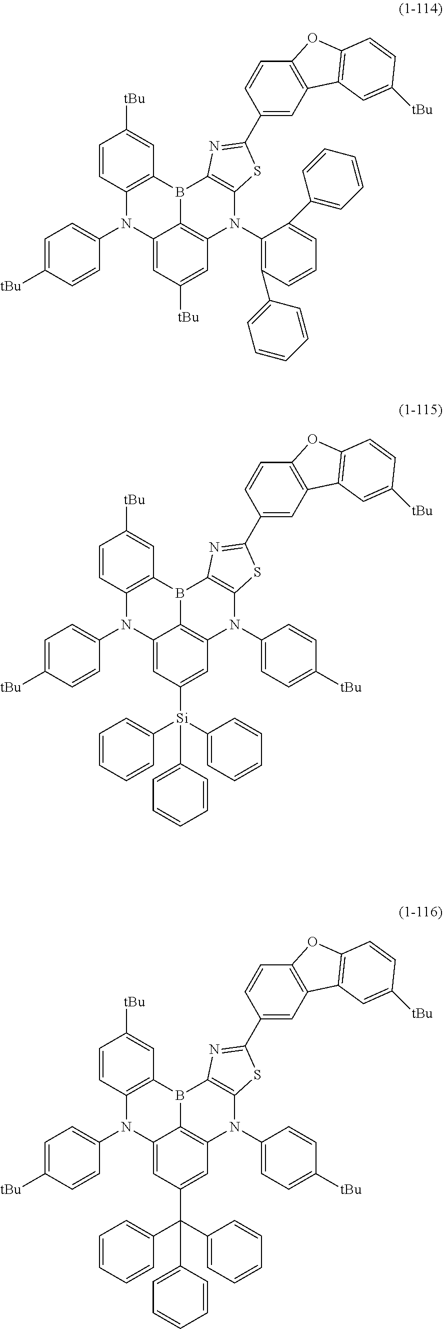 [SMILES: CC(C)(C)c1ccc(N2c3ccc(C(C)(C)C)cc3B3c4nc(-c5ccc6oc7ccc(C(C)(C)C)cc7c6c5)sc4N(c4c(-c5ccccc5)cccc4-c4ccccc4)c4cc(C(C)(C)C)cc2c43)cc1 ; CC(C)(C)c1ccc(N2c3ccc(C(C)(C)C)cc3B3c4nc(-c5ccc6oc7ccc(C(C)(C)C)cc7c6c5)sc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4nc(-c5ccc6oc7ccc(C(C)(C)C)cc7c6c5)sc4N(c4ccc(C(C)(C)C)cc4)c4cc(C(c5ccccc5)(c5ccccc5)c5ccccc5)cc2c43)cc1]

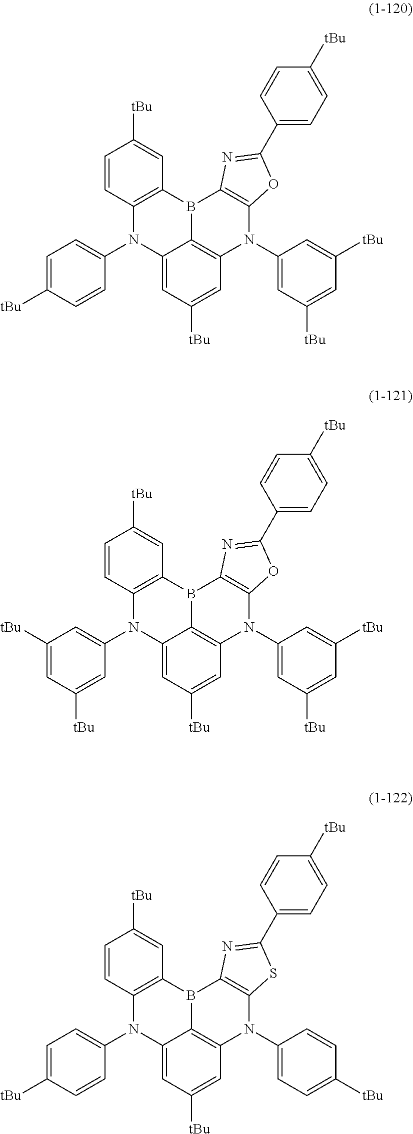 [SMILES: CC(C)(C)c1ccc(-c2nc3c(o2)N(c2cc(C(C)(C)C)cc(C(C)(C)C)c2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(o2)N(c2cc(C(C)(C)C)cc(C(C)(C)C)c2)c2cc(C(C)(C)C)cc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C(C)(C)C)cc4c2B3c2cc(C(C)(C)C)ccc2N4c2ccc(C(C)(C)C)cc2)cc1]

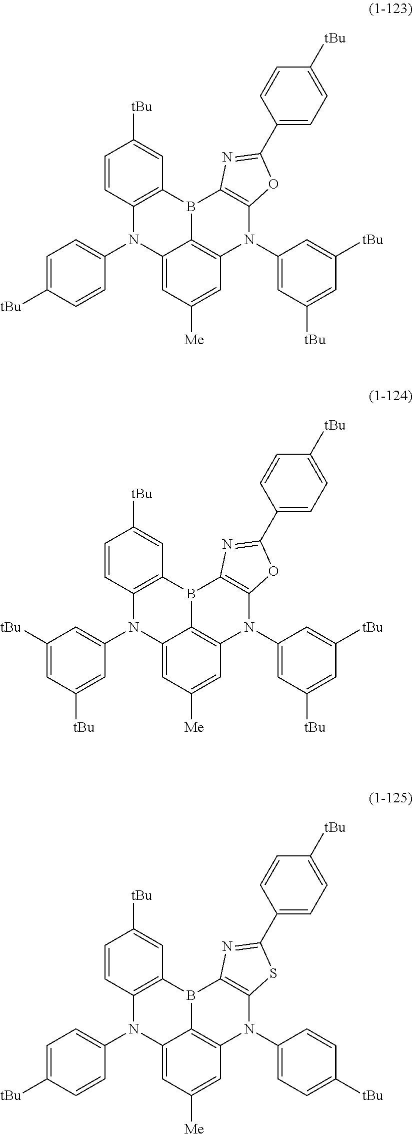 [SMILES: Cc1cc2c3c(c1)N(c1cc(C(C)(C)C)cc(C(C)(C)C)c1)c1oc(-c4ccc(C(C)(C)C)cc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1oc(-c4ccc(C(C)(C)C)cc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(-c4ccc(C(C)(C)C)cc4)nc1B3c1cc(C(C)(C)C)ccc1N2c1ccc(C(C)(C)C)cc1]

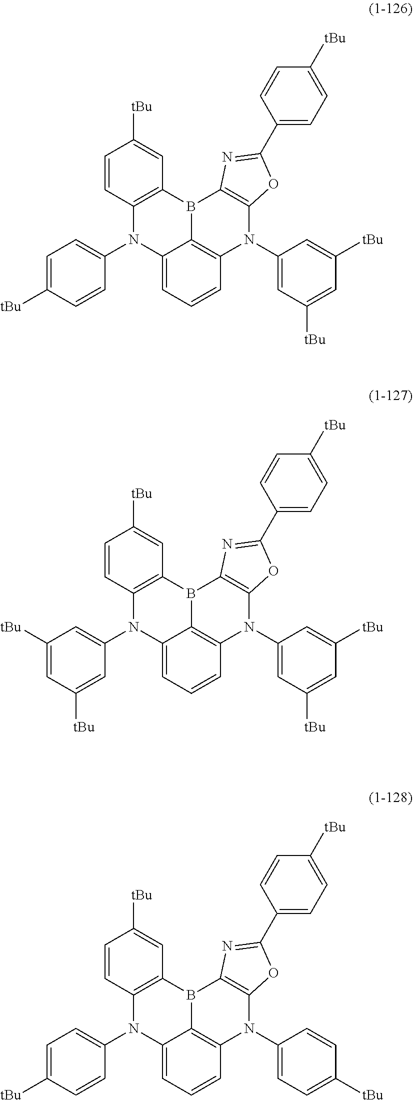 [SMILES: CC(C)(C)c1ccc(-c2nc3c(o2)N(c2cc(C(C)(C)C)cc(C(C)(C)C)c2)c2cccc4c2B3c2cc(C(C)(C)C)ccc2N4c2ccc(C(C)(C)C)cc2)cc1 ; CC(C)(C)c1ccc(-c2nc3c(o2)N(c2cc(C(C)(C)C)cc(C(C)(C)C)c2)c2cccc4c2B3c2cc(C(C)(C)C)ccc2N4c2cc(C(C)(C)C)cc(C(C)(C)C)c2)cc1 ; CC(C)(C)c1ccc(-c2nc3c(o2)N(c2ccc(C(C)(C)C)cc2)c2cccc4c2B3c2cc(C(C)(C)C)ccc2N4c2ccc(C(C)(C)C)cc2)cc1]

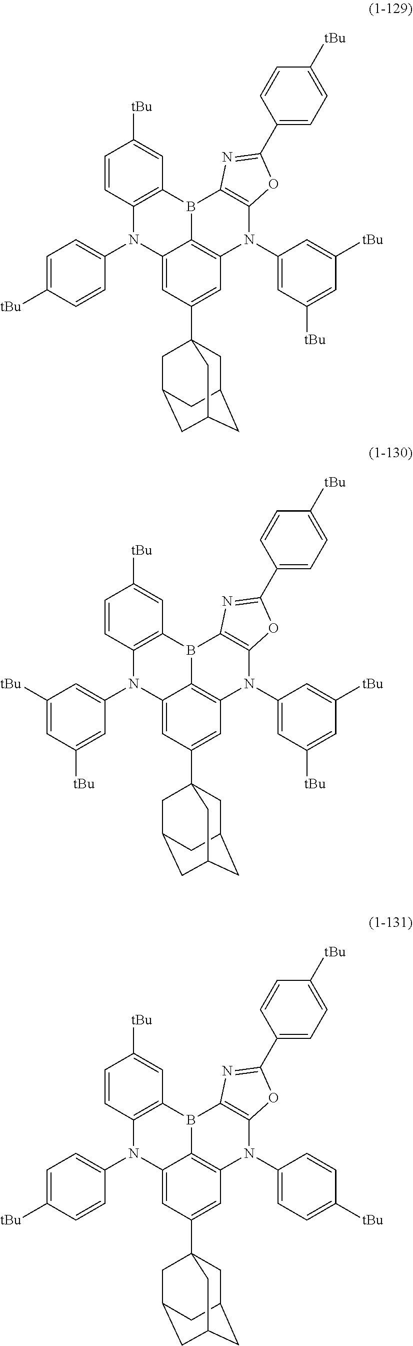 [SMILES: CC(C)(C)c1ccc(-c2nc3c(o2)N(c2cc(C(C)(C)C)cc(C(C)(C)C)c2)c2cc(C45CC6CC(CC(C6)C4)C5)cc4c2B3c2cc(C(C)(C)C)ccc2N4c2ccc(C(C)(C)C)cc2)cc1 ; CC(C)(C)c1ccc(-c2nc3c(o2)N(c2cc(C(C)(C)C)cc(C(C)(C)C)c2)c2cc(C45CC6CC(CC(C6)C4)C5)cc4c2B3c2cc(C(C)(C)C)ccc2N4c2cc(C(C)(C)C)cc(C(C)(C)C)c2)cc1 ; CC(C)(C)c1ccc(-c2nc3c(o2)N(c2ccc(C(C)(C)C)cc2)c2cc(C45CC6CC(CC(C6)C4)C5)cc4c2B3c2cc(C(C)(C)C)ccc2N4c2ccc(C(C)(C)C)cc2)cc1]

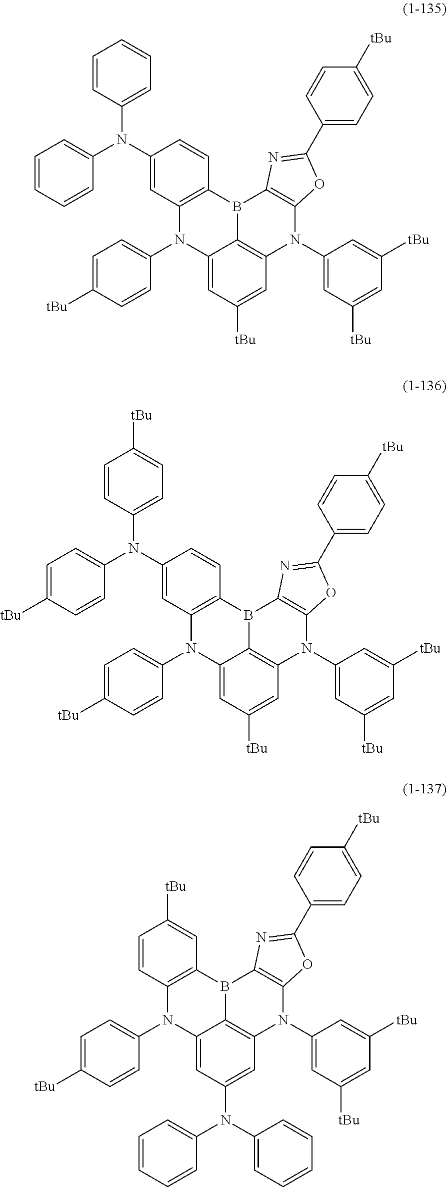 [SMILES: CC(C)(C)c1ccc(-c2nc3c(o2)N(c2cc(C(C)(C)C)cc(C(C)(C)C)c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(o2)N(c2cc(C(C)(C)C)cc(C(C)(C)C)c2)c2cc(C(C)(C)C)cc4c2B3c2ccc(N(c3ccc(C(C)(C)C)cc3)c3ccc(C(C)(C)C)cc3)cc2N4c2ccc(C(C)(C)C)cc2)cc1 ; CC(C)(C)c1ccc(-c2nc3c(o2)N(c2cc(C(C)(C)C)cc(C(C)(C)C)c2)c2cc(N(c4ccccc4)c4ccccc4)cc4c2B3c2cc(C(C)(C)C)ccc2N4c2ccc(C(C)(C)C)cc2)cc1]

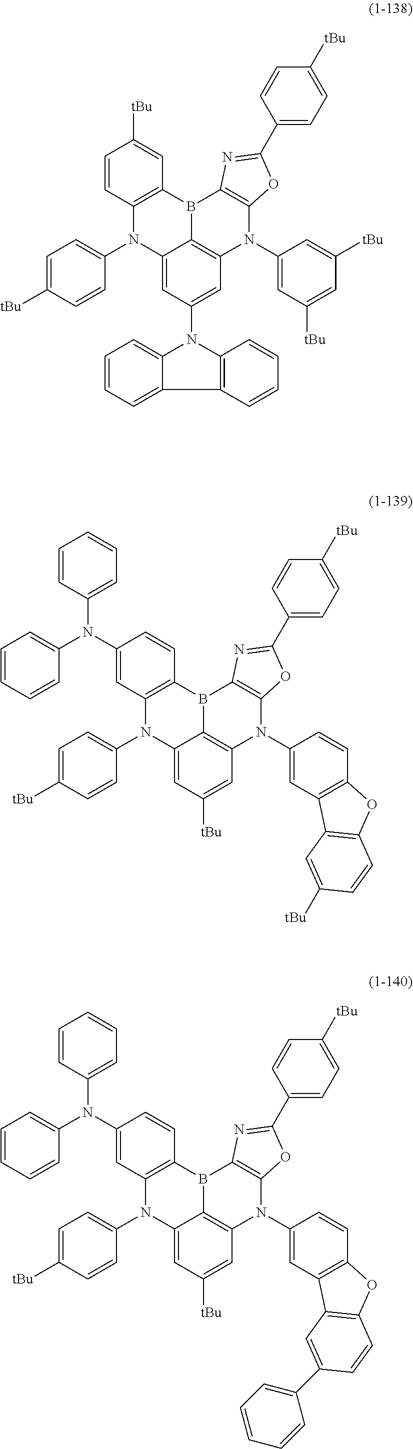 [SMILES: CC(C)(C)c1ccc(-c2nc3c(o2)N(c2cc(C(C)(C)C)cc(C(C)(C)C)c2)c2cc(-n4c5ccccc5c5ccccc54)cc4c2B3c2cc(C(C)(C)C)ccc2N4c2ccc(C(C)(C)C)cc2)cc1 ; CC(C)(C)c1ccc(-c2nc3c(o2)N(c2ccc4oc5ccc(C(C)(C)C)cc5c4c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(o2)N(c2ccc4oc5ccc(-c6ccccc6)cc5c4c2)c2cc(C(C)(C)C)cc4c2B3c2ccc(N(c3ccccc3)c3ccccc3)cc2N4c2ccc(C(C)(C)C)cc2)cc1]

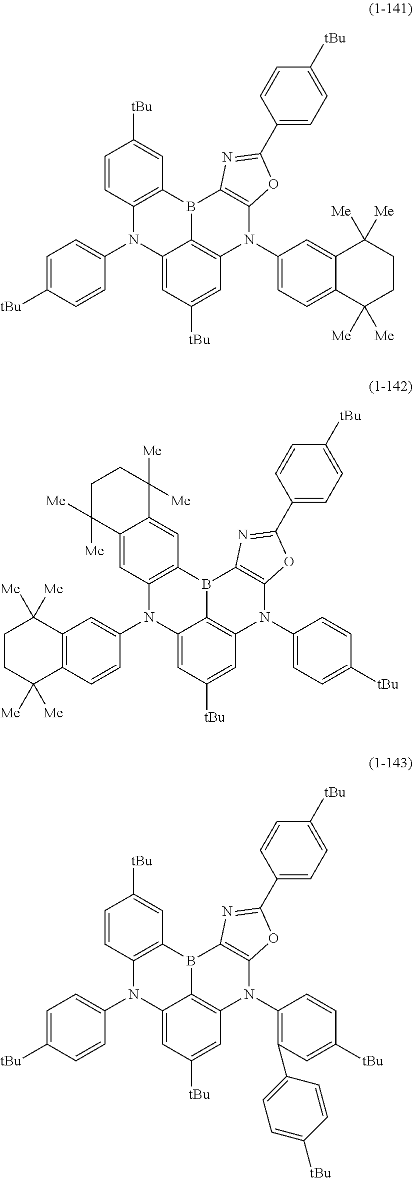 [SMILES: CC(C)(C)c1ccc(-c2nc3c(o2)N(c2ccc4c(c2)C(C)(C)CCC4(C)C)c2cc(C(C)(C)C)cc4c2B3c2cc(C(C)(C)C)ccc2N4c2ccc(C(C)(C)C)cc2)cc1 ; CC(C)(C)c1ccc(-c2nc3c(o2)N(c2ccc(C(C)(C)C)cc2)c2cc(C(C)(C)C)cc4c2B3c2cc3c(cc2N4c2ccc4c(c2)C(C)(C)CCC4(C)C)C(C)(C)CCC3(C)C)cc1 ; CC(C)(C)c1ccc(-c2nc3c(o2)N(c2ccc(C(C)(C)C)cc2-c2ccc(C(C)(C)C)cc2)c2cc(C(C)(C)C)cc4c2B3c2cc(C(C)(C)C)ccc2N4c2ccc(C(C)(C)C)cc2)cc1]

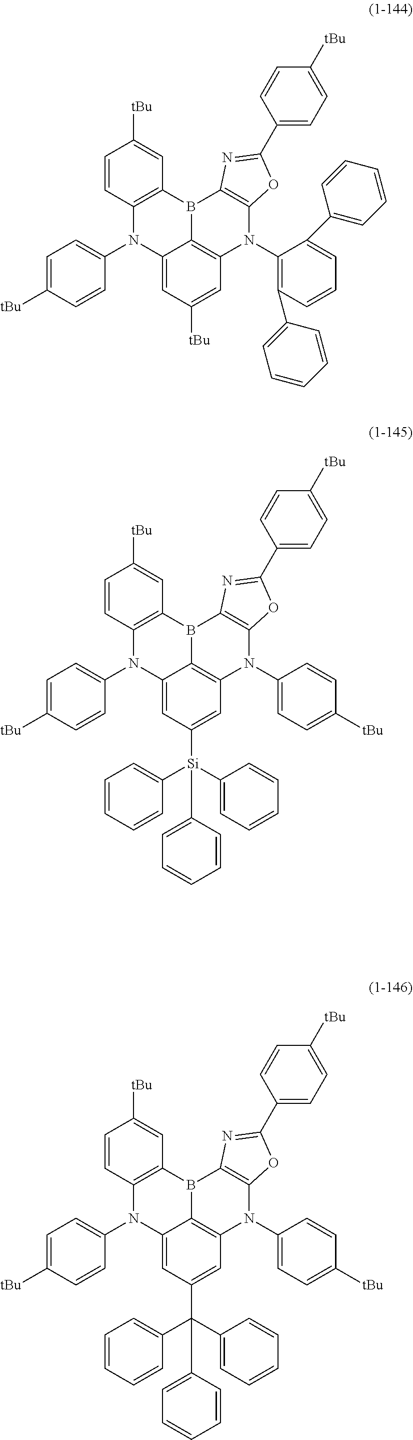 [SMILES: CC(C)(C)c1ccc(-c2nc3c(o2)N(c2c(-c4ccccc4)cccc2-c2ccccc2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(o2)N(c2ccc(C(C)(C)C)cc2)c2cc([Si](c4ccccc4)(c4ccccc4)c4ccccc4)cc4c2B3c2cc(C(C)(C)C)ccc2N4c2ccc(C(C)(C)C)cc2)cc1 ; CC(C)(C)c1ccc(-c2nc3c(o2)N(c2ccc(C(C)(C)C)cc2)c2cc(C(c4ccccc4)(c4ccccc4)c4ccccc4)cc4c2B3c2cc(C(C)(C)C)ccc2N4c2ccc(C(C)(C)C)cc2)cc1]

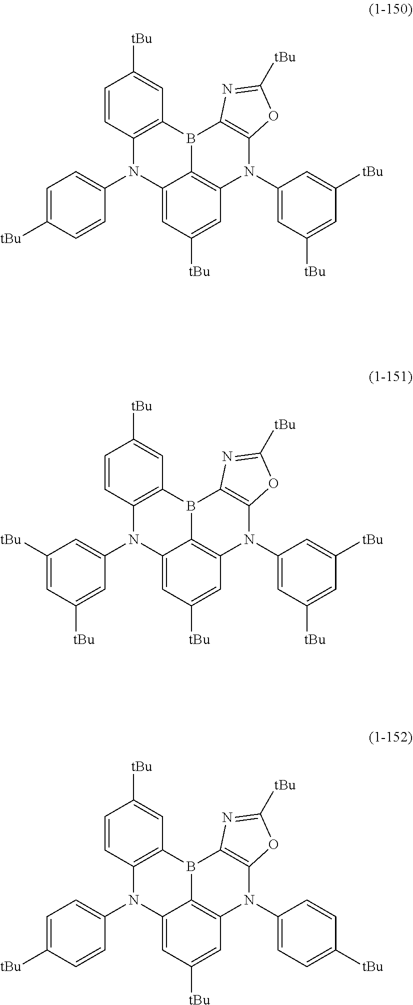 [SMILES: CC(C)(C)c1ccc(N2c3ccc(C(C)(C)C)cc3B3c4nc(C(C)(C)C)oc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(C(C)(C)C)oc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(C(C)(C)C)oc4N(c4ccc(C(C)(C)C)cc4)c4cc(C(C)(C)C)cc2c43)cc1]

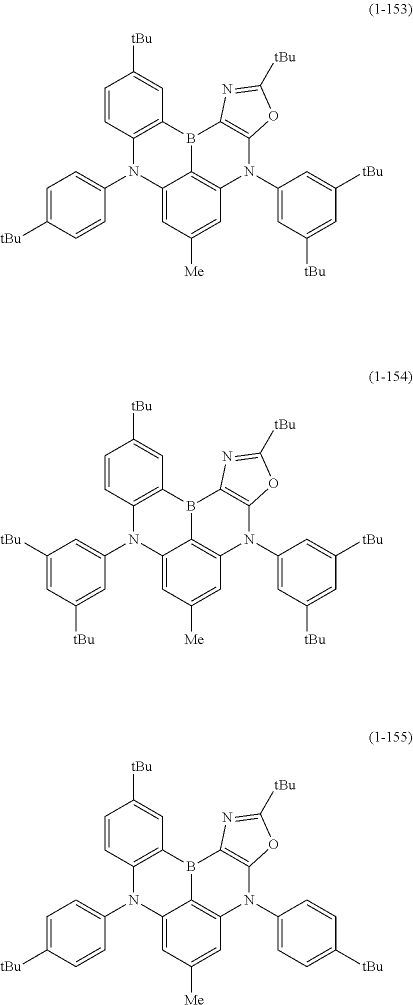 [SMILES: Cc1cc2c3c(c1)N(c1cc(C(C)(C)C)cc(C(C)(C)C)c1)c1oc(C(C)(C)C)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1oc(C(C)(C)C)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1oc(C(C)(C)C)nc1B3c1cc(C(C)(C)C)ccc1N2c1ccc(C(C)(C)C)cc1]

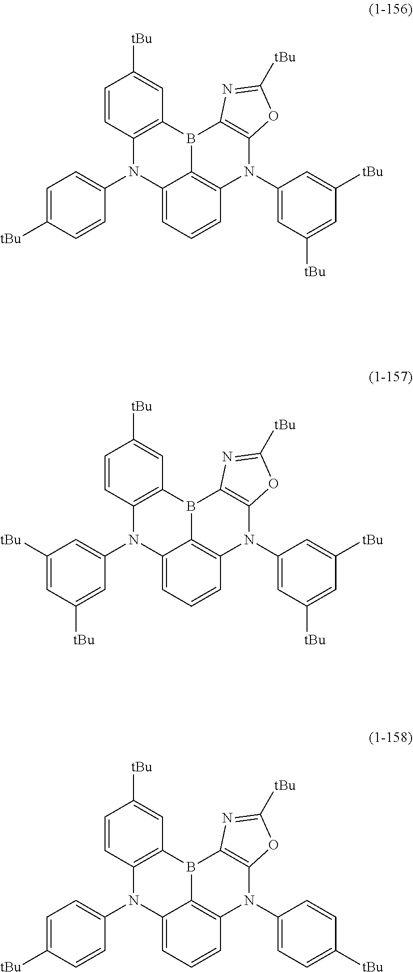 [SMILES: CC(C)(C)c1ccc(N2c3ccc(C(C)(C)C)cc3B3c4nc(C(C)(C)C)oc4N(c4cc(C(C)(C)C)cc(C(C)(C)C)c4)c4cccc2c43)cc1 ; CC(C)(C)c1cc(N2c3ccc(C(C)(C)C)cc3B3c4nc(C(C)(C)C)oc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(C(C)(C)C)oc4N(c4ccc(C(C)(C)C)cc4)c4cccc2c43)cc1]

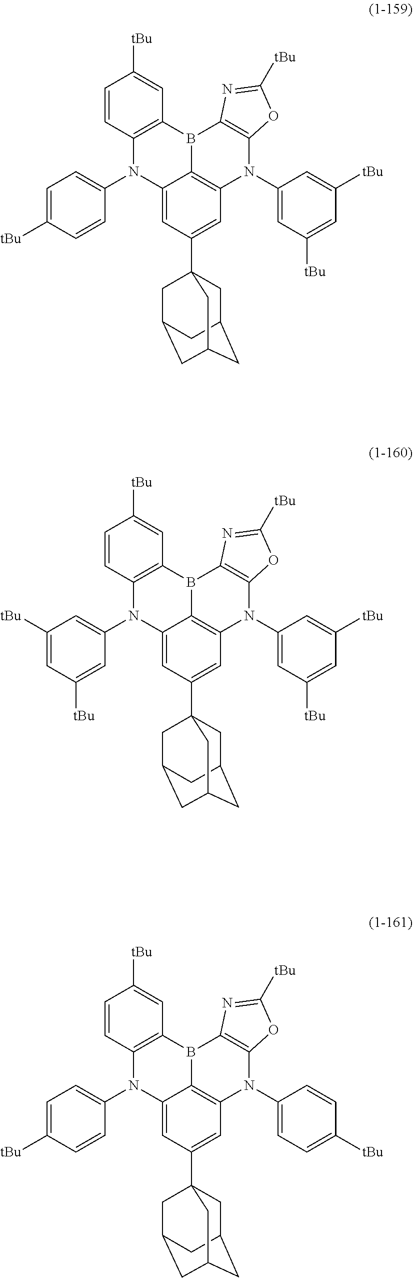 [SMILES: CC(C)(C)c1ccc(N2c3ccc(C(C)(C)C)cc3B3c4nc(C(C)(C)C)oc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(C(C)(C)C)oc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(C(C)(C)C)oc4N(c4ccc(C(C)(C)C)cc4)c4cc(C56CC7CC(CC(C7)C5)C6)cc2c43)cc1]

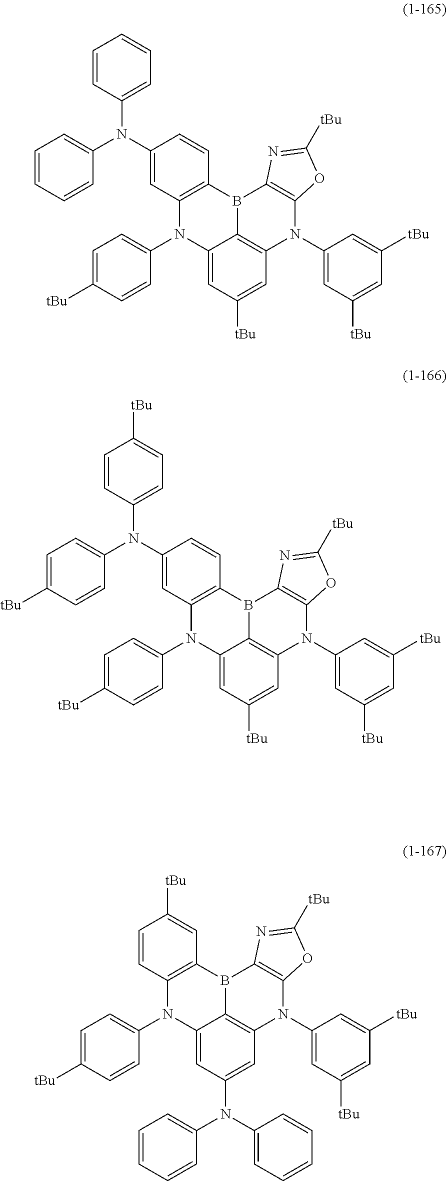 [SMILES: CC(C)(C)c1ccc(N2c3cc(N(c4ccccc4)c4ccccc4)ccc3B3c4nc(C(C)(C)C)oc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2nc(C(C)(C)C)oc2N4c2cc(C(C)(C)C)cc(C(C)(C)C)c2)cc1 ; CC(C)(C)c1ccc(N2c3ccc(C(C)(C)C)cc3B3c4nc(C(C)(C)C)oc4N(c4cc(C(C)(C)C)cc(C(C)(C)C)c4)c4cc(N(c5ccccc5)c5ccccc5)cc2c43)cc1]

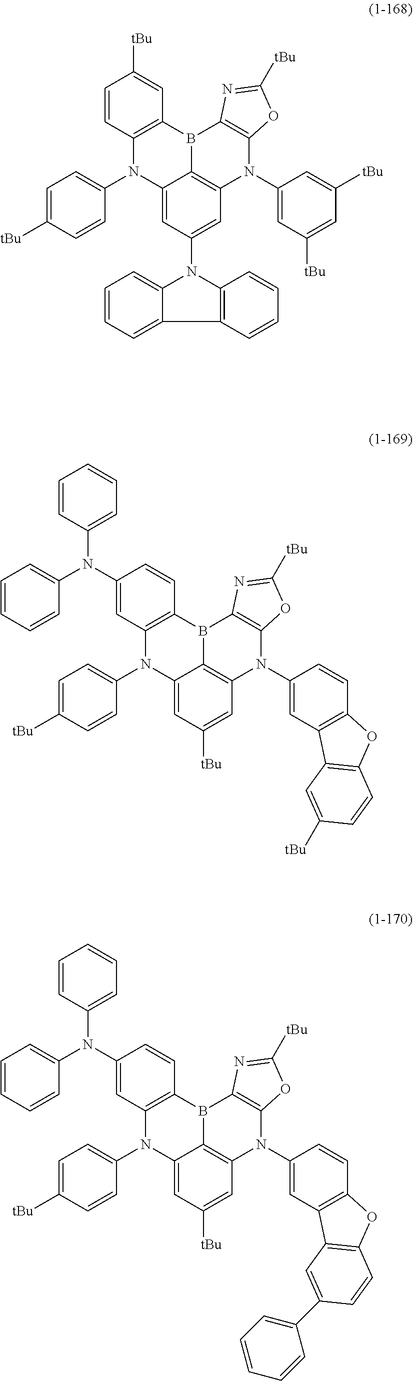 [SMILES: CC(C)(C)c1ccc(N2c3ccc(C(C)(C)C)cc3B3c4nc(C(C)(C)C)oc4N(c4cc(C(C)(C)C)cc(C(C)(C)C)c4)c4cc(-n5c6ccccc6c6ccccc65)cc2c43)cc1 ; CC(C)(C)c1ccc(N2c3cc(N(c4ccccc4)c4ccccc4)ccc3B3c4nc(C(C)(C)C)oc4N(c4ccc5oc6ccc(C(C)(C)C)cc6c5c4)c4cc(C(C)(C)C)cc2c43)cc1 ; CC(C)(C)c1ccc(N2c3cc(N(c4ccccc4)c4ccccc4)ccc3B3c4nc(C(C)(C)C)oc4N(c4ccc5oc6ccc(-c7ccccc7)cc6c5c4)c4cc(C(C)(C)C)cc2c43)cc1]

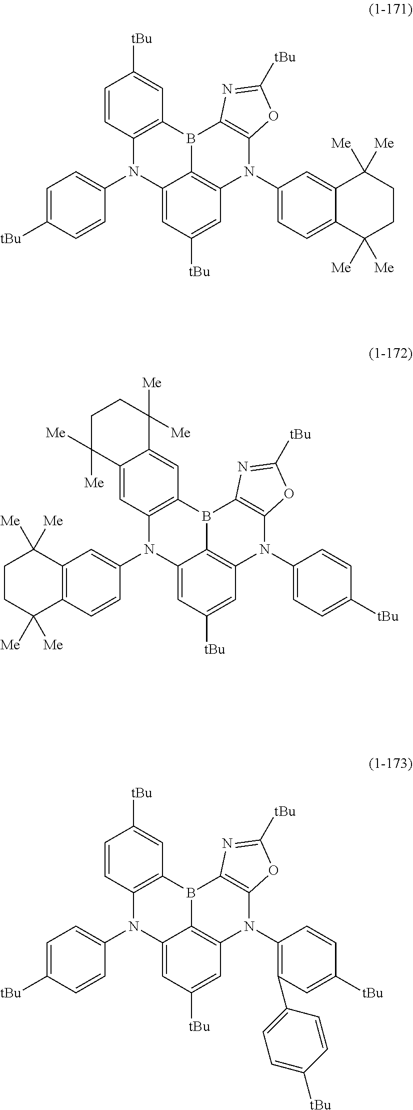 [SMILES: CC(C)(C)c1ccc(N2c3ccc(C(C)(C)C)cc3B3c4nc(C(C)(C)C)oc4N(c4ccc5c(c4)C(C)(C)CCC5(C)C)c4cc(C(C)(C)C)cc2c43)cc1 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3nc(C(C)(C)C)oc32)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(C(C)(C)C)oc32)cc1]

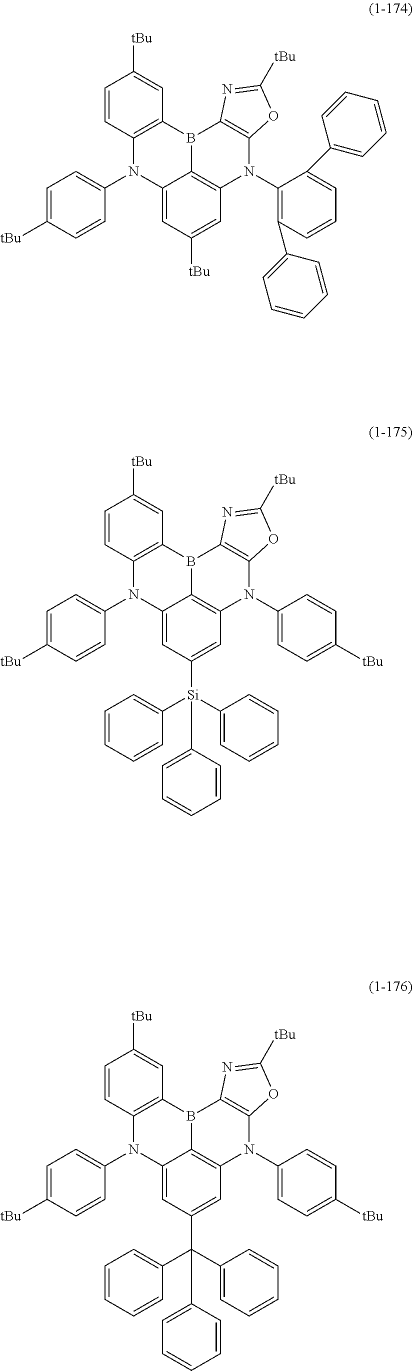 [SMILES: CC(C)(C)c1ccc(N2c3ccc(C(C)(C)C)cc3B3c4nc(C(C)(C)C)oc4N(c4c(-c5ccccc5)cccc4-c4ccccc4)c4cc(C(C)(C)C)cc2c43)cc1 ; CC(C)(C)c1ccc(N2c3ccc(C(C)(C)C)cc3B3c4nc(C(C)(C)C)oc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4nc(C(C)(C)C)oc4N(c4ccc(C(C)(C)C)cc4)c4cc(C(c5ccccc5)(c5ccccc5)c5ccccc5)cc2c43)cc1]

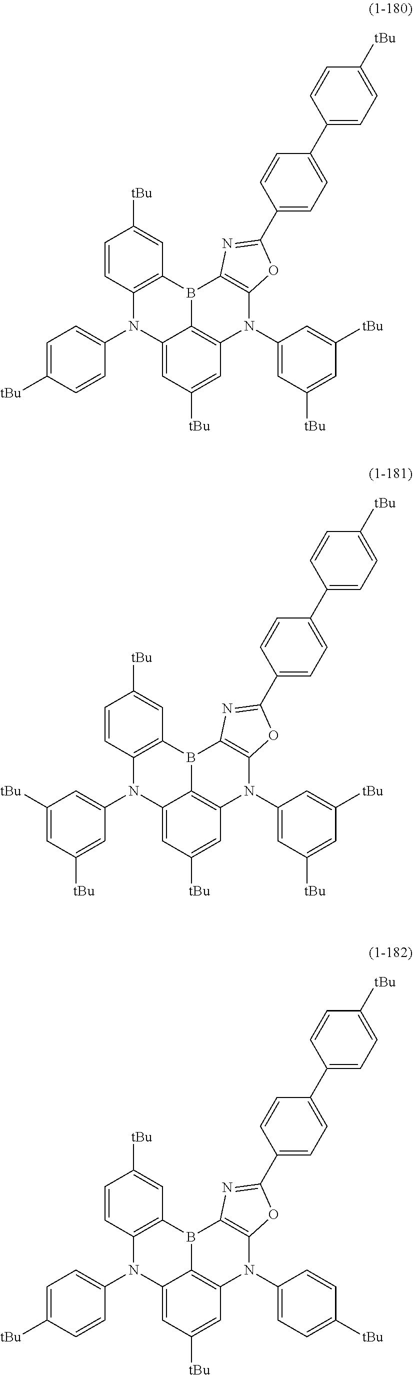 [SMILES: CC(C)(C)c1ccc(-c2ccc(-c3nc4c(o3)N(c3cc(C(C)(C)C)cc(C(C)(C)C)c3)c3cc(C(C)(C)C)cc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3cc(C(C)(C)C)cc(C(C)(C)C)c3)c3cc(C(C)(C)C)cc5c3B4c3cc(C(C)(C)C)ccc3N5c3cc(C(C)(C)C)cc(C(C)(C)C)c3)cc2)cc1 ; CC(C)(C)c1ccc(-c2ccc(-c3nc4c(o3)N(c3ccc(C(C)(C)C)cc3)c3cc(C(C)(C)C)cc5c3B4c3cc(C(C)(C)C)ccc3N5c3ccc(C(C)(C)C)cc3)cc2)cc1]

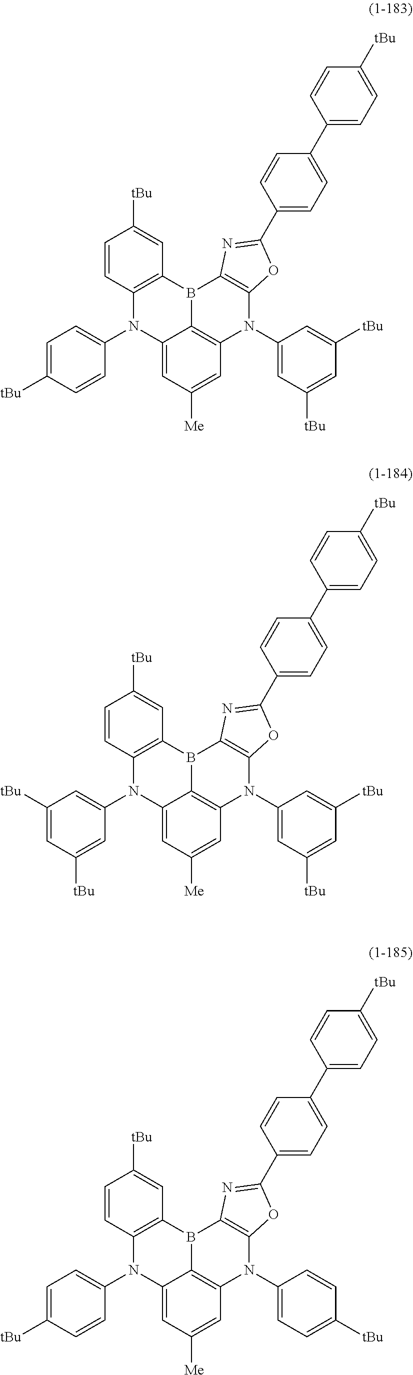 [SMILES: Cc1cc2c3c(c1)N(c1cc(C(C)(C)C)cc(C(C)(C)C)c1)c1oc(-c4ccc(-c5ccc(C(C)(C)C)cc5)cc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1oc(-c4ccc(-c5ccc(C(C)(C)C)cc5)cc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1oc(-c4ccc(-c5ccc(C(C)(C)C)cc5)cc4)nc1B3c1cc(C(C)(C)C)ccc1N2c1ccc(C(C)(C)C)cc1]

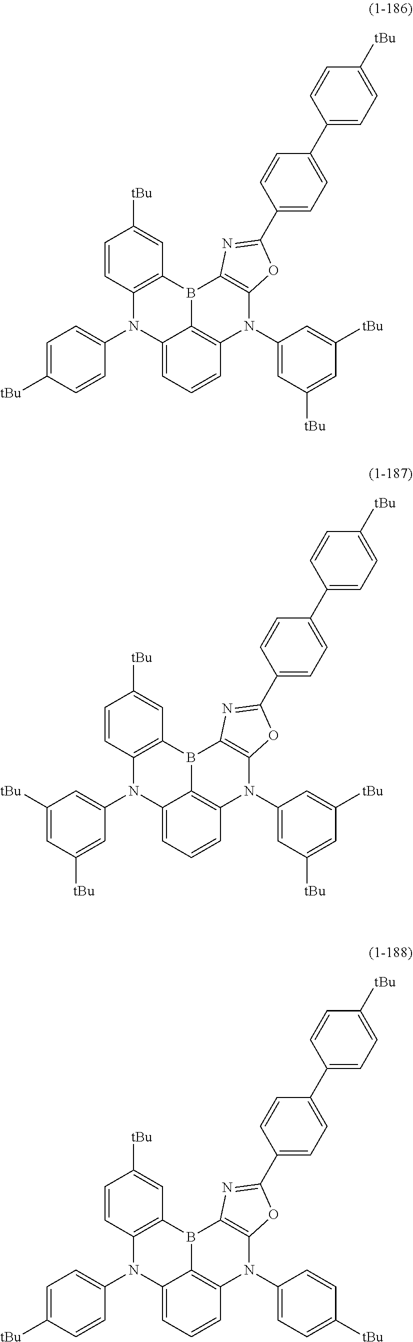 [SMILES: CC(C)(C)c1ccc(-c2ccc(-c3nc4c(o3)N(c3cc(C(C)(C)C)cc(C(C)(C)C)c3)c3cccc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3cc(C(C)(C)C)cc(C(C)(C)C)c3)c3cccc5c3B4c3cc(C(C)(C)C)ccc3N5c3cc(C(C)(C)C)cc(C(C)(C)C)c3)cc2)cc1 ; CC(C)(C)c1ccc(-c2ccc(-c3nc4c(o3)N(c3ccc(C(C)(C)C)cc3)c3cccc5c3B4c3cc(C(C)(C)C)ccc3N5c3ccc(C(C)(C)C)cc3)cc2)cc1]

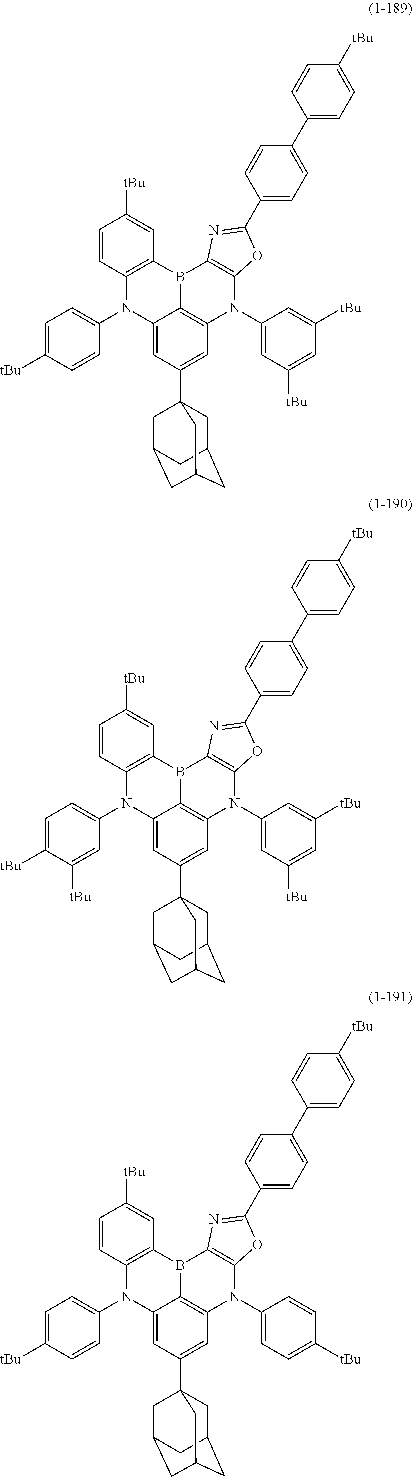 [SMILES: CC(C)(C)c1ccc(-c2ccc(-c3nc4c(o3)N(c3cc(C(C)(C)C)cc(C(C)(C)C)c3)c3cc(C56CC7CC(CC(C7)C5)C6)cc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3cc(C(C)(C)C)cc(C(C)(C)C)c3)c3cc(C56CC7CC(CC(C7)C5)C6)cc5c3B4c3cc(C(C)(C)C)ccc3N5c3ccc(C(C)(C)C)c(C(C)(C)C)c3)cc2)cc1 ; CC(C)(C)c1ccc(-c2ccc(-c3nc4c(o3)N(c3ccc(C(C)(C)C)cc3)c3cc(C56CC7CC(CC(C7)C5)C6)cc5c3B4c3cc(C(C)(C)C)ccc3N5c3ccc(C(C)(C)C)cc3)cc2)cc1]

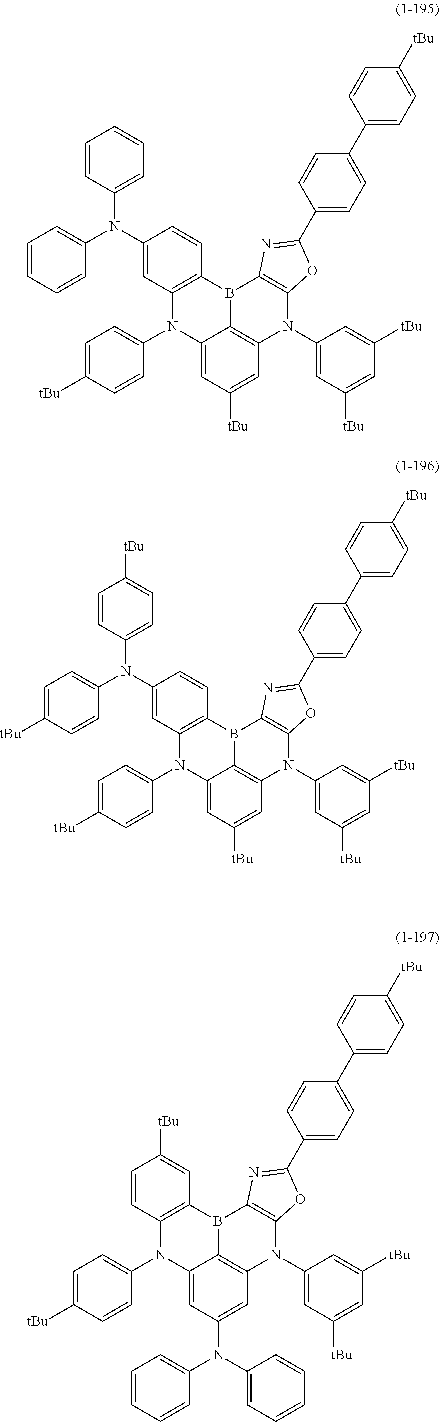 [SMILES: CC(C)(C)c1ccc(-c2ccc(-c3nc4c(o3)N(c3cc(C(C)(C)C)cc(C(C)(C)C)c3)c3cc(C(C)(C)C)cc5c3B4c3ccc(N(c4ccccc4)c4ccccc4)cc3N5c3ccc(C(C)(C)C)cc3)cc2)cc1 ; CC(C)(C)c1ccc(-c2ccc(-c3nc4c(o3)N(c3cc(C(C)(C)C)cc(C(C)(C)C)c3)c3cc(C(C)(C)C)cc5c3B4c3ccc(N(c4ccc(C(C)(C)C)cc4)c4ccc(C(C)(C)C)cc4)cc3N5c3ccc(C(C)(C)C)cc3)cc2)cc1 ; CC(C)(C)c1ccc(-c2ccc(-c3nc4c(o3)N(c3cc(C(C)(C)C)cc(C(C)(C)C)c3)c3cc(N(c5ccccc5)c5ccccc5)cc5c3B4c3cc(C(C)(C)C)ccc3N5c3ccc(C(C)(C)C)cc3)cc2)cc1]

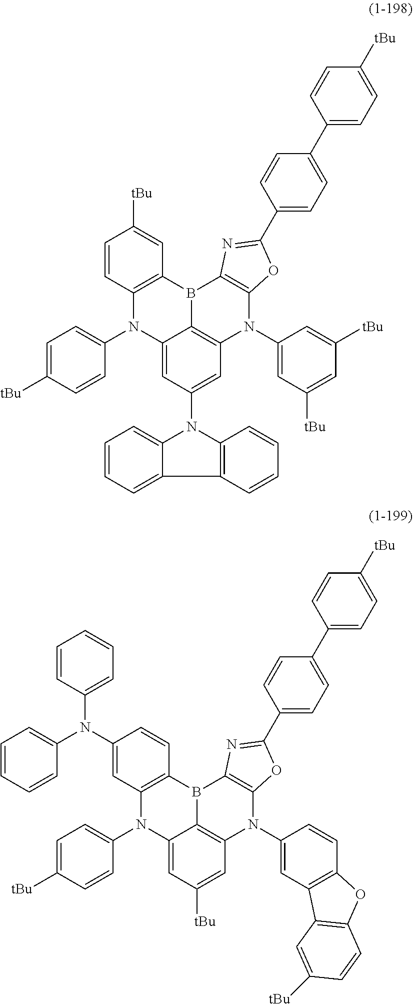 [SMILES: CC(C)(C)c1ccc(-c2ccc(-c3nc4c(o3)N(c3cc(C(C)(C)C)cc(C(C)(C)C)c3)c3cc(-n5c6ccccc6c6ccccc65)cc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3ccc5oc6ccc(C(C)(C)C)cc6c5c3)c3cc(C(C)(C)C)cc5c3B4c3ccc(N(c4ccccc4)c4ccccc4)cc3N5c3ccc(C(C)(C)C)cc3)cc2)cc1]

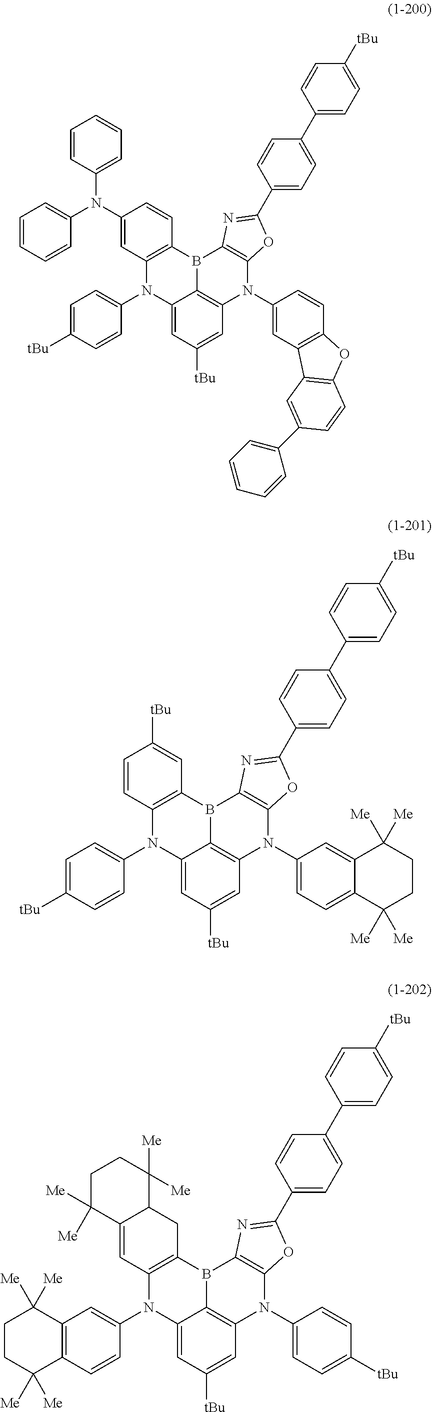 [SMILES: CC(C)(C)c1ccc(-c2ccc(-c3nc4c(o3)N(c3ccc5oc6ccc(-c7ccccc7)cc6c5c3)c3cc(C(C)(C)C)cc5c3B4c3ccc(N(c4ccccc4)c4ccccc4)cc3N5c3ccc(C(C)(C)C)cc3)cc2)cc1 ; CC(C)(C)c1ccc(-c2ccc(-c3nc4c(o3)N(c3ccc5c(c3)C(C)(C)CCC5(C)C)c3cc(C(C)(C)C)cc5c3B4c3cc(C(C)(C)C)ccc3N5c3ccc(C(C)(C)C)cc3)cc2)cc1 ; CC1(C)CCC(C)(C)C2CC3=C(C=C21)N(c1ccc2c(c1)C(C)(C)CCC2(C)C)c1cc(C(C)(C)C)cc2c1B3c1nc(-c3ccc(-c4ccc(C(C)(C)C)cc4)cc3)oc1N2c1ccc(C(C)(C)C)cc1]

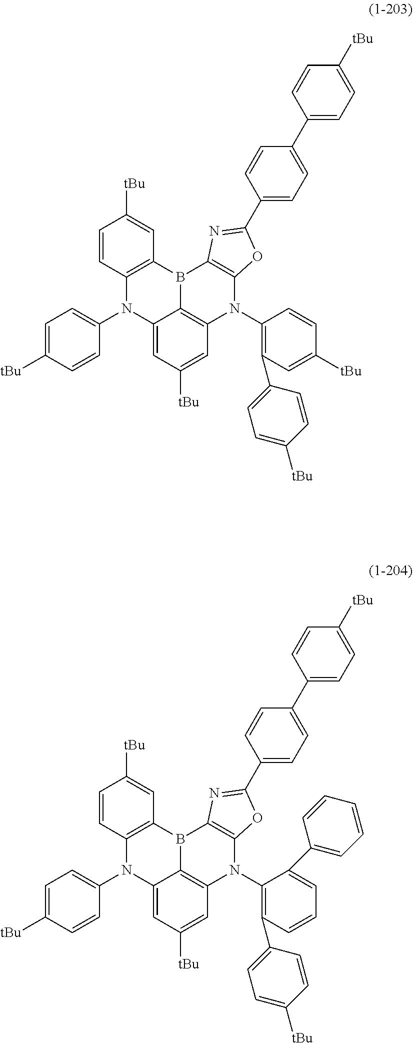 [SMILES: CC(C)(C)c1ccc(-c2ccc(-c3nc4c(o3)N(c3ccc(C(C)(C)C)cc3-c3ccc(C(C)(C)C)cc3)c3cc(C(C)(C)C)cc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3c(-c5ccccc5)cccc3-c3ccc(C(C)(C)C)cc3)c3cc(C(C)(C)C)cc5c3B4c3cc(C(C)(C)C)ccc3N5c3ccc(C(C)(C)C)cc3)cc2)cc1]

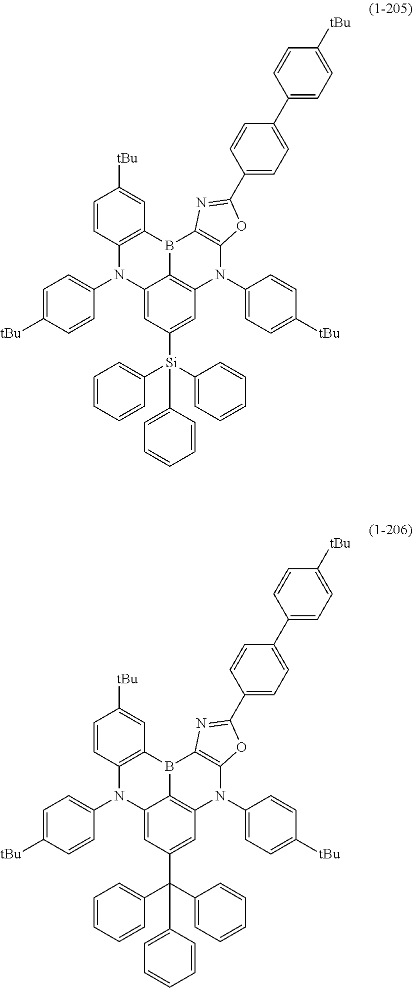 [SMILES: CC(C)(C)c1ccc(-c2ccc(-c3nc4c(o3)N(c3ccc(C(C)(C)C)cc3)c3cc([Si](c5ccccc5)(c5ccccc5)c5ccccc5)cc5c3B4c3cc(C(C)(C)C)ccc3N5c3ccc(C(C)(C)C)cc3)cc2)cc1 ; CC(C)(C)c1ccc(-c2ccc(-c3nc4c(o3)N(c3ccc(C(C)(C)C)cc3)c3cc(C(c5ccccc5)(c5ccccc5)c5ccccc5)cc5c3B4c3cc(C(C)(C)C)ccc3N5c3ccc(C(C)(C)C)cc3)cc2)cc1]

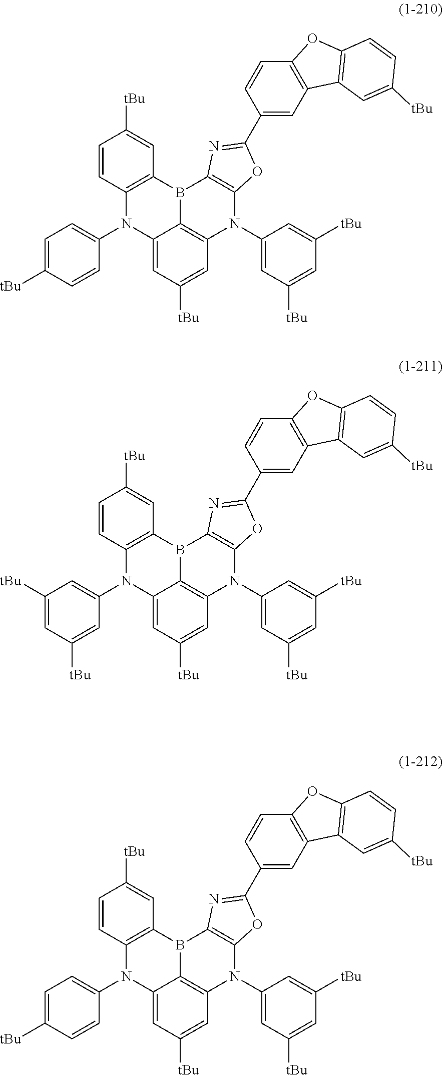 [SMILES: CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(C(C)(C)C)cc2c43)cc1]

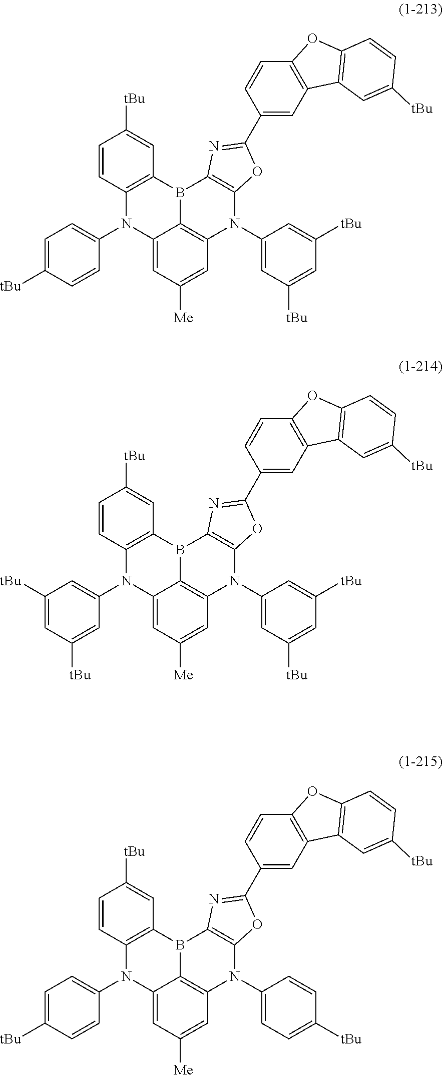 [SMILES: Cc1cc2c3c(c1)N(c1cc(C(C)(C)C)cc(C(C)(C)C)c1)c1oc(-c4ccc5oc6ccc(C(C)(C)C)cc6c5c4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1oc(-c4ccc5oc6ccc(C(C)(C)C)cc6c5c4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1oc(-c4ccc5oc6ccc(C(C)(C)C)cc6c5c4)nc1B3c1cc(C(C)(C)C)ccc1N2c1ccc(C(C)(C)C)cc1]

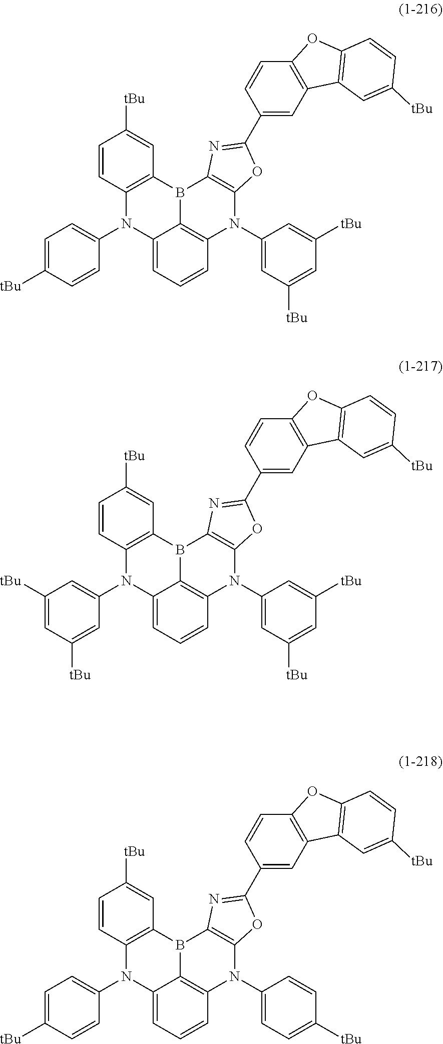 [SMILES: CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cccc2c43)cc1 ; CC(C)(C)c1cc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)oc4N(c4ccc(C(C)(C)C)cc4)c4cccc2c43)cc1]

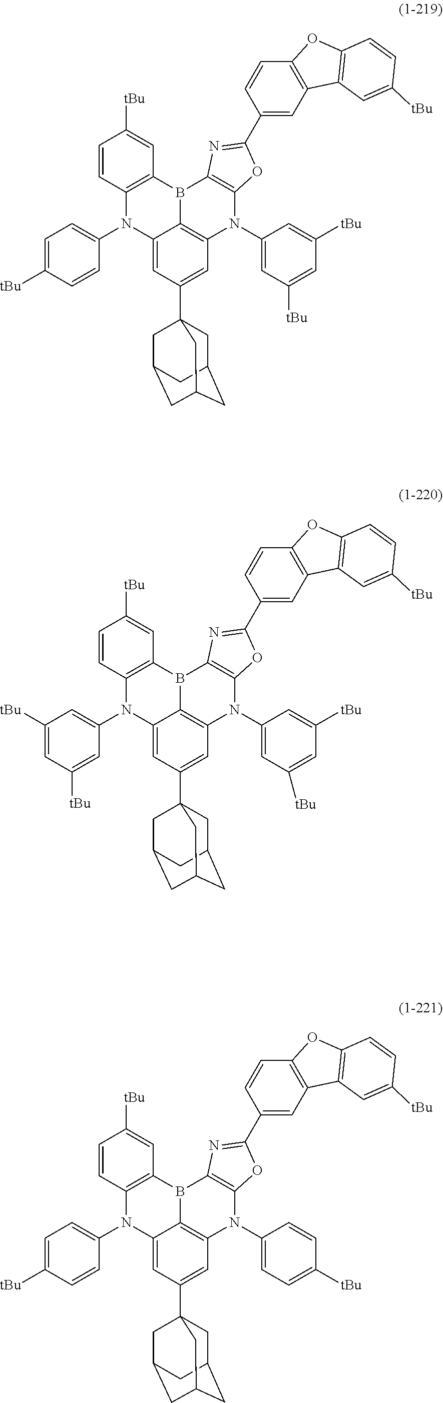 [SMILES: CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(-c5ccc6oc7ccc(C(C)(C)C)cc7c6c5)oc4N(c4ccc(C(C)(C)C)cc4)c4cc(C56CC7CC(CC(C7)C5)C6)cc2c43)cc1]

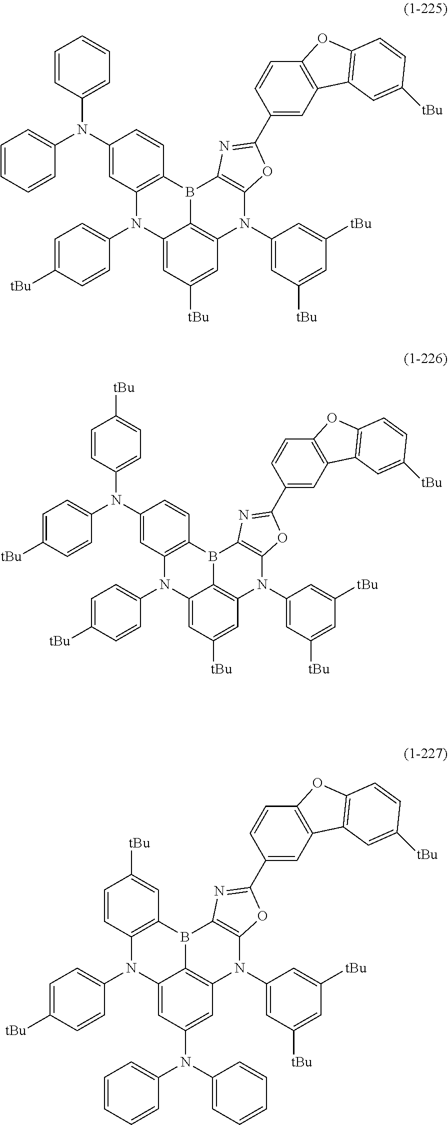 [SMILES: CC(C)(C)c1ccc(N2c3cc(N(c4ccccc4)c4ccccc4)ccc3B3c4nc(-c5ccc6oc7ccc(C(C)(C)C)cc7c6c5)oc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2nc(-c3ccc5oc6ccc(C(C)(C)C)cc6c5c3)oc2N4c2cc(C(C)(C)C)cc(C(C)(C)C)c2)cc1 ; CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(N(c5ccccc5)c5ccccc5)cc2c43)cc1]

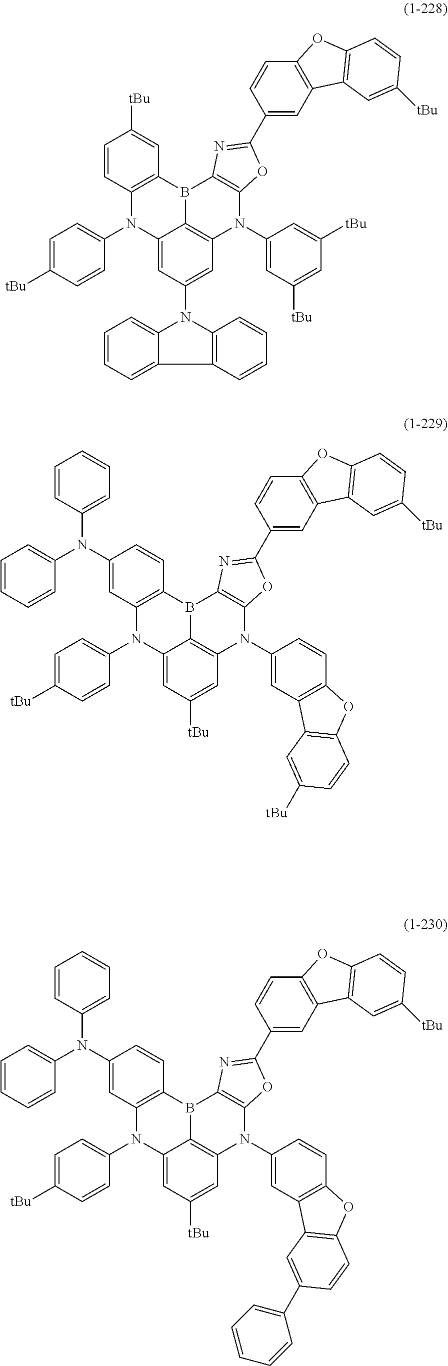 [SMILES: CC(C)(C)c1ccc(N2c3ccc(C(C)(C)C)cc3B3c4nc(-c5ccc6oc7ccc(C(C)(C)C)cc7c6c5)oc4N(c4cc(C(C)(C)C)cc(C(C)(C)C)c4)c4cc(-n5c6ccccc6c6ccccc65)cc2c43)cc1 ; CC(C)(C)c1ccc(N2c3cc(N(c4ccccc4)c4ccccc4)ccc3B3c4nc(-c5ccc6oc7ccc(C(C)(C)C)cc7c6c5)oc4N(c4ccc5oc6ccc(C(C)(C)C)cc6c5c4)c4cc(C(C)(C)C)cc2c43)cc1 ; CC(C)(C)c1ccc(N2c3cc(N(c4ccccc4)c4ccccc4)ccc3B3c4nc(-c5ccc6oc7ccc(C(C)(C)C)cc7c6c5)oc4N(c4ccc5oc6ccc(-c7ccccc7)cc6c5c4)c4cc(C(C)(C)C)cc2c43)cc1]

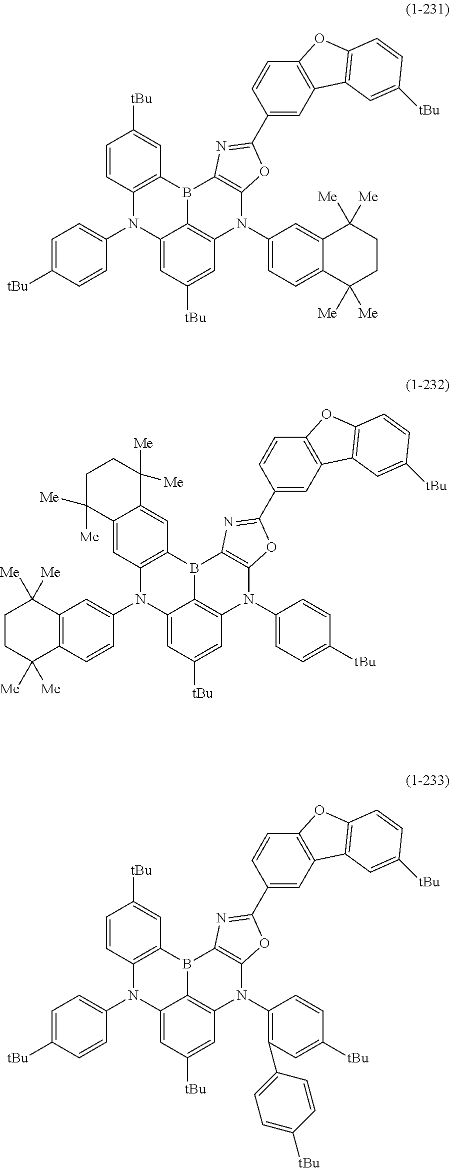 [SMILES: CC(C)(C)c1ccc(N2c3ccc(C(C)(C)C)cc3B3c4nc(-c5ccc6oc7ccc(C(C)(C)C)cc7c6c5)oc4N(c4ccc5c(c4)C(C)(C)CCC5(C)C)c4cc(C(C)(C)C)cc2c43)cc1 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3nc(-c4ccc5oc6ccc(C(C)(C)C)cc6c5c4)oc32)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(-c4ccc5oc6ccc(C(C)(C)C)cc6c5c4)oc32)cc1]

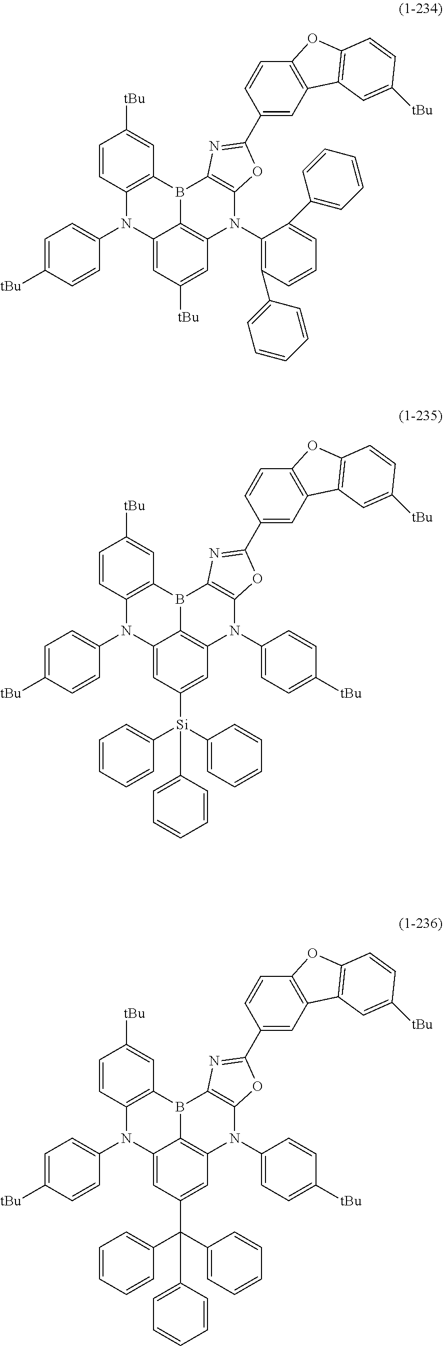 [SMILES: CC(C)(C)c1ccc(N2c3ccc(C(C)(C)C)cc3B3c4nc(-c5ccc6oc7ccc(C(C)(C)C)cc7c6c5)oc4N(c4c(-c5ccccc5)cccc4-c4ccccc4)c4cc(C(C)(C)C)cc2c43)cc1 ; CC(C)(C)c1ccc(N2c3ccc(C(C)(C)C)cc3B3c4nc(-c5ccc6oc7ccc(C(C)(C)C)cc7c6c5)oc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4nc(-c5ccc6oc7ccc(C(C)(C)C)cc7c6c5)oc4N(c4ccc(C(C)(C)C)cc4)c4cc(C(c5ccccc5)(c5ccccc5)c5ccccc5)cc2c43)cc1]

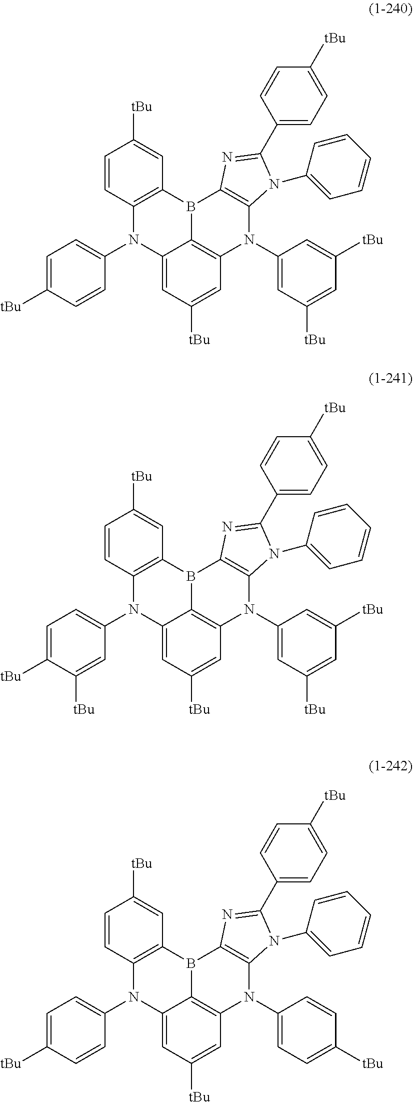 [SMILES: CC(C)(C)c1ccc(-c2nc3c(n2-c2ccccc2)N(c2cc(C(C)(C)C)cc(C(C)(C)C)c2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2cc(C(C)(C)C)cc(C(C)(C)C)c2)c2cc(C(C)(C)C)cc4c2B3c2cc(C(C)(C)C)ccc2N4c2ccc(C(C)(C)C)c(C(C)(C)C)c2)cc1 ; CC(C)(C)c1ccc(-c2nc3c(n2-c2ccccc2)N(c2ccc(C(C)(C)C)cc2)c2cc(C(C)(C)C)cc4c2B3c2cc(C(C)(C)C)ccc2N4c2ccc(C(C)(C)C)cc2)cc1]

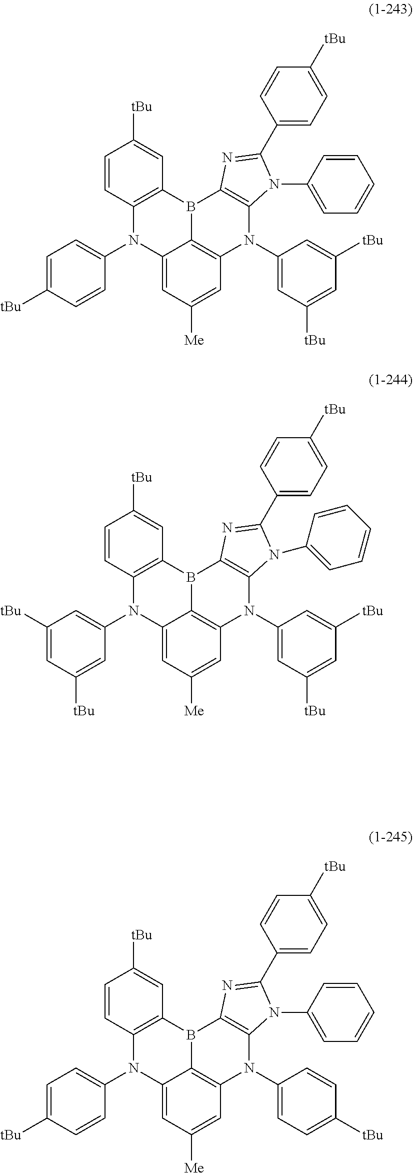 [SMILES: Cc1cc2c3c(c1)N(c1cc(C(C)(C)C)cc(C(C)(C)C)c1)c1c(nc(-c4ccc(C(C)(C)C)cc4)n1-c1ccccc1)B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1c(nc(-c4ccc(C(C)(C)C)cc4)n1-c1ccccc1)B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1c(nc(-c4ccc(C(C)(C)C)cc4)n1-c1ccccc1)B3c1cc(C(C)(C)C)ccc1N2c1ccc(C(C)(C)C)cc1]

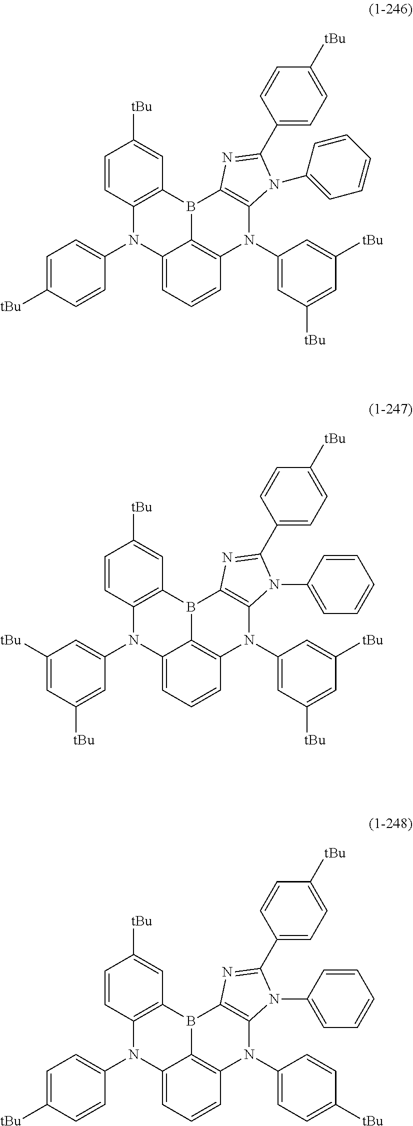 [SMILES: CC(C)(C)c1ccc(-c2nc3c(n2-c2ccccc2)N(c2cc(C(C)(C)C)cc(C(C)(C)C)c2)c2cccc4c2B3c2cc(C(C)(C)C)ccc2N4c2ccc(C(C)(C)C)cc2)cc1 ; CC(C)(C)c1ccc(-c2nc3c(n2-c2ccccc2)N(c2cc(C(C)(C)C)cc(C(C)(C)C)c2)c2cccc4c2B3c2cc(C(C)(C)C)ccc2N4c2cc(C(C)(C)C)cc(C(C)(C)C)c2)cc1 ; CC(C)(C)c1ccc(-c2nc3c(n2-c2ccccc2)N(c2ccc(C(C)(C)C)cc2)c2cccc4c2B3c2cc(C(C)(C)C)ccc2N4c2ccc(C(C)(C)C)cc2)cc1]

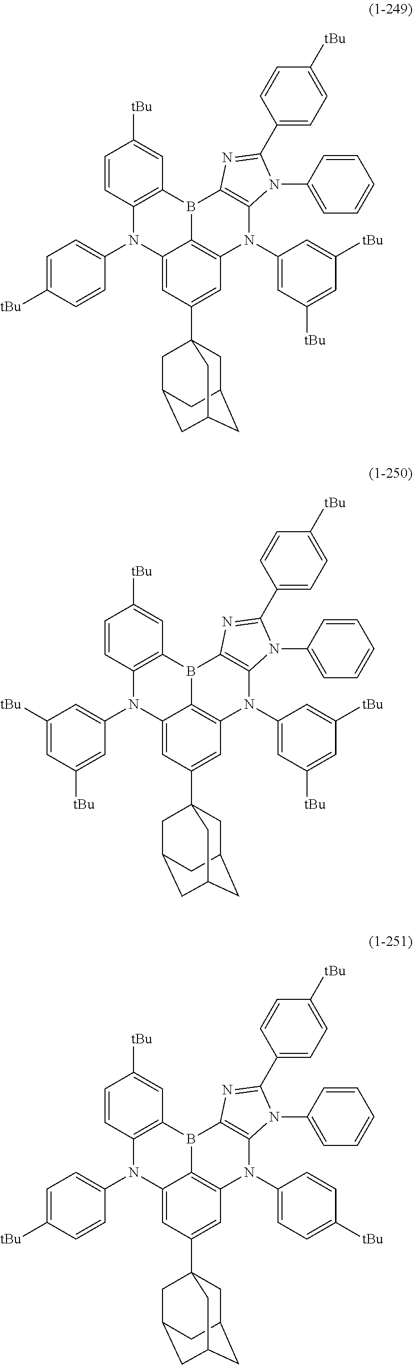 [SMILES: CC(C)(C)c1ccc(-c2nc3c(n2-c2ccccc2)N(c2cc(C(C)(C)C)cc(C(C)(C)C)c2)c2cc(C45CC6CC(CC(C6)C4)C5)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2cc(C(C)(C)C)cc(C(C)(C)C)c2)c2cc(C45CC6CC(CC(C6)C4)C5)cc4c2B3c2cc(C(C)(C)C)ccc2N4c2cc(C(C)(C)C)cc(C(C)(C)C)c2)cc1 ; CC(C)(C)c1ccc(-c2nc3c(n2-c2ccccc2)N(c2ccc(C(C)(C)C)cc2)c2cc(C45CC6CC(CC(C6)C4)C5)cc4c2B3c2cc(C(C)(C)C)ccc2N4c2ccc(C(C)(C)C)cc2)cc1]

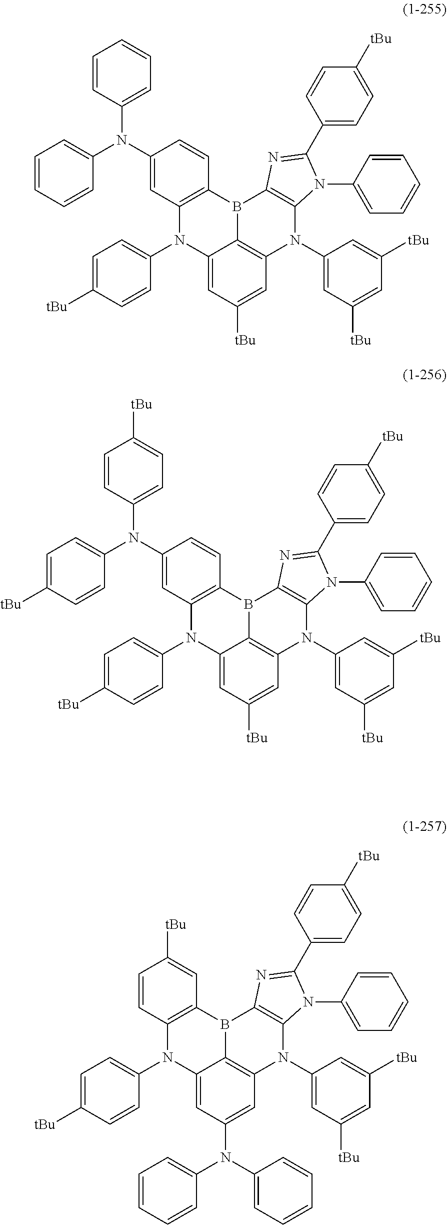 [SMILES: CC(C)(C)c1ccc(-c2nc3c(n2-c2ccccc2)N(c2cc(C(C)(C)C)cc(C(C)(C)C)c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(n2-c2ccccc2)N(c2cc(C(C)(C)C)cc(C(C)(C)C)c2)c2cc(C(C)(C)C)cc4c2B3c2ccc(N(c3ccc(C(C)(C)C)cc3)c3ccc(C(C)(C)C)cc3)cc2N4c2ccc(C(C)(C)C)cc2)cc1 ; CC(C)(C)c1ccc(-c2nc3c(n2-c2ccccc2)N(c2cc(C(C)(C)C)cc(C(C)(C)C)c2)c2cc(N(c4ccccc4)c4ccccc4)cc4c2B3c2cc(C(C)(C)C)ccc2N4c2ccc(C(C)(C)C)cc2)cc1]

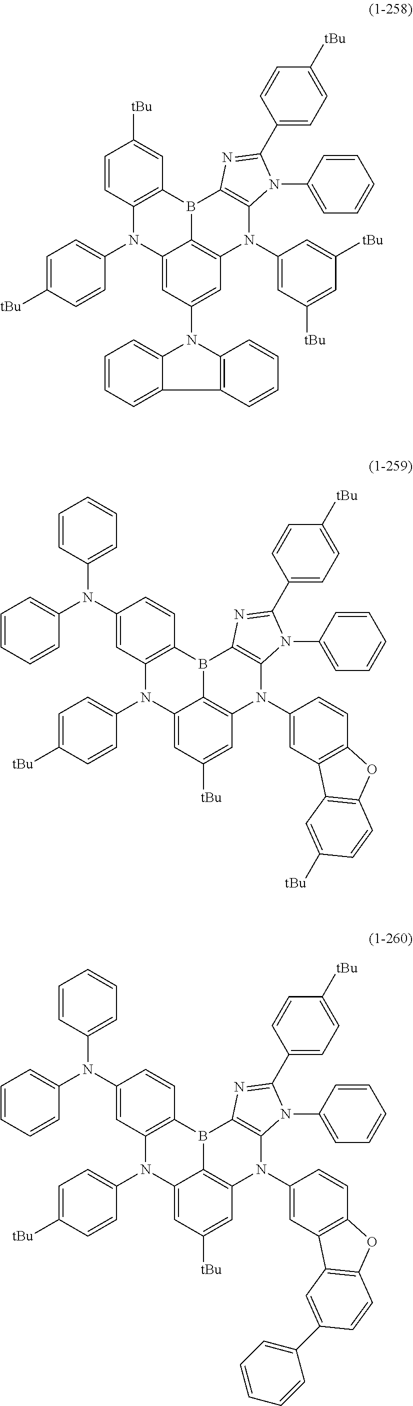 [SMILES: CC(C)(C)c1ccc(-c2nc3c(n2-c2ccccc2)N(c2cc(C(C)(C)C)cc(C(C)(C)C)c2)c2cc(-n4c5ccccc5c5ccccc54)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2ccc4oc5ccc(C(C)(C)C)cc5c4c2)c2cc(C(C)(C)C)cc4c2B3c2ccc(N(c3ccccc3)c3ccccc3)cc2N4c2ccc(C(C)(C)C)cc2)cc1 ; CC(C)(C)c1ccc(-c2nc3c(n2-c2ccccc2)N(c2ccc4oc5ccc(-c6ccccc6)cc5c4c2)c2cc(C(C)(C)C)cc4c2B3c2ccc(N(c3ccccc3)c3ccccc3)cc2N4c2ccc(C(C)(C)C)cc2)cc1]

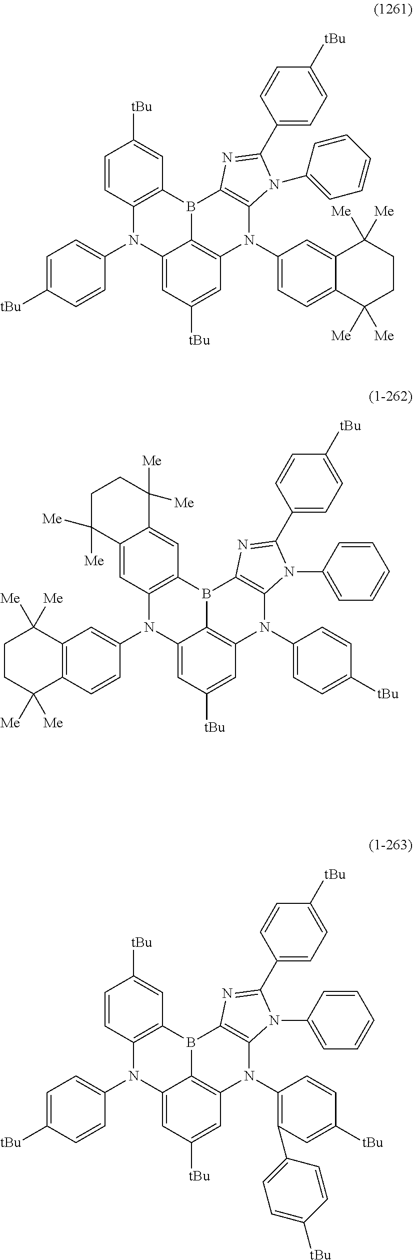 [SMILES: CC(C)(C)c1ccc(-c2nc3c(n2-c2ccccc2)N(c2ccc4c(c2)C(C)(C)CCC4(C)C)c2cc(C(C)(C)C)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2ccc(C(C)(C)C)cc2)c2cc(C(C)(C)C)cc4c2B3c2cc3c(cc2N4c2ccc4c(c2)C(C)(C)CCC4(C)C)C(C)(C)CCC3(C)C)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(-c4ccc(C(C)(C)C)cc4)n(-c4ccccc4)c32)cc1]

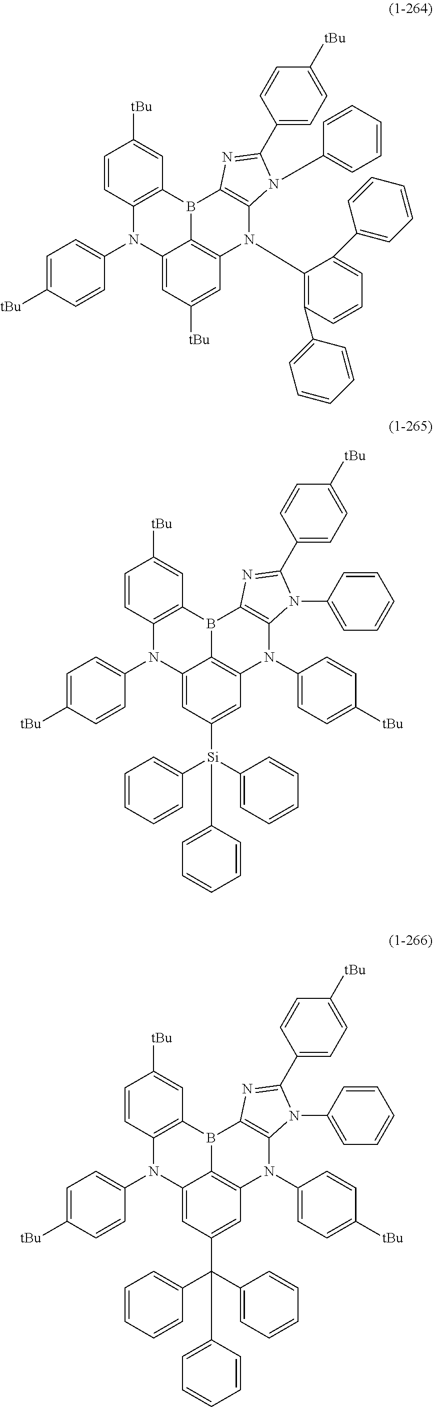 [SMILES: CC(C)(C)c1ccc(-c2nc3c(n2-c2ccccc2)N(c2c(-c4ccccc4)cccc2-c2ccccc2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2ccc(C(C)(C)C)cc2)c2cc([Si](c4ccccc4)(c4ccccc4)c4ccccc4)cc4c2B3c2cc(C(C)(C)C)ccc2N4c2ccc(C(C)(C)C)cc2)cc1 ; CC(C)(C)c1ccc(-c2nc3c(n2-c2ccccc2)N(c2ccc(C(C)(C)C)cc2)c2cc(C(c4ccccc4)(c4ccccc4)c4ccccc4)cc4c2B3c2cc(C(C)(C)C)ccc2N4c2ccc(C(C)(C)C)cc2)cc1]

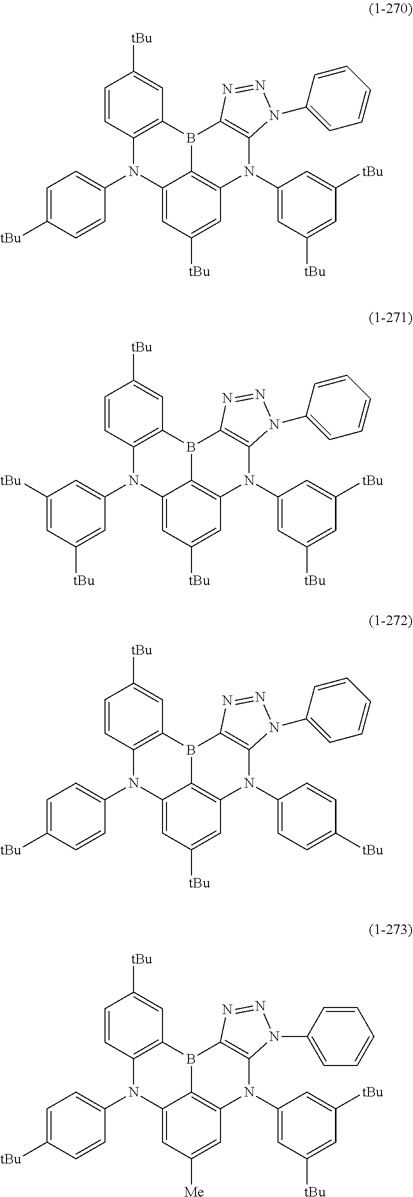 [SMILES: CC(C)(C)c1ccc(N2c3ccc(C(C)(C)C)cc3B3c4nnn(-c5ccccc5)c4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nnn(-c5ccccc5)c4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nnn(-c5ccccc5)c4N(c4ccc(C(C)(C)C)cc4)c4cc(C(C)(C)C)cc2c43)cc1 ; Cc1cc2c3c(c1)N(c1cc(C(C)(C)C)cc(C(C)(C)C)c1)c1c(nnn1-c1ccccc1)B3c1cc(C(C)(C)C)ccc1N2c1ccc(C(C)(C)C)cc1]

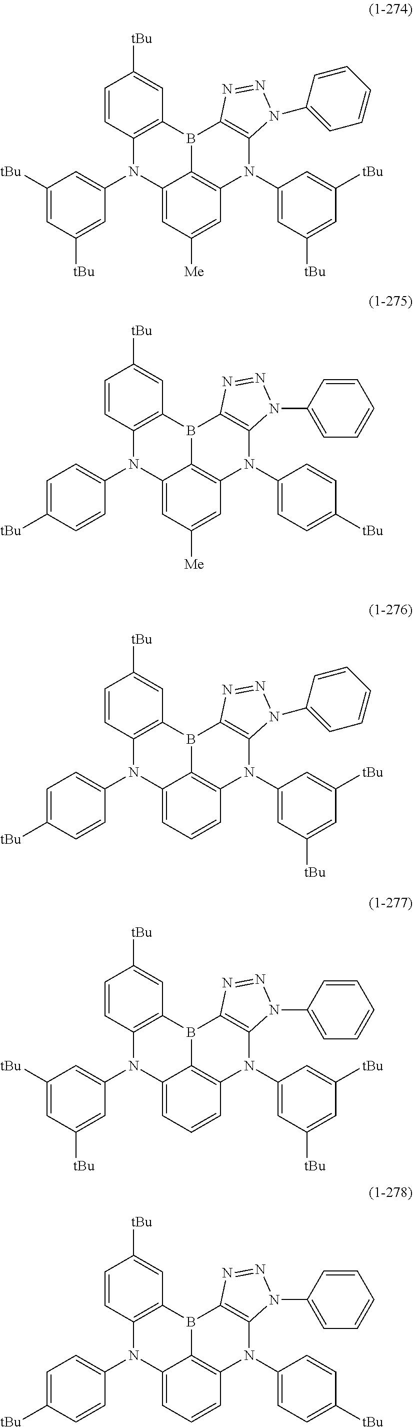

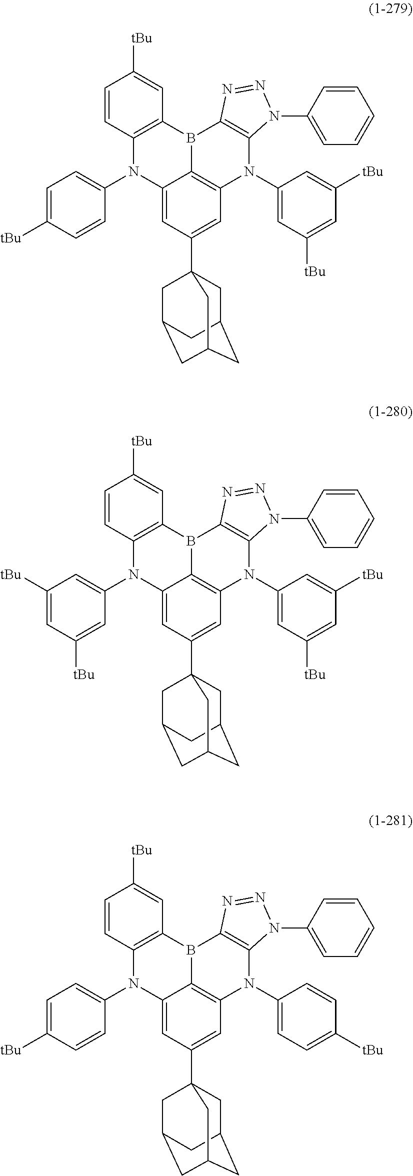 [SMILES: CC(C)(C)c1ccc(N2c3ccc(C(C)(C)C)cc3B3c4nnn(-c5ccccc5)c4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nnn(-c5ccccc5)c4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nnn(-c5ccccc5)c4N(c4ccc(C(C)(C)C)cc4)c4cc(C56CC7CC(CC(C7)C5)C6)cc2c43)cc1]

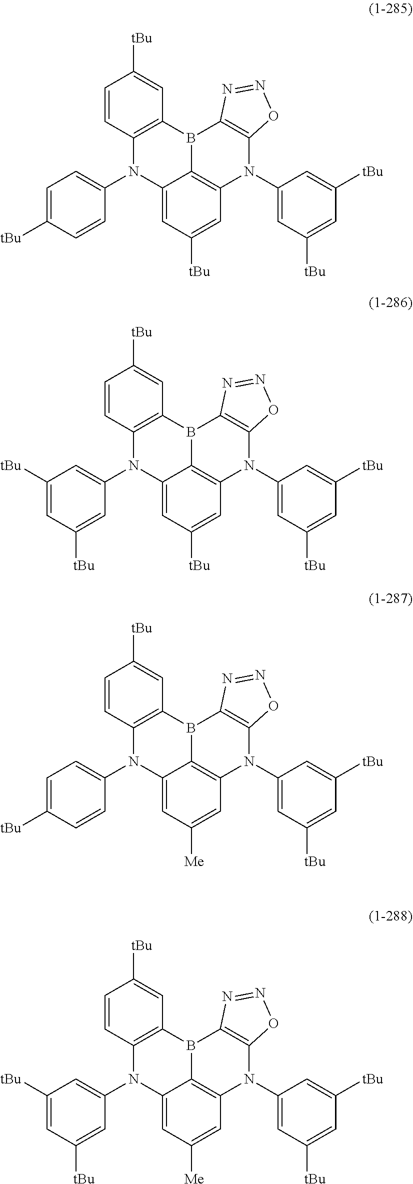 [SMILES: CC(C)(C)c1ccc(N2c3ccc(C(C)(C)C)cc3B3c4nnoc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nnoc4N(c4cc(C(C)(C)C)cc(C(C)(C)C)c4)c4cc(C(C)(C)C)cc2c43)cc(C(C)(C)C)c1 ; Cc1cc2c3c(c1)N(c1cc(C(C)(C)C)cc(C(C)(C)C)c1)c1onnc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1onnc1B3c1cc(C(C)(C)C)ccc1N2c1cc(C(C)(C)C)cc(C(C)(C)C)c1]

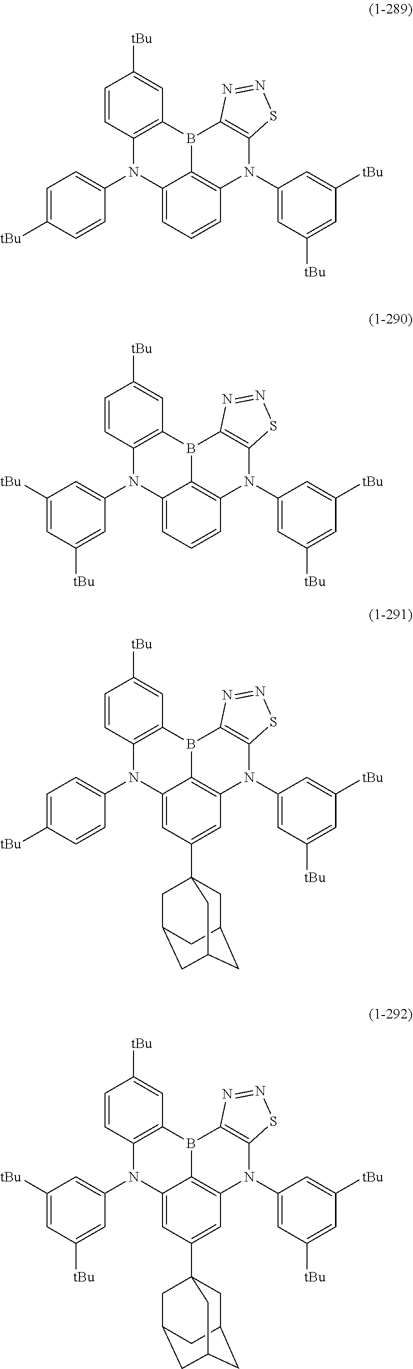 [SMILES: CC(C)(C)c1ccc(N2c3ccc(C(C)(C)C)cc3B3c4nnsc4N(c4cc(C(C)(C)C)cc(C(C)(C)C)c4)c4cccc2c43)cc1 ; CC(C)(C)c1cc(N2c3ccc(C(C)(C)C)cc3B3c4nnsc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nnsc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nnsc4N(c4cc(C(C)(C)C)cc(C(C)(C)C)c4)c4cc(C56CC7CC(CC(C7)C5)C6)cc2c43)cc(C(C)(C)C)c1]

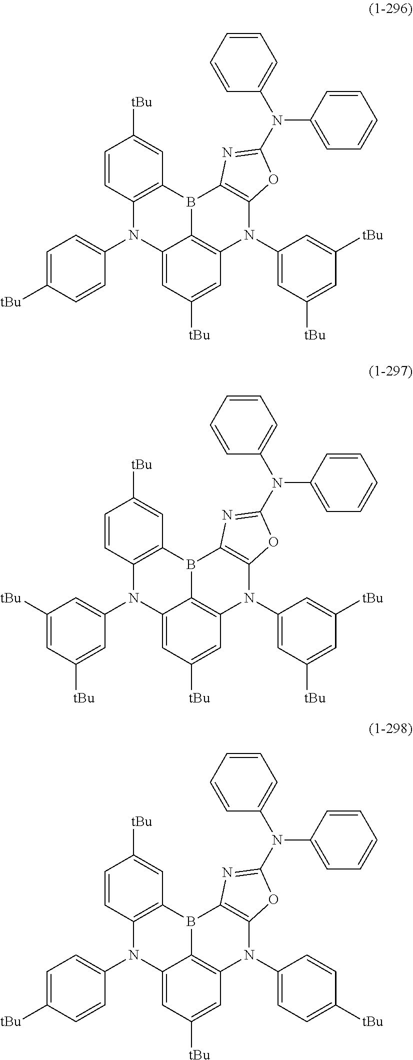 [SMILES: CC(C)(C)c1ccc(N2c3ccc(C(C)(C)C)cc3B3c4nc(N(c5ccccc5)c5ccccc5)oc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(N(c5ccccc5)c5ccccc5)oc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(N(c5ccccc5)c5ccccc5)oc4N(c4ccc(C(C)(C)C)cc4)c4cc(C(C)(C)C)cc2c43)cc1]

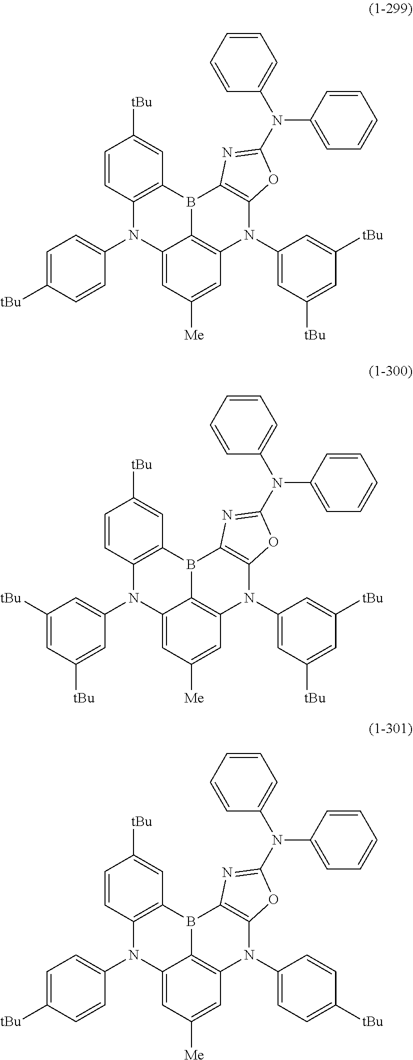 [SMILES: Cc1cc2c3c(c1)N(c1cc(C(C)(C)C)cc(C(C)(C)C)c1)c1oc(N(c4ccccc4)c4ccccc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1oc(N(c4ccccc4)c4ccccc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1oc(N(c4ccccc4)c4ccccc4)nc1B3c1cc(C(C)(C)C)ccc1N2c1ccc(C(C)(C)C)cc1]

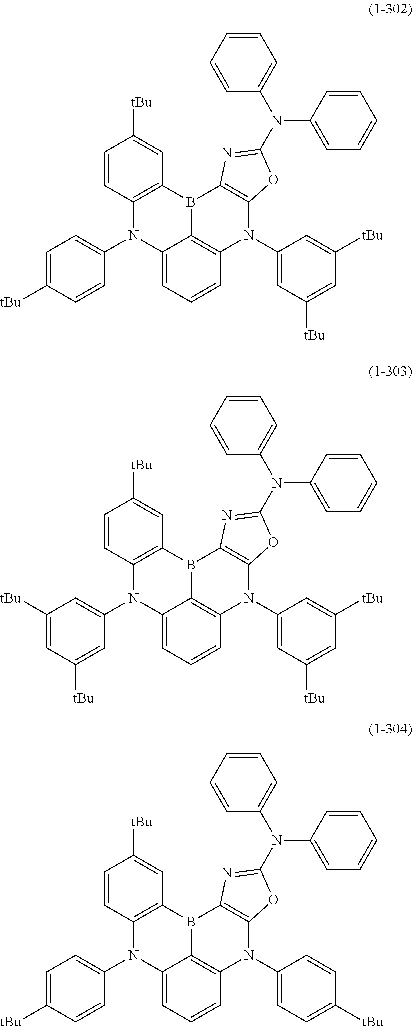 [SMILES: CC(C)(C)c1ccc(N2c3ccc(C(C)(C)C)cc3B3c4nc(N(c5ccccc5)c5ccccc5)oc4N(c4cc(C(C)(C)C)cc(C(C)(C)C)c4)c4cccc2c43)cc1 ; CC(C)(C)c1cc(N2c3ccc(C(C)(C)C)cc3B3c4nc(N(c5ccccc5)c5ccccc5)oc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(N(c5ccccc5)c5ccccc5)oc4N(c4ccc(C(C)(C)C)cc4)c4cccc2c43)cc1]

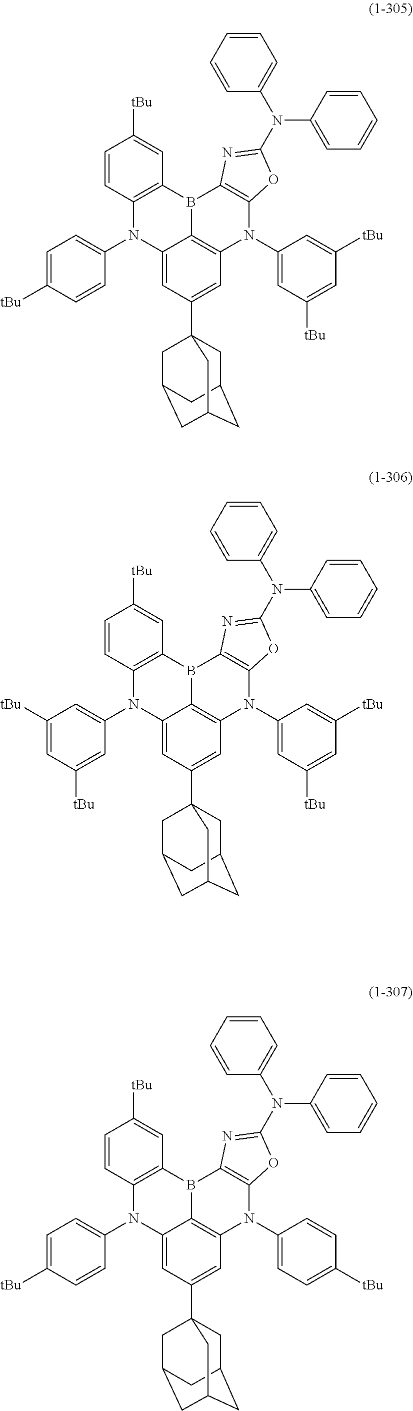 [SMILES: CC(C)(C)c1ccc(N2c3ccc(C(C)(C)C)cc3B3c4nc(N(c5ccccc5)c5ccccc5)oc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(N(c5ccccc5)c5ccccc5)oc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(N(c5ccccc5)c5ccccc5)oc4N(c4ccc(C(C)(C)C)cc4)c4cc(C56CC7CC(CC(C7)C5)C6)cc2c43)cc1]

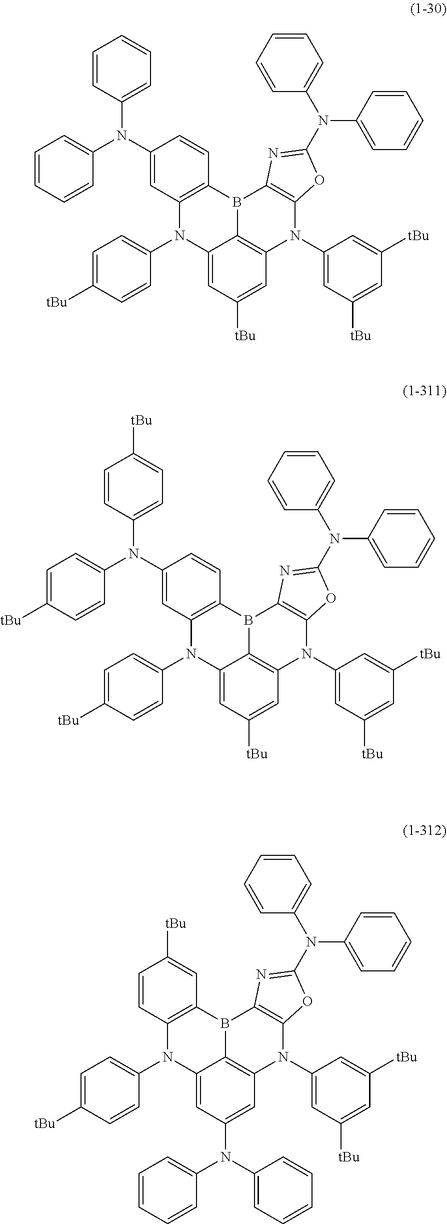 [SMILES: CC(C)(C)c1ccc(N2c3cc(N(c4ccccc4)c4ccccc4)ccc3B3c4nc(N(c5ccccc5)c5ccccc5)oc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2nc(N(c3ccccc3)c3ccccc3)oc2N4c2cc(C(C)(C)C)cc(C(C)(C)C)c2)cc1 ; CC(C)(C)c1ccc(N2c3ccc(C(C)(C)C)cc3B3c4nc(N(c5ccccc5)c5ccccc5)oc4N(c4cc(C(C)(C)C)cc(C(C)(C)C)c4)c4cc(N(c5ccccc5)c5ccccc5)cc2c43)cc1]

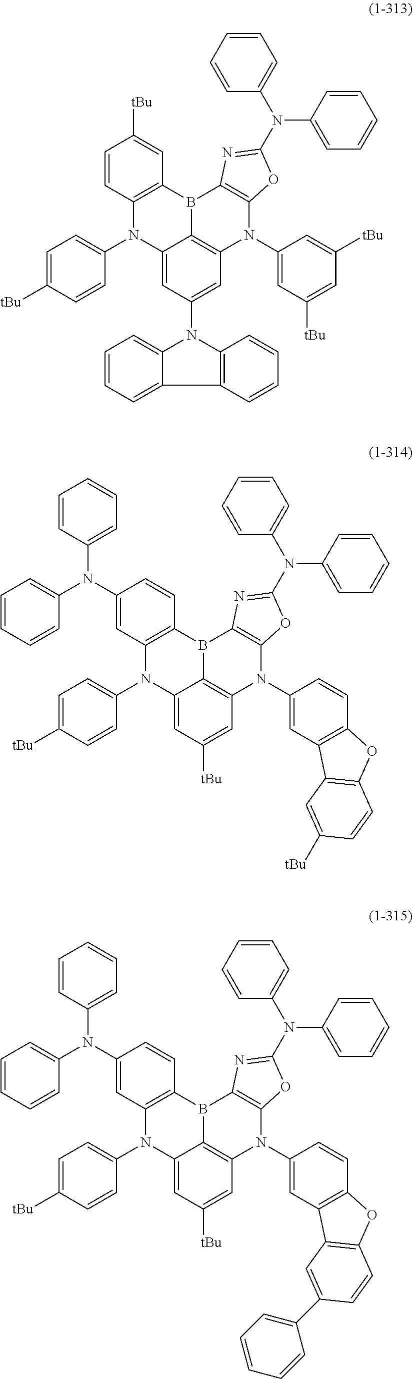 [SMILES: CC(C)(C)c1ccc(N2c3ccc(C(C)(C)C)cc3B3c4nc(N(c5ccccc5)c5ccccc5)oc4N(c4cc(C(C)(C)C)cc(C(C)(C)C)c4)c4cc(-n5c6ccccc6c6ccccc65)cc2c43)cc1 ; CC(C)(C)c1ccc(N2c3cc(N(c4ccccc4)c4ccccc4)ccc3B3c4nc(N(c5ccccc5)c5ccccc5)oc4N(c4ccc5oc6ccc(C(C)(C)C)cc6c5c4)c4cc(C(C)(C)C)cc2c43)cc1 ; CC(C)(C)c1ccc(N2c3cc(N(c4ccccc4)c4ccccc4)ccc3B3c4nc(N(c5ccccc5)c5ccccc5)oc4N(c4ccc5oc6ccc(-c7ccccc7)cc6c5c4)c4cc(C(C)(C)C)cc2c43)cc1]

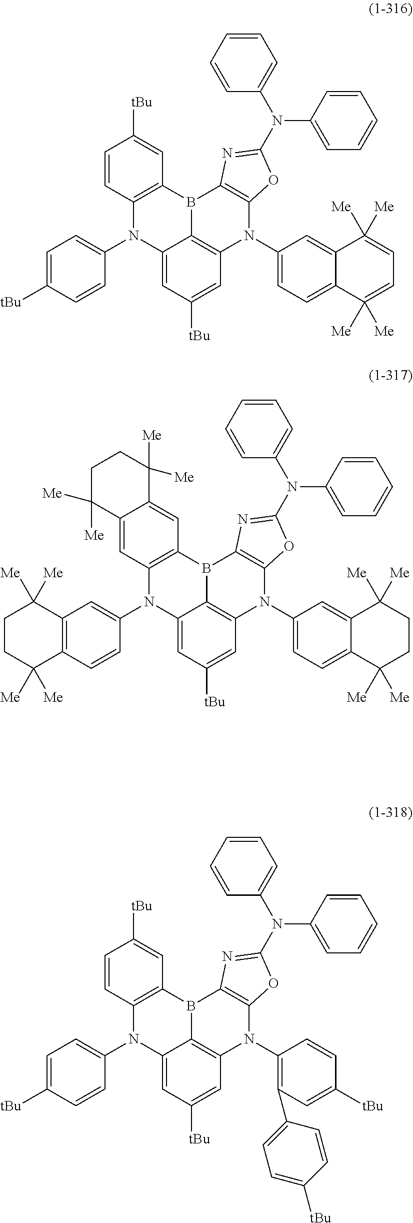

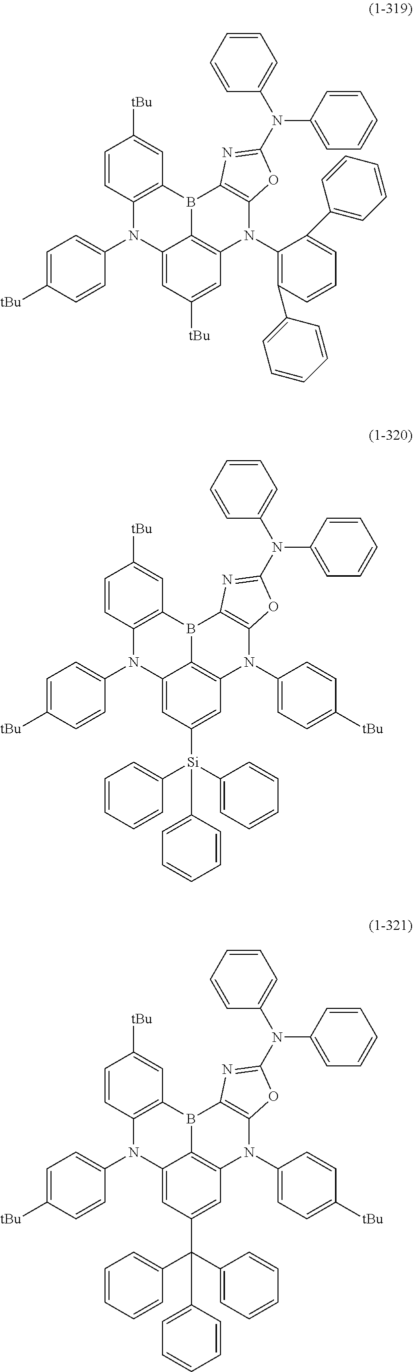 [SMILES: CC(C)(C)c1ccc(N2c3ccc(C(C)(C)C)cc3B3c4nc(N(c5ccccc5)c5ccccc5)oc4N(c4c(-c5ccccc5)cccc4-c4ccccc4)c4cc(C(C)(C)C)cc2c43)cc1 ; CC(C)(C)c1ccc(N2c3ccc(C(C)(C)C)cc3B3c4nc(N(c5ccccc5)c5ccccc5)oc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4nc(N(c5ccccc5)c5ccccc5)oc4N(c4ccc(C(C)(C)C)cc4)c4cc(C(c5ccccc5)(c5ccccc5)c5ccccc5)cc2c43)cc1]

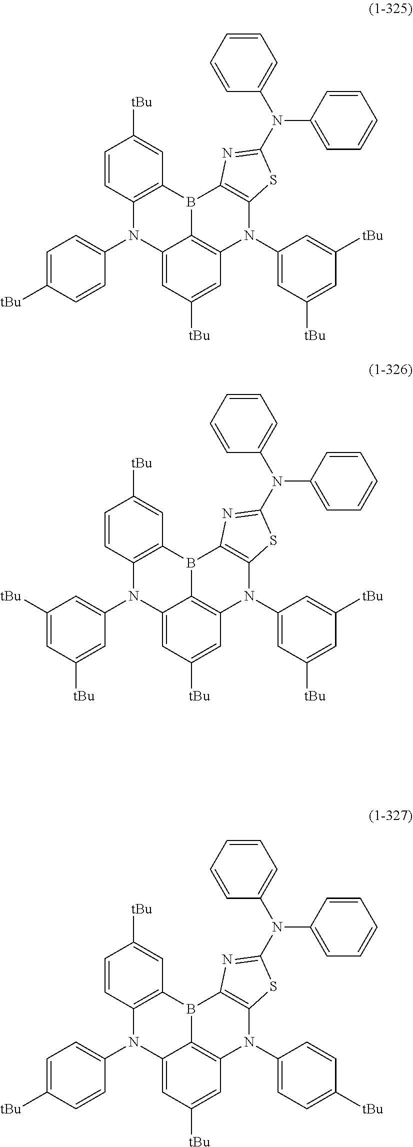 [SMILES: CC(C)(C)c1ccc(N2c3ccc(C(C)(C)C)cc3B3c4nc(N(c5ccccc5)c5ccccc5)sc4N(c4cc(C(C)(C)C)cc(C(C)(C)C)c4)c4cc(C(C)(C)C)cc2c43)cc1 ; CC(C)(C)c1cc(N2c3ccc(C(C)(C)C)cc3B3c4nc(N(c5ccccc5)c5ccccc5)sc4N(c4cc(C(C)(C)C)cc(C(C)(C)C)c4)c4cc(C(C)(C)C)cc2c43)cc(C(C)(C)C)c1 ; CC(C)(C)c1ccc(N2c3ccc(C(C)(C)C)cc3B3c4nc(N(c5ccccc5)c5ccccc5)sc4N(c4ccc(C(C)(C)C)cc4)c4cc(C(C)(C)C)cc2c43)cc1]

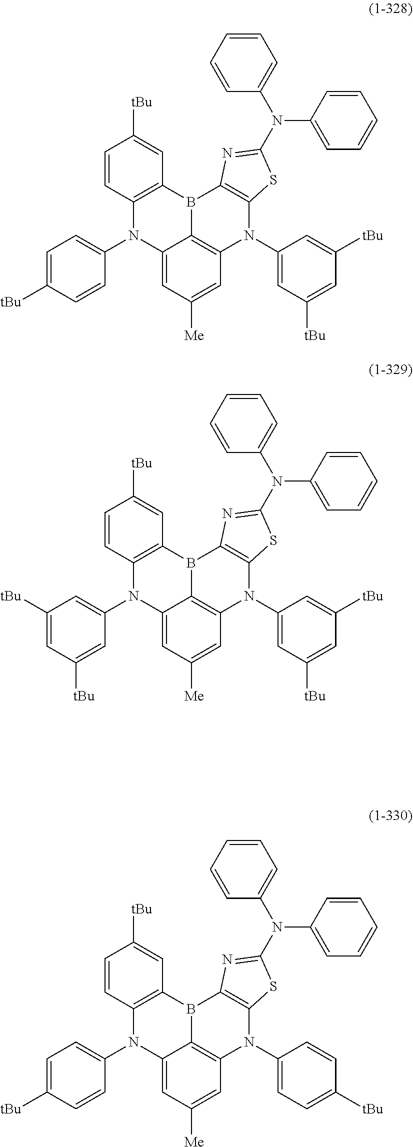 [SMILES: Cc1cc2c3c(c1)N(c1cc(C(C)(C)C)cc(C(C)(C)C)c1)c1sc(N(c4ccccc4)c4ccccc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(N(c4ccccc4)c4ccccc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(N(c4ccccc4)c4ccccc4)nc1B3c1cc(C(C)(C)C)ccc1N2c1ccc(C(C)(C)C)cc1]

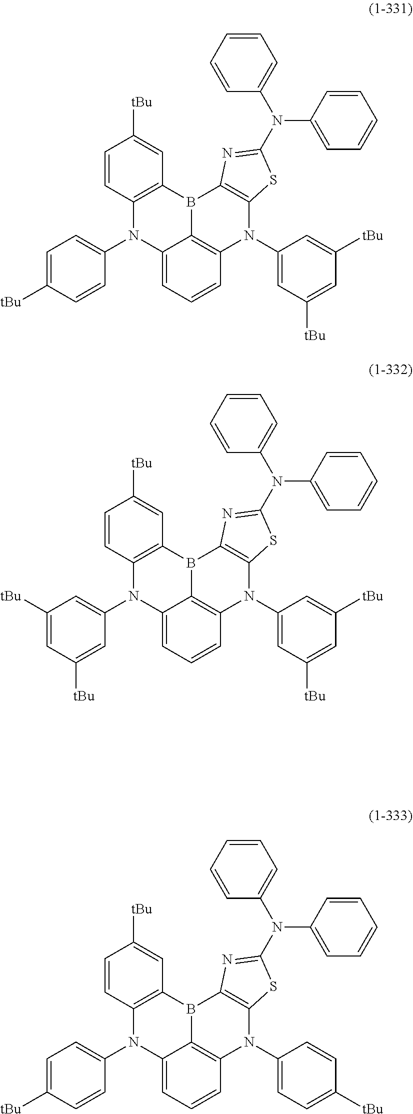 [SMILES: CC(C)(C)c1ccc(N2c3ccc(C(C)(C)C)cc3B3c4nc(N(c5ccccc5)c5ccccc5)sc4N(c4cc(C(C)(C)C)cc(C(C)(C)C)c4)c4cccc2c43)cc1 ; CC(C)(C)c1cc(N2c3ccc(C(C)(C)C)cc3B3c4nc(N(c5ccccc5)c5ccccc5)sc4N(c4cc(C(C)(C)C)cc(C(C)(C)C)c4)c4cccc2c43)cc(C(C)(C)C)c1 ; CC(C)(C)c1ccc(N2c3ccc(C(C)(C)C)cc3B3c4nc(N(c5ccccc5)c5ccccc5)sc4N(c4ccc(C(C)(C)C)cc4)c4cccc2c43)cc1]

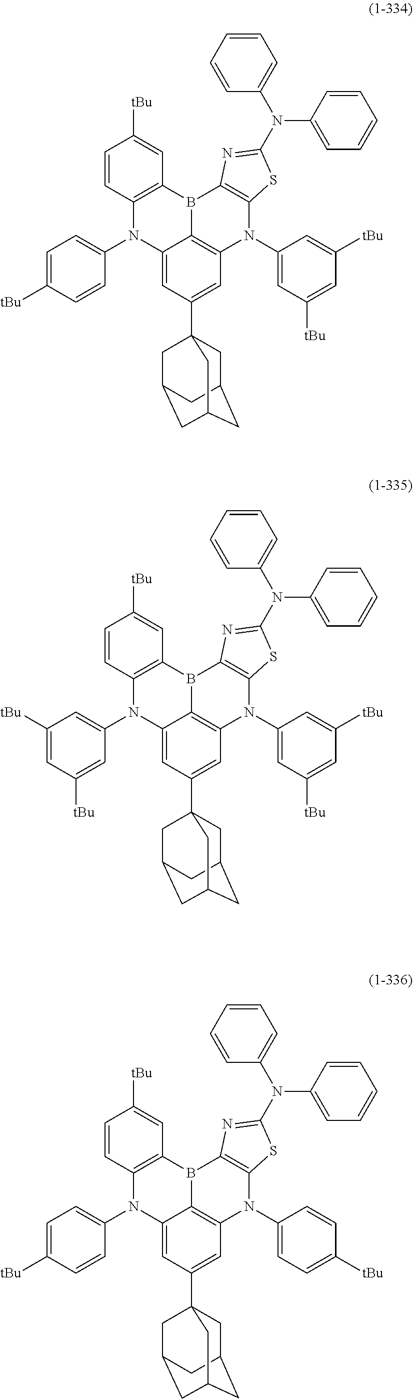 [SMILES: CC(C)(C)c1ccc(N2c3ccc(C(C)(C)C)cc3B3c4nc(N(c5ccccc5)c5ccccc5)sc4N(c4cc(C(C)(C)C)cc(C(C)(C)C)c4)c4cc(C56CC7CC(CC(C7)C5)C6)cc2c43)cc1 ; CC(C)(C)c1cc(N2c3ccc(C(C)(C)C)cc3B3c4nc(N(c5ccccc5)c5ccccc5)sc4N(c4cc(C(C)(C)C)cc(C(C)(C)C)c4)c4cc(C56CC7CC(CC(C7)C5)C6)cc2c43)cc(C(C)(C)C)c1 ; CC(C)(C)c1ccc(N2c3ccc(C(C)(C)C)cc3B3c4nc(N(c5ccccc5)c5ccccc5)sc4N(c4ccc(C(C)(C)C)cc4)c4cc(C56CC7CC(CC(C7)C5)C6)cc2c43)cc1]

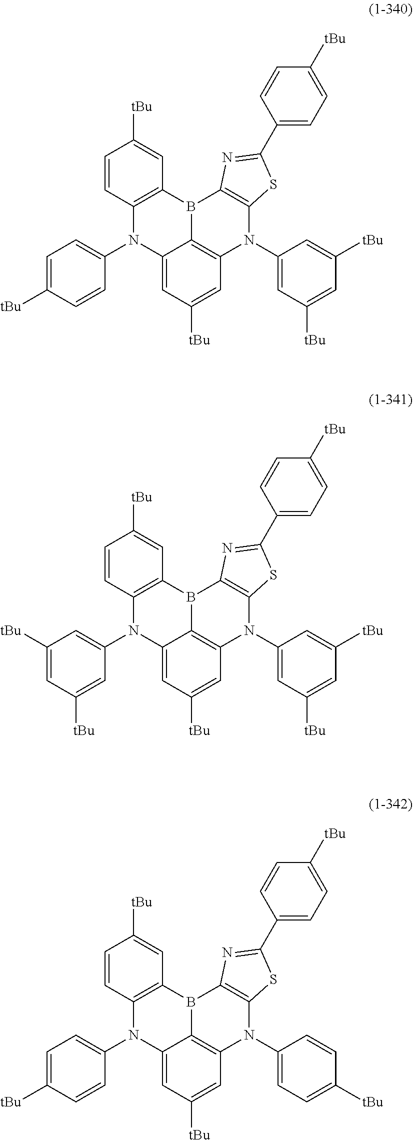 [SMILES: CC(C)(C)c1ccc(-c2nc3c(s2)N(c2cc(C(C)(C)C)cc(C(C)(C)C)c2)c2cc(C(C)(C)C)cc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C(C)(C)C)cc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C(C)(C)C)cc4c2B3c2cc(C(C)(C)C)ccc2N4c2ccc(C(C)(C)C)cc2)cc1]

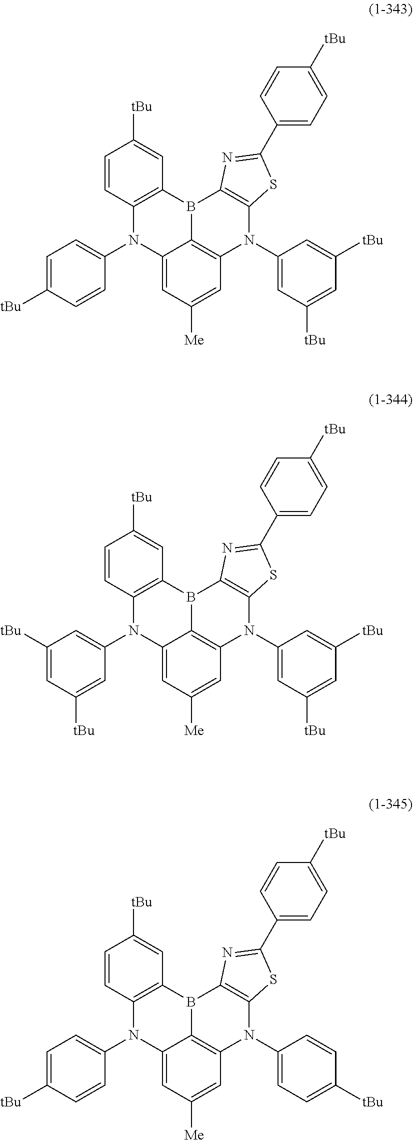 [SMILES: Cc1cc2c3c(c1)N(c1cc(C(C)(C)C)cc(C(C)(C)C)c1)c1sc(-c4ccc(C(C)(C)C)cc4)nc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1sc(-c4ccc(C(C)(C)C)cc4)nc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1sc(-c4ccc(C(C)(C)C)cc4)nc1B3c1cc(C(C)(C)C)ccc1N2c1ccc(C(C)(C)C)cc1]

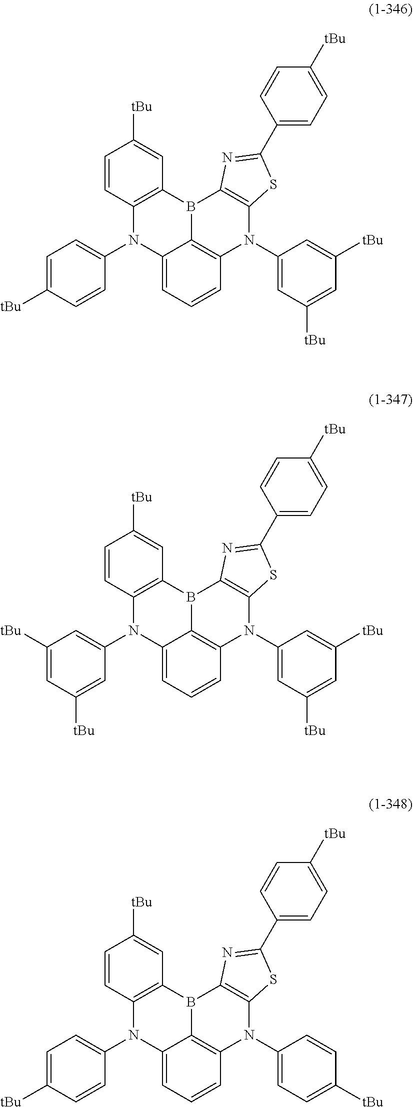 [SMILES: CC(C)(C)c1ccc(-c2nc3c(s2)N(c2cc(C(C)(C)C)cc(C(C)(C)C)c2)c2cccc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cccc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cccc4c2B3c2cc(C(C)(C)C)ccc2N4c2ccc(C(C)(C)C)cc2)cc1]

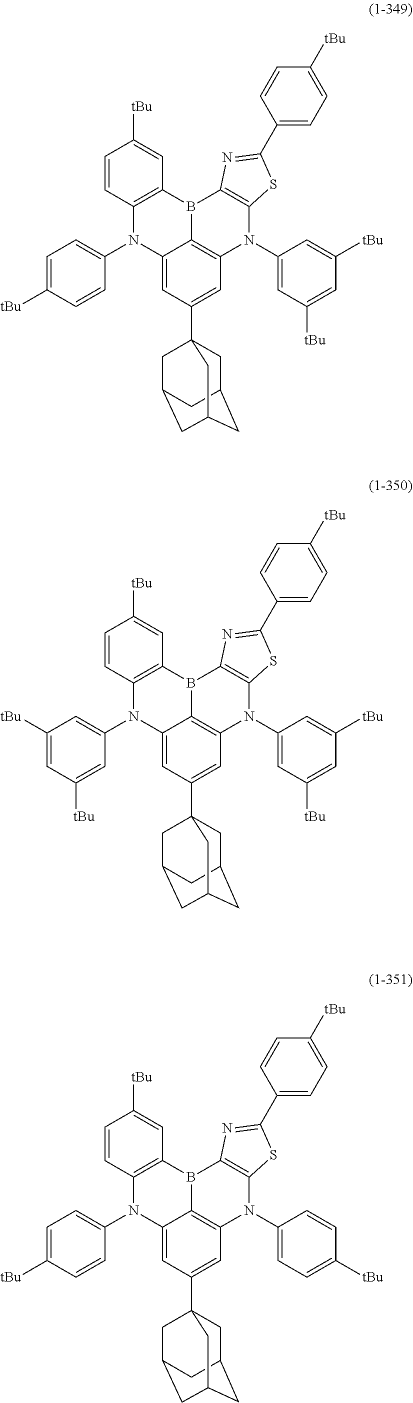 [SMILES: CC(C)(C)c1ccc(-c2nc3c(s2)N(c2cc(C(C)(C)C)cc(C(C)(C)C)c2)c2cc(C45CC6CC(CC(C6)C4)C5)cc4c2B3c2cc(C(C)(C)C)ccc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C45CC6CC(CC(C6)C4)C5)cc4c2B3c2cc(C(C)(C)C)ccc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C45CC6CC(CC(C6)C4)C5)cc4c2B3c2cc(C(C)(C)C)ccc2N4c2ccc(C(C)(C)C)cc2)cc1]

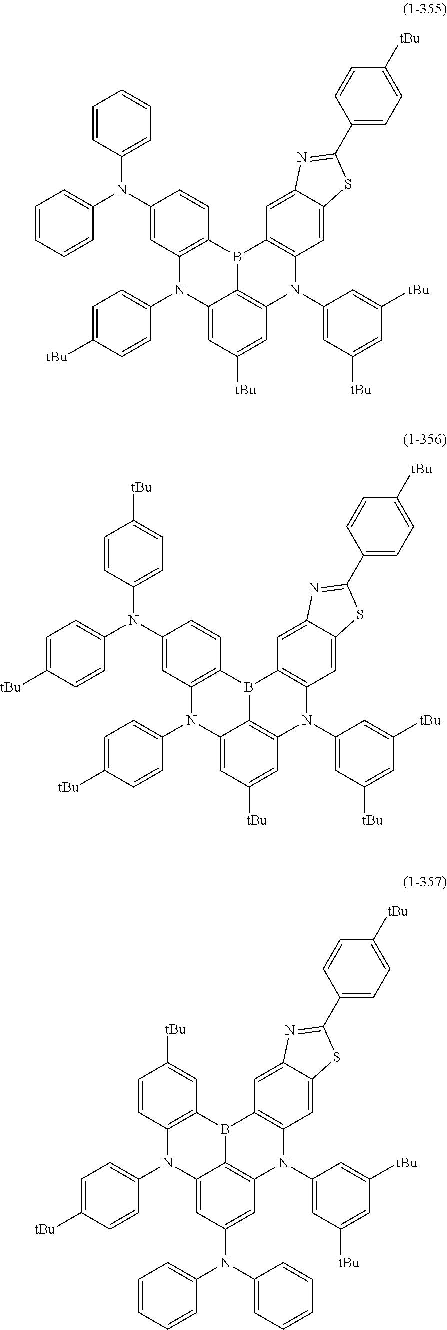 [SMILES: CC(C)(C)c1ccc(-c2nc3cc4c(cc3s2)N(c2cc(C(C)(C)C)cc(C(C)(C)C)c2)c2cc(C(C)(C)C)cc3c2B4c2ccc(N(c4ccccc4)c4ccccc4)cc2N3c2ccc(C(C)(C)C)cc2)cc1 ; CC(C)(C)c1ccc(-c2nc3cc4c(cc3s2)N(c2cc(C(C)(C)C)cc(C(C)(C)C)c2)c2cc(C(C)(C)C)cc3c2B4c2ccc(N(c4ccc(C(C)(C)C)cc4)c4ccc(C(C)(C)C)cc4)cc2N3c2ccc(C(C)(C)C)cc2)cc1 ; CC(C)(C)c1ccc(-c2nc3cc4c(cc3s2)N(c2cc(C(C)(C)C)cc(C(C)(C)C)c2)c2cc(N(c3ccccc3)c3ccccc3)cc3c2B4c2cc(C(C)(C)C)ccc2N3c2ccc(C(C)(C)C)cc2)cc1]

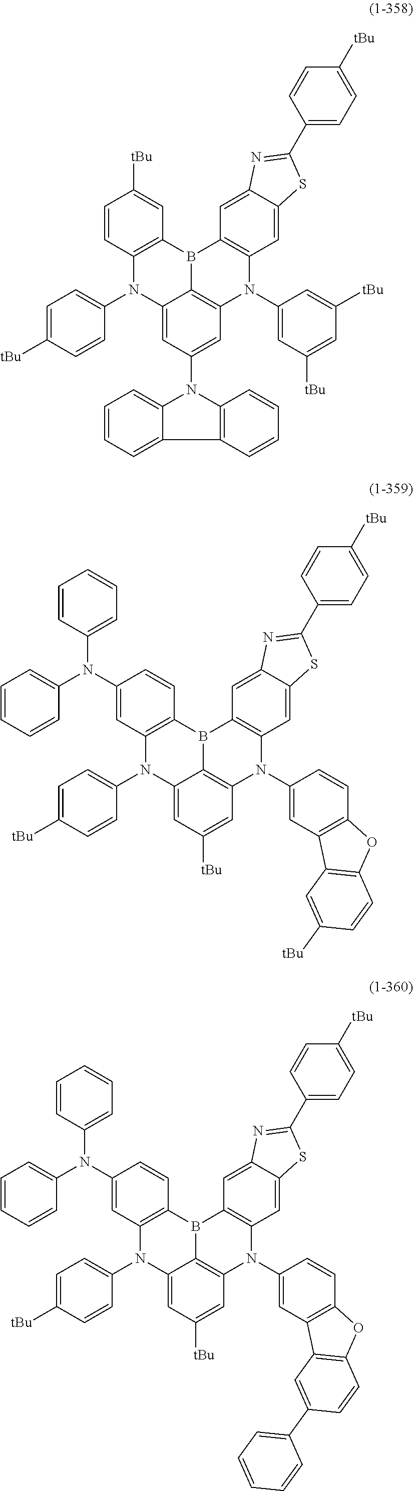 [SMILES: CC(C)(C)c1ccc(-c2nc3cc4c(cc3s2)N(c2cc(C(C)(C)C)cc(C(C)(C)C)c2)c2cc(-n3c5ccccc5c5ccccc53)cc3c2B4c2cc(C(C)(C)C)ccc2N3c2ccc(C(C)(C)C)cc2)cc1 ; CC(C)(C)c1ccc(-c2nc3cc4c(cc3s2)N(c2ccc3oc5ccc(C(C)(C)C)cc5c3c2)c2cc(C(C)(C)C)cc3c2B4c2ccc(N(c4ccccc4)c4ccccc4)cc2N3c2ccc(C(C)(C)C)cc2)cc1 ; CC(C)(C)c1ccc(-c2nc3cc4c(cc3s2)N(c2ccc3oc5ccc(-c6ccccc6)cc5c3c2)c2cc(C(C)(C)C)cc3c2B4c2ccc(N(c4ccccc4)c4ccccc4)cc2N3c2ccc(C(C)(C)C)cc2)cc1]

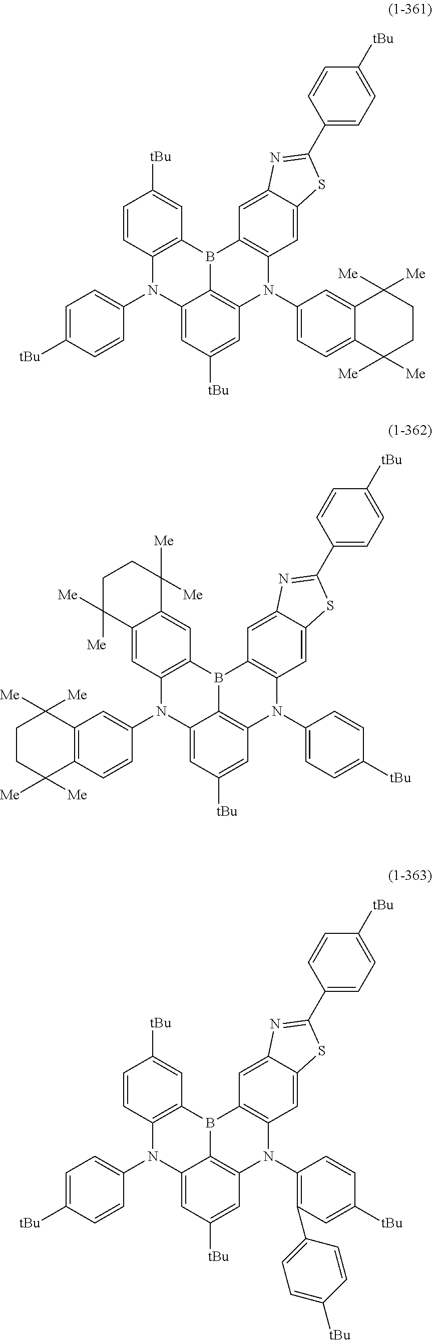 [SMILES: CC(C)(C)c1ccc(-c2nc3cc4c(cc3s2)N(c2ccc3c(c2)C(C)(C)CCC3(C)C)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3s2)N(c2ccc(C(C)(C)C)cc2)c2cc(C(C)(C)C)cc3c2B4c2cc4c(cc2N3c2ccc3c(c2)C(C)(C)CCC3(C)C)C(C)(C)CCC4(C)C)cc1 ; CC(C)(C)c1ccc(-c2nc3cc4c(cc3s2)N(c2ccc(C(C)(C)C)cc2-c2ccc(C(C)(C)C)cc2)c2cc(C(C)(C)C)cc3c2B4c2cc(C(C)(C)C)ccc2N3c2ccc(C(C)(C)C)cc2)cc1]

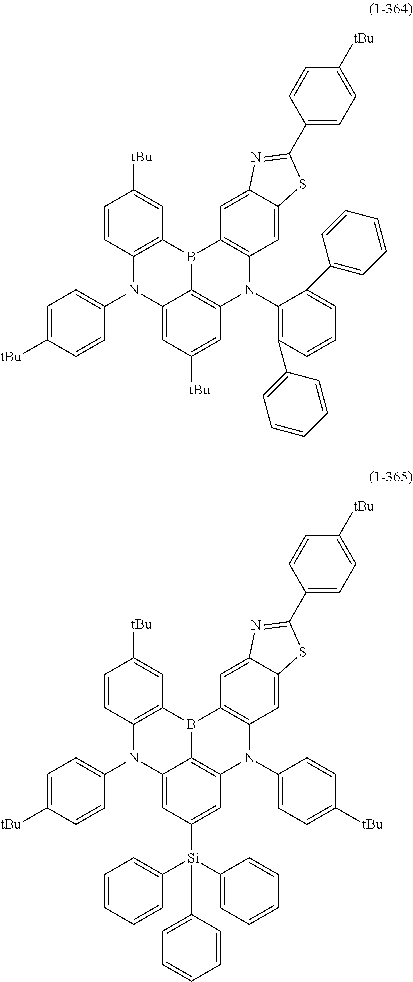 [SMILES: CC(C)(C)c1ccc(-c2nc3cc4c(cc3s2)N(c2c(-c3ccccc3)cccc2-c2ccccc2)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3s2)N(c2ccc(C(C)(C)C)cc2)c2cc([Si](c3ccccc3)(c3ccccc3)c3ccccc3)cc3c2B4c2cc(C(C)(C)C)ccc2N3c2ccc(C(C)(C)C)cc2)cc1]

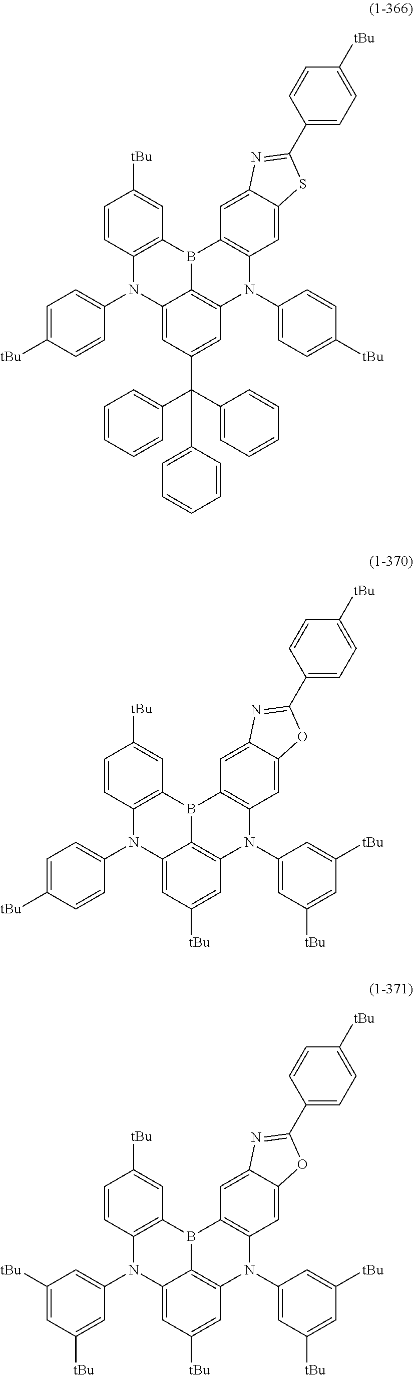 [SMILES: CC(C)(C)c1ccc(-c2nc3cc4c(cc3s2)N(c2ccc(C(C)(C)C)cc2)c2cc(C(c3ccccc3)(c3ccccc3)c3ccccc3)cc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C(C)(C)C)cc3c2B4c2cc(C(C)(C)C)ccc2N3c2cc(C(C)(C)C)cc(C(C)(C)C)c2)cc1]

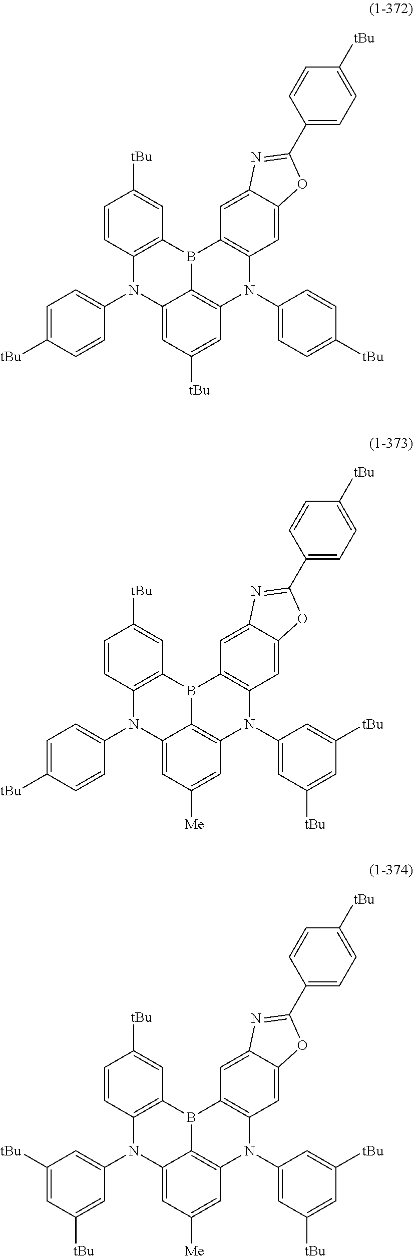 [SMILES: CC(C)(C)c1ccc(-c2nc3cc4c(cc3o2)N(c2ccc(C(C)(C)C)cc2)c2cc(C(C)(C)C)cc3c2B4c2cc(C(C)(C)C)ccc2N3c2ccc(C(C)(C)C)cc2)cc1 ; Cc1cc2c3c(c1)N(c1cc(C(C)(C)C)cc(C(C)(C)C)c1)c1cc4oc(-c5ccc(C(C)(C)C)cc5)nc4cc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1cc4oc(-c5ccc(C(C)(C)C)cc5)nc4cc1B3c1cc(C(C)(C)C)ccc1N2c1cc(C(C)(C)C)cc(C(C)(C)C)c1]

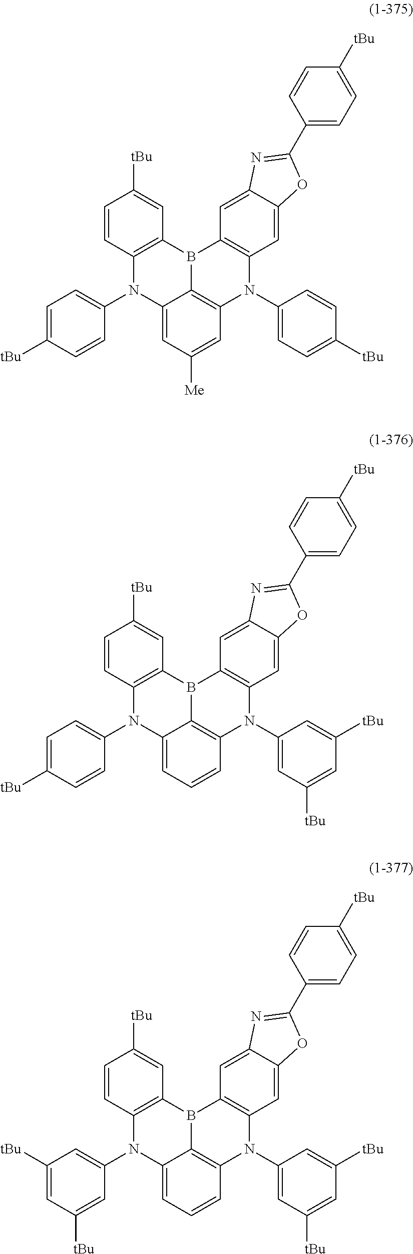 [SMILES: Cc1cc2c3c(c1)N(c1ccc(C(C)(C)C)cc1)c1cc4oc(-c5ccc(C(C)(C)C)cc5)nc4cc1B3c1cc(C(C)(C)C)ccc1N2c1ccc(C(C)(C)C)cc1 ; CC(C)(C)c1ccc(-c2nc3cc4c(cc3o2)N(c2cc(C(C)(C)C)cc(C(C)(C)C)c2)c2cccc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cccc3c2B4c2cc(C(C)(C)C)ccc2N3c2cc(C(C)(C)C)cc(C(C)(C)C)c2)cc1]

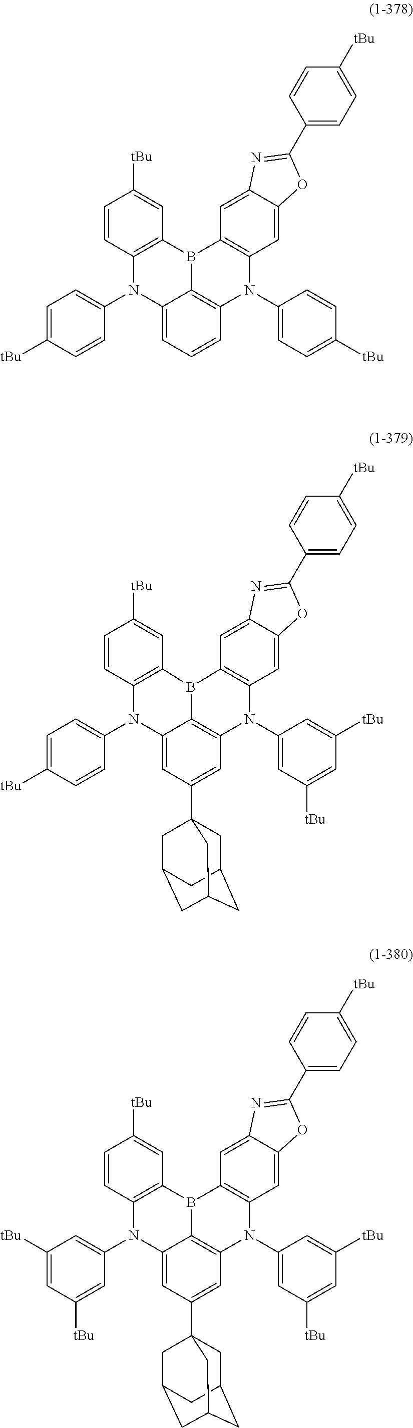 [SMILES: CC(C)(C)c1ccc(-c2nc3cc4c(cc3o2)N(c2ccc(C(C)(C)C)cc2)c2cccc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C35CC6CC(CC(C6)C3)C5)cc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C35CC6CC(CC(C6)C3)C5)cc3c2B4c2cc(C(C)(C)C)ccc2N3c2cc(C(C)(C)C)cc(C(C)(C)C)c2)cc1]

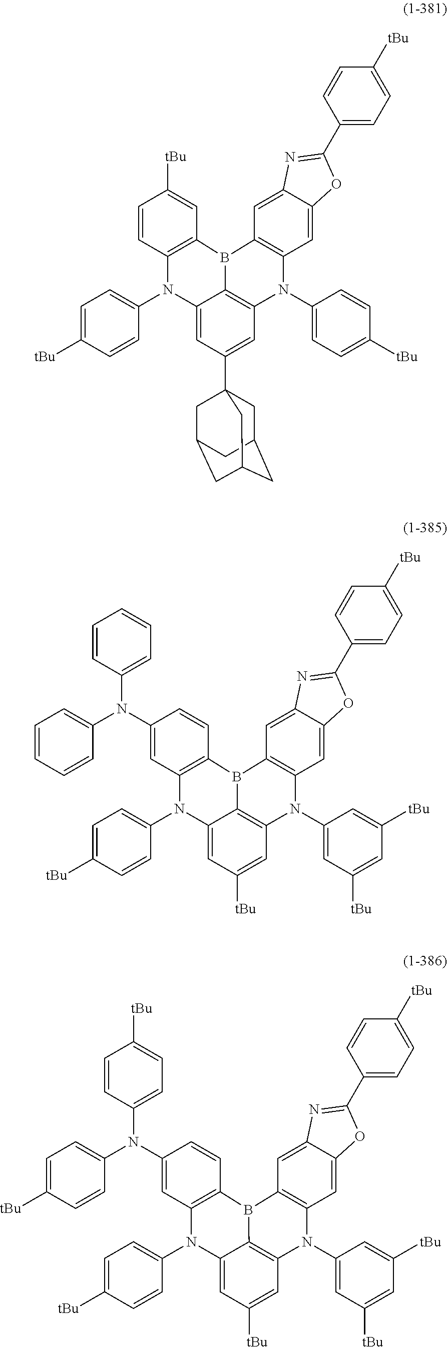 [SMILES: CC(C)(C)c1ccc(-c2nc3cc4c(cc3o2)N(c2ccc(C(C)(C)C)cc2)c2cc(C35CC6CC(CC(C6)C3)C5)cc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C(C)(C)C)cc3c2B4c2ccc(N(c4ccccc4)c4ccccc4)cc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C(C)(C)C)cc3c2B4c2ccc(N(c4ccc(C(C)(C)C)cc4)c4ccc(C(C)(C)C)cc4)cc2N3c2ccc(C(C)(C)C)cc2)cc1]

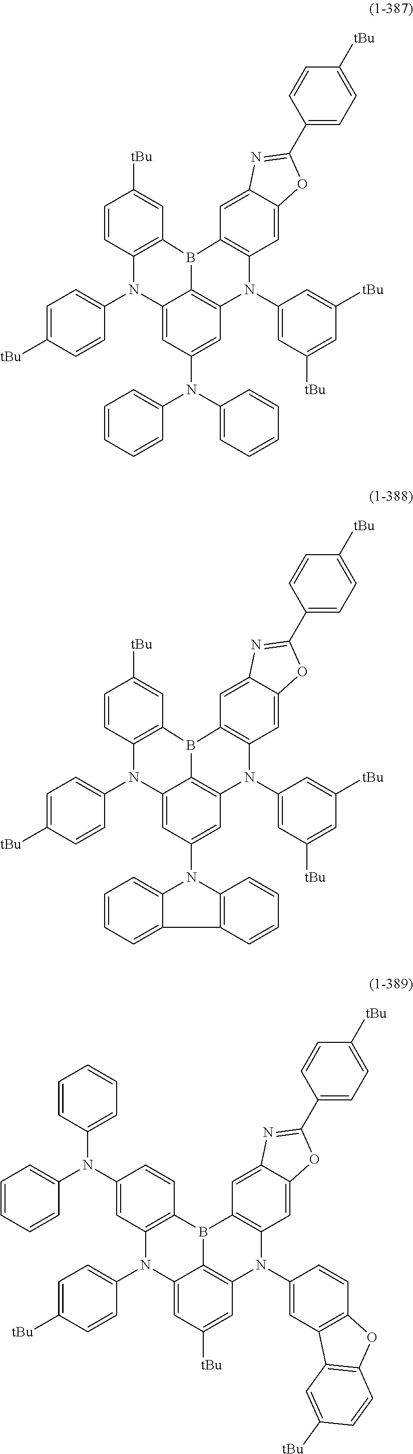 [SMILES: CC(C)(C)c1ccc(-c2nc3cc4c(cc3o2)N(c2cc(C(C)(C)C)cc(C(C)(C)C)c2)c2cc(N(c3ccccc3)c3ccccc3)cc3c2B4c2cc(C(C)(C)C)ccc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(-n3c5ccccc5c5ccccc53)cc3c2B4c2cc(C(C)(C)C)ccc2N3c2ccc(C(C)(C)C)cc2)cc1 ; CC(C)(C)c1ccc(-c2nc3cc4c(cc3o2)N(c2ccc3oc5ccc(C(C)(C)C)cc5c3c2)c2cc(C(C)(C)C)cc3c2B4c2ccc(N(c4ccccc4)c4ccccc4)cc2N3c2ccc(C(C)(C)C)cc2)cc1]

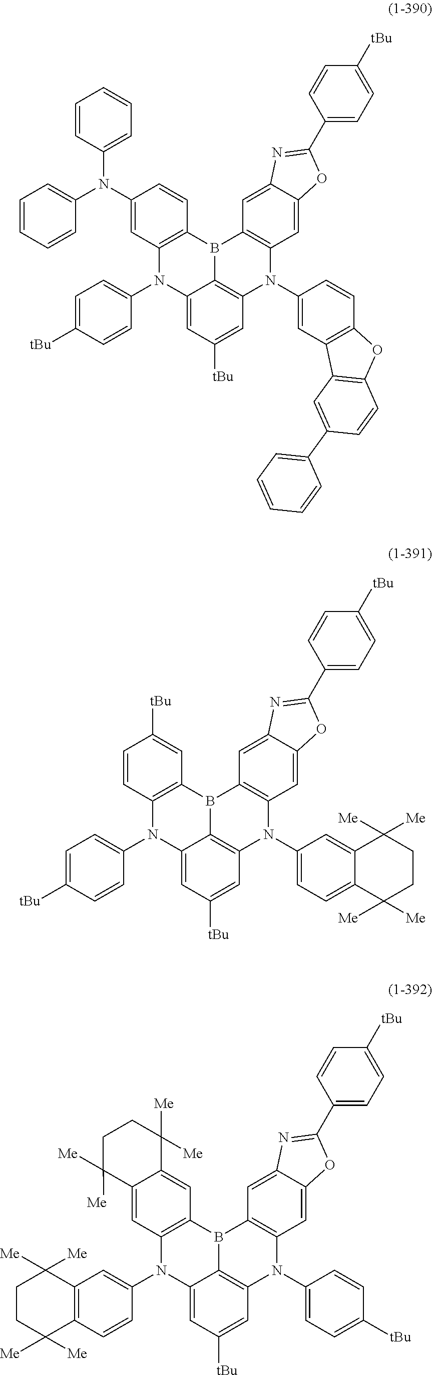 [SMILES: CC(C)(C)c1ccc(-c2nc3cc4c(cc3o2)N(c2ccc3oc5ccc(-c6ccccc6)cc5c3c2)c2cc(C(C)(C)C)cc3c2B4c2ccc(N(c4ccccc4)c4ccccc4)cc2N3c2ccc(C(C)(C)C)cc2)cc1 ; CC(C)(C)c1ccc(-c2nc3cc4c(cc3o2)N(c2ccc3c(c2)C(C)(C)CCC3(C)C)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3o2)N(c2ccc(C(C)(C)C)cc2)c2cc(C(C)(C)C)cc3c2B4c2cc4c(cc2N3c2ccc3c(c2)C(C)(C)CCC3(C)C)C(C)(C)CCC4(C)C)cc1]

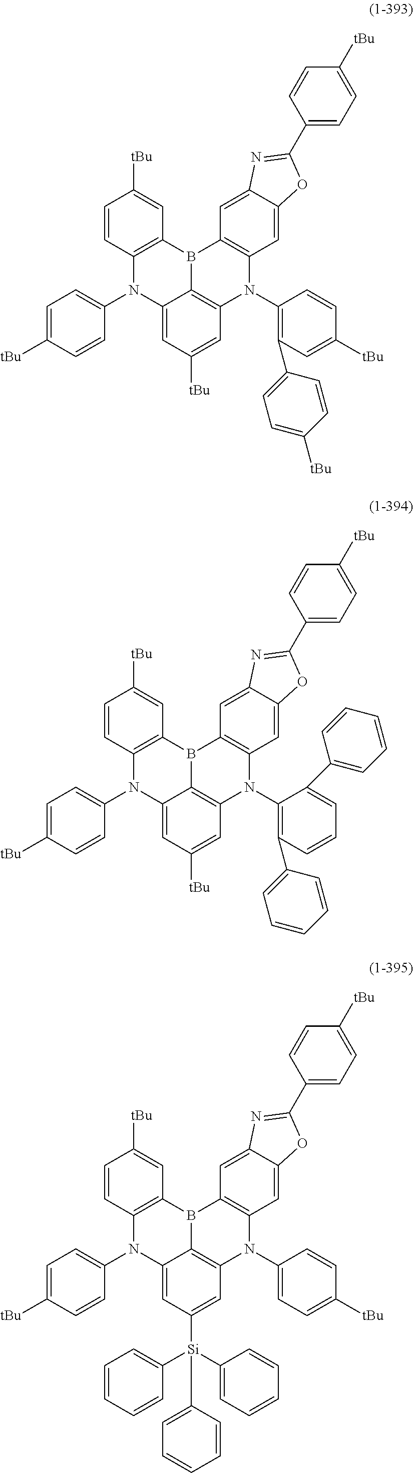 [SMILES: CC(C)(C)c1ccc(-c2nc3cc4c(cc3o2)N(c2ccc(C(C)(C)C)cc2-c2ccc(C(C)(C)C)cc2)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3o2)N(c2c(-c3ccccc3)cccc2-c2ccccc2)c2cc(C(C)(C)C)cc3c2B4c2cc(C(C)(C)C)ccc2N3c2ccc(C(C)(C)C)cc2)cc1 ; CC(C)(C)c1ccc(-c2nc3cc4c(cc3o2)N(c2ccc(C(C)(C)C)cc2)c2cc([Si](c3ccccc3)(c3ccccc3)c3ccccc3)cc3c2B4c2cc(C(C)(C)C)ccc2N3c2ccc(C(C)(C)C)cc2)cc1]

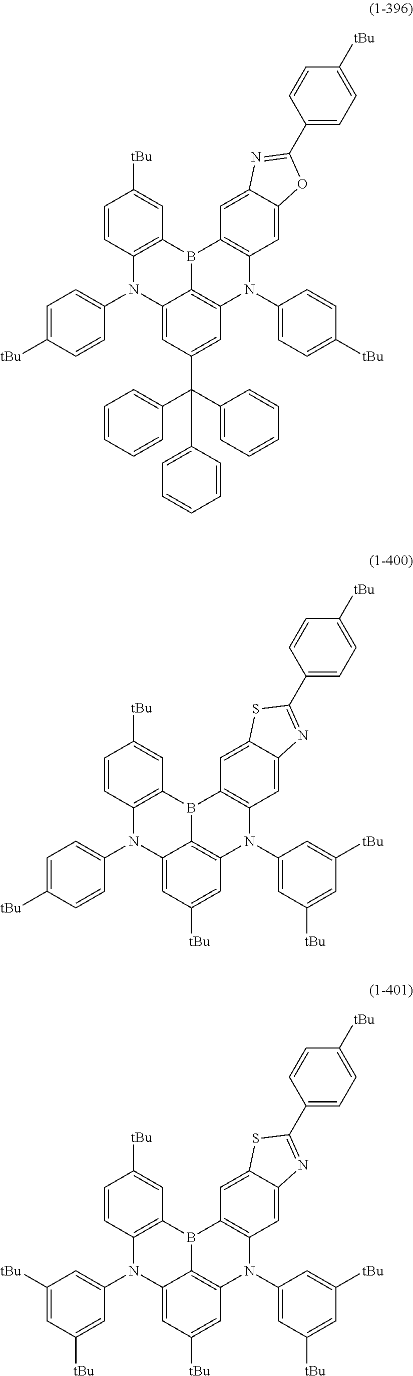 [SMILES: CC(C)(C)c1ccc(-c2nc3cc4c(cc3o2)N(c2ccc(C(C)(C)C)cc2)c2cc(C(c3ccccc3)(c3ccccc3)c3ccccc3)cc3c2B4c2cc(C(C)(C)C)ccc2N3c2ccc(C(C)(C)C)cc2)cc1 ; CC(C)(C)c1ccc(-c2nc3cc4c(cc3s2)B2c3cc(C(C)(C)C)ccc3N(c3ccc(C(C)(C)C)cc3)c3cc(C(C)(C)C)cc(c32)N4c2cc(C(C)(C)C)cc(C(C)(C)C)c2)cc1 ; CC(C)(C)c1ccc(-c2nc3cc4c(cc3s2)B2c3cc(C(C)(C)C)ccc3N(c3cc(C(C)(C)C)cc(C(C)(C)C)c3)c3cc(C(C)(C)C)cc(c32)N4c2cc(C(C)(C)C)cc(C(C)(C)C)c2)cc1]

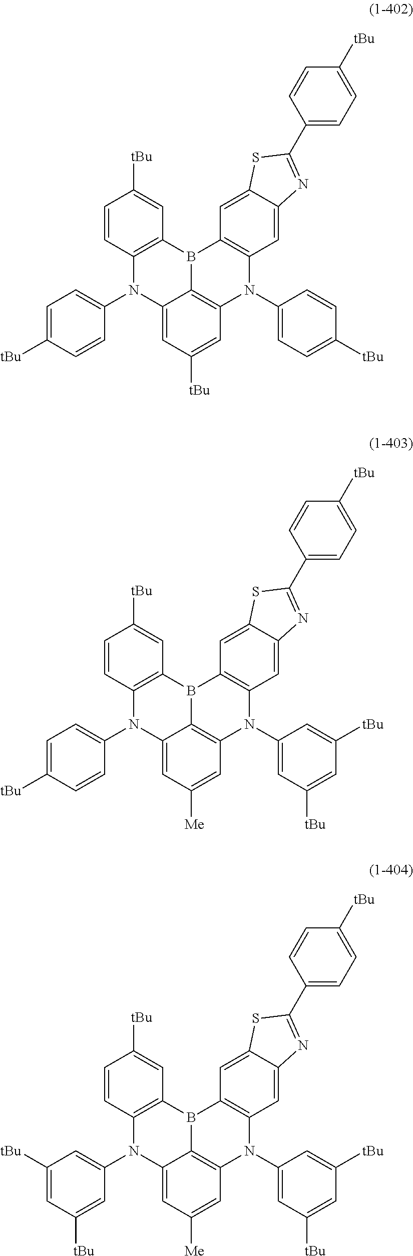 [SMILES: CC(C)(C)c1ccc(-c2nc3cc4c(cc3s2)B2c3cc(C(C)(C)C)ccc3N(c3ccc(C(C)(C)C)cc3)c3cc(C(C)(C)C)cc(c32)N4c2ccc(C(C)(C)C)cc2)cc1 ; Cc1cc2c3c(c1)N(c1cc(C(C)(C)C)cc(C(C)(C)C)c1)c1cc4nc(-c5ccc(C(C)(C)C)cc5)sc4cc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1cc4nc(-c5ccc(C(C)(C)C)cc5)sc4cc1B3c1cc(C(C)(C)C)ccc1N2c1cc(C(C)(C)C)cc(C(C)(C)C)c1]

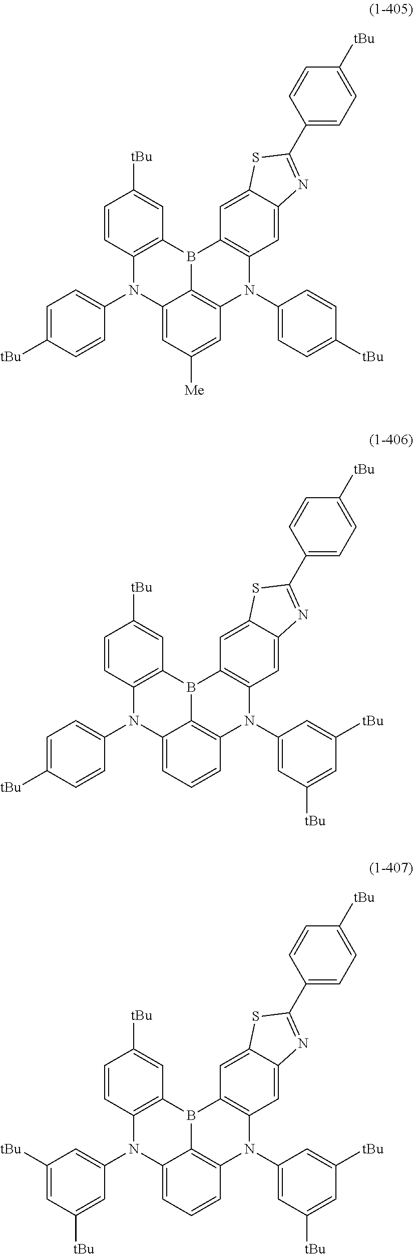 [SMILES: Cc1cc2c3c(c1)N(c1ccc(C(C)(C)C)cc1)c1cc4nc(-c5ccc(C(C)(C)C)cc5)sc4cc1B3c1cc(C(C)(C)C)ccc1N2c1ccc(C(C)(C)C)cc1 ; CC(C)(C)c1ccc(-c2nc3cc4c(cc3s2)B2c3cc(C(C)(C)C)ccc3N(c3ccc(C(C)(C)C)cc3)c3cccc(c32)N4c2cc(C(C)(C)C)cc(C(C)(C)C)c2)cc1 ; CC(C)(C)c1ccc(-c2nc3cc4c(cc3s2)B2c3cc(C(C)(C)C)ccc3N(c3cc(C(C)(C)C)cc(C(C)(C)C)c3)c3cccc(c32)N4c2cc(C(C)(C)C)cc(C(C)(C)C)c2)cc1]

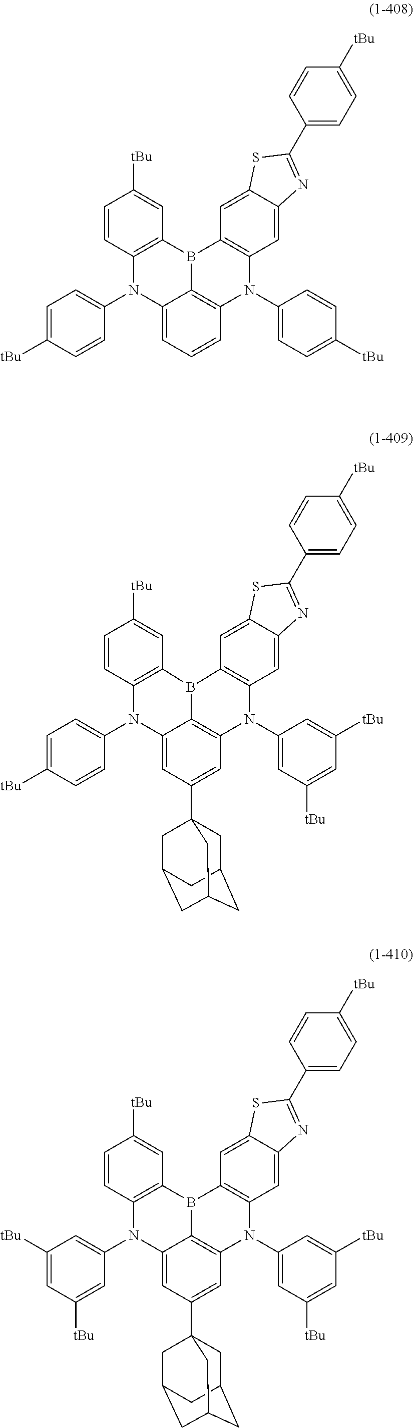 [SMILES: CC(C)(C)c1ccc(-c2nc3cc4c(cc3s2)B2c3cc(C(C)(C)C)ccc3N(c3ccc(C(C)(C)C)cc3)c3cccc(c32)N4c2ccc(C(C)(C)C)cc2)cc1 ; CC(C)(C)c1ccc(-c2nc3cc4c(cc3s2)B2c3cc(C(C)(C)C)ccc3N(c3ccc(C(C)(C)C)cc3)c3cc(C56CC7CC(CC(C7)C5)C6)cc(c32)N4c2cc(C(C)(C)C)cc(C(C)(C)C)c2)cc1 ; CC(C)(C)c1ccc(-c2nc3cc4c(cc3s2)B2c3cc(C(C)(C)C)ccc3N(c3cc(C(C)(C)C)cc(C(C)(C)C)c3)c3cc(C56CC7CC(CC(C7)C5)C6)cc(c32)N4c2cc(C(C)(C)C)cc(C(C)(C)C)c2)cc1]

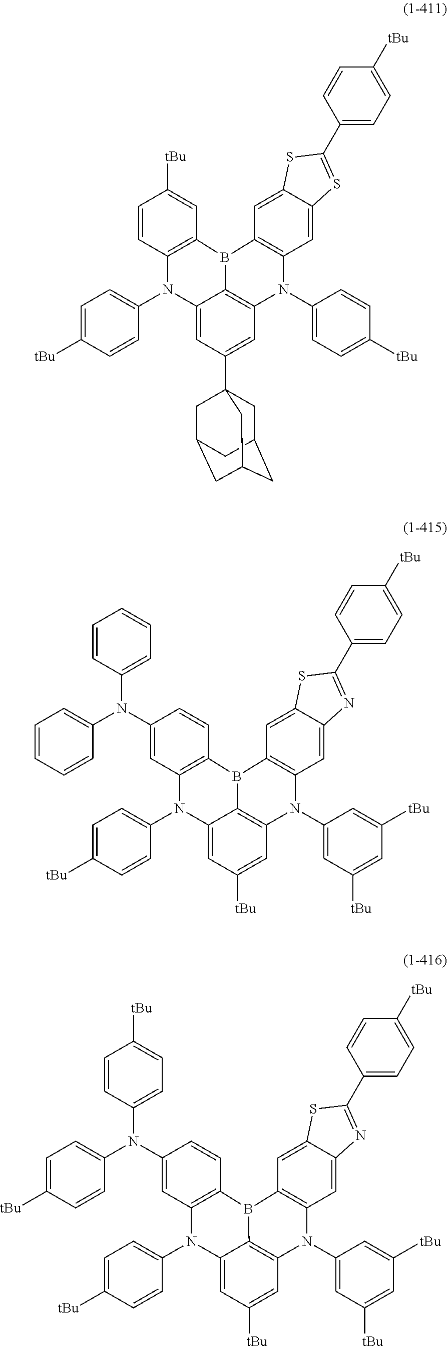

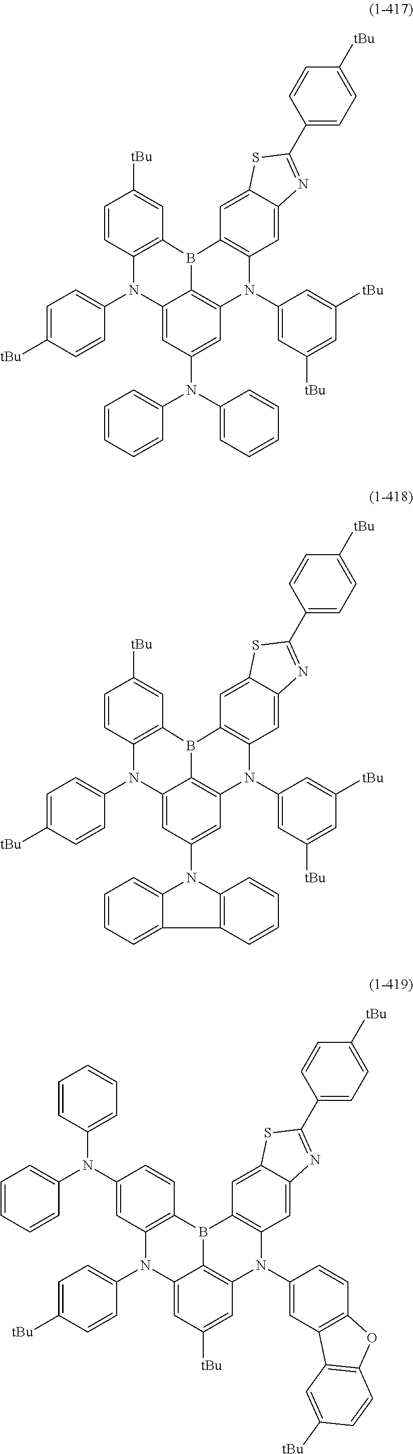 [SMILES: CC(C)(C)c1ccc(-c2nc3cc4c(cc3s2)B2c3cc(C(C)(C)C)ccc3N(c3ccc(C(C)(C)C)cc3)c3cc(N(c5ccccc5)c5ccccc5)cc(c32)N4c2cc(C(C)(C)C)cc(C(C)(C)C)c2)cc1 ; CC(C)(C)c1ccc(-c2nc3cc4c(cc3s2)B2c3cc(C(C)(C)C)ccc3N(c3ccc(C(C)(C)C)cc3)c3cc(-n5c6ccccc6c6ccccc65)cc(c32)N4c2cc(C(C)(C)C)cc(C(C)(C)C)c2)cc1 ; CC(C)(C)c1ccc(-c2nc3cc4c(cc3s2)B2c3ccc(N(c5ccccc5)c5ccccc5)cc3N(c3ccc(C(C)(C)C)cc3)c3cc(C(C)(C)C)cc(c32)N4c2ccc3oc4ccc(C(C)(C)C)cc4c3c2)cc1]

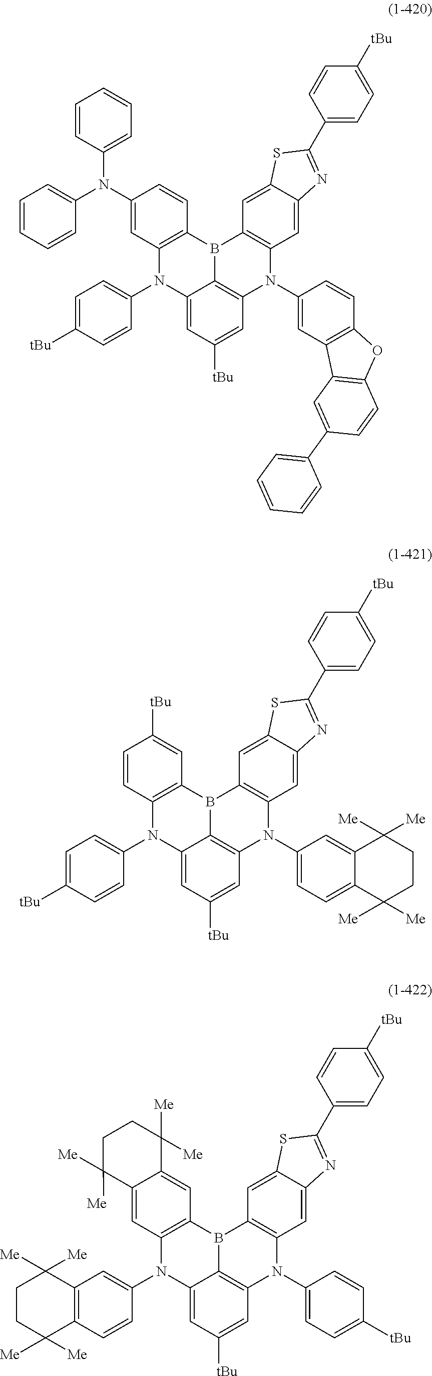 [SMILES: CC(C)(C)c1ccc(-c2nc3cc4c(cc3s2)B2c3ccc(N(c5ccccc5)c5ccccc5)cc3N(c3ccc(C(C)(C)C)cc3)c3cc(C(C)(C)C)cc(c32)N4c2ccc3oc4ccc(-c5ccccc5)cc4c3c2)cc1 ; CC(C)(C)c1ccc(-c2nc3cc4c(cc3s2)B2c3cc(C(C)(C)C)ccc3N(c3ccc(C(C)(C)C)cc3)c3cc(C(C)(C)C)cc(c32)N4c2ccc3c(c2)C(C)(C)CCC3(C)C)cc1 ; CC(C)(C)c1ccc(-c2nc3cc4c(cc3s2)B2c3cc5c(cc3N(c3ccc6c(c3)C(C)(C)CCC6(C)C)c3cc(C(C)(C)C)cc(c32)N4c2ccc(C(C)(C)C)cc2)C(C)(C)CCC5(C)C)cc1]

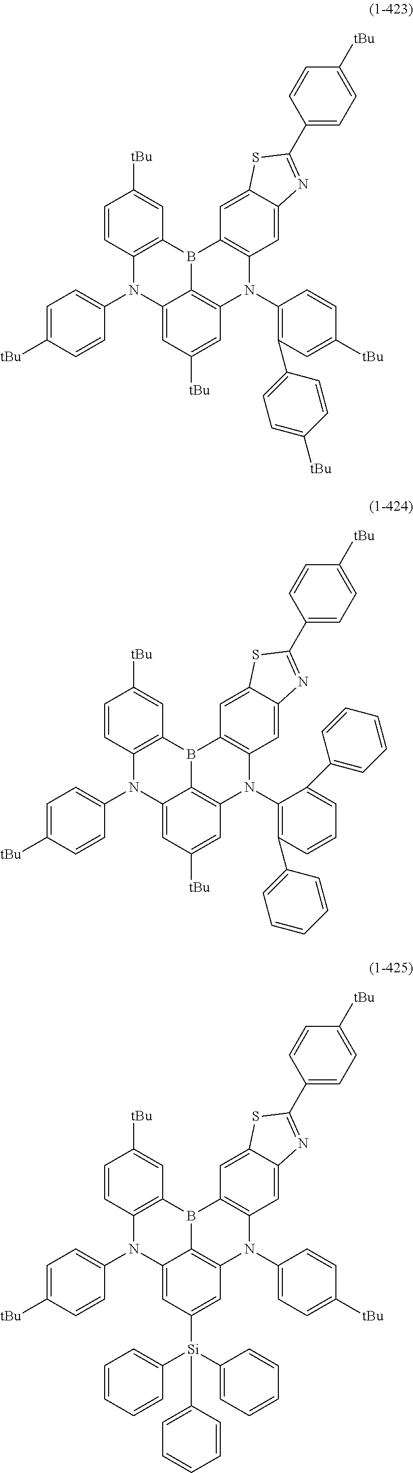 [SMILES: CC(C)(C)c1ccc(-c2nc3cc4c(cc3s2)B2c3cc(C(C)(C)C)ccc3N(c3ccc(C(C)(C)C)cc3)c3cc(C(C)(C)C)cc(c32)N4c2ccc(C(C)(C)C)cc2-c2ccc(C(C)(C)C)cc2)cc1 ; CC(C)(C)c1ccc(-c2nc3cc4c(cc3s2)B2c3cc(C(C)(C)C)ccc3N(c3ccc(C(C)(C)C)cc3)c3cc(C(C)(C)C)cc(c32)N4c2c(-c3ccccc3)cccc2-c2ccccc2)cc1 ; CC(C)(C)c1ccc(-c2nc3cc4c(cc3s2)B2c3cc(C(C)(C)C)ccc3N(c3ccc(C(C)(C)C)cc3)c3cc([Si](c5ccccc5)(c5ccccc5)c5ccccc5)cc(c32)N4c2ccc(C(C)(C)C)cc2)cc1]

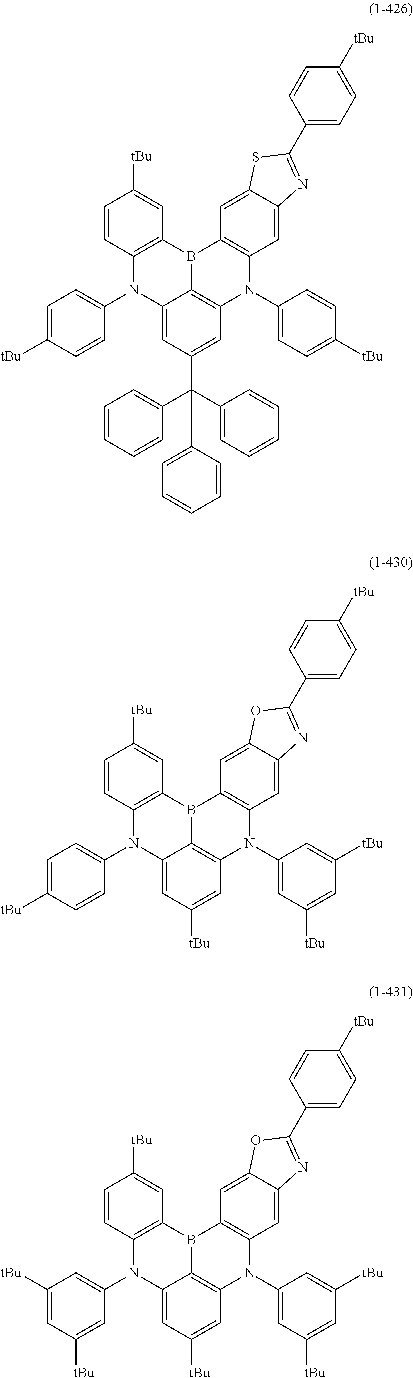 [SMILES: CC(C)(C)c1ccc(-c2nc3cc4c(cc3s2)B2c3cc(C(C)(C)C)ccc3N(c3ccc(C(C)(C)C)cc3)c3cc(C(c5ccccc5)(c5ccccc5)c5ccccc5)cc(c32)N4c2ccc(C(C)(C)C)cc2)cc1 ; CC(C)(C)c1ccc(-c2nc3cc4c(cc3o2)B2c3cc(C(C)(C)C)ccc3N(c3ccc(C(C)(C)C)cc3)c3cc(C(C)(C)C)cc(c32)N4c2cc(C(C)(C)C)cc(C(C)(C)C)c2)cc1 ; CC(C)(C)c1ccc(-c2nc3cc4c(cc3o2)B2c3cc(C(C)(C)C)ccc3N(c3cc(C(C)(C)C)cc(C(C)(C)C)c3)c3cc(C(C)(C)C)cc(c32)N4c2cc(C(C)(C)C)cc(C(C)(C)C)c2)cc1]

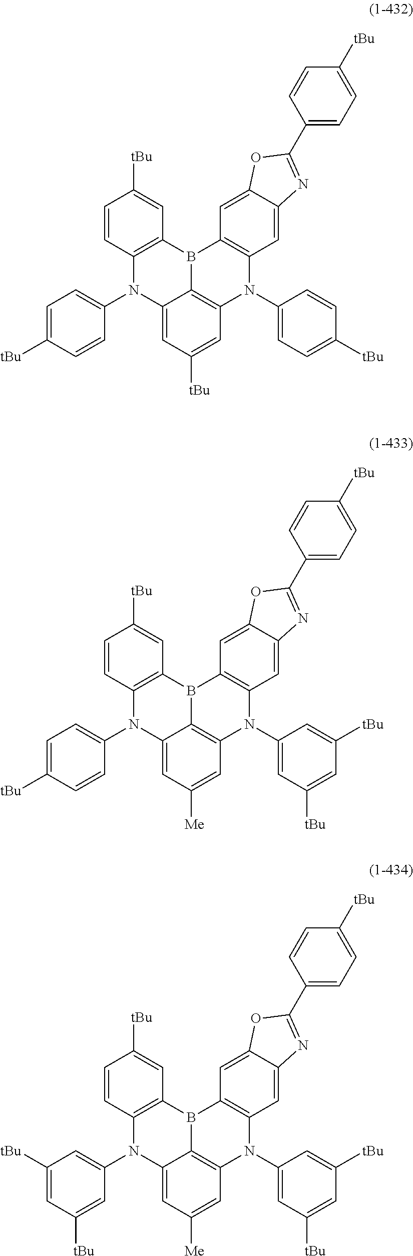 [SMILES: CC(C)(C)c1ccc(-c2nc3cc4c(cc3o2)B2c3cc(C(C)(C)C)ccc3N(c3ccc(C(C)(C)C)cc3)c3cc(C(C)(C)C)cc(c32)N4c2ccc(C(C)(C)C)cc2)cc1 ; Cc1cc2c3c(c1)N(c1cc(C(C)(C)C)cc(C(C)(C)C)c1)c1cc4nc(-c5ccc(C(C)(C)C)cc5)oc4cc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1cc4nc(-c5ccc(C(C)(C)C)cc5)oc4cc1B3c1cc(C(C)(C)C)ccc1N2c1cc(C(C)(C)C)cc(C(C)(C)C)c1]

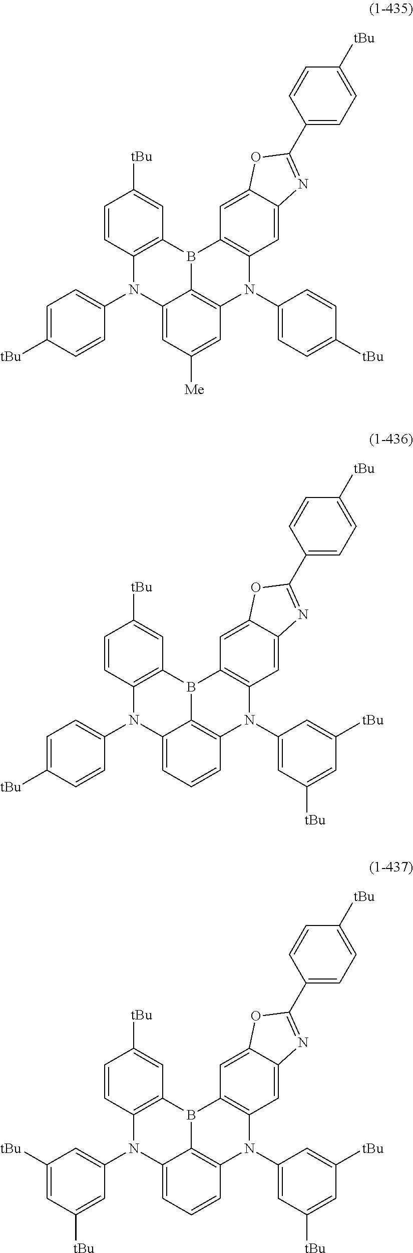 [SMILES: Cc1cc2c3c(c1)N(c1ccc(C(C)(C)C)cc1)c1cc4nc(-c5ccc(C(C)(C)C)cc5)oc4cc1B3c1cc(C(C)(C)C)ccc1N2c1ccc(C(C)(C)C)cc1 ; CC(C)(C)c1ccc(-c2nc3cc4c(cc3o2)B2c3cc(C(C)(C)C)ccc3N(c3ccc(C(C)(C)C)cc3)c3cccc(c32)N4c2cc(C(C)(C)C)cc(C(C)(C)C)c2)cc1 ; CC(C)(C)c1ccc(-c2nc3cc4c(cc3o2)B2c3cc(C(C)(C)C)ccc3N(c3cc(C(C)(C)C)cc(C(C)(C)C)c3)c3cccc(c32)N4c2cc(C(C)(C)C)cc(C(C)(C)C)c2)cc1]

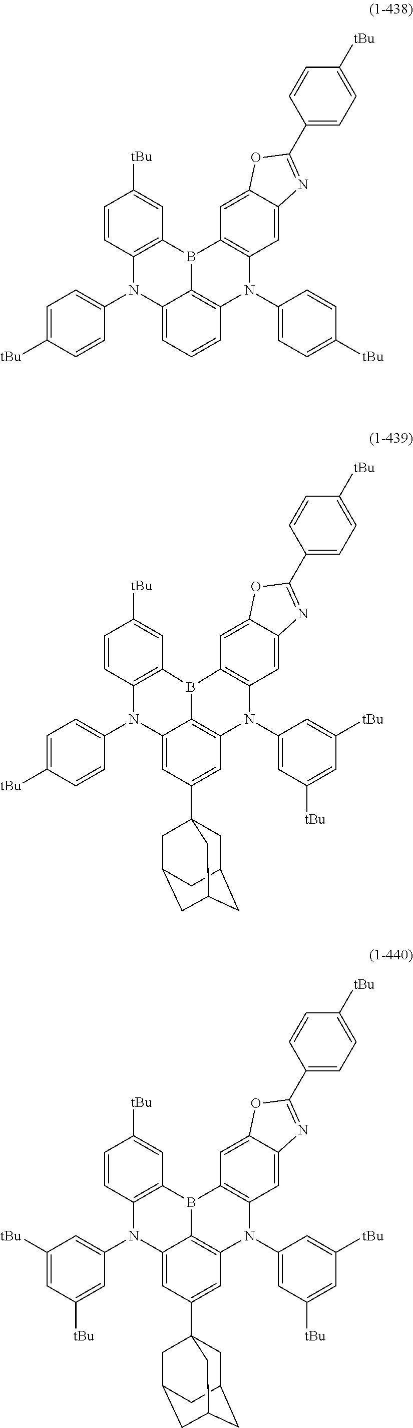 [SMILES: CC(C)(C)c1ccc(-c2nc3cc4c(cc3o2)B2c3cc(C(C)(C)C)ccc3N(c3ccc(C(C)(C)C)cc3)c3cccc(c32)N4c2ccc(C(C)(C)C)cc2)cc1 ; CC(C)(C)c1ccc(-c2nc3cc4c(cc3o2)B2c3cc(C(C)(C)C)ccc3N(c3ccc(C(C)(C)C)cc3)c3cc(C56CC7CC(CC(C7)C5)C6)cc(c32)N4c2cc(C(C)(C)C)cc(C(C)(C)C)c2)cc1 ; CC(C)(C)c1ccc(-c2nc3cc4c(cc3o2)B2c3cc(C(C)(C)C)ccc3N(c3cc(C(C)(C)C)cc(C(C)(C)C)c3)c3cc(C56CC7CC(CC(C7)C5)C6)cc(c32)N4c2cc(C(C)(C)C)cc(C(C)(C)C)c2)cc1]

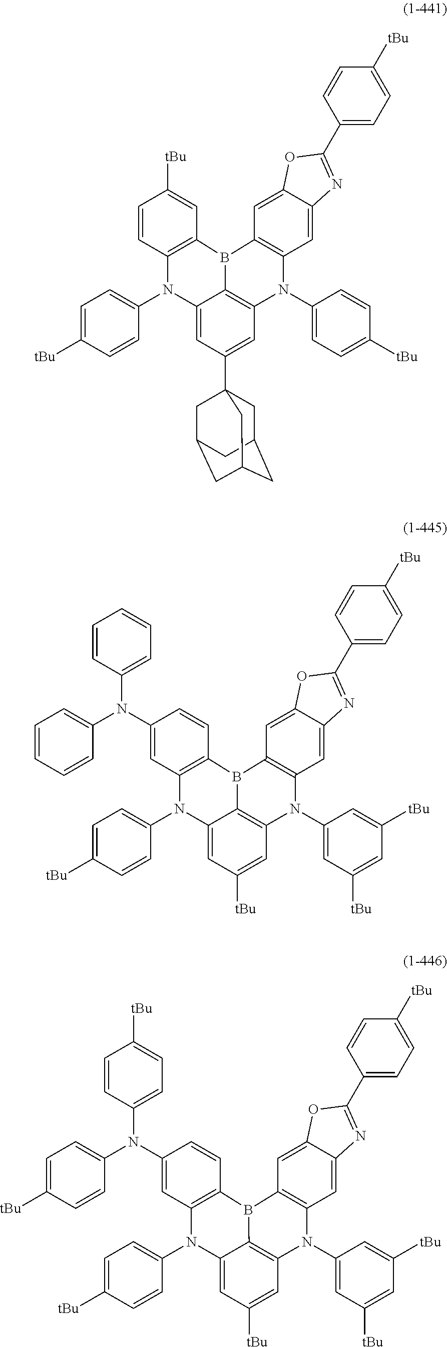 [SMILES: CC(C)(C)c1ccc(-c2nc3cc4c(cc3o2)B2c3cc(C(C)(C)C)ccc3N(c3ccc(C(C)(C)C)cc3)c3cc(C56CC7CC(CC(C7)C5)C6)cc(c32)N4c2ccc(C(C)(C)C)cc2)cc1 ; CC(C)(C)c1ccc(-c2nc3cc4c(cc3o2)B2c3ccc(N(c5ccccc5)c5ccccc5)cc3N(c3ccc(C(C)(C)C)cc3)c3cc(C(C)(C)C)cc(c32)N4c2cc(C(C)(C)C)cc(C(C)(C)C)c2)cc1 ; CC(C)(C)c1ccc(-c2nc3cc4c(cc3o2)B2c3ccc(N(c5ccc(C(C)(C)C)cc5)c5ccc(C(C)(C)C)cc5)cc3N(c3ccc(C(C)(C)C)cc3)c3cc(C(C)(C)C)cc(c32)N4c2cc(C(C)(C)C)cc(C(C)(C)C)c2)cc1]

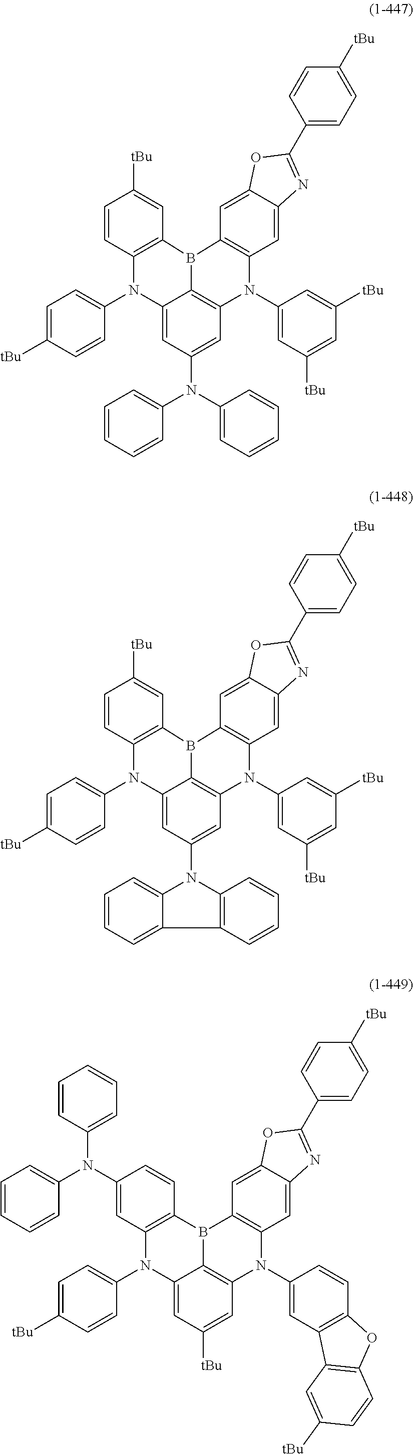 [SMILES: CC(C)(C)c1ccc(-c2nc3cc4c(cc3o2)B2c3cc(C(C)(C)C)ccc3N(c3ccc(C(C)(C)C)cc3)c3cc(N(c5ccccc5)c5ccccc5)cc(c32)N4c2cc(C(C)(C)C)cc(C(C)(C)C)c2)cc1 ; CC(C)(C)c1ccc(-c2nc3cc4c(cc3o2)B2c3cc(C(C)(C)C)ccc3N(c3ccc(C(C)(C)C)cc3)c3cc(-n5c6ccccc6c6ccccc65)cc(c32)N4c2cc(C(C)(C)C)cc(C(C)(C)C)c2)cc1 ; CC(C)(C)c1ccc(-c2nc3cc4c(cc3o2)B2c3ccc(N(c5ccccc5)c5ccccc5)cc3N(c3ccc(C(C)(C)C)cc3)c3cc(C(C)(C)C)cc(c32)N4c2ccc3oc4ccc(C(C)(C)C)cc4c3c2)cc1]

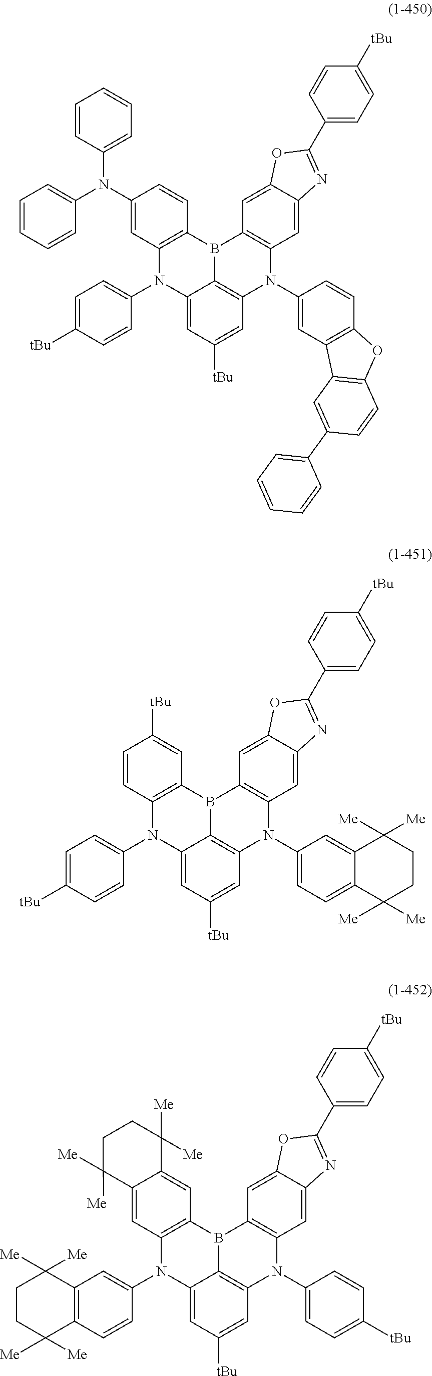 [SMILES: CC(C)(C)c1ccc(-c2nc3cc4c(cc3o2)B2c3ccc(N(c5ccccc5)c5ccccc5)cc3N(c3ccc(C(C)(C)C)cc3)c3cc(C(C)(C)C)cc(c32)N4c2ccc3oc4ccc(-c5ccccc5)cc4c3c2)cc1 ; CC(C)(C)c1ccc(-c2nc3cc4c(cc3o2)B2c3cc(C(C)(C)C)ccc3N(c3ccc(C(C)(C)C)cc3)c3cc(C(C)(C)C)cc(c32)N4c2ccc3c(c2)C(C)(C)CCC3(C)C)cc1 ; CC(C)(C)c1ccc(-c2nc3cc4c(cc3o2)B2c3cc5c(cc3N(c3ccc6c(c3)C(C)(C)CCC6(C)C)c3cc(C(C)(C)C)cc(c32)N4c2ccc(C(C)(C)C)cc2)C(C)(C)CCC5(C)C)cc1]

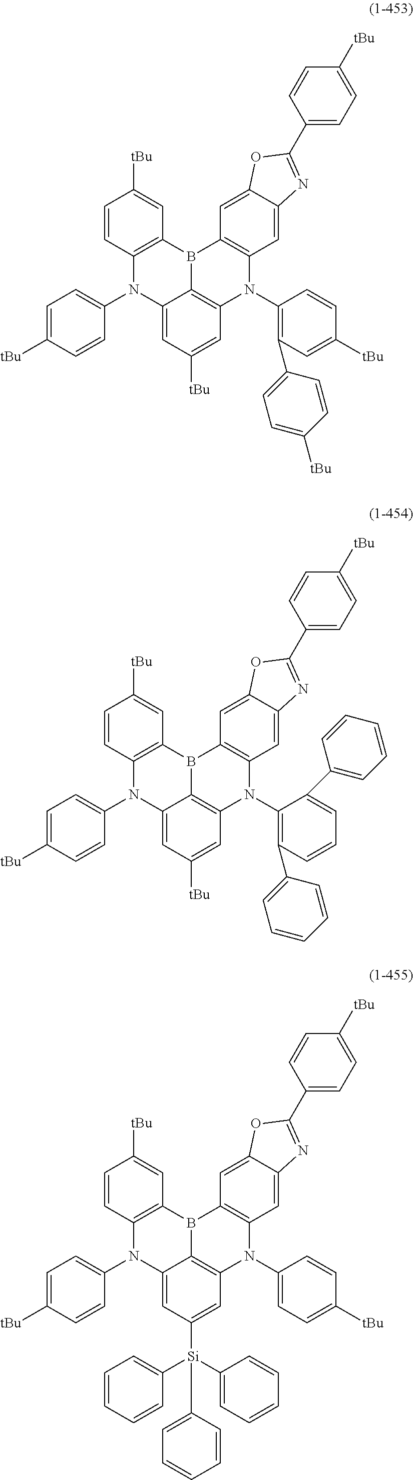 [SMILES: CC(C)(C)c1ccc(-c2nc3cc4c(cc3o2)B2c3cc(C(C)(C)C)ccc3N(c3ccc(C(C)(C)C)cc3)c3cc(C(C)(C)C)cc(c32)N4c2ccc(C(C)(C)C)cc2-c2ccc(C(C)(C)C)cc2)cc1 ; CC(C)(C)c1ccc(-c2nc3cc4c(cc3o2)B2c3cc(C(C)(C)C)ccc3N(c3ccc(C(C)(C)C)cc3)c3cc(C(C)(C)C)cc(c32)N4c2c(-c3ccccc3)cccc2-c2ccccc2)cc1 ; CC(C)(C)c1ccc(-c2nc3cc4c(cc3o2)B2c3cc(C(C)(C)C)ccc3N(c3ccc(C(C)(C)C)cc3)c3cc([Si](c5ccccc5)(c5ccccc5)c5ccccc5)cc(c32)N4c2ccc(C(C)(C)C)cc2)cc1]

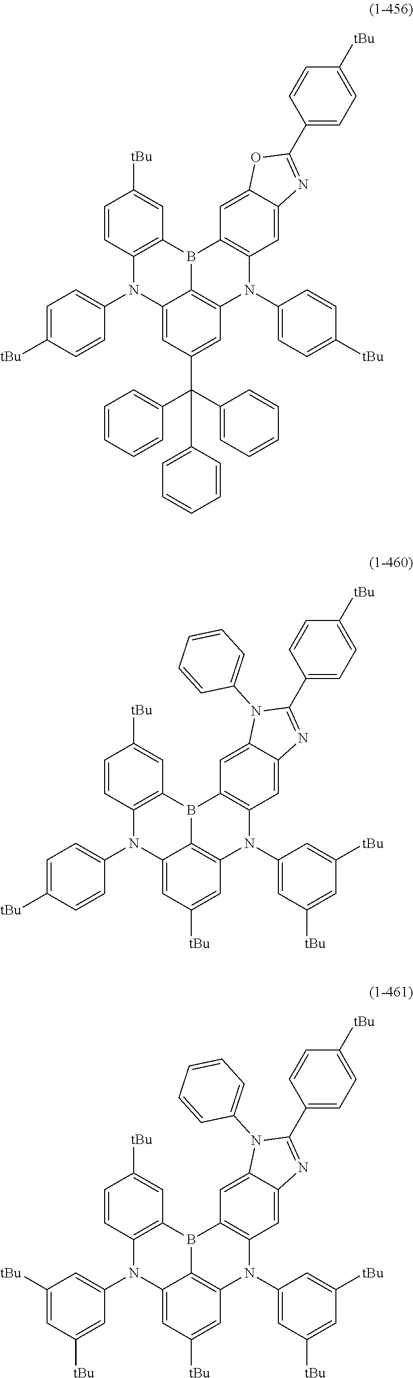 [SMILES: CC(C)(C)c1ccc(-c2nc3cc4c(cc3o2)B2c3cc(C(C)(C)C)ccc3N(c3ccc(C(C)(C)C)cc3)c3cc(C(c5ccccc5)(c5ccccc5)c5ccccc5)cc(c32)N4c2ccc(C(C)(C)C)cc2)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc(C(C)(C)C)cc(c32)N4c2cc(C(C)(C)C)cc(C(C)(C)C)c2)cc1 ; CC(C)(C)c1ccc(-c2nc3cc4c(cc3n2-c2ccccc2)B2c3cc(C(C)(C)C)ccc3N(c3cc(C(C)(C)C)cc(C(C)(C)C)c3)c3cc(C(C)(C)C)cc(c32)N4c2cc(C(C)(C)C)cc(C(C)(C)C)c2)cc1]

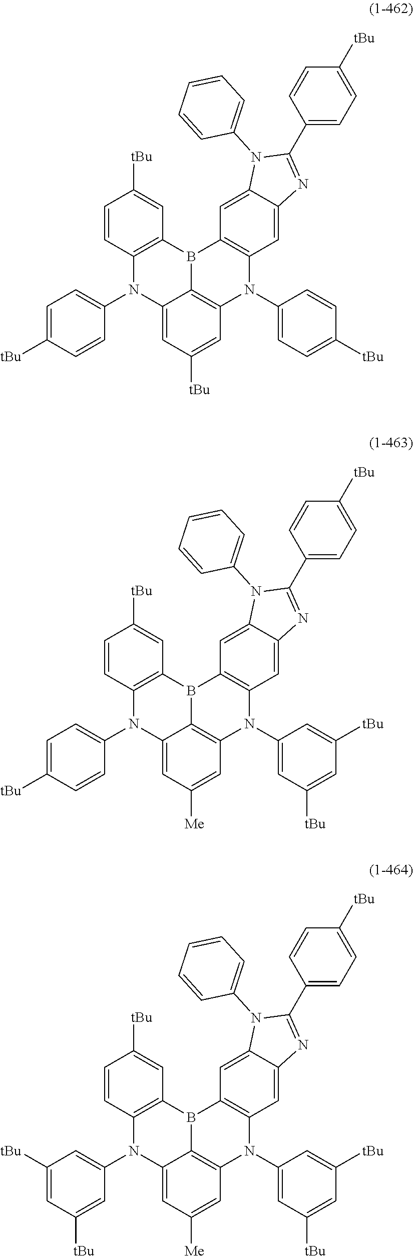 [SMILES: CC(C)(C)c1ccc(-c2nc3cc4c(cc3n2-c2ccccc2)B2c3cc(C(C)(C)C)ccc3N(c3ccc(C(C)(C)C)cc3)c3cc(C(C)(C)C)cc(c32)N4c2ccc(C(C)(C)C)cc2)cc1 ; Cc1cc2c3c(c1)N(c1cc(C(C)(C)C)cc(C(C)(C)C)c1)c1cc4nc(-c5ccc(C(C)(C)C)cc5)n(-c5ccccc5)c4cc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1cc4nc(-c5ccc(C(C)(C)C)cc5)n(-c5ccccc5)c4cc1B3c1cc(C(C)(C)C)ccc1N2c1cc(C(C)(C)C)cc(C(C)(C)C)c1]

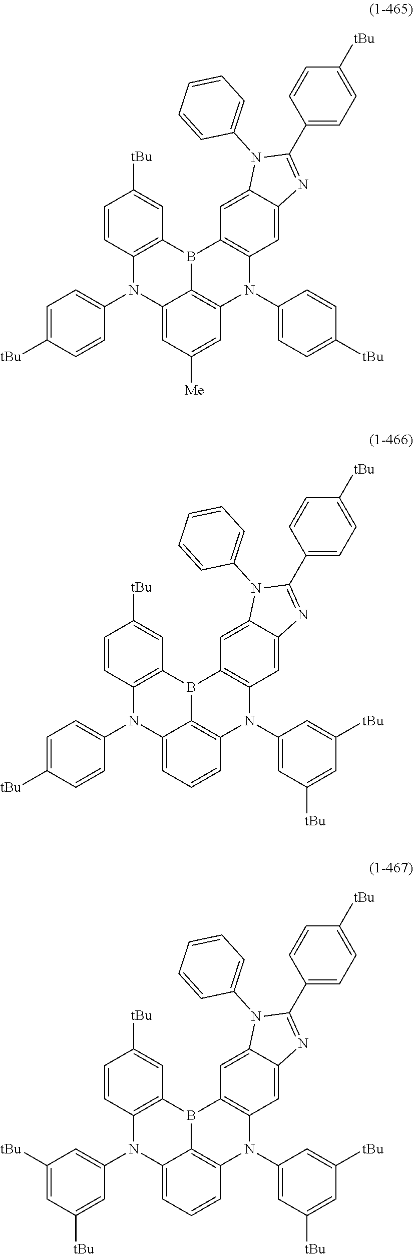 [SMILES: Cc1cc2c3c(c1)N(c1ccc(C(C)(C)C)cc1)c1cc4nc(-c5ccc(C(C)(C)C)cc5)n(-c5ccccc5)c4cc1B3c1cc(C(C)(C)C)ccc1N2c1ccc(C(C)(C)C)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cccc(c32)N4c2cc(C(C)(C)C)cc(C(C)(C)C)c2)cc1 ; CC(C)(C)c1ccc(-c2nc3cc4c(cc3n2-c2ccccc2)B2c3cc(C(C)(C)C)ccc3N(c3cc(C(C)(C)C)cc(C(C)(C)C)c3)c3cccc(c32)N4c2cc(C(C)(C)C)cc(C(C)(C)C)c2)cc1]

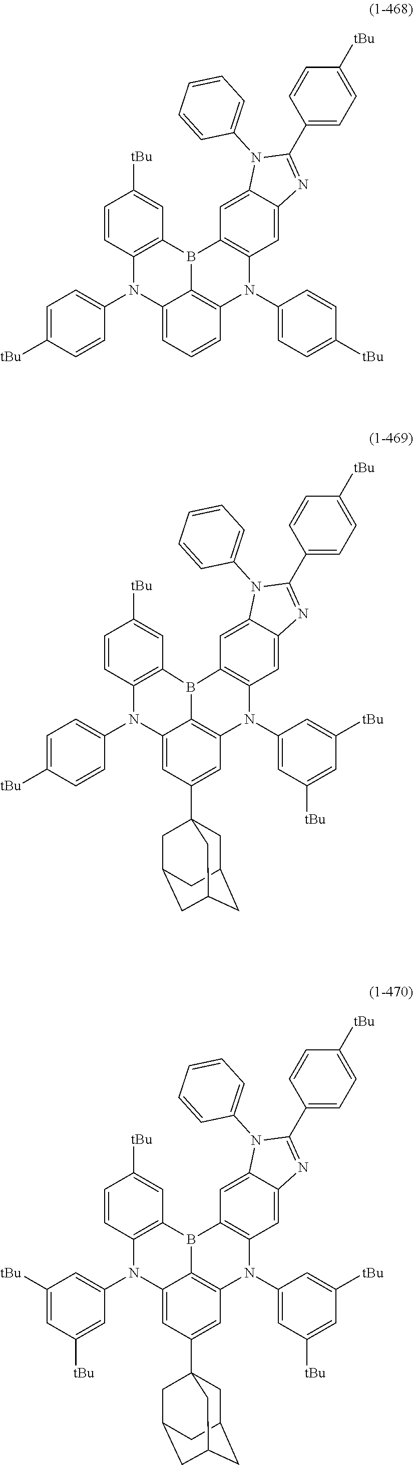 [SMILES: CC(C)(C)c1ccc(-c2nc3cc4c(cc3n2-c2ccccc2)B2c3cc(C(C)(C)C)ccc3N(c3ccc(C(C)(C)C)cc3)c3cccc(c32)N4c2ccc(C(C)(C)C)cc2)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc(C56CC7CC(CC(C7)C5)C6)cc(c32)N4c2cc(C(C)(C)C)cc(C(C)(C)C)c2)cc1 ; CC(C)(C)c1ccc(-c2nc3cc4c(cc3n2-c2ccccc2)B2c3cc(C(C)(C)C)ccc3N(c3cc(C(C)(C)C)cc(C(C)(C)C)c3)c3cc(C56CC7CC(CC(C7)C5)C6)cc(c32)N4c2cc(C(C)(C)C)cc(C(C)(C)C)c2)cc1]

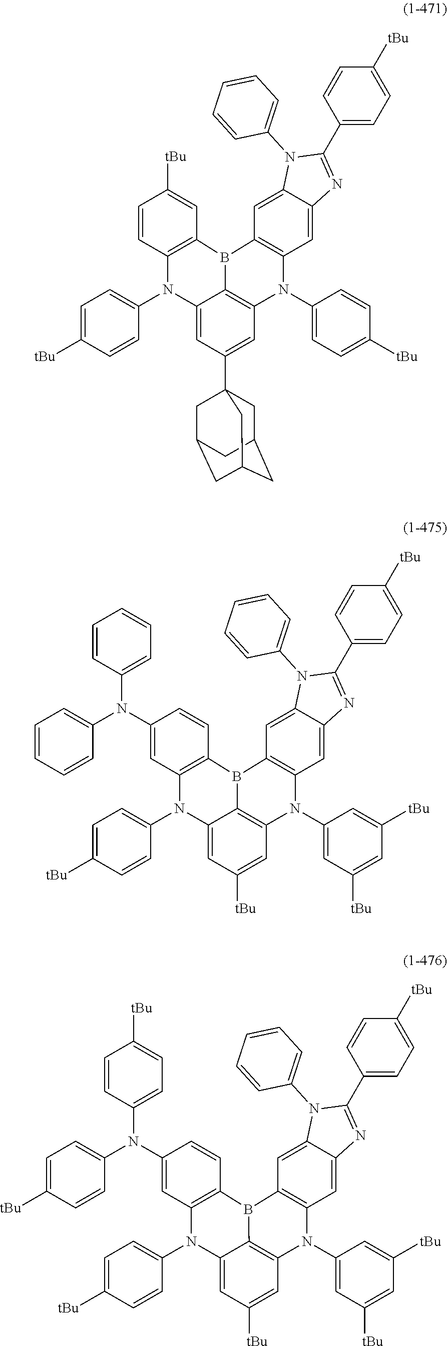 [SMILES: CC(C)(C)c1ccc(-c2nc3cc4c(cc3n2-c2ccccc2)B2c3cc(C(C)(C)C)ccc3N(c3ccc(C(C)(C)C)cc3)c3cc(C56CC7CC(CC(C7)C5)C6)cc(c32)N4c2ccc(C(C)(C)C)cc2)cc1 ; CC(C)(C)c1ccc(-c2nc3cc4c(cc3n2-c2ccccc2)B2c3ccc(N(c5ccccc5)c5ccccc5)cc3N(c3ccc(C(C)(C)C)cc3)c3cc(C(C)(C)C)cc(c32)N4c2cc(C(C)(C)C)cc(C(C)(C)C)c2)cc1 ; CC(C)(C)c1ccc(-c2nc3cc4c(cc3n2-c2ccccc2)B2c3ccc(N(c5ccc(C(C)(C)C)cc5)c5ccc(C(C)(C)C)cc5)cc3N(c3ccc(C(C)(C)C)cc3)c3cc(C(C)(C)C)cc(c32)N4c2cc(C(C)(C)C)cc(C(C)(C)C)c2)cc1]

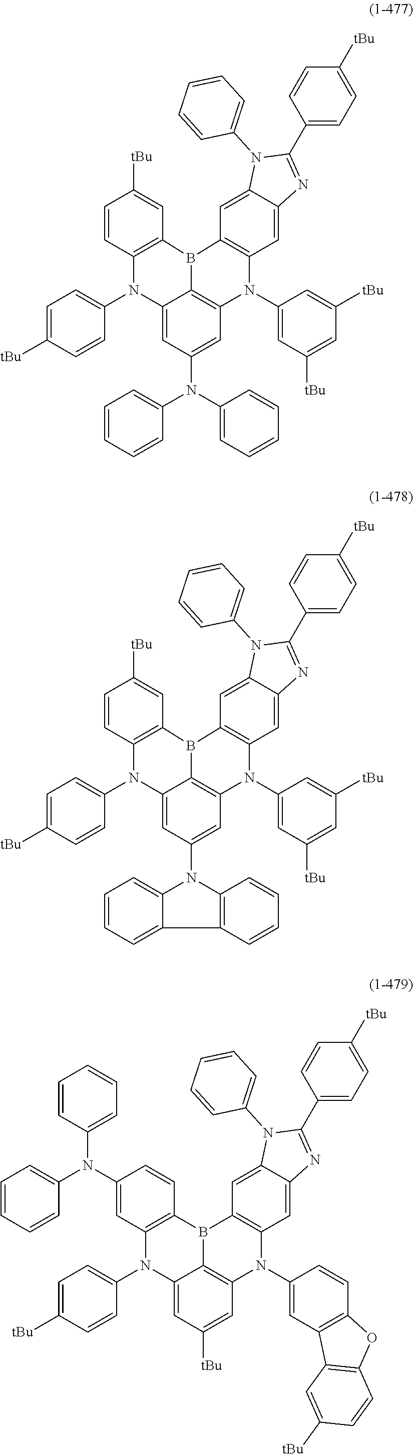 [SMILES: CC(C)(C)c1ccc(-c2nc3cc4c(cc3n2-c2ccccc2)B2c3cc(C(C)(C)C)ccc3N(c3ccc(C(C)(C)C)cc3)c3cc(N(c5ccccc5)c5ccccc5)cc(c32)N4c2cc(C(C)(C)C)cc(C(C)(C)C)c2)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc(-n5c6ccccc6c6ccccc65)cc(c32)N4c2cc(C(C)(C)C)cc(C(C)(C)C)c2)cc1 ; CC(C)(C)c1ccc(-c2nc3cc4c(cc3n2-c2ccccc2)B2c3ccc(N(c5ccccc5)c5ccccc5)cc3N(c3ccc(C(C)(C)C)cc3)c3cc(C(C)(C)C)cc(c32)N4c2ccc3oc4ccc(C(C)(C)C)cc4c3c2)cc1]

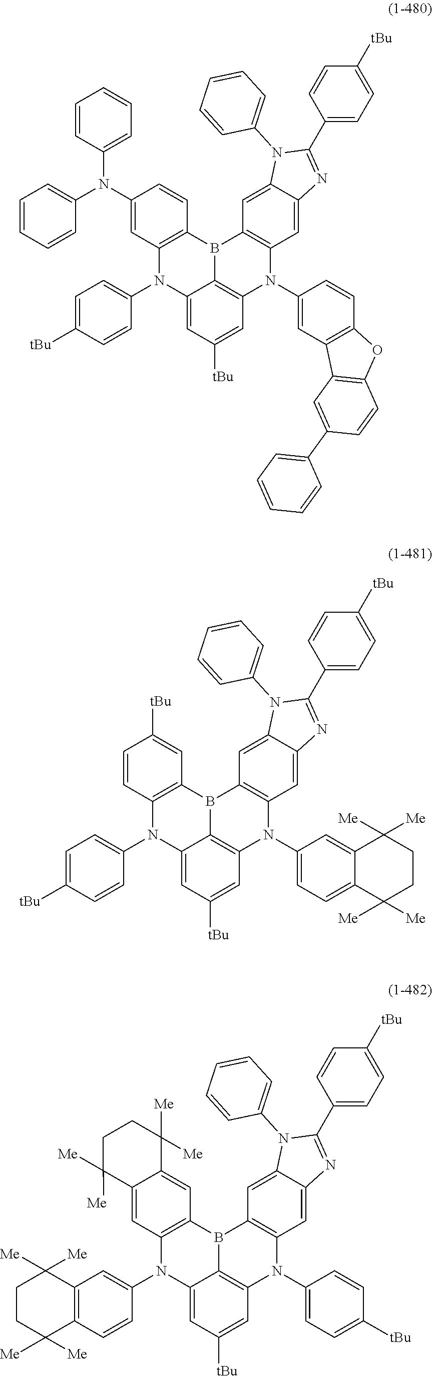 [SMILES: CC(C)(C)c1ccc(-c2nc3cc4c(cc3n2-c2ccccc2)B2c3ccc(N(c5ccccc5)c5ccccc5)cc3N(c3ccc(C(C)(C)C)cc3)c3cc(C(C)(C)C)cc(c32)N4c2ccc3oc4ccc(-c5ccccc5)cc4c3c2)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc(C(C)(C)C)cc(c32)N4c2ccc3c(c2)C(C)(C)CCC3(C)C)cc1 ; CC(C)(C)c1ccc(-c2nc3cc4c(cc3n2-c2ccccc2)B2c3cc5c(cc3N(c3ccc6c(c3)C(C)(C)CCC6(C)C)c3cc(C(C)(C)C)cc(c32)N4c2ccc(C(C)(C)C)cc2)C(C)(C)CCC5(C)C)cc1]

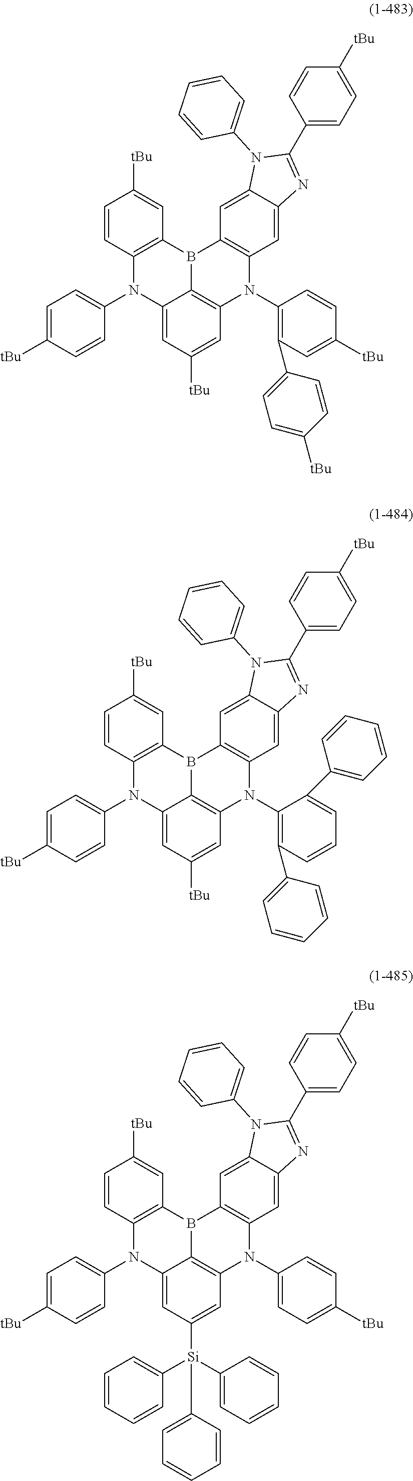 [SMILES: CC(C)(C)c1ccc(-c2cc(C(C)(C)C)ccc2N2c3cc4nc(-c5ccc(C(C)(C)C)cc5)n(-c5ccccc5)c4cc3B3c4cc(C(C)(C)C)ccc4N(c4ccc(C(C)(C)C)cc4)c4cc(C(C)(C)C)cc2c43)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc(C(C)(C)C)cc(c32)N4c2c(-c3ccccc3)cccc2-c2ccccc2)cc1 ; CC(C)(C)c1ccc(-c2nc3cc4c(cc3n2-c2ccccc2)B2c3cc(C(C)(C)C)ccc3N(c3ccc(C(C)(C)C)cc3)c3cc([Si](c5ccccc5)(c5ccccc5)c5ccccc5)cc(c32)N4c2ccc(C(C)(C)C)cc2)cc1]

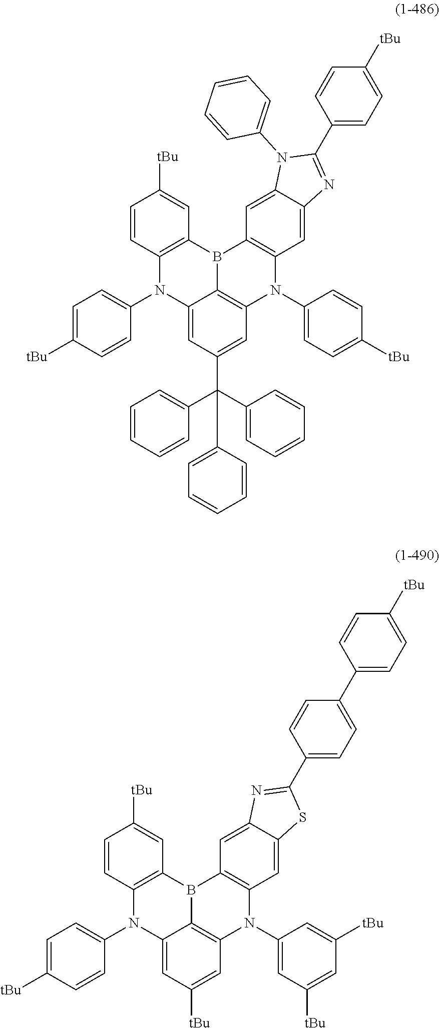 [SMILES: CC(C)(C)c1ccc(-c2nc3cc4c(cc3n2-c2ccccc2)B2c3cc(C(C)(C)C)ccc3N(c3ccc(C(C)(C)C)cc3)c3cc(C(c5ccccc5)(c5ccccc5)c5ccccc5)cc(c32)N4c2ccc(C(C)(C)C)cc2)cc1 ; CC(C)(C)c1ccc(-c2ccc(-c3nc4cc5c(cc4s3)N(c3cc(C(C)(C)C)cc(C(C)(C)C)c3)c3cc(C(C)(C)C)cc4c3B5c3cc(C(C)(C)C)ccc3N4c3ccc(C(C)(C)C)cc3)cc2)cc1]

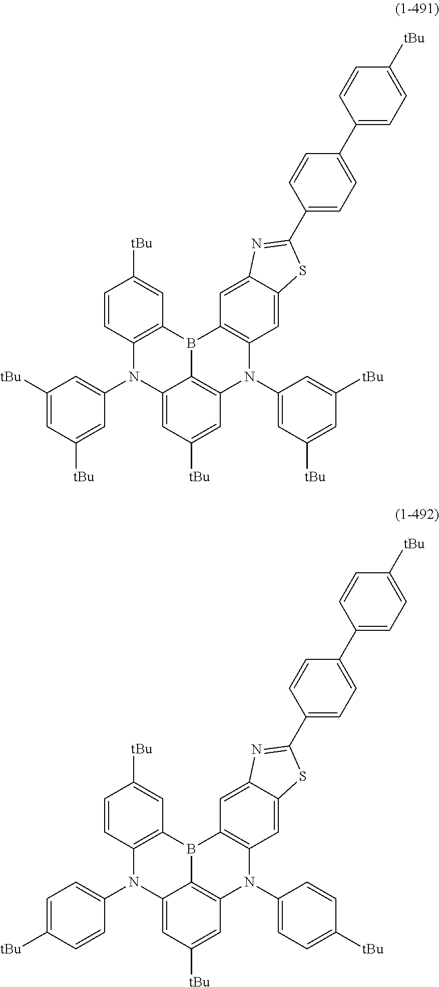 [SMILES: CC(C)(C)c1ccc(-c2ccc(-c3nc4cc5c(cc4s3)N(c3cc(C(C)(C)C)cc(C(C)(C)C)c3)c3cc(C(C)(C)C)cc4c3B5c3cc(C(C)(C)C)ccc3N4c3cc(C(C)(C)C)cc(C(C)(C)C)c3)cc2)cc1 ; CC(C)(C)c1ccc(-c2ccc(-c3nc4cc5c(cc4s3)N(c3ccc(C(C)(C)C)cc3)c3cc(C(C)(C)C)cc4c3B5c3cc(C(C)(C)C)ccc3N4c3ccc(C(C)(C)C)cc3)cc2)cc1]

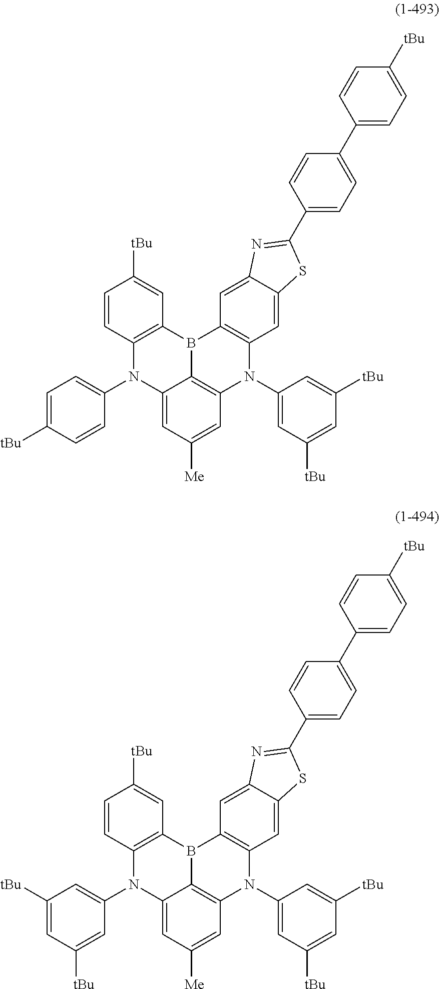 [SMILES: Cc1cc2c3c(c1)N(c1cc(C(C)(C)C)cc(C(C)(C)C)c1)c1cc4sc(-c5ccc(-c6ccc(C(C)(C)C)cc6)cc5)nc4cc1B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1cc4sc(-c5ccc(-c6ccc(C(C)(C)C)cc6)cc5)nc4cc1B3c1cc(C(C)(C)C)ccc1N2c1cc(C(C)(C)C)cc(C(C)(C)C)c1]

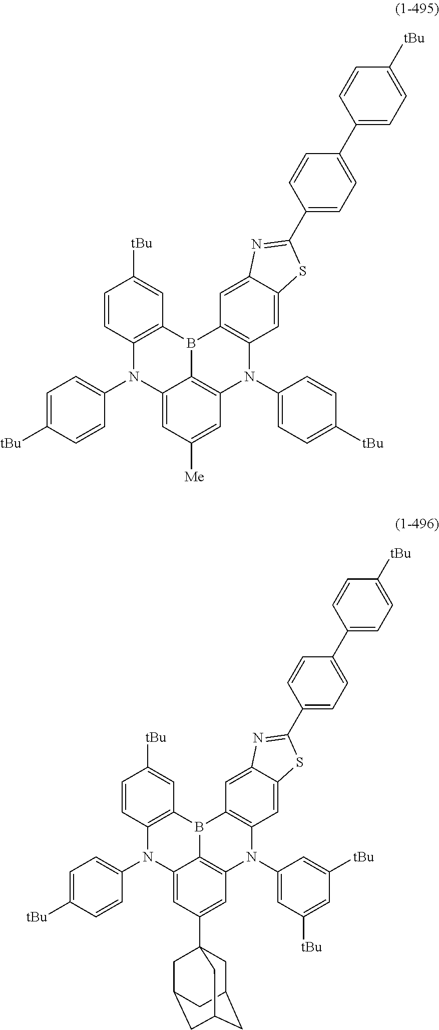 [SMILES: Cc1cc2c3c(c1)N(c1ccc(C(C)(C)C)cc1)c1cc4sc(-c5ccc(-c6ccc(C(C)(C)C)cc6)cc5)nc4cc1B3c1cc(C(C)(C)C)ccc1N2c1ccc(C(C)(C)C)cc1 ; CC(C)(C)c1ccc(-c2ccc(-c3nc4cc5c(cc4s3)N(c3cc(C(C)(C)C)cc(C(C)(C)C)c3)c3cc(C46CC7CC(CC(C7)C4)C6)cc4c3B5c3cc(C(C)(C)C)ccc3N4c3ccc(C(C)(C)C)cc3)cc2)cc1]

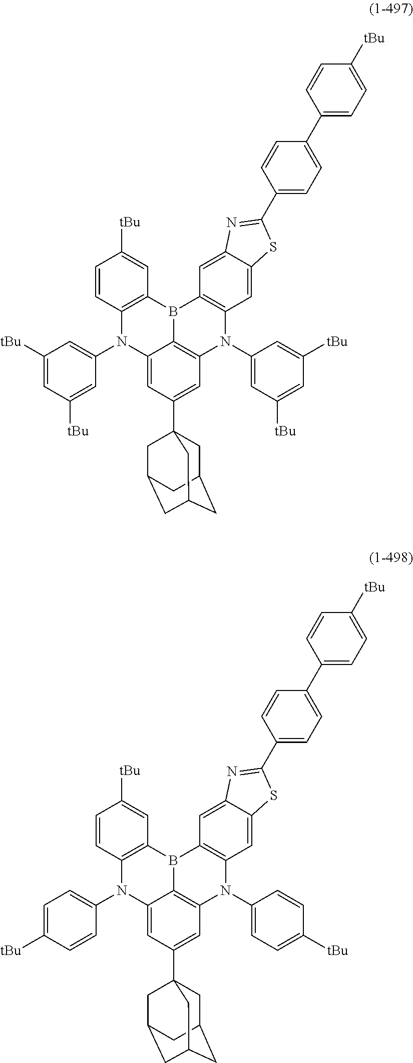 [SMILES: CC(C)(C)c1ccc(-c2ccc(-c3nc4cc5c(cc4s3)N(c3cc(C(C)(C)C)cc(C(C)(C)C)c3)c3cc(C46CC7CC(CC(C7)C4)C6)cc4c3B5c3cc(C(C)(C)C)ccc3N4c3cc(C(C)(C)C)cc(C(C)(C)C)c3)cc2)cc1 ; CC(C)(C)c1ccc(-c2ccc(-c3nc4cc5c(cc4s3)N(c3ccc(C(C)(C)C)cc3)c3cc(C46CC7CC(CC(C7)C4)C6)cc4c3B5c3cc(C(C)(C)C)ccc3N4c3ccc(C(C)(C)C)cc3)cc2)cc1]

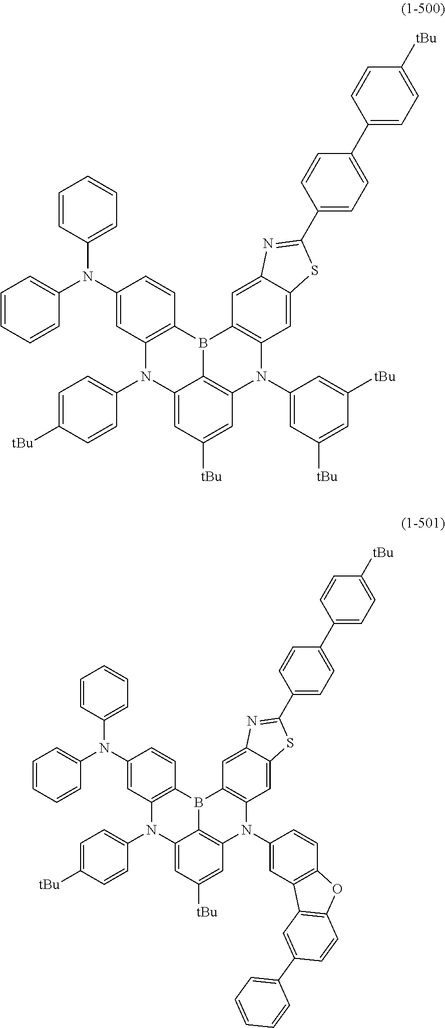 [SMILES: CC(C)(C)c1ccc(-c2ccc(-c3nc4cc5c(cc4s3)N(c3cc(C(C)(C)C)cc(C(C)(C)C)c3)c3cc(C(C)(C)C)cc4c3B5c3ccc(N(c5ccccc5)c5ccccc5)cc3N4c3ccc(C(C)(C)C)cc3)cc2)cc1 ; CC(C)(C)c1ccc(-c2ccc(-c3nc4cc5c(cc4s3)N(c3ccc4oc6ccc(-c7ccccc7)cc6c4c3)c3cc(C(C)(C)C)cc4c3B5c3ccc(N(c5ccccc5)c5ccccc5)cc3N4c3ccc(C(C)(C)C)cc3)cc2)cc1]

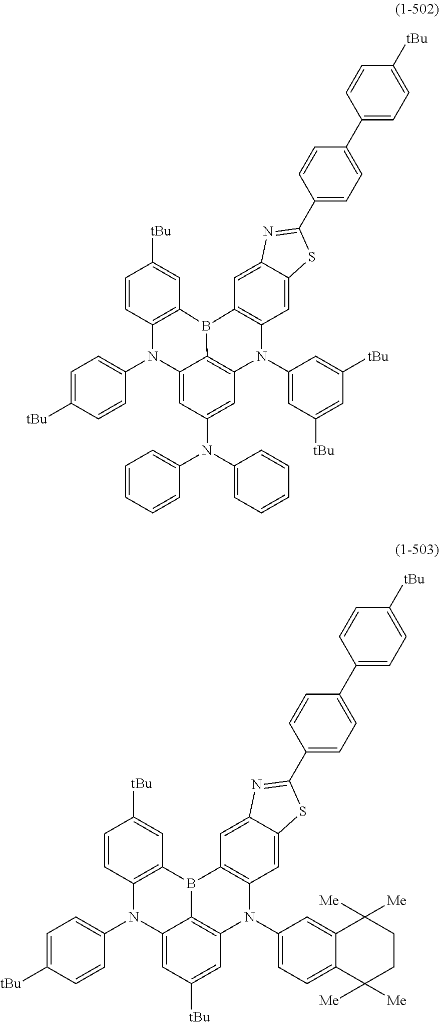 [SMILES: CC(C)(C)c1ccc(-c2ccc(-c3nc4cc5c(cc4s3)N(c3cc(C(C)(C)C)cc(C(C)(C)C)c3)c3cc(N(c4ccccc4)c4ccccc4)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4s3)N(c3ccc4c(c3)C(C)(C)CCC4(C)C)c3cc(C(C)(C)C)cc4c3B5c3cc(C(C)(C)C)ccc3N4c3ccc(C(C)(C)C)cc3)cc2)cc1]

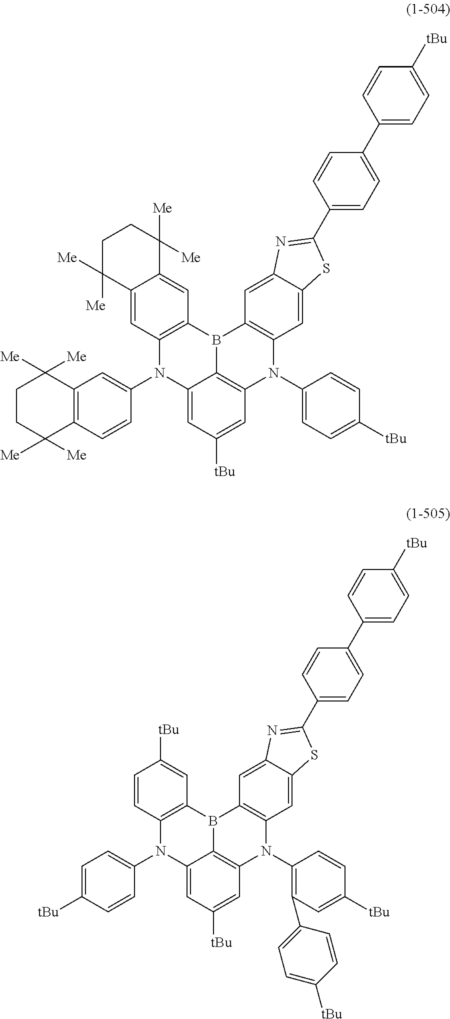 [SMILES: CC(C)(C)c1ccc(-c2ccc(-c3nc4cc5c(cc4s3)N(c3ccc(C(C)(C)C)cc3)c3cc(C(C)(C)C)cc4c3B5c3cc5c(cc3N4c3ccc4c(c3)C(C)(C)CCC4(C)C)C(C)(C)CCC5(C)C)cc2)cc1 ; CC(C)(C)c1ccc(-c2ccc(-c3nc4cc5c(cc4s3)N(c3ccc(C(C)(C)C)cc3-c3ccc(C(C)(C)C)cc3)c3cc(C(C)(C)C)cc4c3B5c3cc(C(C)(C)C)ccc3N4c3ccc(C(C)(C)C)cc3)cc2)cc1]

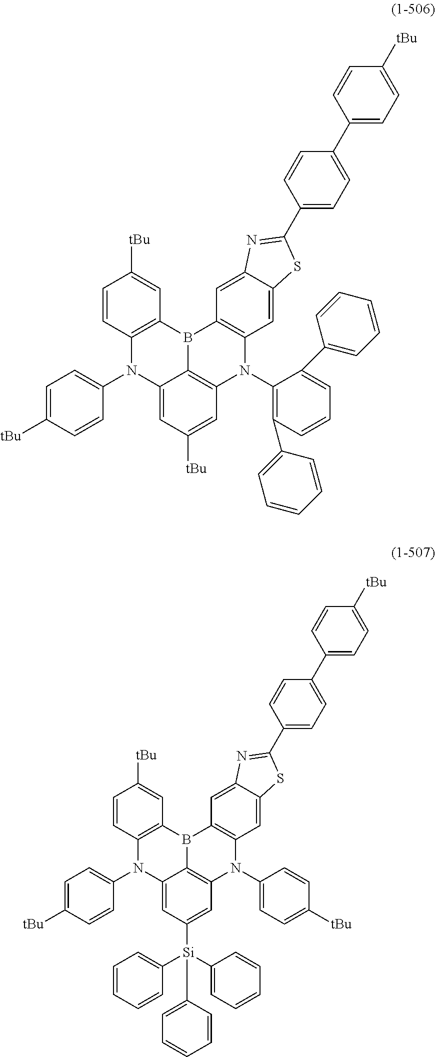 [SMILES: CC(C)(C)c1ccc(-c2ccc(-c3nc4cc5c(cc4s3)N(c3c(-c4ccccc4)cccc3-c3ccccc3)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4s3)N(c3ccc(C(C)(C)C)cc3)c3cc([Si](c4ccccc4)(c4ccccc4)c4ccccc4)cc4c3B5c3cc(C(C)(C)C)ccc3N4c3ccc(C(C)(C)C)cc3)cc2)cc1]

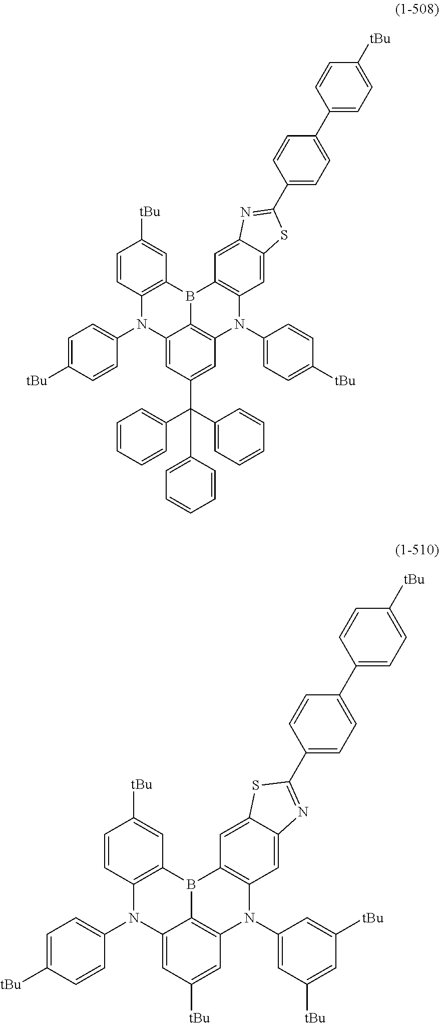 [SMILES: CC(C)(C)c1ccc(-c2ccc(-c3nc4cc5c(cc4s3)N(c3ccc(C(C)(C)C)cc3)c3cc(C(c4ccccc4)(c4ccccc4)c4ccccc4)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4s3)B3c4cc(C(C)(C)C)ccc4N(c4ccc(C(C)(C)C)cc4)c4cc(C(C)(C)C)cc(c43)N5c3cc(C(C)(C)C)cc(C(C)(C)C)c3)cc2)cc1]

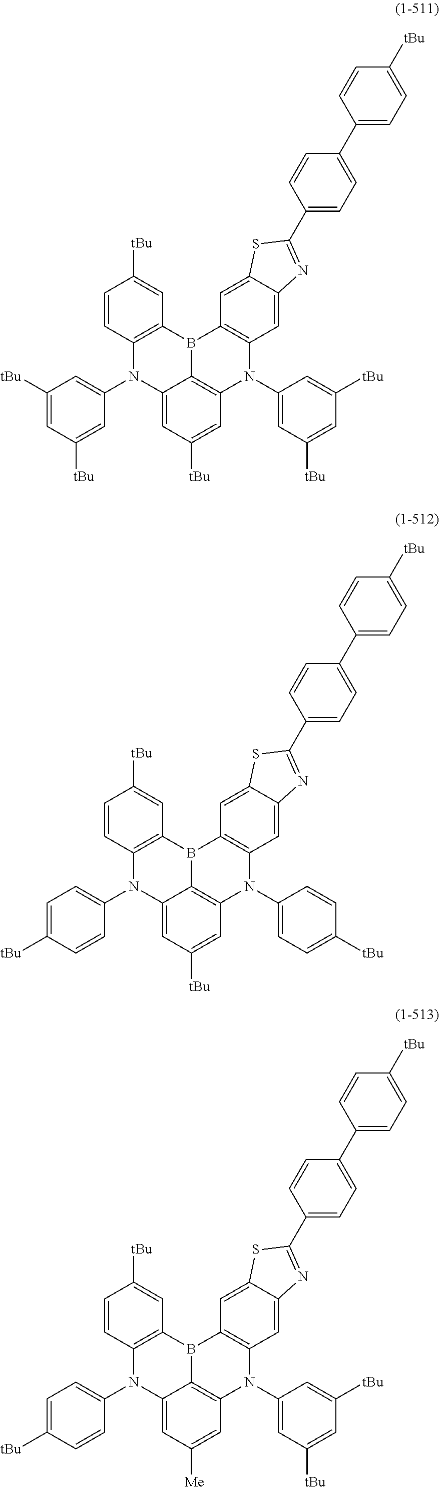 [SMILES: CC(C)(C)c1ccc(-c2ccc(-c3nc4cc5c(cc4s3)B3c4cc(C(C)(C)C)ccc4N(c4cc(C(C)(C)C)cc(C(C)(C)C)c4)c4cc(C(C)(C)C)cc(c43)N5c3cc(C(C)(C)C)cc(C(C)(C)C)c3)cc2)cc1 ; CC(C)(C)c1ccc(-c2ccc(-c3nc4cc5c(cc4s3)B3c4cc(C(C)(C)C)ccc4N(c4ccc(C(C)(C)C)cc4)c4cc(C(C)(C)C)cc(c43)N5c3ccc(C(C)(C)C)cc3)cc2)cc1 ; Cc1cc2c3c(c1)N(c1cc(C(C)(C)C)cc(C(C)(C)C)c1)c1cc4nc(-c5ccc(-c6ccc(C(C)(C)C)cc6)cc5)sc4cc1B3c1cc(C(C)(C)C)ccc1N2c1ccc(C(C)(C)C)cc1]

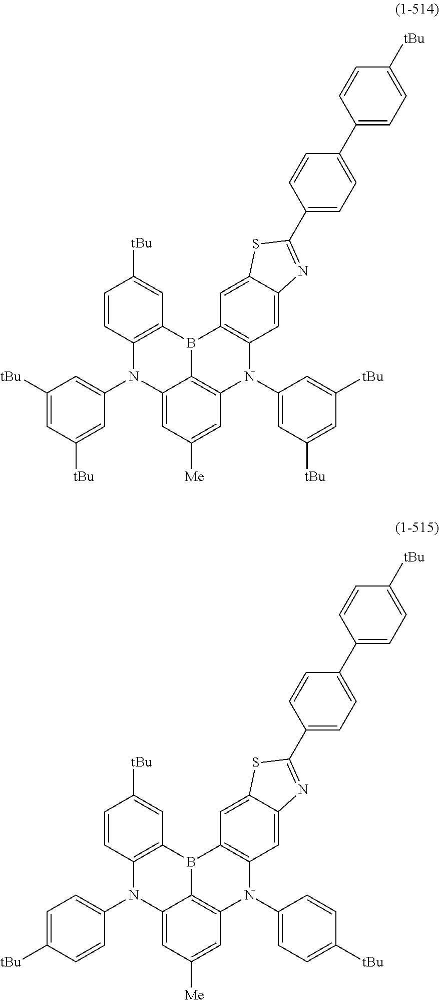 [SMILES: Cc1cc2c3c(c1)N(c1cc(C(C)(C)C)cc(C(C)(C)C)c1)c1cc4nc(-c5ccc(-c6ccc(C(C)(C)C)cc6)cc5)sc4cc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1cc4nc(-c5ccc(-c6ccc(C(C)(C)C)cc6)cc5)sc4cc1B3c1cc(C(C)(C)C)ccc1N2c1ccc(C(C)(C)C)cc1]

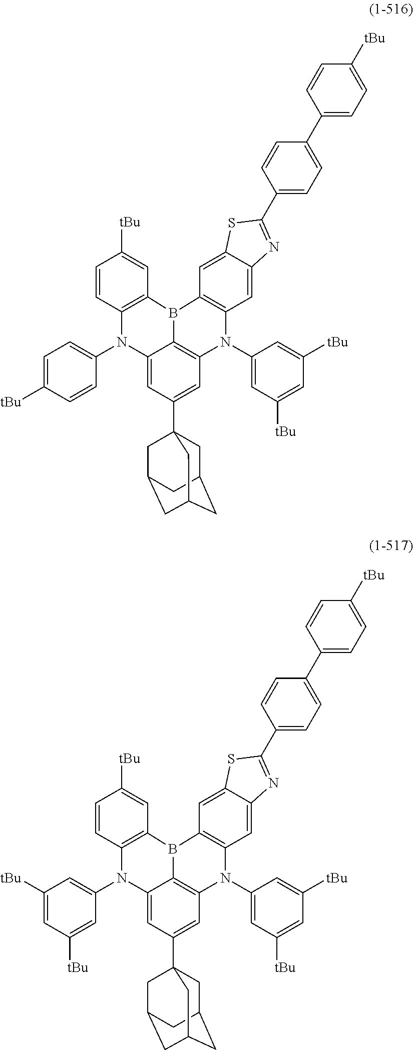 [SMILES: CC(C)(C)c1ccc(-c2ccc(-c3nc4cc5c(cc4s3)B3c4cc(C(C)(C)C)ccc4N(c4ccc(C(C)(C)C)cc4)c4cc(C67CC8CC(CC(C8)C6)C7)cc(c43)N5c3cc(C(C)(C)C)cc(C(C)(C)C)c3)cc2)cc1 ; CC(C)(C)c1ccc(-c2ccc(-c3nc4cc5c(cc4s3)B3c4cc(C(C)(C)C)ccc4N(c4cc(C(C)(C)C)cc(C(C)(C)C)c4)c4cc(C67CC8CC(CC(C8)C6)C7)cc(c43)N5c3cc(C(C)(C)C)cc(C(C)(C)C)c3)cc2)cc1]

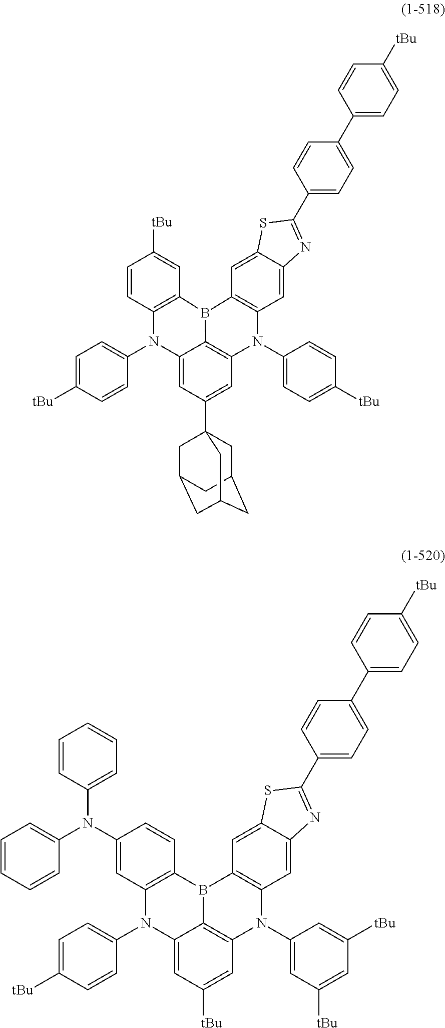 [SMILES: CC(C)(C)c1ccc(-c2ccc(-c3nc4cc5c(cc4s3)B3c4cc(C(C)(C)C)ccc4N(c4ccc(C(C)(C)C)cc4)c4cc(C67CC8CC(CC(C8)C6)C7)cc(c43)N5c3ccc(C(C)(C)C)cc3)cc2)cc1 ; CC(C)(C)c1ccc(-c2ccc(-c3nc4cc5c(cc4s3)B3c4ccc(N(c6ccccc6)c6ccccc6)cc4N(c4ccc(C(C)(C)C)cc4)c4cc(C(C)(C)C)cc(c43)N5c3cc(C(C)(C)C)cc(C(C)(C)C)c3)cc2)cc1]

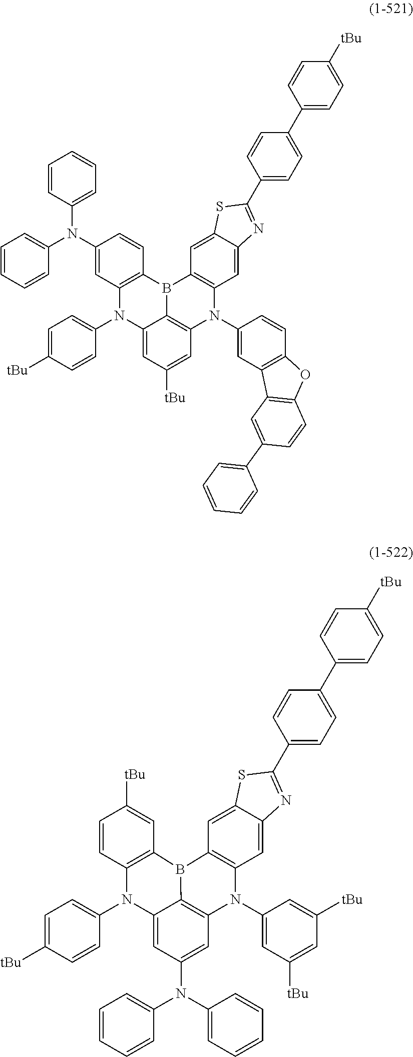 [SMILES: CC(C)(C)c1ccc(-c2ccc(-c3nc4cc5c(cc4s3)B3c4ccc(N(c6ccccc6)c6ccccc6)cc4N(c4ccc(C(C)(C)C)cc4)c4cc(C(C)(C)C)cc(c43)N5c3ccc4oc5ccc(-c6ccccc6)cc5c4c3)cc2)cc1 ; CC(C)(C)c1ccc(-c2ccc(-c3nc4cc5c(cc4s3)B3c4cc(C(C)(C)C)ccc4N(c4ccc(C(C)(C)C)cc4)c4cc(N(c6ccccc6)c6ccccc6)cc(c43)N5c3cc(C(C)(C)C)cc(C(C)(C)C)c3)cc2)cc1]

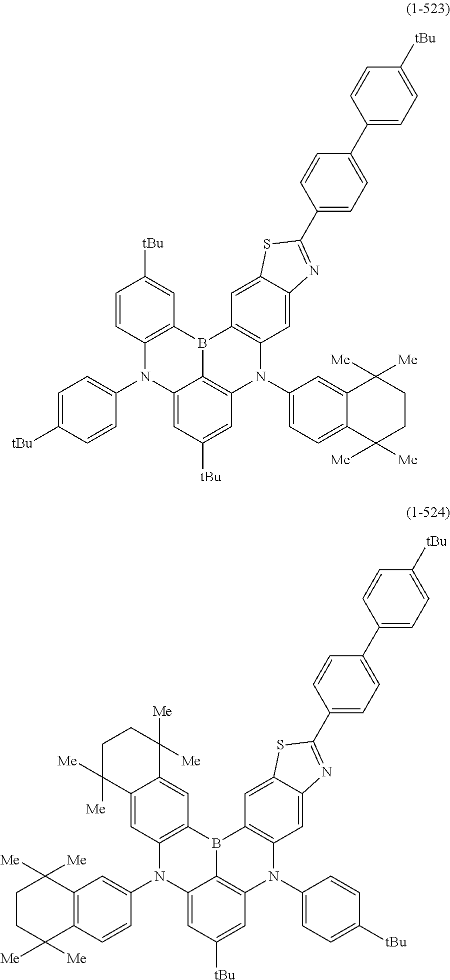 [SMILES: CC(C)(C)c1ccc(-c2ccc(-c3nc4cc5c(cc4s3)B3c4cc(C(C)(C)C)ccc4N(c4ccc(C(C)(C)C)cc4)c4cc(C(C)(C)C)cc(c43)N5c3ccc4c(c3)C(C)(C)CCC4(C)C)cc2)cc1 ; CC(C)(C)c1ccc(-c2ccc(-c3nc4cc5c(cc4s3)B3c4cc6c(cc4N(c4ccc7c(c4)C(C)(C)CCC7(C)C)c4cc(C(C)(C)C)cc(c43)N5c3ccc(C(C)(C)C)cc3)C(C)(C)CCC6(C)C)cc2)cc1]

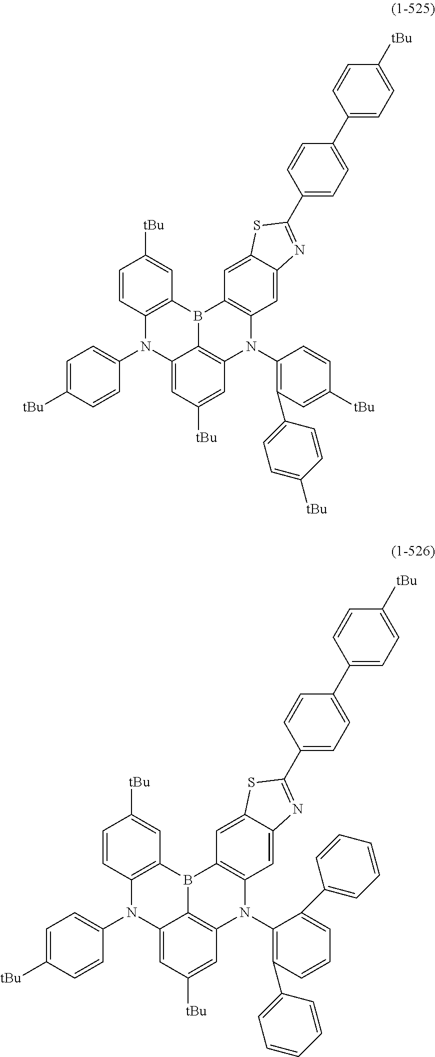 [SMILES: CC(C)(C)c1ccc(-c2ccc(-c3nc4cc5c(cc4s3)B3c4cc(C(C)(C)C)ccc4N(c4ccc(C(C)(C)C)cc4)c4cc(C(C)(C)C)cc(c43)N5c3ccc(C(C)(C)C)cc3-c3ccc(C(C)(C)C)cc3)cc2)cc1 ; CC(C)(C)c1ccc(-c2ccc(-c3nc4cc5c(cc4s3)B3c4cc(C(C)(C)C)ccc4N(c4ccc(C(C)(C)C)cc4)c4cc(C(C)(C)C)cc(c43)N5c3c(-c4ccccc4)cccc3-c3ccccc3)cc2)cc1]

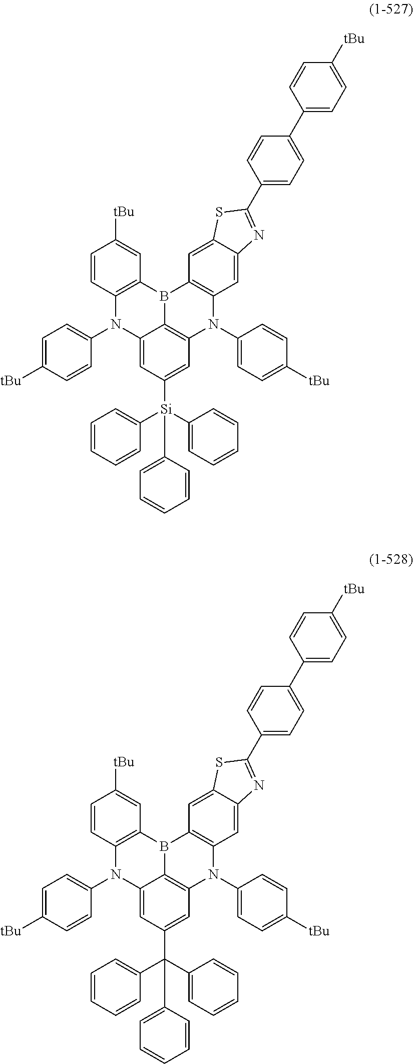 [SMILES: CC(C)(C)c1ccc(-c2ccc(-c3nc4cc5c(cc4s3)B3c4cc(C(C)(C)C)ccc4N(c4ccc(C(C)(C)C)cc4)c4cc([Si](c6ccccc6)(c6ccccc6)c6ccccc6)cc(c43)N5c3ccc(C(C)(C)C)cc3)cc2)cc1 ; CC(C)(C)c1ccc(-c2ccc(-c3nc4cc5c(cc4s3)B3c4cc(C(C)(C)C)ccc4N(c4ccc(C(C)(C)C)cc4)c4cc(C(c6ccccc6)(c6ccccc6)c6ccccc6)cc(c43)N5c3ccc(C(C)(C)C)cc3)cc2)cc1]

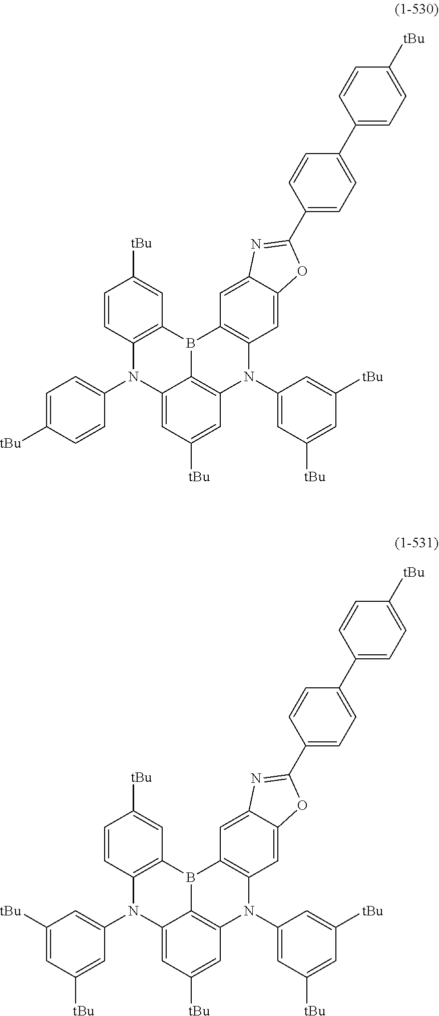 [SMILES: CC(C)(C)c1ccc(-c2ccc(-c3nc4cc5c(cc4o3)N(c3cc(C(C)(C)C)cc(C(C)(C)C)c3)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3cc(C(C)(C)C)cc(C(C)(C)C)c3)c3cc(C(C)(C)C)cc4c3B5c3cc(C(C)(C)C)ccc3N4c3cc(C(C)(C)C)cc(C(C)(C)C)c3)cc2)cc1]

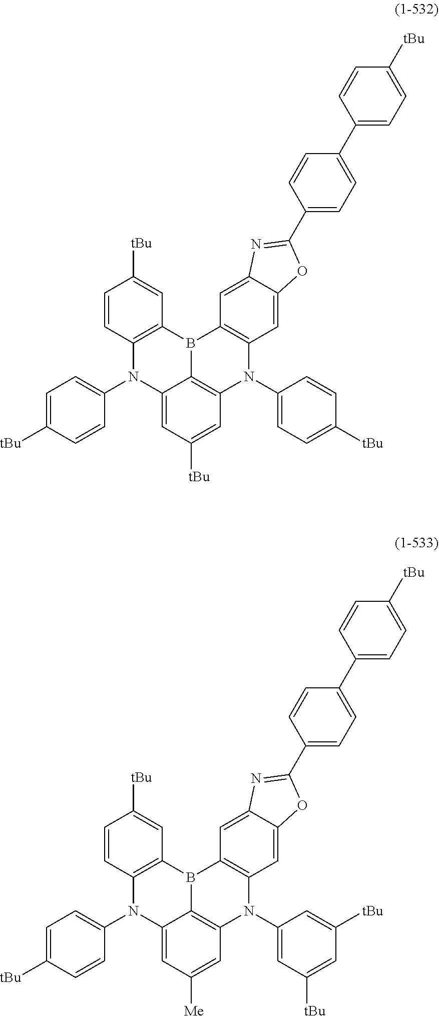 [SMILES: CC(C)(C)c1ccc(-c2ccc(-c3nc4cc5c(cc4o3)N(c3ccc(C(C)(C)C)cc3)c3cc(C(C)(C)C)cc4c3B5c3cc(C(C)(C)C)ccc3N4c3ccc(C(C)(C)C)cc3)cc2)cc1 ; Cc1cc2c3c(c1)N(c1cc(C(C)(C)C)cc(C(C)(C)C)c1)c1cc4oc(-c5ccc(-c6ccc(C(C)(C)C)cc6)cc5)nc4cc1B3c1cc(C(C)(C)C)ccc1N2c1ccc(C(C)(C)C)cc1]

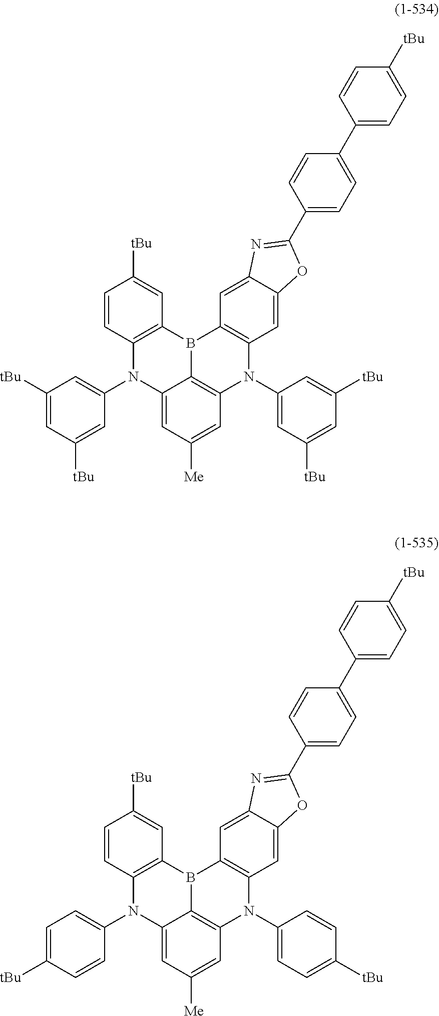 [SMILES: Cc1cc2c3c(c1)N(c1cc(C(C)(C)C)cc(C(C)(C)C)c1)c1cc4oc(-c5ccc(-c6ccc(C(C)(C)C)cc6)cc5)nc4cc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1cc4oc(-c5ccc(-c6ccc(C(C)(C)C)cc6)cc5)nc4cc1B3c1cc(C(C)(C)C)ccc1N2c1ccc(C(C)(C)C)cc1]

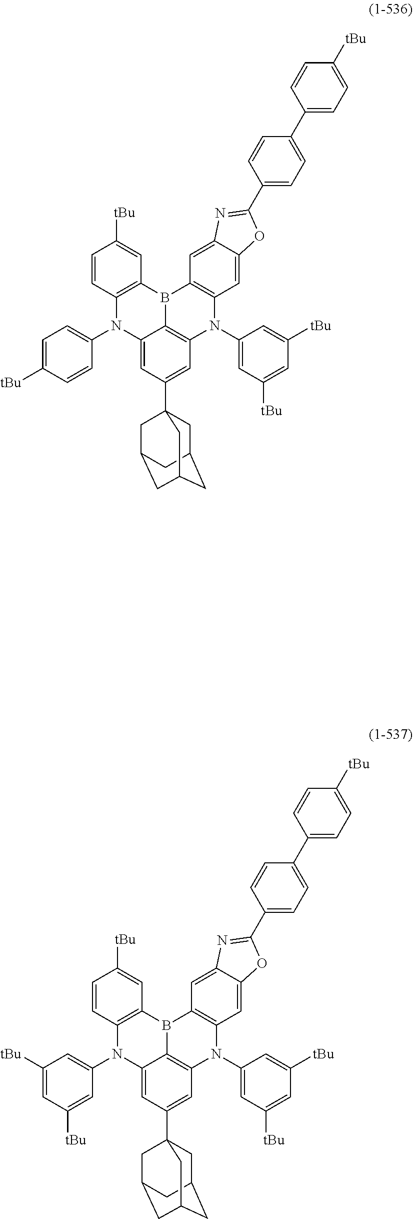 [SMILES: CC(C)(C)c1ccc(-c2ccc(-c3nc4cc5c(cc4o3)N(c3cc(C(C)(C)C)cc(C(C)(C)C)c3)c3cc(C46CC7CC(CC(C7)C4)C6)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3cc(C(C)(C)C)cc(C(C)(C)C)c3)c3cc(C46CC7CC(CC(C7)C4)C6)cc4c3B5c3cc(C(C)(C)C)ccc3N4c3cc(C(C)(C)C)cc(C(C)(C)C)c3)cc2)cc1]

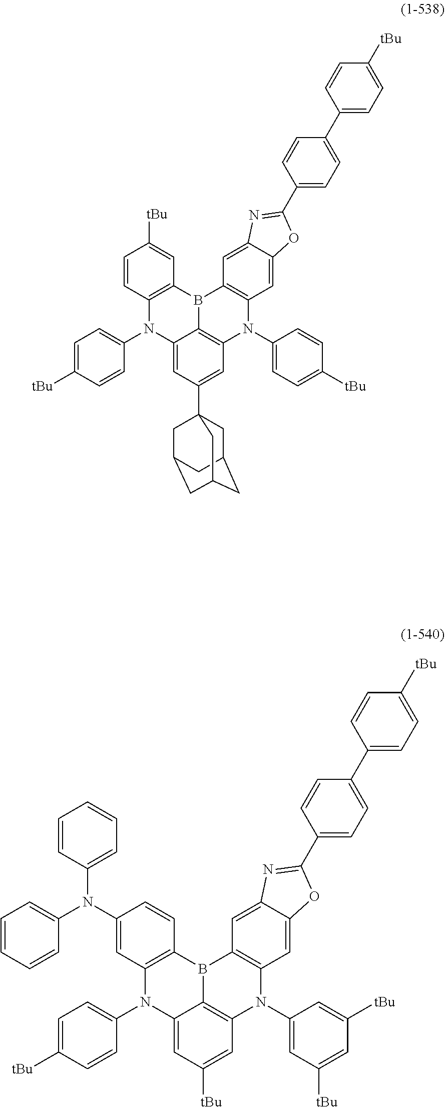 [SMILES: CC(C)(C)c1ccc(-c2ccc(-c3nc4cc5c(cc4o3)N(c3ccc(C(C)(C)C)cc3)c3cc(C46CC7CC(CC(C7)C4)C6)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3cc(C(C)(C)C)cc(C(C)(C)C)c3)c3cc(C(C)(C)C)cc4c3B5c3ccc(N(c5ccccc5)c5ccccc5)cc3N4c3ccc(C(C)(C)C)cc3)cc2)cc1]

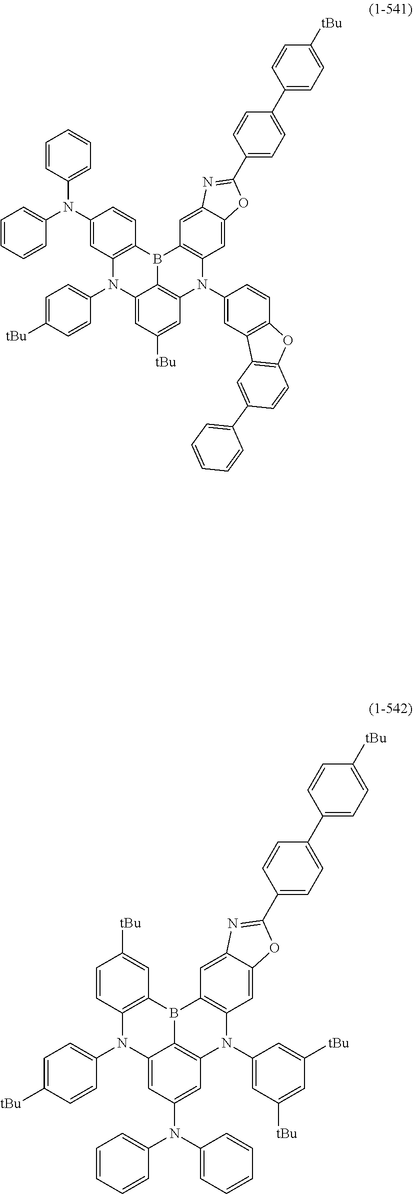 [SMILES: CC(C)(C)c1ccc(-c2ccc(-c3nc4cc5c(cc4o3)N(c3ccc4oc6ccc(-c7ccccc7)cc6c4c3)c3cc(C(C)(C)C)cc4c3B5c3ccc(N(c5ccccc5)c5ccccc5)cc3N4c3ccc(C(C)(C)C)cc3)cc2)cc1 ; CC(C)(C)c1ccc(-c2ccc(-c3nc4cc5c(cc4o3)N(c3cc(C(C)(C)C)cc(C(C)(C)C)c3)c3cc(N(c4ccccc4)c4ccccc4)cc4c3B5c3cc(C(C)(C)C)ccc3N4c3ccc(C(C)(C)C)cc3)cc2)cc1]

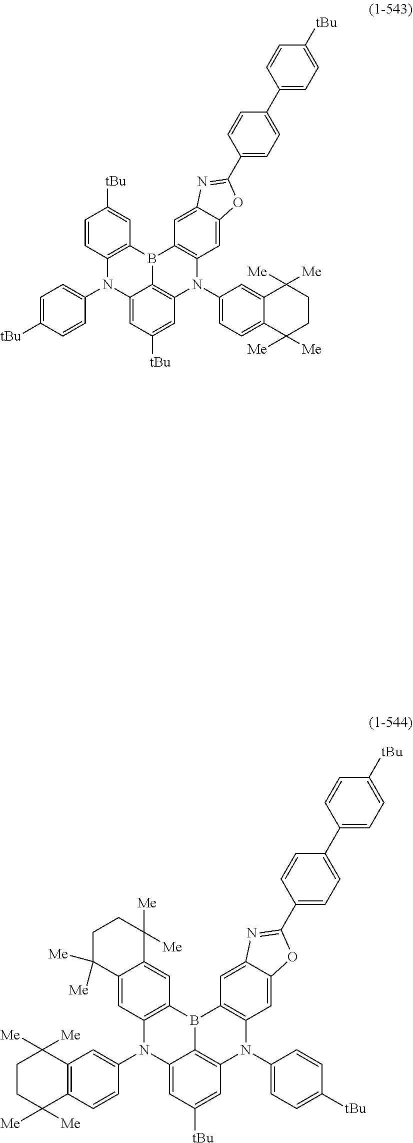 [SMILES: CC(C)(C)c1ccc(-c2ccc(-c3nc4cc5c(cc4o3)N(c3ccc4c(c3)C(C)(C)CCC4(C)C)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3ccc(C(C)(C)C)cc3)c3cc(C(C)(C)C)cc4c3B5c3cc5c(cc3N4c3ccc4c(c3)C(C)(C)CCC4(C)C)C(C)(C)CCC5(C)C)cc2)cc1]

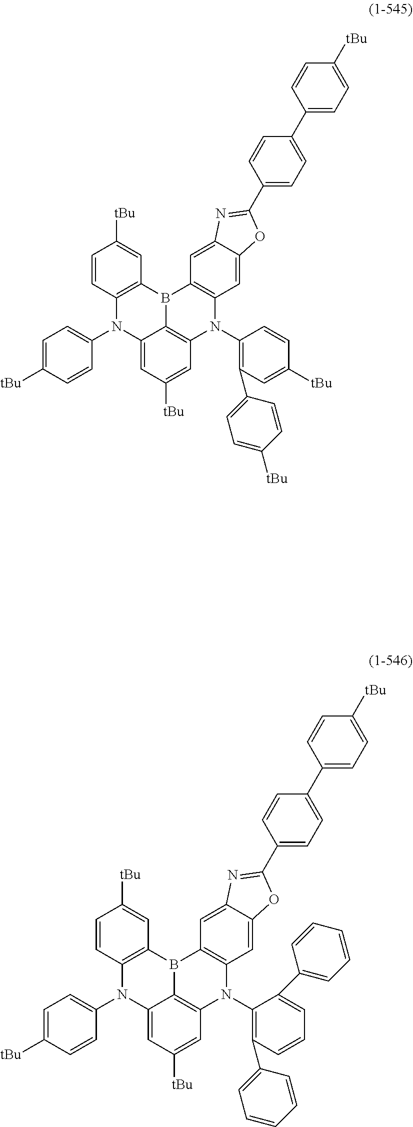 [SMILES: CC(C)(C)c1ccc(-c2ccc(-c3nc4cc5c(cc4o3)N(c3ccc(C(C)(C)C)cc3-c3ccc(C(C)(C)C)cc3)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3c(-c4ccccc4)cccc3-c3ccccc3)c3cc(C(C)(C)C)cc4c3B5c3cc(C(C)(C)C)ccc3N4c3ccc(C(C)(C)C)cc3)cc2)cc1]

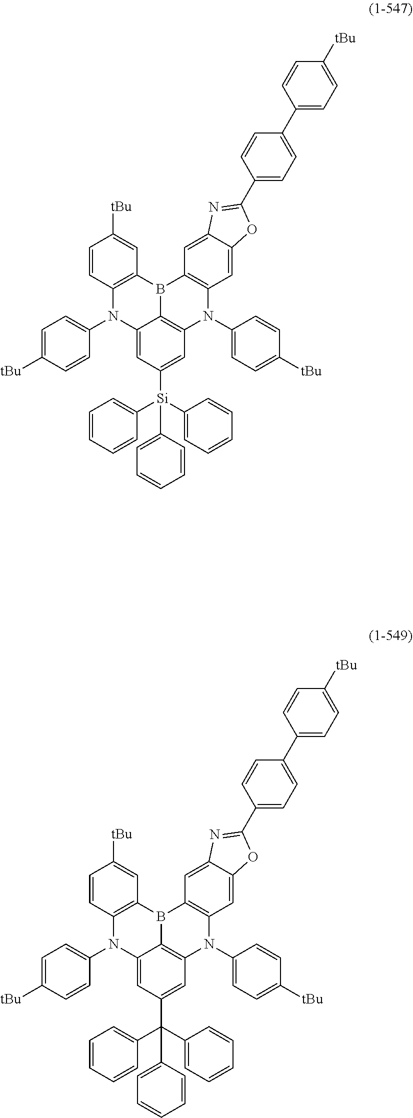 [SMILES: CC(C)(C)c1ccc(-c2ccc(-c3nc4cc5c(cc4o3)N(c3ccc(C(C)(C)C)cc3)c3cc([Si](c4ccccc4)(c4ccccc4)c4ccccc4)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4o3)N(c3ccc(C(C)(C)C)cc3)c3cc(C(c4ccccc4)(c4ccccc4)c4ccccc4)cc4c3B5c3cc(C(C)(C)C)ccc3N4c3ccc(C(C)(C)C)cc3)cc2)cc1]

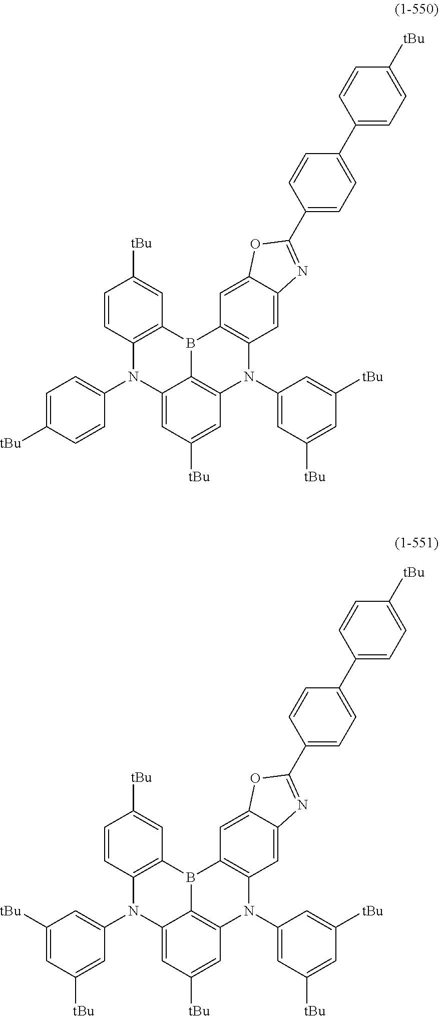 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C(C)(C)C)cc(c43)N5c3cc(C(C)(C)C)cc(C(C)(C)C)c3)cc2)cc1 ; CC(C)(C)c1ccc(-c2ccc(-c3nc4cc5c(cc4o3)B3c4cc(C(C)(C)C)ccc4N(c4cc(C(C)(C)C)cc(C(C)(C)C)c4)c4cc(C(C)(C)C)cc(c43)N5c3cc(C(C)(C)C)cc(C(C)(C)C)c3)cc2)cc1]

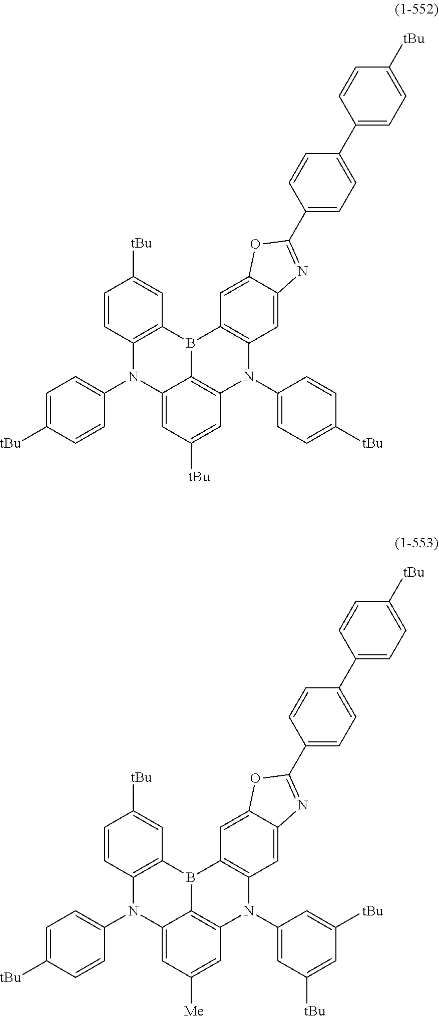 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C(C)(C)C)cc(c43)N5c3ccc(C(C)(C)C)cc3)cc2)cc1 ; Cc1cc2c3c(c1)N(c1cc(C(C)(C)C)cc(C(C)(C)C)c1)c1cc4nc(-c5ccc(-c6ccc(C(C)(C)C)cc6)cc5)oc4cc1B3c1cc(C(C)(C)C)ccc1N2c1ccc(C(C)(C)C)cc1]

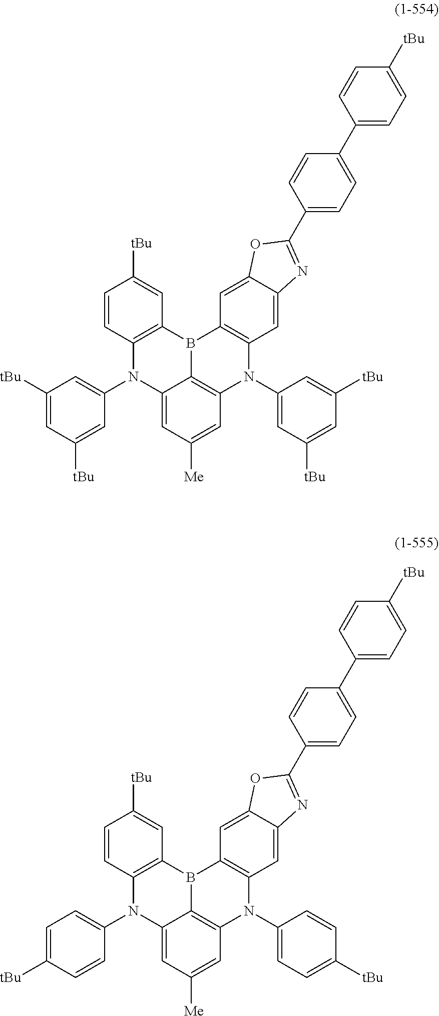 [SMILES: Cc1cc2c3c(c1)N(c1cc(C(C)(C)C)cc(C(C)(C)C)c1)c1cc4nc(-c5ccc(-c6ccc(C(C)(C)C)cc6)cc5)oc4cc1B3c1cc(C(C)(C)C)ccc1N2c1cc(C(C)(C)C)cc(C(C)(C)C)c1 ; Cc1cc2c3c(c1)N(c1ccc(C(C)(C)C)cc1)c1cc4nc(-c5ccc(-c6ccc(C(C)(C)C)cc6)cc5)oc4cc1B3c1cc(C(C)(C)C)ccc1N2c1ccc(C(C)(C)C)cc1]

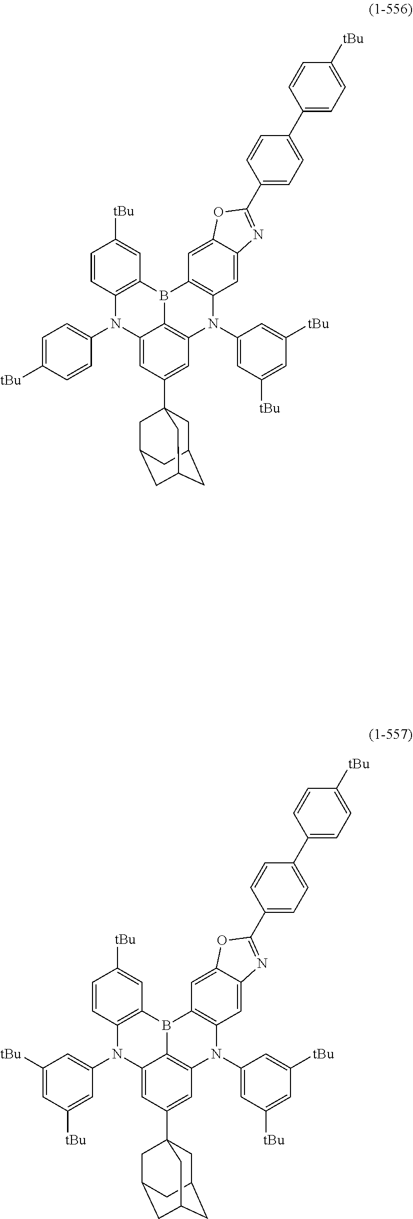 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C67CC8CC(CC(C8)C6)C7)cc(c43)N5c3cc(C(C)(C)C)cc(C(C)(C)C)c3)cc2)cc1 ; CC(C)(C)c1ccc(-c2ccc(-c3nc4cc5c(cc4o3)B3c4cc(C(C)(C)C)ccc4N(c4cc(C(C)(C)C)cc(C(C)(C)C)c4)c4cc(C67CC8CC(CC(C8)C6)C7)cc(c43)N5c3cc(C(C)(C)C)cc(C(C)(C)C)c3)cc2)cc1]

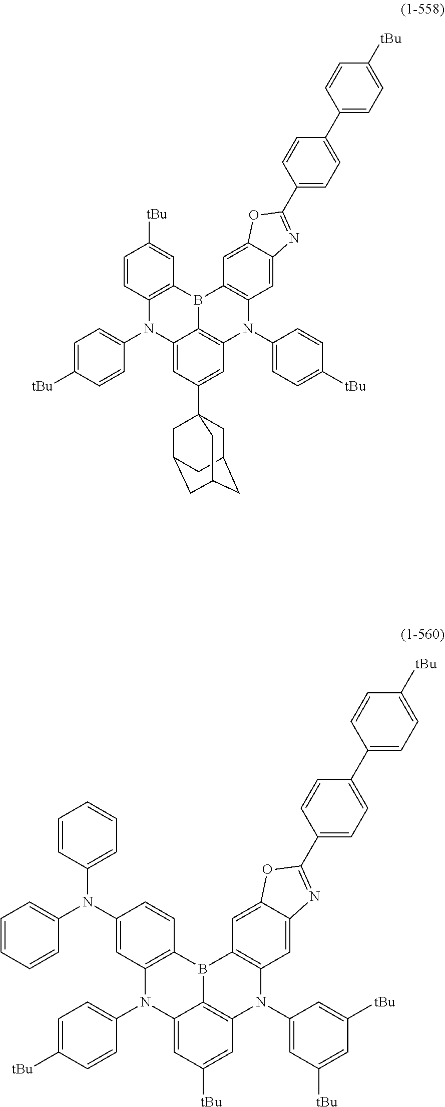 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C67CC8CC(CC(C8)C6)C7)cc(c43)N5c3ccc(C(C)(C)C)cc3)cc2)cc1 ; CC(C)(C)c1ccc(-c2ccc(-c3nc4cc5c(cc4o3)B3c4ccc(N(c6ccccc6)c6ccccc6)cc4N(c4ccc(C(C)(C)C)cc4)c4cc(C(C)(C)C)cc(c43)N5c3cc(C(C)(C)C)cc(C(C)(C)C)c3)cc2)cc1]

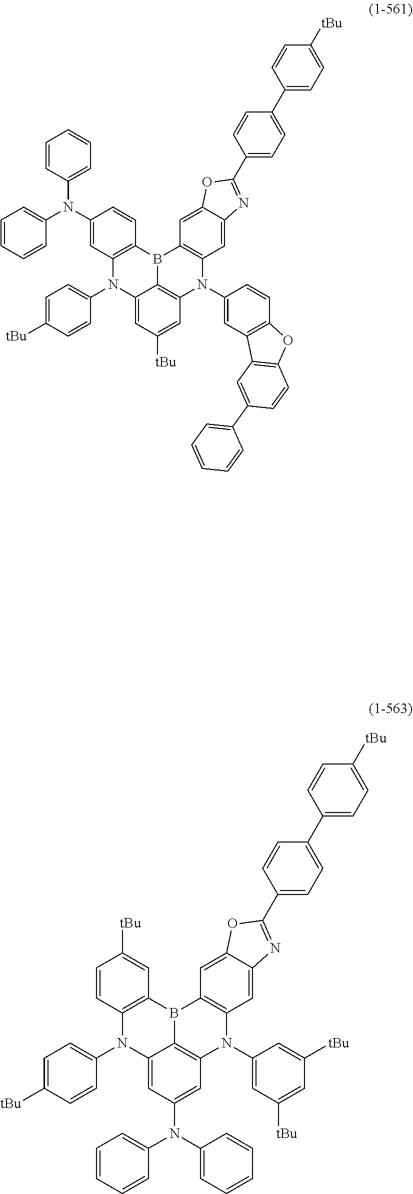 [SMILES: CC(C)(C)c1ccc(-c2ccc(-c3nc4cc5c(cc4o3)B3c4ccc(N(c6ccccc6)c6ccccc6)cc4N(c4ccc(C(C)(C)C)cc4)c4cc(C(C)(C)C)cc(c43)N5c3ccc4oc5ccc(-c6ccccc6)cc5c4c3)cc2)cc1 ; CC(C)(C)c1ccc(-c2ccc(-c3nc4cc5c(cc4o3)B3c4cc(C(C)(C)C)ccc4N(c4ccc(C(C)(C)C)cc4)c4cc(N(c6ccccc6)c6ccccc6)cc(c43)N5c3cc(C(C)(C)C)cc(C(C)(C)C)c3)cc2)cc1]

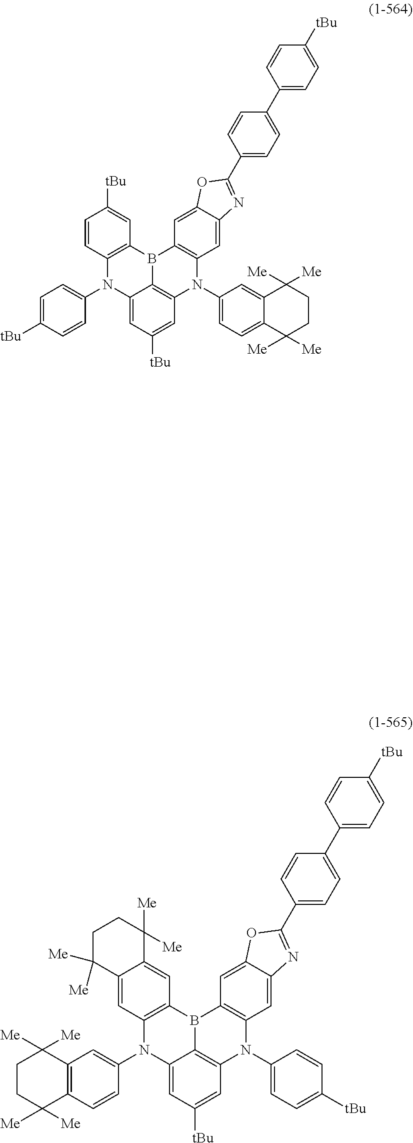 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C(C)(C)C)cc(c43)N5c3ccc4c(c3)C(C)(C)CCC4(C)C)cc2)cc1 ; CC(C)(C)c1ccc(-c2ccc(-c3nc4cc5c(cc4o3)B3c4cc6c(cc4N(c4ccc7c(c4)C(C)(C)CCC7(C)C)c4cc(C(C)(C)C)cc(c43)N5c3ccc(C(C)(C)C)cc3)C(C)(C)CCC6(C)C)cc2)cc1]

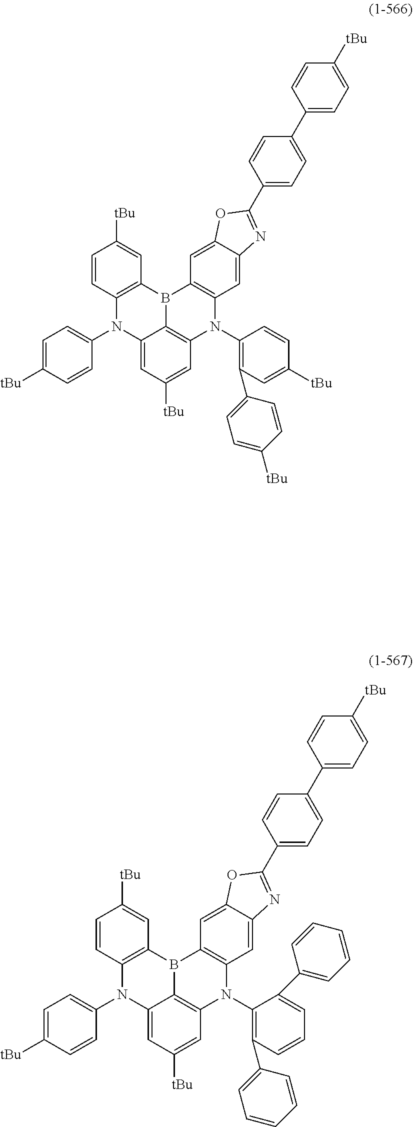 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc(C(C)(C)C)cc(c43)N5c3ccc(C(C)(C)C)cc3-c3ccc(C(C)(C)C)cc3)cc2)cc1 ; CC(C)(C)c1ccc(-c2ccc(-c3nc4cc5c(cc4o3)B3c4cc(C(C)(C)C)ccc4N(c4ccc(C(C)(C)C)cc4)c4cc(C(C)(C)C)cc(c43)N5c3c(-c4ccccc4)cccc3-c3ccccc3)cc2)cc1]

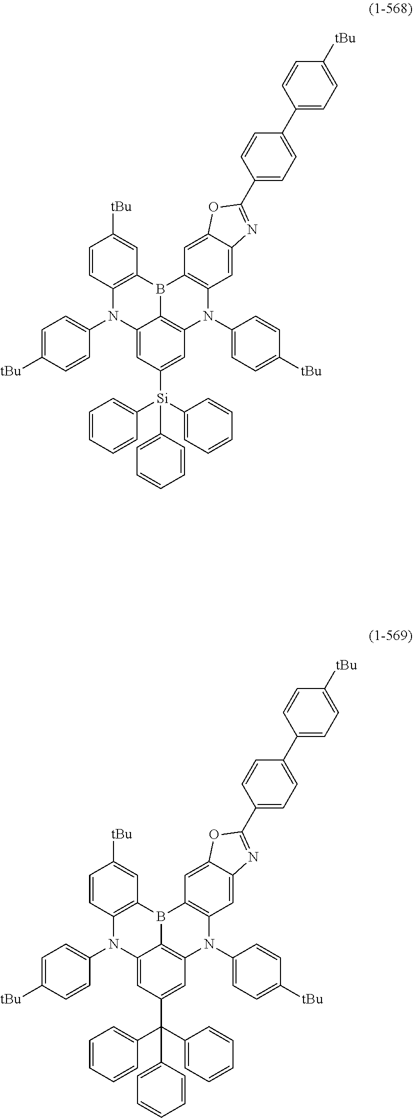 [SMILES: CC(C)(C)c1ccc(-c2ccc(-c3nc4cc5c(cc4o3)B3c4cc(C(C)(C)C)ccc4N(c4ccc(C(C)(C)C)cc4)c4cc([Si](c6ccccc6)(c6ccccc6)c6ccccc6)cc(c43)N5c3ccc(C(C)(C)C)cc3)cc2)cc1 ; CC(C)(C)c1ccc(-c2ccc(-c3nc4cc5c(cc4o3)B3c4cc(C(C)(C)C)ccc4N(c4ccc(C(C)(C)C)cc4)c4cc(C(c6ccccc6)(c6ccccc6)c6ccccc6)cc(c43)N5c3ccc(C(C)(C)C)cc3)cc2)cc1]

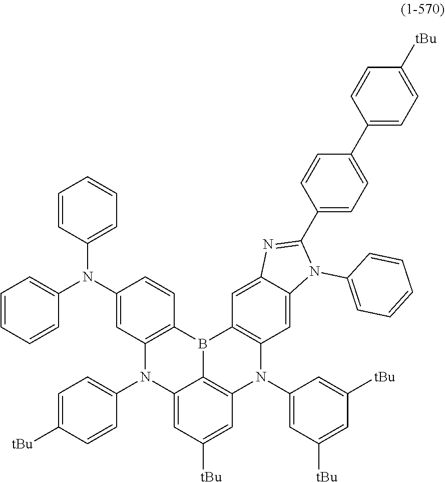 [SMILES: CC(C)(C)c1ccc(-c2ccc(-c3nc4cc5c(cc4n3-c3ccccc3)N(c3cc(C(C)(C)C)cc(C(C)(C)C)c3)c3cc(C(C)(C)C)cc4c3B5c3ccc(N(c5ccccc5)c5ccccc5)cc3N4c3ccc(C(C)(C)C)cc3)cc2)cc1]

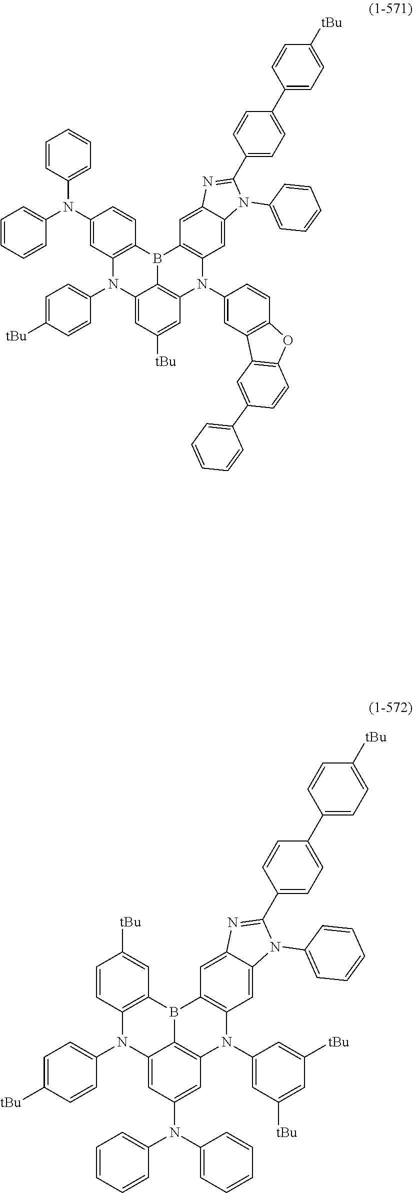 [SMILES: CC(C)(C)c1ccc(-c2ccc(-c3nc4cc5c(cc4n3-c3ccccc3)N(c3ccc4oc6ccc(-c7ccccc7)cc6c4c3)c3cc(C(C)(C)C)cc4c3B5c3ccc(N(c5ccccc5)c5ccccc5)cc3N4c3ccc(C(C)(C)C)cc3)cc2)cc1 ; CC(C)(C)c1ccc(-c2ccc(-c3nc4cc5c(cc4n3-c3ccccc3)N(c3cc(C(C)(C)C)cc(C(C)(C)C)c3)c3cc(N(c4ccccc4)c4ccccc4)cc4c3B5c3cc(C(C)(C)C)ccc3N4c3ccc(C(C)(C)C)cc3)cc2)cc1]

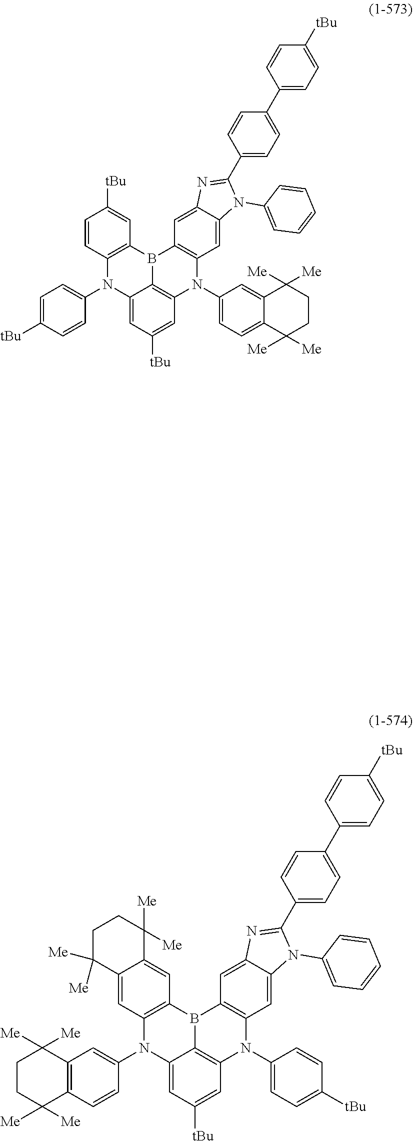 [SMILES: CC(C)(C)c1ccc(-c2ccc(-c3nc4cc5c(cc4n3-c3ccccc3)N(c3ccc4c(c3)C(C)(C)CCC4(C)C)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4n3-c3ccccc3)N(c3ccc(C(C)(C)C)cc3)c3cc(C(C)(C)C)cc4c3B5c3cc5c(cc3N4c3ccc4c(c3)C(C)(C)CCC4(C)C)C(C)(C)CCC5(C)C)cc2)cc1]

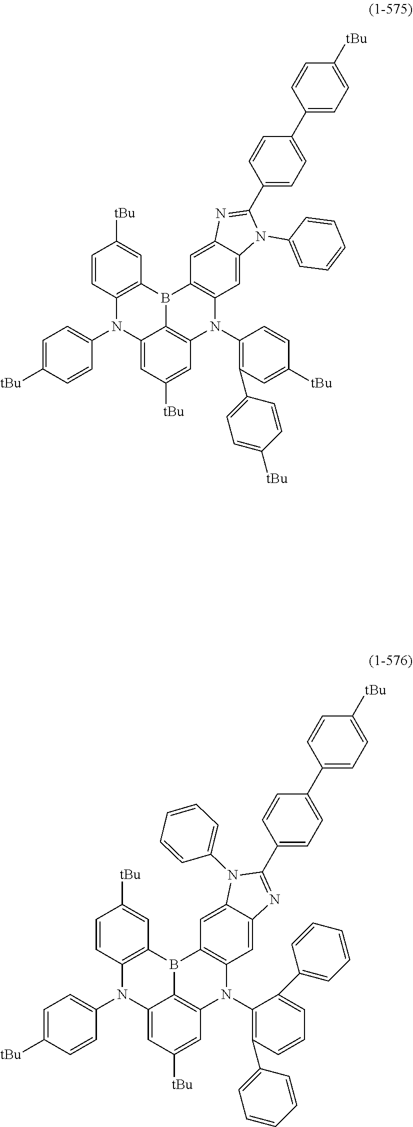 [SMILES: CC(C)(C)c1ccc(-c2ccc(-c3nc4cc5c(cc4n3-c3ccccc3)N(c3ccc(C(C)(C)C)cc3-c3ccc(C(C)(C)C)cc3)c3cc(C(C)(C)C)cc4c3B5c3cc(C(C)(C)C)ccc3N4c3ccc(C(C)(C)C)cc3)cc2)cc1 ; CC(C)(C)c1ccc(-c2ccc(-c3nc4cc5c(cc4n3-c3ccccc3)B3c4cc(C(C)(C)C)ccc4N(c4ccc(C(C)(C)C)cc4)c4cc(C(C)(C)C)cc(c43)N5c3c(-c4ccccc4)cccc3-c3ccccc3)cc2)cc1]

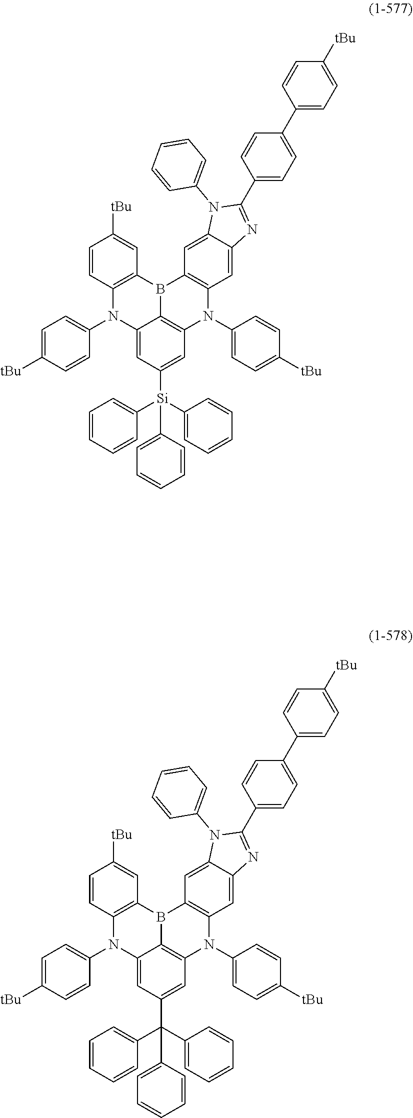 [SMILES: CC(C)(C)c1ccc(-c2ccc(-c3nc4cc5c(cc4n3-c3ccccc3)B3c4cc(C(C)(C)C)ccc4N(c4ccc(C(C)(C)C)cc4)c4cc([Si](c6ccccc6)(c6ccccc6)c6ccccc6)cc(c43)N5c3ccc(C(C)(C)C)cc3)cc2)cc1 ; CC(C)(C)c1ccc(-c2ccc(-c3nc4cc5c(cc4n3-c3ccccc3)B3c4cc(C(C)(C)C)ccc4N(c4ccc(C(C)(C)C)cc4)c4cc(C(c6ccccc6)(c6ccccc6)c6ccccc6)cc(c43)N5c3ccc(C(C)(C)C)cc3)cc2)cc1]

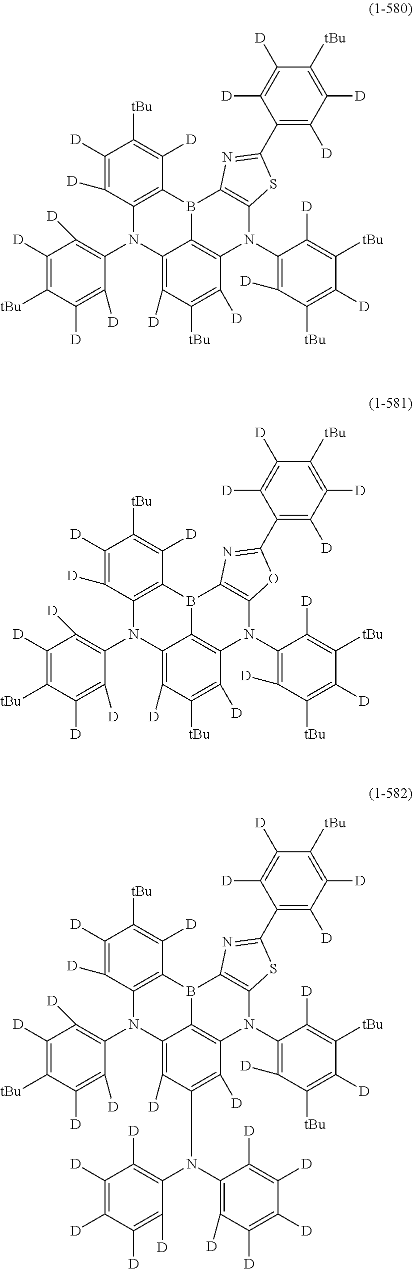

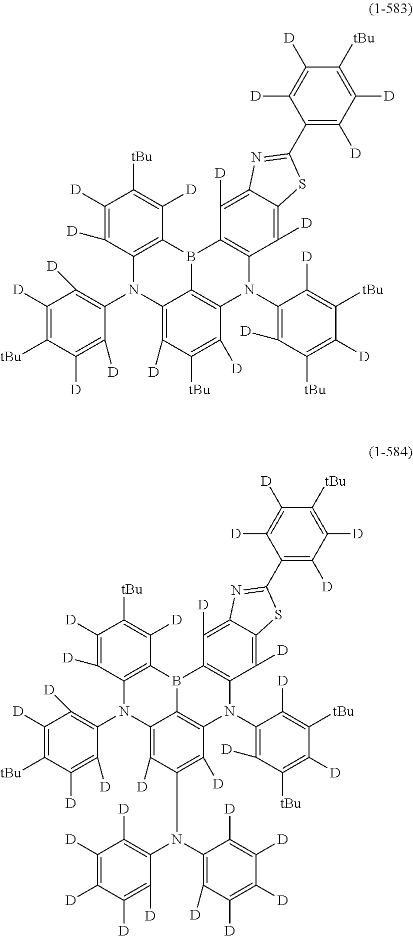

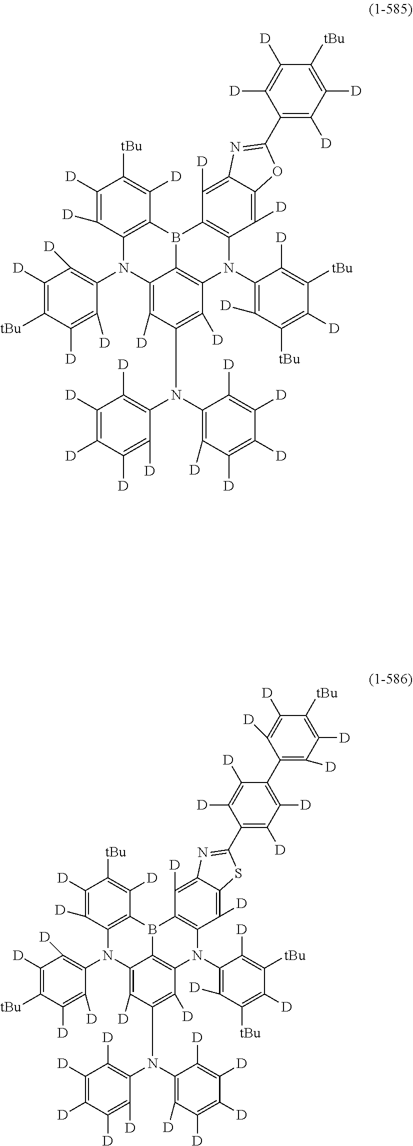

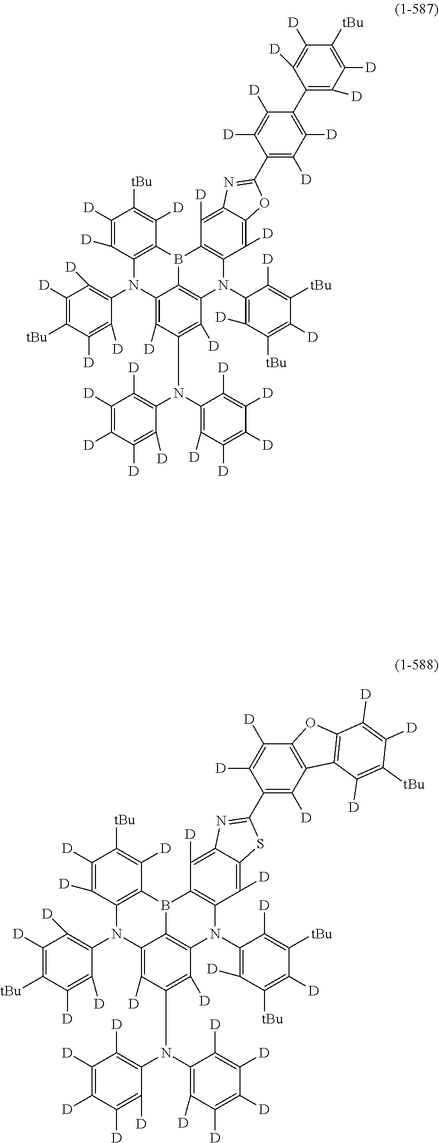

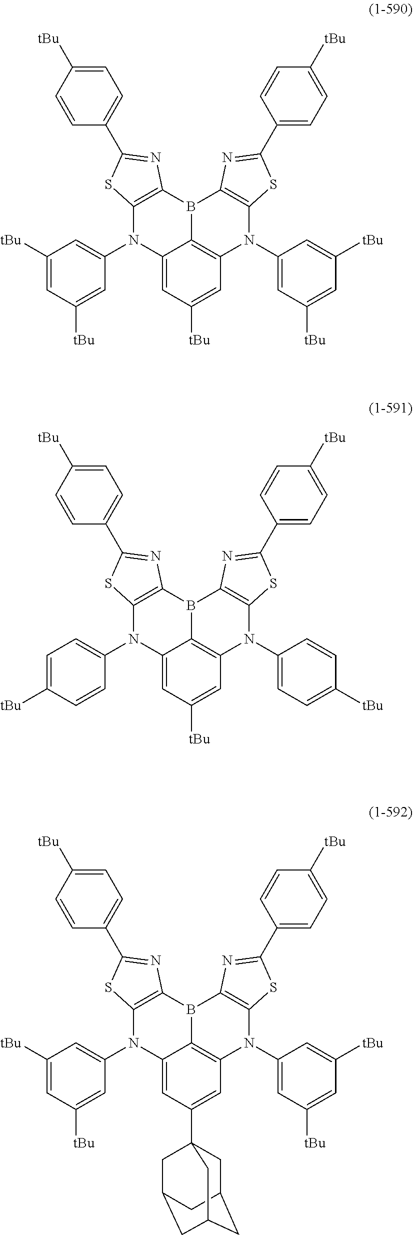 [SMILES: CC(C)(C)c1ccc(-c2nc3c(s2)N(c2cc(C(C)(C)C)cc(C(C)(C)C)c2)c2cc(C(C)(C)C)cc4c2B3c2nc(-c3ccc(C(C)(C)C)cc3)sc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(C(C)(C)C)cc4c2B3c2nc(-c3ccc(C(C)(C)C)cc3)sc2N4c2ccc(C(C)(C)C)cc2)cc1 ; CC(C)(C)c1ccc(-c2nc3c(s2)N(c2cc(C(C)(C)C)cc(C(C)(C)C)c2)c2cc(C45CC6CC(CC(C6)C4)C5)cc4c2B3c2nc(-c3ccc(C(C)(C)C)cc3)sc2N4c2cc(C(C)(C)C)cc(C(C)(C)C)c2)cc1]

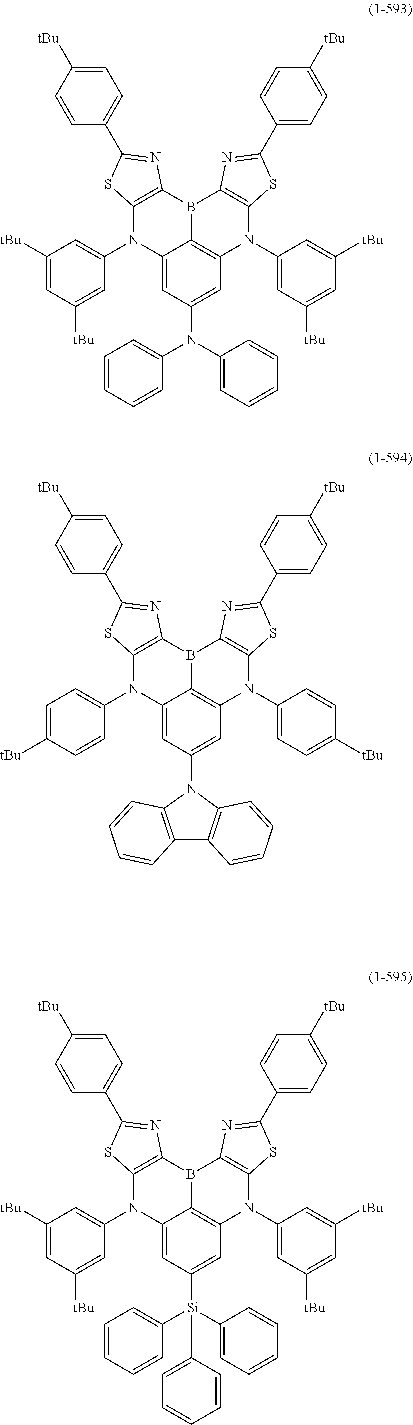 [SMILES: CC(C)(C)c1ccc(-c2nc3c(s2)N(c2cc(C(C)(C)C)cc(C(C)(C)C)c2)c2cc(N(c4ccccc4)c4ccccc4)cc4c2B3c2nc(-c3ccc(C(C)(C)C)cc3)sc2N4c2cc(C(C)(C)C)cc(C(C)(C)C)c2)cc1 ; CC(C)(C)c1ccc(-c2nc3c(s2)N(c2ccc(C(C)(C)C)cc2)c2cc(-n4c5ccccc5c5ccccc54)cc4c2B3c2nc(-c3ccc(C(C)(C)C)cc3)sc2N4c2ccc(C(C)(C)C)cc2)cc1 ; CC(C)(C)c1ccc(-c2nc3c(s2)N(c2cc(C(C)(C)C)cc(C(C)(C)C)c2)c2cc([Si](c4ccccc4)(c4ccccc4)c4ccccc4)cc4c2B3c2nc(-c3ccc(C(C)(C)C)cc3)sc2N4c2cc(C(C)(C)C)cc(C(C)(C)C)c2)cc1]

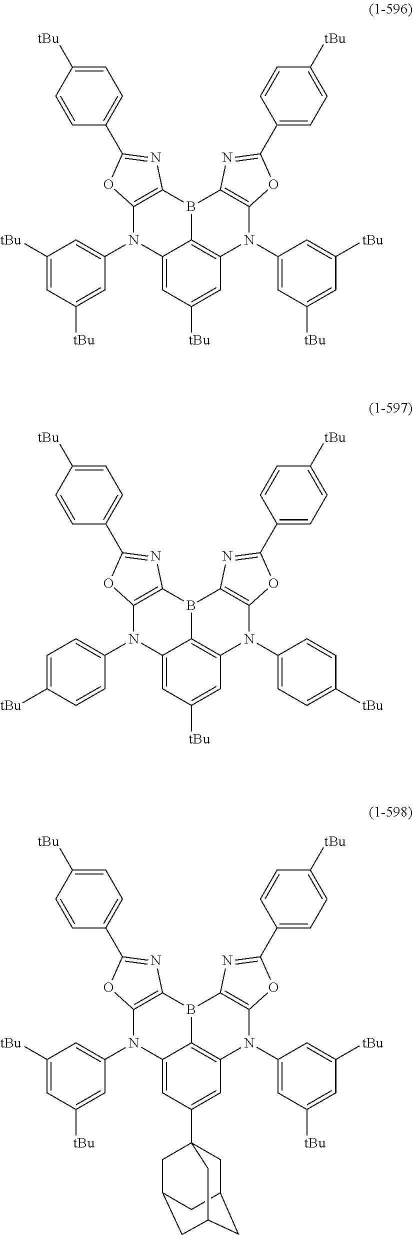 [SMILES: CC(C)(C)c1ccc(-c2nc3c(o2)N(c2cc(C(C)(C)C)cc(C(C)(C)C)c2)c2cc(C(C)(C)C)cc4c2B3c2nc(-c3ccc(C(C)(C)C)cc3)oc2N4c2cc(C(C)(C)C)cc(C(C)(C)C)c2)cc1 ; CC(C)(C)c1ccc(-c2nc3c(o2)N(c2ccc(C(C)(C)C)cc2)c2cc(C(C)(C)C)cc4c2B3c2nc(-c3ccc(C(C)(C)C)cc3)oc2N4c2ccc(C(C)(C)C)cc2)cc1 ; CC(C)(C)c1ccc(-c2nc3c(o2)N(c2cc(C(C)(C)C)cc(C(C)(C)C)c2)c2cc(C45CC6CC(CC(C6)C4)C5)cc4c2B3c2nc(-c3ccc(C(C)(C)C)cc3)oc2N4c2cc(C(C)(C)C)cc(C(C)(C)C)c2)cc1]

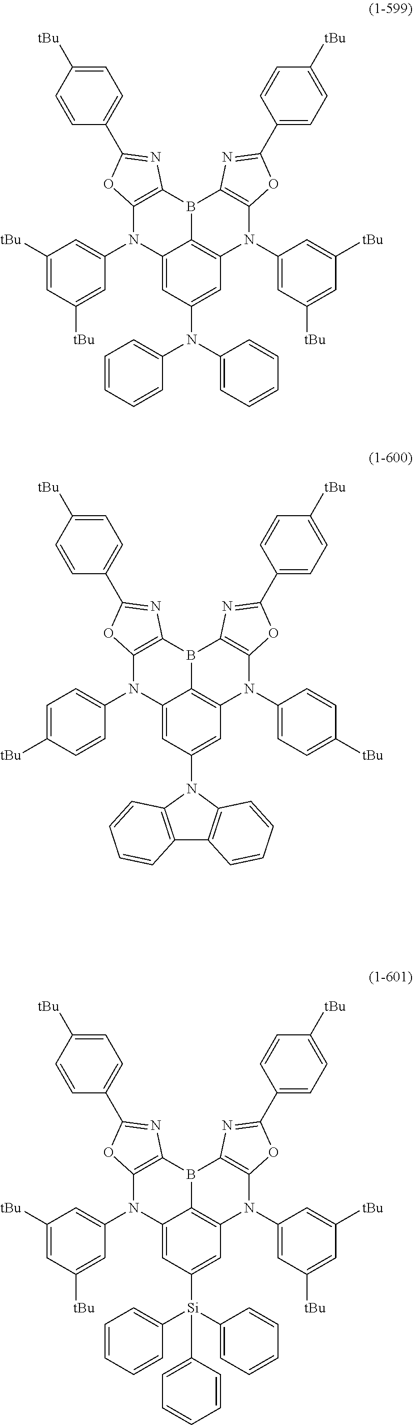 [SMILES: CC(C)(C)c1ccc(-c2nc3c(o2)N(c2cc(C(C)(C)C)cc(C(C)(C)C)c2)c2cc(N(c4ccccc4)c4ccccc4)cc4c2B3c2nc(-c3ccc(C(C)(C)C)cc3)oc2N4c2cc(C(C)(C)C)cc(C(C)(C)C)c2)cc1 ; CC(C)(C)c1ccc(-c2nc3c(o2)N(c2ccc(C(C)(C)C)cc2)c2cc(-n4c5ccccc5c5ccccc54)cc4c2B3c2nc(-c3ccc(C(C)(C)C)cc3)oc2N4c2ccc(C(C)(C)C)cc2)cc1 ; CC(C)(C)c1ccc(-c2nc3c(o2)N(c2cc(C(C)(C)C)cc(C(C)(C)C)c2)c2cc([Si](c4ccccc4)(c4ccccc4)c4ccccc4)cc4c2B3c2nc(-c3ccc(C(C)(C)C)cc3)oc2N4c2cc(C(C)(C)C)cc(C(C)(C)C)c2)cc1]

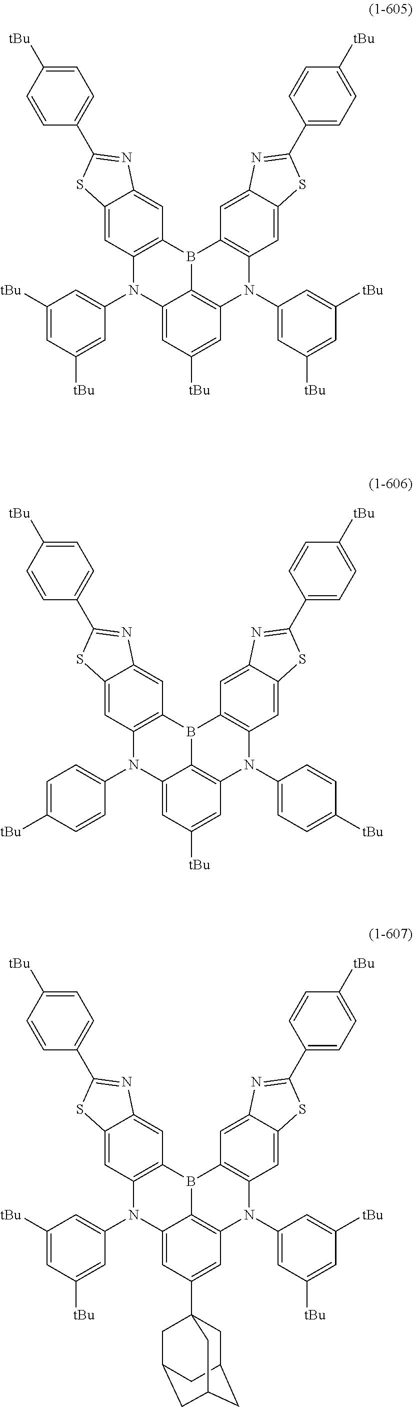 [SMILES: CC(C)(C)c1ccc(-c2nc3cc4c(cc3s2)N(c2cc(C(C)(C)C)cc(C(C)(C)C)c2)c2cc(C(C)(C)C)cc3c2B4c2cc4nc(-c5ccc(C(C)(C)C)cc5)sc4cc2N3c2cc(C(C)(C)C)cc(C(C)(C)C)c2)cc1 ; CC(C)(C)c1ccc(-c2nc3cc4c(cc3s2)N(c2ccc(C(C)(C)C)cc2)c2cc(C(C)(C)C)cc3c2B4c2cc4nc(-c5ccc(C(C)(C)C)cc5)sc4cc2N3c2ccc(C(C)(C)C)cc2)cc1 ; CC(C)(C)c1ccc(-c2nc3cc4c(cc3s2)N(c2cc(C(C)(C)C)cc(C(C)(C)C)c2)c2cc(C35CC6CC(CC(C6)C3)C5)cc3c2B4c2cc4nc(-c5ccc(C(C)(C)C)cc5)sc4cc2N3c2cc(C(C)(C)C)cc(C(C)(C)C)c2)cc1]

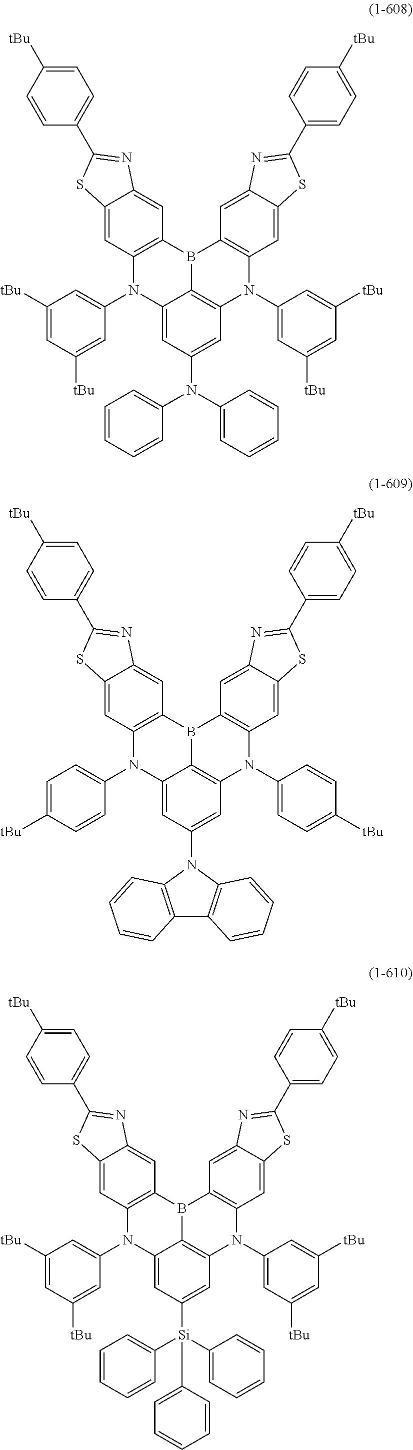 [SMILES: CC(C)(C)c1ccc(-c2nc3cc4c(cc3s2)N(c2cc(C(C)(C)C)cc(C(C)(C)C)c2)c2cc(N(c3ccccc3)c3ccccc3)cc3c2B4c2cc4nc(-c5ccc(C(C)(C)C)cc5)sc4cc2N3c2cc(C(C)(C)C)cc(C(C)(C)C)c2)cc1 ; CC(C)(C)c1ccc(-c2nc3cc4c(cc3s2)N(c2ccc(C(C)(C)C)cc2)c2cc(-n3c5ccccc5c5ccccc53)cc3c2B4c2cc4nc(-c5ccc(C(C)(C)C)cc5)sc4cc2N3c2ccc(C(C)(C)C)cc2)cc1 ; CC(C)(C)c1ccc(-c2nc3cc4c(cc3s2)N(c2cc(C(C)(C)C)cc(C(C)(C)C)c2)c2cc([Si](c3ccccc3)(c3ccccc3)c3ccccc3)cc3c2B4c2cc4nc(-c5ccc(C(C)(C)C)cc5)sc4cc2N3c2cc(C(C)(C)C)cc(C(C)(C)C)c2)cc1]

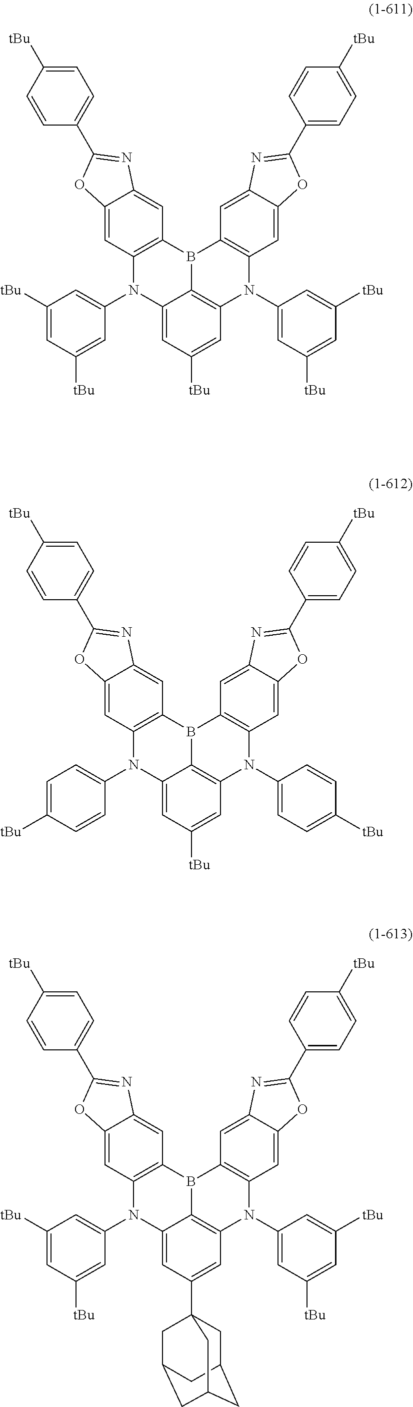 [SMILES: CC(C)(C)c1ccc(-c2nc3cc4c(cc3o2)N(c2cc(C(C)(C)C)cc(C(C)(C)C)c2)c2cc(C(C)(C)C)cc3c2B4c2cc4nc(-c5ccc(C(C)(C)C)cc5)oc4cc2N3c2cc(C(C)(C)C)cc(C(C)(C)C)c2)cc1 ; CC(C)(C)c1ccc(-c2nc3cc4c(cc3o2)N(c2ccc(C(C)(C)C)cc2)c2cc(C(C)(C)C)cc3c2B4c2cc4nc(-c5ccc(C(C)(C)C)cc5)oc4cc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc(C35CC6CC(CC(C6)C3)C5)cc3c2B4c2cc4nc(-c5ccc(C(C)(C)C)cc5)oc4cc2N3c2cc(C(C)(C)C)cc(C(C)(C)C)c2)cc1]

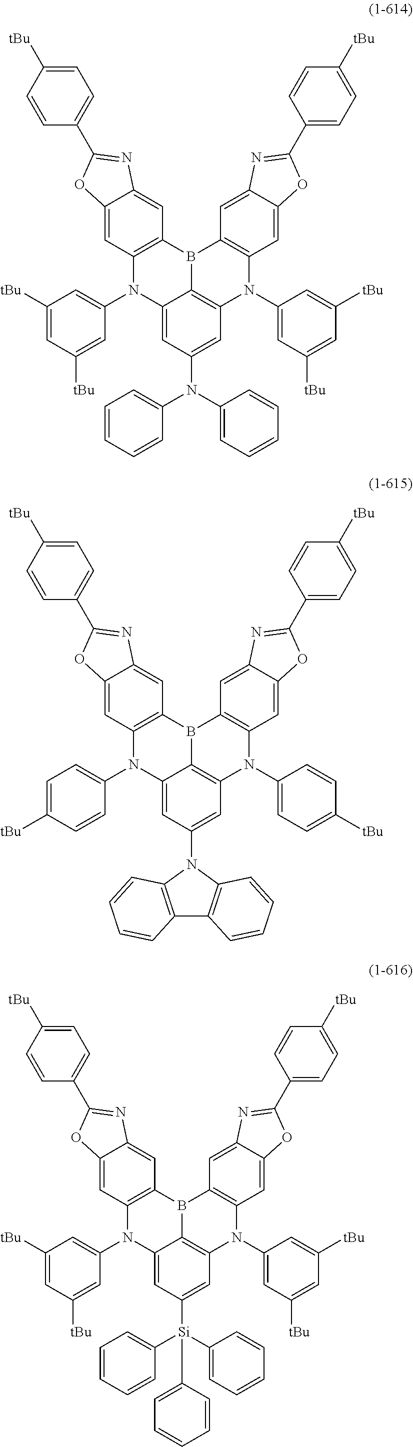 [SMILES: CC(C)(C)c1ccc(-c2nc3cc4c(cc3o2)N(c2cc(C(C)(C)C)cc(C(C)(C)C)c2)c2cc(N(c3ccccc3)c3ccccc3)cc3c2B4c2cc4nc(-c5ccc(C(C)(C)C)cc5)oc4cc2N3c2cc(C(C)(C)C)cc(C(C)(C)C)c2)cc1 ; CC(C)(C)c1ccc(-c2nc3cc4c(cc3o2)N(c2ccc(C(C)(C)C)cc2)c2cc(-n3c5ccccc5c5ccccc53)cc3c2B4c2cc4nc(-c5ccc(C(C)(C)C)cc5)oc4cc2N3c2ccc(C(C)(C)C)cc2)cc1 ; CC(C)(C)c1ccc(-c2nc3cc4c(cc3o2)N(c2cc(C(C)(C)C)cc(C(C)(C)C)c2)c2cc([Si](c3ccccc3)(c3ccccc3)c3ccccc3)cc3c2B4c2cc4nc(-c5ccc(C(C)(C)C)cc5)oc4cc2N3c2cc(C(C)(C)C)cc(C(C)(C)C)c2)cc1]

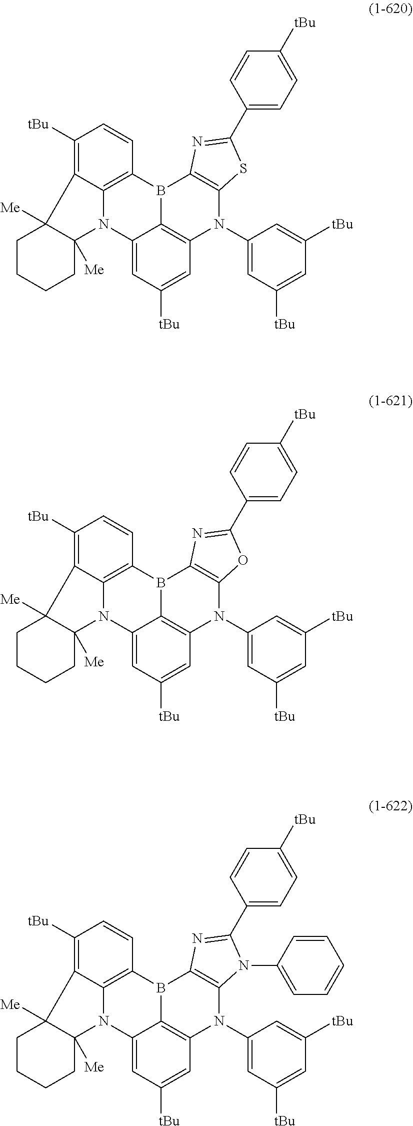 [SMILES: CC(C)(C)c1ccc(-c2nc3c(s2)N(c2cc(C(C)(C)C)cc(C(C)(C)C)c2)c2cc(C(C)(C)C)cc4c2B3c2ccc(C(C)(C)C)c3c2N4C2(C)CCCCC32C)cc1 ; CC(C)(C)c1ccc(-c2nc3c(o2)N(c2cc(C(C)(C)C)cc(C(C)(C)C)c2)c2cc(C(C)(C)C)cc4c2B3c2ccc(C(C)(C)C)c3c2N4C2(C)CCCCC32C)cc1 ; CC(C)(C)c1ccc(-c2nc3c(n2-c2ccccc2)N(c2cc(C(C)(C)C)cc(C(C)(C)C)c2)c2cc(C(C)(C)C)cc4c2B3c2ccc(C(C)(C)C)c3c2N4C2(C)CCCCC32C)cc1]

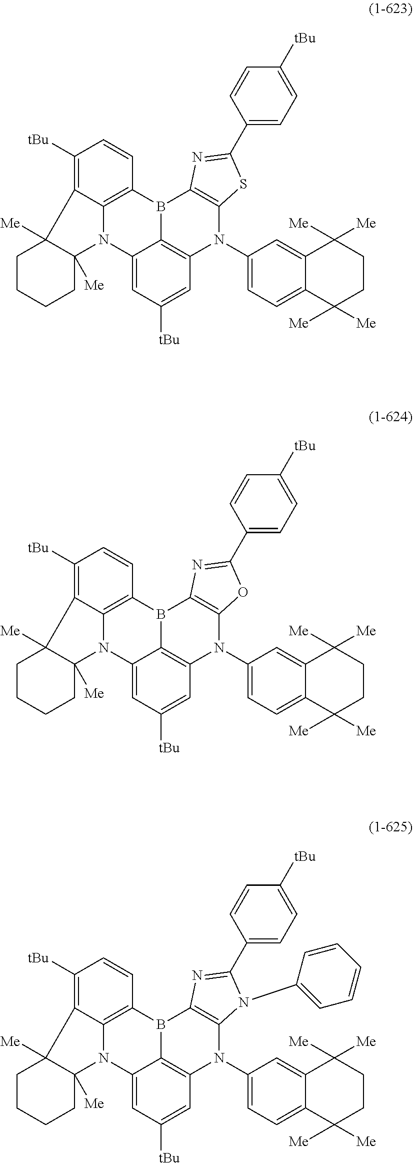 [SMILES: CC(C)(C)c1ccc(-c2nc3c(s2)N(c2ccc4c(c2)C(C)(C)CCC4(C)C)c2cc(C(C)(C)C)cc4c2B3c2ccc(C(C)(C)C)c3c2N4C2(C)CCCCC32C)cc1 ; CC(C)(C)c1ccc(-c2nc3c(o2)N(c2ccc4c(c2)C(C)(C)CCC4(C)C)c2cc(C(C)(C)C)cc4c2B3c2ccc(C(C)(C)C)c3c2N4C2(C)CCCCC32C)cc1 ; CC(C)(C)c1ccc(-c2nc3c(n2-c2ccccc2)N(c2ccc4c(c2)C(C)(C)CCC4(C)C)c2cc(C(C)(C)C)cc4c2B3c2ccc(C(C)(C)C)c3c2N4C2(C)CCCCC32C)cc1]

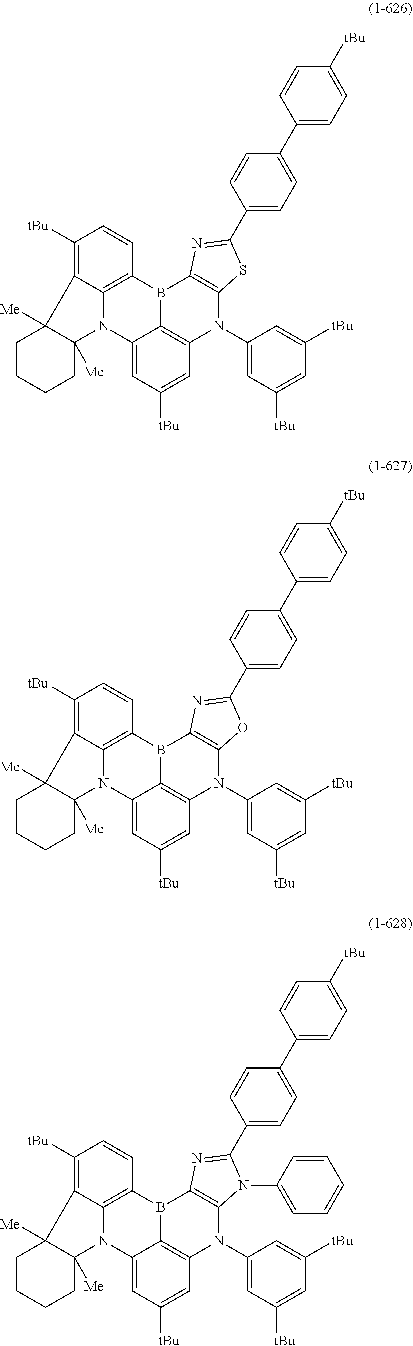 [SMILES: CC(C)(C)c1ccc(-c2ccc(-c3nc4c(s3)N(c3cc(C(C)(C)C)cc(C(C)(C)C)c3)c3cc(C(C)(C)C)cc5c3B4c3ccc(C(C)(C)C)c4c3N5C3(C)CCCCC43C)cc2)cc1 ; CC(C)(C)c1ccc(-c2ccc(-c3nc4c(o3)N(c3cc(C(C)(C)C)cc(C(C)(C)C)c3)c3cc(C(C)(C)C)cc5c3B4c3ccc(C(C)(C)C)c4c3N5C3(C)CCCCC43C)cc2)cc1 ; CC(C)(C)c1ccc(-c2ccc(-c3nc4c(n3-c3ccccc3)N(c3cc(C(C)(C)C)cc(C(C)(C)C)c3)c3cc(C(C)(C)C)cc5c3B4c3ccc(C(C)(C)C)c4c3N5C3(C)CCCCC43C)cc2)cc1]

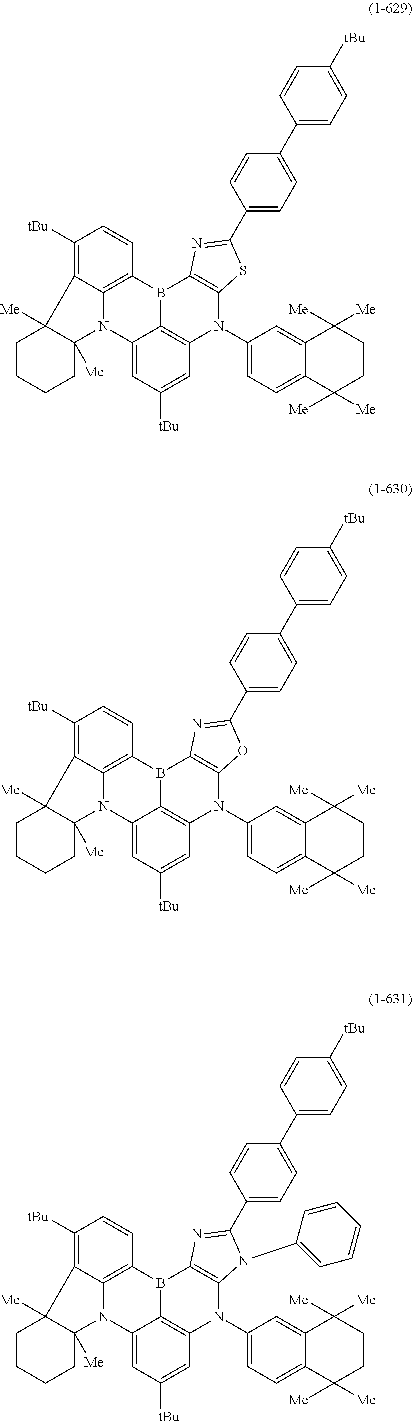 [SMILES: CC(C)(C)c1ccc(-c2ccc(-c3nc4c(s3)N(c3ccc5c(c3)C(C)(C)CCC5(C)C)c3cc(C(C)(C)C)cc5c3B4c3ccc(C(C)(C)C)c4c3N5C3(C)CCCCC43C)cc2)cc1 ; CC(C)(C)c1ccc(-c2ccc(-c3nc4c(o3)N(c3ccc5c(c3)C(C)(C)CCC5(C)C)c3cc(C(C)(C)C)cc5c3B4c3ccc(C(C)(C)C)c4c3N5C3(C)CCCCC43C)cc2)cc1 ; CC(C)(C)c1ccc(-c2ccc(-c3nc4c(n3-c3ccccc3)N(c3ccc5c(c3)C(C)(C)CCC5(C)C)c3cc(C(C)(C)C)cc5c3B4c3ccc(C(C)(C)C)c4c3N5C3(C)CCCCC43C)cc2)cc1]

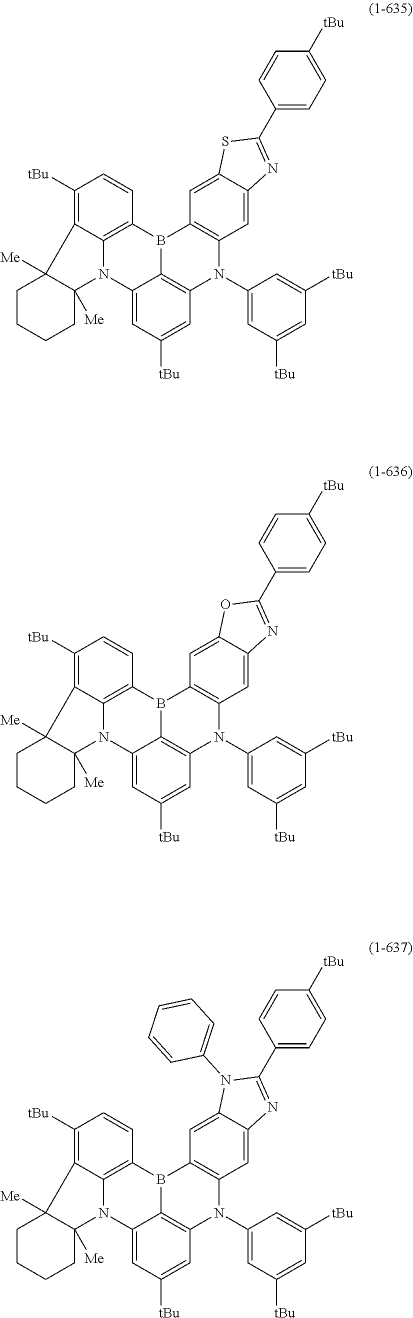 [SMILES: CC(C)(C)c1ccc(-c2nc3cc4c(cc3s2)B2c3ccc(C(C)(C)C)c5c3N(c3cc(C(C)(C)C)cc(c32)N4c2cc(C(C)(C)C)cc(C(C)(C)C)c2)C2(C)CCCCC52C)cc1 ; CC(C)(C)c1ccc(-c2nc3cc4c(cc3o2)B2c3ccc(C(C)(C)C)c5c3N(c3cc(C(C)(C)C)cc(c32)N4c2cc(C(C)(C)C)cc(C(C)(C)C)c2)C2(C)CCCCC52C)cc1 ; CC(C)(C)c1ccc(-c2nc3cc4c(cc3n2-c2ccccc2)B2c3ccc(C(C)(C)C)c5c3N(c3cc(C(C)(C)C)cc(c32)N4c2cc(C(C)(C)C)cc(C(C)(C)C)c2)C2(C)CCCCC52C)cc1]

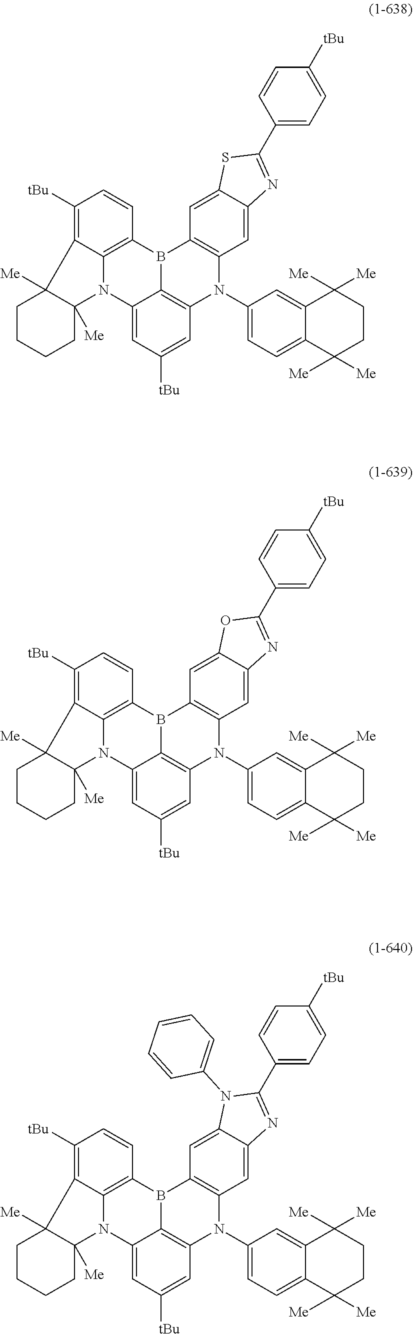 [SMILES: CC(C)(C)c1ccc(-c2nc3cc4c(cc3s2)B2c3ccc(C(C)(C)C)c5c3N(c3cc(C(C)(C)C)cc(c32)N4c2ccc3c(c2)C(C)(C)CCC3(C)C)C2(C)CCCCC52C)cc1 ; CC(C)(C)c1ccc(-c2nc3cc4c(cc3o2)B2c3ccc(C(C)(C)C)c5c3N(c3cc(C(C)(C)C)cc(c32)N4c2ccc3c(c2)C(C)(C)CCC3(C)C)C2(C)CCCCC52C)cc1 ; CC(C)(C)c1ccc(-c2nc3cc4c(cc3n2-c2ccccc2)B2c3ccc(C(C)(C)C)c5c3N(c3cc(C(C)(C)C)cc(c32)N4c2ccc3c(c2)C(C)(C)CCC3(C)C)C2(C)CCCCC52C)cc1]

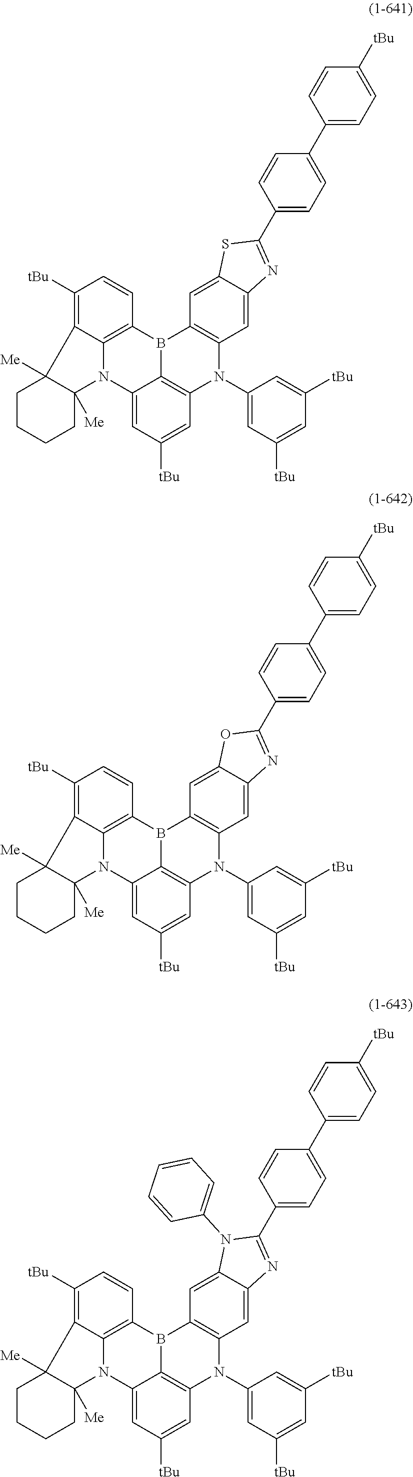 [SMILES: CC(C)(C)c1ccc(-c2ccc(-c3nc4cc5c(cc4s3)B3c4ccc(C(C)(C)C)c6c4N(c4cc(C(C)(C)C)cc(c43)N5c3cc(C(C)(C)C)cc(C(C)(C)C)c3)C3(C)CCCCC63C)cc2)cc1 ; CC(C)(C)c1ccc(-c2ccc(-c3nc4cc5c(cc4o3)B3c4ccc(C(C)(C)C)c6c4N(c4cc(C(C)(C)C)cc(c43)N5c3cc(C(C)(C)C)cc(C(C)(C)C)c3)C3(C)CCCCC63C)cc2)cc1 ; CC(C)(C)c1ccc(-c2ccc(-c3nc4cc5c(cc4n3-c3ccccc3)B3c4ccc(C(C)(C)C)c6c4N(c4cc(C(C)(C)C)cc(c43)N5c3cc(C(C)(C)C)cc(C(C)(C)C)c3)C3(C)CCCCC63C)cc2)cc1]

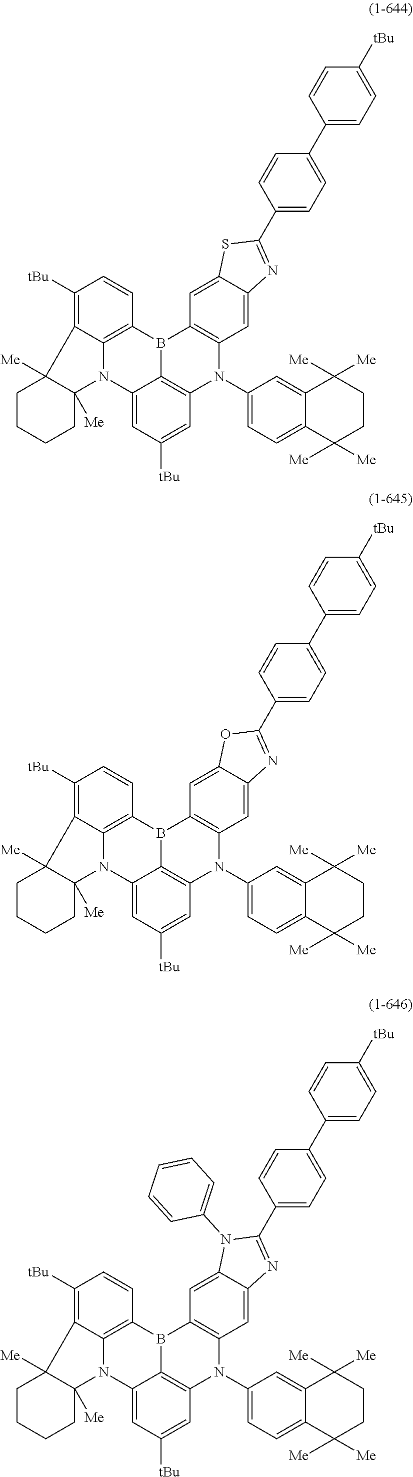 [SMILES: CC(C)(C)c1ccc(-c2ccc(-c3nc4cc5c(cc4s3)B3c4ccc(C(C)(C)C)c6c4N(c4cc(C(C)(C)C)cc(c43)N5c3ccc4c(c3)C(C)(C)CCC4(C)C)C3(C)CCCCC63C)cc2)cc1 ; CC(C)(C)c1ccc(-c2ccc(-c3nc4cc5c(cc4o3)B3c4ccc(C(C)(C)C)c6c4N(c4cc(C(C)(C)C)cc(c43)N5c3ccc4c(c3)C(C)(C)CCC4(C)C)C3(C)CCCCC63C)cc2)cc1 ; CC(C)(C)c1ccc(-c2ccc(-c3nc4cc5c(cc4n3-c3ccccc3)B3c4ccc(C(C)(C)C)c6c4N(c4cc(C(C)(C)C)cc(c43)N5c3ccc4c(c3)C(C)(C)CCC4(C)C)C3(C)CCCCC63C)cc2)cc1]

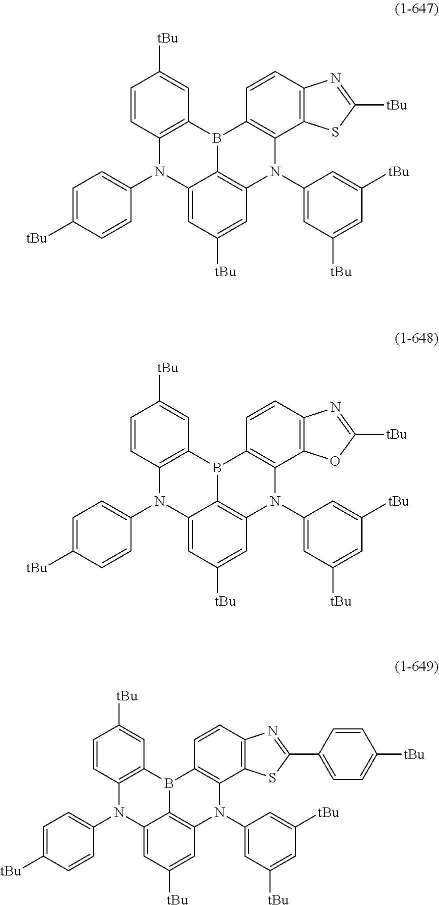 [SMILES: CC(C)(C)c1ccc(N2c3ccc(C(C)(C)C)cc3B3c4ccc5nc(C(C)(C)C)sc5c4N(c4cc(C(C)(C)C)cc(C(C)(C)C)c4)c4cc(C(C)(C)C)cc2c43)cc1 ; CC(C)(C)c1ccc(N2c3ccc(C(C)(C)C)cc3B3c4ccc5nc(C(C)(C)C)oc5c4N(c4cc(C(C)(C)C)cc(C(C)(C)C)c4)c4cc(C(C)(C)C)cc2c43)cc1 ; CC(C)(C)c1ccc(-c2nc3ccc4c(c3s2)N(c2cc(C(C)(C)C)cc(C(C)(C)C)c2)c2cc(C(C)(C)C)cc3c2B4c2cc(C(C)(C)C)ccc2N3c2ccc(C(C)(C)C)cc2)cc1]

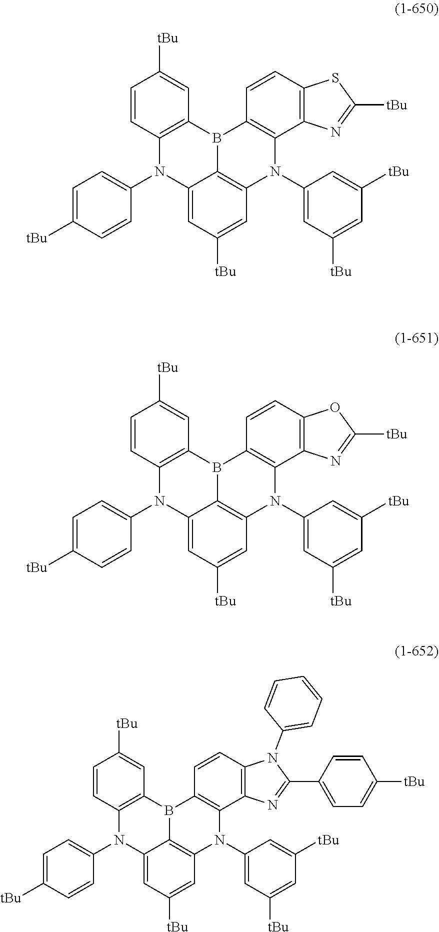 [SMILES: CC(C)(C)c1ccc(N2c3ccc(C(C)(C)C)cc3B3c4ccc5sc(C(C)(C)C)nc5c4N(c4cc(C(C)(C)C)cc(C(C)(C)C)c4)c4cc(C(C)(C)C)cc2c43)cc1 ; CC(C)(C)c1ccc(N2c3ccc(C(C)(C)C)cc3B3c4ccc5oc(C(C)(C)C)nc5c4N(c4cc(C(C)(C)C)cc(C(C)(C)C)c4)c4cc(C(C)(C)C)cc2c43)cc1 ; CC(C)(C)c1ccc(-c2nc3c4c(ccc3n2-c2ccccc2)B2c3cc(C(C)(C)C)ccc3N(c3ccc(C(C)(C)C)cc3)c3cc(C(C)(C)C)cc(c32)N4c2cc(C(C)(C)C)cc(C(C)(C)C)c2)cc1]

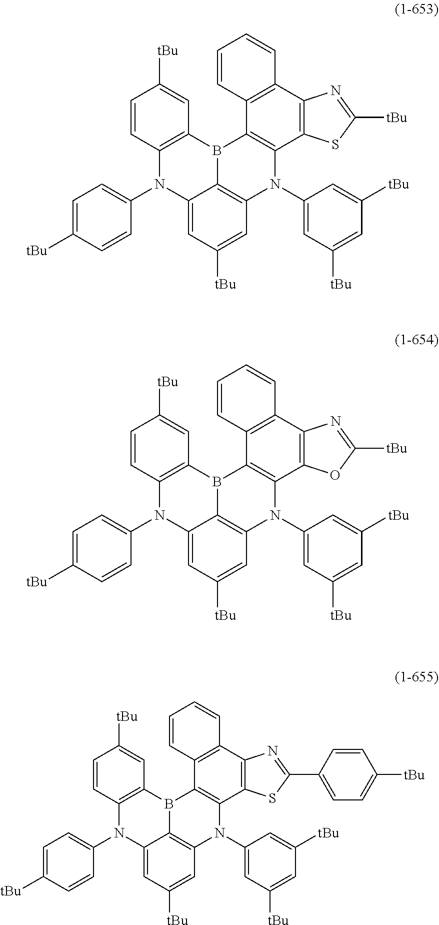 [SMILES: CC(C)(C)c1ccc(N2c3ccc(C(C)(C)C)cc3B3c4c2cc(C(C)(C)C)cc4N(c2cc(C(C)(C)C)cc(C(C)(C)C)c2)c2c3c3ccccc3c3nc(C(C)(C)C)sc23)cc1 ; CC(C)(C)c1ccc(N2c3ccc(C(C)(C)C)cc3B3c4c2cc(C(C)(C)C)cc4N(c2cc(C(C)(C)C)cc(C(C)(C)C)c2)c2c3c3ccccc3c3nc(C(C)(C)C)oc23)cc1 ; CC(C)(C)c1ccc(-c2nc3c(s2)c2c(c4ccccc43)B3c4cc(C(C)(C)C)ccc4N(c4ccc(C(C)(C)C)cc4)c4cc(C(C)(C)C)cc(c43)N2c2cc(C(C)(C)C)cc(C(C)(C)C)c2)cc1]

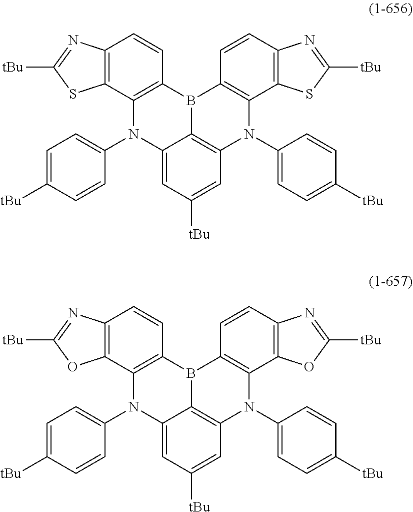 [SMILES: CC(C)(C)c1ccc(N2c3cc(C(C)(C)C)cc4c3B(c3ccc5nc(C(C)(C)C)sc5c32)c2ccc3nc(C(C)(C)C)sc3c2N4c2ccc(C(C)(C)C)cc2)cc1 ; CC(C)(C)c1ccc(N2c3cc(C(C)(C)C)cc4c3B(c3ccc5nc(C(C)(C)C)oc5c32)c2ccc3nc(C(C)(C)C)oc3c2N4c2ccc(C(C)(C)C)cc2)cc1]

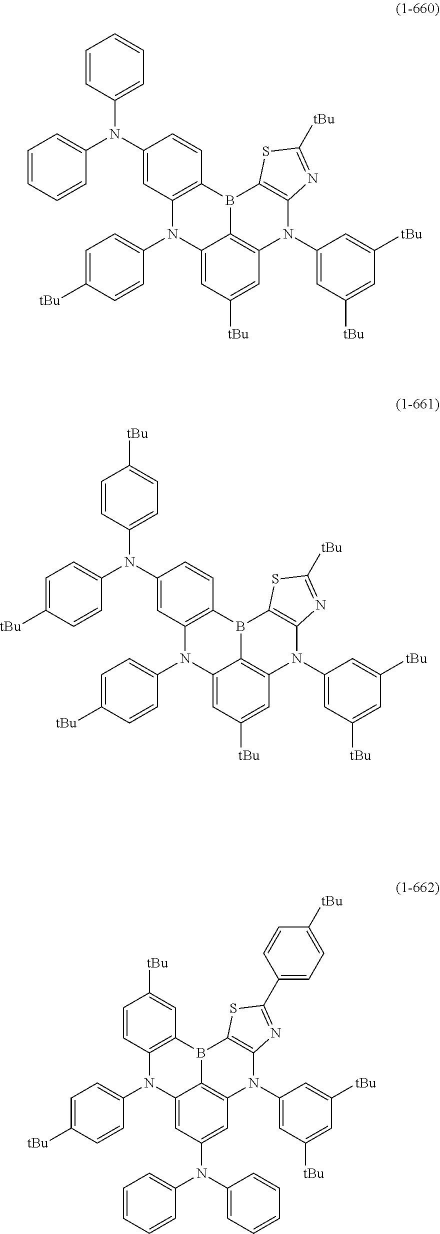 [SMILES: CC(C)(C)c1ccc(N2c3cc(N(c4ccccc4)c4ccccc4)ccc3B3c4sc(C(C)(C)C)nc4N(c4cc(C(C)(C)C)cc(C(C)(C)C)c4)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2sc(C(C)(C)C)nc2N4c2cc(C(C)(C)C)cc(C(C)(C)C)c2)cc1 ; CC(C)(C)c1ccc(-c2nc3c(s2)B2c4cc(C(C)(C)C)ccc4N(c4ccc(C(C)(C)C)cc4)c4cc(N(c5ccccc5)c5ccccc5)cc(c42)N3c2cc(C(C)(C)C)cc(C(C)(C)C)c2)cc1]

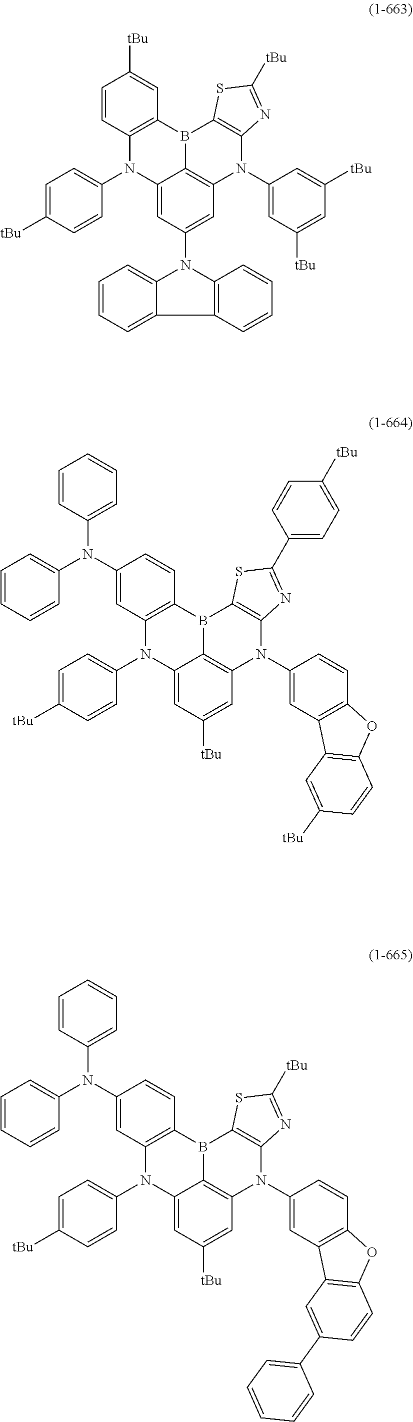 [SMILES: CC(C)(C)c1ccc(N2c3ccc(C(C)(C)C)cc3B3c4sc(C(C)(C)C)nc4N(c4cc(C(C)(C)C)cc(C(C)(C)C)c4)c4cc(-n5c6ccccc6c6ccccc65)cc2c43)cc1 ; CC(C)(C)c1ccc(-c2nc3c(s2)B2c4ccc(N(c5ccccc5)c5ccccc5)cc4N(c4ccc(C(C)(C)C)cc4)c4cc(C(C)(C)C)cc(c42)N3c2ccc3oc4ccc(C(C)(C)C)cc4c3c2)cc1 ; CC(C)(C)c1ccc(N2c3cc(N(c4ccccc4)c4ccccc4)ccc3B3c4sc(C(C)(C)C)nc4N(c4ccc5oc6ccc(-c7ccccc7)cc6c5c4)c4cc(C(C)(C)C)cc2c43)cc1]

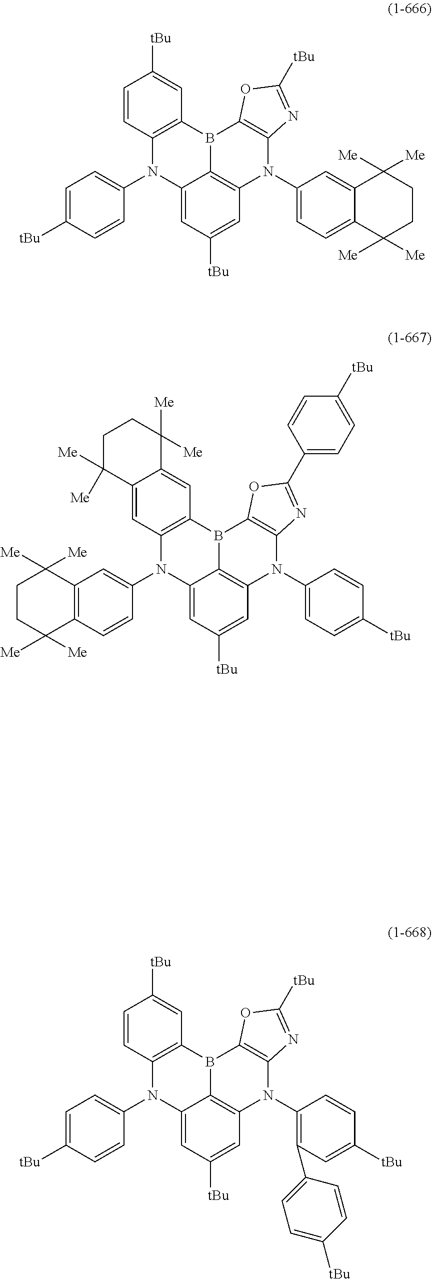 [SMILES: CC(C)(C)c1ccc(N2c3ccc(C(C)(C)C)cc3B3c4oc(C(C)(C)C)nc4N(c4ccc5c(c4)C(C)(C)CCC5(C)C)c4cc(C(C)(C)C)cc2c43)cc1 ; CC(C)(C)c1ccc(-c2nc3c(o2)B2c4cc5c(cc4N(c4ccc6c(c4)C(C)(C)CCC6(C)C)c4cc(C(C)(C)C)cc(c42)N3c2ccc(C(C)(C)C)cc2)C(C)(C)CCC5(C)C)cc1 ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3oc(C(C)(C)C)nc32)cc1]

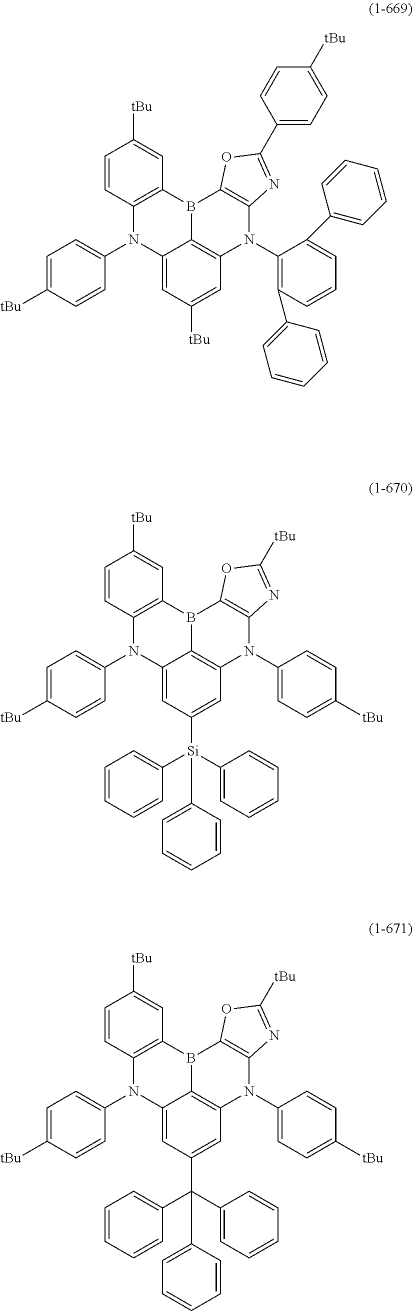 [SMILES: CC(C)(C)c1ccc(-c2nc3c(o2)B2c4cc(C(C)(C)C)ccc4N(c4ccc(C(C)(C)C)cc4)c4cc(C(C)(C)C)cc(c42)N3c2c(-c3ccccc3)cccc2-c2ccccc2)cc1 ; CC(C)(C)c1ccc(N2c3ccc(C(C)(C)C)cc3B3c4oc(C(C)(C)C)nc4N(c4ccc(C(C)(C)C)cc4)c4cc([Si](c5ccccc5)(c5ccccc5)c5ccccc5)cc2c43)cc1 ; CC(C)(C)c1ccc(N2c3ccc(C(C)(C)C)cc3B3c4oc(C(C)(C)C)nc4N(c4ccc(C(C)(C)C)cc4)c4cc(C(c5ccccc5)(c5ccccc5)c5ccccc5)cc2c43)cc1]

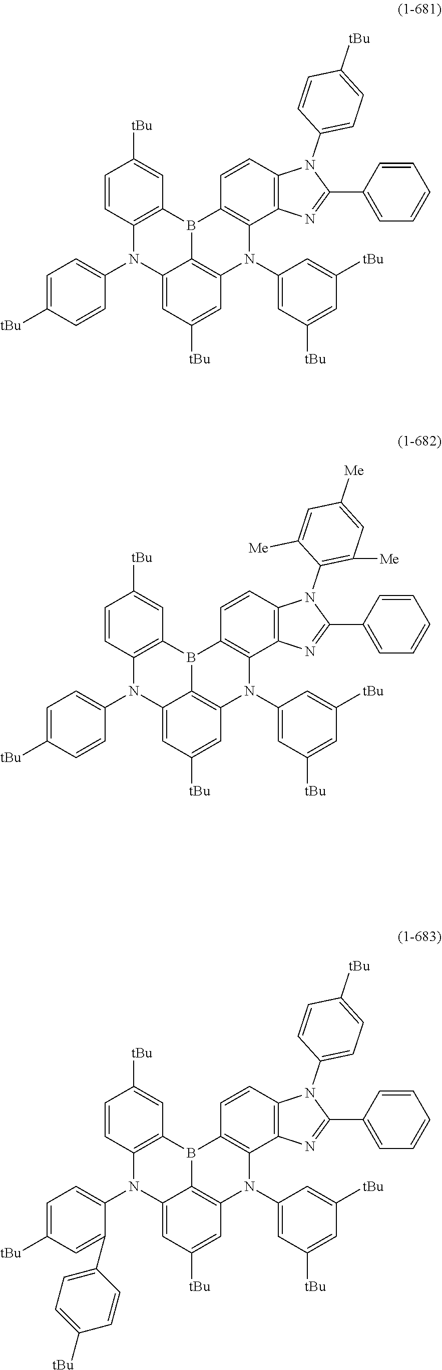 [SMILES: CC(C)(C)c1ccc(N2c3ccc(C(C)(C)C)cc3B3c4ccc5c(nc(-c6ccccc6)n5-c5ccc(C(C)(C)C)cc5)c4N(c4cc(C(C)(C)C)cc(C(C)(C)C)c4)c4cc(C(C)(C)C)cc2c43)cc1 ; Cc1cc(C)c(-n2c(-c3ccccc3)nc3c4c(ccc32)B2c3cc(C(C)(C)C)ccc3N(c3ccc(C(C)(C)C)cc3)c3cc(C(C)(C)C)cc(c32)N4c2cc(C(C)(C)C)cc(C(C)(C)C)c2)c(C)c1 ; CC(C)(C)c1ccc(-c2cc(C(C)(C)C)ccc2N2c3ccc(C(C)(C)C)cc3B3c4ccc5c(nc(-c6ccccc6)n5-c5ccc(C(C)(C)C)cc5)c4N(c4cc(C(C)(C)C)cc(C(C)(C)C)c4)c4cc(C(C)(C)C)cc2c43)cc1]

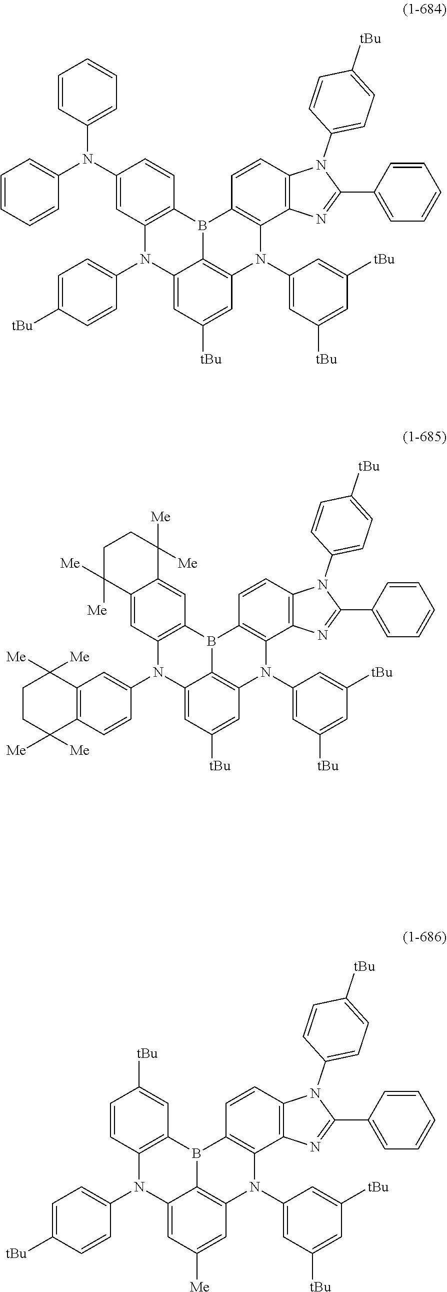 [SMILES: CC(C)(C)c1ccc(N2c3cc(N(c4ccccc4)c4ccccc4)ccc3B3c4ccc5c(nc(-c6ccccc6)n5-c5ccc(C(C)(C)C)cc5)c4N(c4cc(C(C)(C)C)cc(C(C)(C)C)c4)c4cc(C(C)(C)C)cc2c43)cc1 ; CC(C)(C)c1ccc(-n2c(-c3ccccc3)nc3c4c(ccc32)B2c3cc5c(cc3N(c3ccc6c(c3)C(C)(C)CCC6(C)C)c3cc(C(C)(C)C)cc(c32)N4c2cc(C(C)(C)C)cc(C(C)(C)C)c2)C(C)(C)CCC5(C)C)cc1 ; Cc1cc2c3c(c1)N(c1cc(C(C)(C)C)cc(C(C)(C)C)c1)c1c(ccc4c1nc(-c1ccccc1)n4-c1ccc(C(C)(C)C)cc1)B3c1cc(C(C)(C)C)ccc1N2c1ccc(C(C)(C)C)cc1]

The polycyclic aromatic compound of the present invention can be produced by the following procedure.

### Method Fax Producing a Polycyclic Aromatic Compound

For producing a polycyclic aromatic compound having a structure composed of one or more of structural units represented by Formula (1) or Formula (1-a), (1-b), (1-c), (1-e), (1-f), (1-g). (1-h), (1-i), (1-j), (1-k), (1-l), (1-d), or (1-o), an intermediate is first prepared by bonding A ring (a ring) with B ring (b ring) and C ring (c ring) with a bonding group (a group containing X¹ or X²) (first reaction), and then bonding A ring (a ring), B ring (b ring), and C ring (c ring) with a bonding group (a group containing Y¹) to prepare a final product (second reaction). In the first reaction, for example, a general reaction, such as a nucleophilic substitution reaction or a Ullmann reaction, can be used, and for an amination reaction, a general reaction, such as a Buchwald-Hartwig reaction, can be used. In the second reaction, a tandem hetero-Friedel-Crafts reaction (continuous aromatic electrophilic substitution reaction—the same shall apply hereinunder) can be used. By using a raw material having a desired fused ring or adding a step of condensing a ring anywhere in the reaction step, a compound can be produced with a fused ring in which at least one ring selected from the group consisting of A ring, B ring and C ring is composed of 2 or more rings selected from the group consisting of an aryl ring of a monocyclic ring, a heteroaryl ring of a monocyclic ring, and cyclopentadiene ring.

### Production Method Via Intermediate-1

The polycyclic aromatic compound of the present invention can be produced by a production method comprising the following steps. For each step below, reference may be made to the description of WO 2015/102118.

A process comprising: a method step of metallizing a halogen atom (Hal) between X¹ and X² in Intermediate 1 below using an organic alkaline compound; a. reaction step of exchanging the metal and Y¹ using a reagent selected from the group consisting of a halide of Y¹, an amino halide of Y¹, an alkoxide of Y¹ and an aryloxy oxide of Y¹; and a reaction step of joining B ring and C ring at Y¹ by a consecutive electrophilic aromatic substitution reaction using a Bronsted base.

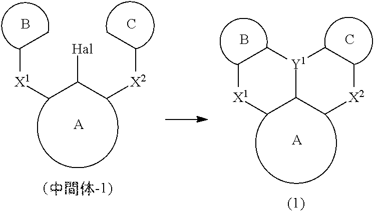

Metalating reagents used in the halogen-metal exchange reactions in the schemes described above include alkyllithium such as methyllithium, n-butyllithium, sec-butyllithium, t-butyllithium, and the like, isopropylmagnesium chloride, isopropylmagnesium bromide, phenylmagnesium chloride, phenylmagnesium bromide, a lithium chloride complex of isopropylmagnesiwn chloride, known as a turbo Grignard reagent, and the like.

In addition, as the metalation reagent used in the ortho-meal exchange reaction in the scheme described above, in addition to the above-described reagents, examples thereof include organic alkali compounds such as lithium diisopropylamide, lithium tetramethylpiperidide, lithiumhexamethyldisilazide, potassium hexamethyldisilazide, lithium tetramethylpiperidinylmagnesium chloride lithium complex, and tri-n-butyllithium mnagnesate.

Further, examples of the additive which promotes the reaction when an alkyllithium is used as the metalating reagent include N,N,N′,N′-tetramethylethylenediamine, diazabicyclo[2.2.2]octane, and N,N-dimethylpropyleneurea. AlCl₃, AlBr₃, AlF₃, BF₃.OEt₂, BCl₃, BBr₃, GaCl₃, GaBr₃, InCl₃, InBr₃, In(OTf)₃, SnCl₄, SnBr₄, AgOATf, ScCl₃, Sc(OTf)₃, ZnCl₂, ZnBr₂, Zn(OTf)₂, MgCl₂, MgBr₂, Mg(OTf)₂, LiOATf, NaOTf, KOTf, Me₃SiOTf, Cu(OTf)₂, CuCl₂, YCl₃, Y(OTf)₃, TiCl₄, TiBr₄, ZrCl₄, ZrBr₄, FeCl₃, FeBr₃, CoCl₃, CoBr₃ and others are used in the schemes described so far. Also, those in which these Lewis acids are supported on a solid can be used in the same manner.

Bronsted acids used in the schemes described above include p-toluenesulfonic acid, methanesulfonic acid, trifluoromethanesulfonic acid, fluorosulfonic acid, carbolanic acid, trifluoroacetic acid, (trifluoromethanesulfonyl)imide, tris(trifluoromethanesulfonyl)methane, hydrogen chloride, hydrogen bromide, hydrogen fluoride, and the like. Solid Bronsted acids include Amberlist (trade name: Dow Chemical), Nafion (trade name: DuPont), zeolite, TAYCACURE (trade name: Tayca Corporation), and the like.

Further, examples of amines which may be added in the scheme described above include diisopropylethylamine, triethylamine, tributylamine, 1,4-diazabicyclo[2.2.2]octane, N,N-dimethyl-p-toluidine, N,N-dimethylaniline, pyridine, 2,6-lutidine, and 2,6-di-t-butylamine.

Also, solvents used in the schemes described above include o-dichlorobenzene, chlorobenzene, toluene, benzene, methylene chloride, chloroform, di chloroethylene, benzotrifluoride, decalin, cyclohexane, hexane, heptane, 1,2,4-trimethylbenzene, xylene, diphenyl ether, anisole, cyclopentylmethyl ether, tetrahydrofuran, dioxane, methyl-t-butyl ether, and the like.

Here, although an example in which Y¹ is B has been described, it is possible to synthesize a compound in which Y¹ is P, P═O, P═S, Ga, As, Si—R or Ge—R by changing the raw material as appropriate.

In the above scheme, a Bronsted base or a Lewis acid may be used for promotion of the tandem hetero Friedel Crafts reaction. However, when Y¹ halides such as Y¹ trifluoride, Y¹ trichloride, Y¹ tribromide, and Y¹ triiodide are used, acids such as hydrogen fluoride, hydrogen chloride, hydrogen bromide, and hydrogen iodide are produced along with the progress of the electrophilic aromatic substitution reactions, and therefore the use of a Bronsted base for capturing acids is effective. On the other hand, when amino halide or Y¹ alkoxylide is used, it is not required to use a Bronsted base in many cases because of the formation of amines and alcohols as the electrophilic aromatic substitutions proceed, but the use of a Lewis acid to promote the elimination of amino and alkoxy is effective because of their low elimination ability.

Further, the polycyclic aromatic compound of the present invention also includes a compound in which at least a part of hydrogens are replaced with deuterium or cyano, or a compound in which the hydrogens are replaced with halogen such as fluorine or chlorine. Such a compound or the like can be synthesized in the same manner as described above by using a raw material in which a desired position is deuterated, cyanogenated, fluorinated or chlorinated.

2. Organic Devices

The polycyclic aromatic compound of the present invention can be used as a material for an organic device. Examples of the organic device include an organic electroluminescent element, an organic field effect transistor, and an organic thin film solar cell.

### 2-1. Organic Electroluminescent Element

### 2-1-1. Configuration of Organic Electroluminescent Element

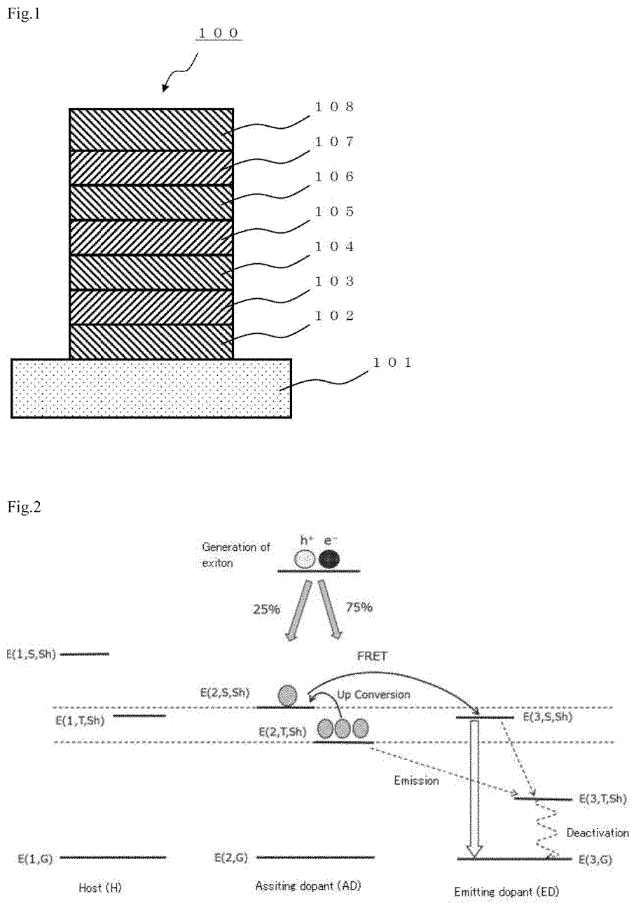

FIG. 1 shows a schematic cross-sectional view of an example of an organic electroluminescent element.

Organic EL element 100 shown in FIG. 1 has substate 101, anode 102 provided on substate 101, hole injection layer 103 provided on anode 102, hole transport layer 104 provided on hole injection layer 103, light-emitting layer 105 provided on hole transport layer 104, electron transport layer 106 provided on light-emitting layer 105, electron injection layer 107 provided on electron transport layer 106 and cathode 108 provided on electron injection layer 107.

In addition, with reversing preparation order, organic EL element 100 may he formed into a configuration having substate 101, cathode 108 provided on substate 101, electron injection layer 107 provided on cathode 108, electron transport layer 106 provided on electron injection layer 107, light-emitting layer 105 provided on electron transport layer 106, hole transport layer 104 provided on light-emitting layer 105, hole injection layer 103 provided on hole transport layer 104 and anode 102 provided on hole injection layer 103, for example.

All of the respective layers are not necessarily required, and a minimum constitutional unit may be formed into a configuration formed of anode 102, light-emitting layer 105 and cathode 108, and hole injection layer 103, hole transport layer 104, electron transport layer 106 and electron injection layer 107 are an arbitrarily provided layer. Moreover, each layer described above may be formed of a single layer, or may be formed of a plurality of layers.

A form of the layers constituting the organic EL element may be, in addition to the constitutional form of “substrate/anode/hole injection layer/hole transport layer/light-emitting layer/electron. transport layer/electron injection layer/cathode” described above, in a constitutional form such as “substrate/anode/hole transport layer/light-emitting layer/electron transport layer/electron injection layer/cathode,” “substrate/anode/hole injection layer/light-emitting layer/electron transport. layer/electron injection layer/cathode,” “substrate/anode/hole injection layer/hole transport layer/light-emitting layer/electron injection layer/cathode,” “substrate/anode/hole injection layer/hole transport layer/light-emitting layer/electron transport layer/cathode,” “substrate/anode/light-emitting layer/electron transport layer/electron injection layer/cathode,” “substrate/anode/hole transport layer/light-emitting layer/electron injection layer/cathode,” “substrate/anode/hole transport layer/light-emitting layer/electron transport layer/cathode,” “substrate/anode/hole injection layer/light-emitting layer/electron injection layer/cathode,” “substrate/anode/hole injection layer/light-emitting layer/electron transport layer/cathode,”' “substrate/anode/light-emitting layer/electron transport layer/cathode” and “substrate/anode/light-emitting layer/electron injection layer/cathode.”

2-1-2. Light-Emitting Layer in Organic Electroluminescent Element

The polycyclic aromatic compound of the present invention is preferably used as a material for forming any one or more organic layers in an organic electroluminescent element, and more preferably used as a material for torming a light-emitting layer

Light-emitting layer 105 is a layer which produces luminescence by allowing holes injected from anode 102 to recombine with electrons injected from cathode 108, between electrodes to which an electric field is applied. A material forming light-emitting layer 105 only needs be a compound (luminescent compound) which produces luminescence by being excited by recombination between the holes and the electrons, and is preferably a compound that can forms a stable thin film shape, and exhibits strong luminescence (fluorescence) efficiency in a solid state.

The polycyclic aromatic compound of the present invention can be used as a material for a light emitting layer, and may be used as a dopant material or as a host material, but is preferably used as a dopant material.

As the dopant, there is an example in which an assisting dopant and an emitting dopant are used in combination, and this example will be described below. In this specification, when simply described as “dopant”, it refers to a light emitting dopant used alone.

The light-emitting layer may be formed of a single layer or a plurality of layers, and each layer is formed of a light-emitting layer material (the host material and the dopant material), The host material and the dopant material may be in one kind, or in combination of a plurality of kinds, respectively. The dopant material may be Wholly contained in the host material, or may be partly contained therein. As a. doping method, the layer can be formed by vapor codeposition with the host material, or the dopant material is previously mixed with the host material, and then the resulting mixture may be simultaneously deposited.

The amount of the host material used varies depending on the type of the host material, and may be determined in accordance with the characteristics of the host material. The amount of the host material to be used is preferably 50 to 99.999% by mass, more preferably 80 to 99.95% by mass, and still more preferably 90 to 99.9% by mass, with respect to the total mass of the light-emitting layer.

The amount of the dopant material used varies depending on the type of the dopant material and may be determined according to characteristics of the dopant material. The amount of the dopant to be used is preferably 0.001 to 50% by mass, more preferably 0.05 to 20% by mass, and still more preferably 0.1 to 10% by mass, with respect to the total mass of the light-emitting layer. The amount within the above-described range is preferred in view of capability of preventing a concentration quenching phenomenon, for example.

### Host Material

Host materials include fused ring derivatives such as anthracene, pyrene, dibenzochrysene or fluorene, previously known as luminescents, bisstyryl derivatives such as bisstyryl anthracene and distyrylbenzene derivatives, tetraphenylbutadiene derivatives, cyclopentadiene derivatives, fluorene derivatives, benzofluorene derivatives, and di benzochrysene based compounds. As a host material when the polycyclic aromatic compound of the present invention is a dopant material, an anthracene-based compound, a fluorene-based compound, or a dibenzochrysene-based compound is preferred. Further, a polymer host material can also be used.

As the host material, for example, a compound represented by any one of Formulas (H1), (H2) and (H3) below may be used.

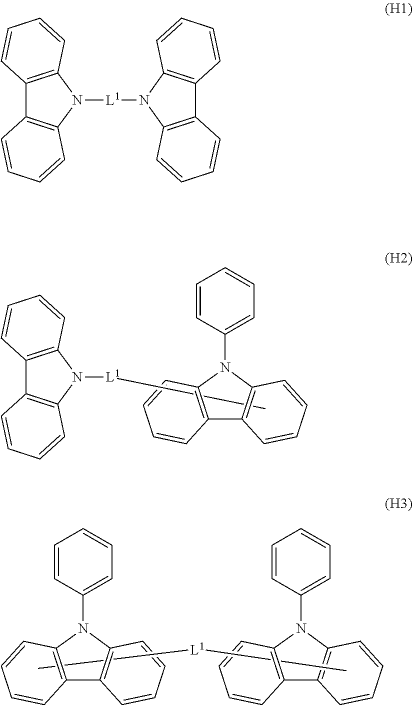

In Formulas (H1), (H2) and (H3), L¹ is an arylene having 6 to 24 carbons, a heteroarylene having 2 to 24 carbons, a heteroarylenearylene having 6 to 24 carbons and an aryleneheteroarylenearylene having 6 to 24 carbons, preferably an arylene having 6 to 16 carbons, more preferably an arylene having 6 to 12 carbons, and particularly preferably an arylene having 6 to 10 carbons, and specifically a divalent group of benzene ring, biphenyl ring, terphenyl ring, fluorene ring or the like. As heteroarylene, a heteroarylene having 2-24 carbons is preferable, and a heteroarylene having 2-15 carbons is still more preferable. Specifically, a divalent group of pyrrole ring, oxazole ring, isoxazole ring, thiazole ring, isothiazole ring, imidazole ring, oxadiazole ring, thiadiazole ring, triazole ring, tetrazole ring, pyrazole ring, pyridine ring, a pyrimidine ring, pyndazine ring, pyrazine ring, triazine ring, indole ring, isoindole ring, 1H-indazole ring, benzoimidazole ring. benzoxazole ring, benzothiazole ring, 1H-benzotriazole ring, quinoline ring, isoquinoline ring, cinnoline ring, quinazoline ring, quinoxaline ring, ph thalazine ring, naphthyridine ring, purine ring, pteridine ring, carbazole ring, acridine ring, phenoxathiin ring, phenoxazine ring, phenothiazine ring, phenazine ring, indolizine ring, furan ring, benzofuran ring, isobenzofuran ring, dibenzofuran ring, thiophene ring, benzothiophene ring, dibenzothiophene ring. furazane ring. oxadiazole ring or thianthrene ring can be exemplified.

At least one hydrogen in the compound represented by each of the above formulas may be replaced with an alkyl having 1 to 6 carbons, cyano, a halogen or deuterium.

Preferred specific examples include compounds represented by any of the structural formulas listed below. In the structural formula listed below, at least one hydrogen may be substituted with a halogen, cyano, an alkyl having 1 to 4 carbons (e.g., methyl or t-butyl), phenyl naphthyl, or the like.

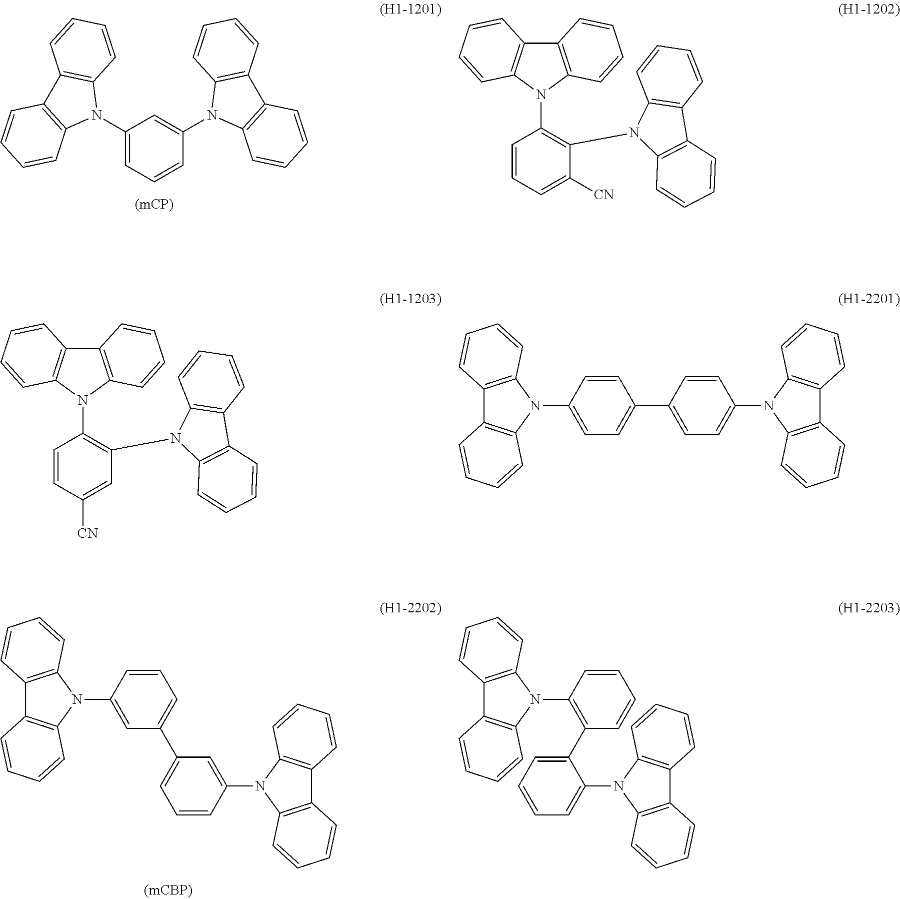 [SMILES: c1cc(-n2c3ccccc3c3ccccc32)cc(-n2c3ccccc3c3ccccc32)c1 ; N#Cc1cccc(-n2c3ccccc3c3ccccc32)c1-n1c2ccccc2c2ccccc21 ; N#Cc1ccc(-n2c3ccccc3c3ccccc32)c(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1]

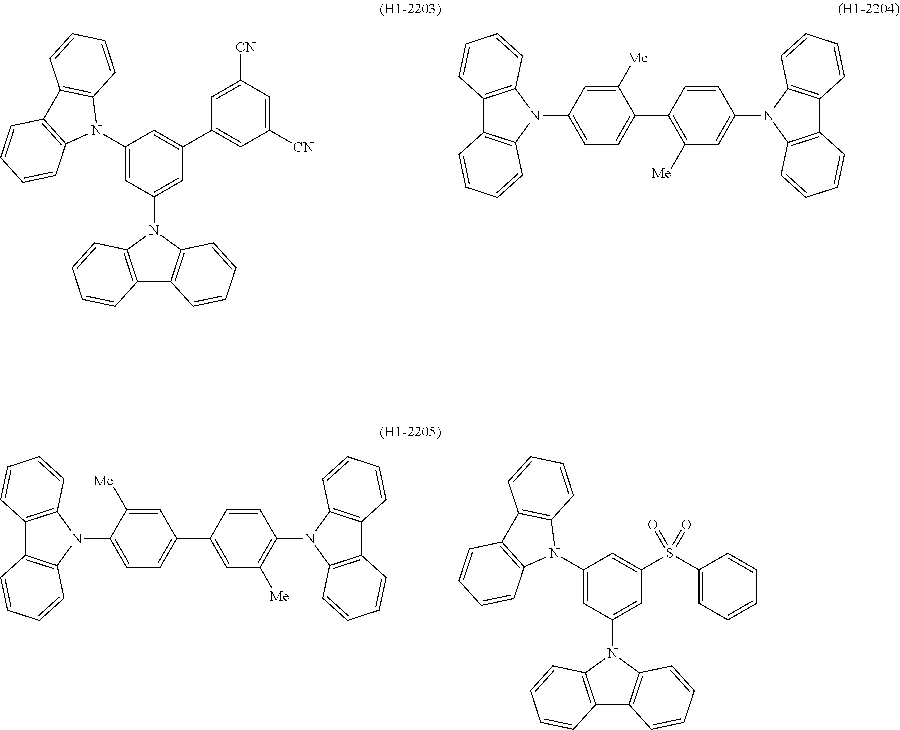 [SMILES: N#Cc1cc(C#N)cc(-c2cc(-n3c4ccccc4c4ccccc43)cc(-n3c4ccccc4c4ccccc43)c2)c1 ; Cc1cc(-n2c3ccccc3c3ccccc32)ccc1-c1ccc(-n2c3ccccc3c3ccccc32)cc1C ; Cc1cc(-c2ccc(-n3c4ccccc4c4ccccc43)c(C)c2)ccc1-n1c2ccccc2c2ccccc21 ; O=S(=O)(c1ccccc1)c1cc(-n2c3ccccc3c3ccccc32)cc(-n2c3ccccc3c3ccccc32)c1]

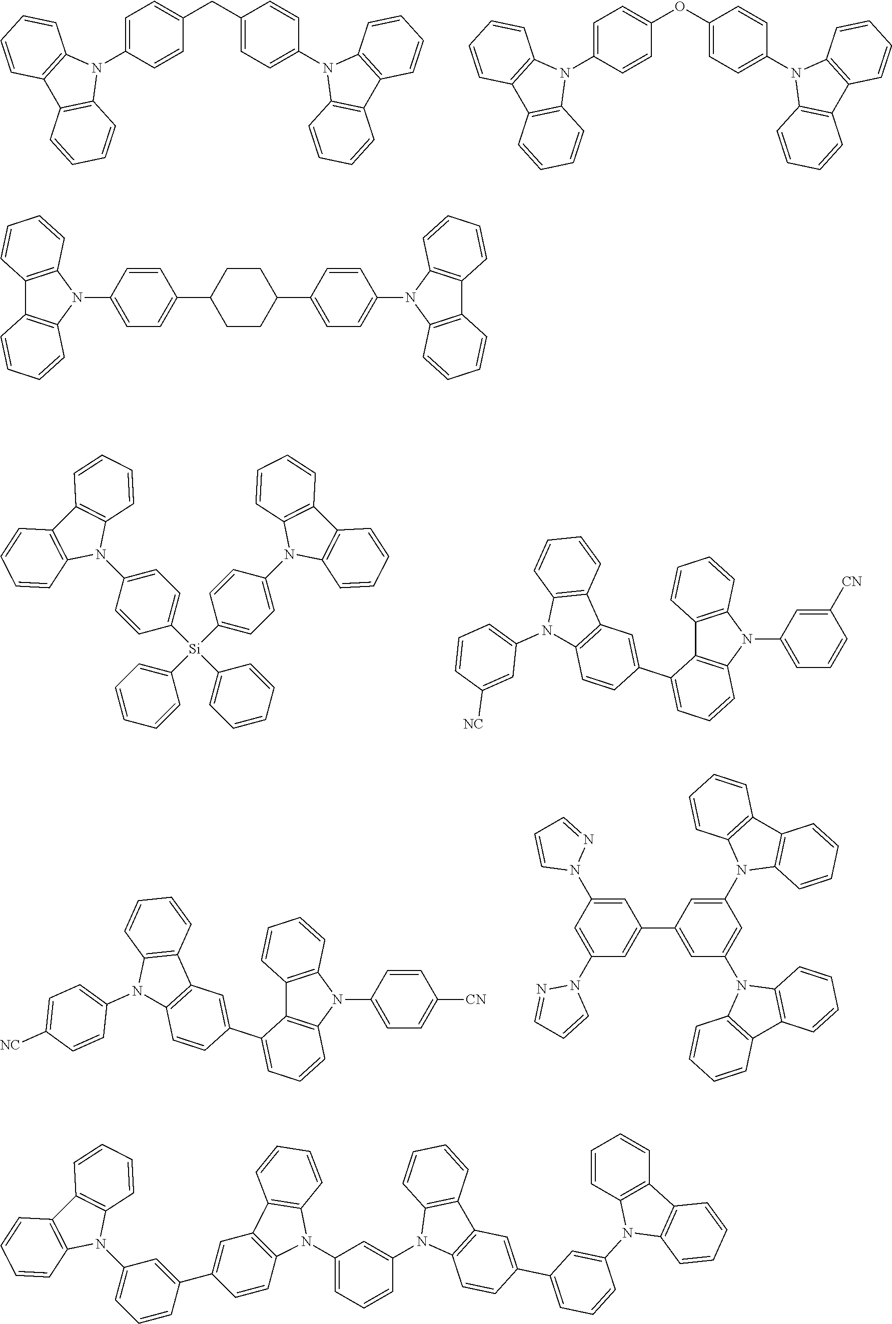

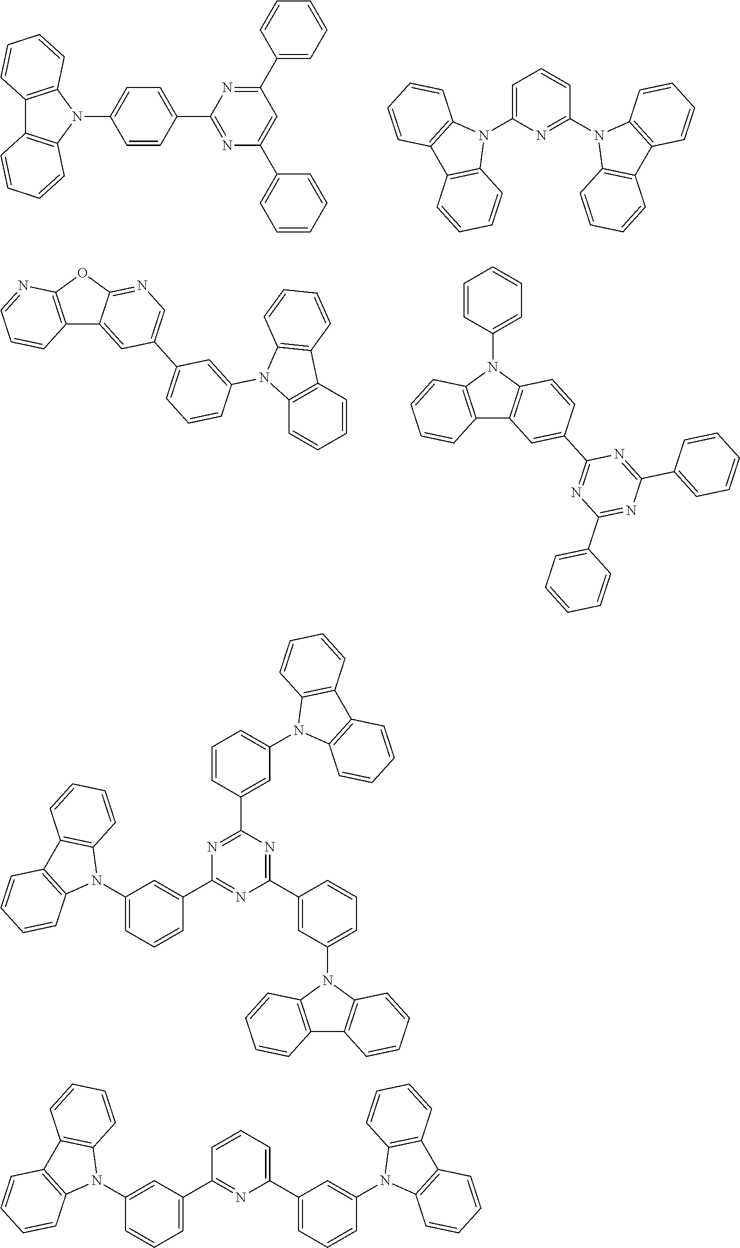

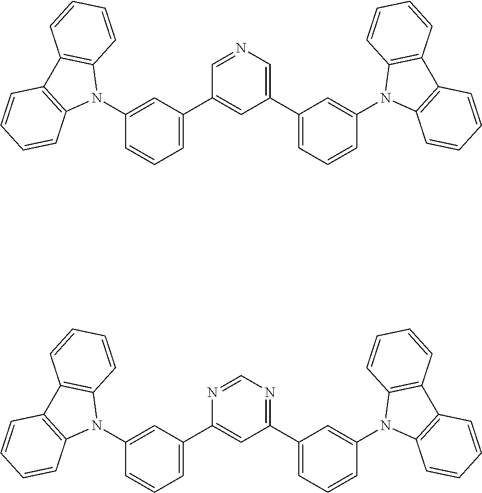 [SMILES: c1cc(-c2cncc(-c3cccc(-n4c5ccccc5c5ccccc54)c3)c2)cc(-n2c3ccccc3c3ccccc32)c1 ; c1cc(-c2cc(-c3cccc(-n4c5ccccc5c5ccccc54)c3)ncn2)cc(-n2c3ccccc3c3ccccc32)c1]

### <Anthracene-Based Compound>

Examples of anthracene-bed compound as a host include a compound represented by Formula (3-H) and a compound represented by Formula (3-H2).

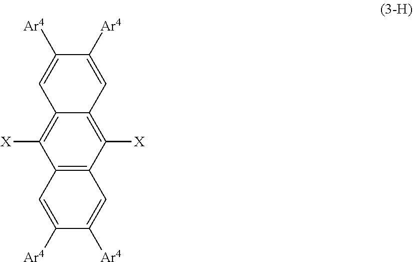

In Formula (3-H):
X and Ar⁴ is each independently hydrogen, an aryl which may be subjected to substitution, a heteroaryl which may be subjected to substitution, a diarylamino which may be subjected to substitution, a diheteroarylamino which may be subjected to substitution, an arylheteroarylamino which may be subjected to substitution, an alkyl which may be subjected to substitution, a cycloalkyl which may be subjected to substitution, an alkenyl which may be subjected to substitution, an alkoxy which may be subjected to substitution, an aryloxy which may be subjected to substitution, an arylthio which may be subjected to substitution or a silyl which may be subjected to substitution, and a case where all of X and Ar⁴ simultaneously become hydrogen is excluded, and at least one hydrogen in the compound represented by formula (3-H) may be replaced with a halogen, cyano, deuterium or a heteroaryl which may be subjected to substitution.

Further, a multimer (preferably a dimer) may be formed using a structure represented by Formula (3-H) as a unit structure. In this case, for example, an embodiment in which a plural of the unit structure represented by Formula(3-H) is bonded via X can be exemplified. Examples of X include single bond, an arylene (phenylene, biphenylene and naphthylene, etc), a heteroarylene (a divalent group of pyridine ring, dibenzofuran ring, dibenzothiophene ring, carbazole ring, benzocarbazole ring and phenyl-substituted carbazole ring, etc.) and the like.

For details of each group in the compound represented by Formula (3-H), the description in Formula (1) above can be referred to. The details will be further described in the column of the following preferred embodiments.

Preferred embodiments of the above anthracene-based compound will be described below. The definitions of the symbols in the following structures are the same as those described above.

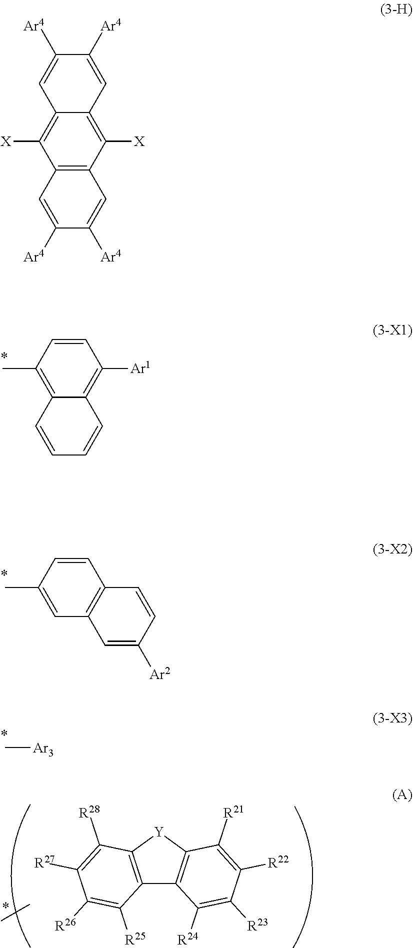

In Formula (3-H), X is each independently a group represented by Formula (3-X1), Formula (3-X2) or Formula (3-X3). The group represented by Formula (3-X1), Formula (3-X2) or Formula (3-X3) is bonded to the anthracene ring in Formula (3-H) at “*.” Preferably, two X are not the group represented by Formula (3-X3) at the same time.. More preferably, two X are not the group represented by Formula (3-X2) at the same time.

Further, a multimer (preferably a dimer) may be formed using a structure represented by Formula (3-H) as a unit structure. In this case, for example, an embodiment in which a plural of the unit structures represented by Formula (3-H) is bonded via X can be exemplified. Examples of X include single bond, an arylene (phenylene, biphenylene and na.phthylene, etc.) and a heteroarylene (a divalent group of pyridine ring, dibenzofuran ring, dibenzothiophene ring, carbazole ring, benzocarbazole ring or phenyl-substituted carbazole ring, etc) and the like.

A naphthylene site in formula (3-X1) and formula (3-X2) may be fused by one benzene ring. A structure thus fused is as described below.

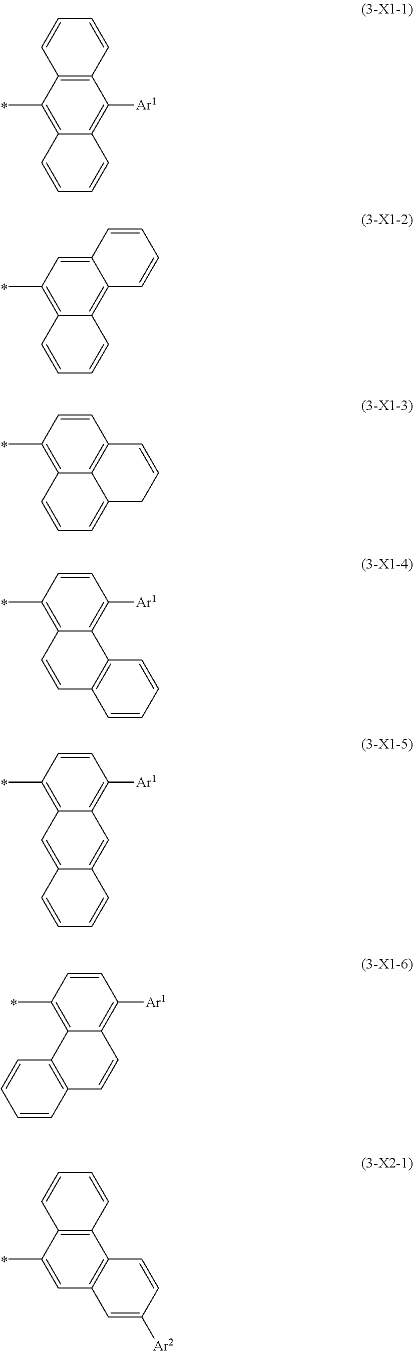

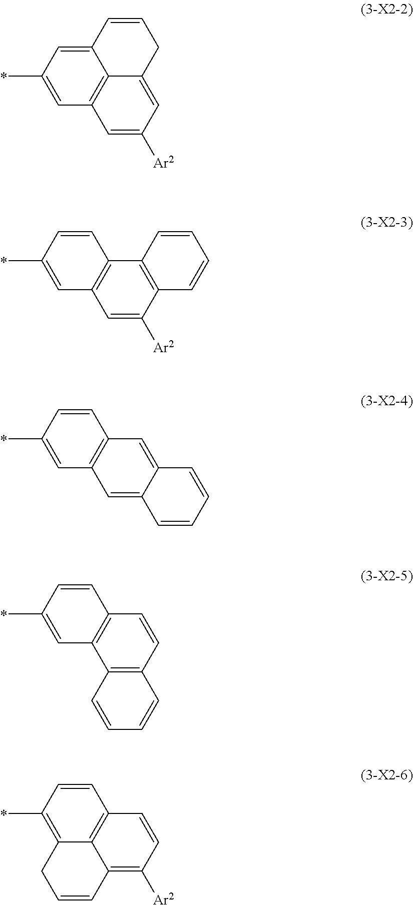

Ar¹ and Ar² are each independently hydrogen, phenyl, biphenylyl, terphenylyl, quaterphenylyl, naphthyl, phenanthryl, fluorenyl, benzofluorenyl, chrysenyl, triphenylenyl, pyrenyl, or a group represented by formula, (A) described below (also including carbazolyl, benzocarbazolyl and a phenyl-substituted carbazolyl). In addition, when Ar¹ or Ar² is a group represented by formula (A), the group represented by formula (A) is bonded to a naphthalene ring in formula (3-X1) or formula (3-X2) at a position “*.”

Ar³ is phenyl, biphenylyl, terphenylyl, quaterphenylyl, naphthyl, phenanthryl, fluorenyl, benzofluorenyl, chrysenyl, triphenylenyl, pyrenyl, or a group represented by formula (A) (also including carbazolyl, benzocarbazolyl and a phenyl-substituted carbazolyl). In addition, when Ar³ is a group represented by formula (A), the group represented by formula (A) is bonded to a single bond represented by a straight line in formula (3-X3) at a position “*.” More specifically, the anthracene ring in formula (3-H) is directly bonded to the group represented by formula (A).

Moreover, Ar³ may have a substituent, and at least one hydrogen in Ar³ may be replaced with phenyl, biphenylyl, terphenylyl, naphthyl, phenanthryl, fluorenyl, chrysenyl, triphenylenyl, pyrenyl, or a group represented by formula (A) (also including carbazolyl and a phenyl-substituted carbazolyl). In addition, when the substituent of Ar³ is the group represented by formula (A), the group represented by formula (A) is bonded to Ar³ in formula (3-X3) at a position “*.”

Ar⁴ is each independently hydrogen, phenyl, biphenylyl, terphenylyl, naphthyl, or silyl which has as substituents an alkyl having 1 to 4 carbons (metyl, ethyl, t-butyl, or the like) and/or a cycloalkyl having 5 to 10 carbons.

Specific example of the alkyl having 1 to 4 carbons by which silyl is replaced include methyl, ethyl, propyl, isopropyl, butyl, sec-butyl, t-butyl and cyclobutyl, and three hydrogens in silyl are independently replaced with an alkyl.

Specific examples of the “silyl which has as substituents an alkyl having 1 to 4 carbons alkyl” include trimethylsilyl, triethylsilyl, tripropylsilyl, triisopropylsilyl, tributylsilyl, trisec-butylsilyl, trit-butylsilyl, ethyldimethylsilyl, propyldimethylsilyl, i-propyldimethylsilyl, butyldimethylsilyl, sec-butyldimethylsilyl, t-butyldimethylsilyl, methyldiethylsilyl, propyldiethylsilyl, i-propyldiethylsilyl, sec-butyldiethylsilyl, t-butyldiethylsilyl, methyldipropylsilyl, ethyldipropylsilyl, butyldipropylsilyl, sec-butyldipropylsilyl, t-butyldipropylsilyl, methyldiisopropylsilyl, ethyldiisopropylsilyl, butyldiisopropylsilyl, sec-butyldiisopropylsilyl and t-butyldiisopropylsilyl.

Cycloal having 5 to 10 carbons as substituent to silyl include cyclopentyl, cyclohexyl, cycioheptyl, cyclooctyl, cyclononyl, cyclodecyl, and an alkyl (especially methyl) substituents thereof having 1 to 5 carbons, norbornyl(bicyclo[2.2.1]heptyl), bicyclo[1.1.1]pentyl, bicyclo[2.1.0]pentyl, bicyclo[2.1.1]hexyl, bicyclo[3.1.0]hexyl, bicyclo[2.2.2]octyl, adamanthyl, diamantyl, decahydronaphthalenyl, and decahydroazulenyl and each of the three hydrogens in silyl is independently replaced with one of these cycloalkyls.

Specific examples of “a silyl substituted with a cycloalkyl having 5 to 10 carbons” include clopentylsilyl and tricyclohexylsilyl.

Examples of the substituted silyi include a dialkylcycloalkylsilyl substituted with two alkyls and one cycloalkyl, and an alkyldicycloalkylsilyl substituted with one alkyl and two cycloalkyls. Specific examples of the alkyl and cycloalkyl as the substitutents include the above-mentioned groups.

Moreover, hydrogen in a chemical structure of the anthracene-based compound represented by formula (3-H) may be replaced with the group represented by formula (A). When the hydrogen is replaced by the group represented by formula (A), at least one hydrogen in the compound represented by formula (3-H) is replaced with the group represented by formula (A) at a position “*.”

The group represented by Formula (A) is one of the substituents that the anthracene-based compound represented by Formula (3-H) can have.

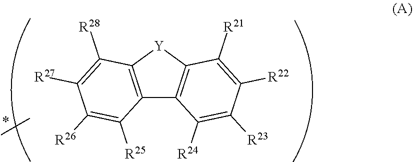

In formula (A), Y is —O—, —S— or >N—R²⁹,R²¹ to R²⁸ are each independently hydrogen, an alkyl which may be subjected to substitution, a cycloalkyl which may be subjected to substitution, an aryl which may be subjected to substitution, a heteroaryl which may be subjected to substitution, an alkoxy which may be subjected to substitution, an aryloxy which may be subjected to substitution, an arylthio which may he subjected to substitution, a trialkylsilyl, a tricycloalkylsilyl, an alkyldicycloalkylsilyl, an amino which may be subjected to substitution, halogen, hydroxy or cyano, and adjacent groups of R²¹ to R²⁸ may be bonded to each other to form a hydrocarbon ring, an aryl ring or a heteroaryl ring, and R²⁹ is hydrogen or aryl which may be subjected to substitution.

Y in formula (A) is preferably —O—.

The “alkyl” of the “alkyl which may be subjected to substitution” in R²¹ to R²⁸ may he any of a straight-chain alkyl and a branched-chain alkyl, and specific examples thereof include a straight-chain alkyl having 1 to 24 carbons or a branched-chain alkyl having 3 to 24 carbons. An alkyl having 3 to 18 carbons (branched-chain alkyl having 3 to 18 carbons) is preferred, an alkyl having 1 to 12 carbons (branched-chain alkyl having 3 to 12 carbons) is further preferred, an alkyl having 1 to 6 carbons (branched-chain alkyl having 3 to 6 carbons) is still further preferred, and an alkyl having 1 to 4 carbons (branched-chain alkyl having 3 to 4 carbons) is particularly preferred.

Specific examples of the “alkyl” include methyl, ethyl, n-propyl, isopropyl, n-butyl, isohutyl, s-butyl, t-butyl, n-pentyl, isopentyl, neopentyl, t-pentyl, n-hexyl, 1-methylpentyl, 4-methyl-2-pentyl, 3,3-dimethylbutyl, 2-ethylbutyl, n-heptyl, 1-methylhexyl, n-octyl, t-octyl, 1-methylheptyl, 2-ethylhexyl 2-propypentyl, n-nonyl, 2,2-dimethylheptyl, 2,6-dimethyl-4-heptyl, 3,5,5-trimethylhexyl, n-decyl, n-andecyl, 1-methyldecyl, n-dodecyl, n-tridecyl, hexylheptyl, n-tetradecyl, n-pentadecyl, n-hexadecyl, n-heptadecyl, n-octadecyl and n-eicosyl.

Moreover, specific examples of “cycloalkyl” of the “cycoloalkyl which may be subjected to substitution” in R²¹ to R²⁸ include a cycloalkyl having 3 to 24 carbons, a cycloalkyl having 3 to 20 carbons, a cycloalkyl having 3 to 16 carbons, a cycloalkyl having 3 to 14 carbons, a cycloalkyl having 5 to 10 carbons, a cycloalkyl having 5 to 8 carbons, a cycloalkyl having 5 to 6 carbons, a cycloalkyl having 5 carbons, and the like.

Specific examples of the cycloalkyl include cyclopropyl, cyclobutyl, cyclopentyl, cyclohexyl, cycloheptyl, cyclooctyl, cyclononyl, cyclodecyl, and an alkyl (especially methyl) substituents thereof having 1 to 5 carbons, norbornyl(bicyclo[2.2.1]heptyl), bicyclo[1.1.0]butyl, bicyclo[1.1.1]pentyl, bicyclo[2.1.0]pentyl, bicyclo[2.1.1]hexyl, bicyclo[3.1.0]hexyl, bicyclo[2.2.2]octyl, adamanthyl, diamantyl, decahydronaphthalenyl, and decahydroazulenyl.

Specific examples of the “aryl” of the “aryl which may be subjected to substitution” in R²¹ to R²⁸ include an aryl having 6 to 30 carbons, and an aryl having 6 to 20 carbons is preferred, an aryl having 6 to 16 carbons is further preferred, and an aryl having 6 to 10 carbons is particularly preferred.

Specific examples of the “aryl” include phenyl as monocyclic aryl, biphenylyl as bicyclic aryl, naphthyl as fused bicyclic aryl, terphenylyl (m-terphenylyl, o-terphenylyi, p-terphenylyl) as tricyclic aryl, acenaphthylenyl, fluorenyl, phenalenyl and phenanthrenyl as fused tricyclic aryl, triphenylenyl, pyrenyl and naphthacenyl as fused tetracyclic aryl, and perylenyl and pentacenyl as fused pentacyclic aryl.

Specific examples of the “heteroaryl” of the “heteroaryl which may be subjected to substitution” in R²¹ to R²⁸ include a heteroaryl having 2 to 30 carbons or a heteroaryl having 2 to 25 carbons is preferred, a heteroaryl having 2 to 20 carbons is further preferred, a heteroaryl having 2 to 15 carbons is still further preferred, and a heteroaryl having 2 to 10 carbons is particularly preferred. Moreover, specific examples of the heterocycle include a heterocyclic ring containing, in addition to carbon, 1 to 5 hetero atoms selected from oxygen, sulfur and nitrogen as a ring-forming atom.

Specific examples of the “heteroaryl” include pyrrolyl, oxazolyl, isoxazolyl, thiazolyl isothiazolyl, imidazolyL oxadiazolyl, thiadiazolyl, triazolyl, tetrazoryl, pyrazolyl, pyridyl, pyrimidinyl, pyridazinyl, pyrazinyl, thoriadinyl, indolyl, isoindolyl, benzimidazolyl, benzoxazolyl, benzothiazolyl, 1H-benzotriazoryl, quinolyl, isoquinolyl, cinnolyl, quinazolyl, quinoxalinyl, phthalazinyl, naphthyridinyl, purinyl, pteridinyl, carbazolyl, acridinyl, phenoxathiinyl, phenoxazinyl, phenothiazinyl, phenazinyl, indolizinyl, furyl, benzofuranyl, isobenzofuranyl, dibenzofuranyl, thienyl, benzo[b]thienyl, dibenzothienyl, furazanyl, oxadiazolyl, thianthrenyl, naphthobenzofuranyl and naphthobenzothienyl.

Specific examples of the “alkoxy” of the “alkoxy which may be subjected to substitution” in R²¹ to R²⁸ include a straight-chain alkoxy having 1 to 24 carbons or a branched-chain alkoxy having 3 to 24 carbons. An alkoxy having 1 to 18 carbons (a branched-chain alkoxy having 3 to 18 carbons) is preferred, an alkoxy having 1 to 12 carbons (branched-chain alkoxy having 3 to 12 carbons) is further preferred, an alkoxy having 1 to 6 carbons (branched-chain alkoxy having 3 to 6 carbons) is still further preferred, and an alkoxy having 1 to 4 carbons (branched-chain alkoxy having 3 to 4 carbons) is particularly preferred.

Specific examples of the “alkoxy” include methoxy, ethoxy, propoxy, isopropoxy, butoxy, isobutoxy, s-butoxy, t-butoxy, pentyloxy, hexyloxy, heptyloxy and octyloxy.

Specific examples of the “aryloxy” of the “aryloxy which may be subjected to substitution” in R²¹ to R²⁸ include a group in which hydrogen of an —OH group is replaced by aryl, and for the above aryl, the groups described as the “aryl” in R²¹ to R²⁸ can be quoted.

Specific examples of the “arylthio” of the “arylthio which may be subjected to substitution” in R²¹ to R²⁸ include a group in which hydrogen of an —SH group is replaced by aryl, and for the above aryl, the groups described as the “aryl” in R²¹ to R²⁸ can be quoted.

Specific examples of the “trialkylsilyl” in R²¹ to R²⁸ include a group in which three hydrogens in a silyl group are independently replaced by alkyl, and for the above alkyl, the groups described as the “alkyl” in R²¹ to R²⁸ can be quoted. Alkyl by which hydrogen is preferably replaced is alkyl having 1 to 4 carbons, and specific examples thereof include methyl, ethyl, propyl, i-propyl, butyl, sec-butyl, t-butyl and cyclobutyl.

Specific examples of the “trialkylsilyl” include trimethylsilyl, triethylsilyl, tripropylsilyl, triisopropylsilyl, tributylsilyl, trisec-butylsilyl, ethyldimethylsilyl, propyldimethylsilyl, i-propyldimethylsilyl, butyldimethylsilyl, sec-butyldimethylsilyl, t-butyldimethylsilyl, methyldiethylsilyl, propyldiethylsilyl, i-propyldiethylsilyl, butyldiethylsilyl, sec-butyldiethylsilyl, t-butyldiethylsilyl, methyldipropylsilyl, ethyldipropylsilyl, butyldipropylsilyl, sec-butyldipropylsilyl, t-butyldipropylsilyl, methyldiisopropylsilyl, ethyldiisopropylsilyl, butyldiisopropylsilyl, sec-butyldiisopropylsilyl and t-butyldiisopropylsilyl.

Examples of the “tricycloalkylsilyl” in R²¹ to R²⁸ include groups in which the three hydrogens in the silyl group are each independently replaced with cycloalkyl. For the cycloalkyl, the groups described as “cycloalkyl” in the above described R²¹ to R²⁸ can be referred to. A preferable cycloalkyl as the substituent is a cycloalkyl having 5 to 10 carbons and specific examples include cyclopentyl, cyclohexyl, cycloheptyl, cyclooctyl, cyclononyl, cyclodecyl, bicyclo[1.1.1]pentyl, bicyclo[2.1.0]pentyl, bicyclo[2.1.1]hexyl, bicyclo[3.1.0]hexyl, bicyclo[2.2.1]heptyl, bicyclo[2.2.2]octyl, adamanthyl, diamantyl, decahydronaphthalenyl, and decahydroazulenyl.

Cycloalkyl having 5 to 10 carbons as substituent to silyl include cyclopentyl, cyclohexyl, cycloheptyl, cyclooctyl, cyclononyl, cyclodecyl, and an alkyl (especially methyl) substituents thereof having 1 to 5 carbons, norbornyl(bicyclo[2.2.1]heptyl), bicyclo[1.1.1]pentyl, bicyclo[2.1.0]pentyl, bicyclo[2.1.1]hexyl bicyclo[3.1.0]hexyl, bicyclo[2.2.2]octyl, adamantlyl, diamantyl, decahydronaphthalenyl, and decahydroazulenyl and each of the three hydrogens in silyl is independently replaced with one of these cycloalkyls.

Specific examples of the “tricycloalkylsilyl” include tricyclopentylsilyl and tricyclohexylsilyl.

Specific examples of the dialkylcycloalkylsilyl substituted with two alkyls and one cycloalkyl, and the alkyldicvcloalkylsilyl substituted with one alkyl and two cycloalkyls include a silyl substituted with a group selected from the specific alkyl and cycloalkyl described above.

Specific examples of the “substituted amino” of the “amino which may be subjected to substitution” in R²¹ to R²⁸ include an amino group in which two hydrogens are replaced by aryl or heteroaryl. Amino in which two hydrogens are replaced by aryl is diaryl-substituted amino, amino in which two hydrogens are replaced by heteroaryl is diheteroaryl-substituted amino, and amino in which two hydrogens are replaced by aryl and heteroaryl is aryl heteroaryl-substituted amino. For the above aryl or heteroaryl, the groups described as the “aryl” or the “heteroaryl” in R²¹ to R′⁸ can be quoted.

Specific examples of the “substituted amino” include diphenylamino, dinaphthylamino, phenylnaphthylamino, dipyridyl amino, phenylpyridylamino and naphthylpyridylamino.

Specific examples of the “halogen” in R²¹ to R²⁸ include fluorine, chlorine, bromine and iodine.

Some of the groups described as R²¹ to R²⁸ may be substituted as described above and the substituents include an alkyl, a cycloalkyl, an aryl or a heteroaryl. For the alkyl, cycloalkyl, aryl or heteroaryl, the groups described as “alkyl”, “cycloalkyl”, “aryl” or “heteroaryl” in the above R²¹ to R²⁸ can be referred to.

Several of the groups described as R²¹ to R²⁸ may be subjected to substitution as described above, and specific examples of the substituent in the above case include alkyl, cycloalkyl, aryl or heteroaryl. For the above alkyl, cycloalkyl, aryl or heteroaryl, the groups described as the “alkyl,” “cycloalkyl,” “aryl” or “heteroaryl” in R²¹ to R²⁸ can be quoted.

R²⁹ in “>N—R²⁹” as Y is hydrogen or aryl which may be subjected to substitution, and as the above aryl, the groups described as the “aryl” in R²¹ to R²⁸ can be quoted, and as the substituent, the groups described as the substituent to R²¹ to R²⁸ can be quoted.

Adjacent groups of R²¹ to R²⁸ may be bonded to each other to form a hydrocarbon ring, an aryl ring or a heteroaryl ring. Specific examples thereof include a group represented by formula. (A-1) in the case where the ring is not formed, and groups represented by formulas (A-2) to (A-14) in the case where the ring is formed. In addition, at least one hydrogen in the group represented by any one of formulas (A-1) to (A-14) may be replaced with an alkyl, a cycloalkyl, an aryl, a heteroaryl, an alkoxy, an aryloxy, an aryl thio, a trialkylsilyl, a tricycloalkylsilyl, a dialkylcycloalkylsilyl, an alkyldicycloalkylsilyl, a diaryl-substituted amino, a diheteroaryl-substituted amino, an arylheteroaryl-substituted amino, a halogen and hydroxy or cyano.

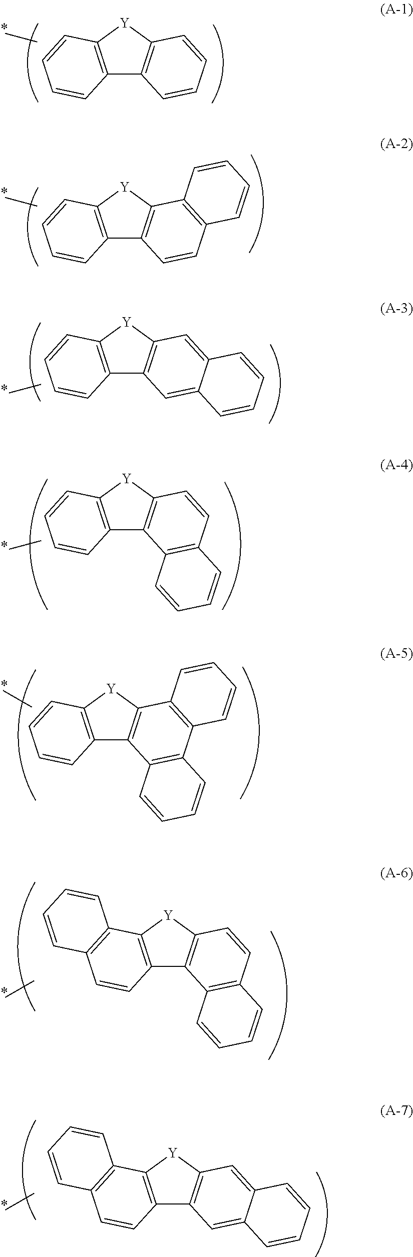

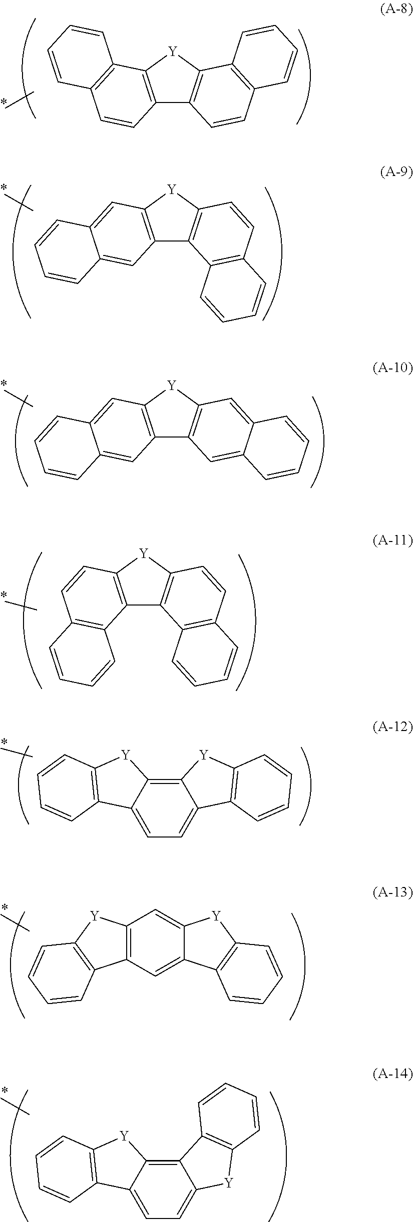

Specific examples of the ring formed by bonding adjacent groups to each other include a cyclohexane ring, if the ring is a hydrocarbon ring, and the ring structure described as the “aryl” or the “heteroaryl” in R²¹ to R²⁸, if the ring is the aryl ring or the heteroaryl ring, in which the above rings are formed so as to be fused to one or two benzene rings in formula (A-1).

The group represented by Formula (A) is a group obtained by deleting one hydrogen at any position of Formula (A), and * indicates the position at which the hydrogen is deleted. In other words, the group represented by Formula (A) may have the bonding position at any position. For example, it can be any carbon atom on two benzene rings in the structure of formula (A). an atom on any ring formed by bonding adjacent groups of R²¹ to R²⁸ in the structure of formula (A) to each other, any position in R²⁹ in “>N—R⁹⁹ⁿ” as Y in the structure of formula (A), or N in “>N—R²⁹” (R²⁹ is a bonding hand). The same applies to the group represented by any of Formulas (A-1) to (A-14).

The group represented by Formula (A) includes, for example, a group represented by any of Formulas (A-1) to (A-14), a group represented by any of Formulas (A-1) to (A-5) and Formulas (A-12) to (A-14) is preferable, a group represented by any of Formulas (A-1) to (A-4) is more preferable, a group represented by any of Formulas (A-1), (A-3) and (A-4) is more preferable, and a group represented by Formula (A-1) is particularly preferable.

Examples of the group represented by Formula (A) include the following groups. Y and a position “*” in the formulas have the same definition as described above.

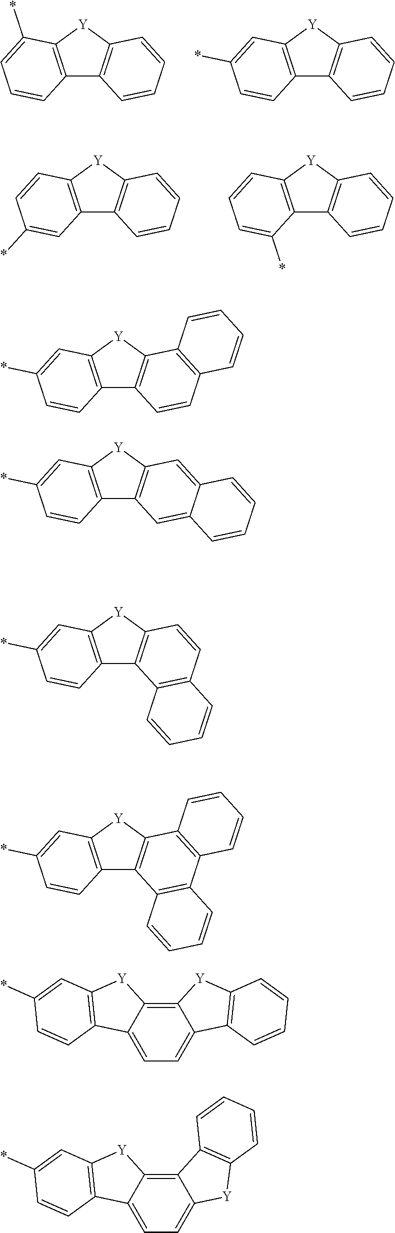

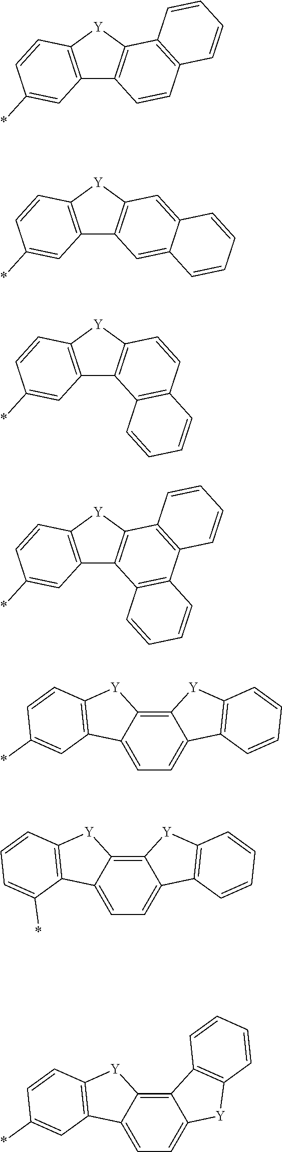

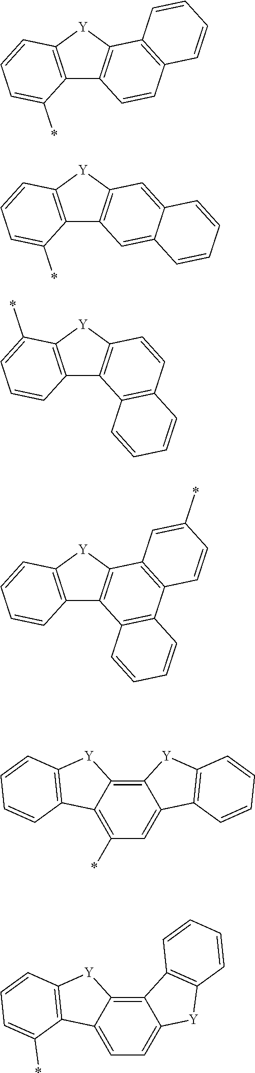

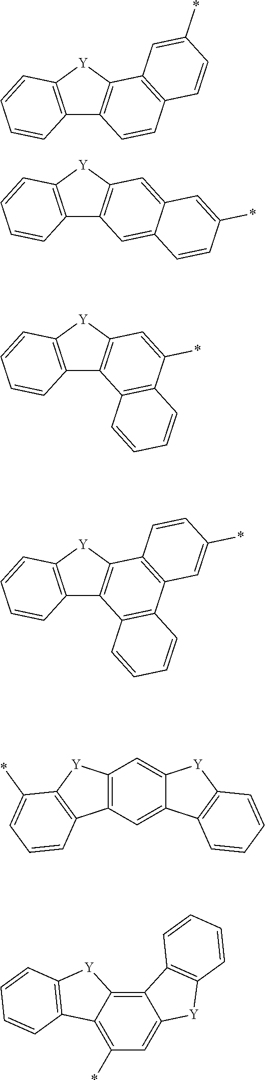

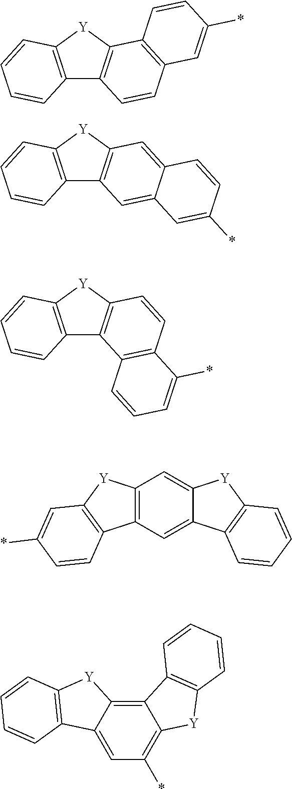

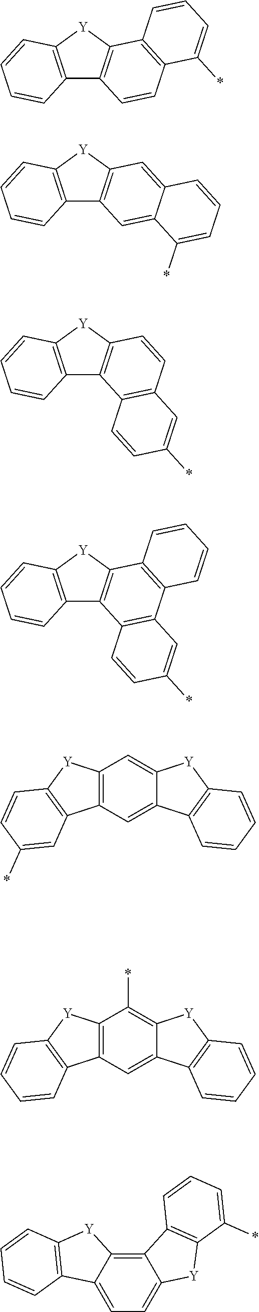

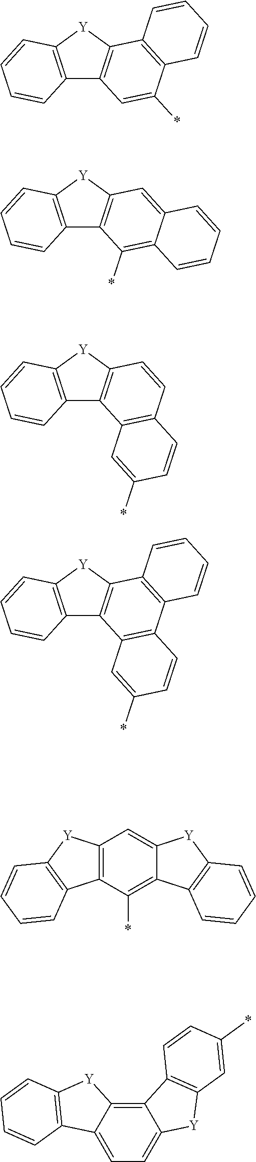

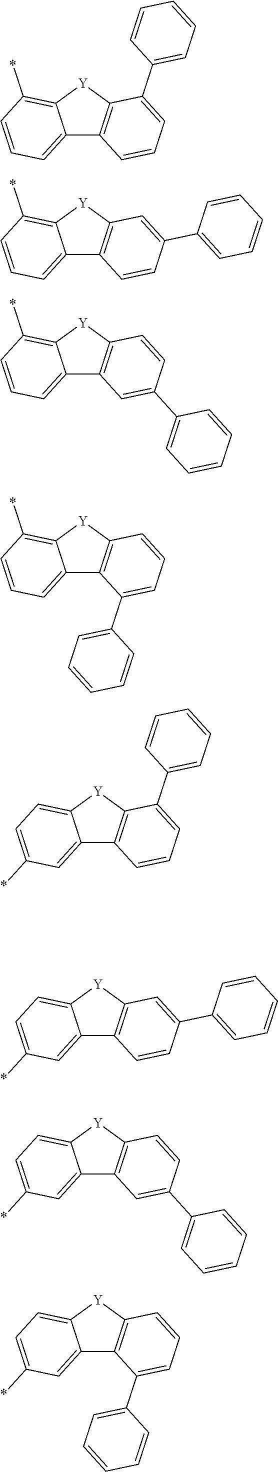

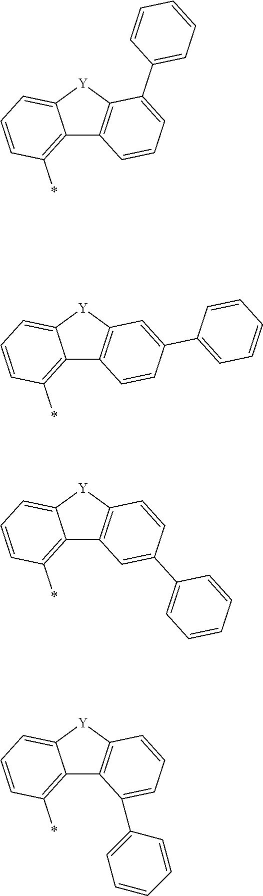

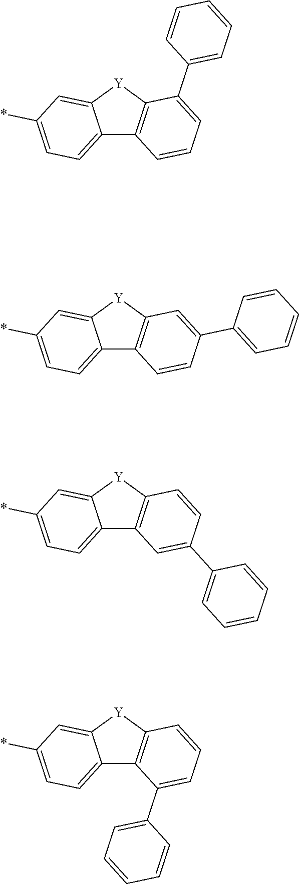

In the compound represented by Formula (3-H), the group represented by formula (A) preferably binds to a naphthalene ring in Formula (3-X1) or Formula (3-X2), a single bond in Formula (3-X3) and/or Ar³ in Formula (3-X3).

Moreover, all or a part of hydrogens in the chemical structure of the anthracene-based compound represented by Formula (3-H) may be deuterium.

The anthracene-based compound as a host may be, for example, a compound represented by Formula (3-H2) below

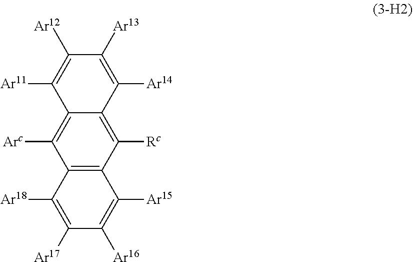

In Formula (3-H2), Ar^{c} is an optionally substituted aryl or an optionally substituted heteroaryl, R^{c} is hydrogen, an alkyl, or a cycloalkyl, and Ar¹¹, Ar¹², Ar¹³, Ar¹⁴, Ar¹⁵, Ar¹⁶, Ar¹⁷ and Ar¹⁸ are each independently hydrogen, an optionally substituted aryl, an optionally substituted heteroaryl, an optionally substituted diarylamino, an optionally substituted diheteroarylamino, an optionally substituted arylheteroalylamino, an optionally substituted alkyl, an optionally substituted cycloalkyl, an optionally substituted alkenyl, an optionally substituted alkoxy, an optionally substituted aryloxy, an optionally substituted arylthio, or a substituted silyl, and at least one hydrogen in a compound represented by Formula (3-H2) may be replaced with a halogen, cyano, or deuterium.

The definitions of “an optionally substituted aryl,” “an optionally substituted heteroaryl,” “an optionally substituted diarylamino,” “an optionally substituted diheteroarylamino,” “an optionally substituted arylheteroarylamino,” “an optionally substituted alkyl,” “an optionally substituted cycloalkyl,” “an optionally substituted alkenyl,” “an optionally substituted alkoxy,” “an optionally substituted aryloxy,” “an optionally substituted arylthio,” or “a substituted silyl” in Formula (3-H2) are the same as those in Formula (3-H) above and the descriptions in Formula (3-H) can be referred to.

As the “optionally substituted aryl”, a group represented by any one of Formulas (3-H2-X1) to (3-H2-X7) below is also preferred.

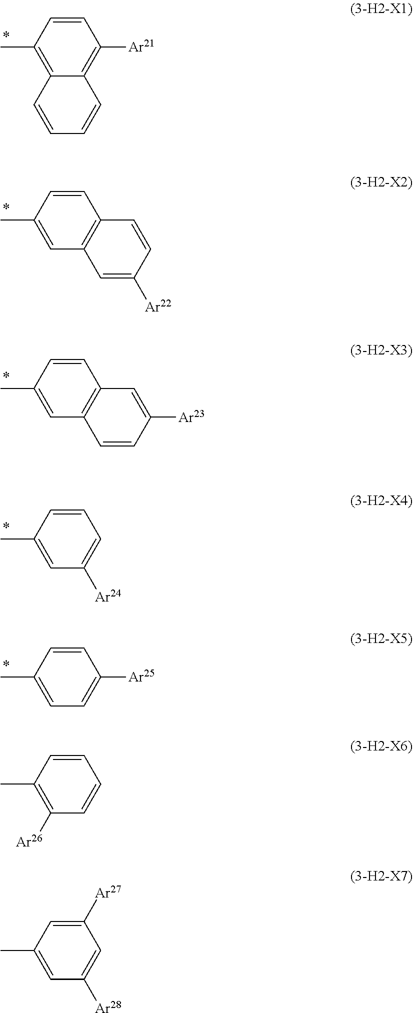

In the formulas (3-H2-X1) to (3-H2-X7), * denotes a bonding position.

In Formulas (3-H2-X1) to (3-H2-X3), Ar²¹, Ar²², and Ar²³ are each independently hydrogen phenyl, biphenylyl, terphenylyl, quaterphenylyl, naphthyl, phenanthryl, fluorenyl, benzofluorenyl, chrysenyl, triphenylenyl, pyrenyl, anthracenyl, or a group represented by formula (A) In the description of Formula (3412), the group represented by Formula (A) is the same as that described in the anthracene-based compound represented by Formula (3-H).

In Formulas (3-H2-X4) to (3-H2-X7), Ar²⁴, Ar²⁵, Ar²⁶, Ar²⁷ and Ar²⁸ are each independently hydrogen, phenyl, biphenylyl, terphenylyl, naphthyl, phenanthryl, fluorenyl, chrysenyl, triphenylenyl, pyrenyl, or a group represented by formula (A).

In addition, any one or two or more hydrogens in each of the groups represented by Formula (3-H2-X1) to Formula (3-H2-X7) may be replaced with an alkyl having 1 to 6 carbons (preferably methyl or t-butyl).

Further, preferred examples of “optionally substituted aryl” include terphenylyl (particularly m-terphenyl-5′-yl), which may be substituted with one or more substituents selected from the group consisting of phenyl, biphenylyl, terphenylyl, naphthyl, phenanthryl, fluorenyl, chrysenyl, triphenylenyl, pyrenyl, and a group represented by formula (A).

Examples of the “optionally substituted heteroaryl” also include a group represented by Formula (A).

In addition, specific examples of “optionally substituted aryl” and “optionally substituted heteroaryl” include dibenzofuryl, naphthobenzofuryl, a phenyl-substituted dibenzofuryl, and the like.

At least one hydrogen in the compound represented by Formula (3-H2) may be replaced with a halogen, cyano, or deuterium. The “halogen” includes fluorine, chlorine, bromine, and iodine. In particular, a compound in which all hydrogens in the compound represented by Formula (3-H2) are replaced with deuterium is preferred.

In Formula(3-H2), R^{c} is hydrogen, an alkyl, or a cycloalkyl, preferably hydrogen, methyl, or t-butyl, more preferably hydrogen.

In Formula (3-H2), it is preferable that at least two of Ar¹¹ to Ar¹⁸ are an optionally substituted aryl or an optionally substituted heteroaryl. In other words, it is preferable that the anthracene-based compound represented by Formula (3-H2) has a structure in which at least 3 substituents selected from the group consisting of an optionally substituted aryl and an optionally substituted heteroaryl are bonded to an anthracene ring.

It is more preferable that in the anthracene-based compound represented by Formula (3-H2) two of Ar¹¹ to Ar¹⁸ are each independently an optionally substituted aryl or an optionally substituted heteroaryl, and that the other six are hydrogen, an optionally substituted alkyl, an optionally substituted cycloalkyl, an optionally substituted alkenyl, or an optionally substituted alkoxy. In other words, it is more preferable that the anthracene-based compound represented by Formula (3-H2) has a structure in which 3 substituents selected from the group consisting of an optionally substituted aryl and an optionally substituted heteroaryl are bonded to an anthracene ring.

More preferably, in the anthracene-based compound represented by Formula. (3-H2) any two of Ar¹¹ to Ar¹⁸ are each independently an optionally substituted aryl or an optionally substituted heteroaryl, and that the other six are each independently hydrogen, methyl, or t-butyl.

Further, in Formula(3-H2), it is preferable that R^{c} is hydrogen and any six of Ar¹¹ to Ar¹⁸ are hydrogen.

The anthracene-based compound represented by Formula (3-H2) is preferably an anthracene-based compound represented by Formula (3-H2-A), (3-H2-B), (3-H2-C), (3-H2-D), or (3-H2-E) below.

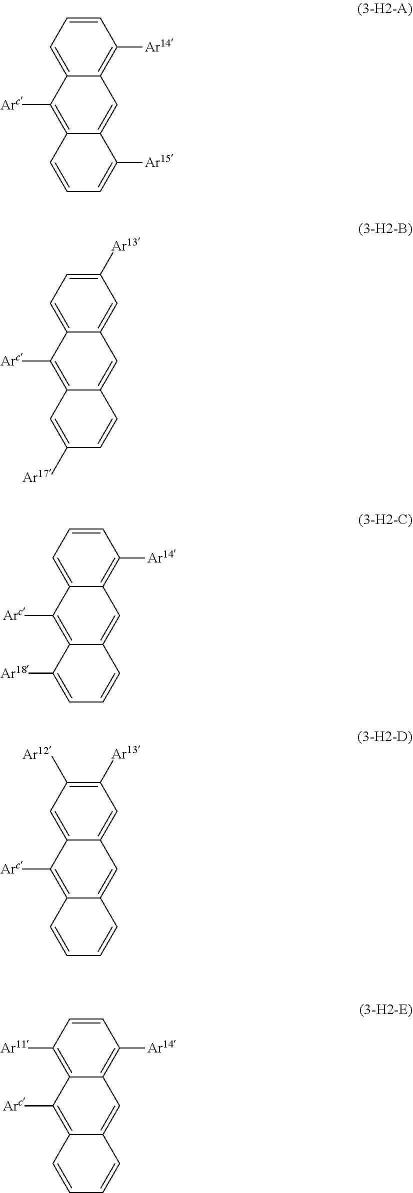

In Formulas (3-H2-A), (3-H2-B), (3-H2-C), (3-H2-D), or (3-H2-E) , Ar^{c}′, Ar¹¹′, Ar¹²′, Ar¹³′, Ar¹⁴′, Ar¹⁵′, Ar¹⁷′ and Ar¹⁸′ are each independently phenyl, biphenylyl, terphenylyl, quaterphenylyl, naphthyl, phenanthtyl, fluorenyl, benzofluorenyl, chrysenyl, triphenylenyl, pyrenyl, or a group represented by formula (A), and at least one hydrogen in each of the above groups may be replaced with phenyl, biphenylyl, terphenylyl, quaterphenylyl, naphthyl, phenanthryl, fluorenyl, benzofluorenyl, chrysenyl, triphenylenyl, pyrenyl, or a group represented by formula (A). Here, when the hydrogens of methylene in fluorenyl and benzofluorenyl are both replaced with phenyls, these phenyls may be bonded to each other via a single bond. The carbons of the anthracene ring to which Ar^{c}′, Ar¹¹′, Ar¹²′, Ar¹³′, Ar¹⁴′, Ar¹⁵′, Ar¹⁷′, or Ar¹⁸′ is not bonded may be bonded with methyl or t-butyl instead of hydrogen.

A substituted or unsubstituted phenyl or a substituted or unsubstituted naphthyl as Ar^{c}′, Ar¹¹′, Ar¹²′, Ar¹³′, Ar¹⁴′, Ar¹⁵′, Ar¹⁷′, or Ar¹⁸′ is preferably a group represented by any of Formulas (3-H2-X1) to (3-H2-X7) above.

Ar^{c}′, Ar¹¹′, Ar¹²′, Ar¹⁴′, Ar¹⁵′, Ar¹⁷′, and Ar¹⁸′ is each independently phenyl, biphenyl (particularly biphenyl-2-yl or biphenyl-4-yl), terphenyl (particularly m-terphenyl-5′-yl), naphthyl, phenanthryl, fluorenyl, or any of the above formulas (A-1) to (A-4), wherein at least one of the hydrogens in these groups may be replaced with phenyl, biphenyl, naphthyl, phenanthryl, fluorenyl, or any of Formulas (A-1) to (A-4).

In addition, at least one hydrogen in the compound represented by Formula (3-H2-A), (3-H2-B), (3-H2-C), (3-H2-D), or (3-H2-E) may be replaced with a halogen, cyano, or deuterium.

Particularly preferred examples of the anthracene-based compound represented by Formula (3-H2) include an anthracene-based compound represented by Formula (3-H2-Aa) below.

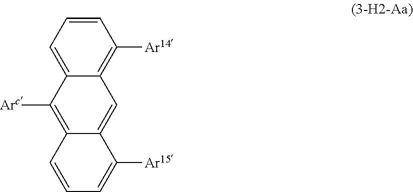

In Formula (3-H2-Aa), Ar^{c}′, Ar¹⁴′ and Ar¹⁵′ are each independently phenyl, biphenylyl, terphenylyl, naphthyl, phenanthryl, fluorenyl, benzofluorenyl, cricenyl, triphenylyl, pyrenyl, or a group represented by any of Formulas (A-1) to (A-11) above, and at least one of the hydrogens in these groups may be replaced with a group represented by phenyl, biphenyl, terphenyl, naphthyl, phenanthryl, fluorenyl, benzofluorenyl, chrysenyl, triphenylenyl, pyrenyl, or any of Formula (A-1) to Formula (A-11). When the hydrogens of methylene in fluorenyl and benzofluorenyl are both replaced with phenyls, these phenyls may be bonded to each other via a single bond. The carbons on the anthracene ring to which Ar^{c}′, Ar¹⁴′ and Ar¹⁵′ are not bonded may be substituted with methyl or t-butyl instead of hydrogens. At least one hydrogen in the compound represented by Formula (3-H2-Aa) may be replaced with a halogen or cyano, and at least one hydrogen in the compound represented by Formula (3-H2-Aa) is replaced with deuterium.

In Formula (3-H2-Aa), Ar^{c}′, Ar¹⁴′ and Ar¹⁵′ are preferably each independently phenyl, biphenylyl, terphenylyl, naphthyl, phenanthryl, fluorenyl, or a group represented by any of Formulas (A-1) to (A-4) above, and at least one of the hydrogens in these groups may be replaced with phenyl, naphthyl, phenanthryl, fluorenyl, or a group represented by any of Formulas (A-1) to (A-4).

In the compound represented by Formula (3-H2-Aa), it is preferable that at least a hydrogen bonded to a carbon at position 10 of an anthracene ring (a carbon to which Ar^{c}′ is bonded is set at position 9) is replaced with deuterium. In other words, the compound represented by Formula (3-H2-Aa) is preferably a compound represented by the following Formula (3-H2-Ab). In Formula(3-H2-Ab), D is deuterium, and Ar^{c}′, Ar¹⁴′ and Ar¹⁵′ are the same as defined in Formula,(3-H2-Aa). D in Formula (3-H2-Ab) indicates that at least this position is deuterium, and any one or more other hydrogens in Formula (3-H2-Aa) may be deuterium at the same time, and it is also preferred that every hydrogen in Formula (3-H2-Aa) is deuterium.

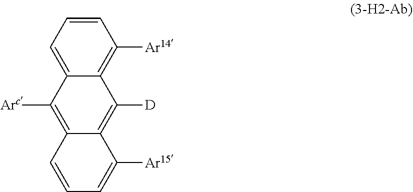

Specific examples of the anthracene-based compound include, for example, compounds represented by the following formulas. In the following structural formulas, “Me” represents methyl, “D” represents deuterium, and “tBu” represents t-butyl.

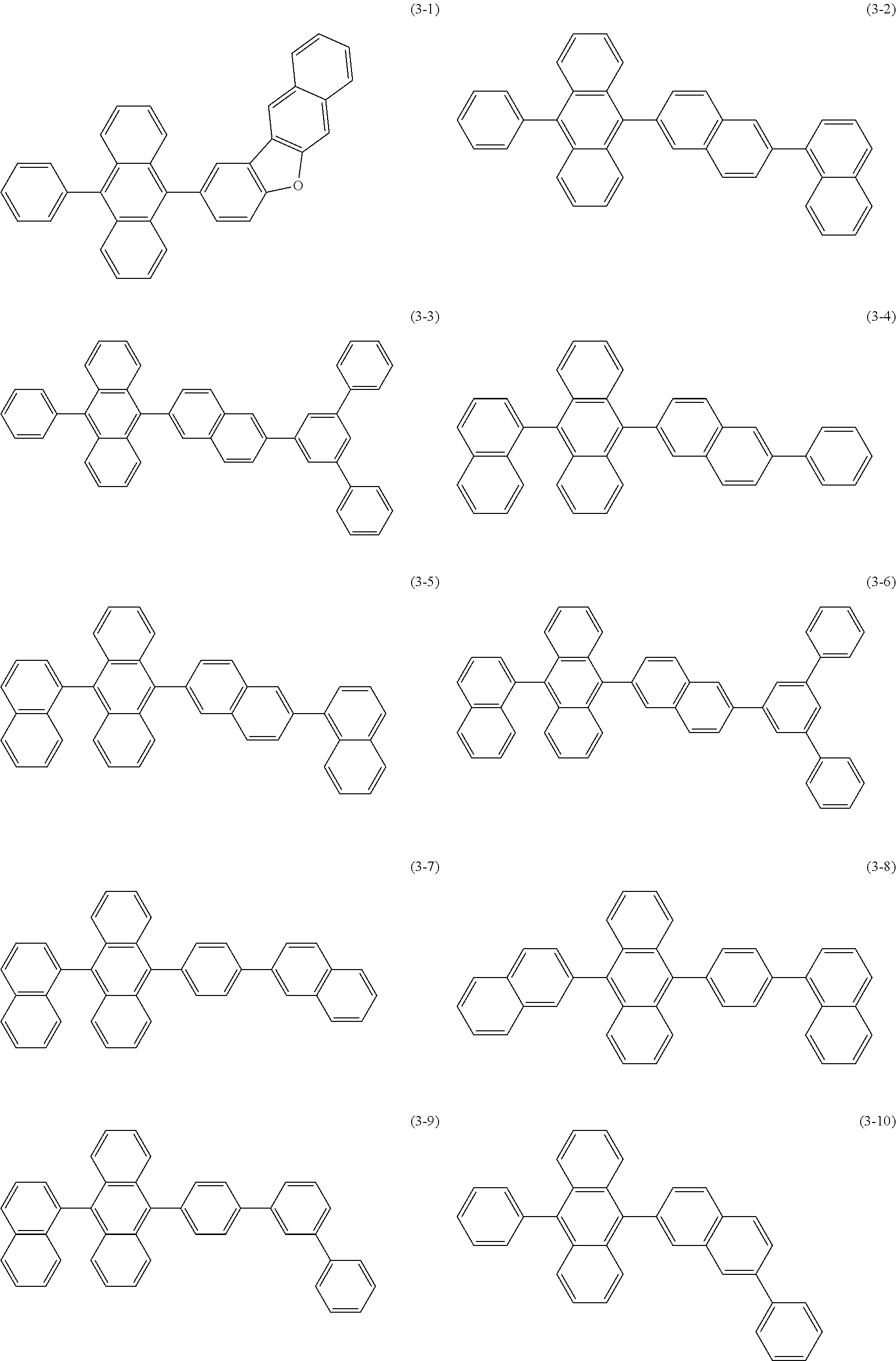

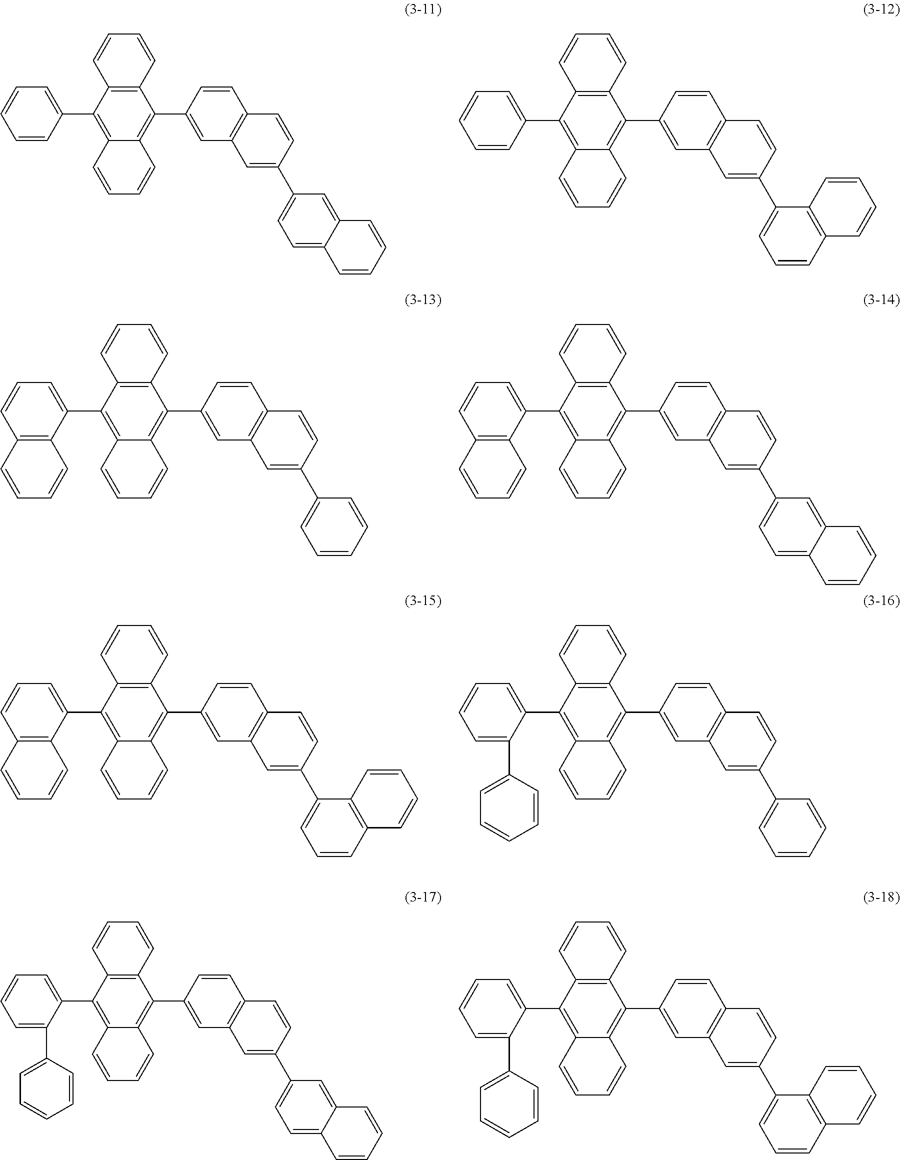

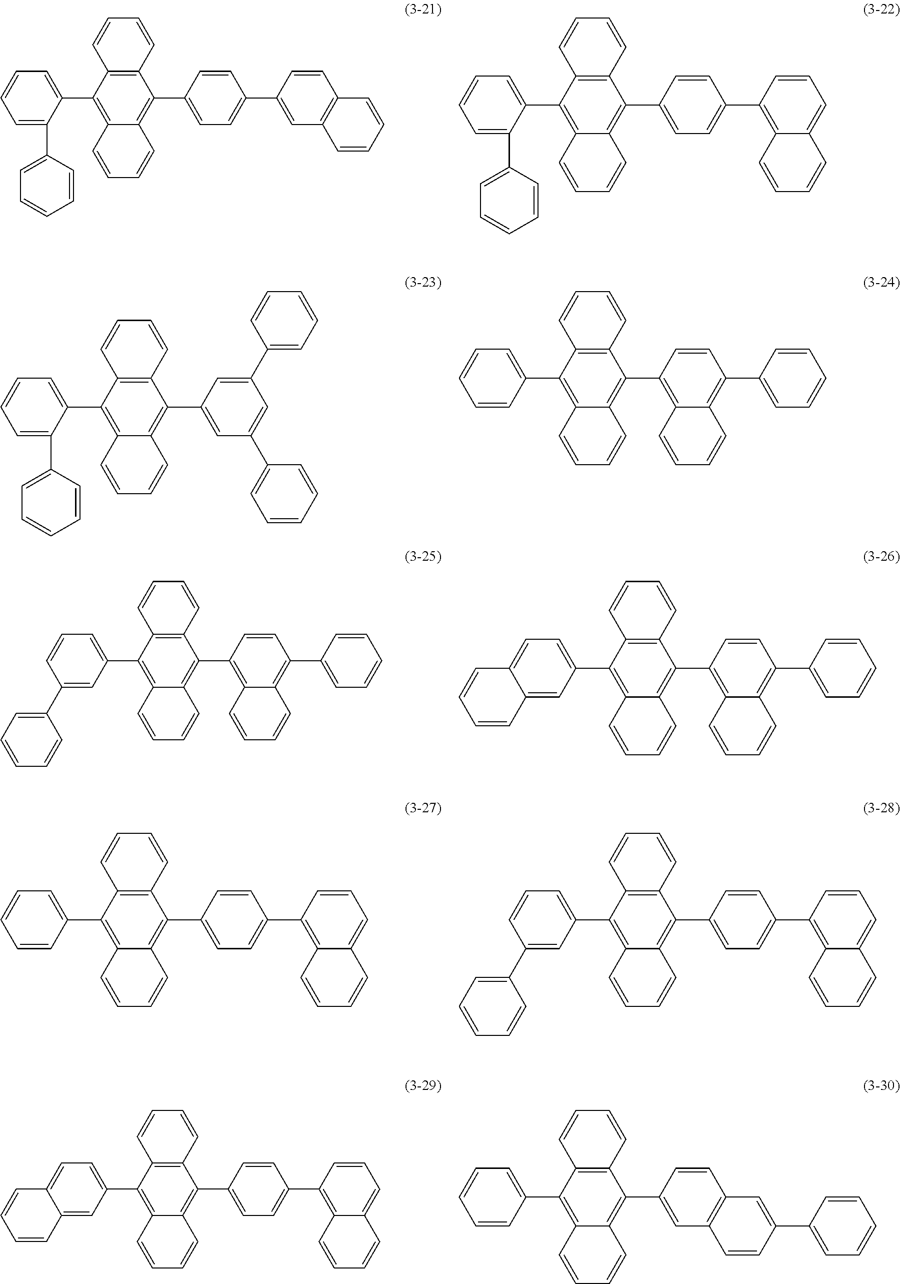

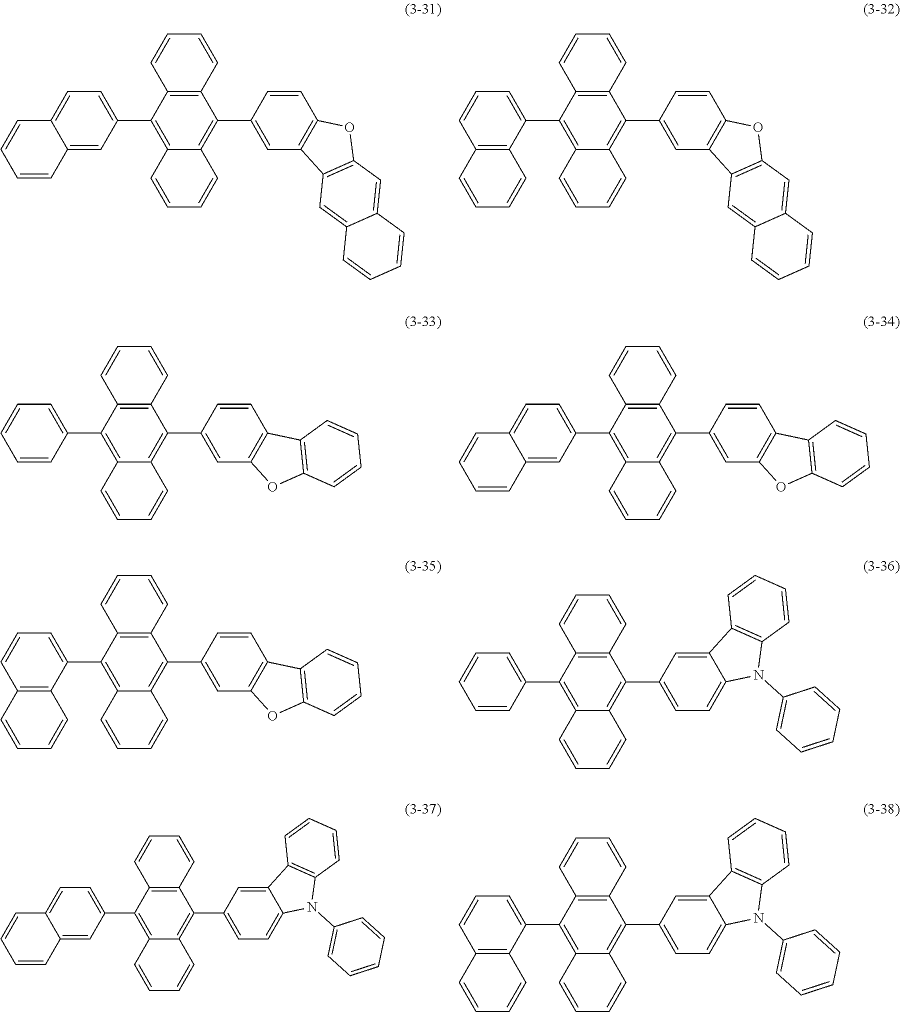

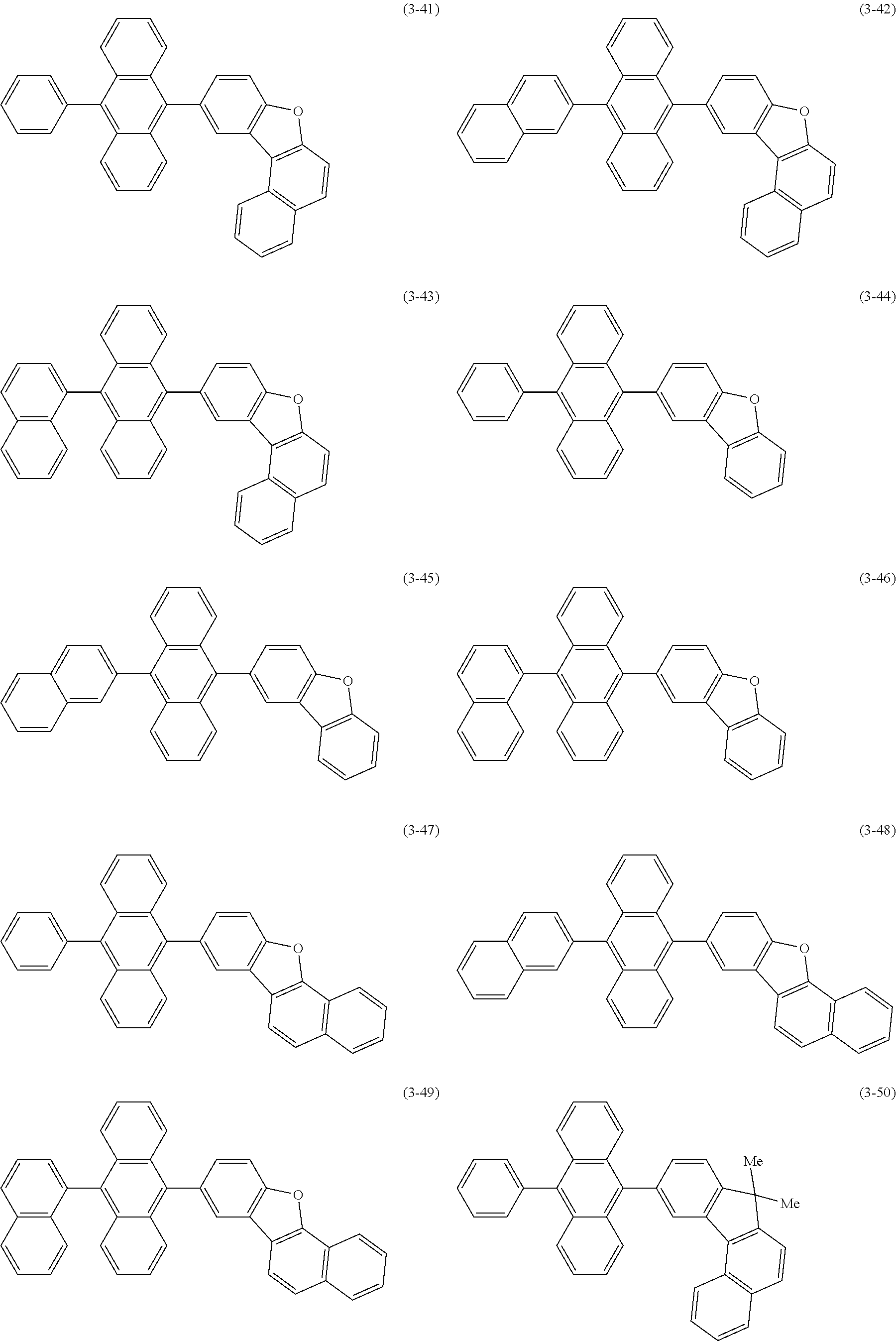

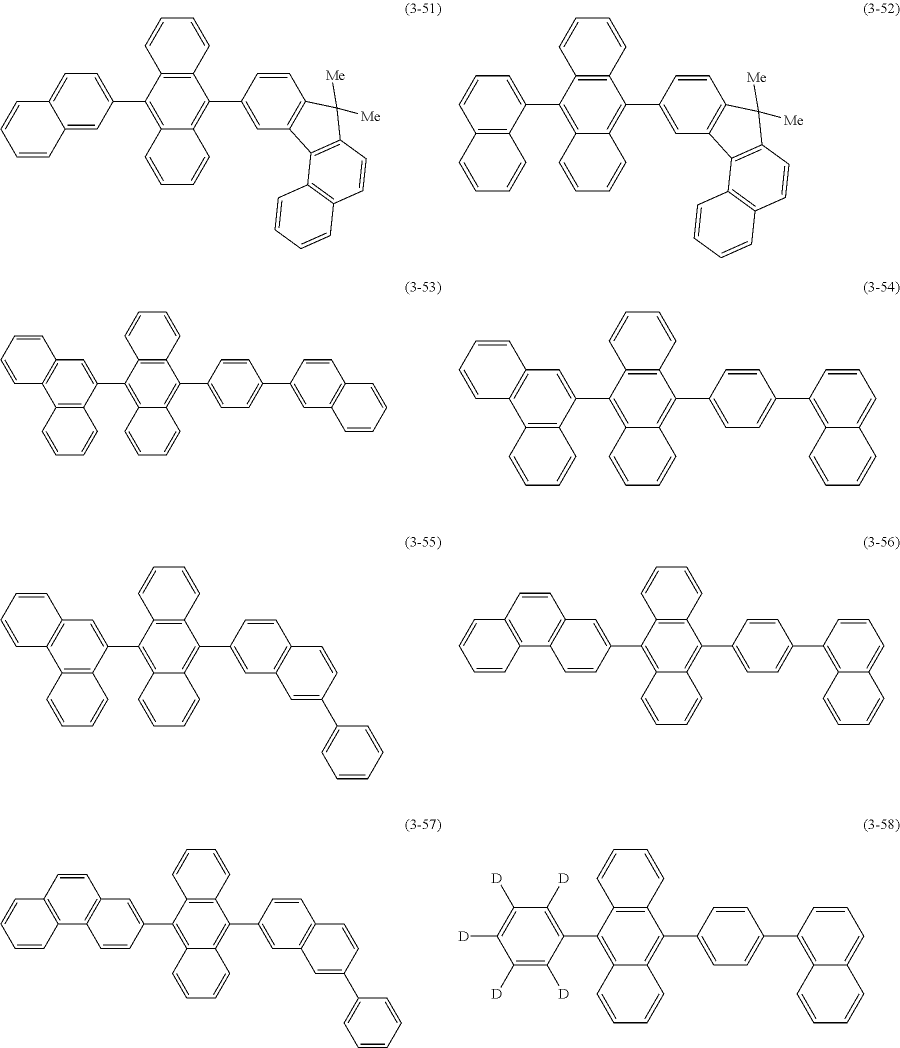

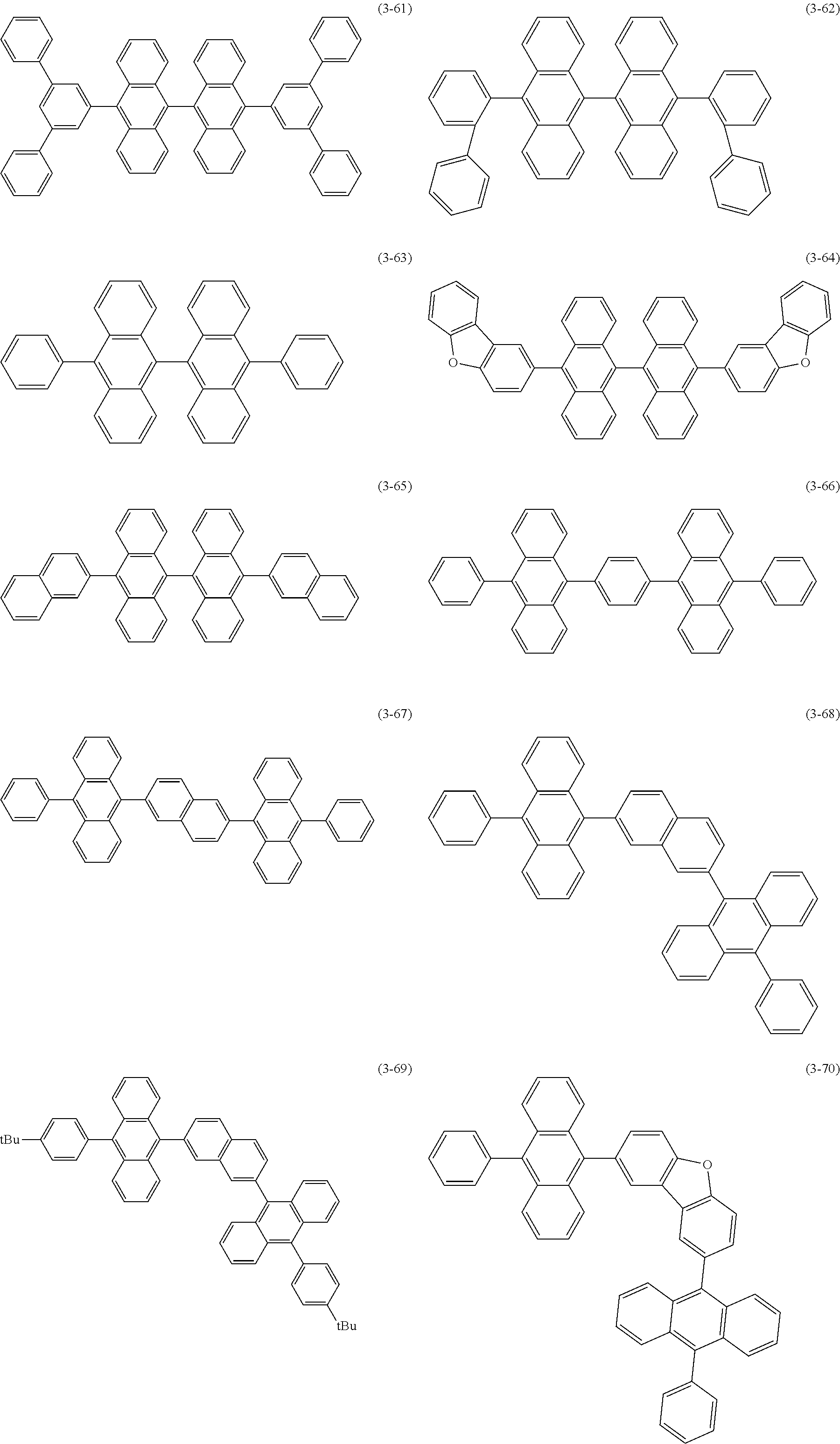

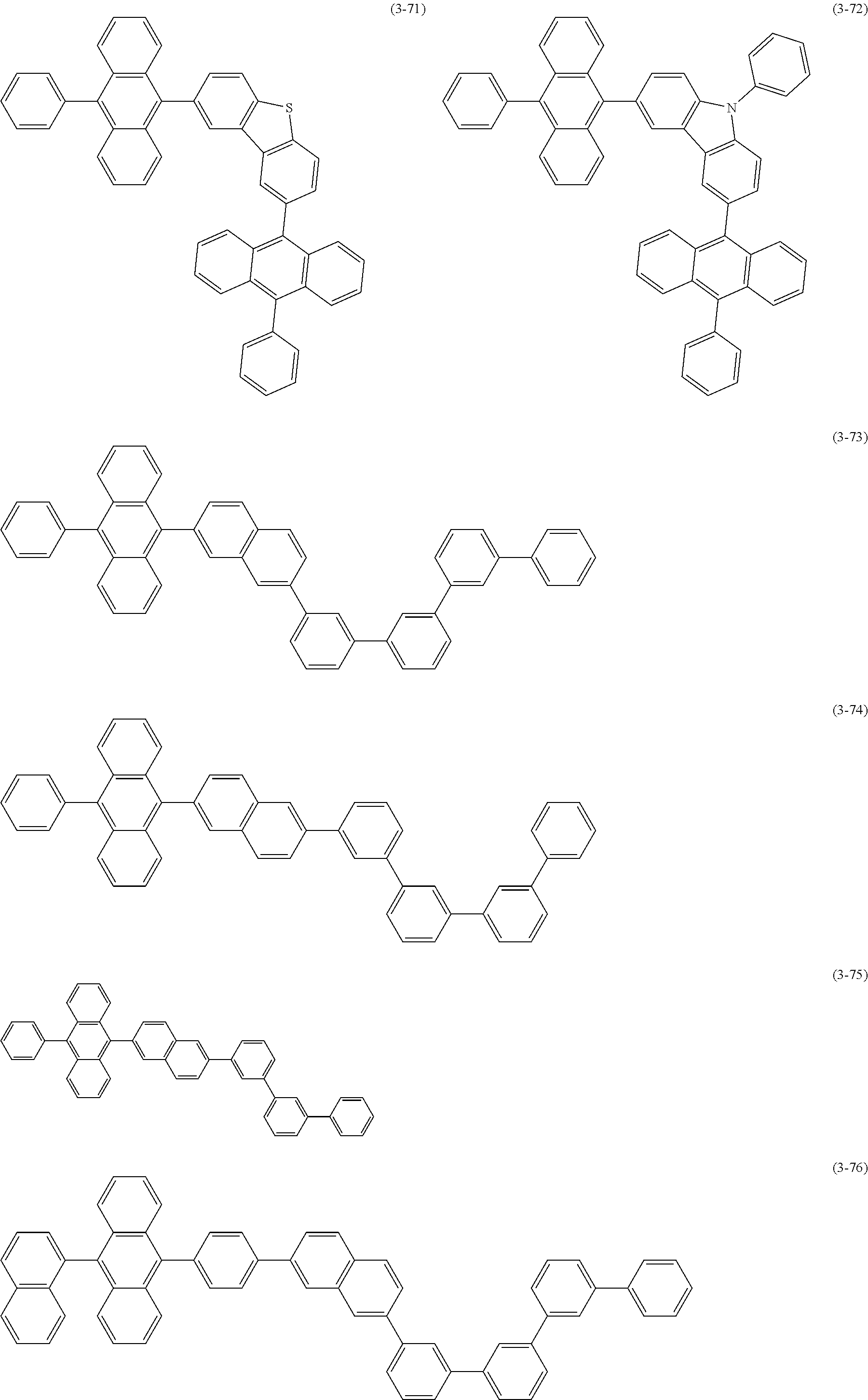

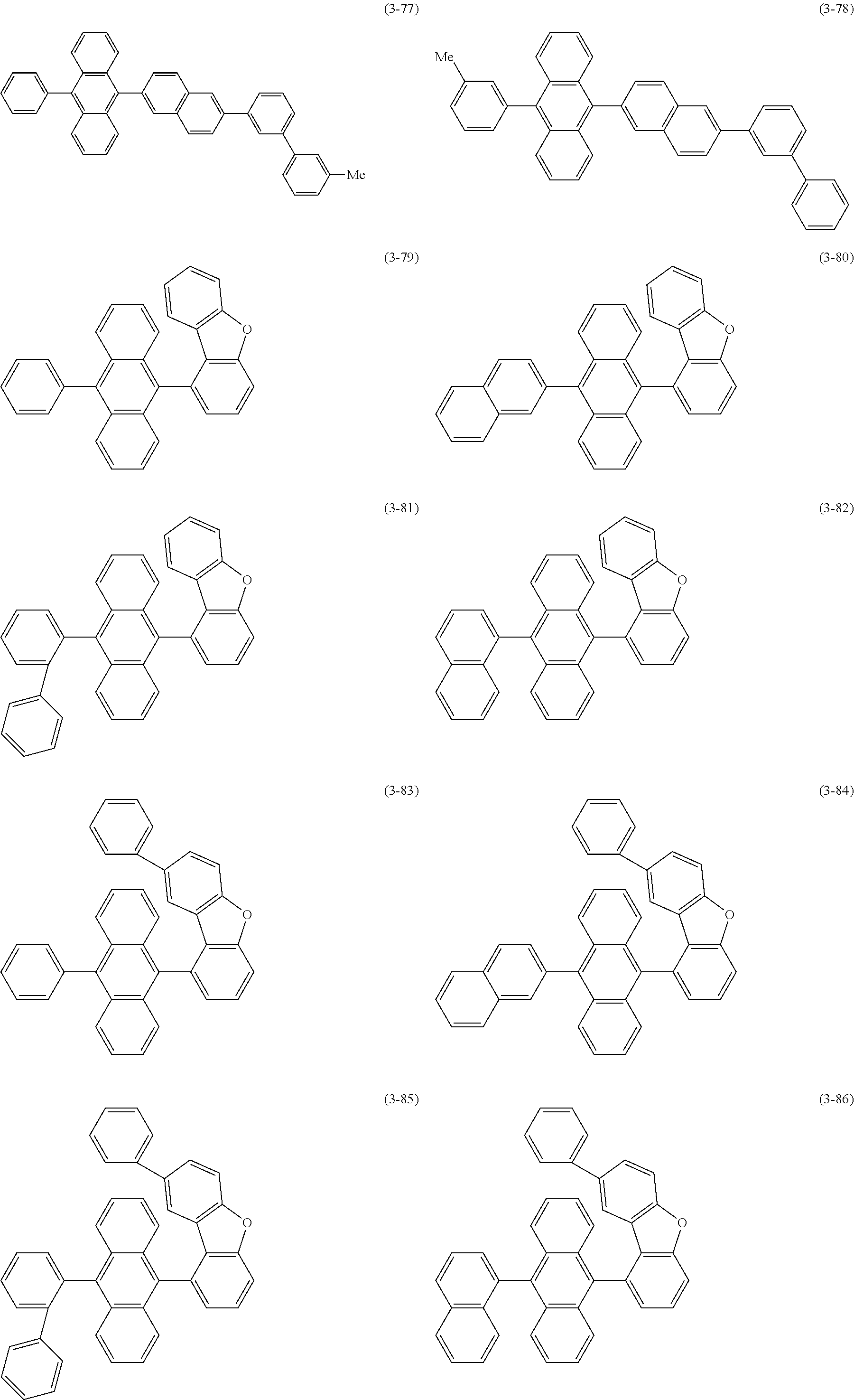

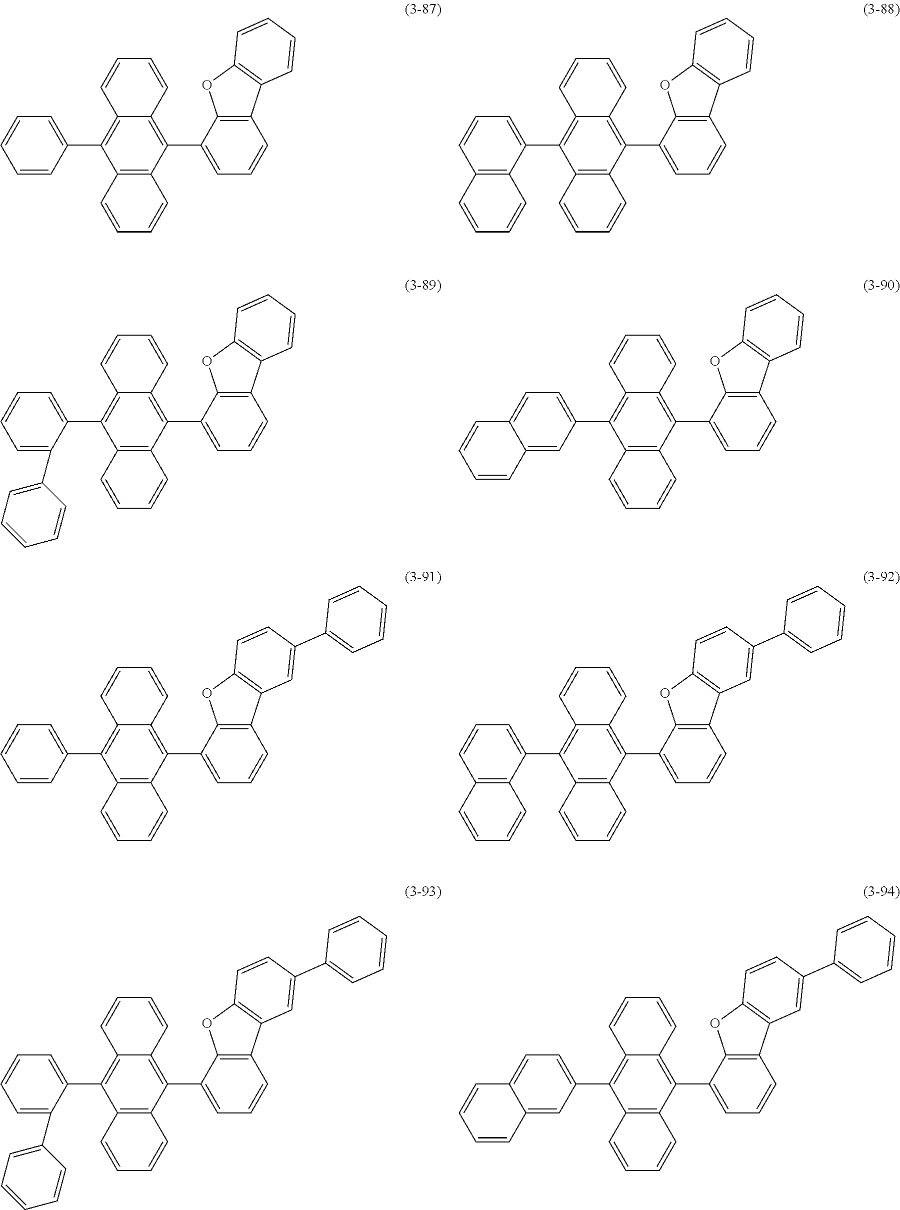

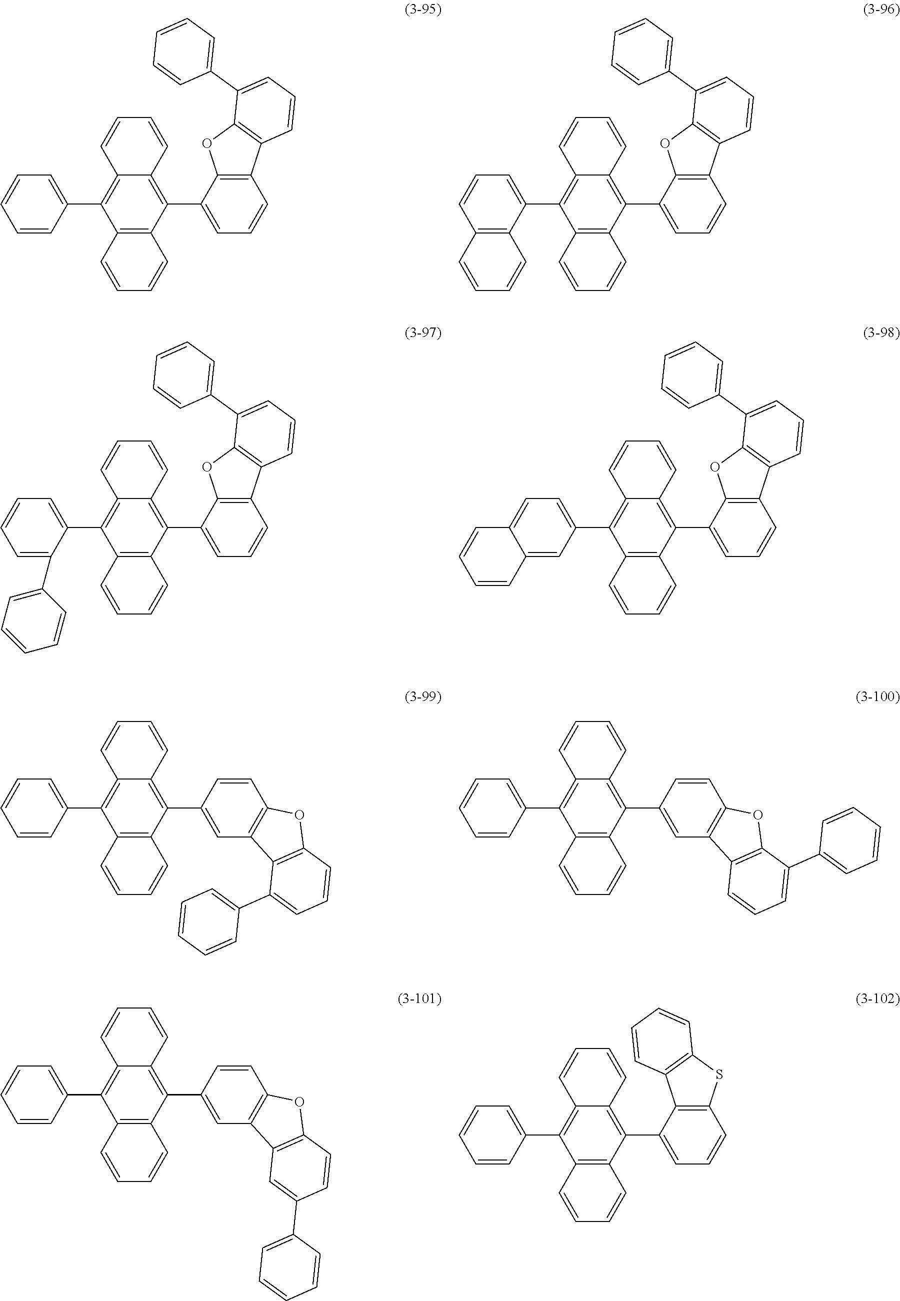

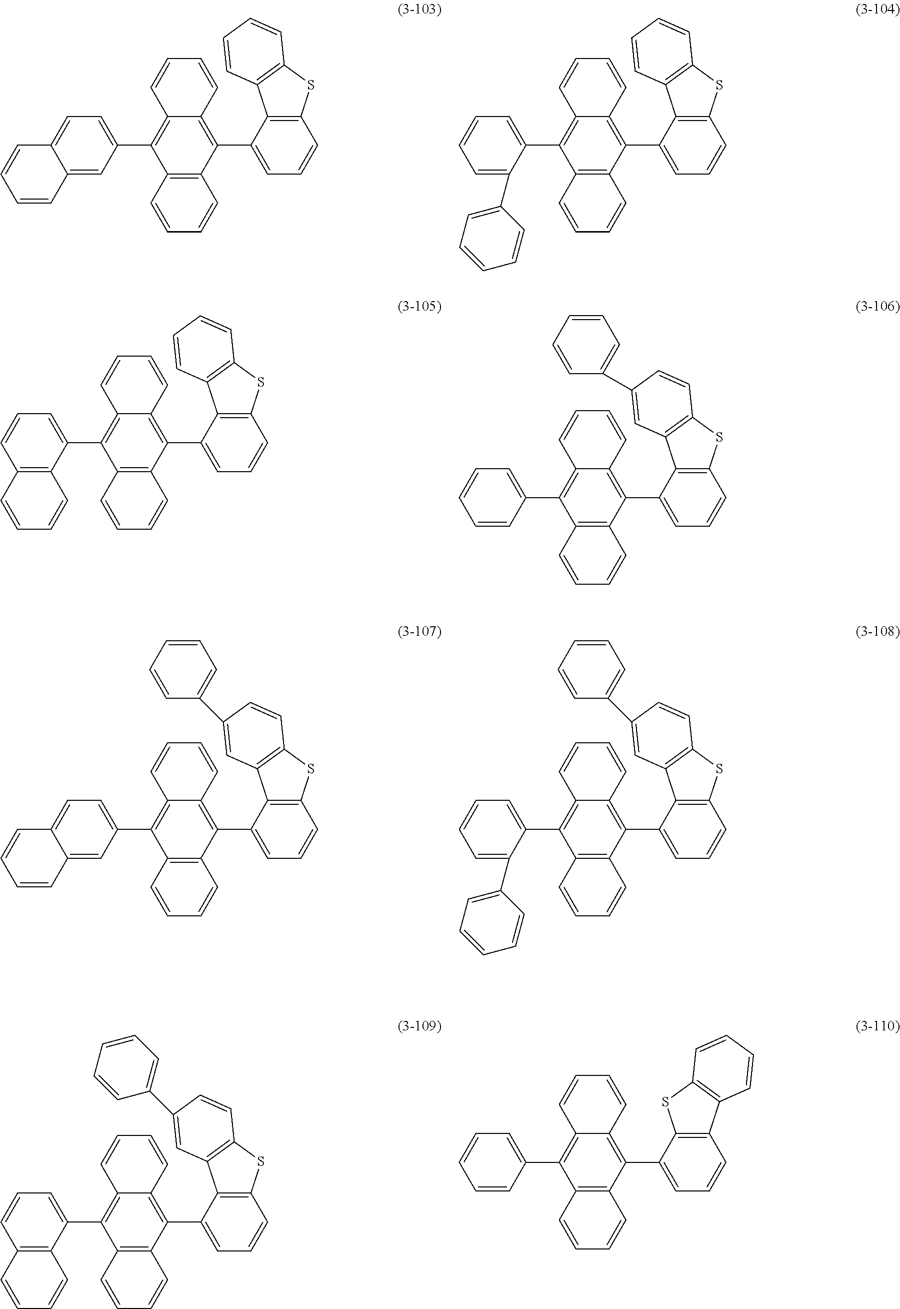

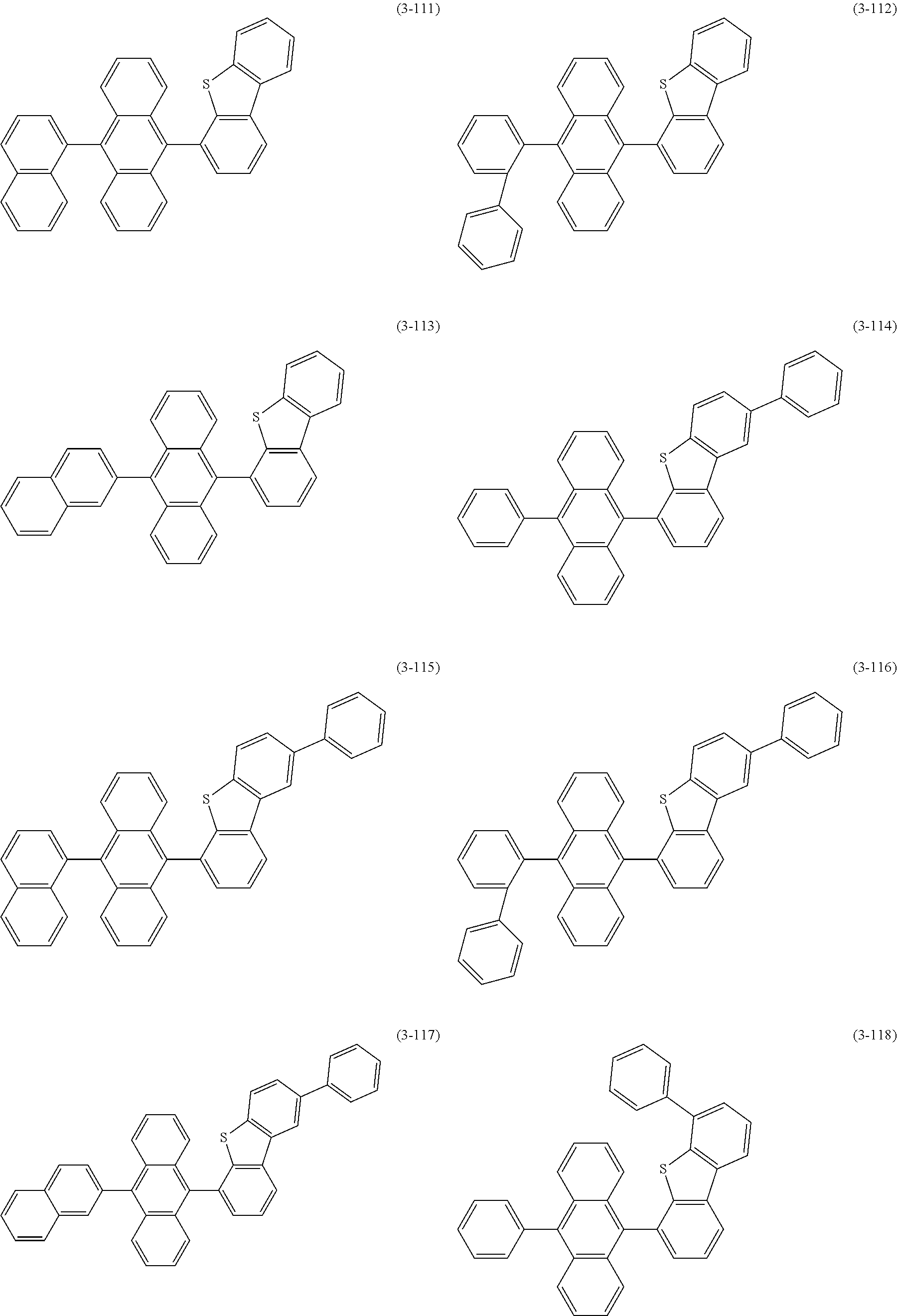

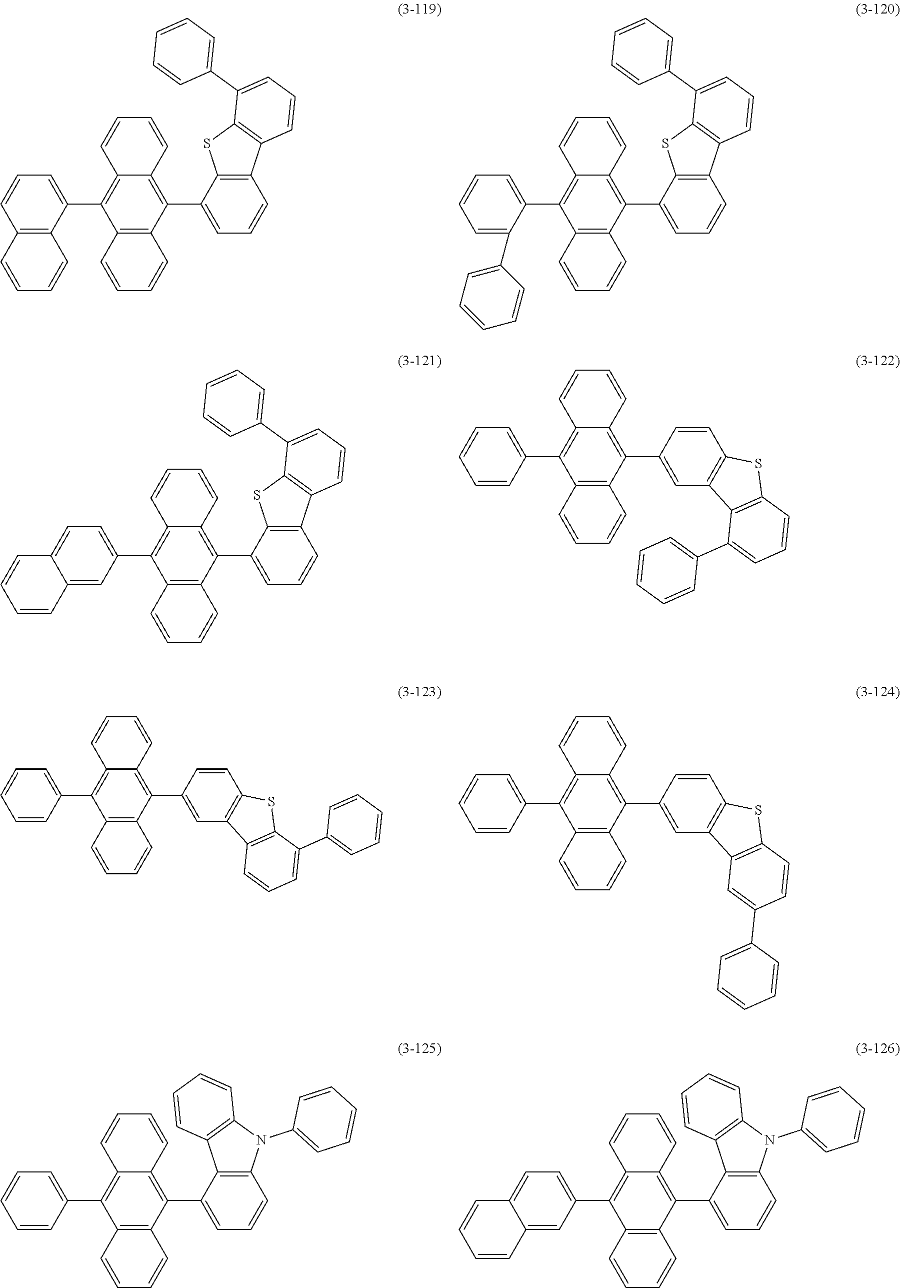

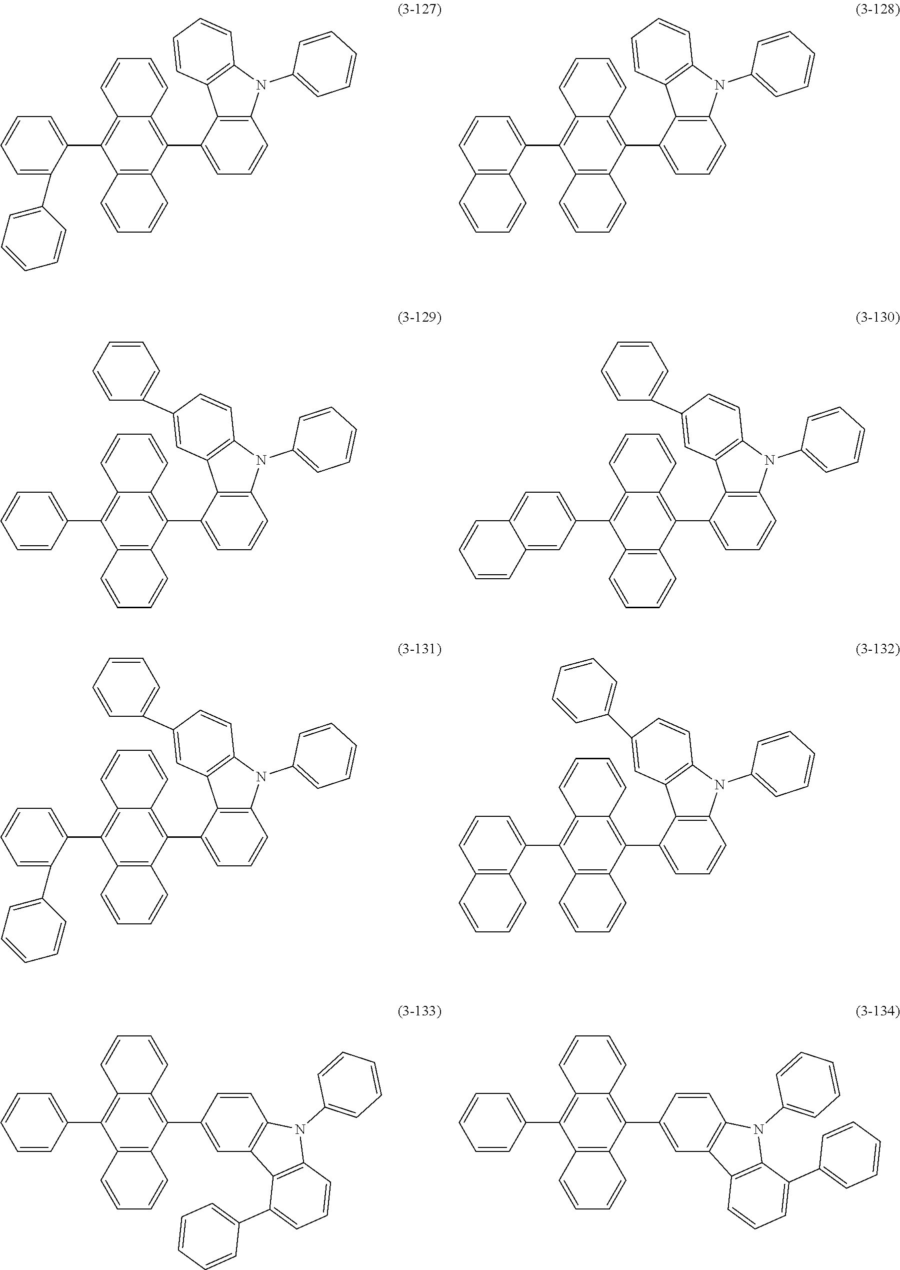

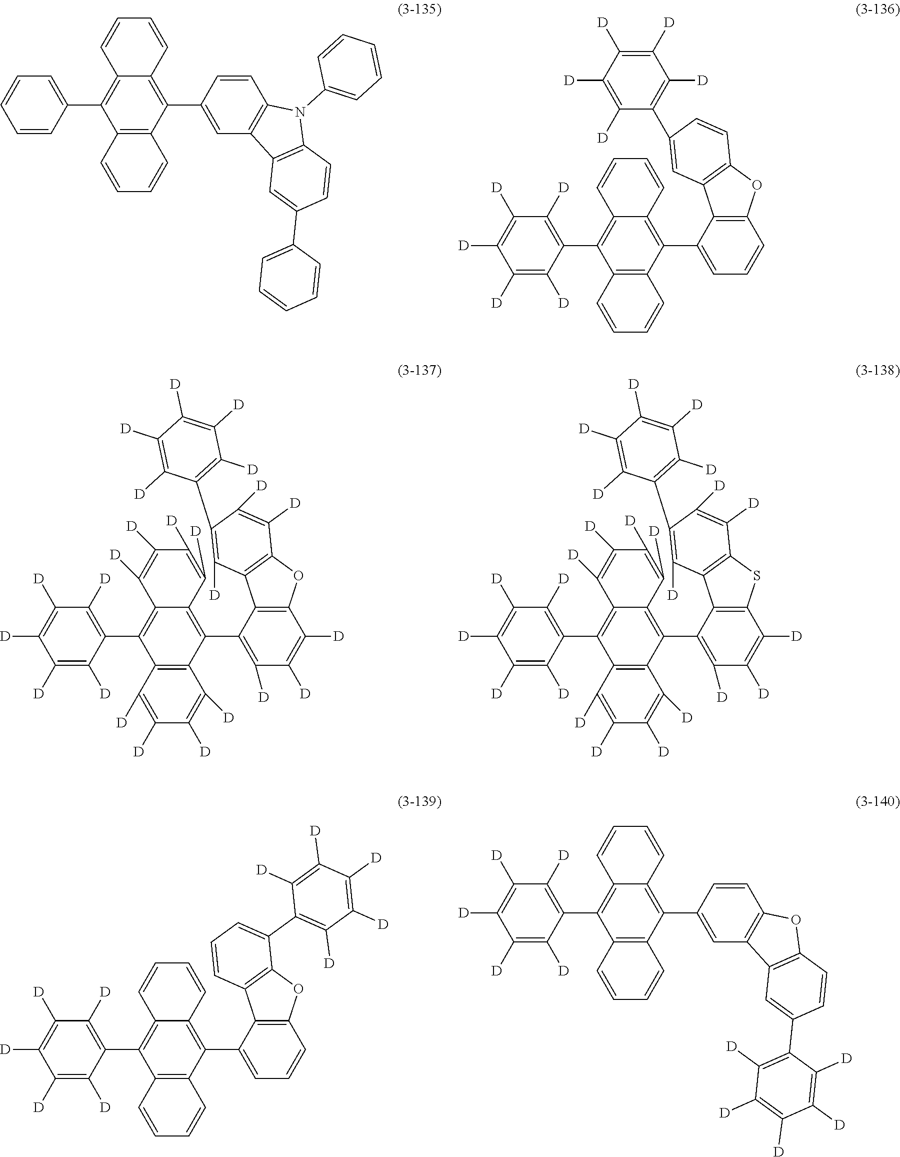

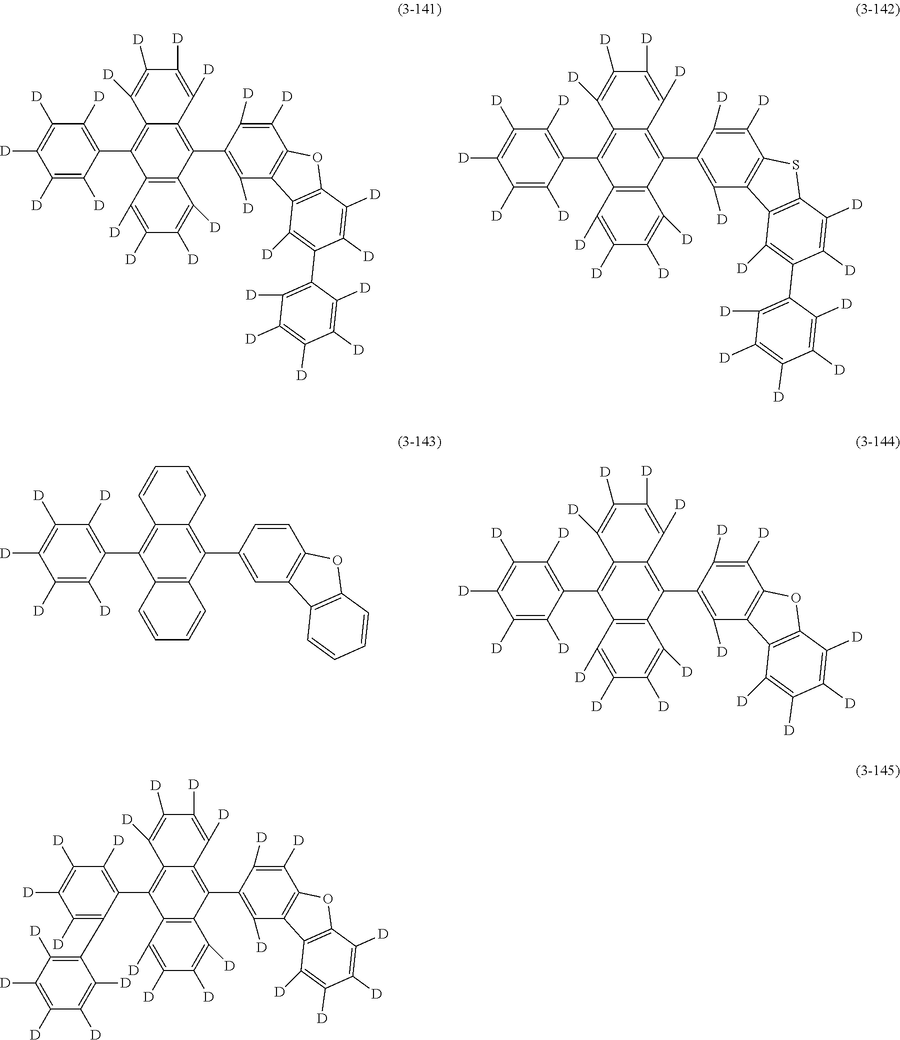

Other specific examples of anthracene-based compounds include, for example, compounds represented by a formula selected from the group consisting of Formulas (3-131-Y) to (3-182-Y), Formula (3-183-N), Formulas (3-184-Y) to (3-269-Y), Formulas (3-500) to (3-557) and Formulas (3-600) to (3-620) shown below. In Formulas (3-131-Y) to (3-182-Y), Formula (3-183-N). Formulas (3-184-Y) to (3-269-Y), Formulas (3-500) to (3-557) and Formulas (3-600) to (3-620), hydrogens may be partially or entirely replaced with deuterium. Y in the formula may be any of —O—, —S—, >N—R²⁹(R²⁹ as defined above), or >C(—R³⁰)₂ (R³⁰ may be an optionally bonded aryl or an alkyl), and R²⁹ is phenyl, for example, R³⁰ is methyl, for example. For example, when Y is O, Formula (3-131-Y) is Formula (3-131-O), and when Y is —S— or >N—R²⁹. Formula (3-131-Y) is Formula (3-131-S) or Formula (3-131-N), respectively.

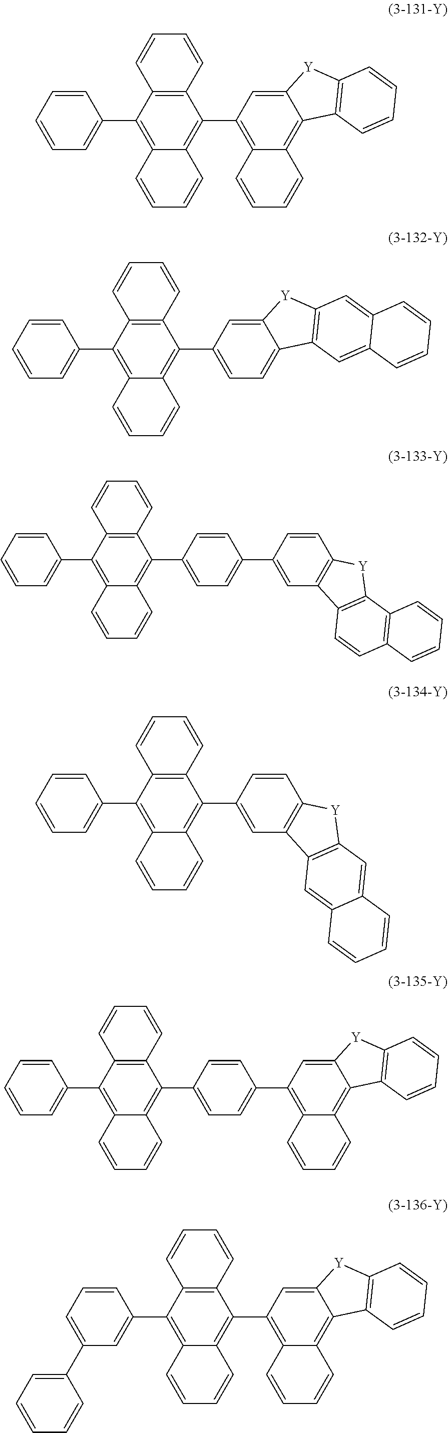

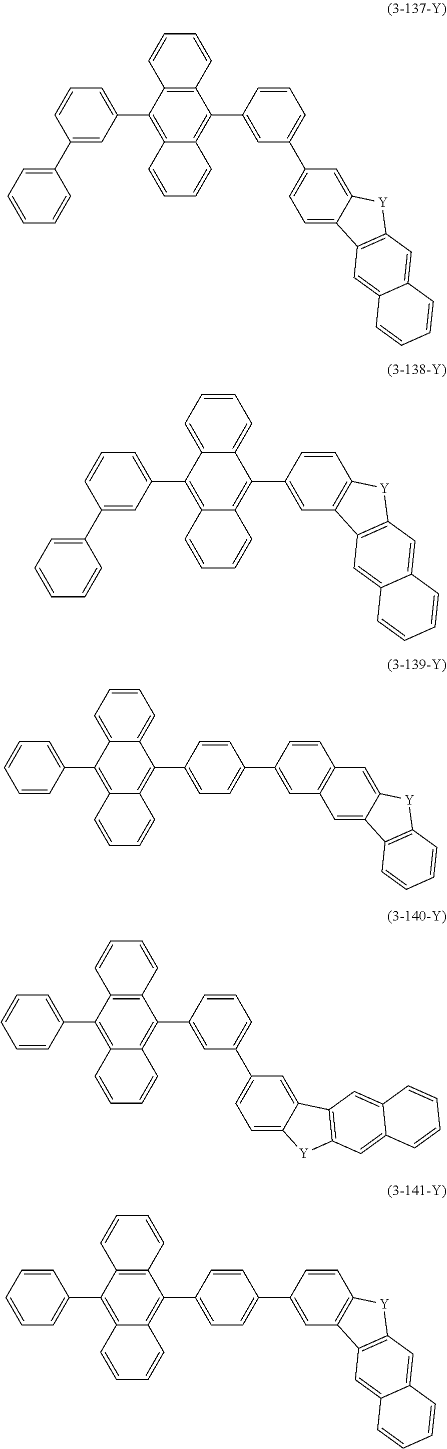

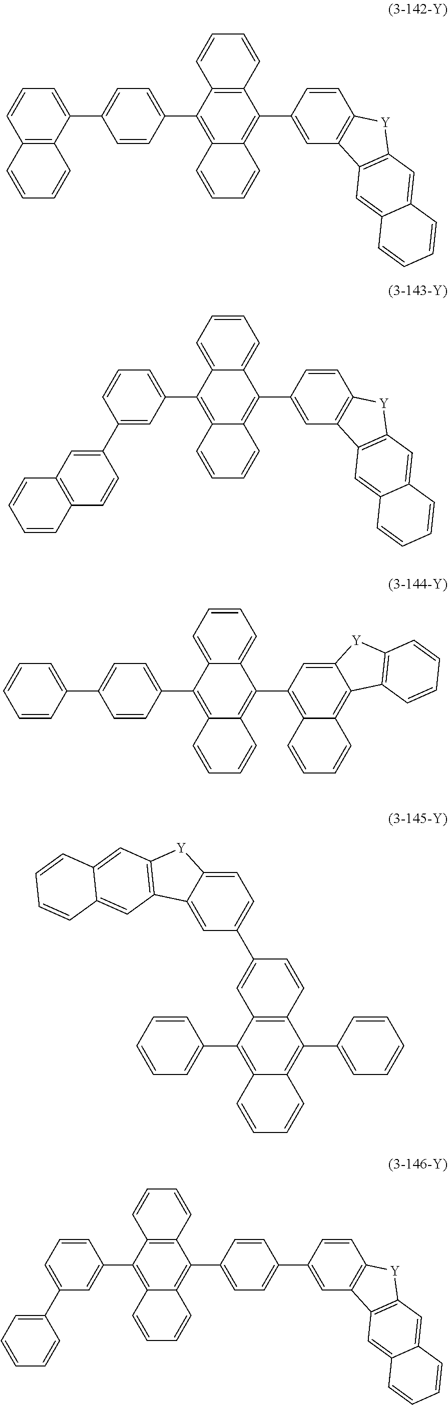

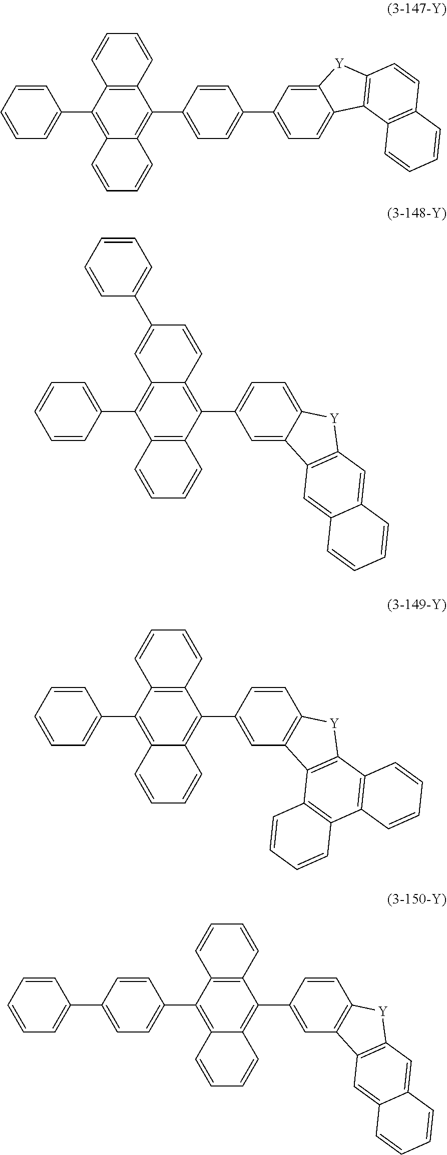

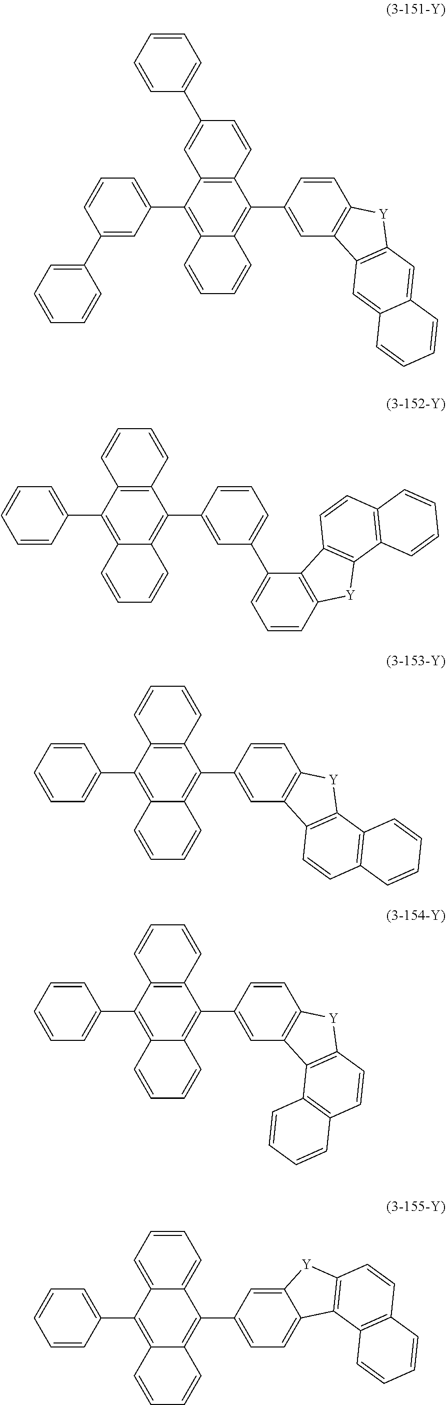

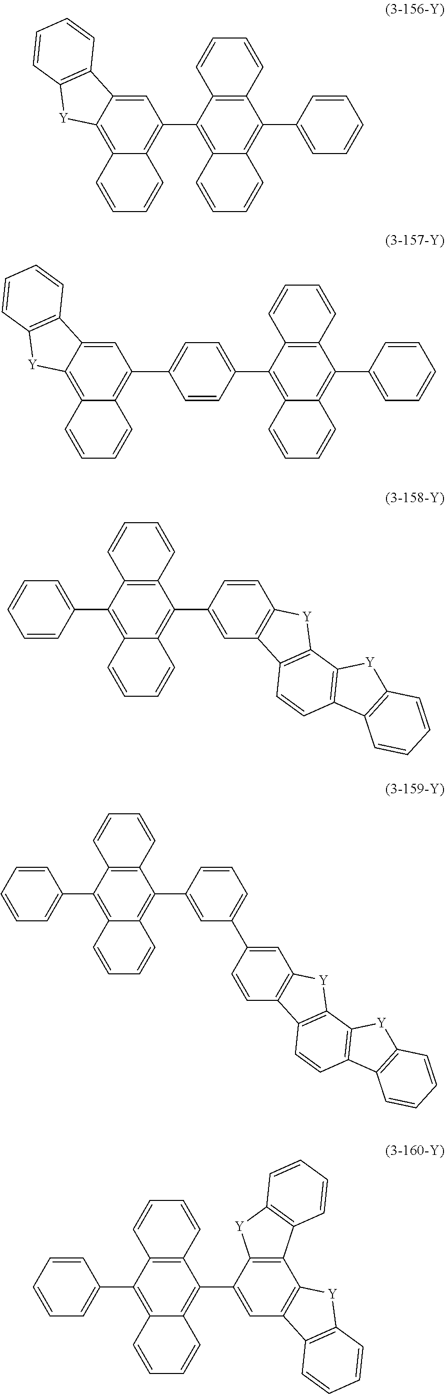

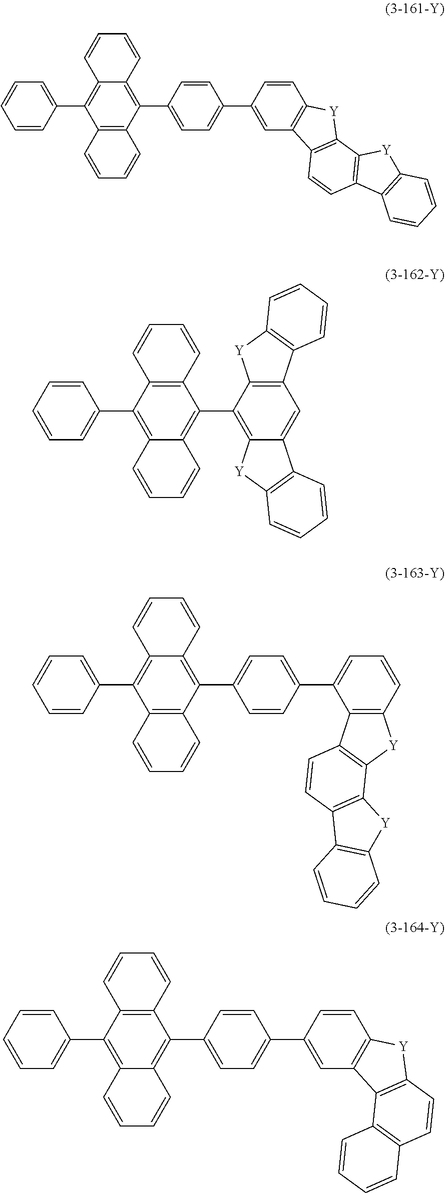

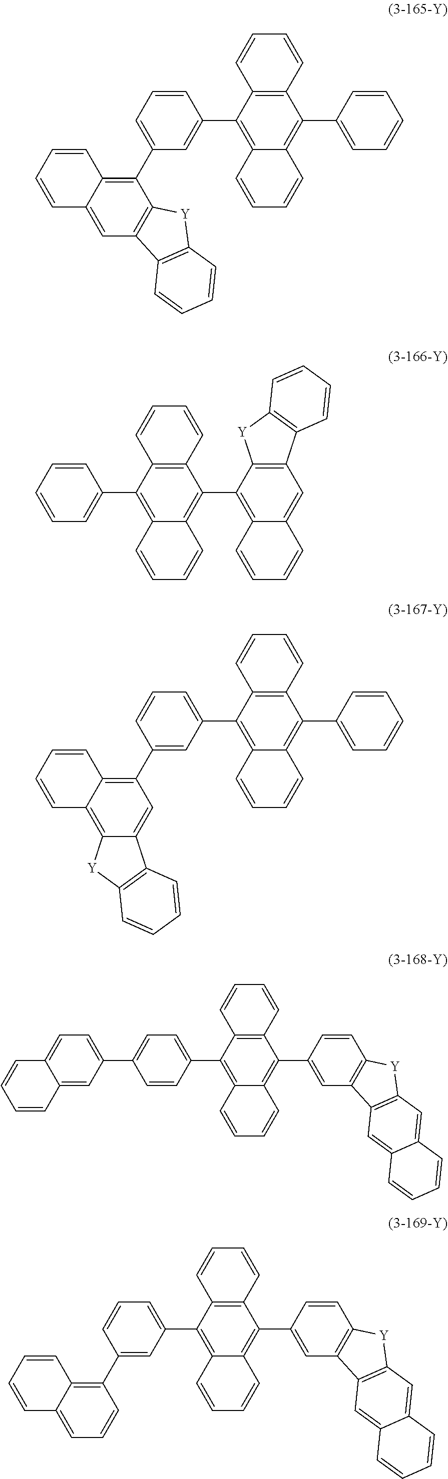

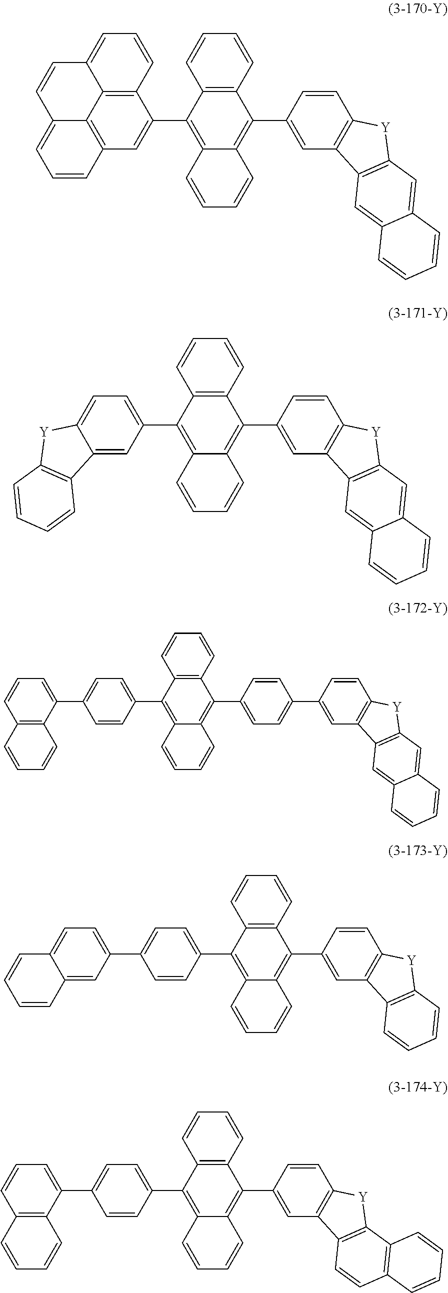

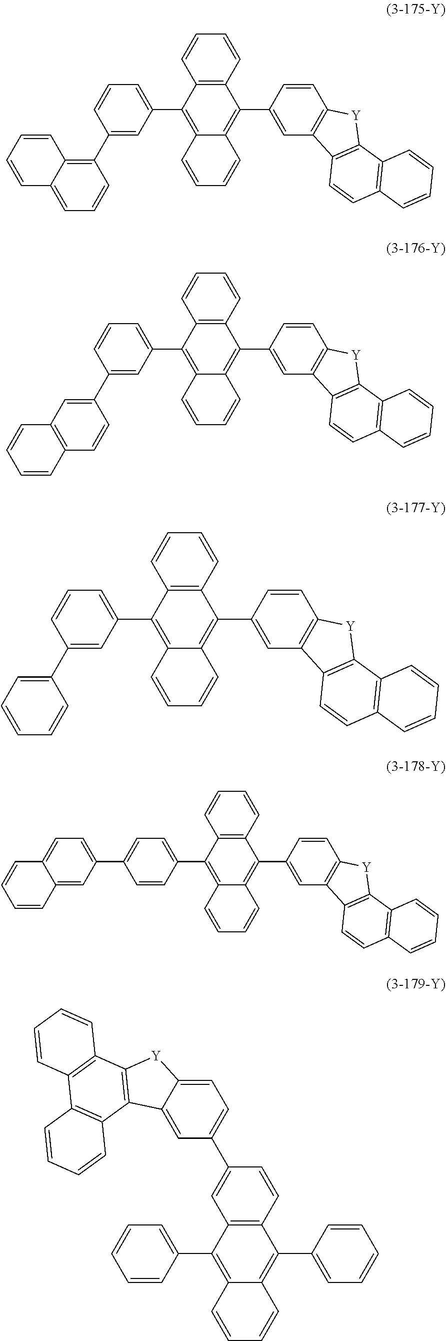

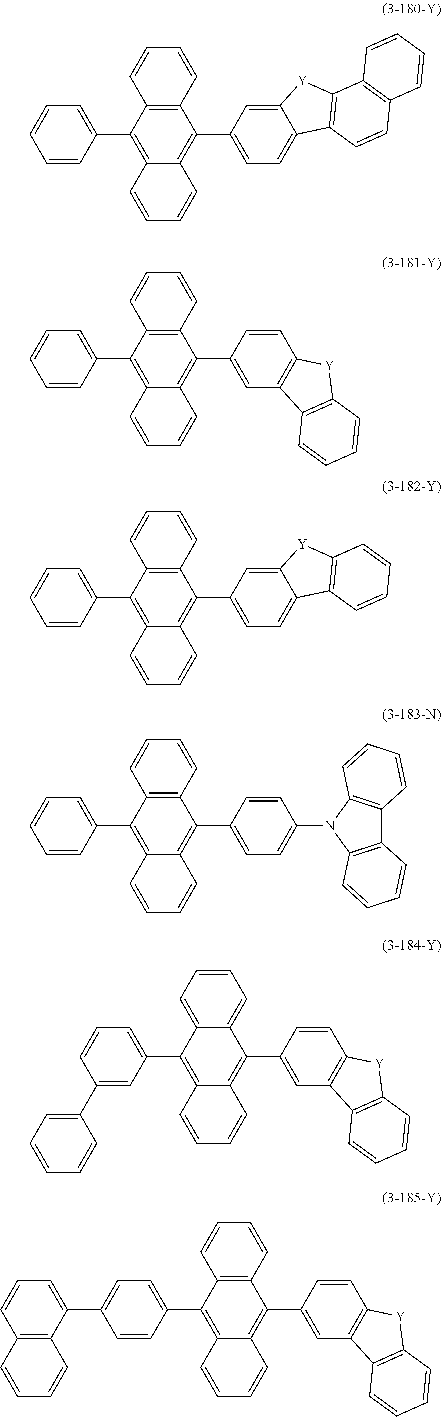

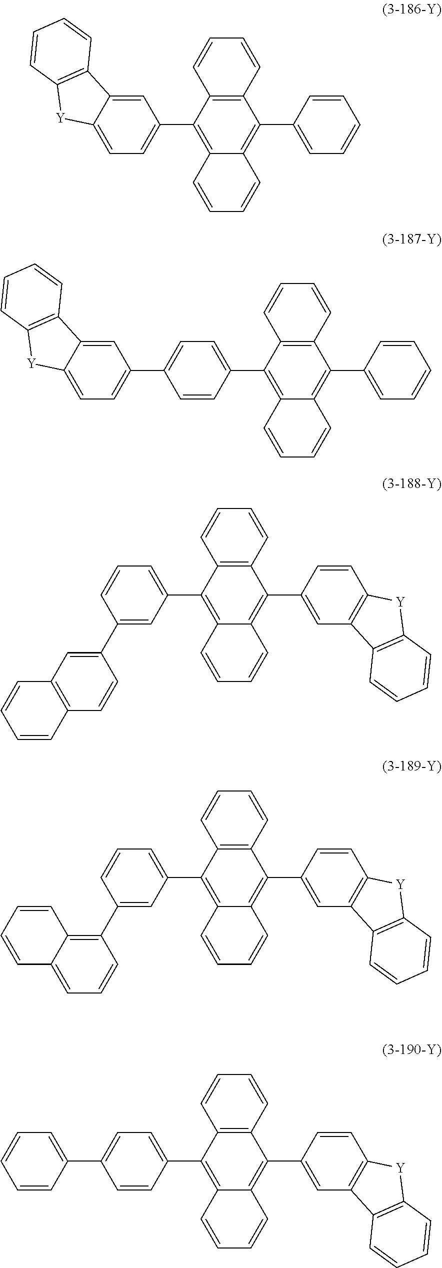

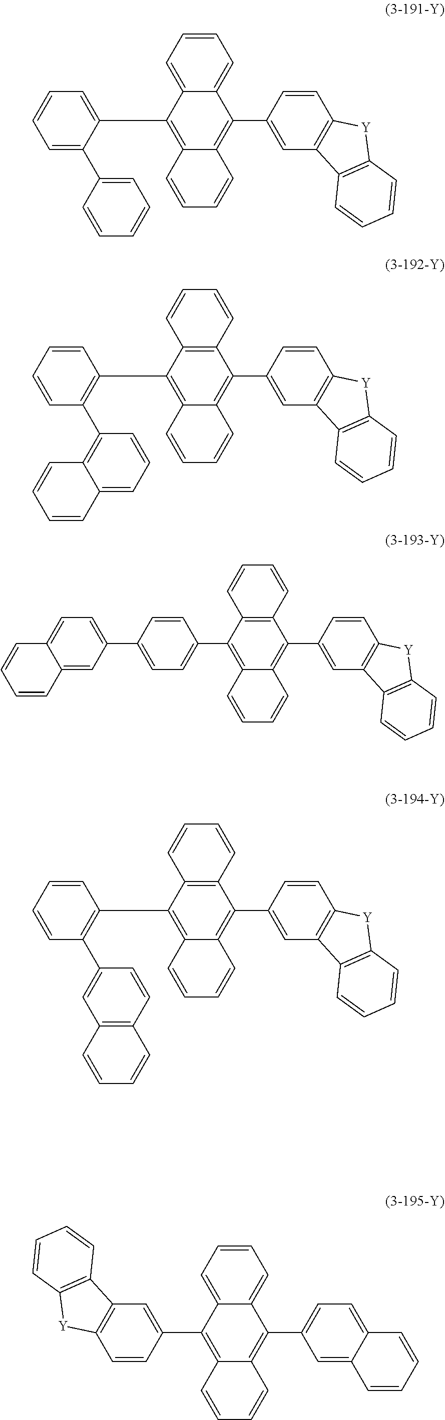

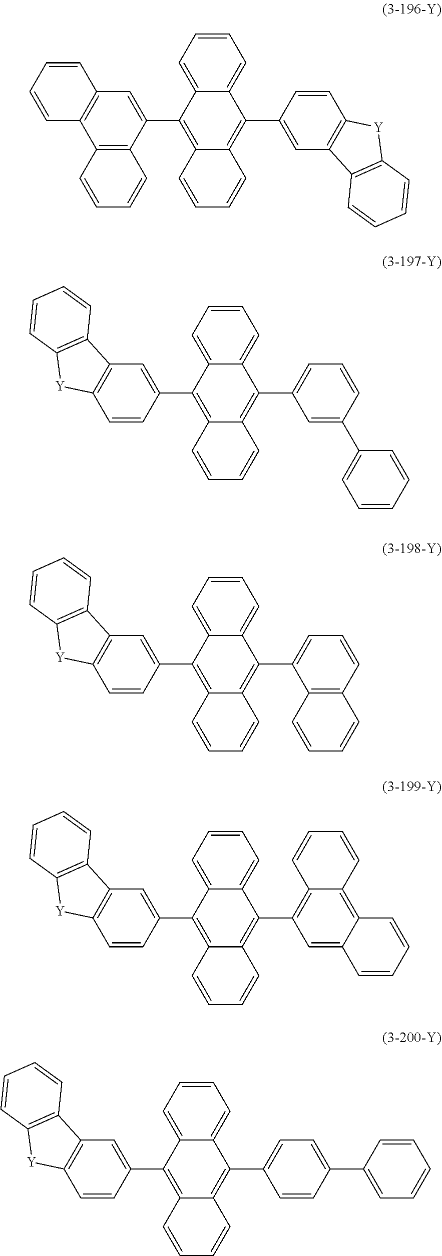

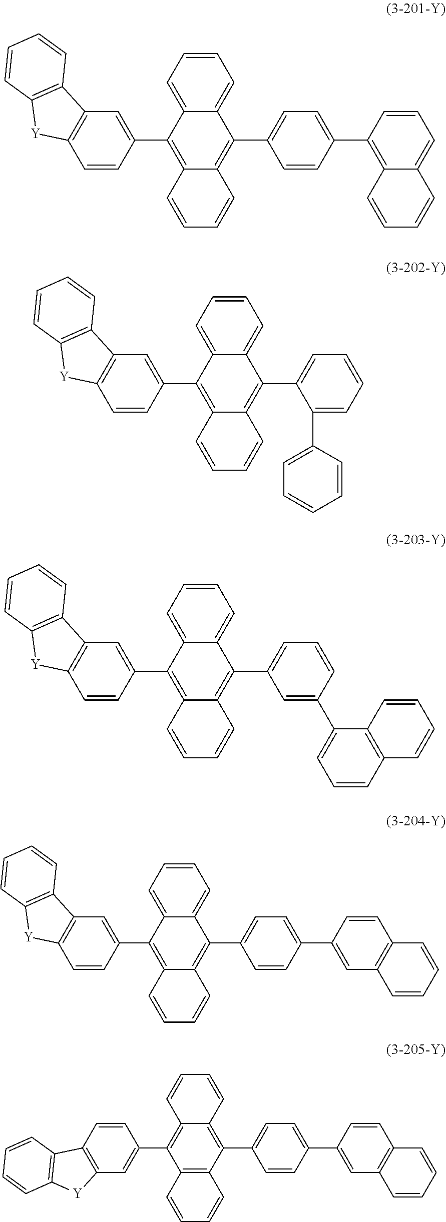

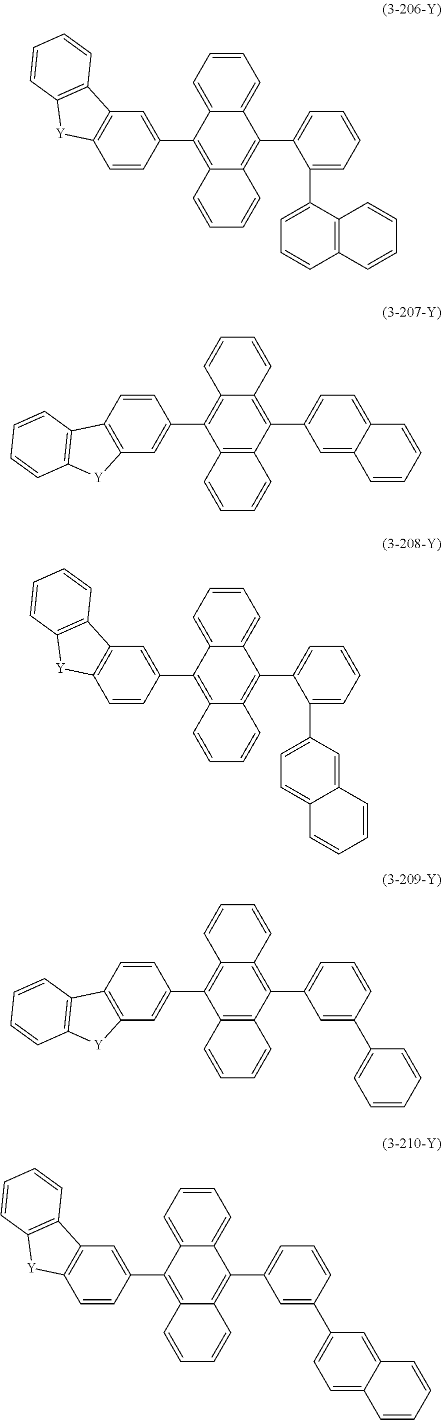

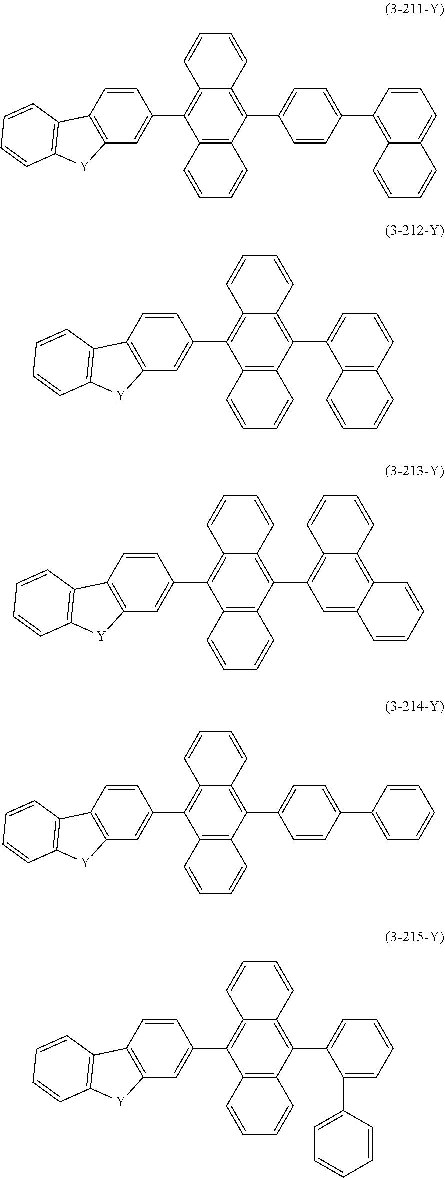

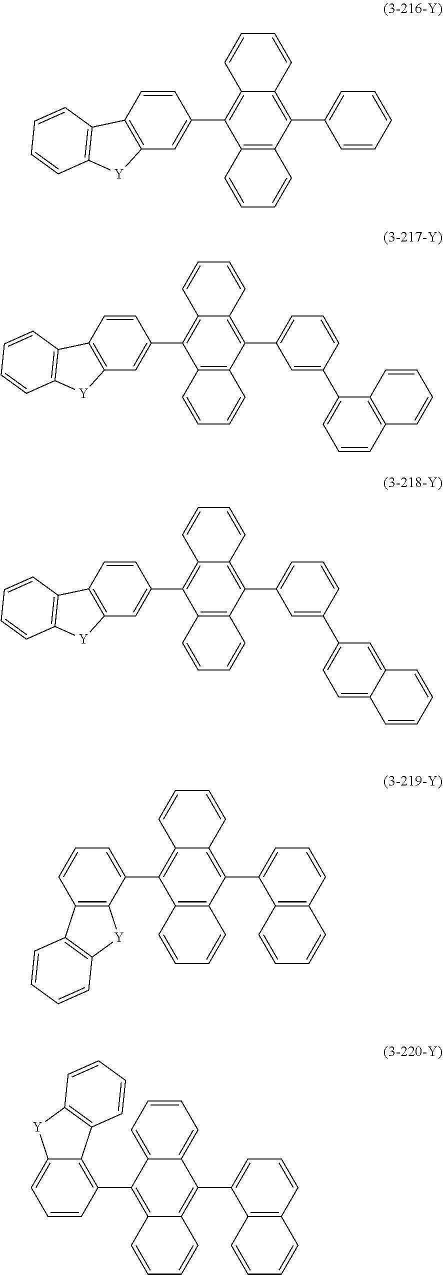

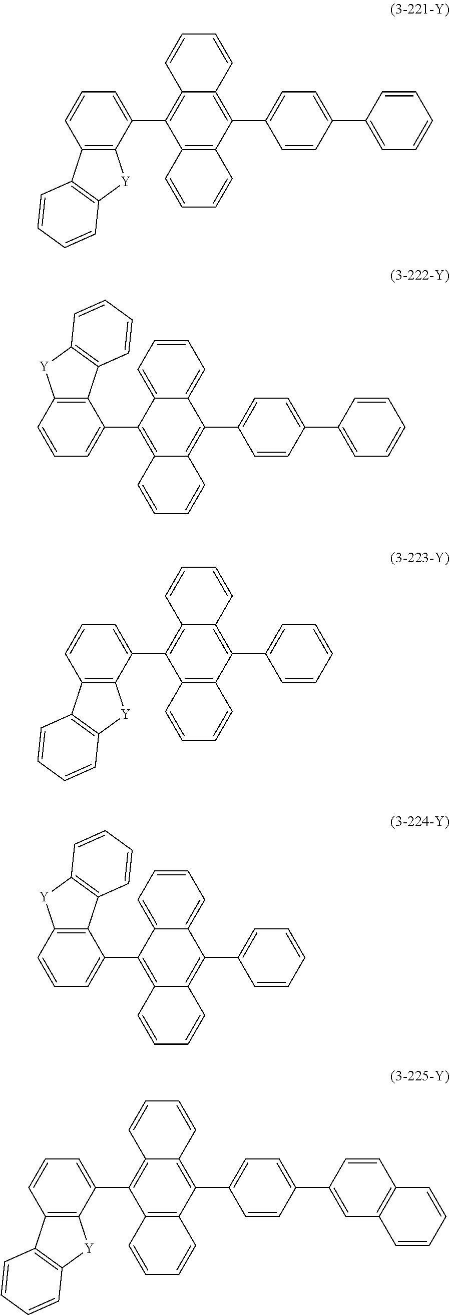

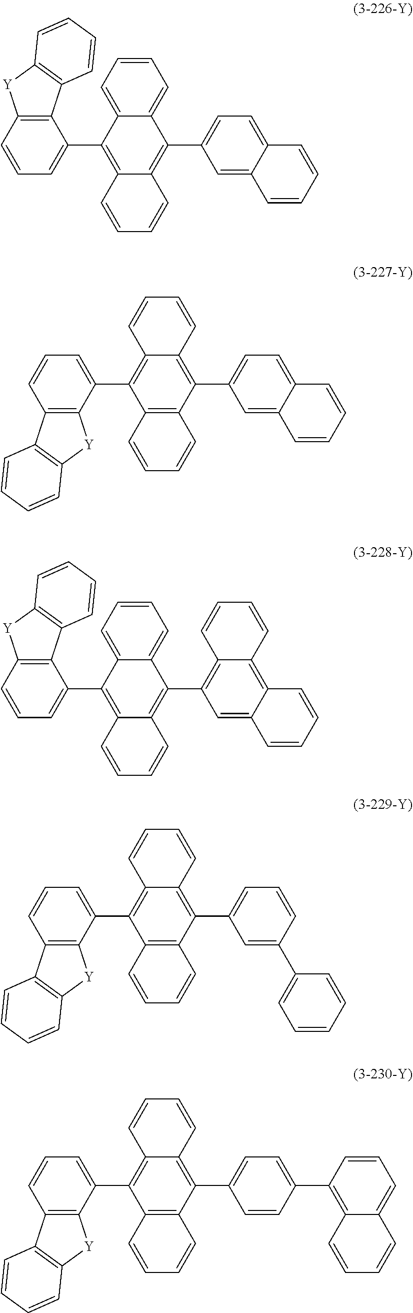

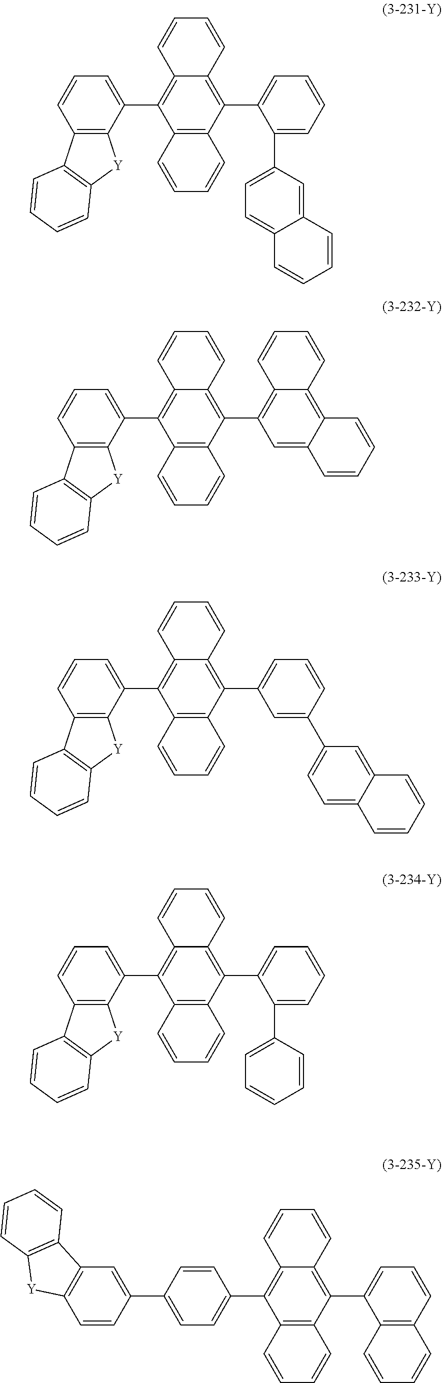

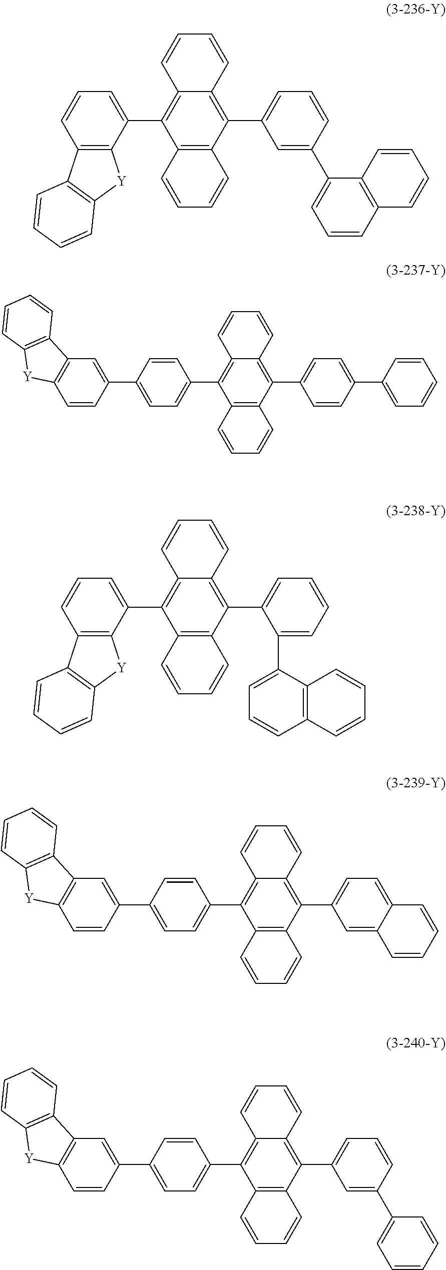

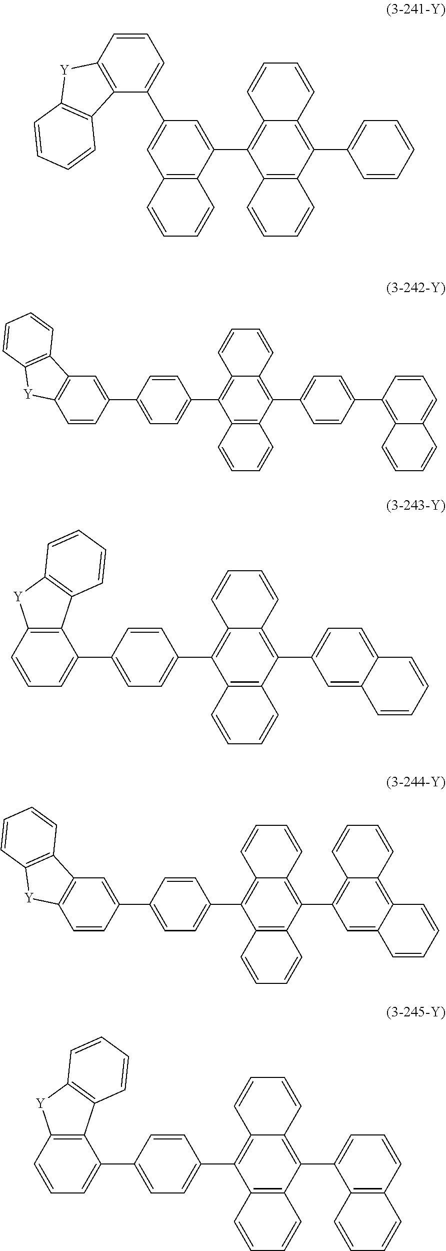

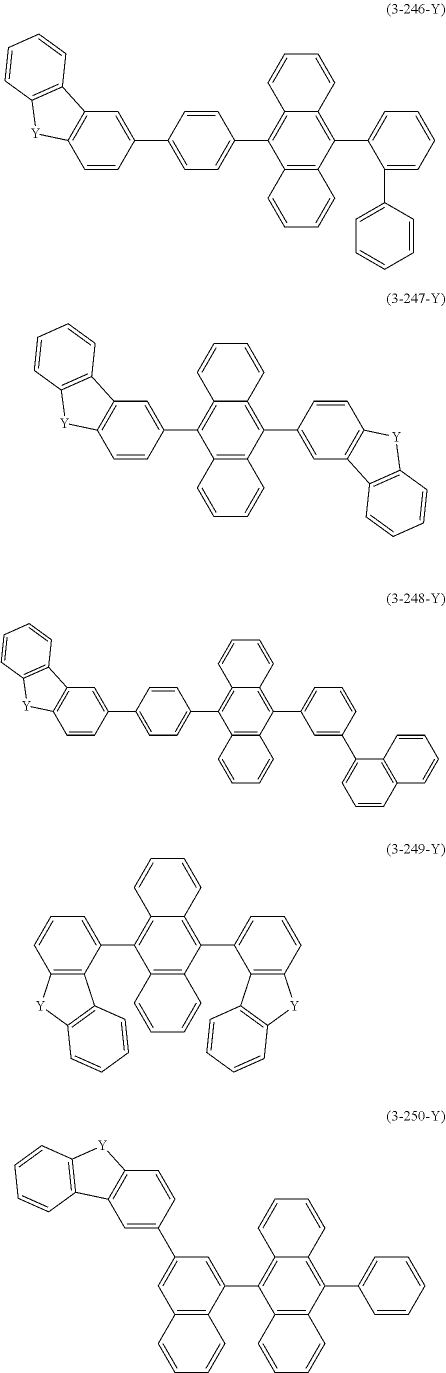

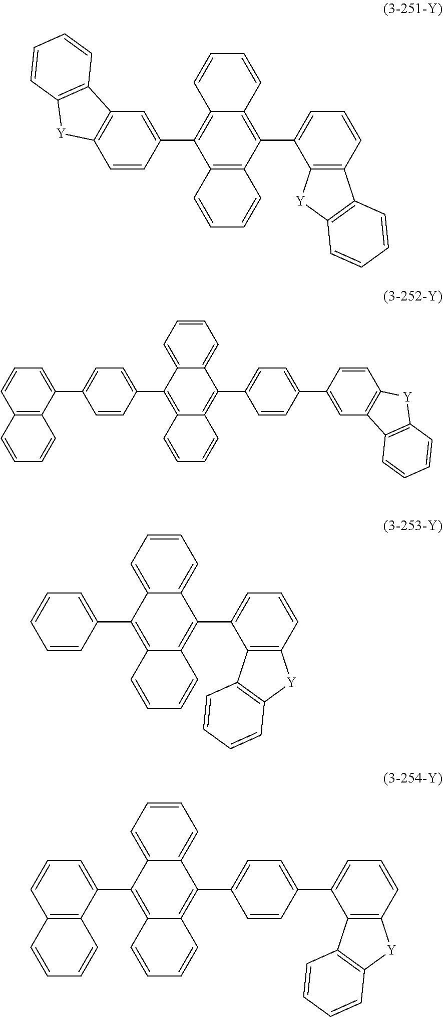

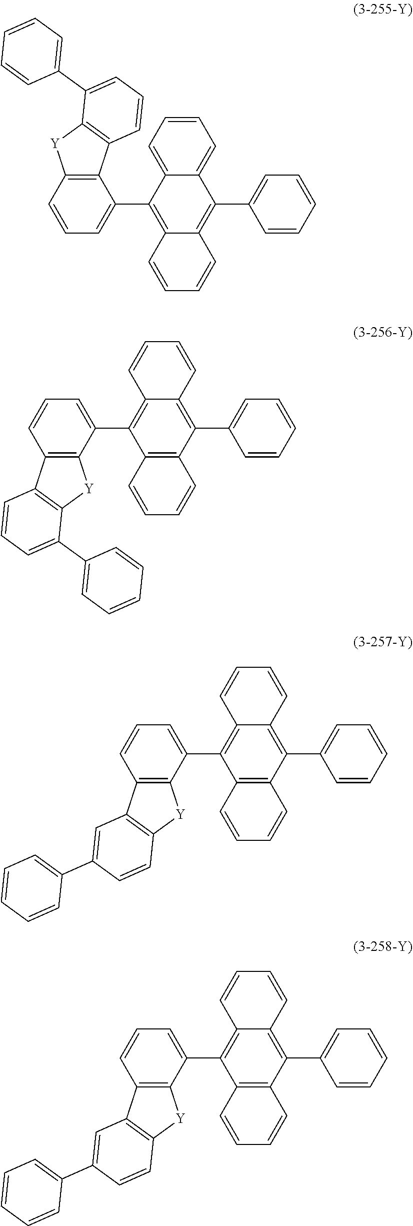

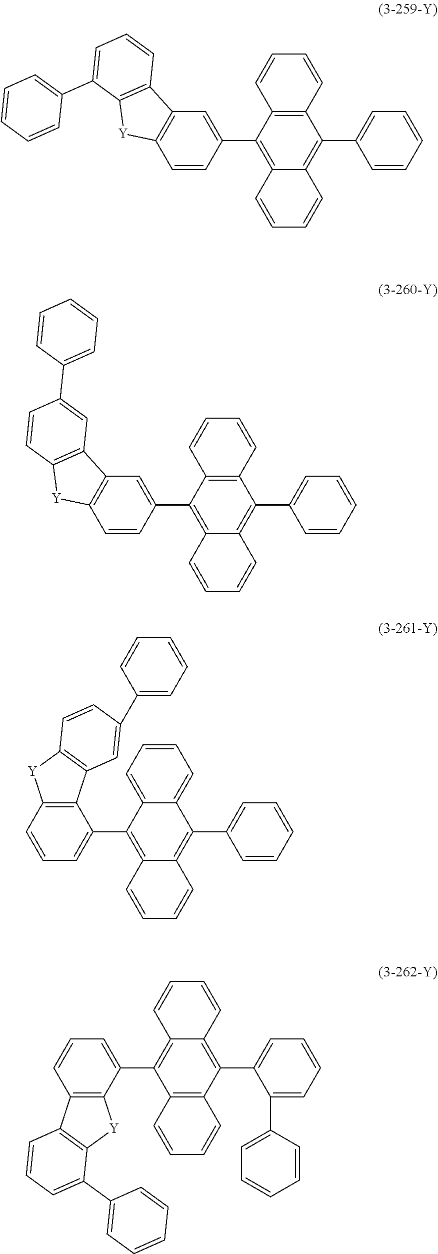

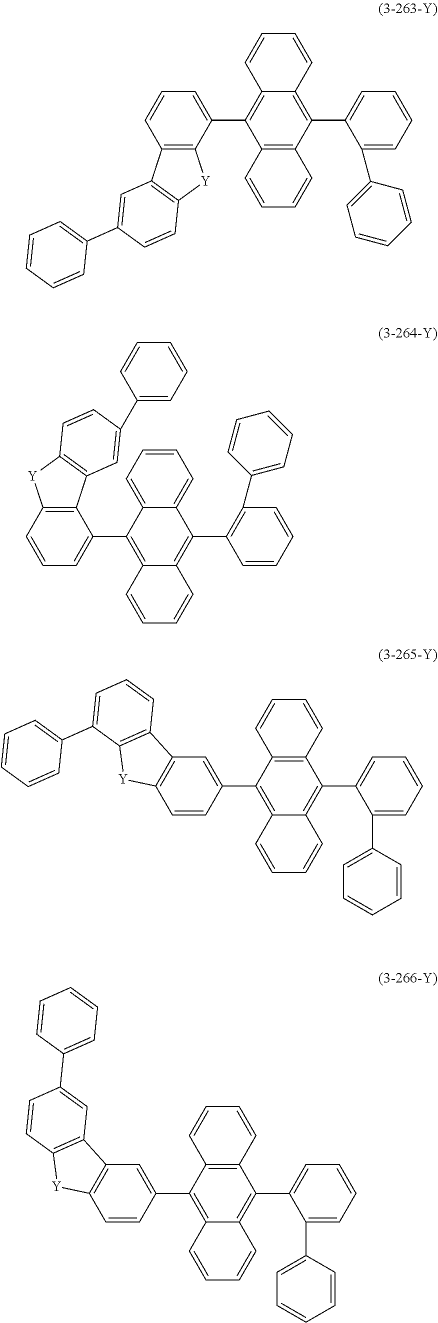

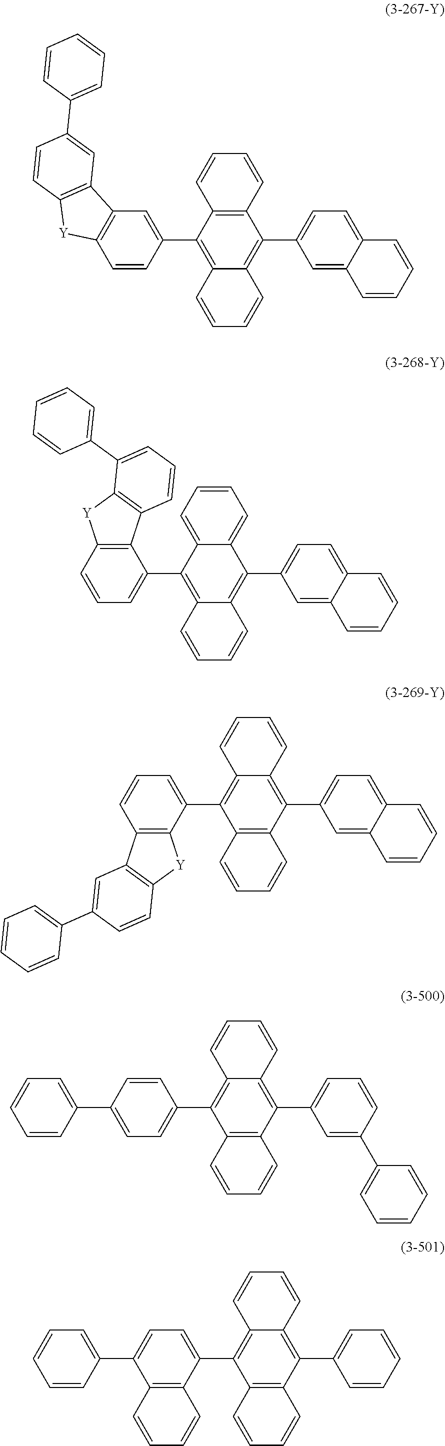

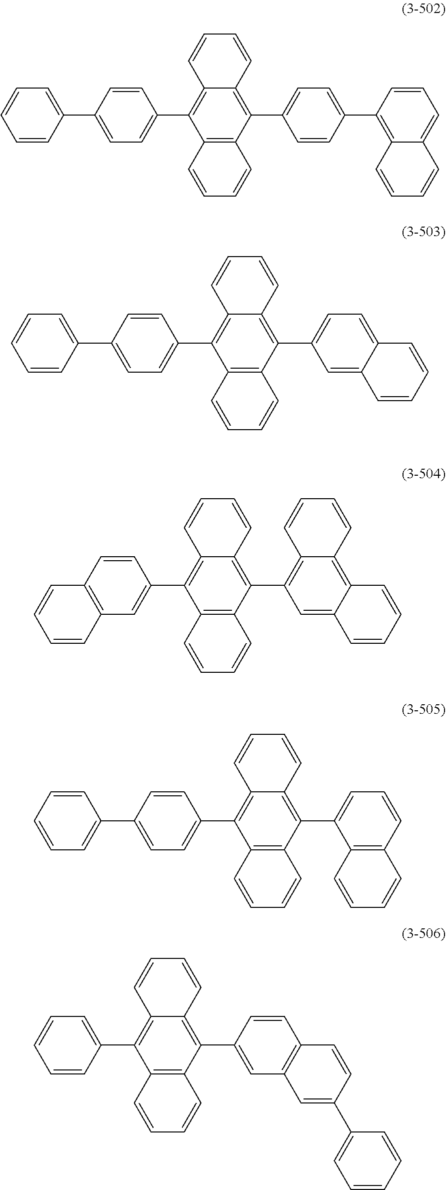

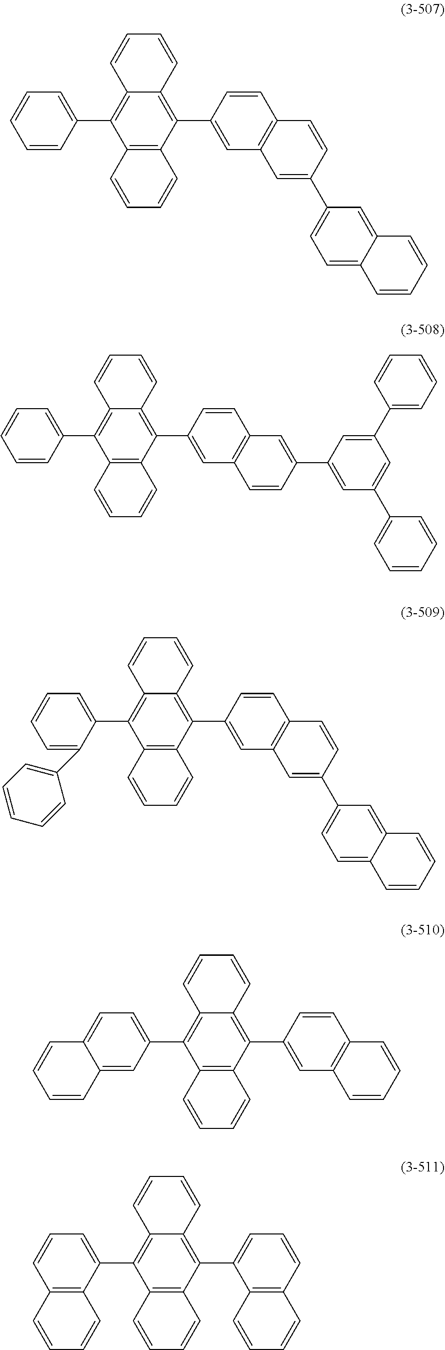

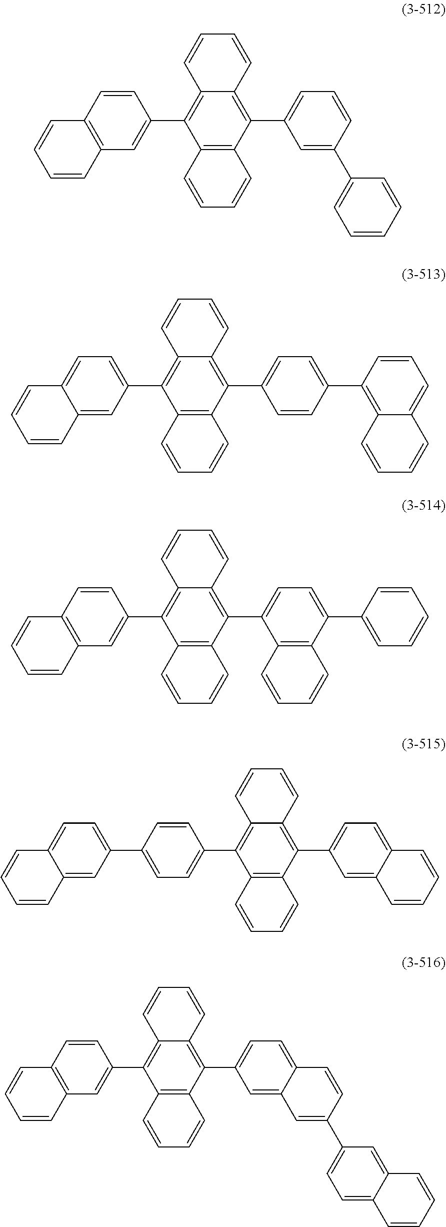

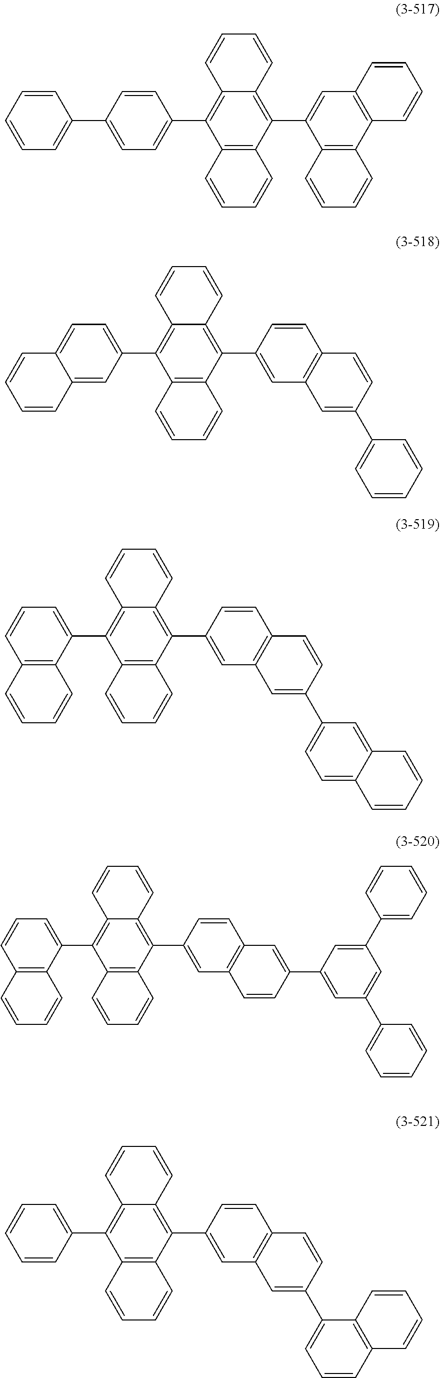

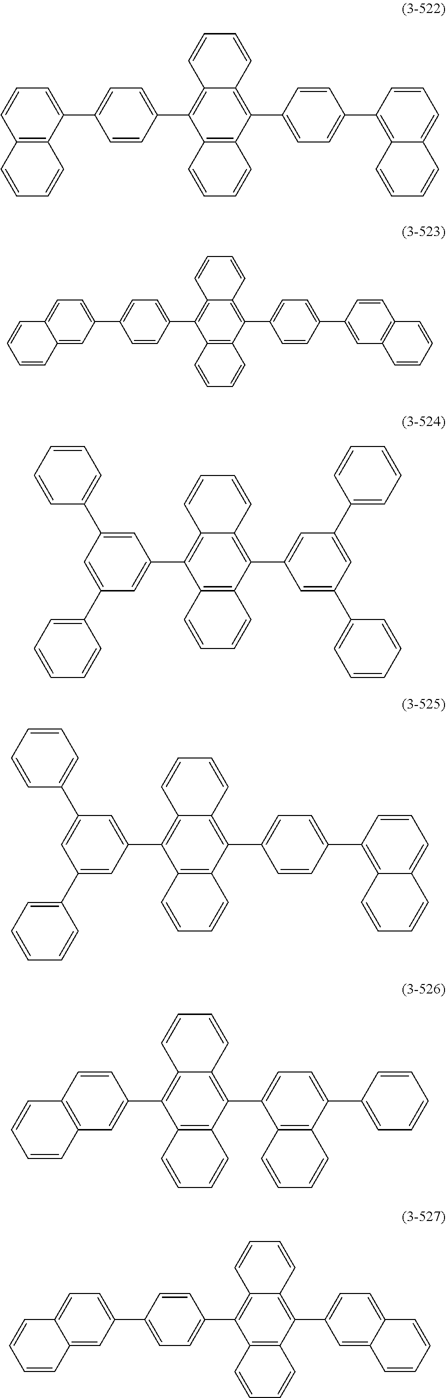

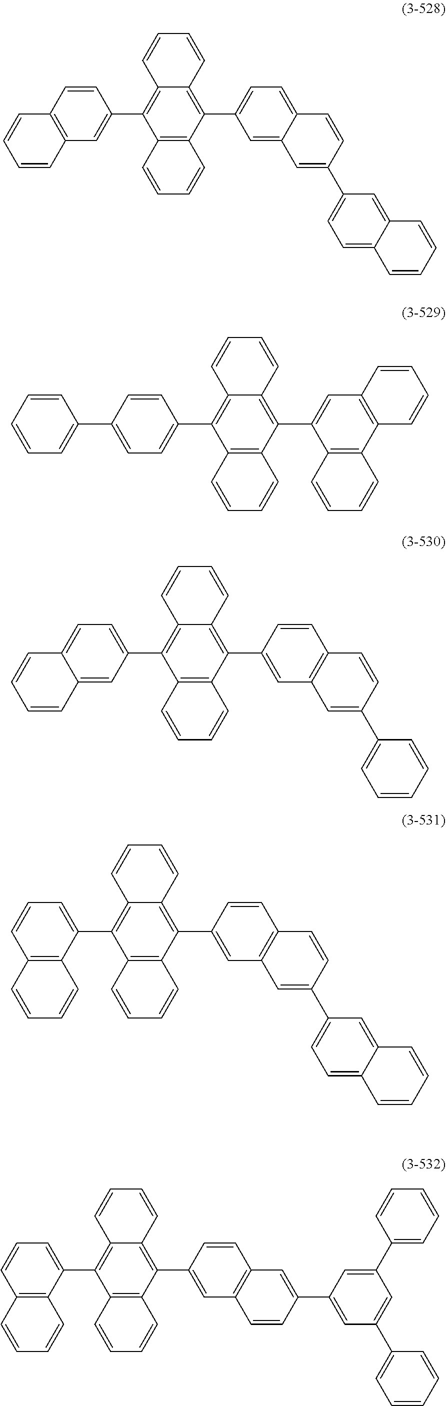

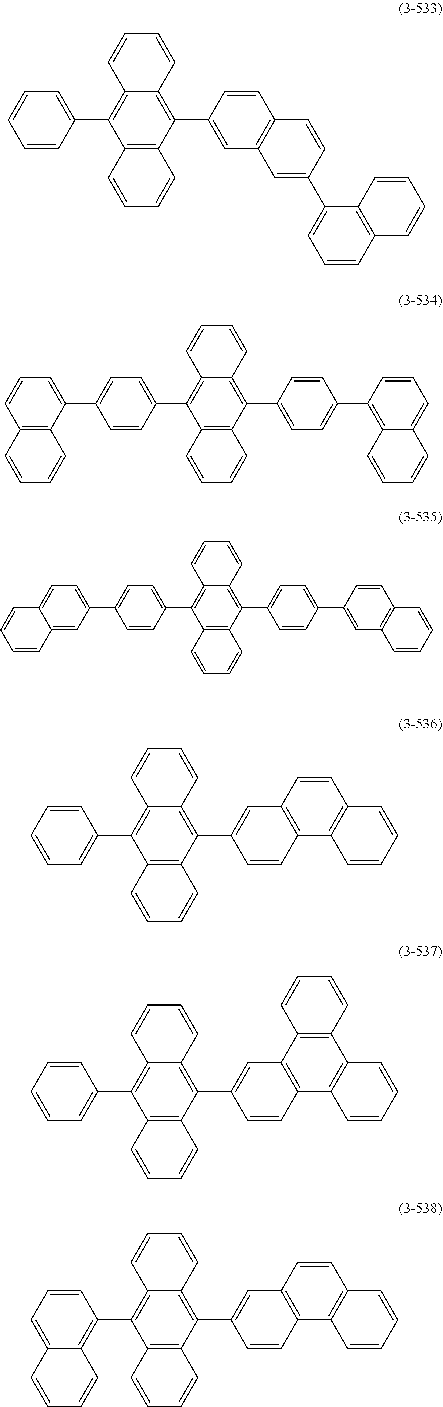

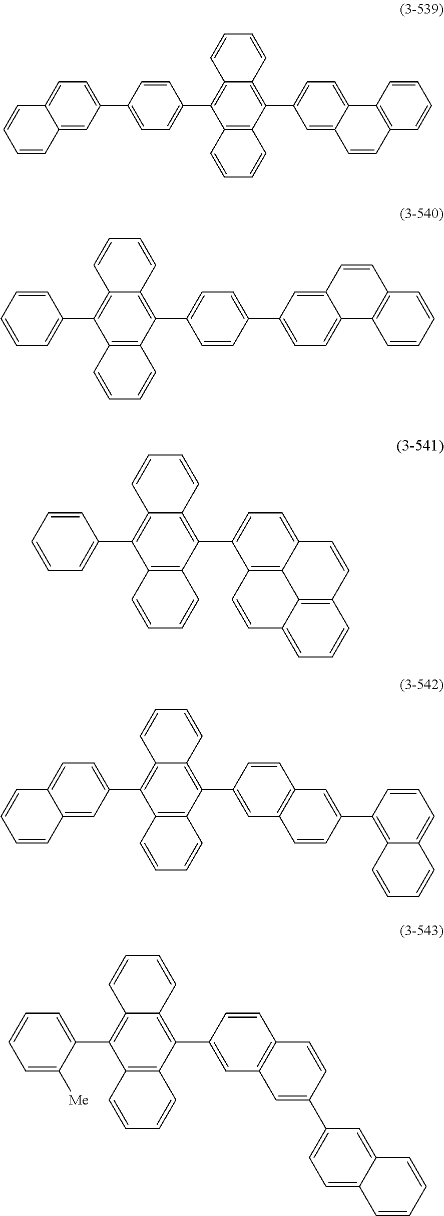

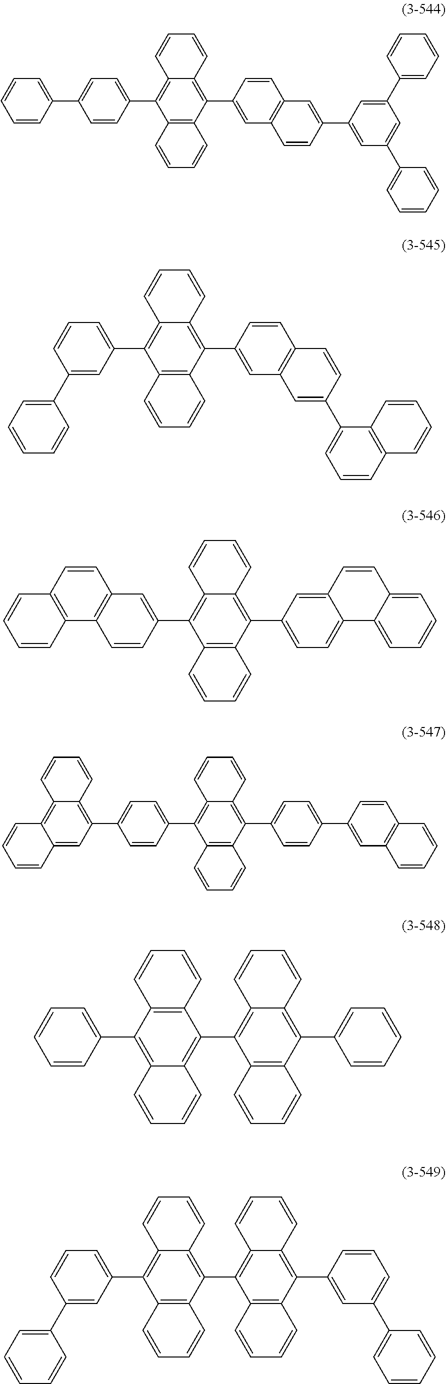

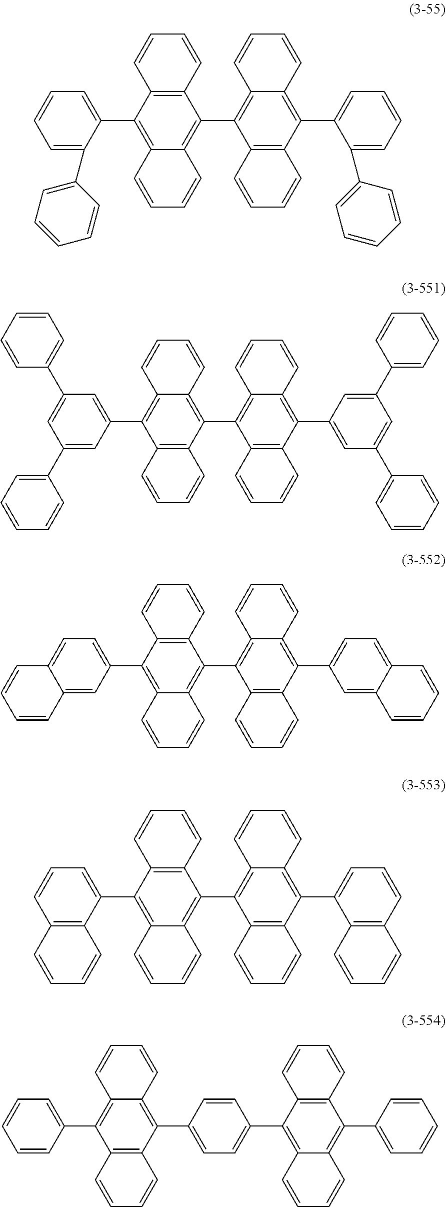

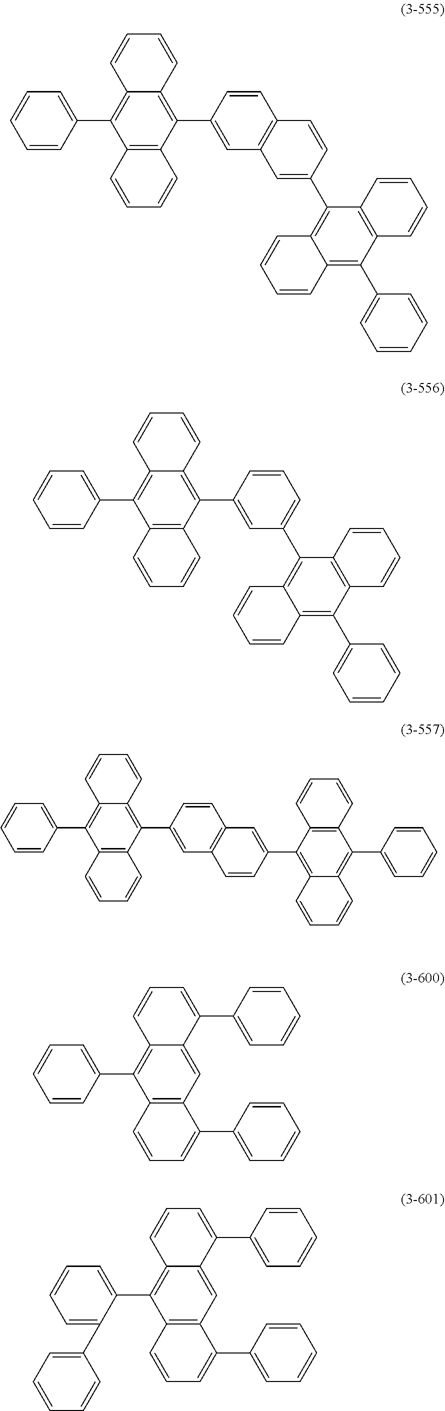

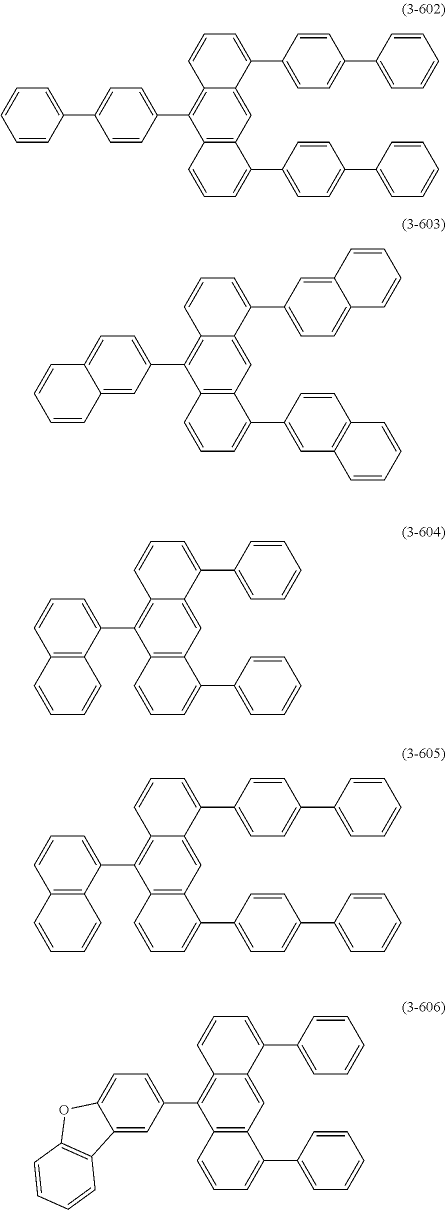

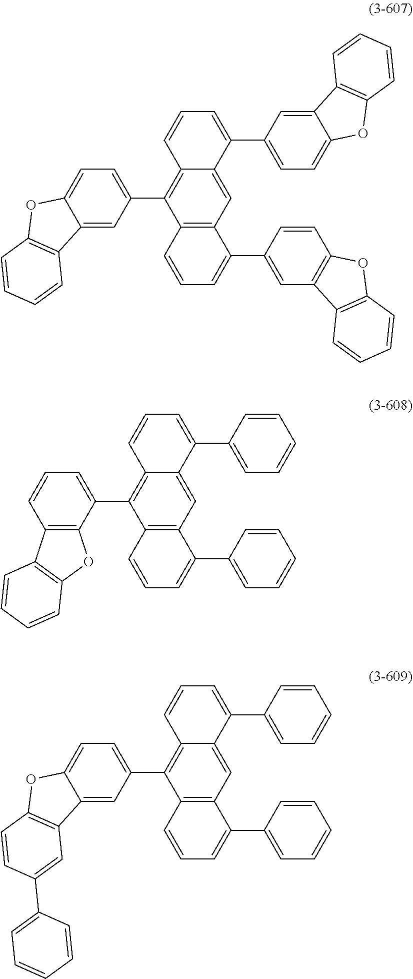 [SMILES: c1ccc2c(c1)oc1ccc(-c3cccc4c(-c5ccc6oc7ccccc7c6c5)c5cccc(-c6ccc7oc8ccccc8c7c6)c5cc34)cc12 ; c1ccc(-c2cccc3c(-c4cccc5c4oc4ccccc45)c4cccc(-c5ccccc5)c4cc23)cc1 ; c1ccc(-c2ccc3oc4ccc(-c5c6cccc(-c7ccccc7)c6cc6c(-c7ccccc7)cccc56)cc4c3c2)cc1]

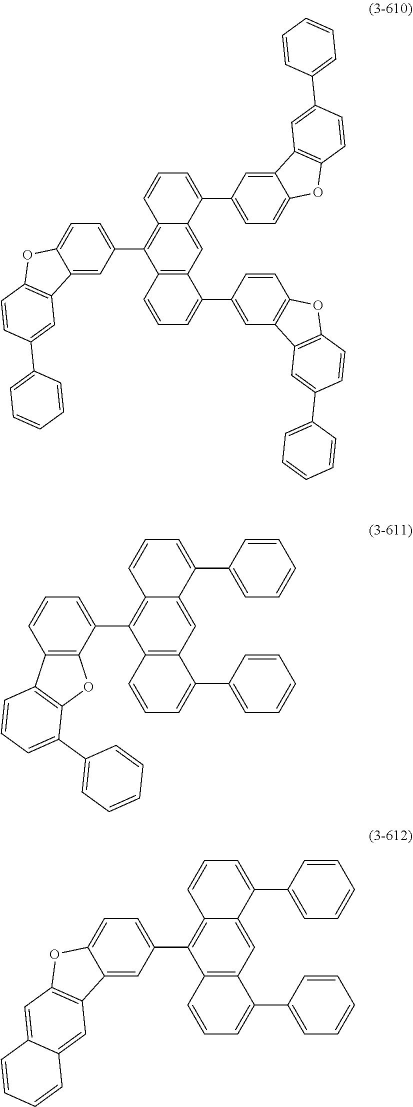 [SMILES: c1ccc(-c2ccc3oc4ccc(-c5cccc6c(-c7ccc8oc9ccc(-c%10ccccc%10)cc9c8c7)c7cccc(-c8ccc9oc%10ccc(-c%11ccccc%11)cc%10c9c8)c7cc56)cc4c3c2)cc1 ; c1ccc(-c2cccc3c(-c4cccc5c4oc4c(-c6ccccc6)cccc45)c4cccc(-c5ccccc5)c4cc23)cc1 ; c1ccc(-c2cccc3c(-c4ccc5oc6cc7ccccc7cc6c5c4)c4cccc(-c5ccccc5)c4cc23)cc1]

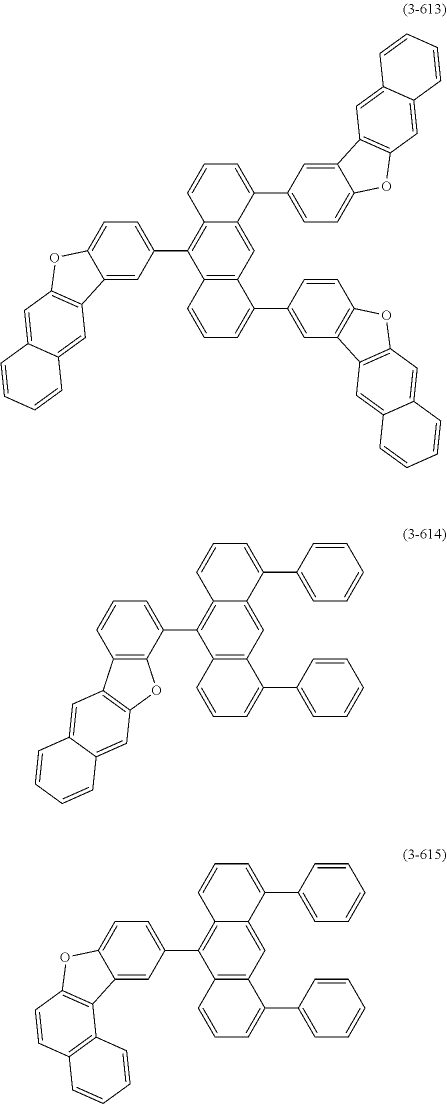 [SMILES: c1ccc2cc3c(cc2c1)oc1ccc(-c2cccc4c(-c5ccc6oc7cc8ccccc8cc7c6c5)c5cccc(-c6ccc7oc8cc9ccccc9cc8c7c6)c5cc24)cc13 ; c1ccc(-c2cccc3c(-c4cccc5c4oc4cc6ccccc6cc45)c4cccc(-c5ccccc5)c4cc23)cc1 ; c1ccc(-c2cccc3c(-c4ccc5oc6ccc7ccccc7c6c5c4)c4cccc(-c5ccccc5)c4cc23)cc1]

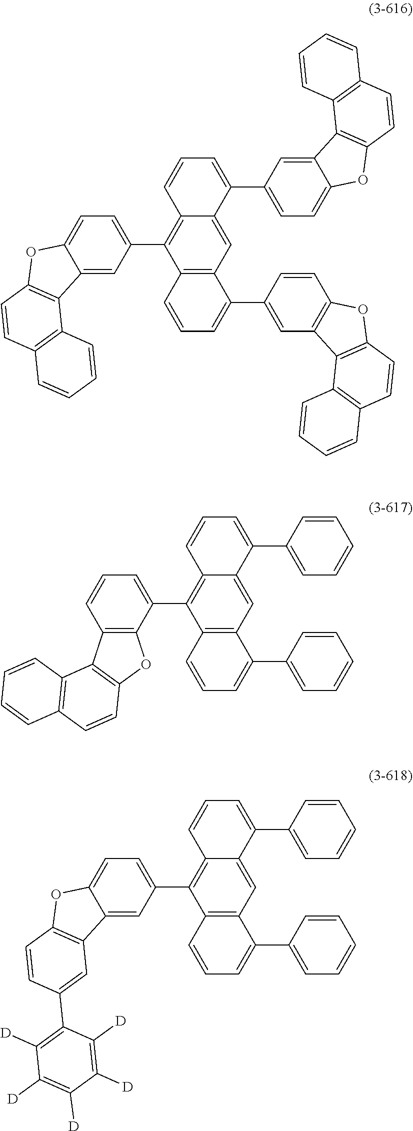 [SMILES: c1ccc2c(c1)ccc1oc3ccc(-c4cccc5c(-c6ccc7oc8ccc9ccccc9c8c7c6)c6cccc(-c7ccc8oc9ccc%10ccccc%10c9c8c7)c6cc45)cc3c12 ; c1ccc(-c2cccc3c(-c4cccc5c4oc4ccc6ccccc6c45)c4cccc(-c5ccccc5)c4cc23)cc1 ; [2H]c1c([2H])c([2H])c(-c2ccc3oc4ccc(-c5c6cccc(-c7ccccc7)c6cc6c(-c7ccccc7)cccc56)cc4c3c2)c([2H])c1[2H]]

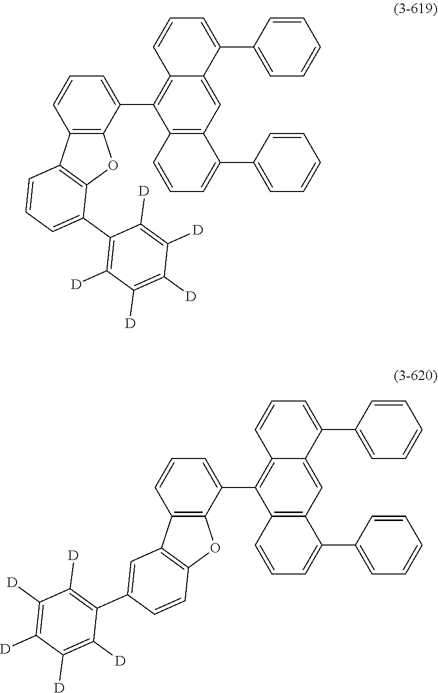 [SMILES: [2H]c1c([2H])c([2H])c(-c2cccc3c2oc2c(-c4c5cccc(-c6ccccc6)c5cc5c(-c6ccccc6)cccc45)cccc23)c([2H])c1[2H] ; [2H]c1c([2H])c([2H])c(-c2ccc3oc4c(-c5c6cccc(-c7ccccc7)c6cc6c(-c7ccccc7)cccc56)cccc4c3c2)c([2H])c1[2H]]

Among the compounds, a compound represented by Formula (3-131-Y) to Formula (3-134-Y), Formula (3-138-Y), Formula (3-140-Y) to Formula (3-143-Y), Formula (3-150-Y), Formula (3-153-Y) to Formula (3-156-Y), Formula (3-166-Y), Formula (3-168-Y), Formula (3-173-Y), Formula (3-177-Y), Formula (3-180-Y) to Formula (3-183-N), Formula (3-185-Y), Formula (3-190-Y), Formula (3-223-Y), Formula (3-241-Y), Formula (3-250-Y). Formula (3-252-Y) to Formula (3-254-Y), Formula (3-501), Formula (3-507), Formula (3-508), Formula (3-509), Formula (3-513), Formula (3-514). Formula (3-519), Formula (3-521), Formula (3-538) to Formula (3-547) or Formula (3-600) to (3-620) is preferred. Y is preferably —O—.

The above anthracene-based compound can be produced by applying Suzuki coupling. Negishi coupling, or other known coupling reactions using a compound having a reactive group at a desired position of an anthracene skeleton and a compound having a reactive group in a partial structure such as X. Ar⁴, and a structure of Formula (A) as a starting material if the compound is an anthracene-based compound represented by Formula (3-H). Examples of the reactive group of these reactive compounds include a halogen and boronic acid. As a specific manufacturing method, for example, a synthesis method in paragraphs [0089] to [175] of WO 2014/141725 can be referred to.

### <Fluorene Compounds>

The compound represented by Formula (4-H) basically functions as a host.

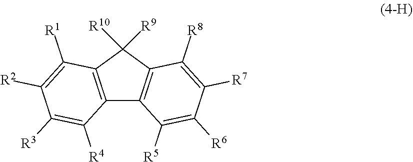

In Formula. (4-H),

each of R¹ to R¹⁰ is independently hydrogen, an aryl, a heteroaryl (the heteroaryl may be linked to the fluorene skelton in Formula (4-H) via a linking group), a diarylamino, a diheteroarylamino, an arylheteroarylamino, an alkyl, a cycloalkyl, an alkenyl, an alkoxy or an aryloxy, and at least one hydrogen in these may be replaced with an aryl, a heteroaryl, an alkyl, or a cycloalkyl, R¹ and R², R² and R³, R³ and R⁴, R⁵ and R⁶, R⁶ and R⁷, R⁷ and R⁸, a R⁹ and R¹⁰ may be independently bonded to form a fused ring or a Spiro ring, and at least one hydrogen in the formed ring may be replaced with an aryl, a heteroaryl (the heteroaryl may be bonded to the formed ring via a linking group), a diarylamino, a diheteroarylamino, an arylheteroaryla.mino, an alkyl, a cycloalkyl, an alkenyl, an alkoxy, or an aryloxy, and at least one hydrogen in these may be replaced with an aryl, a heteroaryl, an alkyl, an alkyl, or a cycloalkyl. At least one hydrogen in the compound represented by Formula. (4-H) may be replaced with a halogen, cyano or deuterium.

For details of each group in the definition of Formula (4-H), the description in the polycyclic aromatic compound of Formula (1) described above can be referred to,

Examples of the alkenyl in R′ to R¹⁰ include, for example, an alkenyl having 2 to 30 carbons, preferably an alkenyl having 2 to 20 carbons, more preferably an alkenyl haying 2 to 10 carbons, further preferably an alkenyl having 2 to 6 carbons, and particularly preferably an alkenyl having 2 to 4 carbons. Preferred alkenyls are vinyl, 1-propenyl, 2-propenyl, 1-butenyl, 2-butenyl, 3-butenyl, 1-pentenyl, 2-pentenyl, 3-pentenyl, 4-pentenyl, 1-hexenyl, 2-hexenyl, 3-hexenyl, 4-hexenyl, or 5-hexenyl.

Specific examples of the heteroaryl include a monovalent group obtained by deleting any one hydrogen atom from the compound represented by Formula (4-Ar1), (4-Ar2), (4-Ar3), (4-Ar4) or (4-Ar5) shown below.

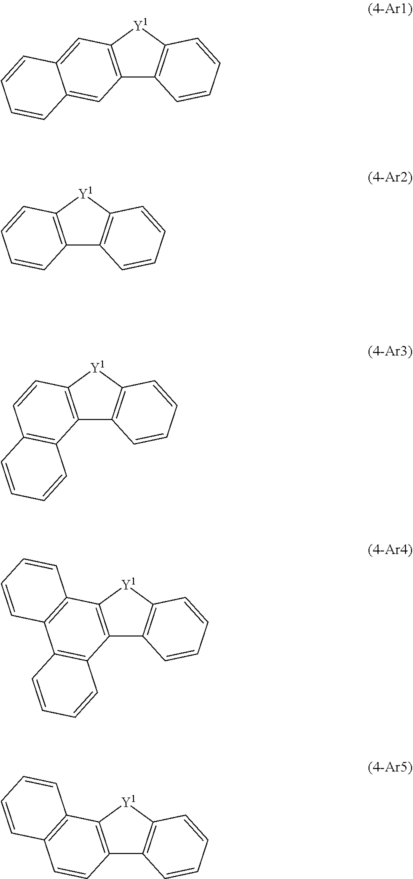

In Formulas (4-Ar1) to (4-Ar5), Y¹ is independently O, S or N—R, and. R is phenyl, biphenylyl, naphthyl, anthracenyl or hydrogens, at least one hydrogen in the structure of formula (4-Ar1) to formula (4-Ar5) may be replaced with phenyl, biphenylyl, naphthyl, anthracenyl, phenanthrenyl, methyl, ethyl, propyl, or butyl.

These heteroaryls may be bonded to the fluorene skeleton in Formula (4-H) via a linking group. In other words, not only the fluorene skeleton and the above-mentioned heteroaryl in Formula (4-H) are directly bonded to each other but also they may be bonded to each other via a linking group. These linking groups include phenylene, biphenylene, naphthylene, anthracenylene, methylene, ethylene, —OCH₂CH₂—, —CH₂CH₂O— or —OCH2CH₂O—.

In Formula (4-H), and R¹ and R², R² and R³, R³ and R⁴, R⁵ and R⁶, R⁶ and R⁷ or R⁷ and R⁸ may he bonded to form a fused ring, and R⁹ and R¹⁰ may be bonded to form a Spiro ring. The fused ring formed by R¹ to R⁸ is a ring fused to the benzene ring in Formula(4-H) and is an aliphatic ring or an aromatic ring. The fused ring formed is preferably an aromatic ring, and examples of the structure including a benzene ring in Formula (4-H) include naphthalene ring and phenanthrene ring. The spino ring formed by R⁹ and R¹⁰ is a ring that is spiro-bonded to the five-membered ring in Formula (4-H) and is an aliphatic ring or an aromatic ring, The Spiro ring formed is preferably an aromatic ring, and examples thereof include a fluorene ring and the like.

The compound represented by Formula (4-H) is preferably a compound represented by Formula (4-H-1), Formula (4-H-2) or Formula (4-H-3) below, which are a compound in which a benzene formed by bonding R¹ and R² in Formula (4-H) is fused, a compound in which a benzene ring formed by bonding R³ and R⁴ in Formula (4-H) is fused, and a compound in which none of R¹ to R⁸ is bonded in Formula (4-H), respectively.

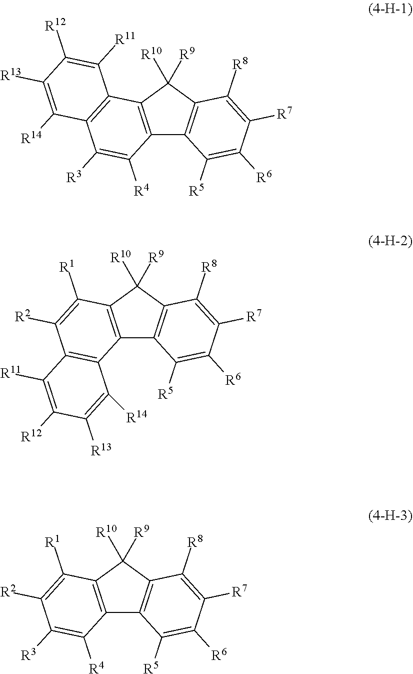

The definitions of R¹ to R¹⁰ in Formulas (4-H-1), (4-H-2) and (4-H-3) are the same as the definitions of the corresponding R¹ to R¹⁰ in Formula (4-H), and the definitions of R¹¹ to R¹⁴ in Formulas (4-H-1) and (4-H-2) are the same as the definitions of R¹ to R¹⁰ in Formula (4-H).

The compound represented by Formula (4-H) is more preferably a compound represented by Formula (4-H-1A), Formula (4-H-2A) or Formula (4-H-3A), which is a compound in which R⁹ and R¹⁰ are bonded to each other in Formula (4-H-1), Formula (4-H-1) or Formula (4-H-3), respectively, to form a spiro-fluorene ring.

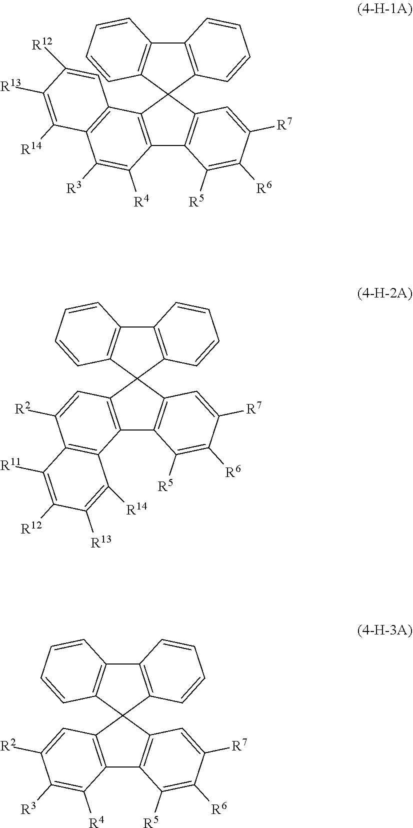

The definition of R² to R⁷ in Formulas(4-1 A), (4-2A) and (4-3A) is the same as the definition of the corresponding R² to R⁷ in Formulas (4-1), (4-2), and (4-3), and the definition of R¹¹ to R¹⁴ in Formulas (4-1A) and (4-2A) is the same as R¹¹ to R¹⁴ in Formulas (4-1) and (4-2), respectively.

In addition, all or a part of hydrogens in the compound represented by Formula (4-H) may be replaced with a halogen, cyano or deuterium.

Further specific examples of the fluoren.e-bed compound as a host of the present invention include a compound represented by the following structural formula. “Me” represents methyl.

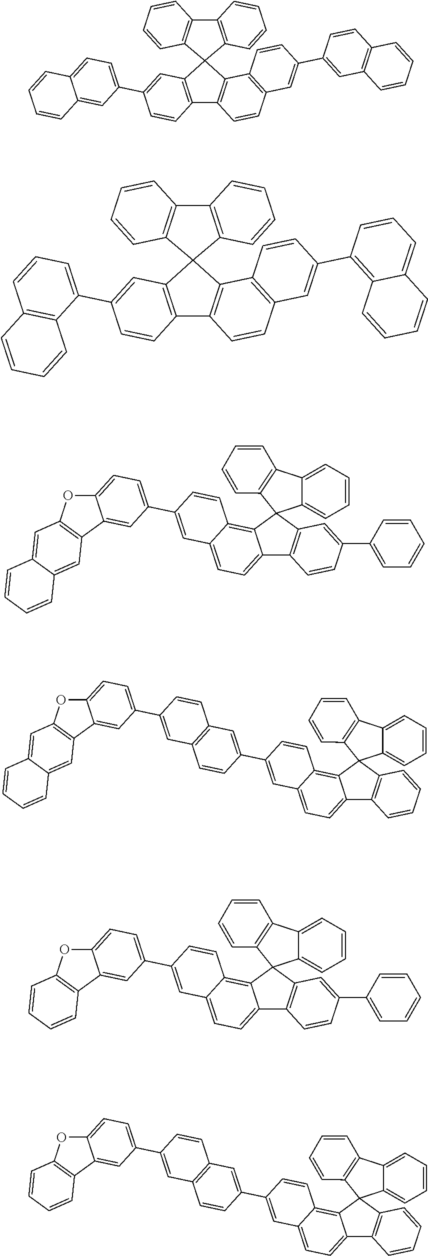

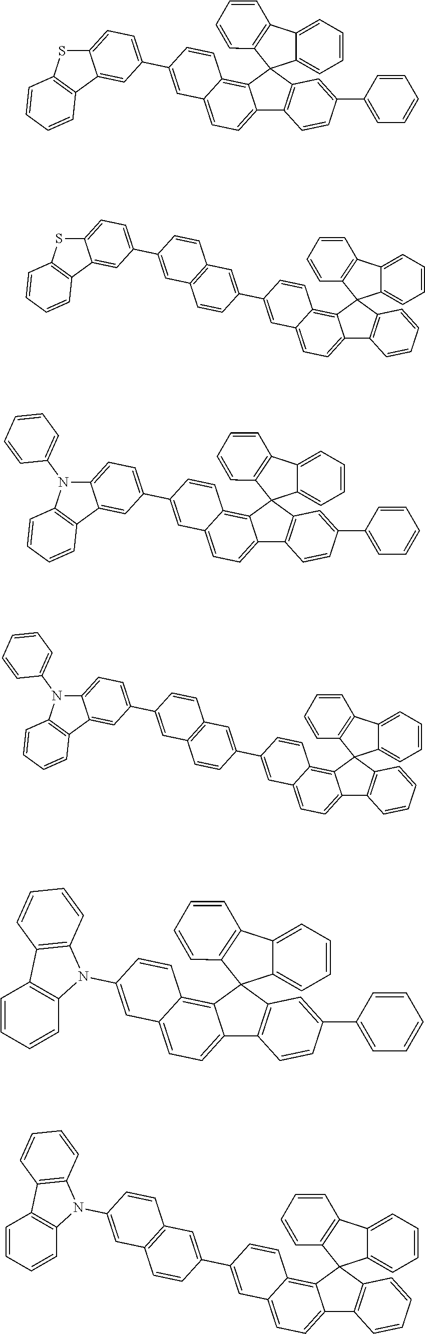

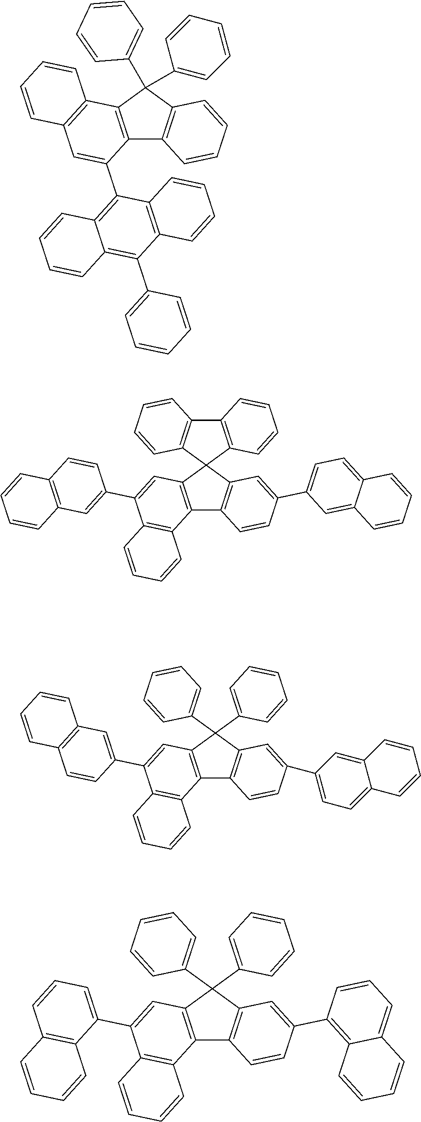

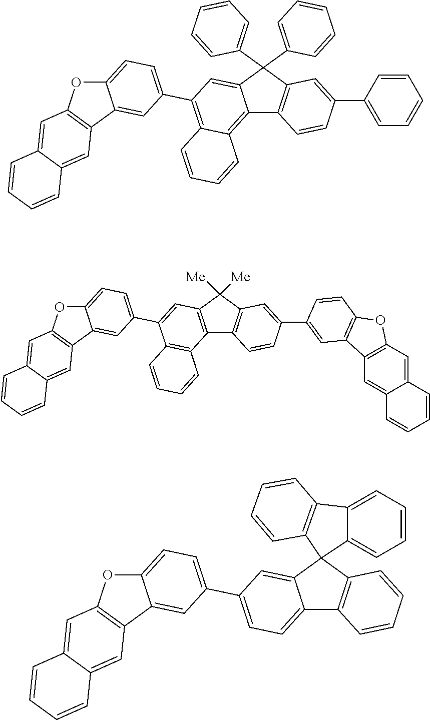 [SMILES: c1ccc(-c2ccc3c(c2)C(c2ccccc2)(c2ccccc2)c2cc(-c4ccc5oc6cc7ccccc7cc6c5c4)c4ccccc4c2-3)cc1 ; CC1(C)c2cc(-c3ccc4oc5cc6ccccc6cc5c4c3)ccc2-c2c1cc(-c1ccc3oc4cc5ccccc5cc4c3c1)c1ccccc21 ; c1ccc2c(c1)-c1ccccc1C21c2ccccc2-c2ccc(-c3ccc4oc5cc6ccccc6cc5c4c3)cc21]

### <Dibenzochrysene-Based Compounds>

The dibenzocrvsene-based compound as a host is, for example, a compound represented by the following Formula (5-H).

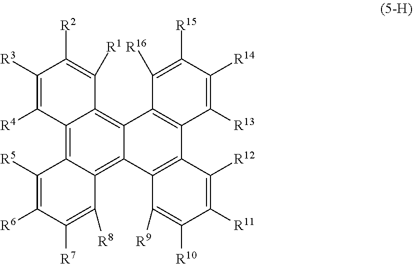

In Formula (5-H).

R¹ to R¹⁶ are each independently hydrogen, an aryl, a heteroaryl (the heteroaryl may be bonded to the dibenzochrysene skelton in Formula (5-H) via a linking group), a diarylamino, diheteroarylamino, an arylheteroarylamino, an alkyl, a cycloalkyl, an alkenyl, an alkoxy or an aryloxy, and at least one hydrogen in the above substituents may be substituted with an aryl, a heteroaryl, an alkyl, or a cycloalkyl, any adjacent groups among R¹ to R¹⁶ may be bonded to each other to form a fused ring, and at least one hydrogen in the formed ring may be replaced with an aryl, a heteroaryl (the heteroaryl may be bonded via a linking group to form a ring), a diarylamino, a diheteroarylamino, an arylheteroarylamino, an alkyl, a cycloalkyl, an alkenyl, an alkoxy, or an aryloxy, wherein at least one hydrogen in these may be replaced with an aryl, a heteroaryl, an alkyl, or a cycloalkyl, at least one hydrogen in the compound represented by Formula (5-H) may be replaced with a halogen, cyano or deuterium.

For details of each group in the definition of Formula (5-H), the description in the polycyclic aromatic compound of Formula (1) described above can be referred to.

Examples of the Amyl as defined in Formula (5-H) include an alkenyl having 2 to 30 carbons, and an alkenyl having 2 to 20 carbons is preferred, an alkenyl having 2 to 10 carbons is more preferred, an alkenyl having 2 to 6 carbons is further preferred, and an alkenyl having 2 to 4 carbons is particularly preferred, Preferred alkenyls are vinyl, 1-propenyl, 2-propenyl, 1-butenyl, 2-butenyl, 3-butenyl, 1-pentenyl, 2-pentenyl, 3-pentenyl, 4-pentenyl, 1-hexenyl, 2-hexenyl, 3-hexenyl, 4-hexenyl, or 5-hexenyl.

Specific examples of the heteroaryl include a monovalent group obtained by deleting any one hydrogen atom from a compound represented by Formula (5-Ar1), Formula (5-Ar2), Formula (5-Ar3), Formula (5-Ar4) or Formula (5-Ar5).

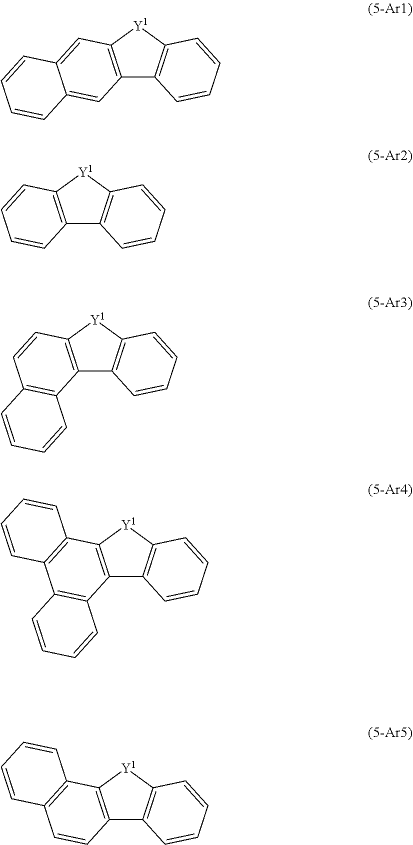

In Formulas (5-Ar1) to (5-Ar5). Y¹ is independently O, S or N—R, and R is phenyl, biphenylyl, naphthyl, anthracenyl or hydrogen, at least one hydrogen in the structure of Formula (5-Ar1) to Formula (5-Ar5) may be replaced with phenyl, biphenylyl, naphthyl, anthracenyl, phenanthrenyl, methyl, ethyl, propyl, or butyl.

These heteroaryls may be bonded to the dibenzocrysene skelton Formula (5-H) via a linking group. In other words, not only the dibenzochrysene skelton and the above heteroaryl in Formula (5-H) may be directly bonded to each other but also they may be bonded to each other via a linking group. These linking groups include phenylene, biphenylene, naphthylene, anthracenylene, methylene, ethylene, —OCH₂CH₂—, —CH₂CH₂O— or —OCH₂CH₂O—.

In Formula (5-H), R¹, R⁴, R⁵, R⁸, R⁹, R¹², R¹³ and R¹⁶ are preferably hydrogen. In this case, R², R³, R⁶, R⁷, R¹⁰, R¹¹, R¹⁴ and R¹⁵ in Formula (5-H) are preferred to be each independently hydrogen, phenyl, biphenylyl, naphthyl, anthracenyl, phenanthrenyl, a monovalent group haying the structure of Formula (5-Ar1), Formula (5-Ar2), Formula (5-Ar4), or Formula (5-Ar5) (the monovalent group having the structure may be bonded to the dibenzochrysene skeleton in Formula (5-H) via phenylene, biphenylene, naphthalne, anthracenylene, methylene, ethylene, —OCH₂CH₂—, —CH₂CH₂O—, or —OCH₂CH₂O—), methyl, ethyl, propyl, or butyl.

In the compound represented by Formula (5-H) i R¹, R², R⁴, R⁵, R⁷, R⁸, R⁹, R¹⁰, R¹², R¹³, R¹⁵ and R¹⁶ are hydrogens. In this case, at least one (preferably one or two, more preferably one) of R³, R⁶, R¹¹ and R¹⁴ in Formula (5-H) is a monovalent group having the structures of Formula (5-Ar1), (5-Ar2), (5-Ar3), (5-Ar4) or (5-Ar5) via a single bond, phenylene, biphenylene, naphthylene, anthracenylene, methylene, ethylene, —OCH₂CH₂—, —CH₂CH₂O or —OCH₂CH₂O—; and other than the above at least one (i.e., other than the positions at which the monovalent group having the above structure is substituted) is hydrogen, phenyl, biphenylyl, naphthyl, anthracenyl, methyl, ethyl, propyl, or butyl, and at least one hydrogen in these may be replaced with phenyl, biphenylyl, naphthyl, anthracenyl, methyl, ethyl, propyl, or butyl.

In addition, when a monovalent group having a structure represented by Formula (5-Ar1) to Formula (5-Ar5) is selected as R², R³, R⁶, R⁷, R¹⁰, R¹¹, R¹⁴ as R¹⁵ in the Formula (5-H), at least one of the hydrogens in the structure may be instead single bond to be bonded to any of R¹ to R¹⁶ in the Formula (5-H).

Further specific examples of the dibenzochrysene-based compound as a host of the present invention include a compound represented by the following structural formula. “tBu” represents t-butyl.

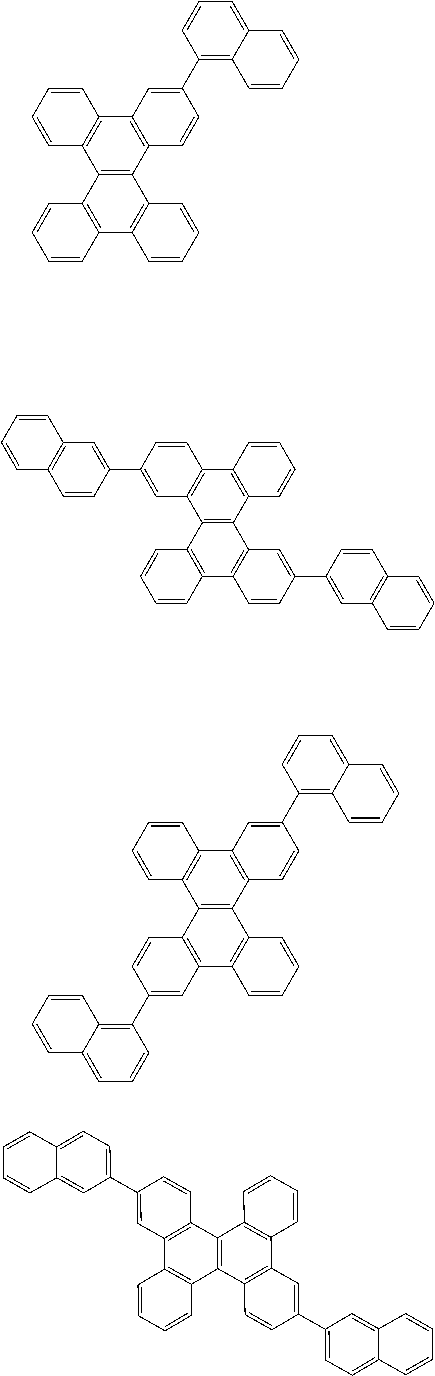

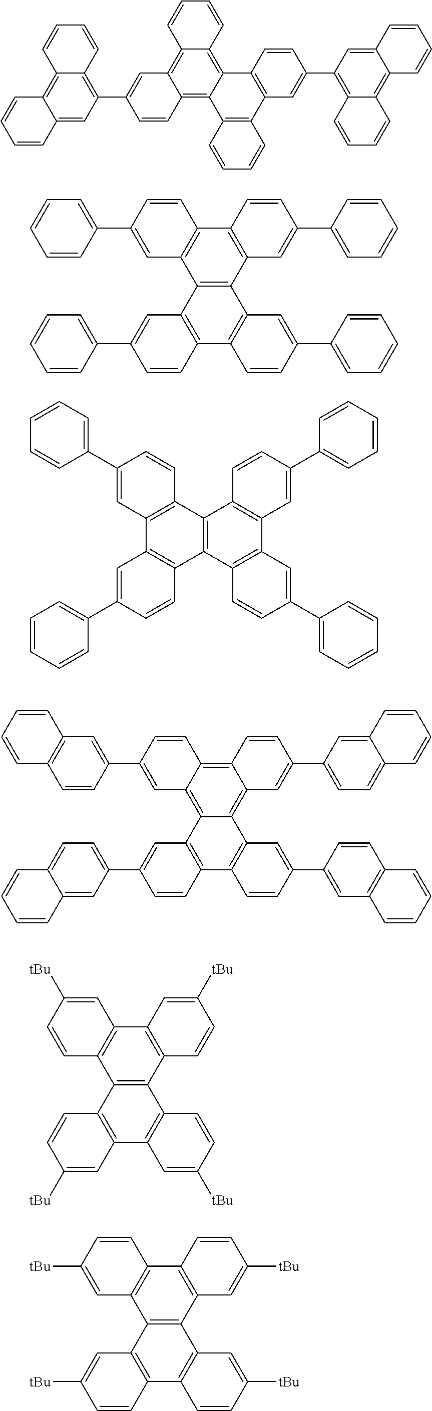

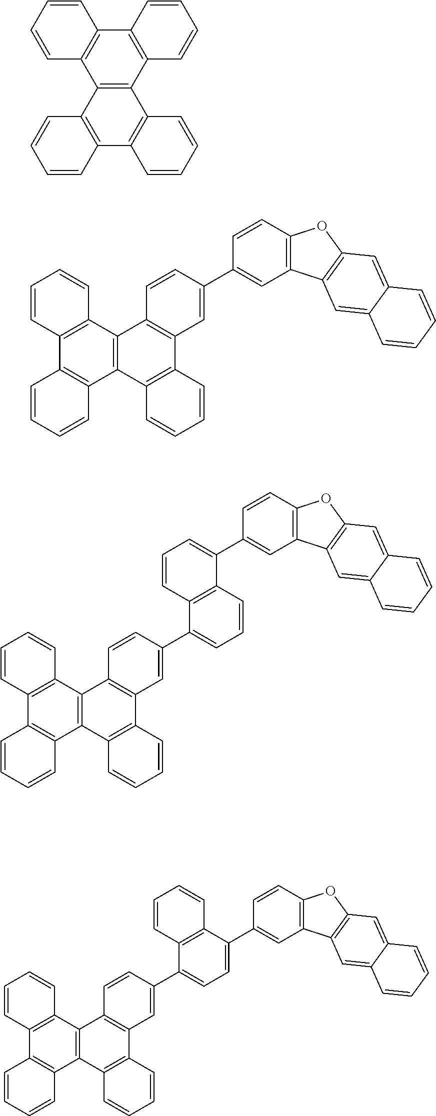

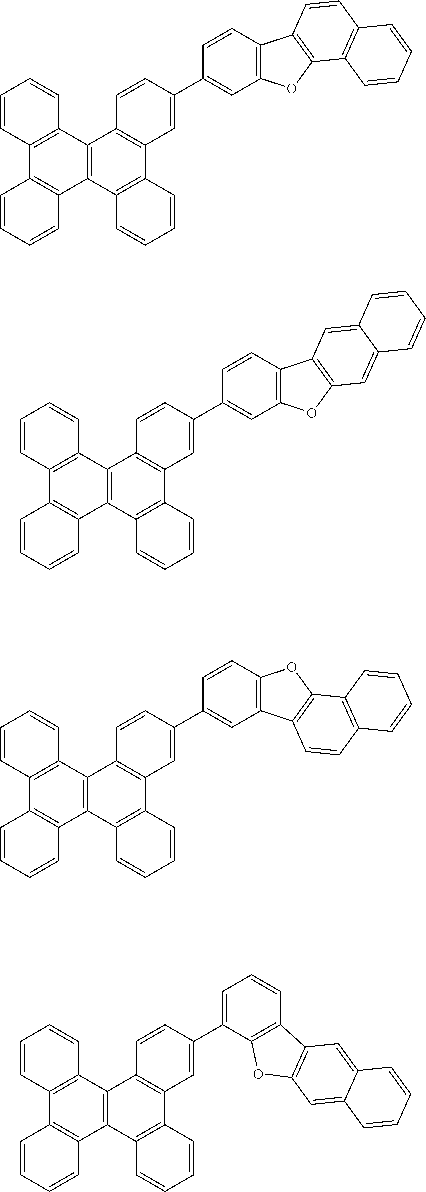 [SMILES: c1ccc2c(c1)ccc1c3ccc(-c4ccc5c(c4)c4ccccc4c4c6ccccc6c6ccccc6c54)cc3oc21 ; c1ccc2cc3c(cc2c1)oc1cc(-c2ccc4c(c2)c2ccccc2c2c5ccccc5c5ccccc5c42)ccc13 ; c1ccc2c(c1)ccc1c3cc(-c4ccc5c(c4)c4ccccc4c4c6ccccc6c6ccccc6c54)ccc3oc21 ; c1ccc2cc3c(cc2c1)oc1c(-c2ccc4c(c2)c2ccccc2c2c5ccccc5c5ccccc5c42)cccc13]

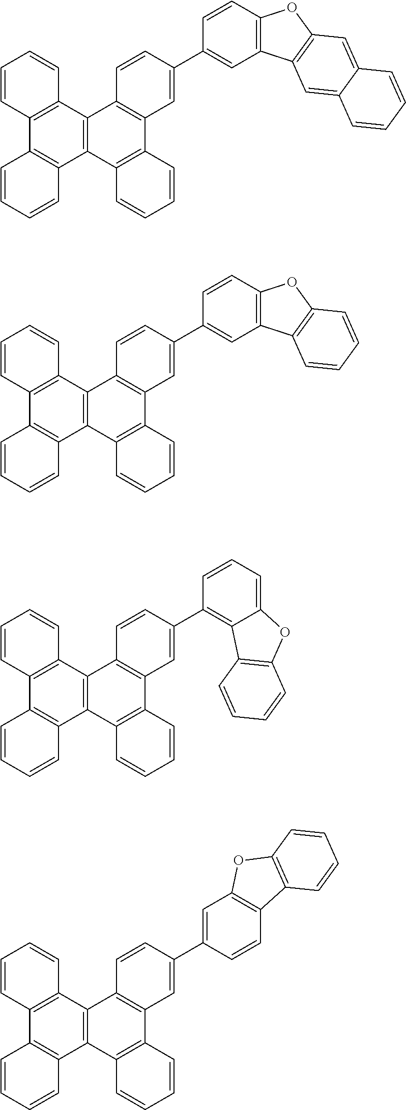 [SMILES: c1ccc2cc3c(cc2c1)oc1ccc(-c2ccc4c(c2)c2ccccc2c2c5ccccc5c5ccccc5c42)cc13 ; c1ccc2c(c1)oc1ccc(-c3ccc4c(c3)c3ccccc3c3c5ccccc5c5ccccc5c43)cc12 ; c1ccc2c(c1)oc1cccc(-c3ccc4c(c3)c3ccccc3c3c5ccccc5c5ccccc5c43)c12 ; c1ccc2c(c1)oc1cc(-c3ccc4c(c3)c3ccccc3c3c5ccccc5c5ccccc5c43)ccc12]

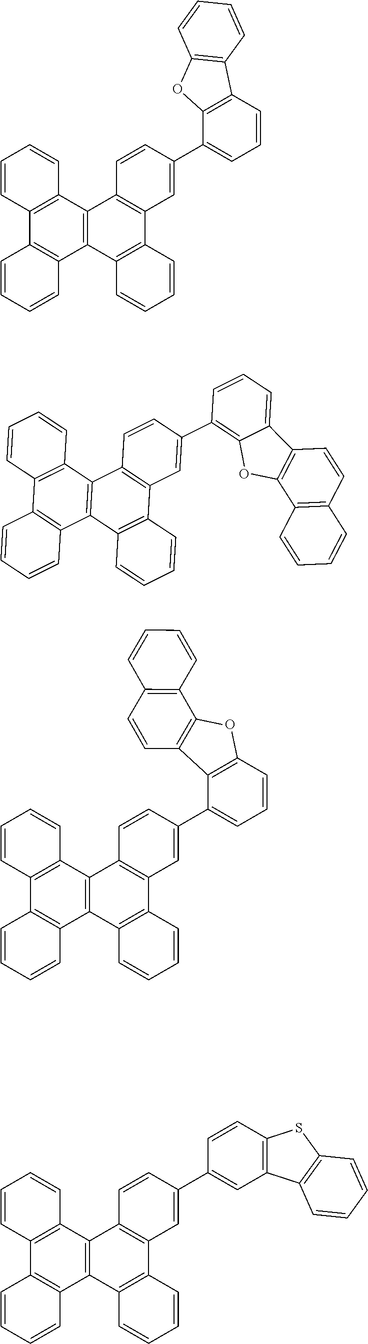

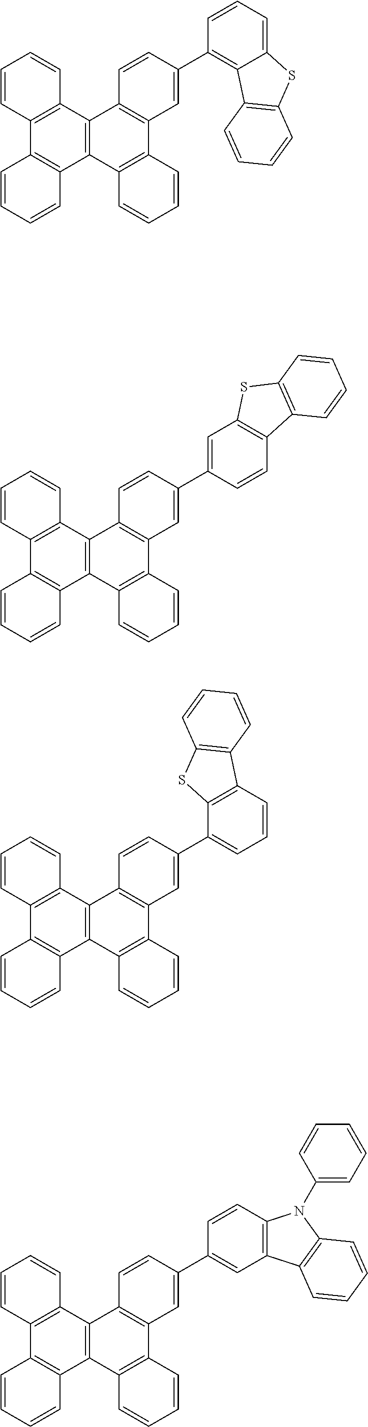 [SMILES: c1ccc2c(c1)sc1cccc(-c3ccc4c(c3)c3ccccc3c3c5ccccc5c5ccccc5c43)c12 ; c1ccc2c(c1)sc1cc(-c3ccc4c(c3)c3ccccc3c3c5ccccc5c5ccccc5c43)ccc12 ; c1ccc2c(c1)sc1c(-c3ccc4c(c3)c3ccccc3c3c5ccccc5c5ccccc5c43)cccc12 ; c1ccc(-n2c3ccccc3c3cc(-c4ccc5c(c4)c4ccccc4c4c6ccccc6c6ccccc6c54)ccc32)cc1]

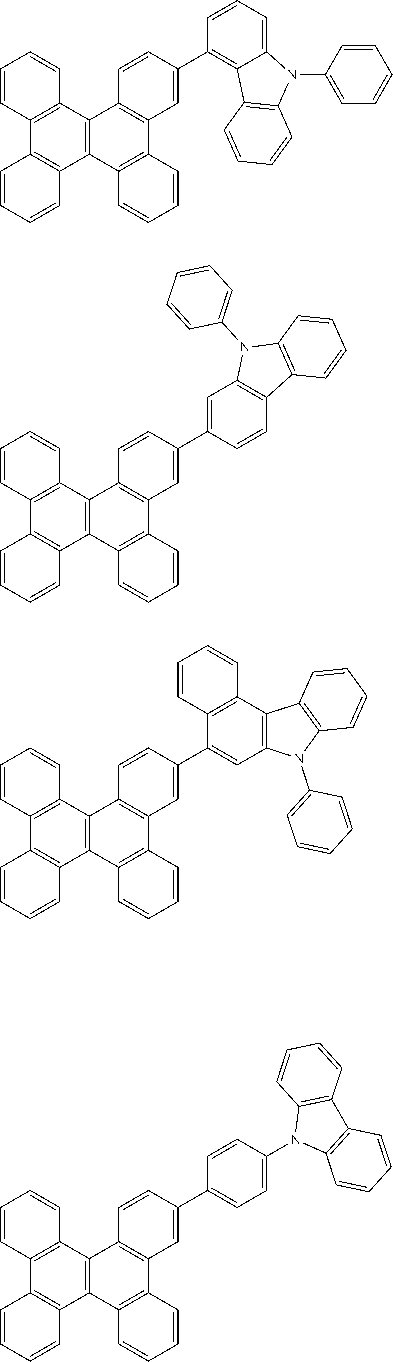 [SMILES: c1ccc(-n2c3ccccc3c3c(-c4ccc5c(c4)c4ccccc4c4c6ccccc6c6ccccc6c54)cccc32)cc1 ; c1ccc(-n2c3ccccc3c3ccc(-c4ccc5c(c4)c4ccccc4c4c6ccccc6c6ccccc6c54)cc32)cc1 ; c1ccc(-n2c3ccccc3c3c4ccccc4c(-c4ccc5c(c4)c4ccccc4c4c6ccccc6c6ccccc6c54)cc32)cc1 ; c1ccc2c(c1)c1ccccc1c1c3ccc(-c4ccc(-n5c6ccccc6c6ccccc65)cc4)cc3c3ccccc3c21]

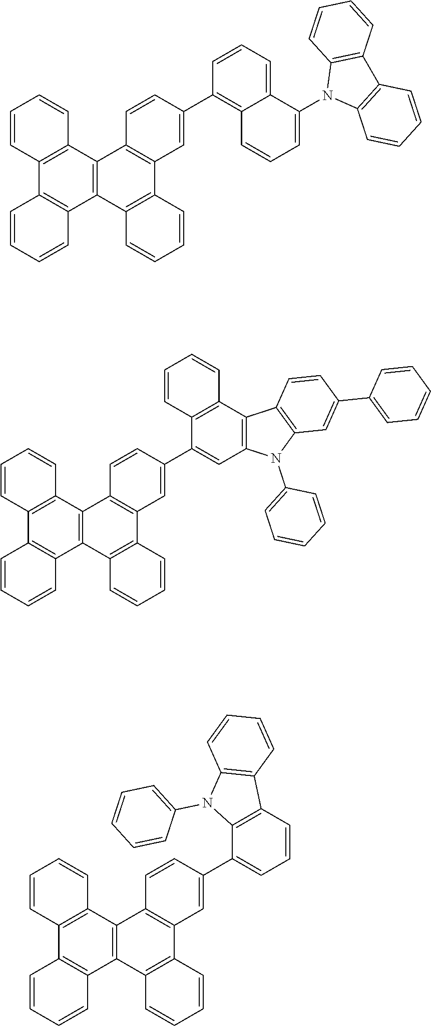 [SMILES: c1cc(-n2c3ccccc3c3ccccc32)c2cccc(-c3ccc4c(c3)c3ccccc3c3c5ccccc5c5ccccc5c43)c2c1 ; c1ccc(-c2ccc3c4c5ccccc5c(-c5ccc6c(c5)c5ccccc5c5c7ccccc7c7ccccc7c65)cc4n(-c4ccccc4)c3c2)cc1 ; c1ccc(-n2c3ccccc3c3cccc(-c4ccc5c(c4)c4ccccc4c4c6ccccc6c6ccccc6c54)c32)cc1]

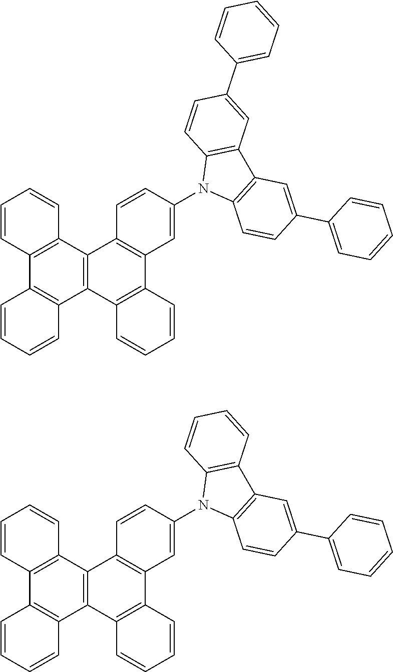 [SMILES: c1ccc(-c2ccc3c(c2)c2cc(-c4ccccc4)ccc2n3-c2ccc3c(c2)c2ccccc2c2c4ccccc4c4ccccc4c32)cc1 ; c1ccc(-c2ccc3c(c2)c2ccccc2n3-c2ccc3c(c2)c2ccccc2c2c4ccccc4c4ccccc4c32)cc1]

The above-described material for a light-emitting layer (host material and dopant material) can be used as a material for a light-emitting layer, even as a polymer compound obtained by polymerizing a reactive compound in which a reactive substituent is substituted into these as a monomer, or a polymer cross-linked body thereof, or a pendant type polymer compound obtained by reacting a main chain type polymer with the reactive compound, or a pendant type polymer crosslinked body thereof.

### <Examples of Polymer Host Material>

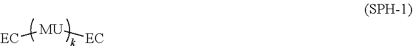

In Formula (SPH-1),

MU's are each independently a divalent aromatic group, EC's are each independently a monovalent aromatic group, two hydrogens in MU are replaced with EC or MU, k is an integer of 2 to 50000.

More specifically, MUs are each independently, an arylene, a heteroarylene, diarylenearylamino, a diarylenearylboryl, an oxaborin-diyl, or an azaborine-diyl. ECs are each independently, an aryl, a heteroaryl, a diarylamino, a diheteroarylamino, an arylheteroarylamino, or an aryloxy. At least one hydrogen in MU and EC may further be replaced with one or more substituent selected from the group consisting of amyl, heteroaryl, diarylamino, alkyl, and cycloalkyl. k is an integer of 2 to 50000. k is preferably an integer of 20 to 50000, and more preferably an integer of 100 to 50000.

At least one hydrogen in MU and EC in Formula (SPH-1) may be replaced with an alkyl having 1 to 24 carbons, a cvcloalkyl having 3 to 24 carbons. Further, any —CH₂— in the above alkyl may he replaced with —O— or —Si(CH₃)₂—, any —CH₂— except —CH₂— directly linked to EC in Formula (SPH-1) in the above alkyl may be replaced with an arylene having 6 to 24 carbons, and any hydrogen in the above alkyl may be replaced with fluorine,

Examples of the MU include a divalent derivative of the following structure (e.g., a divalent group obtained by deleting two hydrogens from any of the compounds of the following structures, a divalent group composed of a combination of any two or more of divalent groups each obtained by deleting two hydrogens from any of the compounds of the following structures, a divalent group in which at least one of hydrogens in those groups is replaced with an alkyl or the like).

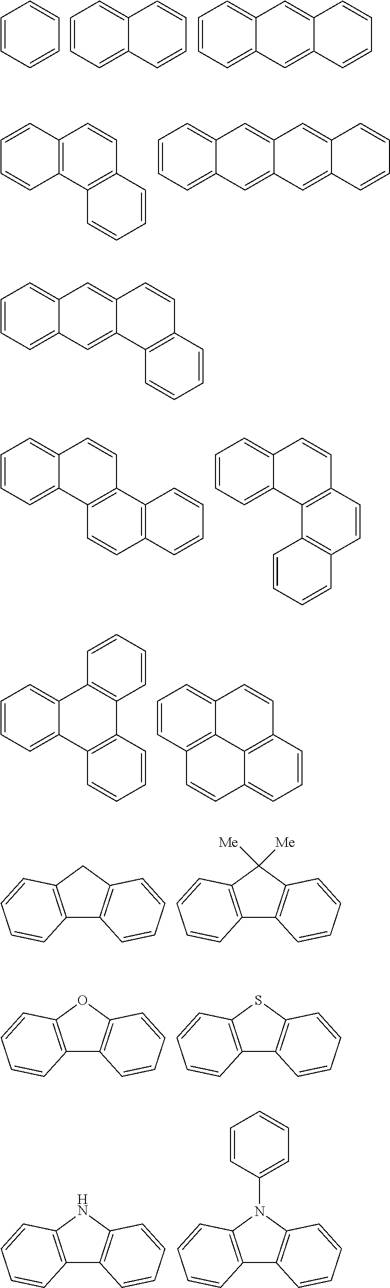

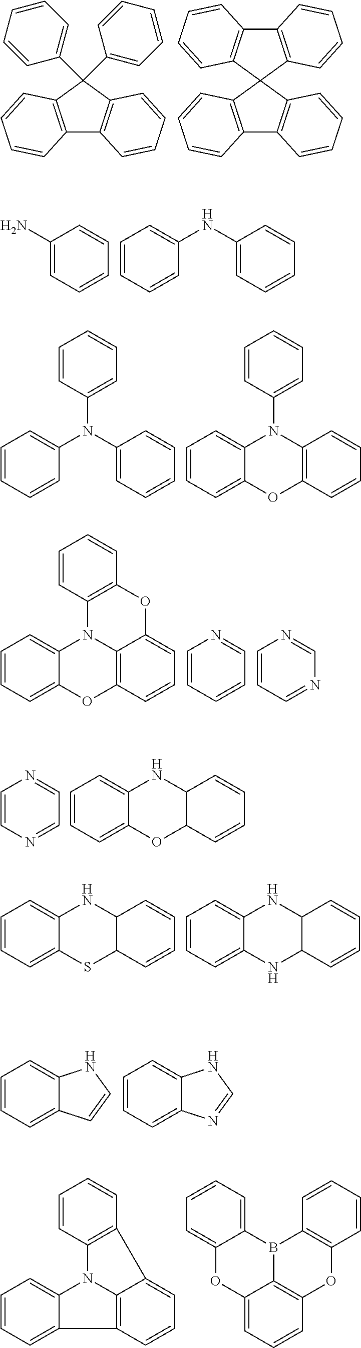

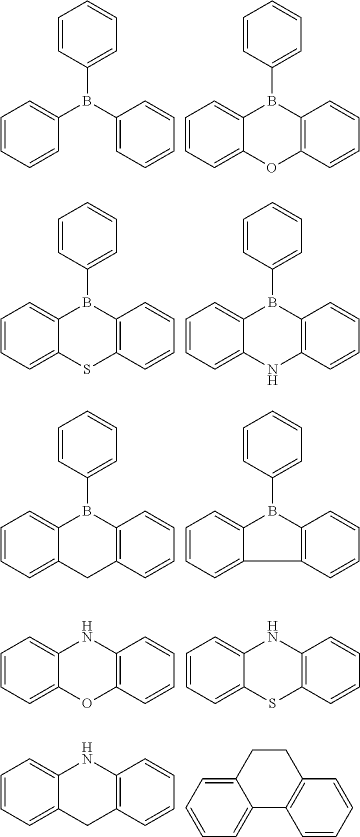

More specifically, a divalent group represented by any of the following structures can be exemplified. In these structures, the MU binds to another MU or EC at *.

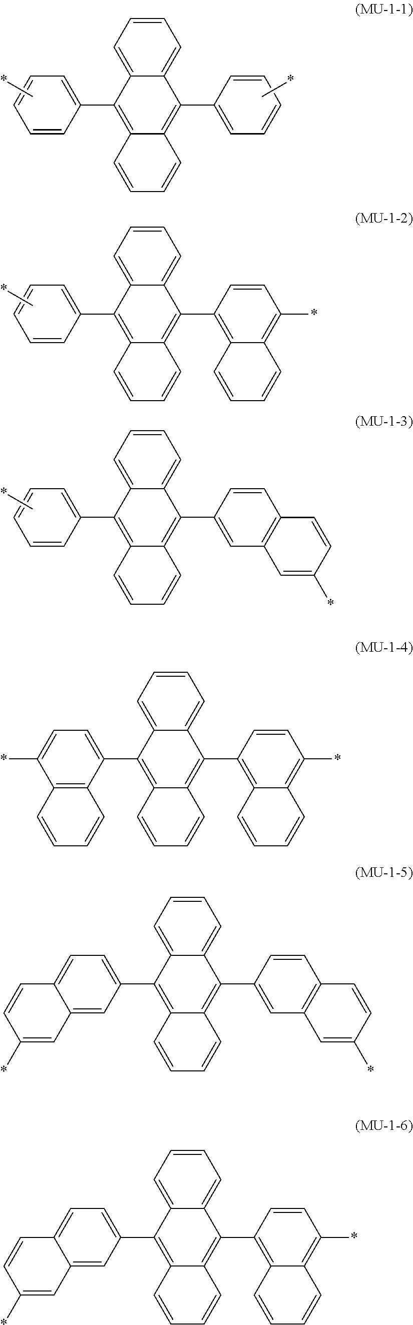

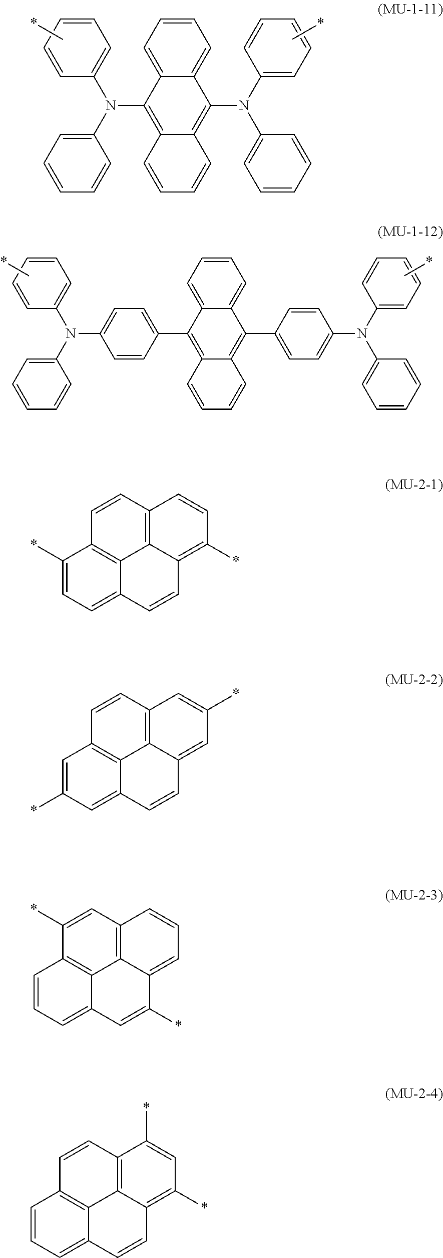

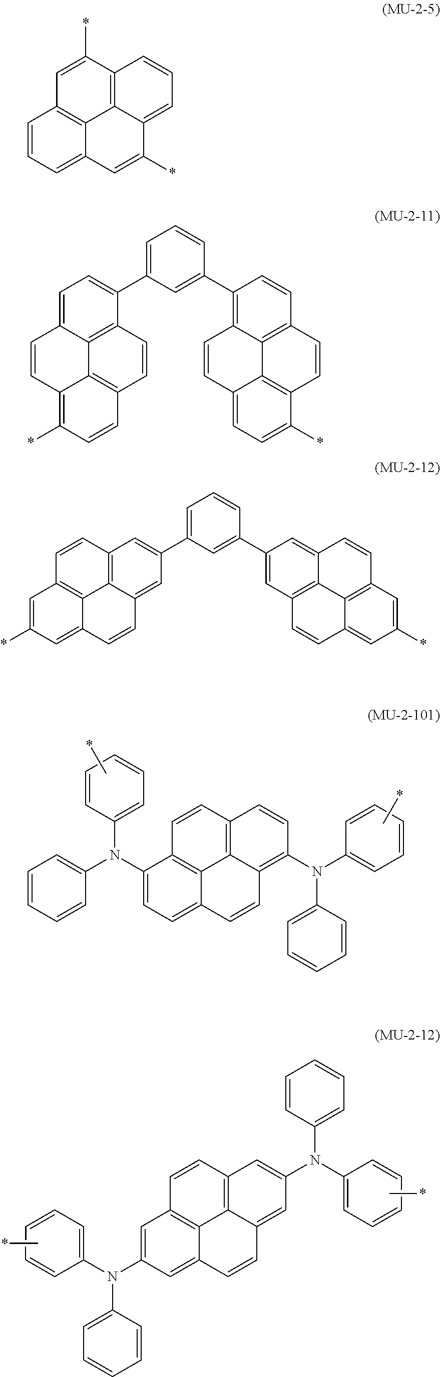

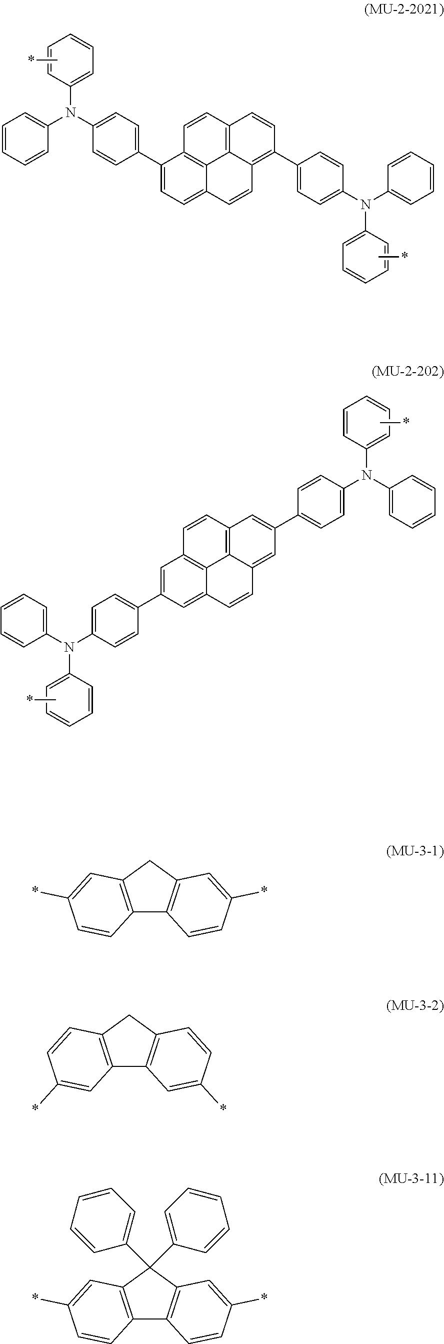

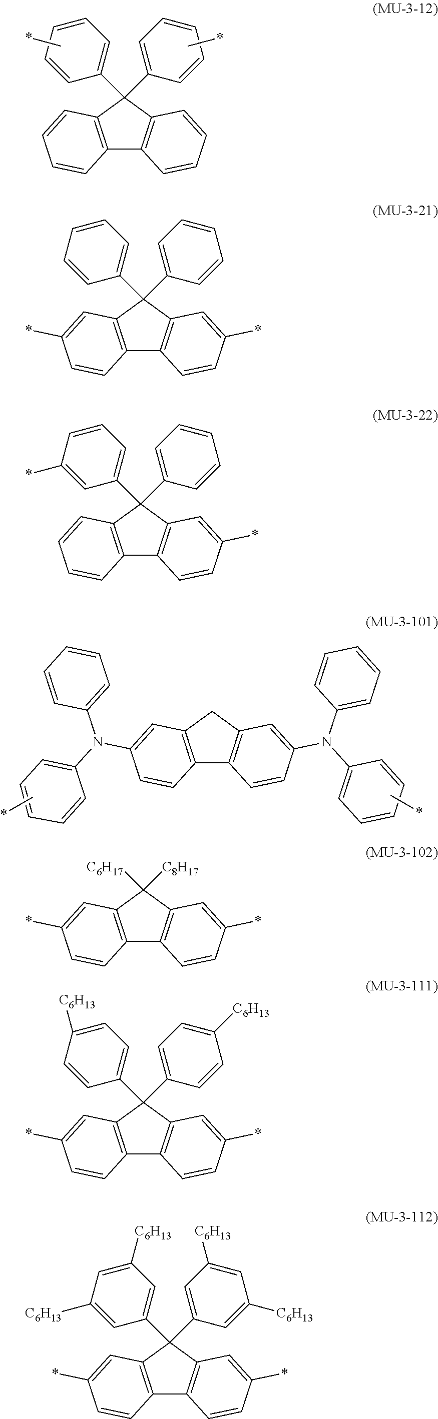

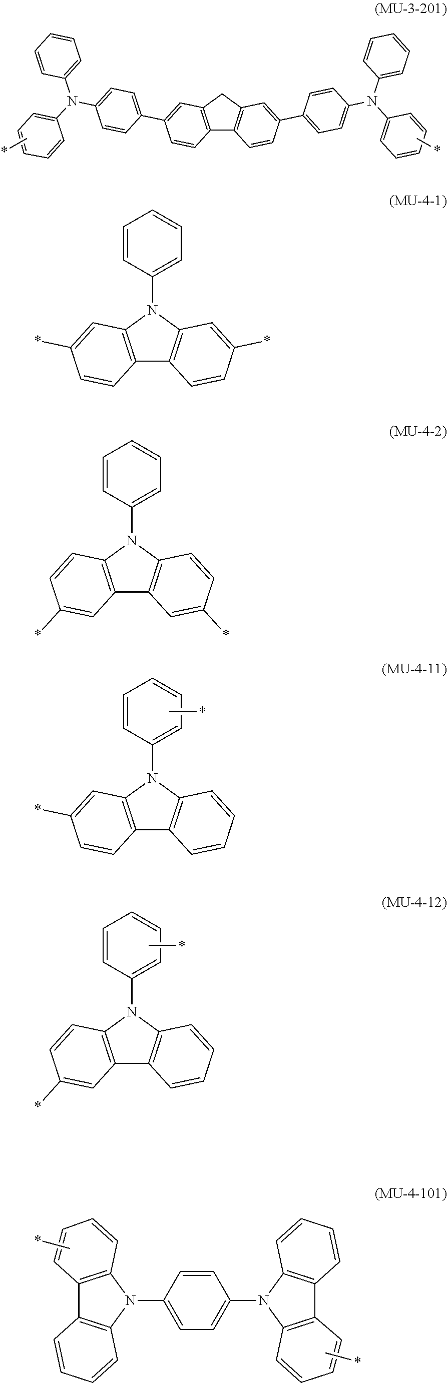

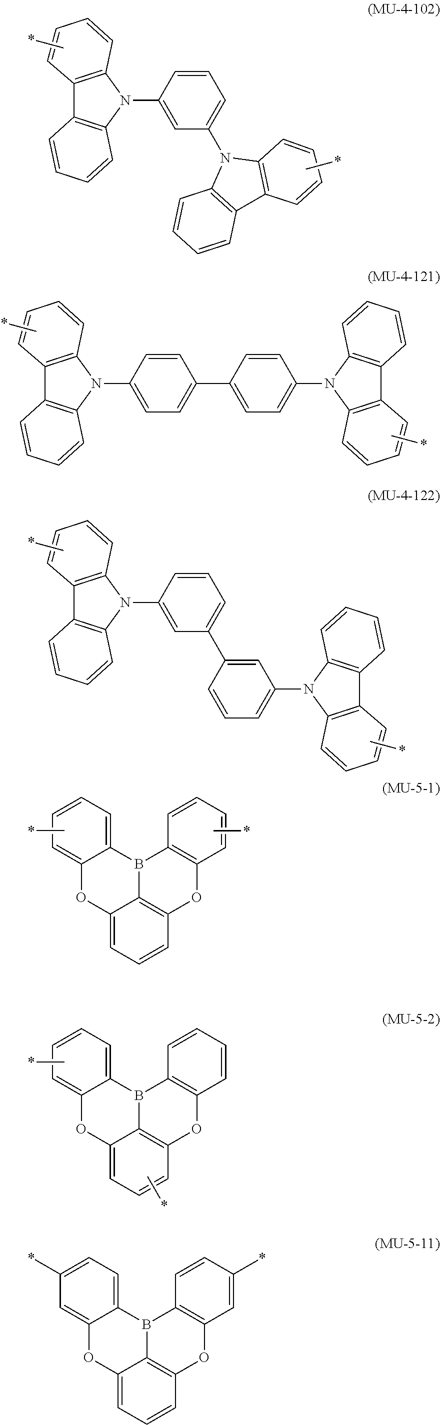

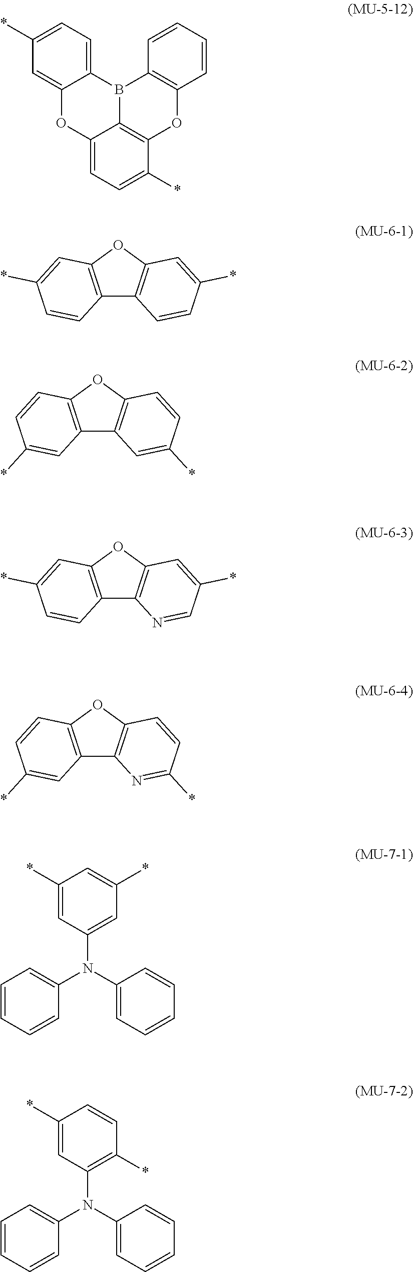

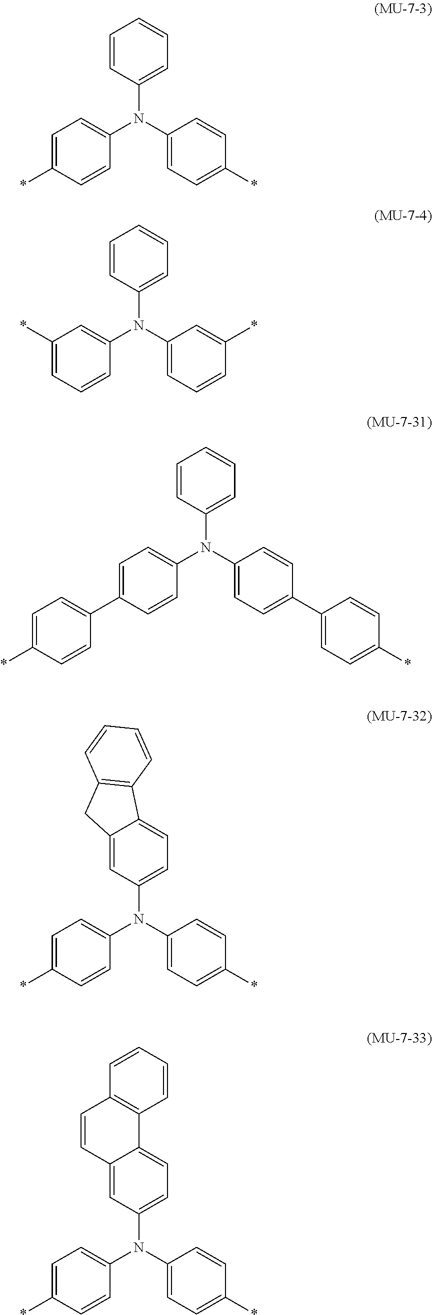 [SMILES: *c1ccc(N(c2ccccc2)c2ccc(*)cc2)cc1 ; *c1cccc(N(c2ccccc2)c2cccc(*)c2)c1 ; *c1ccc(-c2ccc(N(c3ccccc3)c3ccc(-c4ccc(*)cc4)cc3)cc2)cc1 ; *c1ccc(N(c2ccc(*)cc2)c2ccc3c(c2)Cc2ccccc2-3)cc1 ; *c1ccc(N(c2ccc(*)cc2)c2ccc3c(ccc4ccccc43)c2)cc1]

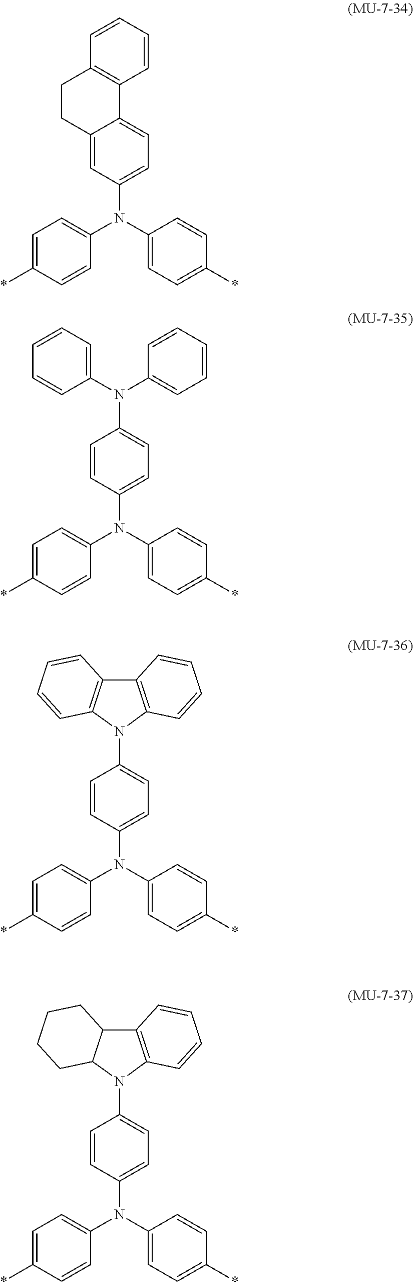

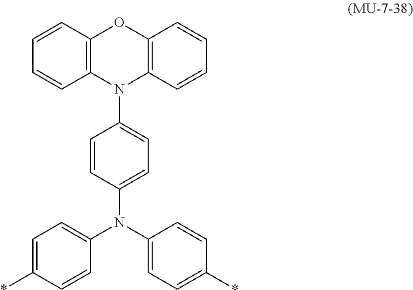 [SMILES: *c1ccc(N(c2ccc(*)cc2)c2ccc(N3c4ccccc4Oc4ccccc43)cc2)cc1]

Further, as EC, an example includes a monovalent group represented by any of the following structures. In these substituents, EC binds to MU at *.

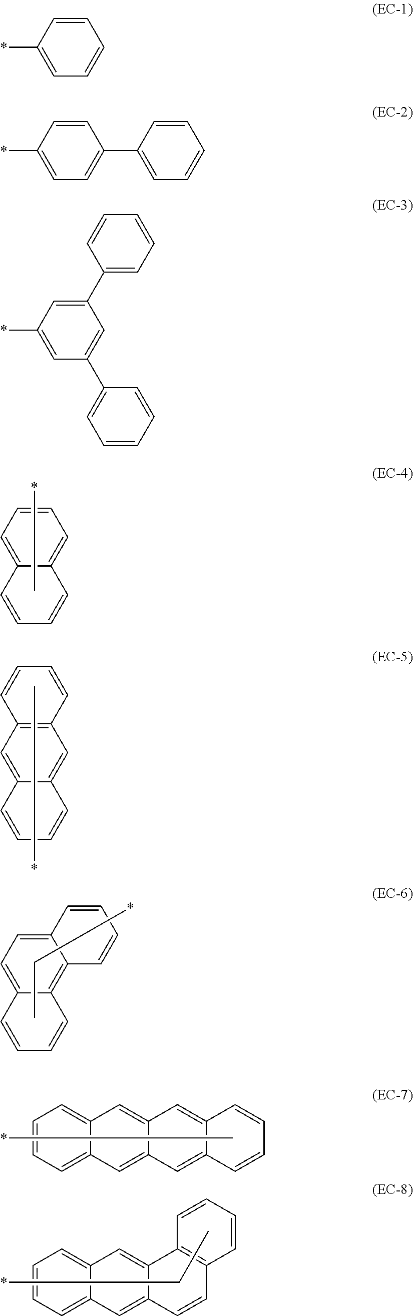

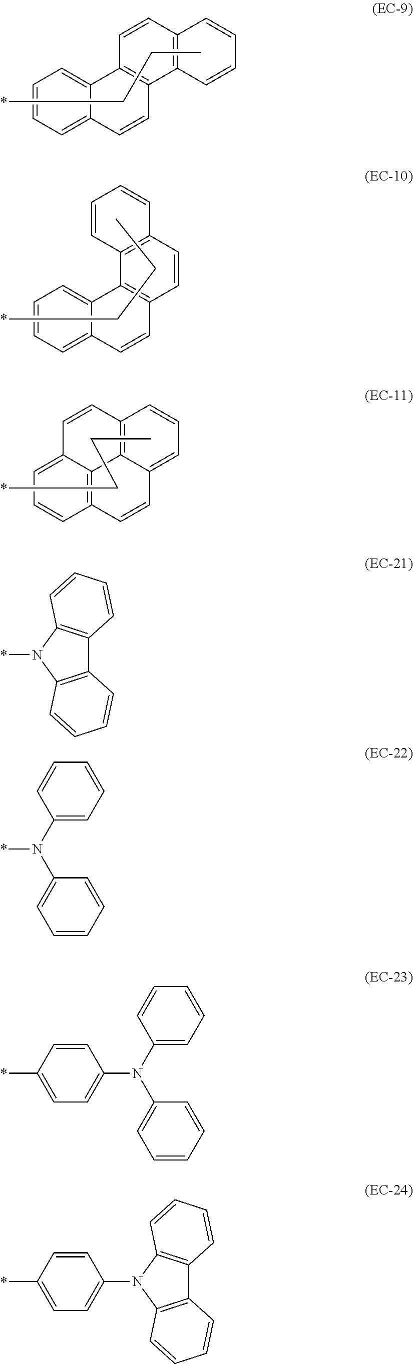

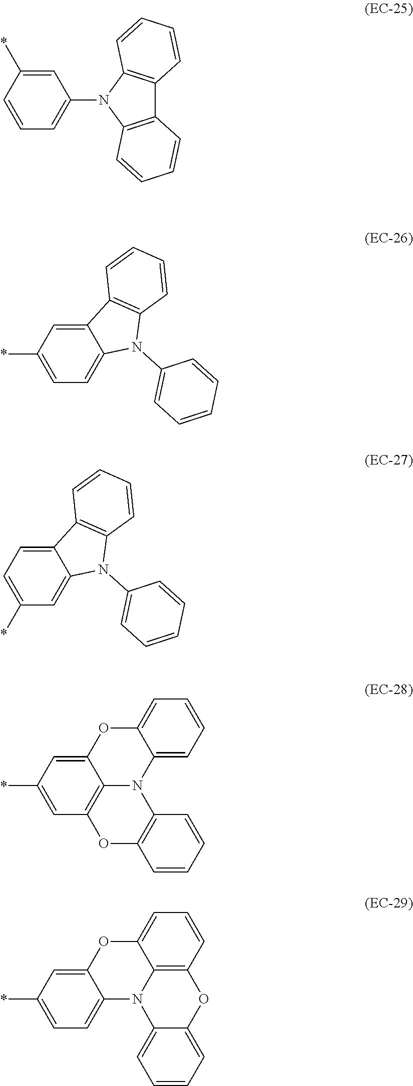

From the viewpoint of solubility and coating formability, the compound represented by formula (SPH-1) preferably has an alkyl having 1 to 24 carbons in an MU of 10 to 100% of the total number of MU (k) in the molecule, more preferably, an MU having 30 to 100% of the total number of MU (k) in the molecule has an alkyl having 1 to 18 carbons (branched chain alkyl having 3 to 18 carbons), and still more preferably, an MU having 50 to 100% of the total number of MU (k) in the molecule has an alkyl having 1 to 12 carbons (branched chain alkyl having 3 to 12 carbons). On the other hand, from the viewpoint of in-plane orientation and charge transport, it is preferable that an MU of 10 to 100% of the total number of MU (k) in the molecule has an alkyl having 7 to 24 carbons, and it is more preferable that an MU of 30 to 100% of the total number of MU (k) in the molecule has an alkyl having 7 to 24 carbons (branched chain alkyl having 7 to 24 carbons).

### Light Emitting Layer Containing an Assisting Dopant and an Emittine Dopant

The light-emitting layer in the organic electroluminescent element may include a host compound as a first component, an assisting dopant (compound) as a second component, and an emitting dopant (compound) as a third component.

The poly cyclic aromatic compound of the present invention is also preferably used as an emitting dopant.

As the assisting dopant (compound), a thermally assisting delayed fluorescent material can be used.

In the following explanation, an organic electroluminescent element using a thermally assisting delay phosphor as an assisting dopant is sometimes referred to as a “TAF element” (TADF Assisting Fluorescence element).

The “host compound” in the TAF element means a compound in which the excited singlet energy level obtained from the shoulder on the short wavelength side of the peak of the fluorescence spectrum is higher than that of the thermally assisting delayed fluorescent material as the second component and that of the emitting dopant as the third component.

“Thermally assisting delayed phosphor” means a compound capable of absorbing thermal energy to cause an inverse intersystem crossing from an excited triplet state to an excited singlet state, and radiatively deactivating from the excited singlet state to emit delayed fluorescence. However, the term “thermally assisting delayed fluorescence” includes those that undergo higher-order triplet in the excitation process from the excited triplet state to the excited singlet state. For example, there are a paper by Monkman et al. of Durham University (NATURE COMMUNICATIONS, 7:13680, DOI:10.1038/ncomms13680), a paper by Hosokai et al, of National Institute of Advanced Industrial Science and Technology (Sci. Adv. 2017;3: e1603282), a paper by Sato et al. of Kyoto University (Scientific Reports, 7:4820, DOI:10.1038/s41598-017-05007-7), and a presentation by Sato et al. of Kyoto University (Japan Chemical Society's 98th Spring Annual Meeting, Presentation Number: 214-15, Mechanism of high-efficiency luminescence in organic electroluminescence using DABNA as a luminescent molecule, Graduate School of Engineering, Kyoto University), etc. In the present invention, a. sample containing a target compound is analyzed to measure the fluorescence lifetime at 300K, and when the sample gives a delayed fluorescence component, the target compound therein is determined to be a “thermally assisting delayed fluorescent material.” Here, a delayed fluorescent component refers to a component having a fluorescence lifetime of 0.1 ₗisec or longer. The fluorescence lifetime may be measured by, for example, a fluorescence lifetime measurement device (C11367-01; a product of Hamamatsu Photonics K.K.).

The polycyclic aromatic compound of the present invention can function as an emitting dopant, and the “thermally assisting delayed fluorescent material” can function as an assisting dopant which assists in light emission of the polycyclic aromatic compound of the present invention.

FIG. 2 shows the energy level diagram of the light-emitting layer of a TAF element using a common fluorescent dopant as an emitting dopant (ED). In the figure, E(1,G) is the energy level of the ground state of the host, E(1,S,Sh) is the excited singlet energy level determined from the short wavelength side of the fluorescence spectrum of the host. E(1,T,Sh) is the excited triplet energy level determined from the short wavelength side of the phosphorescence spectrum of the host, E(2,G) is the energy level of the ground state of the assisting dopant as the second component, E(2,S,Sh) is the excited singlet enemy level determined from the short wavelength side of the fluorescence spectrum of the assisting dopant as the second component, E(2,T,Sh) is the excited triplet energy level determined from the short wavelength side of the phosphorescence spectrum of the assisting dopant as the second component, E(3,G) is the energy level of the ground state of the emitting dopant, E(3,S,Sh) is the excited singlet energy level determined from the short wavelength side of the fluorescence spectrum of the emitting dopant as the third component, E(3,T,Sh) is the excited triplet energy level determined from the short wavelength side of the phosphorescence spectrum of emitting dopant as the third component, “h+” is a hole, “e+” is an electron, FRET is Fluorescence Resonance Energy Transfer, When a common fluorescent dopant is used as an emitting dopant (ED) in a TAF element, the energy upconverted by the assisting dopant moves to the excited singlet energy level E(3,S,Sh) of the emitting dopant, leading to light emission. However, a part of the excited triplet energy E(2,T,Sh) on the assisting dopant moves to the excited triplet energy level E(3,T,Sh) of the emitting dopant, or intersystem crossing from the excited singlet energy level E(3,S,Sh) to the excited triplet energy level E(3,T,Sh) occurs on the emitting dopant, followed by thermal deactivation to the ground state E(3,G). Due to this pathway, a part of energy is not used for light emission, and energy is wasted.

On the other hand, in the organic electroluminescence element of the present embodiment, the energy transferred from the assisting dopant to the emitting dopant can he efficiently used for light emission, whereby high light emission efficiency can be realized. This is presumed to be due to the following light emission mechanism.

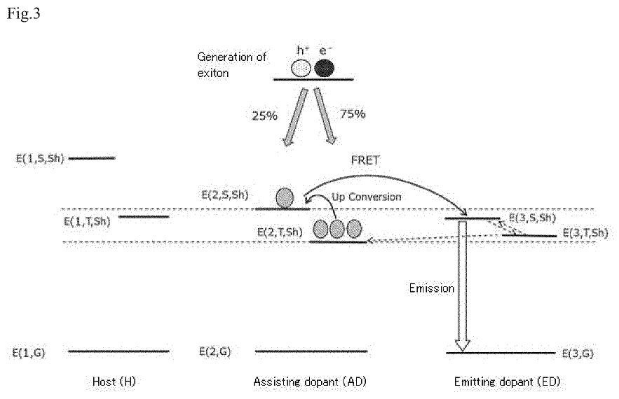

FIG. 3 shows a preferable energy relationship in the organic electroluminescent element of this aspect. In the organic electroluminescent element of this aspect, a compound having a boron atom as an emitting dopant has a high excited triplet energy level E(3,T,Sh). Therefore, even when the excited singlet energy up-converted with the assisting dopant undergo an intersystem crossing to the excited triplet energy level E(3,T,Sh) with the emitting dopants, it will be up-converted on the emitting dopants or recovered to the excited triplet energy level E(2,T,Sh) on the assisting dopants (thermally assisting delayed fluorescent material). Therefore, the generated excitation energy can be used for light emission without waste. Further, by dividing the functions of upconversion and emission into two kinds of molecules, each of which is good at each other, it is expected that the residence time of high energy is reduced and the burden on the compound is reduced.

In this aspect, as the host compound, a known compound can be used, and examples thereof include a compound having at least one of a carbazole ring and a furan ring, and among them, a compound in which at least one of (uranyl and carbazolyl and at least one of an arylene and a heteroarylene are bonded is preferably used. Specific examples include mCP and mCBP.

The excited triplet energy level E(1,T,Sh) determined from the short-wavelength-side shoulder of the phosphorescence spectrum of the host compound is preferably higher than the excited triplet energy level E(2,T,Sh), E(3,T,Sh) of the emitting dopant or assisting dopant having the highest excited triplet energy level in the light emitting layer from the viewpoint of promoting without inhibiting the generation of TADF in the light emitting layer, and specifically, the excited triplet energy level E(1,T,Sh) of the host compound is preferably 0.01 eV or higher, more preferably 0.03 eV or higher, more preferably 0.1 eV or higher than E(2,T,Sh), E(3,T,Sh), Further, a TADF active compound may be used as the host compound.

For example, a compound represented by any one of the above formulas (H1), (H2) and (H3) can he used as the host compound.

### <Thermally Assisting Delay Phosphor (Assisting Dopant)>

The thermally assisting delayed fluorescent material (TADF compound) used in the TAF element is preferably a donor-acceptor type thermally assisting delayed phosphor (D-A type TADF compound) designed to localize an intramolecular HOMO(Highest Occupied Molecular Orbital) and LUMO(Lowest Unoccupied Molecular Orbital) using an electron-donating substituent called as a donor and an electron-accepting substituent called as an acceptor to cause an efficient reverse intersystem crossing.

In this specification, “electron donating substituent” (donor) means a substituent and a partial structure in which a HOMO orbital is localized in a thermally assisting delayed fluorescent material molecule, and “electron accepting substituent” (acceptor) means a substituent and a partial structure in which a LUMO orbital is localized in a thermally assisting delayed phosphor molecule.

Generally, a thermally assisting delayed fluorescent material that uses donor and acceptor has a large spin orbital bond (SOC: Spin Orbit Coupling) due to the structure thereof, shows low exchange interaction between the HOMO and the LUMO, and has a small ΔE_{ST}. Thus, a very large inverse intersystem crossing rate can be achieved. Meanwhile, a thermally assisting delayed fluorescent material that uses donor and acceptor shows large structural relaxation in an excited state (since a stable structure in a ground state differs from that in an excited state in a, certain molecule, when a conversion from a ground state to an excited state by stimulation from the exterior occurs, the structure thereafter changes into a stable structure in an excited state) and shows a wide light emission spectrum. Thus, a thermally assisting delayed fluorescent material may deteriorate the color purity when used as a light-emitting material.

As the thermally assisting delayed fluorescent material in TAF element, a compound in which a donor and an acceptor bind to each other directly or via a spacer can be used, for example. As an electron donating group (the donor-type structure) and an electron accepting group (the acceptor-type structure) for use in the thermally assisting delayed fluorescent material in the present invention, for example, the structures described in Chemistry of Materials, 2017, 29, 1946-1963 are also usable. The donor-type structure includes carbazole, dimethylcarbazole, di-tert-butylcarbazole, dimethoxycarbazole, tetramethylcarbazole, benzofluorocarbazole, benzothienocarbazole, phenyldihydroindolocarbazole, phenylbicarbazole, bicarbazole, tercarbazole, diphenylcarbazolylamine, tetraphenylcarbazolyldiamine, phenoxazine, dihydrophenazine, phenothiazine, dimethvldihydroacridine, diphenylamine, bis(tert-butylphenyDamine, N1-(4-(diphenylamino) phenyl)-N4,N4-diphenybenzene-1,4-diamine, dimethyltetraphenyldroacridinediamine, tetramethyl-dihydro-indenoacridine and diphenyl-dihydrodibenzazaserine. The acceptor-type structure includes sulfonyldibenzene, benzophenone, phenylenebis(phenylmethanone), benzonitrile, isonicotinonitrile, phthalonitrile, isophthalonitrile, paraphthalonitrile, benzenetricarbonitrile, triazole, oxazole, thiadiazole, henzothiazole, benzobis(thiazole), benzoxazole, benzobis(oxazole), quinoline, benzimidazole, dibenzoquinoxaline, heptaazaphenalene, thioxanthene dioxide, dimethylanthrazene, anthracenedione, 5H-cyclopenta[1,2-b:5,4-b′]dipyridine, fluorenedicarbonitrile, triphenyltriazine, pyrazinecarbonitrile, pyrimidine, phenylpyrimidine, methylpyrimidine, pyridinedicarbonitrile, dibenzoquinoxalinedicarbonitrile, bis(phenylsulfonyl)benzene, dimethylthioxanthone dioxide, thianthrene tetroxide and tris(dimethylphenyl)borane. In particular, the thermally assisting delayed fluorescent compound in TAF element is preferably a compound having, as a partial structure, at least one selected from the group consisting of carbazole, phenoxazine, acridine, triazine, pyrimidine, pyrazine, thioxanthene, benzonitrile, phthalonitrile, isophthalonitrile, diphenyl sulfone, triazole, oxadiazole, thiadiazole and benzophenone.

The compound for use as the second component in the light-emitting layer in TAF element is preferably a thermally assisting delayed fluorescent material whose emission spectrum overlaps at least partly with the absorption peak of an emitting dopant. Hereinafter, compounds that can be used as he second component in the light-emitting layer in TAF element (a thermally assisting delayed fluorescent material) will be exemplified. However, the compounds that can be used as a thermally assisting delayed fluorescent material in TAF element are not limitedly interpreted by the following exemplary compounds. In the following formulas, Me represents a methyl, tBu represents a t-butyl, Ph represents a phen and the wavy line indicates a bonding position.

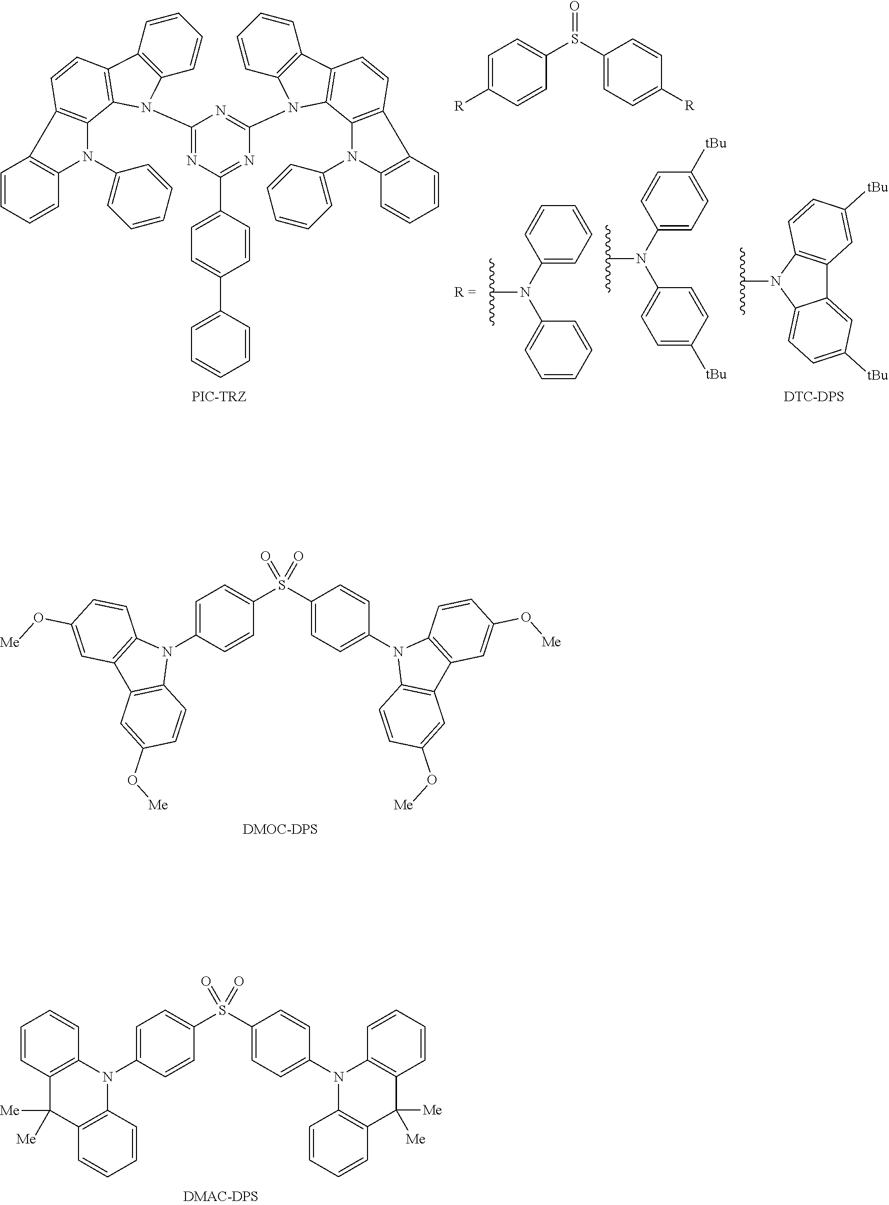

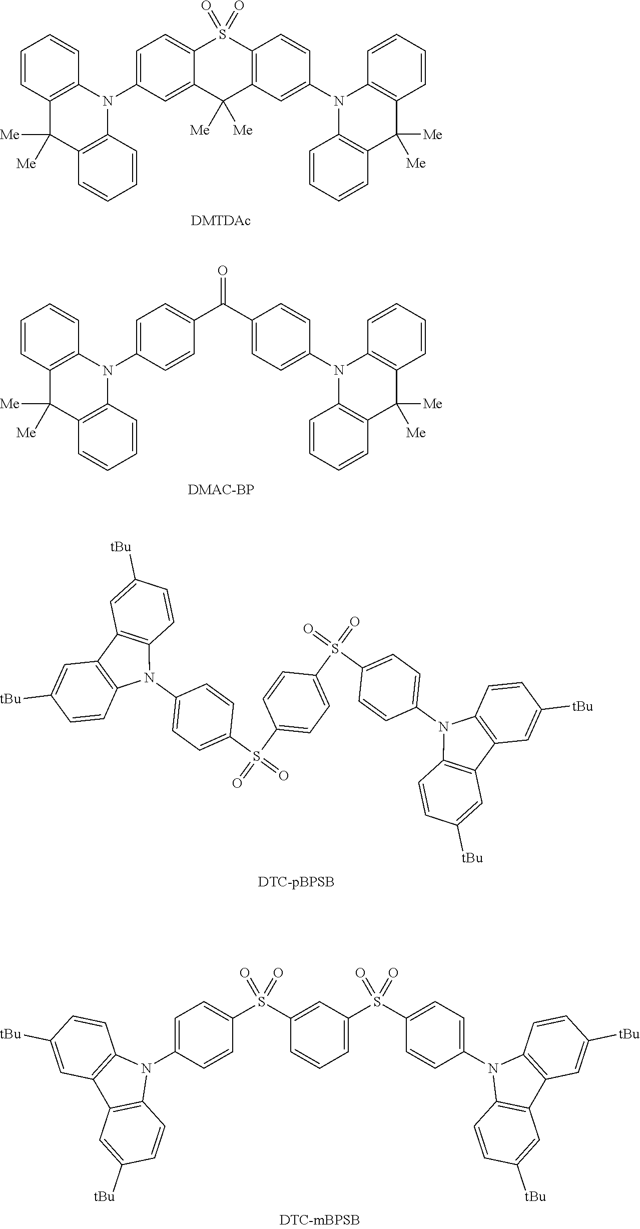

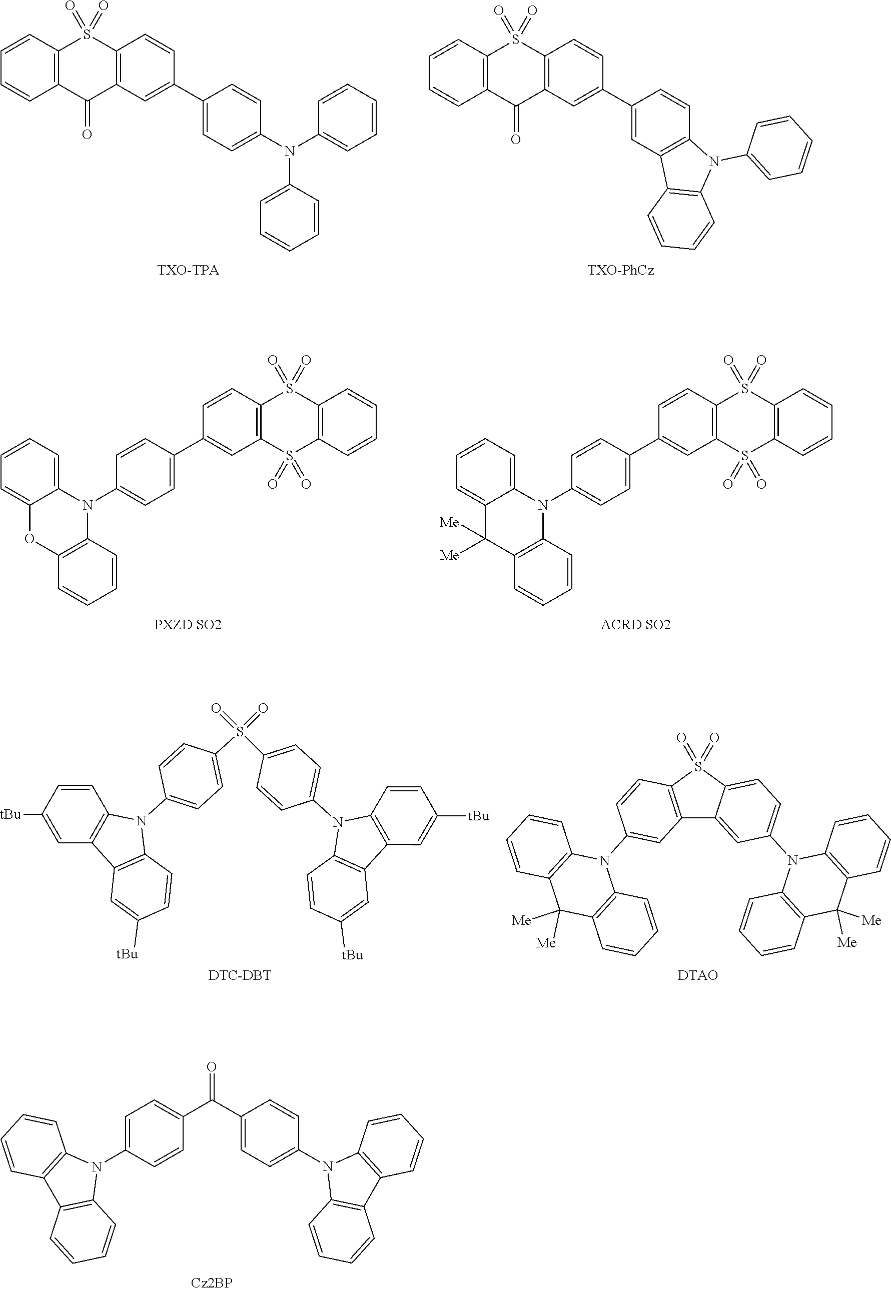

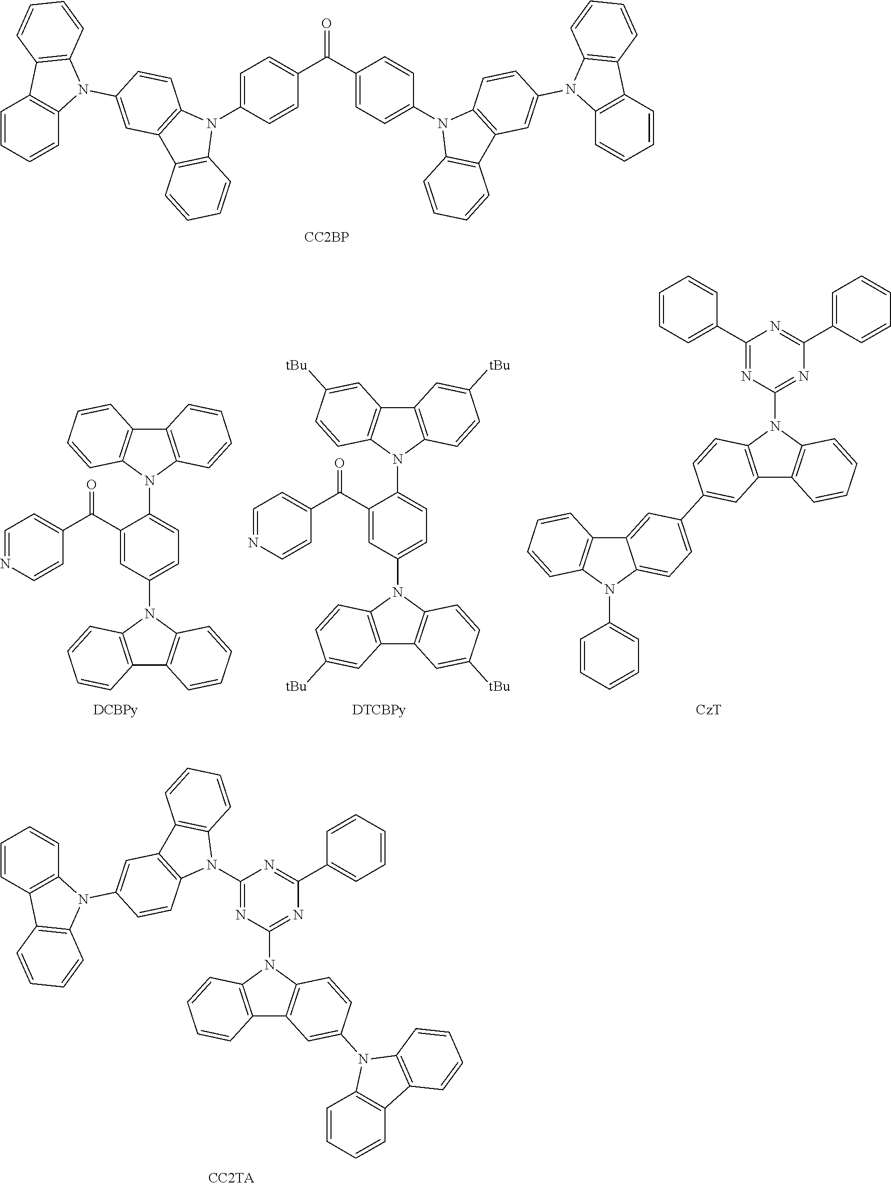

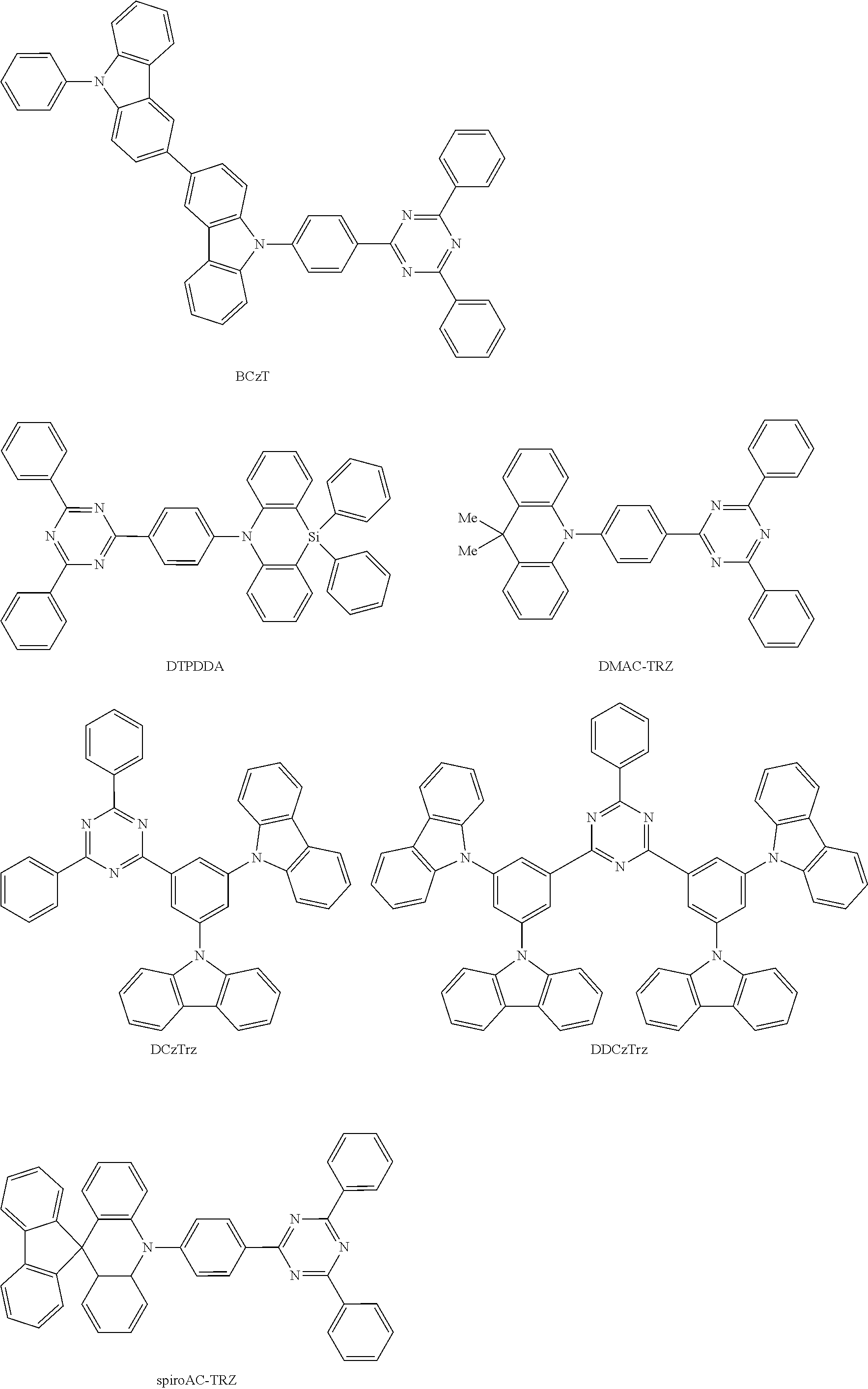

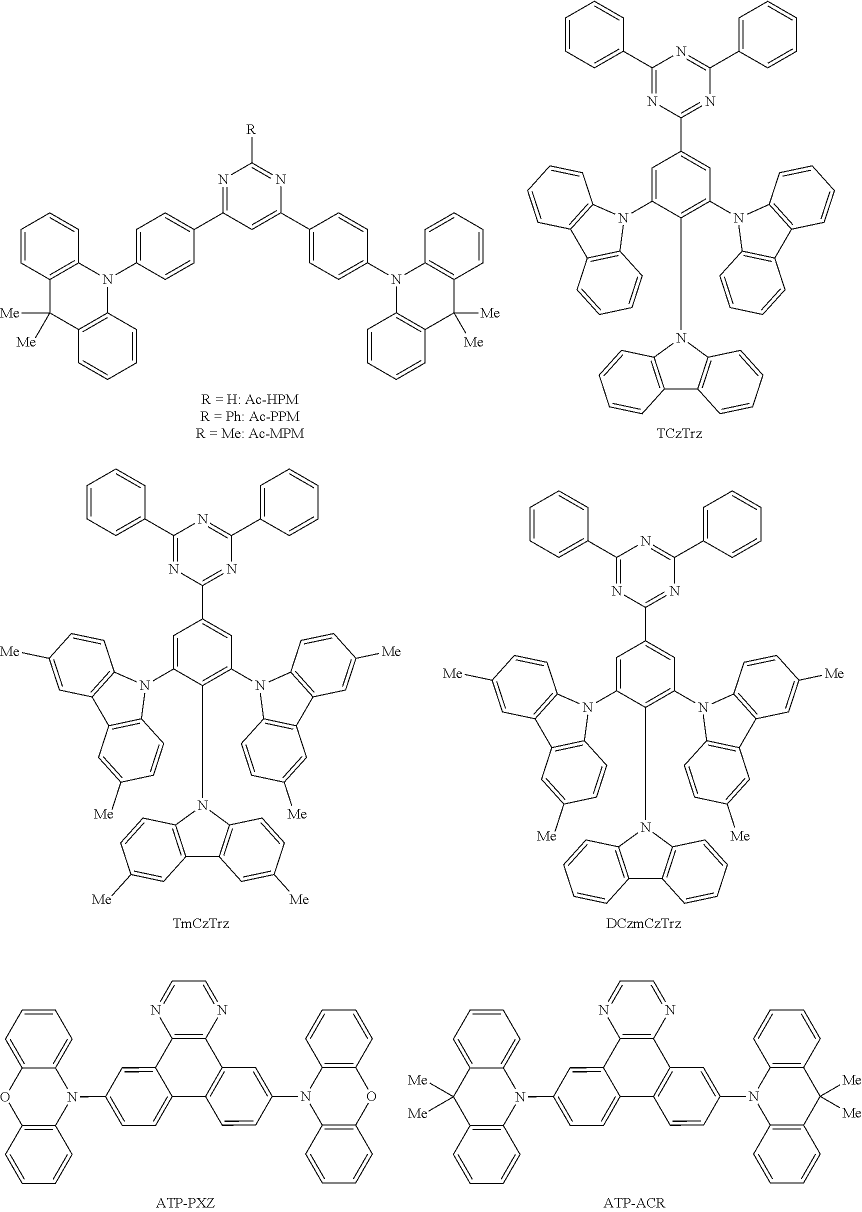

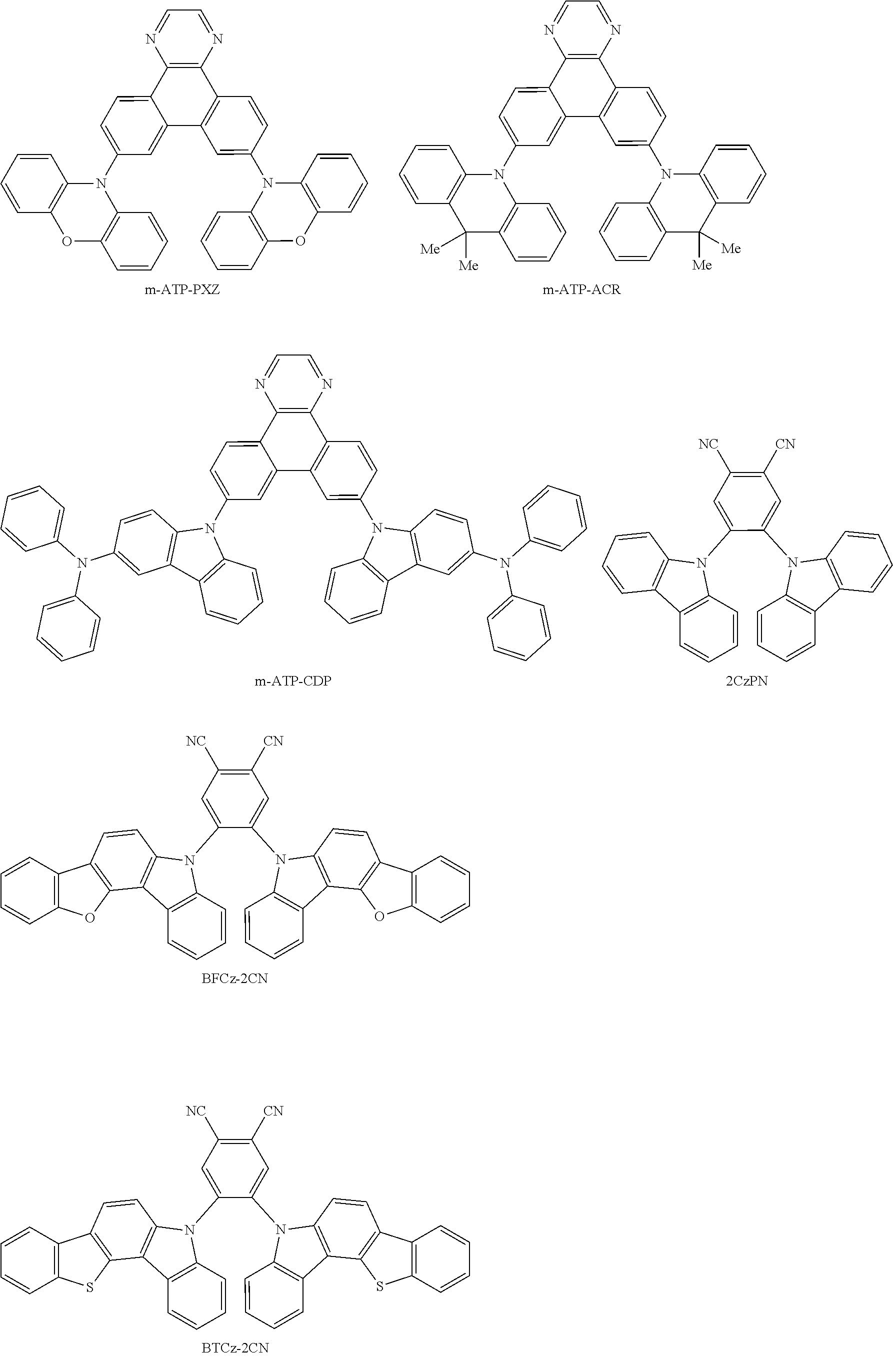

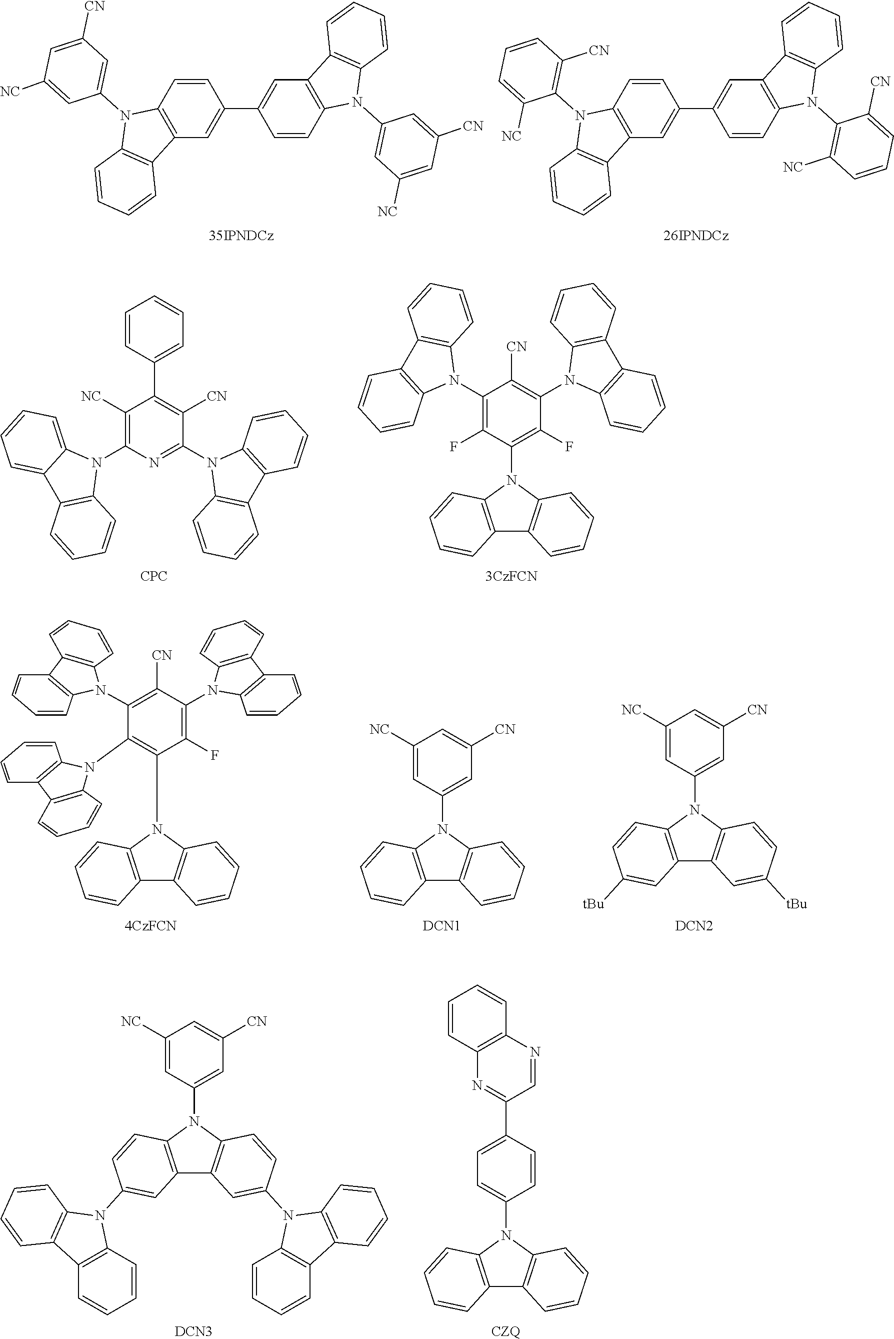

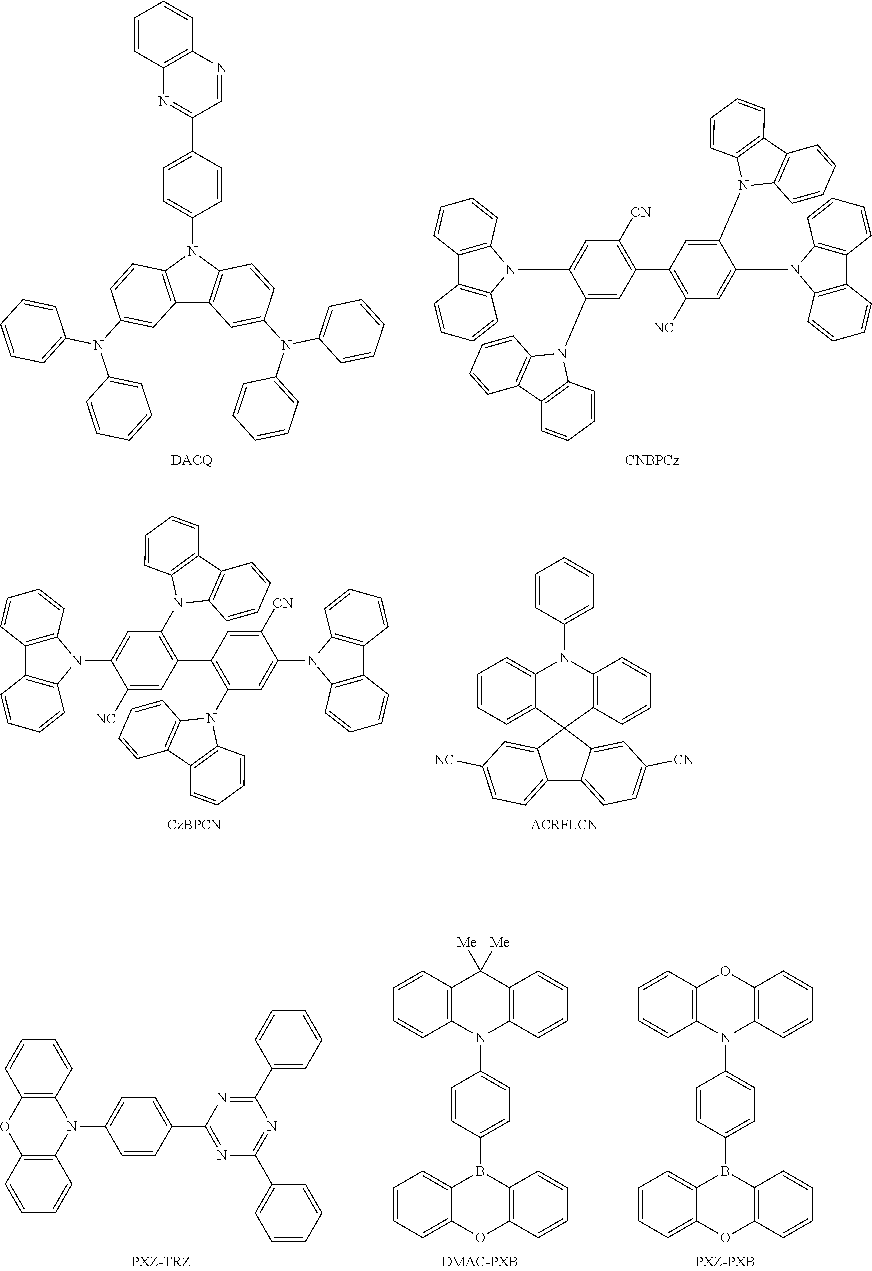

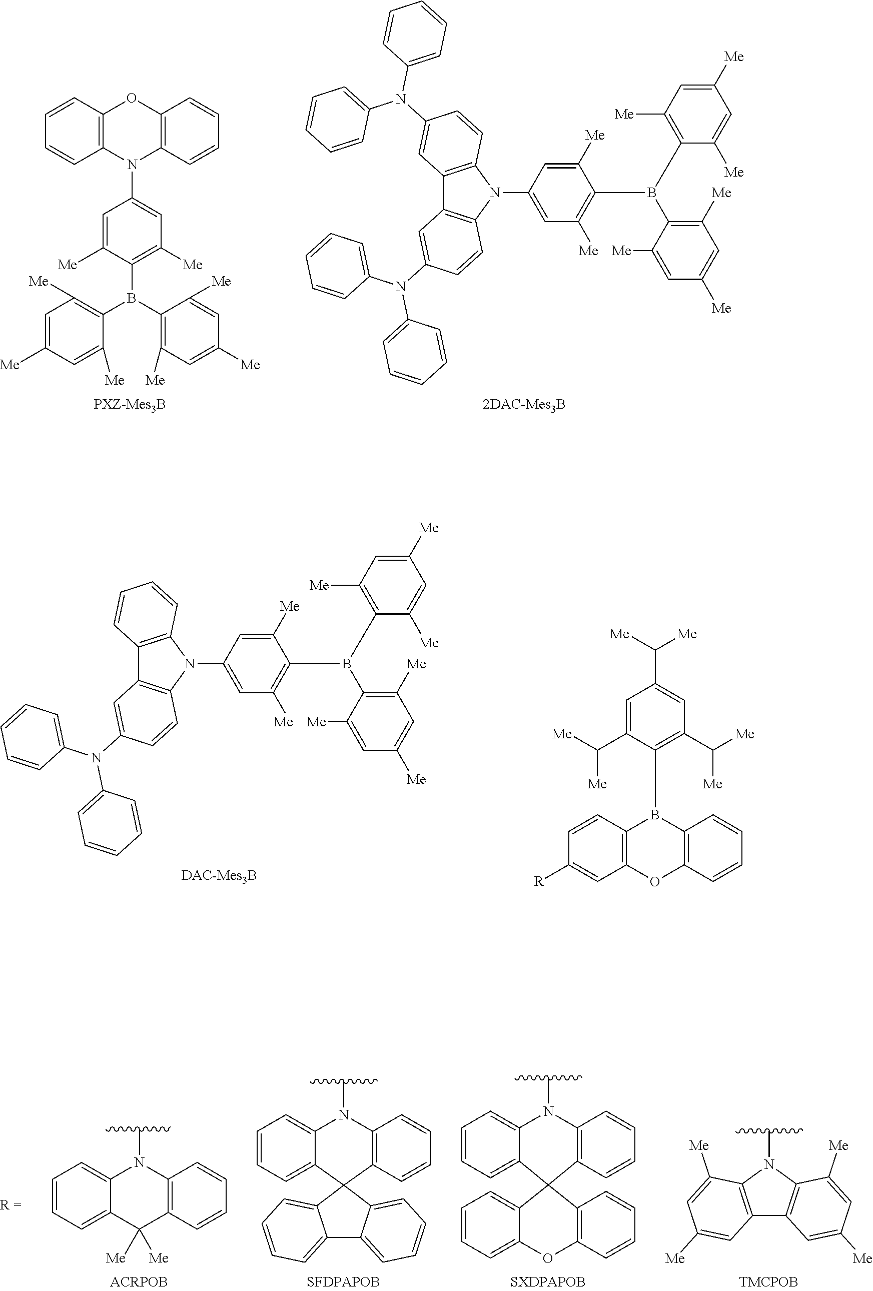

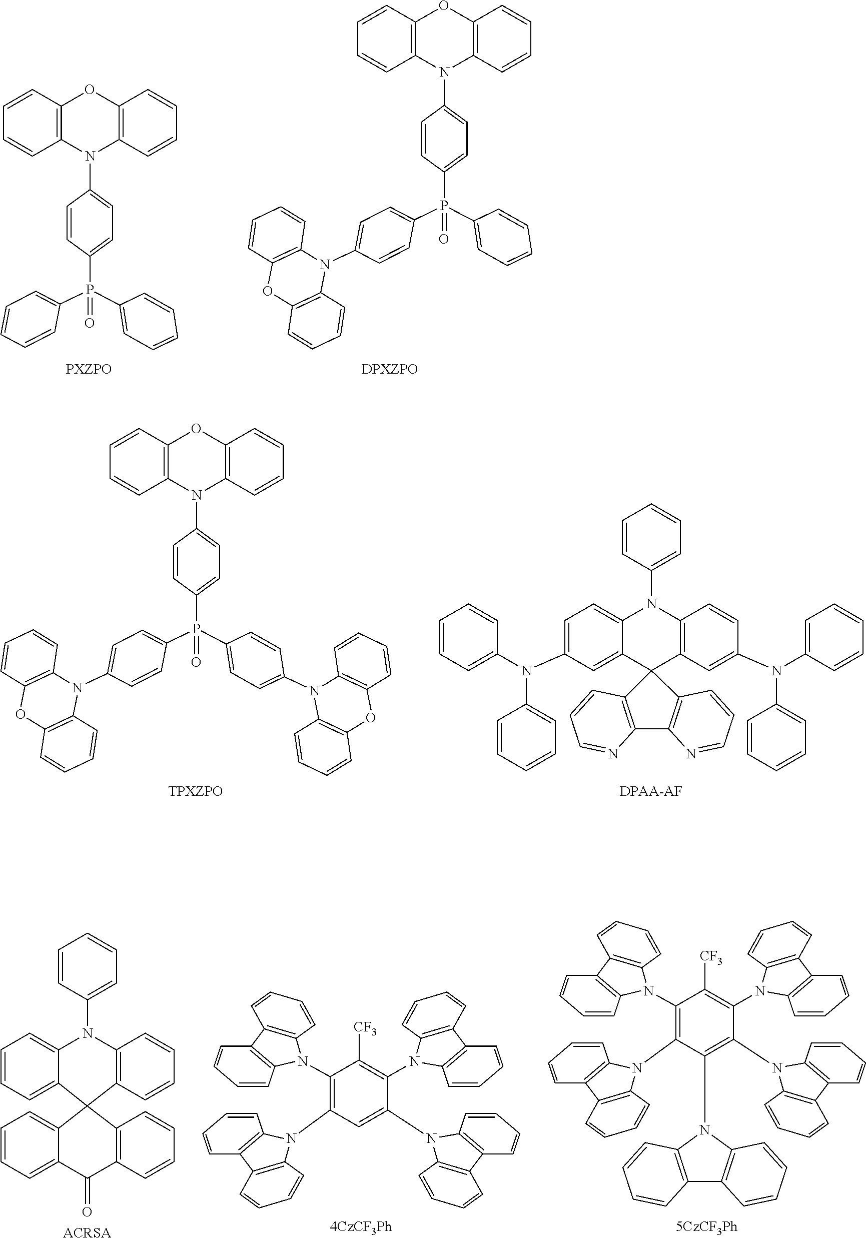

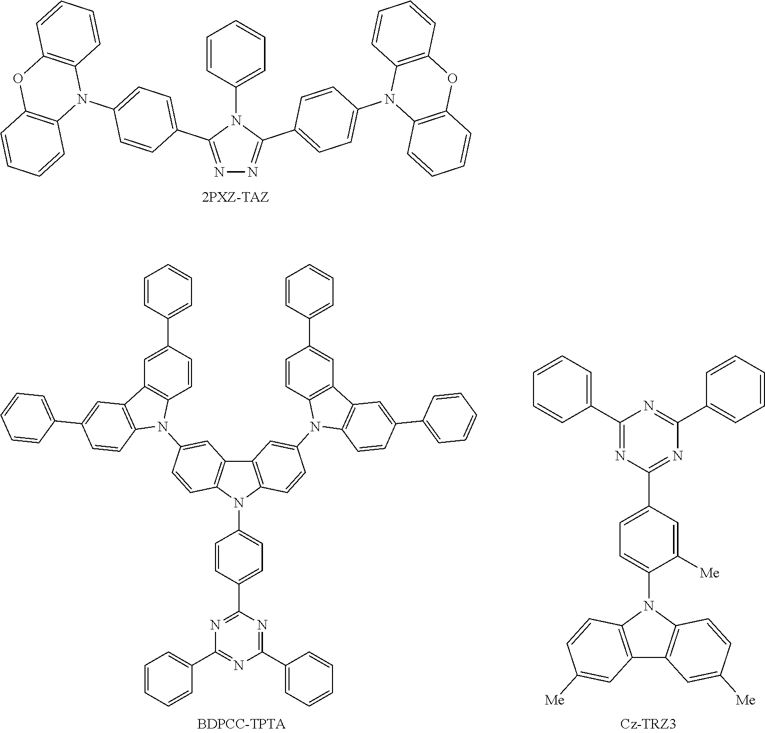 [SMILES: c1ccc(-n2c(-c3ccc(N4c5ccccc5Oc5ccccc54)cc3)nnc2-c2ccc(N3c4ccccc4Oc4ccccc43)cc2)cc1 ; c1ccc(-c2ccc3c(c2)c2cc(-c4ccccc4)ccc2n3-c2ccc3c(c2)c2cc(-n4c5ccc(-c6ccccc6)cc5c5cc(-c6ccccc6)ccc54)ccc2n3-c2ccc(-c3nc(-c4ccccc4)nc(-c4ccccc4)n3)cc2)cc1 ; Cc1ccc2c(c1)c1cc(C)ccc1n2-c1ccc(-c2nc(-c3ccccc3)nc(-c3ccccc3)n2)cc1C]

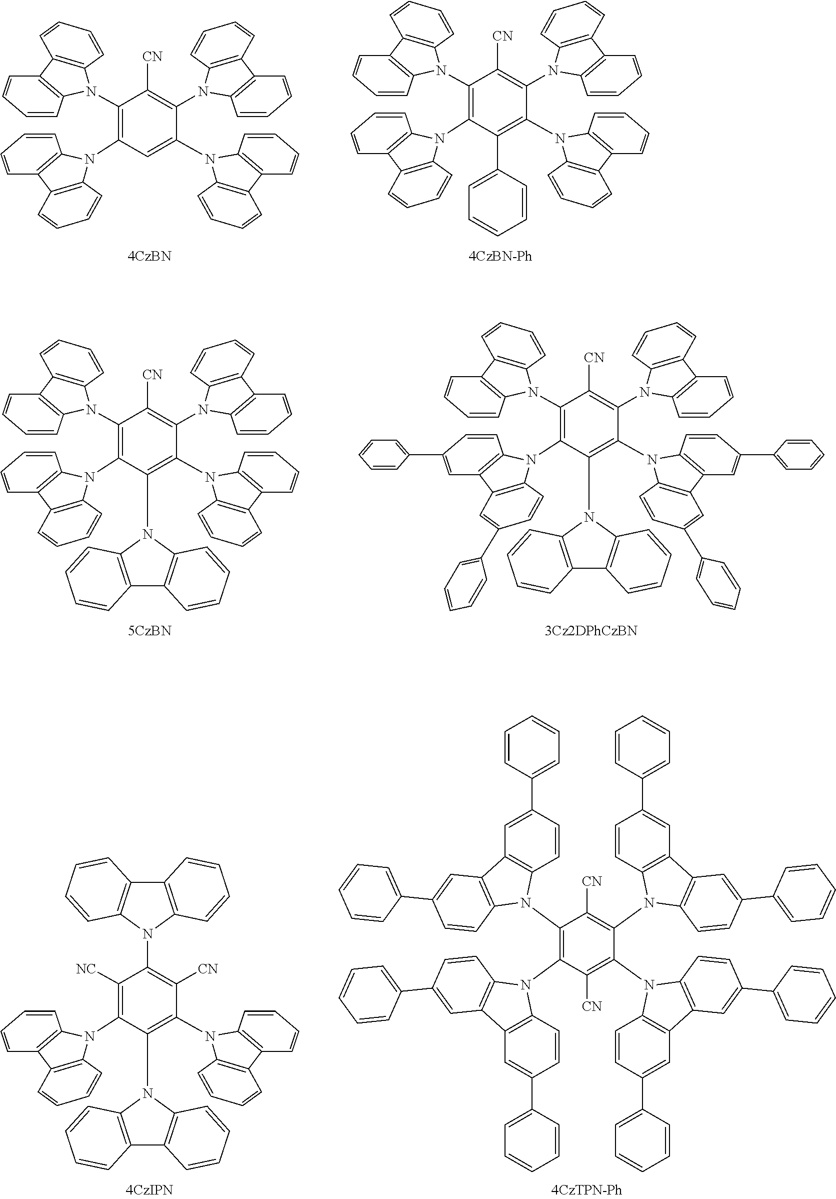

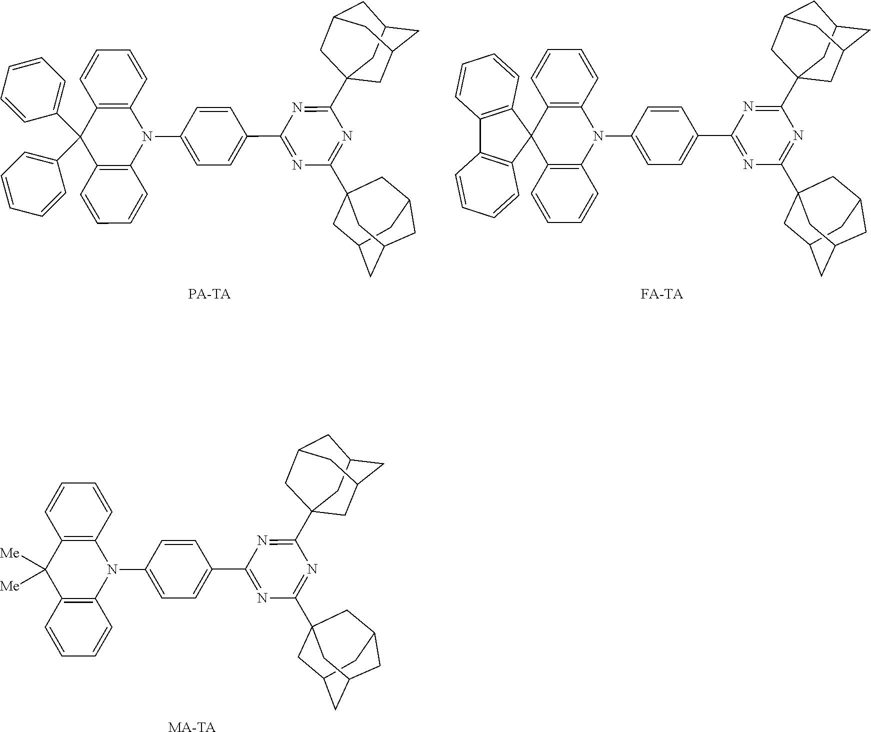

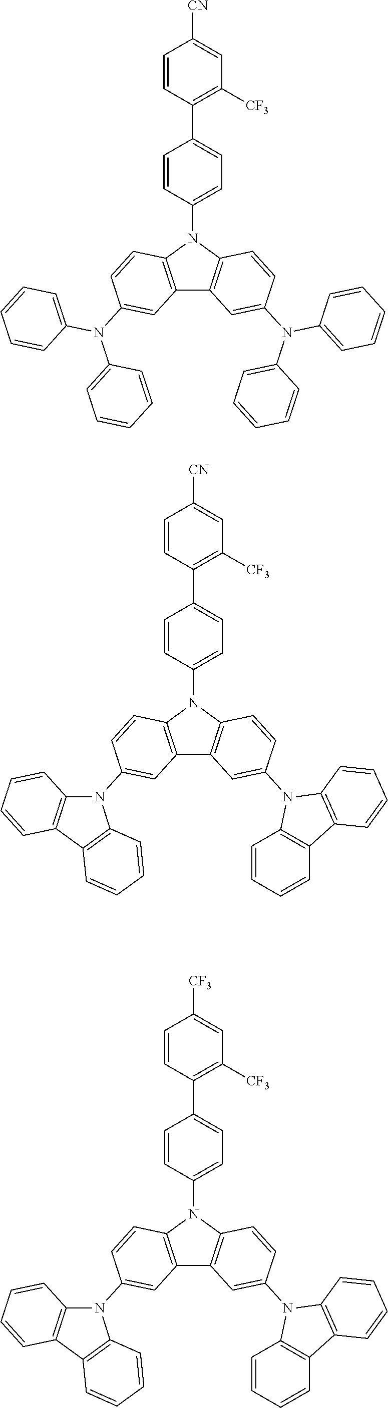 [SMILES: N#Cc1ccc(-c2ccc(-n3c4ccc(N(c5ccccc5)c5ccccc5)cc4c4cc(N(c5ccccc5)c5ccccc5)ccc43)cc2)c(C(F)(F)F)c1 ; N#Cc1ccc(-c2ccc(-n3c4ccc(-n5c6ccccc6c6ccccc65)cc4c4cc(-n5c6ccccc6c6ccccc65)ccc43)cc2)c(C(F)(F)F)c1 ; FC(F)(F)c1ccc(-c2ccc(-n3c4ccc(-n5c6ccccc6c6ccccc65)cc4c4cc(-n5c6ccccc6c6ccccc65)ccc43)cc2)c(C(F)(F)F)c1]

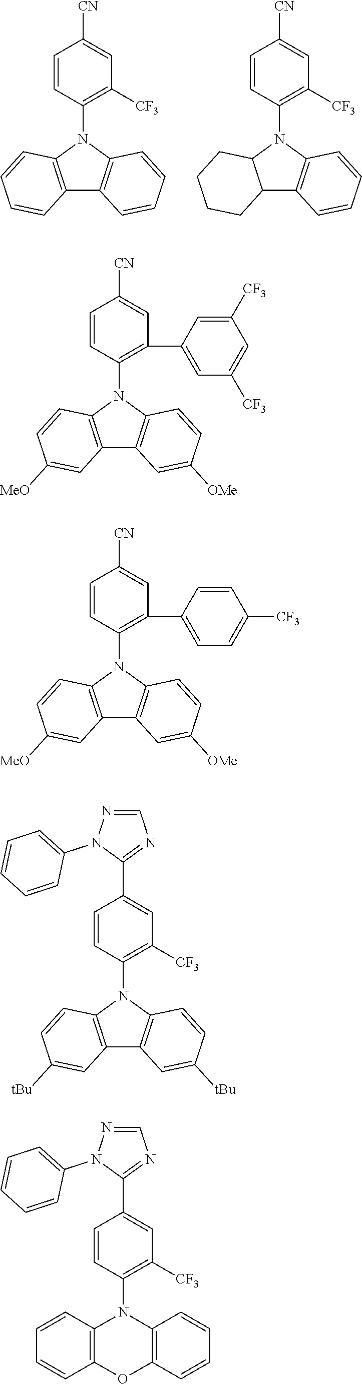

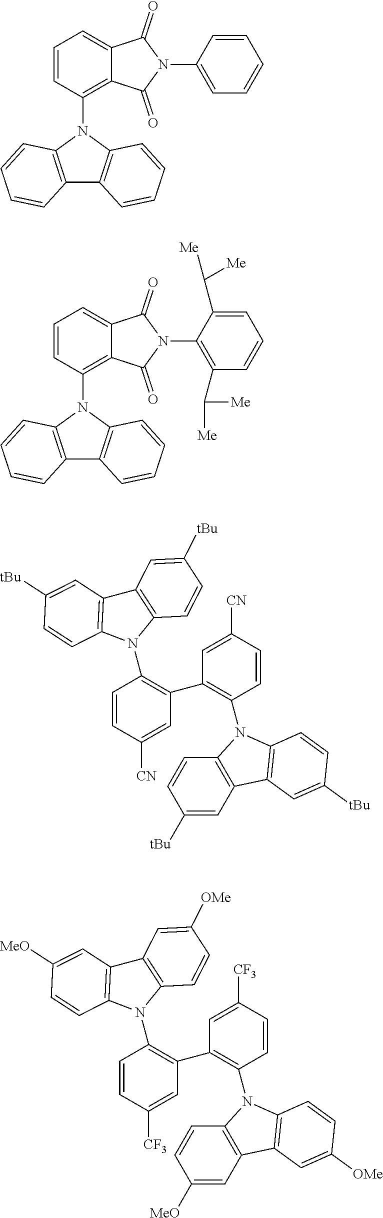 [SMILES: O=C1c2cccc(-n3c4ccccc4c4ccccc43)c2C(=O)N1c1ccccc1 ; CC(C)c1cccc(C(C)C)c1N1C(=O)c2cccc(-n3c4ccccc4c4ccccc43)c2C1=O ; CC(C)(C)c1ccc2c(c1)c1cc(C(C)(C)C)ccc1n2-c1ccc(C#N)cc1-c1cc(C#N)ccc1-n1c2ccc(C(C)(C)C)cc2c2cc(C(C)(C)C)ccc21 ; COc1ccc2c(c1)c1cc(OC)ccc1n2-c1ccc(C(F)(F)F)cc1-c1cc(C(F)(F)F)ccc1-n1c2ccc(OC)cc2c2cc(OC)ccc21]

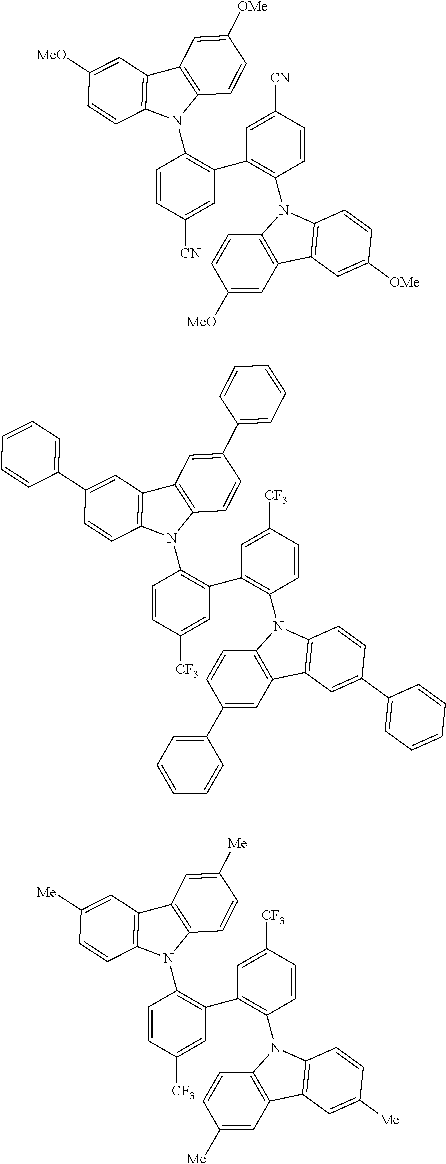 [SMILES: COc1ccc2c(c1)c1cc(OC)ccc1n2-c1ccc(C#N)cc1-c1cc(C#N)ccc1-n1c2ccc(OC)cc2c2cc(OC)ccc21 ; FC(F)(F)c1ccc(-n2c3ccc(-c4ccccc4)cc3c3cc(-c4ccccc4)ccc32)c(-c2cc(C(F)(F)F)ccc2-n2c3ccc(-c4ccccc4)cc3c3cc(-c4ccccc4)ccc32)c1 ; Cc1ccc2c(c1)c1cc(C)ccc1n2-c1ccc(C(F)(F)F)cc1-c1cc(C(F)(F)F)ccc1-n1c2ccc(C)cc2c2cc(C)ccc21]

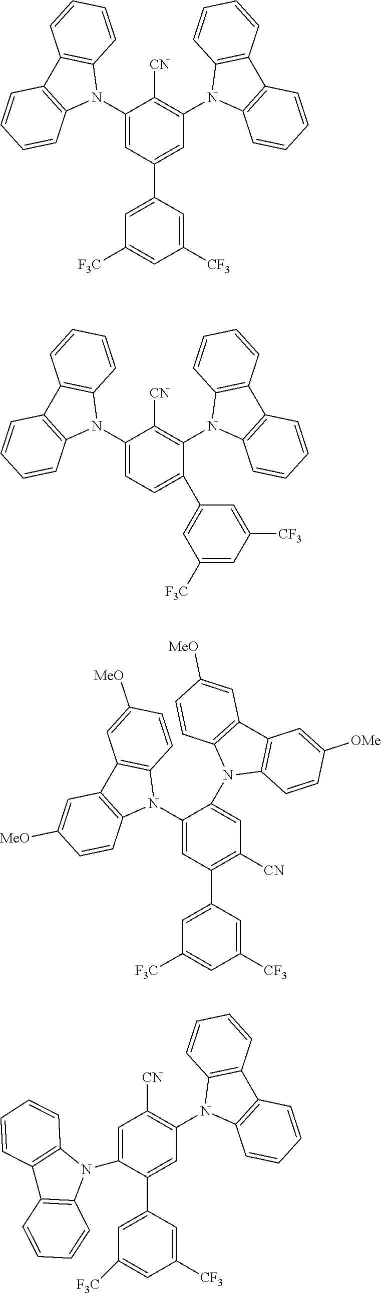 [SMILES: N#Cc1c(-n2c3ccccc3c3ccccc32)cc(-c2cc(C(F)(F)F)cc(C(F)(F)F)c2)cc1-n1c2ccccc2c2ccccc21 ; N#Cc1c(-n2c3ccccc3c3ccccc32)ccc(-c2cc(C(F)(F)F)cc(C(F)(F)F)c2)c1-n1c2ccccc2c2ccccc21 ; COc1ccc2c(c1)c1cc(OC)ccc1n2-c1cc(C#N)c(-c2cc(C(F)(F)F)cc(C(F)(F)F)c2)cc1-n1c2ccc(OC)cc2c2cc(OC)ccc21 ; N#Cc1cc(-n2c3ccccc3c3ccccc32)c(-c2cc(C(F)(F)F)cc(C(F)(F)F)c2)cc1-n1c2ccccc2c2ccccc21]

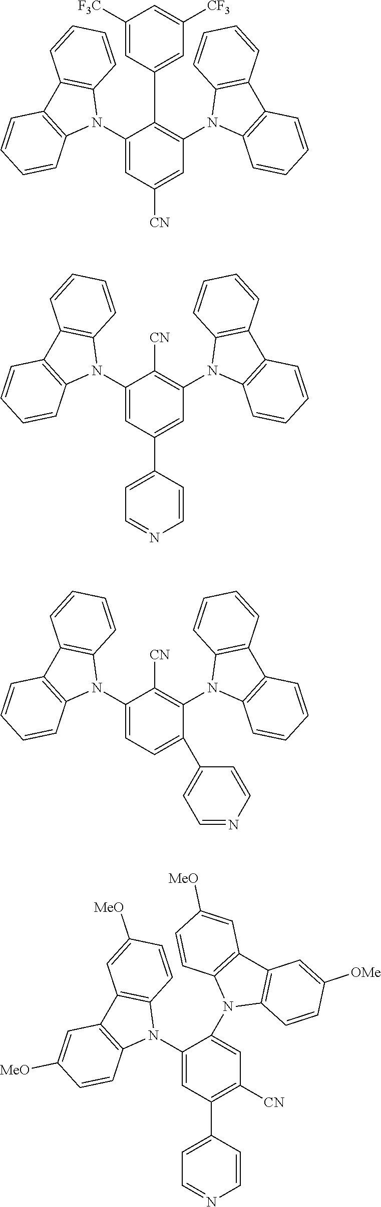 [SMILES: N#Cc1cc(-n2c3ccccc3c3ccccc32)c(-c2cc(C(F)(F)F)cc(C(F)(F)F)c2)c(-n2c3ccccc3c3ccccc32)c1 ; N#Cc1c(-n2c3ccccc3c3ccccc32)cc(-c2ccncc2)cc1-n1c2ccccc2c2ccccc21 ; N#Cc1c(-n2c3ccccc3c3ccccc32)ccc(-c2ccncc2)c1-n1c2ccccc2c2ccccc21 ; COc1ccc2c(c1)c1cc(OC)ccc1n2-c1cc(C#N)c(-c2ccncc2)cc1-n1c2ccc(OC)cc2c2cc(OC)ccc21]

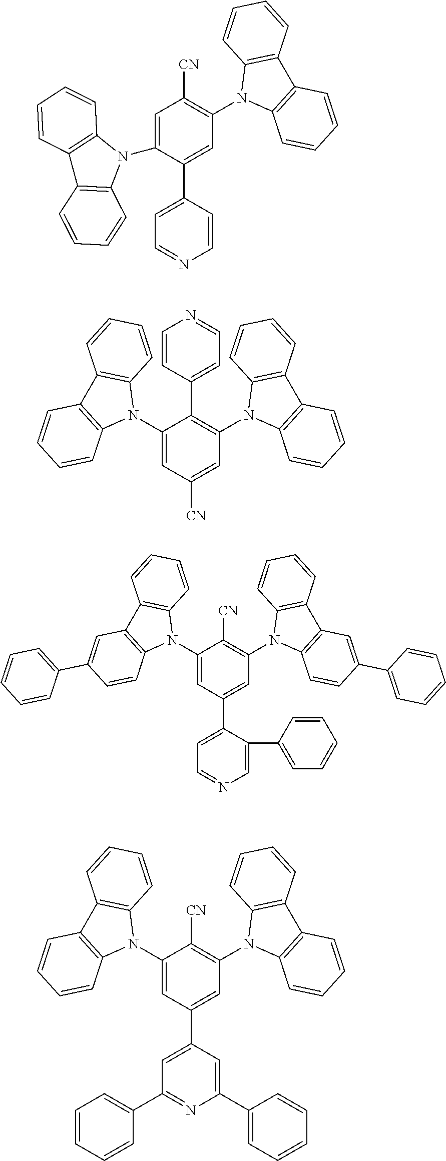 [SMILES: N#Cc1cc(-n2c3ccccc3c3ccccc32)c(-c2ccncc2)cc1-n1c2ccccc2c2ccccc21 ; N#Cc1cc(-n2c3ccccc3c3ccccc32)c(-c2ccncc2)c(-n2c3ccccc3c3ccccc32)c1 ; N#Cc1c(-n2c3ccccc3c3cc(-c4ccccc4)ccc32)cc(-c2ccncc2-c2ccccc2)cc1-n1c2ccccc2c2cc(-c3ccccc3)ccc21 ; N#Cc1c(-n2c3ccccc3c3ccccc32)cc(-c2cc(-c3ccccc3)nc(-c3ccccc3)c2)cc1-n1c2ccccc2c2ccccc21]

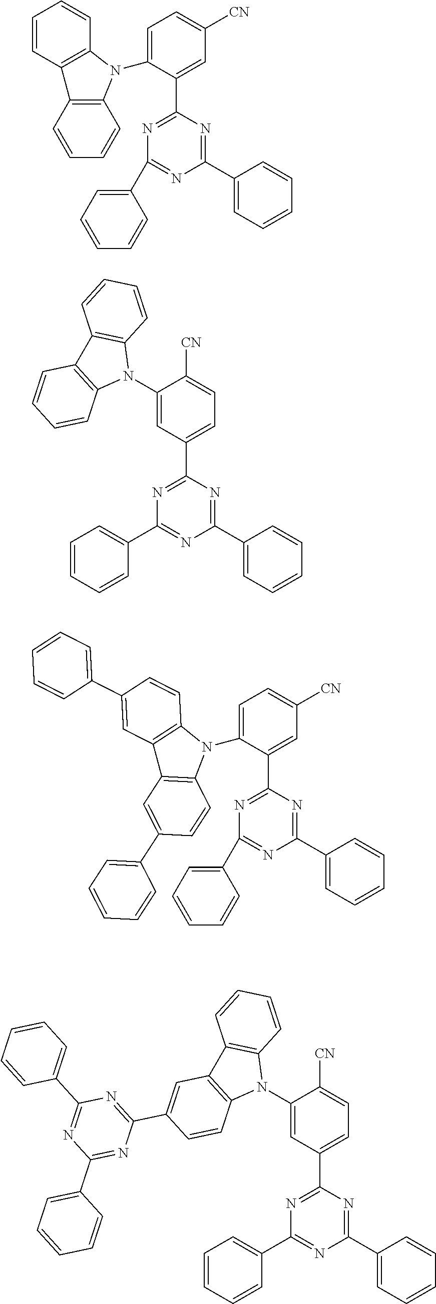

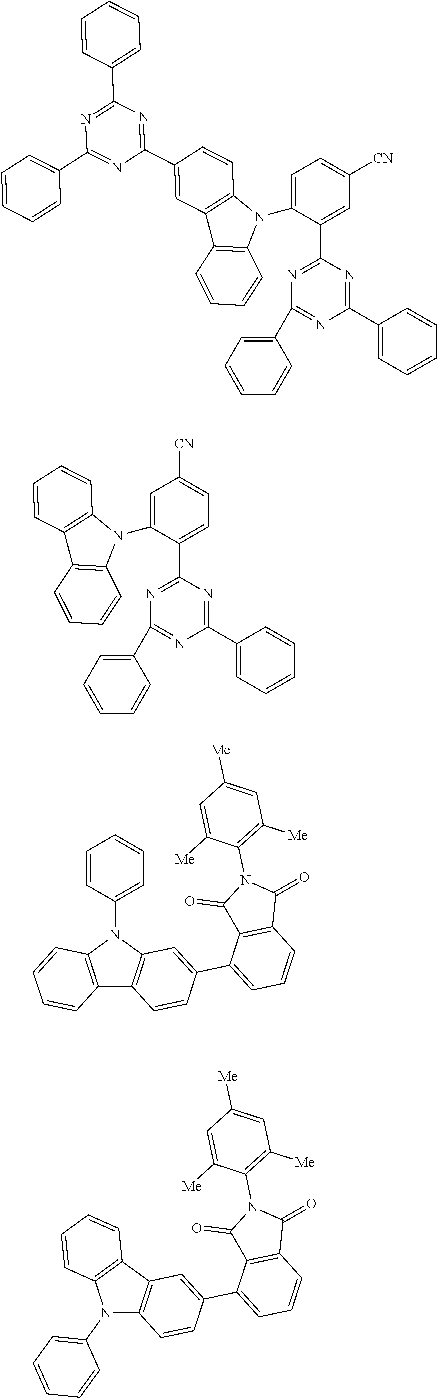 [SMILES: N#Cc1ccc(-n2c3ccccc3c3cc(-c4nc(-c5ccccc5)nc(-c5ccccc5)n4)ccc32)c(-c2nc(-c3ccccc3)nc(-c3ccccc3)n2)c1 ; N#Cc1ccc(-c2nc(-c3ccccc3)nc(-c3ccccc3)n2)c(-n2c3ccccc3c3ccccc32)c1 ; Cc1cc(C)c(N2C(=O)c3cccc(-c4ccc5c6ccccc6n(-c6ccccc6)c5c4)c3C2=O)c(C)c1 ; Cc1cc(C)c(N2C(=O)c3cccc(-c4ccc5c(c4)c4ccccc4n5-c4ccccc4)c3C2=O)c(C)c1]

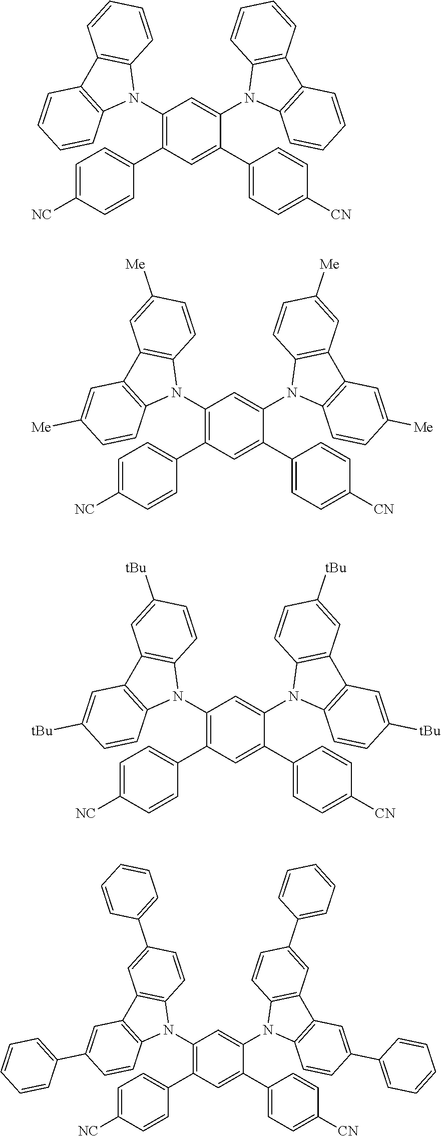 [SMILES: N#Cc1ccc(-c2cc(-c3ccc(C#N)cc3)c(-n3c4ccccc4c4ccccc43)cc2-n2c3ccccc3c3ccccc32)cc1 ; Cc1ccc2c(c1)c1cc(C)ccc1n2-c1cc(-n2c3ccc(C)cc3c3cc(C)ccc32)c(-c2ccc(C#N)cc2)cc1-c1ccc(C#N)cc1 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-c2ccc(C#N)cc2)cc1-c1ccc(C#N)cc1 ; N#Cc1ccc(-c2cc(-c3ccc(C#N)cc3)c(-n3c4ccc(-c5ccccc5)cc4c4cc(-c5ccccc5)ccc43)cc2-n2c3ccc(-c4ccccc4)cc3c3cc(-c4ccccc4)ccc32)cc1]

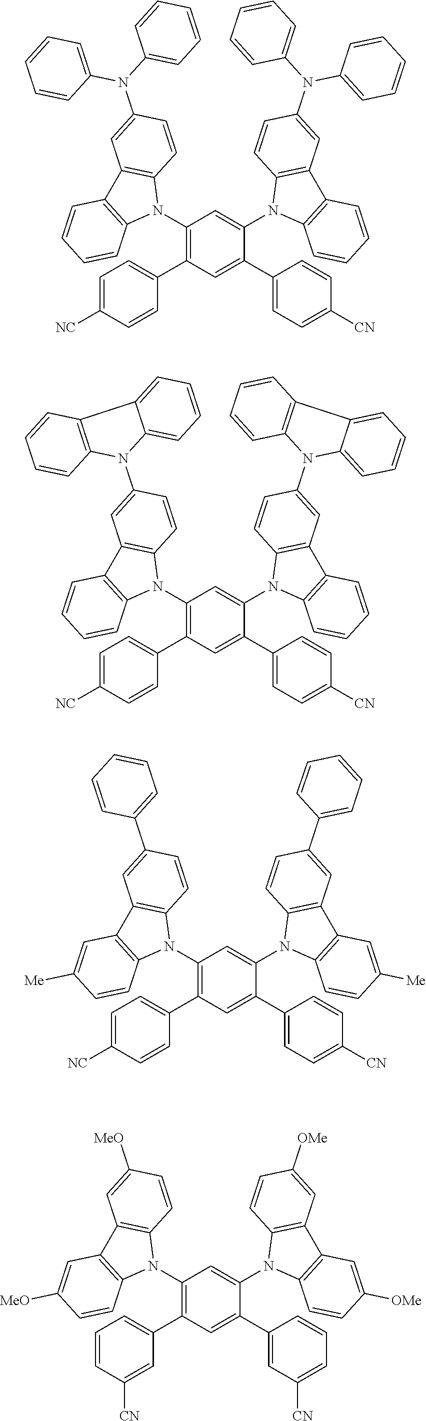 [SMILES: N#Cc1ccc(-c2cc(-c3ccc(C#N)cc3)c(-n3c4ccccc4c4cc(N(c5ccccc5)c5ccccc5)ccc43)cc2-n2c3ccccc3c3cc(N(c4ccccc4)c4ccccc4)ccc32)cc1 ; N#Cc1ccc(-c2cc(-c3ccc(C#N)cc3)c(-n3c4ccccc4c4cc(-n5c6ccccc6c6ccccc65)ccc43)cc2-n2c3ccccc3c3cc(-n4c5ccccc5c5ccccc54)ccc32)cc1 ; Cc1ccc2c(c1)c1cc(-c3ccccc3)ccc1n2-c1cc(-n2c3ccc(C)cc3c3cc(-c4ccccc4)ccc32)c(-c2ccc(C#N)cc2)cc1-c1ccc(C#N)cc1 ; COc1ccc2c(c1)c1cc(OC)ccc1n2-c1cc(-n2c3ccc(OC)cc3c3cc(OC)ccc32)c(-c2cccc(C#N)c2)cc1-c1cccc(C#N)c1]

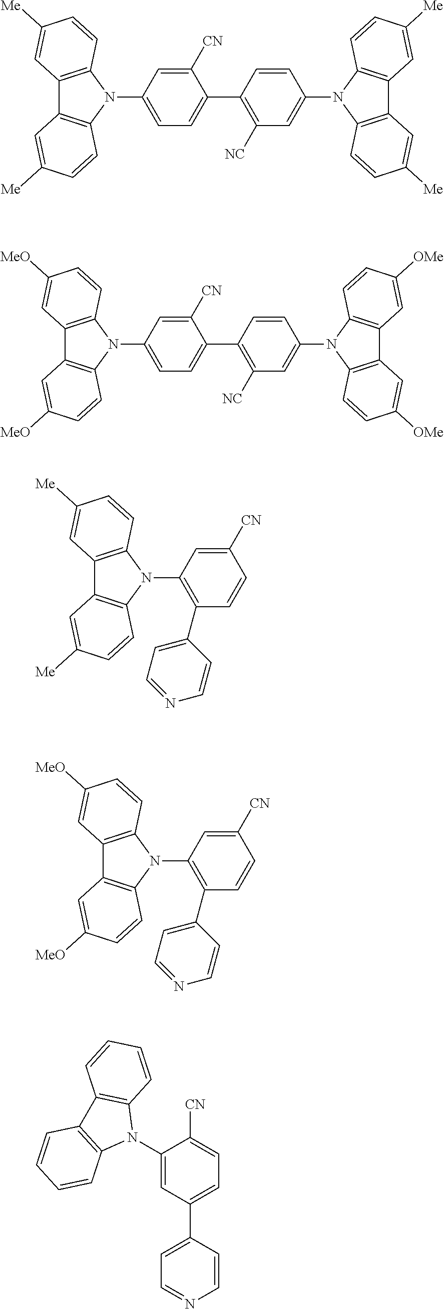 [SMILES: Cc1ccc2c(c1)c1cc(C)ccc1n2-c1ccc(-c2ccc(-n3c4ccc(C)cc4c4cc(C)ccc43)cc2C#N)c(C#N)c1 ; COc1ccc2c(c1)c1cc(OC)ccc1n2-c1ccc(-c2ccc(-n3c4ccc(OC)cc4c4cc(OC)ccc43)cc2C#N)c(C#N)c1 ; Cc1ccc2c(c1)c1cc(C)ccc1n2-c1cc(C#N)ccc1-c1ccncc1 ; COc1ccc2c(c1)c1cc(OC)ccc1n2-c1cc(C#N)ccc1-c1ccncc1 ; N#Cc1ccc(-c2ccncc2)cc1-n1c2ccccc2c2ccccc21]

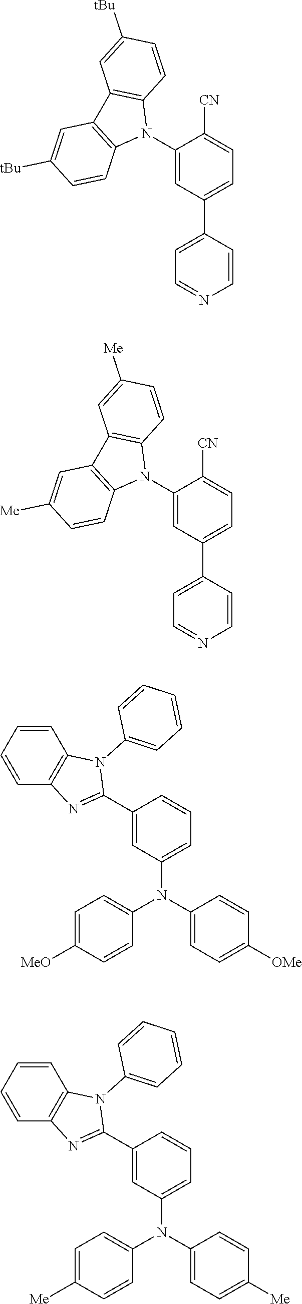 [SMILES: CC(C)(C)c1ccc2c(c1)c1cc(C(C)(C)C)ccc1n2-c1cc(-c2ccncc2)ccc1C#N ; Cc1ccc2c(c1)c1cc(C)ccc1n2-c1cc(-c2ccncc2)ccc1C#N ; COc1ccc(N(c2ccc(OC)cc2)c2cccc(-c3nc4ccccc4n3-c3ccccc3)c2)cc1 ; Cc1ccc(N(c2ccc(C)cc2)c2cccc(-c3nc4ccccc4n3-c3ccccc3)c2)cc1]

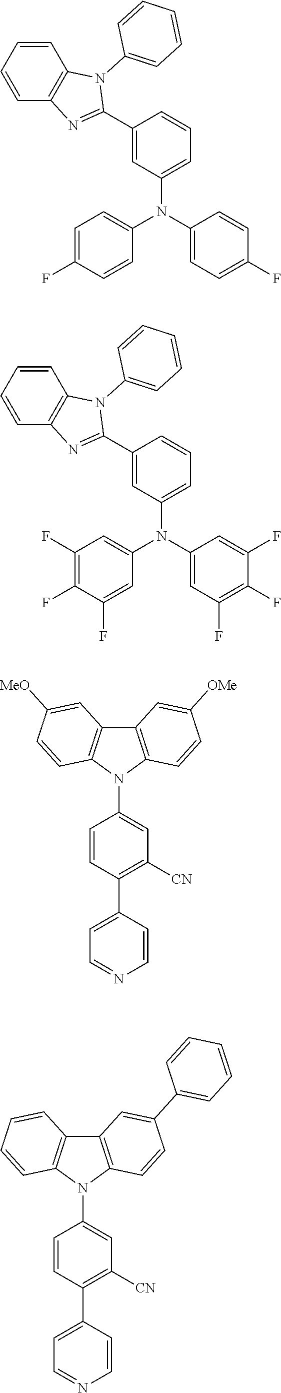 [SMILES: Fc1ccc(N(c2ccc(F)cc2)c2cccc(-c3nc4ccccc4n3-c3ccccc3)c2)cc1 ; Fc1cc(N(c2cccc(-c3nc4ccccc4n3-c3ccccc3)c2)c2cc(F)c(F)c(F)c2)cc(F)c1F ; COc1ccc2c(c1)c1cc(OC)ccc1n2-c1ccc(-c2ccncc2)c(C#N)c1 ; N#Cc1cc(-n2c3ccccc3c3cc(-c4ccccc4)ccc32)ccc1-c1ccncc1]

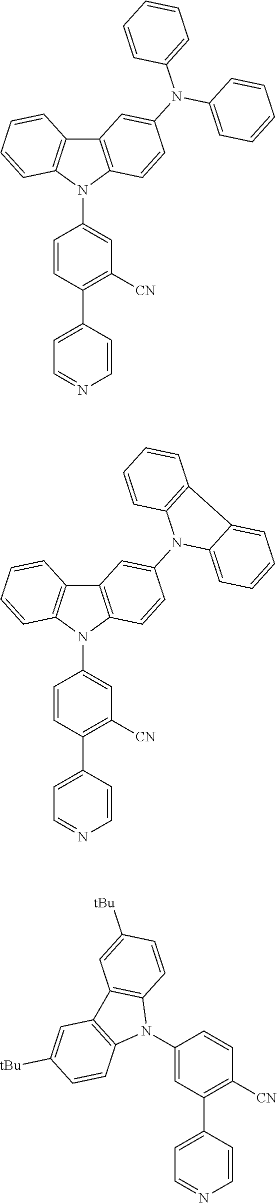 [SMILES: N#Cc1cc(-n2c3ccccc3c3cc(N(c4ccccc4)c4ccccc4)ccc32)ccc1-c1ccncc1 ; N#Cc1cc(-n2c3ccccc3c3cc(-n4c5ccccc5c5ccccc54)ccc32)ccc1-c1ccncc1 ; CC(C)(C)c1ccc2c(c1)c1cc(C(C)(C)C)ccc1n2-c1ccc(C#N)c(-c2ccncc2)c1]

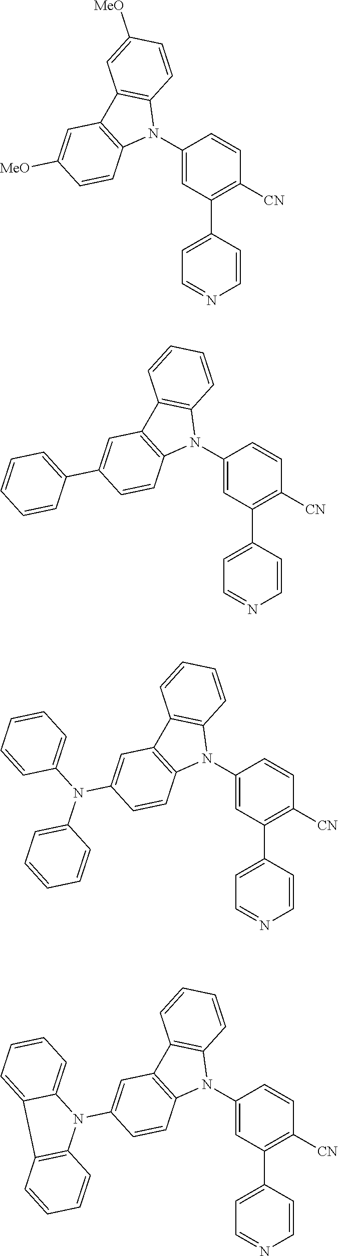 [SMILES: COc1ccc2c(c1)c1cc(OC)ccc1n2-c1ccc(C#N)c(-c2ccncc2)c1 ; N#Cc1ccc(-n2c3ccccc3c3cc(-c4ccccc4)ccc32)cc1-c1ccncc1 ; N#Cc1ccc(-n2c3ccccc3c3cc(N(c4ccccc4)c4ccccc4)ccc32)cc1-c1ccncc1 ; N#Cc1ccc(-n2c3ccccc3c3cc(-n4c5ccccc5c5ccccc54)ccc32)cc1-c1ccncc1]

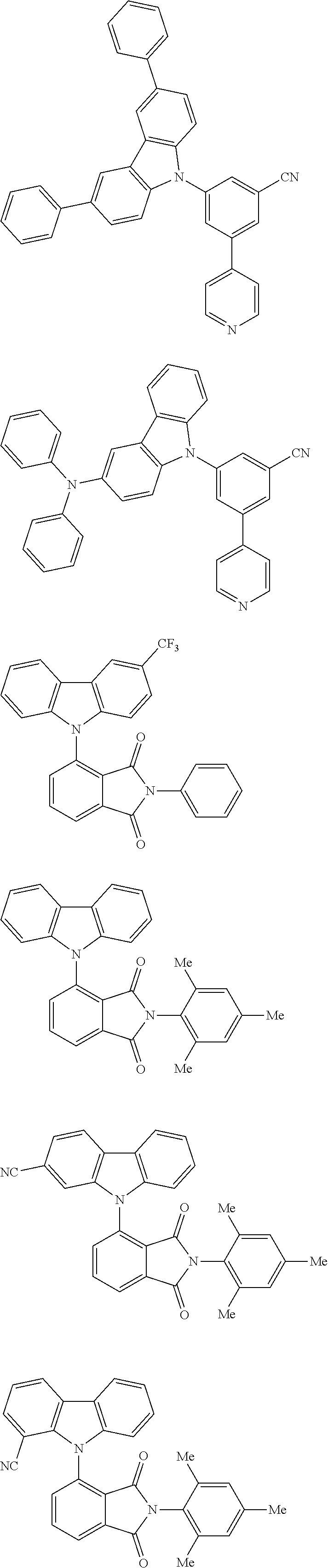 [SMILES: N#Cc1cc(-c2ccncc2)cc(-n2c3ccc(-c4ccccc4)cc3c3cc(-c4ccccc4)ccc32)c1 ; N#Cc1cc(-c2ccncc2)cc(-n2c3ccccc3c3cc(N(c4ccccc4)c4ccccc4)ccc32)c1 ; O=C1c2cccc(-n3c4ccccc4c4cc(C(F)(F)F)ccc43)c2C(=O)N1c1ccccc1 ; Cc1cc(C)c(N2C(=O)c3cccc(-n4c5ccccc5c5ccccc54)c3C2=O)c(C)c1 ; Cc1cc(C)c(N2C(=O)c3cccc(-n4c5ccccc5c5ccc(C#N)cc54)c3C2=O)c(C)c1 ; Cc1cc(C)c(N2C(=O)c3cccc(-n4c5ccccc5c5cccc(C#N)c54)c3C2=O)c(C)c1]

Further, as the thermally assisting delayed fluorescent material, a compound represented by any of the following formulas (AD1), (AD2) and (AD3) can also be used.

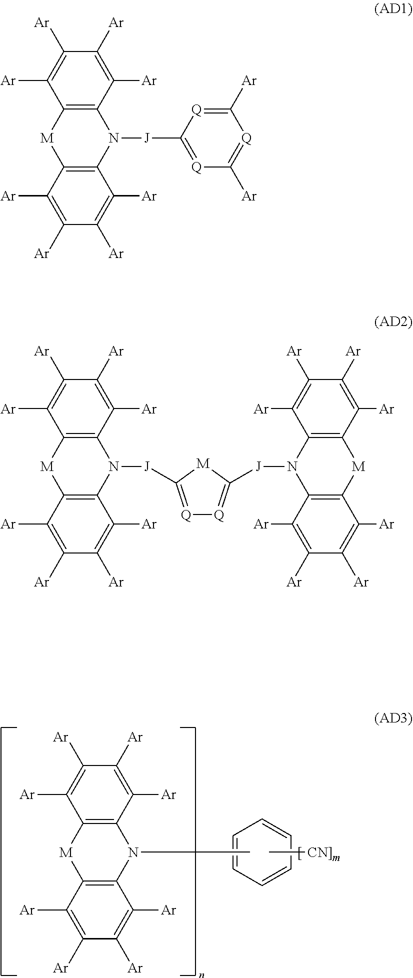

In Formulas (AD1), (AD2) and (AD3),

M is each independently a single bond, —O—, >N—Ar or >CAr₂, and is preferably a single bond, —O—, or >N—Ar in terms of the depth of HOMO of the substructure to be formed and the height of the excited singlet energy level and the excited triplet energy level. J is a spacer structure that separates the donor and acceptor substructures, and each is independently an arylene having 6 to 18 carbons. From the viewpoint of the magnitude of conjugation that seeps out of the donor and acceptor substructures, an arylene having 6 to 12 carbons is preferable. More specifically, phenylene, methylphenylene and dimethylphenylene can be exemplified. Q's are each independently ═C(—H)— or ═N—, and preferably ═N—, in terms of the shallowness of LUMO of the substructure forming and the height of the excited singlet energy level and the excited triplet energy level. Ar's are each independently hydrogen, an aryl having 6 to 24 carbons, a heteroaryl having 2 to 24 carbons, an alkyl having 1 to 12 carbons, or a cycloalkyl having 3 to 18 carbons, and Ar is preferably hydrogen, an aryl having 6 to 12 carbons, a heteroaryl having 2 to 14 carbons, an alkyl having I to 4 carbons, or a cycloalkyl having 6 to 10 carbons, and more preferably hydrogen, phenyl, tolyl, xylyl, mesityl, biphenyl, pyridyl, bipyridyl, triazyl, carbazolyl, dimethylcarbazolyl, di-tert-butylcarbazolyl, benzoimidazolyl, and pheny benzoimidazolyl, further preferably hydrogen, phenyl, or carbazolyl, from the viewpoint of the depth of HOMO of the substructures formed and the height of the excited singlet energy level and excited triplet energy level, m is 1 or 2. n is an integer of 1 to (6-m.), and preferably an integer of 4 to (6-m) from the viewpoint of steric hindrance. Further, at least one hydrogen in the compound represented by each of the above formulas may be replaced with a halogen or deuterium.

More specifically, preferable examples of a compound used as the second component of the present embodiment include 4CzBN, 4CzBN-Ph, 5CzBN, 3Cz2DPhCzBN, 4CzlPN, 2PXZ-TAZ, Cz-TRZ3, BDPCC-TPTA, MA-TA., PA-TA, FA-TA, PXZ-TRZ, DMAC-TRZ, BCzT, DCzTrz, DDCzTRz, spiroAC-TRZ, Ac-RPM. Ac-PPM, Ac-MPM, TCzTrz, TmCzTrz, and DCzmCzTrz.

The compound used as the second component of the present embodiment may be a donor acceptor type TADF compound represented by D-A in which one donor D and one acceptor A are bonded via a direct bond or a linking group, but it is preferable that the compound has a structure represented by the following formula (DAD 1) in which a plurality of donors D are bonded to one acceptor A via a direct bond or a linking group, because the characteristics of the organic electroluminescent element become more excellent.

(D¹-L¹)n-A¹ (DAD1)

A compound represented by Formula (DAD2) below is included in Formula (DAD1),

D²-L²-A²-L³-D³ (DAD2)

In Formulas (DAD1) and (DAD2), D¹, D² and D³ each independently represent a donor group. As the donor group, the above-described donor structure can be employed. A¹ and A² each independently represent an acceptor group. As the acceptor group, a structure having an acceptor property described above can be employed. L¹, L² and L³ each independently represent a single bind or a conjugated linking group. The conjugated linking group is a spacer structure separating a donor group and an acceptor group, and is preferably an arylene having 6 to 18 carbons, and more preferably an arylene having 6 to 12 carbons. More preferably, L¹, L² and L³ are each independently phenylene, methylphenylene or dimethylphenylene. n in Formula (DAD1) is two or more and represents an integer less than or equal to the largest number that A¹ can substitute. n may be selected, for example, within the range of 2 to 10, or may be selected within the range of 2 to 6. When n is 2, it becomes a compound represented by Formula (DAD2). n D¹'s may be the same or different to each other, n L¹ may be the same or different to each other. Preferred specific examples of the compound represented by Formula (DAD1) and Formula (DAD2) include 2PXZ-TAZ and the following compounds, but the second component which can be used in the present invention is not limited to these compounds.

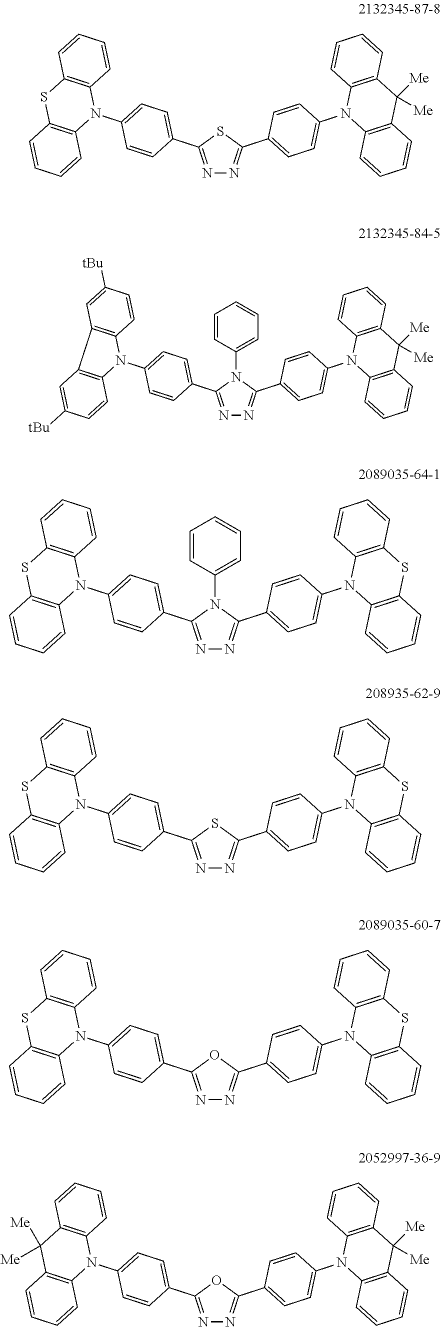

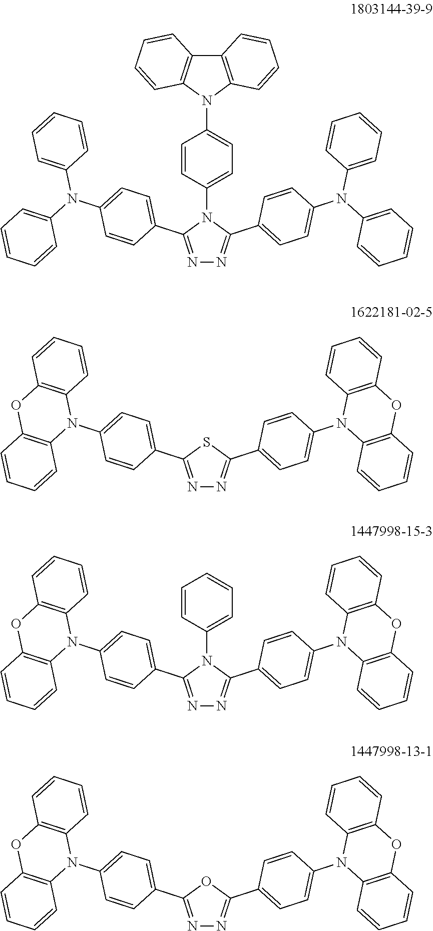 [SMILES: c1ccc(N(c2ccccc2)c2ccc(-c3nnc(-c4ccc(N(c5ccccc5)c5ccccc5)cc4)n3-c3ccc(-n4c5ccccc5c5ccccc54)cc3)cc2)cc1 ; c1ccc2c(c1)Oc1ccccc1N2c1ccc(-c2nnc(-c3ccc(N4c5ccccc5Oc5ccccc54)cc3)s2)cc1 ; c1ccc(-n2c(-c3ccc(N4c5ccccc5Oc5ccccc54)cc3)nnc2-c2ccc(N3c4ccccc4Oc4ccccc43)cc2)cc1 ; c1ccc2c(c1)Oc1ccccc1N2c1ccc(-c2nnc(-c3ccc(N4c5ccccc5Oc5ccccc54)cc3)o2)cc1]

The light-emitting layer may he formed of a single layer or multiple layers, Further, the host compound, the thermally assisting delayed fluorescent material, and the polycyclic aromatic compound of the present invention may be contained in the same layer and may be contained in a plurality of layers such that at least one component is in each layer. Each of the host compound, the thermally assisting delayed fluorescent material, and the polycyclic aromatic compound of the present invention included in the light-emitting layer may be either a single type or a combination of a plurality types. The assisting dopant and the emitting dopant may be wholly contained in the host compound as a matrix or may be partially contained therein. The light emitting layer doped with the assisting dopant and the emitting dopant can be formed by a method of depositing the host compound, the assisting dopant, and the emitting dopant by a ternary co-deposition method, a method of depositing the host compound, the assisting dopant, the emitting dopant simultaneously after mixing them in advance, or a wet film deposition method in which a composition for forming a light emitting layer (paint) prepared by dissolving the host compound, the assisting dopant, and the emitting dopant in an organic solvent is applied.

In this aspect, the amount of the host compound to be used varies depending on the type of the host compound and may^{,} be determined according to the properties of the host compound. The amount of the host compound to be used is preferably 40 to 99% by mass, more preferably 50 to 98% by mass, and still more preferably 70 to 95% by mass, with respect to the total mass of the light-emitting layer. The range is preferred from the viewpoint of efficient charge transportation and efficient energy transfer to the dopant.

The amount of the assisting dopant (a thermally assisting delayed fluorescent material) to be used varies depending on the type of the assisting dopant, and may be determined according to the properties of the assisting dopant. The amount of the assisting dopant to be used is preferably 1 to 60% by mass, more preferably 2 to 50% by mass, and still more preferably 5 to 30% by mass, with respect to the total mass of the light emitting layer. The above range is preferable, for example, in that energy can be efficiently transferred to the emitting dopant.

The amount of the emitting dopant (the polycyclic aromatic compound of the present invention) to be used varies depending on the type of the emitting clop=and may be determined according to the properties of the emitting dopant. The amount of the emitting dopant to be used is preferably 0.001% to 30% by mass, more preferably 0.01% to 20% by mass, and still more preferably 0.1% to 10% by mass, with respect to the total mass of the light emitting layer. The above range is preferable from the viewpoint of capability of preventing a concentration quenching phenomenon, for example.

It is preferable that the amount of the emitting dopant used is low in terms of preventing concentration quenching phenomenon, A high concentration of the assisting dopant is preferable from the viewpoint of the efficiency of the thermally assisting delayed fluorescence mechanism. Furthermore, from the viewpoint of the efficiency of the thermally assisting delayed fluorescence mechanism of the assisting dopant, it is preferable that the amount of emitting dopant used is lower than the amount of assisting dopant used.

### 2-1-3. Substrate in Organic Electroluminescent Element

The substate 101 is to be a support of the organic EL element, for which generally used are quartz, glass, metals plastics, etc. The substate 101 is shaped in a tabular form, a filmy form or a sheet form depending on the intended use, and for example, glass plates, metal plates, metal foils, plastic films and plastic sheets are used. Above all, glass plates, arid transparent synthetic resin plates of polyester, polymethacrylate, polycarbonate or polysulfone are preferred. For glass substrates, soda lime glass and alkali-free glass are usable, and the thickness may be one that is enough for securing mechanical strength, and is, for example, 0.2 mm or more, The upper limit of the thickness is, for example, 2 mm or less, preferably 1 mm or less. Regarding the glass material, alkali-free glass is preferred as releasing fewer ions. However, soda lime glass coated with a barrier coat of SiO₂ or the like is available on the market and can be used here. For increasing gas barrier performance, the substate 101 may be provided with a gas barrier film of a dense silicon oxide film or the like on at least one surface thereof, and in particular, in the case Where a synthetic resin plate, film or sheet having low gas barrier performance is used as the substate 101, such a gas barrier film is preferably provided.

### 3-1-5. Anode in Organic Electroluminescent Element

The anode 102 plays a role of injecting holes into the light-emitting layer 105. In the case where the hole injection layer 103 and/or the hole transport layer 104 are/is arranged between the anode 102 and the light-emitting layer 105, holes are injected into the light-emitting layer 105 via these.

The material to form the anode 102 includes an inorganic compound and an organic compound. Examples of the inorganic compound include metals (e.g., aluminum, gold, silver, nickel, palladium, chromium), metal oxides (e.g., indium oxide, tin oxide, indium-tin oxide (ITO), indium-zinc oxide (IZO)), metal halides (e.g., copper iodide), copper sulfide, carbon black, ITO glass and NESA glass. Examples of the organic compound include polythiophenes such as poly(3-methylthiophene, and conductive polymers such as polypyrrole and polyaniline. In addition, the material for use herein can be appropriately selected from substances that are used as an anode of an organic EL element.

The resistance of the transparent electrode is not limited so far as sufficient current for light emission from light-emitting devices can be supplied, but from the viewpoint of power conswnption by light-emitting devices, the resistance is preferably low. For example, an ITO substrate with 300 Ω/square or less can function as a device electrode, but at present, a substrate with 10 Ω/square or so is available, and therefore, low-resistance substrates with, for example, 100 to 5 Ω/square. preferably 50 to 5 Ω/square are especially preferably used. The thickness of ITO can be arbitrarily selected in accordance with the resistance value thereof, and is generally within a range of 50 to 300 nm in many cases.

### 2-1-5.Hole Injection Layer, and Hole Transport Layer in Organic Electroluminescent Element

The hole injection layer 103 plays a role of efficiently injecting the holes having transferred from the anode 102, into the light-emitting layer 105 or the hole transport layer 104. The hole transport layer 104 plays a role of efficiently transporting the holes injected from the anode 102 or the holes injected from the anode 102 via the hole injection layer 103, into the light-emitting layer 105. The hole injection layer 103 and the hole transport layer 104 each are formed by laminating or mixing one or more of hole injection/transport materials or are formed from a mixture of a hole injection/transport material and a polymer binder. An inorganic salt such as iron(III) chloride may be added to the hole injection/transport material to form a layer.

The hole injection/transport material needs to efficiently inject and transport the holes from the positive electrode between electrodes given an electric field, and is one having a high hole injection efficiency and capable of efficiently transporting the injected holes. For that purpose, preferably, the substance has a small ionization potential and has a large hole mobility, and is excellent in stability and hardly generates impurities to be traps in production and during use.

The material to form the hole injection layer 103 and the hole transport layer 104 can be arbitrarily selected from compounds heretofore generally used as a charge transport material for holes in a photoconductive material, as well as p-type semiconductors and other known compounds that are used in a hole injection layer and a hole transport layer in an organic EL element. Specific examples thereof include a carbazole derivative (e.g,, N-phenylcarbazole, polyvinylcarbazole), a biscarbazole derivative such as bis(N-arylcarbazole) or bis(N-alkyl carbazole), a triarylamine derivative (e.g., 4,4′,4″-tris(N-carbazolyl)triphenylamine, polymer having an aromatic tertiary amino group in the main chain or the side chain, a triphenylamine derivative such as 1,1-bis(4-di-p-tolylaminophenyl)cyclohexane, N,N′-diphenyl-N,N′-di(3-methylphenyl)-4,4′-diaminobiphenyl, N,N′-diphenyl-N,N′-dinaphthyl-4,4′-diaminobiphenyl, N,N′-diphenyl-N,N′-di(3-methylphenyl)-4,4′-diphenyl-1,1′-diamine, N,N′-dinaphthyl-N,N′-diphenyl-4,4′-diphenyl-1,1′-diamine, N⁴,N⁴-diphenyl-N⁴,N⁴-bis(9-phenyl-9H-carbazol-3-yl)-[1,1′-biphenyl]-4,4′-diamine, N⁴,N⁴,N^{4′},N⁴′-tetra[1,1′-biphenyl]-4-yl)-[1,1′-biphenyl]-4,4′-diamine, 4,4′,4″-tris(3-methylphenyl(phenyl)amino)triphenylamine, a starburst amine derivative), a stilbene derivative, a phthalocyanine derivative (e.g., metal-free, or copper phthalocyanine), a pyrazoline derivative, a hydrazone compound, a benzofuran derivative, a thiophene derivative, an oxadiazole derivative, a quinoxaline derivative (e.g., 1,4,5,8,9,12-hexazatriphenylene-2,3,6,7,10,11-hexacarbonitrile), a heterocyclic compound such as a porphyrin derivative, and a polysilane. Regarding the polymer-type substances, a polycarbonate, a styrene derivative, a polyvinyl carbazole and a polysilane having the above-mentioned monomer in the side chain are preferred, but are not specifically limited so far as the compounds can form a thin film necessary for production of light-emitting devices and can inject holes from an anode and further can transport holes.

It is known that electric conductivity of organic semiconductors is strongly influenced by doping. Such organic semiconductor matrix substances are formed of compounds having good electron donating performance, or compounds having good electron acceptability. For doping with an electron-donating substance, an electron acceptor such as tetracyanoquinonedimethane (TCNQ) or 2,3,5,6-tetrafluorotetracyano-1,4-benzoquinonedimethane (F4TCNQ) is known (for example, see literature of M. Pfeiffer, A. Beyer, T. Fritz, K. Leo, Appl. Phys. Lett., 73(22), 3202-3204 (1998), and literature of J. Blochwitz, M. Pfeiffer, T. Fritz, K. Leo. Appl. Phys. Lett., 73(6), 729-731 (1998)). These form so-called holes by an electron transfer process in an electron-donating base substance (hole transport substance). Depending on the number of holes and the mobility thereof, the conductivity of the base substance greatly varies. As the matrix substance having a hole transporting properly, for example, there are known a benzidine compound (e.g., TPD), and a starburst amine derivative (e.g., TDATA), or a specific metal phthalocyanine (especially, zinc phthalocyanine (ZnPc)) (see JP 2005-167175 A).

### 2-1-6. Electron Blocking Layer in Organic Electroluminescent Element

An electron blocking layer for preventing the diffusion of electrons from the light emitting. layer may be provided between the hole injection/transport layer and the light emitting layer. For forming the electron blocking layer, a compound represented by any one of the above formulas (H1), (H2) and (H3) can be used.

The polycyclic aromatic compound of the present invention may be used as a material for forming an electron blocking layer.

### 2-1-7. Electron Injection Layer and an Electron Transport Layer in Organic Electroluminescent Element

Electron injection layer 107 plays a role of efficiently injecting electrons moved from cathode 108 into light-emitting layer 105 or electron transport layer 106. Electron transport layer 106 plays a role of efficiently transport the electrons injected from cathode 108 or the electrons injected from cathode 108 through electron injection layer 107 to light-emitting layer 105. Electron injection layer 107 and electron transport layer 106 are formed by lamination and mixing one kind or two or more kinds of electron injection/transport materials or formed from a mixture of an electron injection/transport material and a polymer binder.

An electron injection/transport layer means a layer that manages injection of the electrons from the cathode and transportation of the electrons, and desirably has high electron injection efficiency and efficiently transports the electrons injected. Accordingly, a material having large electron affinity, large electron mobility and excellent stability, and hard to generate impurities to be a trap during production and use is preferred. However, in consideration of a transport balance between the holes and the electrons, when the material mainly plays a role of being able to efficiently inhibit the holes from the anode from flowing to a cathode side without recombination, even if the material has a comparatively low electron transport capability, the material has an effect on improving luminescent efficiency as high as a material having high electron transport capability. Accordingly, the electron injection/transport layer in the present embodiment may also include a function of a layer that can efficiently inhibit movement of the holes.

A material (electron transport material) that forms electron transport layer 106 or electron injection layer 107 can be selected and used from a compound which has been commonly used so far as an electron transfer compound in a photoconductive material, and a publicly-known compound used for a hole injection layer and a hole transport layer of an organic EL element.

A material used for the electron transport layer or the electron injection layer preferably contains at least one kind selected from a compound formed of an aromatic ring or a complex aromatic ring composed of one or more atoms selected from carbon, hydrogen, oxygen, sulfur, silicon and phosphorus, a pyrrole derivative and a fused ring derivative thereof and a metal complex having electron accepting nitrogen, Specific examples thereof include a fused ring-based aromatic ring derivative such as naphthalene and anthracene, a styryl-based aromatic ring derivative typified by 4,4′-bis(diphenylethenyl)biphenyl, a pennon derivative, a coumarin derivative, a naphthalimide derivative, a quinone derivative such as anthraquinone arid diphenoquinone, a phosphine oxide derivative, an aryl nitrile derivative and an indole derivative. Specific examples of the metal complex having electron accepting nitrogen include a hydroxy azole complex such as a hydroxyphenyl oxazole complex, an azomethine complex, a tropolone metal complex, a flavonol metal complex and a benzoquinoline metal complex. The above materials may be used alone, or in combination of a different material.

Specific examples of other electron transport compounds include a pyridine derivative, a naphthalene derivative, a fluoranthene derivative, a BO-based derivative, an anthracene derivative, a phenanthroline derivative, a perinone derivative, a coumarin derivative, a naphthalimide derivative, an anthraquinone derivative, a diphenoquinone derivative, a diphenylquinone derivative, a perylene derivative, an oxadimole derivative (such as 1,3-bis[(4-t-butylphenyl)1,3,4-oxadiazolyl]phenylene), a thiophene derivative, a triazole derivative (such as N-naphthyl-2,5-diphenyl-1,3,4-triazole), a thiadiazole derivative, a metal complex of an oxime derivative, a quinolinol metal complex, a quinoxaline derivative, a polymer of a quinoxaline derivative, a benzazole compound, a gallium complex, a pyrazol derivative, a pertluorophenylene derivative, a triazine derivative, a pyrazine derivative, a benzoquinoline derivative (such as 2,2′-bis(benzo[h]quinolin-2-yl)-9,9′-spirobifluorene), an imidazopyridine derivative, a borane derivative, a benzimidazole derivative (such as tris(N-phenylbenzimidazole-2-yl)benzene), a benzooxazol derivative, a thiazole derivative, a benzothiazole derivative, a quinoline derivative, an oligo pyridine derivative such as terpyridine, a bipyridine derivative, a terpyridine derivative (such as 1,3-bis(4′-(2,2′:6′,2″-terpyridinyl))benzene), a naphthyridine derivative (such as bis(1-naphthyl)-4-(1,8-naphthyridine-2-yl)phenyl phosphine oxide), an aldazine derivative, a pyrimidine derivative, an aryl nitrile derivative, an indole derivative, a phosphorus oxide derivative, a bisstyryl derivative, a silole derivative and an azoline derivative.

Moreover, a metal complex having electron accepting nitrogen can also be used, and specific examples thereof include a quinolinol-based metal complex, a hydroxyazole complex such as a hydroxyphenyloxazole complex, an azomethine complex, a tropolone metal complex, a flavonol metal complex and a benzoquinoline metal complex.

The above materials may be used alone, or in combination of a different material.

Among the above-mentioned materials, a borane derivative, a pyridine derivative, a. fluoranthene derivative, a BO-based derivative, an anthracene derivative, a benzofluorene derivative, a phosphine oxide derivative, a pyrimidine derivative, an aryl nitrile derivative, a triazine derivative, a benzimidazole derivative, a phenanthroline derivative, a quinolinol metal complex, a thiazole derivative, a benzothiazole derivative, a si.lole derivative and an azoline derivative are preferred.

The polycyclic aromatic compound of the present invention can be used as a material fur electron transport layer and/or the electron injection layer.

The electron transport layer and/or the electron injection layer further includes a substance that can reduce a material forming the electron transport layer or the electron injection layer. Various substances are used as the reducing substance if the substance has predetermined reducing properties. For example, at least one selected from the group of alkali metal, alkaline earth metal, rare earth metal, an oxide of alkali metal, a halide of alkali metal, an oxide of alkaline earth metal, a halide of alkaline earth metal, an oxide of rare earth metal, a halide of rare earth metal, an organic complex of alkali metal, an organic complex of alkaline earth metal and an organic complex of rare earth metal can be preferably used.

Specific examples of the preferred reducing substance include alkali metal such as Na (work function: 2.36 eV), K (work function: 2.28 eV), Rb (work function: 2.16 eV) or Cs (work function 1.95 eV), and alkaline earth metal such as Ca (work function: 2.9 eV), Sr (work function: 2.0 to 2.5 eV) or Ba (work function: 2.52 eV), and a substance having a work function of 2.9 eV or less is particularly preferred. Among the above substances, as the reducing substance, alkali metal of K, Rb or Cs is preferred, Rb or Cs is further preferred, and Cs is most preferred. The above alkali metals have particularly high reduction capability, and improvement in luminance and extension of a service life in the organic EL element can be achieved by adding a relatively small amount thereof to the material forming the electron transport layer or the electron injection layer. Moreover, as the reducing substance having a work function of 2.9 eV or less, a combination of two or more kinds of alkali metals is preferred, and a combination including Cs, for example, a combination of Cs and Na, Cs and K, Cs and Rh, or Cs and Na and K is particularly preferred. The reduction capability can be efficiently exhibited by containing Cs, and improvement in luminance and extension of a service life in the organic EL element can be achieved by adding Cs to the material forming the electron transport layer or the electron injection layer.

### 2-1-8. Cathode in Organic Electroluminescent Element

Cathode 108 plays a role of injecting electrons into light-emitting layer 105 through electron injection layer 107 and electron transport layer 106.

A material forming cathode 108 is not particularly limited, as long as the material can efficiently inject electrons into an organic layer, and a material similar to the material forming anode 102 can be used. Particularly, metal such as tin, indium, calcium, aluminum, silver, copper, nickel, chromium, gold, platinum, iron, zinc, lithium, sodium, potassium, cesium and magnesium, or alloy thereof (such as magnesium-silver alloy, magnesium-indium alloy and aluminum-lithium alloy such as lithium fluoride/aluminum), or the like is preferred. In order to enhance electron injection efficiency to improve device characteristics, lithium, sodium, potassium, cesium, calcium, magnesium, or alloy containing the above low-work-function metals is effective, However, the above low-work-function metals are generally unstable in atmospheric air in many cases. In order to improve the above point, a method of doping a small amount of lithium, cesium and magnesium to an organic layer, and using an electrode having high stability is known, for example. As other dopants, inorganic salt such as lithium fluoride, cesium fluoride, lithium oxide and cesium oxide can also be used, but not limited thereto.

Further, preferred examples for protecting the electrode include lamination of metals such as platinum, gold, silver, copper, iron, tin, aluminum and indium, alloy using the above metals, inorganic substances such as silica, titanic and silicon nitride, polyvinyl alcohol, polyvinyl chloride, a hydrocarbon-based polymer compound, or the like. A method of preparing the above electrodes is not particularly limited, as long as conduction, such as resistance heating, electron beam vapor deposition, sputtering, ion plating and coating, can be achieved.

2-1-9. Binding Agent that May be Used in Each Layer

The above materials used for the hole injection layer, the hole transport layer, the light-emitting layer, the electron transport layer and the electron injection layer can form each layer alone, but can also be dispersed and used, as a polymer binding agent, in a solvent-soluble resin such as polyvinyl chloride, polycarbonate, polystyrene, poly(N-vinylcarbazole), polymethylmethacrylate, polybutylmethacrylate, polyester, polysulfone, polyphenylene oxide, polybutadiene, a hydrocarbon resin, a ketone resin, a phenoxy resin, polyamide, ethyl cellulose, a vinyl acetate resin, an ABS resin and a polyurethane resin; or a curable resin such as a phenolic resin, a xylene resin, a petroleum resin, a urea resin, a melamine resin, an unsaturated polyester resin, an alkyd resin, an epoxy resin and a silicone resin.

### 2-1-10. Production Method for Organic Electroluminescent Element

The layers constituting the organic EL element can be firmed each as a thin film of a material to constitute each layer, according to a vapor deposition method, a low resistance vapor deposition method, an electron beam vapor deposition method, a sputtering method, a molecular lamination method, a printing method, a inkjet method, a. spin coating method, a casting method or a coating method. The thickness of each layer thus formed in the manner is not specifically limited and can be appropriately set depending on the properties of the material. In general, the thickness falls within a range of 2 nm to 5000 nm. The film thickness can be measured generally according to a crystal oscillation-type thickness meter. In the case where a thin film is formed according to a vapor deposition method, the deposition condition varies depending on the kind of the material, and the crystal structure and the association structure intended for the film. In general, it is preferable to appropriately set the vapor deposition conditions in the ranges of a heating temperature for the boat of +50 to +400° C., a degree of vacuum of 10⁻⁶ to 10⁻³ Pa, a rate of deposition of 0.01 to 50 nm/sec, a substrate temperature of −150 to +300° C., and a film thickness of 2 nm to 5 μm.

Next, as an example of the method for preparing the organic EL device, a method for preparing the organic EL device including anode/hole injection layer/hole transport layer/luminescent layer including host material and dopant material/electron transport layer/electron injection layer/cathode will he described. The anode is prepared by forming a thin film of an anode material on a. suitable substrate by a vapor deposition method or the like, and then thin films of the hole injection layer and the hole transport layer are formed on the anode. A thin film is formed thereon by vapor codeposition of the host material and the dopant material, and is taken as the luminescent layer, and the electron transport layer and the electron injection layer are formed on the luminescent layer, and a thin film composed of a cathode substance is formed by a vapor deposition method or the like, and is taken as the cathode, and thus the objective organic EL device is obtained. In addition, in preparing the above organic EL device, the order can be reversed so as to be prepared in the order of the cathode, the electron injection layer, the electron transport layer, the luminescent layer, the hole transport layer, the hole injection layer and the anode.

When a DC voltage is applied to the organic EL device thus obtained, the voltage may he applied in such a manner that the anode has “+” polarity and the cathode has “−” polarity, and when a voltage of about 2 to about 40 V is applied, luminescence can be observed from a transparence or translucent electrode side (the anode or the cathode, or both). Moreover, the organic EL device also produces luminance in the case of application of a pulse current or an AC current. In addition, a waveform of the AC current to be applied may be arbitrary.

### 2-1-11. Application for Organic Electroluminescent Element

An organic EL element is also applicable to a display device, a lighting device, or the like.

The display device and the lighting device equipped with an organic EL element can be produced by connecting the organic EL element and a known driving device, according to a known method, and can be driven appropriately using a known driving method of direct current driving, pulse driving or alternate current driving.

Examples of the lighting device include panel displays such as color flat panel displays, and flexible displays such as flexible color organic electroluminescent (EL) displays (for example, see JP 10-335066 A, JP 2003-321546 A, JP 2004-281086 A). Examples of the display system include a matrix and/or segment system. A matrix display and a segment display may co-exist in the same panel.

In a matrix, pixels for display are two-dimensionally arranged such as in a lattice-like or mosaic-like form, and pixel aggregation displays a letter and an image. The shape and the size of pixels are determined depending on the intended use. For example, for image and letter display on personal computers, monitors and televisions, square pixels of 300 μm or less on each side are generally used, while in the case of a large-size display such as a display panel, pixels of mm order on each side are used. In the case of monochromatic display, pixels of the same color may be aligned, but in the case of color display, pixels of red, green and blue are aligned and displayed. In this case, typically, there is known a delta type and a stripe type. Regarding the driving method for the matrix, any of a line-sequential drive method or an active matrix method may be employed. A line-sequential drive method has an advantage that the structure is simple, but in consideration of operation characteristics, an active matrix may often be superior to it, as the case may be. Accordingly, the two need to be used individually depending on the intended use.

In a segment type, patterns are formed so as to display previously determined information, and a determined region is made to emit light. Examples thereof include time and temperature display in digital watches and thermometers, operating state display in audio instruments and induction cookers, and panel display in automobiles.

Examples of the lighting device include a lighting device for in-room lighting, and a backlight in liquid-crystal display devices (for example, see JP 2003-257621 A, JP 2003-277741 A, and JP 2004-119211 A). A backlight is used mainly for the purpose of improving the visibility in non-luminescent devices, and is used, for example, in liquid-crystal display devices, watches, audio instruments, automobile panels, display boards and sign boards. In particular, regarding a backlight for liquid-crystal displays, especially for personal computers whose issue is to be thinned, a conventional system uses a fluorescent lamp or a light guide plate and is therefore difficult to thin, and taking this into consideration, a backlight using the organic EL element is characterized in that it is thin and light.

### 2-2. Other Organic Devices

The polycyclic aromatic compound according to the present invention can be used for manufacturing an organic field effect transistor, an organic thin film solar cell, or the like, in addition to the organic electroluminescent element described above.

The organic field effect transistor is a transistor that controls a current by means of an electric field generated by voltage input, and is provided with a source electrode, a drain electrode, and a gate electrode. When a voltage is applied to the gate electrode, an electric field is generated, and the organic field effect transistor can control a current by arbitrarily damming a flow of electrons (or holes) flowing between the source electrode and the drain electrode. The field effect transistor can be easily miniaturized compared with a simple transistor (bipolar transistor), and is often used as an element constituting an integrated circuit or the like.

The structure of the organic field effect transistor is usually as follows. That is, a source electrode and a. drain electrode are provided in contact with an organic semiconductor active layer formed using the polycyclic aromatic compound according to the present invention, and it is only required to further provide a gate electrode so as to interpose an insulating layer (dielectric layer) in contact with the organic semiconductor active layer. Examples of the element structure include the following structures.
(1) Substrate/gate electrode/insulator layer/source electrode and drain electrode/organic semiconductor active layer;
(2) Substrate/gate electrode/insulator layer/organic semiconductor active layer/source electrode and drain electrode;
(3) Substrate/organic semiconductor active layer/source electrode and drain electrode/insulator layer/gate electrode;
(4) Substrate/source electrode and drain electrode/organic semiconductor active layer/insulator layer/gate electrode.

An organic field effect transistor thus configured can be applied as a pixel driving switching element of an active matrix driving type liquid crystal display or an organic electroluminescent display, or the like.

An organic thin film solar cell has a. structure in which a. positive electrode such as ITO, a hole transport layer, a photoelectric conversion layer, an electron transport layer, and a negative electrode are laminated on a transparent substrate of glass or the like. The photoelectric conversion layer has a p-type semiconductor layer on the positive electrode side, and has an n-type semiconductor layer on the negative electrode side. The polycyclic aromatic compound according to the present invention can be used as a material for a hole transport layer, a p-type semiconductor layer, an n-type semiconductor layer, or an electron transport layer depending on physical properties thereof The polycyclic aromatic compound according to the present invention can function as a hole transport material or an electron transport material in an organic thin film solar cell. The organic thin film solar cell may appropriately include a hole blocking layer, an electron blocking layer, an electron injection layer, a hole injection layer, a smoothing layer, and the like, in addition to the members described above. For the organic thin film solar cell, known materials used for an organic thin film solar cell can be appropriately selected and used in combination.

### 3. Wavelength Conversion Material

The polycyclic aromatic compound of the present invention may be used as a wavelength conversion material.

Currently, the application of a multicoloring technique by a color conversion method to a liquid crystal display, an organic EL display, illumination, and the like has been energetically studied. Color conversion refers to a wavelength conversion of emitted light from a light-emitting substance into light with a longer wavelength and includes, for example, conversion of UV light or blue light into green light or red emitted light. By molding a wavelength conversion material having this color conversion function into a film and then combining the film with a blue light source, three primary colors of blue, green, and red can be taken out; that is, white light can be taken out from a blue light source. A full-color display can be constructed using such a white light source, in which a blue light source is combined with a wavelength conversion film having a color conversion function, as a light source unit and combining the white light source with a liquid crystal-driving part and a color filter. When a, liquid crystal-driving part is omitted, such a white light source is used as a white light source as it is and can be applied to a white light source for, for example, an LED illumination. A full-color organic EL display can be constructed without a metal mask using a combination of a blue organic EL element as a light source and a wavelength conversion film that converts blue light into green light and red light. A low-cost full-color organic micro-LED display can be constructed by using a combination of a blue micro-LED as a light source and a wavelength conversion film that converts blue light into green light and red light.

The polycyclic aromatic compound of the present invention may be used as this wavelength conversion material. By using a wavelength conversion material containing a polycyclic aromatic compound of the present invention, light from a light source or a light-emitting element that generates UV light or blue light with a shorter wavelength into blue light or green light with high color purity, suitable for the use in a display device (a display device using an organic EL element or a liquid crystal display device). The color to be converted may be adjusted by appropriately selecting the substituent of the polycyclic aromatic compound of the present invention, a binder resin used in a wavelength-converting composition that will be described below, or the like. The wavelength conversion material may be prepared as a wavelength-converting composition containing a polycyclic aromatic compound of the present invention. A wavelength conversion film may be formed by using this wavelength-converting composition.

The wavelength-converting composition may contain a binder resin, another additive, and a solvent in addition to the polycyclic aromatic compound of the present invention. As the binder resin, for example, those disclosed in paragraphs [0173]-[0176] of WO 2016/190283 may be used. As the other additive, for example, those disclosed in paragraphs [0177]-[0181] of WO 2016/190283 may be used. As the solvent, the description about the solvents contained in the light-emitting layer forming composition may be referred to.

The wavelength conversion film includes a wavelength conversion layer formed by curing a wavelength-converting composition. A known film formation method may be referred to as a method for constructing a wavelength conversion layer from a wavelength-converting composition. The wavelength conversion film may consist only of wavelength conversion layers formed from a composition containing a polycyclic aromatic compound of the present invention and may include other wavelength conversion layers (for example, a wavelength conversion layer converting blue light into green light or red light, or a wavelength conversion layer converting blue light into green light or red light). Furthermore, the wavelength conversion film may include a substrate layer or a barrier layer for preventing deterioration of a color conversion layer due to oxygen, moisture, or heat.

### EXAMPLES

Hereinunder the present invention is described specifically with reference to Examples, but the present invention is not whatsoever restricted by these Examples.

### Synthesis Example (1)

Synthesis of Compound (1-1)

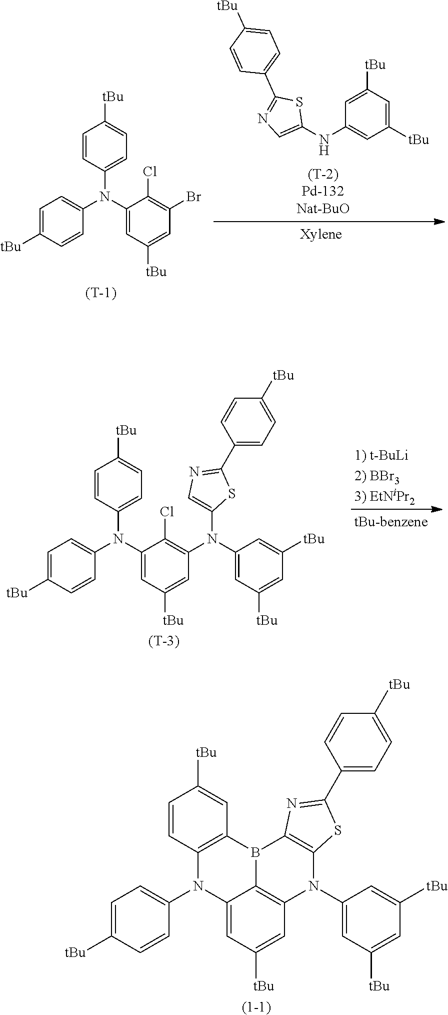

### First Step

Under a nitrogen atmosphere, Compound (T-1) (5.3 g), Compound (T-2) (5.1 g), tert-butoxy sodium (2.9 g), Pd-132 (0.35 g) and xylene (100 ml) were placed in a reactor and heated under reflux for 5 hours. After cooling the reaction mixture to room temperature, the aqueous layer was extracted with toluene. The combined organic layers were washed with water and dried over anhydrous magnesium sulfate. This solution was concentrated under reduced pressure and the residue was purified by silica gel chromatography (toluene) to give Compound (T-3) (6.22 g).

### Synthesis of Compound (1-1)

To a flask containing Compound (T-3) (1.0 g) and tert-butylbenzene (7.0 ml) was added a 1.6M of butyllithium pentane solution (1.5 ml) at −30° C. under a nitrogen atmosphere. After completion of the dropwise addition, the temperature was increased to 60° C., and the reaction mixture was stirred for 2 hours, and then the components having a lower boiling point than that of tert-butylbenzene were distilled off under reduced pressure. The reaction mixture was cooled to −30 ° C., added with boron tribromide (0.61 g), and stirred for 0.5 hours after the temperature was increased to room temperature. Thereafter, the reaction mixture was cooled again to 0° C. and added with N,N-diisopropylethylamine (0.42 ml), and stirred at room temperature until exothermic heat had settled, and then heated and stirred for 3 hours at a temperature increased to 120° C. The reaction mixture was cooled to room temperature, added with an aqueous sodium acetate solution cooled in an ice bath, followed by heptane, and separated. Then, after purification on a silica gel short pass column (addition liquid:toluene), the solvent was distilled off under reduced pressure, and the obtained solid was dissolved in toluene, and heptane was added thereto for reprecipitation to obtain a compound represented by Formula (1-1).

¹H-NMR(CDCl₃):δ=1.0(s,9H), 1.4(s,9H), 1.4(s,18H), 1.5(s,9H), 1.5(s,9H), 6.2(s,1H), 6.3(s,1H), 6.6(d,1H), 7.3(d,2H), 7.4(s,2H), 7.4 to 7.5(m,3H), 7.6(s,1H), 7.7(d,2H), 8.0(d,2H), 9.6(s,1H).

### Synthesis Example (2)

Synthesis of Compound (1-340)

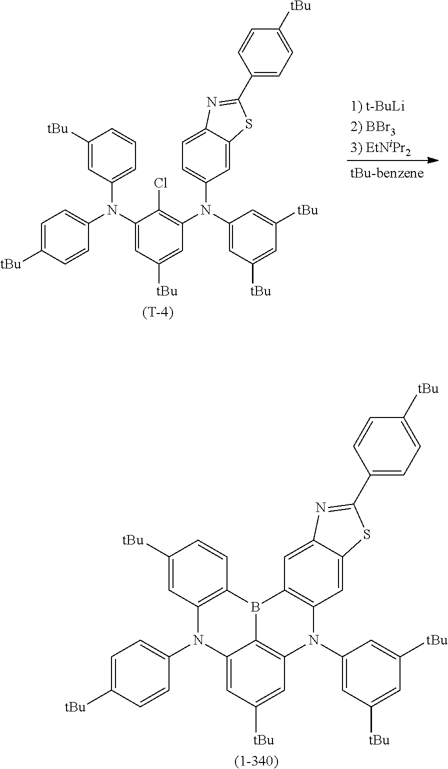

The synthesis was performed in a similar manner to that of Synthesis Example (1). MALDI-TOF-MS(M+H)=890.55

### Synthesis Example (3)

Synthesis of Compound (1-20)

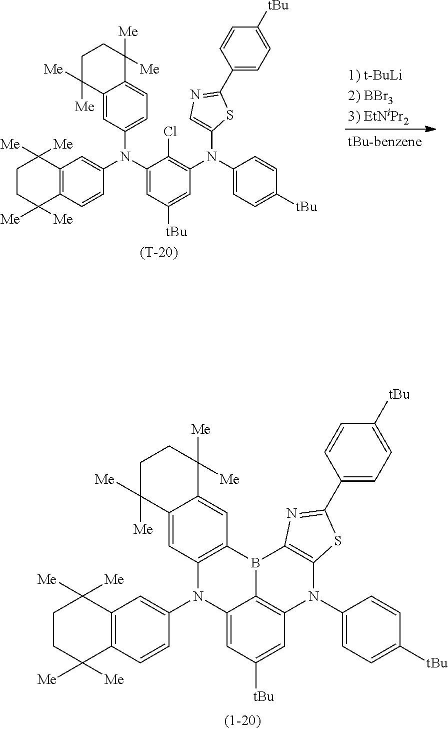

The synthesis was performed in a similar manner to that of Synthesis Example (1). MALDI-TOF-MS(M+H)=892.58

### Synthesis Example (4)

Synthesis of Compound (1-48)

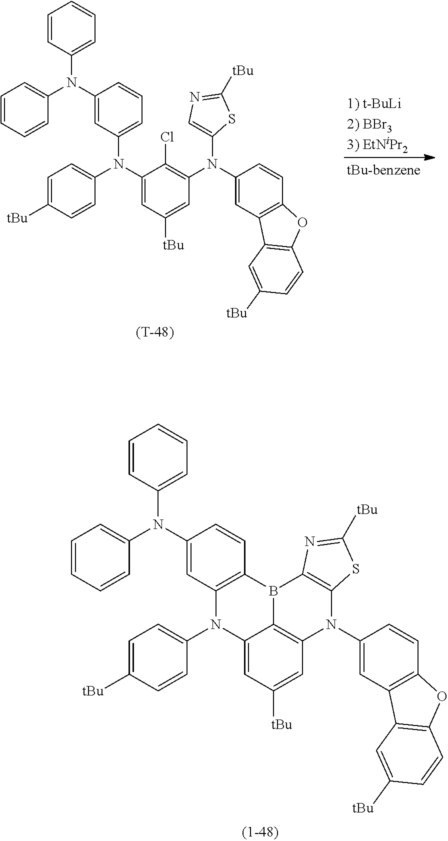 [SMILES: CC(C)(C)c1ccc(N(c2cccc(N(c3ccccc3)c3ccccc3)c2)c2cc(C(C)(C)C)cc(N(c3ccc4oc5ccc(C(C)(C)C)cc5c4c3)c3cnc(C(C)(C)C)s3)c2Cl)cc1 ; "(T-48)" ; CC(C)(C)c1ccc(N2c3cc(N(c4ccccc4)c4ccccc4)ccc3B3c4nc(C(C)(C)C)sc4N(c4ccc5oc6ccc(C(C)(C)C)cc6c5c4)c4cc(C(C)(C)C)cc2c43)cc1]

The synthesis was performed in a similar manner to that of Synthesis Example (1). MALDI-TOF-MS(M+H)−909.47

### Synthesis Example (5)

Synthesis of Compound (1-52)

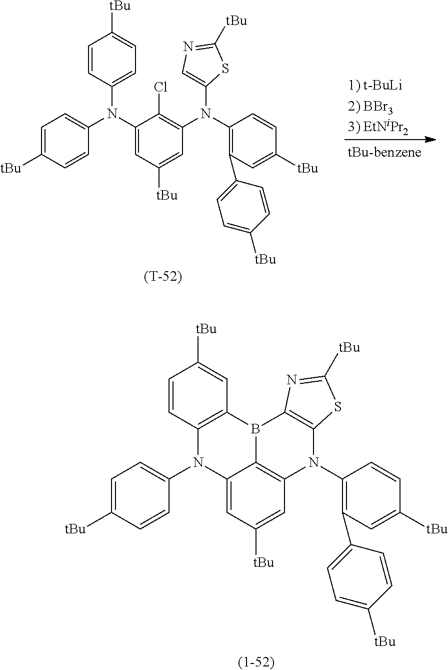 [SMILES: CC(C)(C)c1ccc(-c2cc(C(C)(C)C)ccc2N(c2cnc(C(C)(C)C)s2)c2cc(C(C)(C)C)cc(N(c3ccc(C(C)(C)C)cc3)c3ccc(C(C)(C)C)cc3)c2Cl)cc1 ; "(T-52)" ; CC(C)(C)c1ccc(-c2cc(C(C)(C)C)ccc2N2c3cc(C(C)(C)C)cc4c3B(c3cc(C(C)(C)C)ccc3N4c3ccc(C(C)(C)C)cc3)c3nc(C(C)(C)C)sc32)cc1 ; "(1-52)"]

The synthesis was performed in a similar manner to that of Synthesis Example (1). MALDI-TOF-MS(M+H)=840.54

### Synthesis Example (6)

Synthesis of Compound )1-85)

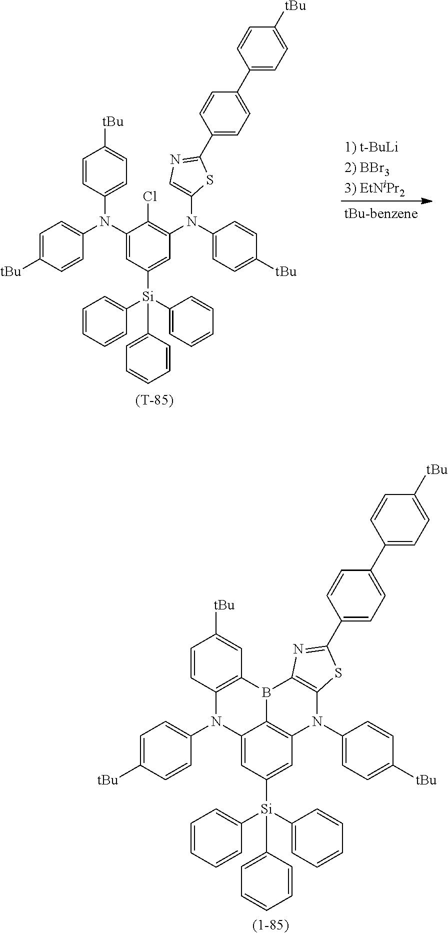

The synthesis was performed in a similar manner to that of Synthesis Example (1). MALDI-TOF-MS(M+H)=1062.54

### Synthesis Example (7)

Synthesis of Compound (1-131)

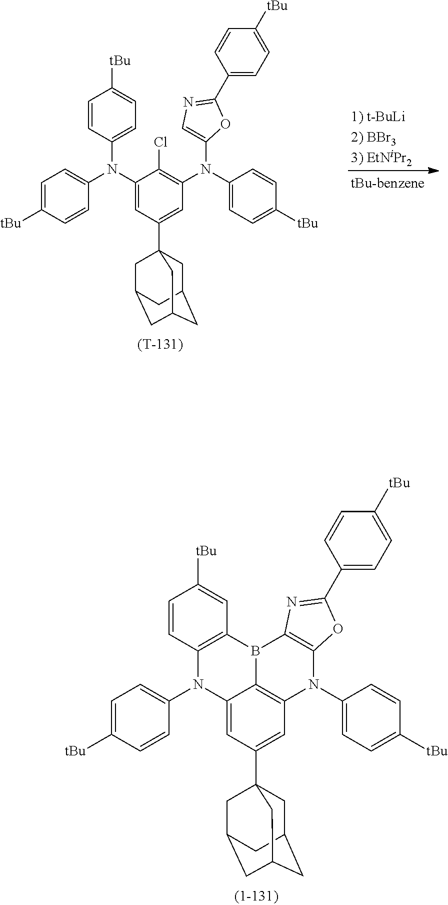 [SMILES: CC(C)(C)c1ccc(-c2ncc(N(c3ccc(C(C)(C)C)cc3)c3cc(C45CC6CC(CC(C6)C4)C5)cc(N(c4ccc(C(C)(C)C)cc4)c4ccc(C(C)(C)C)cc4)c3Cl)o2)cc1 ; CC(C)(C)c1ccc(-c2nc3c(o2)N(c2ccc(C(C)(C)C)cc2)c2cc(C45CC6CC(CC(C6)C4)C5)cc4c2B3c2cc(C(C)(C)C)ccc2N4c2ccc(C(C)(C)C)cc2)cc1]

The synthesis was performed in a similar manner to that of Synthesis Example (1). MALDI-TOF-MS(M+H)=846.55

### Synthesis Example (8)

Synthesis of Compound (1-422)

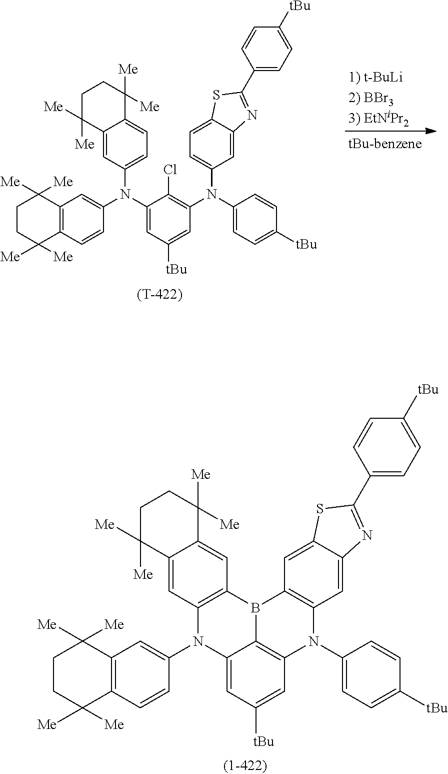 [SMILES: CC(C)(C)c1ccc(-c2nc3cc(N(c4ccc(C(C)(C)C)cc4)c4cc(C(C)(C)C)cc(N(c5ccc6c(c5)C(C)(C)CCC6(C)C)c5ccc6c(c5)C(C)(C)CCC6(C)C)c4Cl)ccc3s2)cc1 ; CC(C)(C)c1ccc(-c2nc3cc4c(cc3s2)B2c3cc5c(cc3N(c3ccc6c(c3)C(C)(C)CCC6(C)C)c3cc(C(C)(C)C)cc(c32)N4c2ccc(C(C)(C)C)cc2)C(C)(C)CCC5(C)C)cc1]

The synthesis was performed in a similar manner to that of Synthesis Example (1). MALDI-TOF-MS(M+H)=942.59

### Synthesis Example (9)

Synthesis of Compound (1-445)

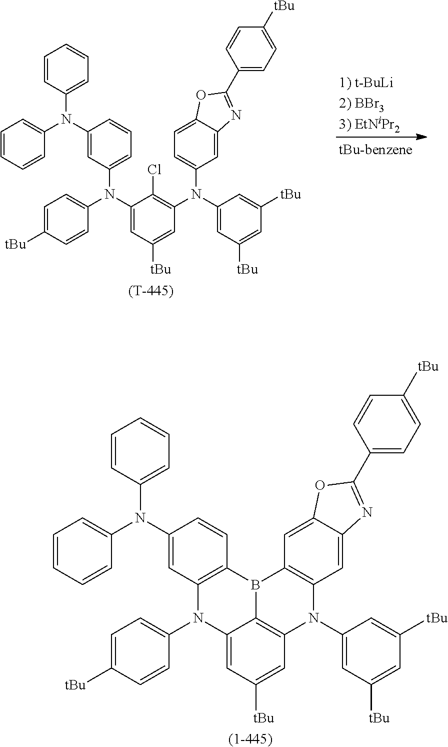

The synthesis was performed in a similar manner to that of Synthesis Example (1). MALDI-TOF-MS(M+H)=985.60

### Synthesis Example (10)

Synthesis of Compound (1-580)

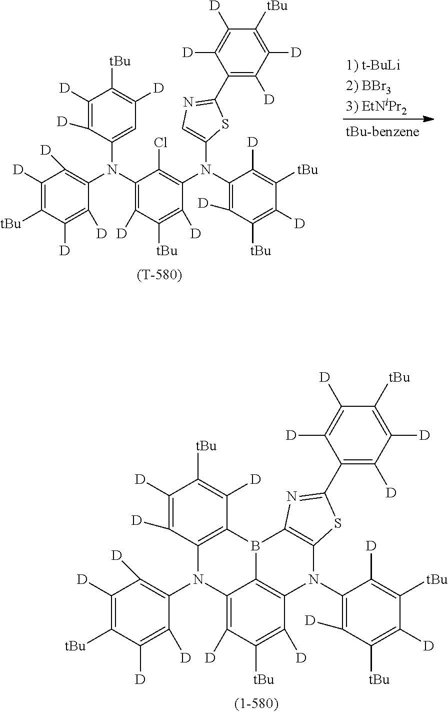 [SMILES: [2H]c1cc(N(c2c([2H])c([2H])c(C(C)(C)C)c([2H])c2[2H])c2c([2H])c(C(C)(C)C)c([2H])c(N(c3cnc(-c4c([2H])c([2H])c(C(C)(C)C)c([2H])c4[2H])s3)c3c([2H])c(C(C)(C)C)c([2H])c(C(C)(C)C)c3[2H])c2Cl)c([2H])c([2H])c1C(C)(C)C ; [2H]c1c([2H])c(C(C)(C)C)c([2H])c([2H])c1-c1nc2c(s1)N(c1c([2H])c(C(C)(C)C)c([2H])c(C(C)(C)C)c1[2H])c1c([2H])c(C(C)(C)C)c([2H])c3c1B2c1c([2H])c(C(C)(C)C)c([2H])c([2H])c1N3c1c([2H])c([2H])c(C(C)(C)C)c([2H])c1[2H]]

The synthesis was performed in a similar manner to that of Synthesis Example (1). MALDI-TOF-MS(M+H)=856.65

### Synthesis Example (11)

Synthesis of Compound (1-635)

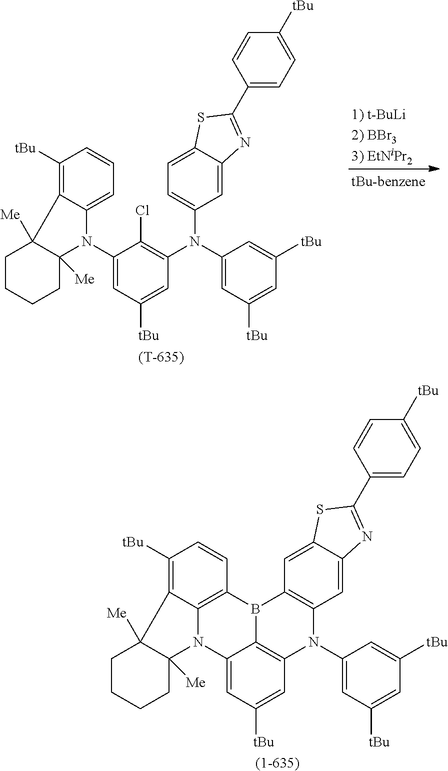

The synthesis was performed in a similar manner to that of Synthesis Example (1). MALDI-TOF-MS(M+H)=872.60

### Synthesis Example (12)

Synthesis of Compound (1-660)

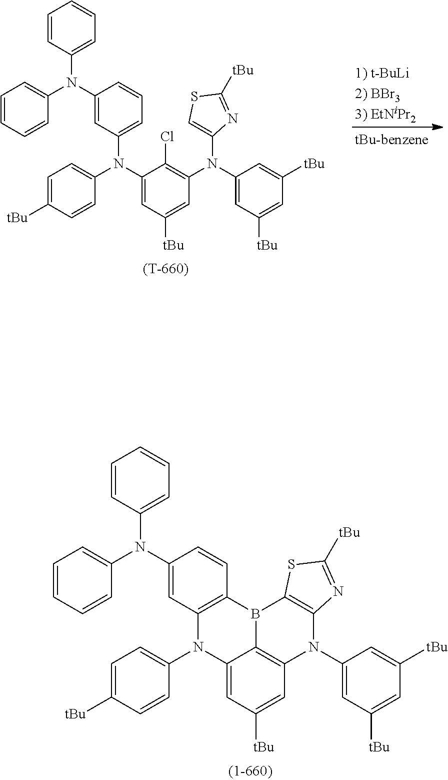 [SMILES: CC(C)(C)c1ccc(N(c2cccc(N(c3ccccc3)c3ccccc3)c2)c2cc(C(C)(C)C)cc(N(c3cc(C(C)(C)C)cc(C(C)(C)C)c3)c3csc(C(C)(C)C)n3)c2Cl)cc1 ; CC(C)(C)c1ccc(N2c3cc(N(c4ccccc4)c4ccccc4)ccc3B3c4sc(C(C)(C)C)nc4N(c4cc(C(C)(C)C)cc(C(C)(C)C)c4)c4cc(C(C)(C)C)cc2c43)cc1]

The synthesis was performed in a similar manner to that of Synthesis Example (1). MALDI-TOF-MS(M+H)=875.53

### Synthesis Example (13)

Synthesis of Compound (1-667)

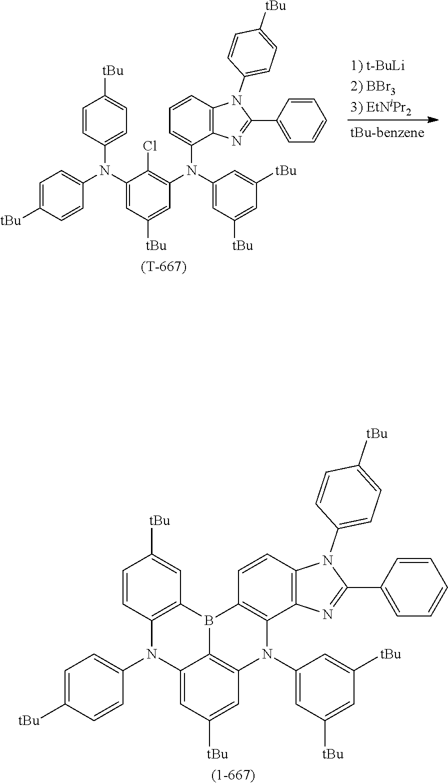

The synthesis was performed in a similar manner to that of Synthesis Example (1). MALDI-TOF-MS(M+H)=949.63

¹H-NMR (500 MHz, CDCl₃, δ (ppm)): 8.90 (1H, s), 8.76 (1H, d), 7.68 (2H, d), 7.66 (1H, s), 7.54 (2H, d), 7.45 (1H, d), 7.35 (2H, s), 7.32-7.30 (4H, m), 7.21 (2H, d), 7.18 (1H, t), 7.09 (2H, d), 7.08 (1H, t), 6.74 (1H, d), 3.56(1H, s), 6.18 (1H, s), 1.46 (9H, s), 1.43 (9H, s), 1.41 (9H, s), 1.32 (18H, s), 1.03 (9H, s).

### Synthesis Example (14)

Synthesis of Compound (1-668)

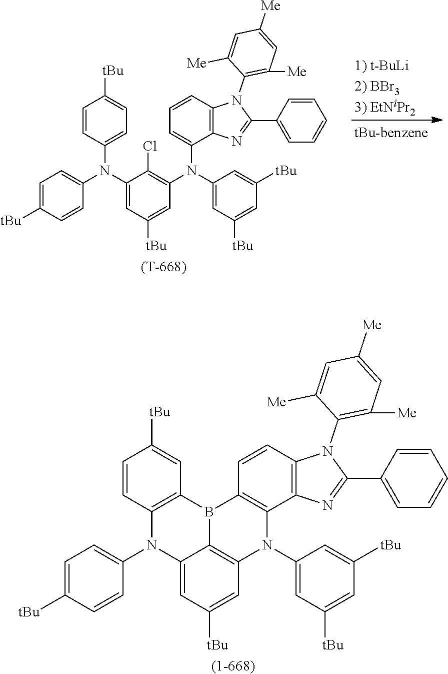

The synthesis was performed in a similar manner to that of Synthesis Example (1). MALDI-TOF-MS(M+H)=935.62

¹H-NMR (500 MHz, DMSO-d₆, δ (ppm)): 8.74 (1H, s), 8.13 (1H, d), 7.76 (2H, d), 7.67 (1H, s), 7.51 (1H, d), 7.29 (2H, d), 7.25-7.09 (9H, m), 6.76 (1H, d), 6.62 (1H, d), 6.58 (1H, s), 6.04 (1H, s), 2.35 (3H, s), 1.73 (6H, s), 1.39 (9H, s), 1.35 (9H, s), 1.27 (18H, s), 0.93 (9H, s).

### Synthesis Example (15)

Synthesis of Compound (1-669)

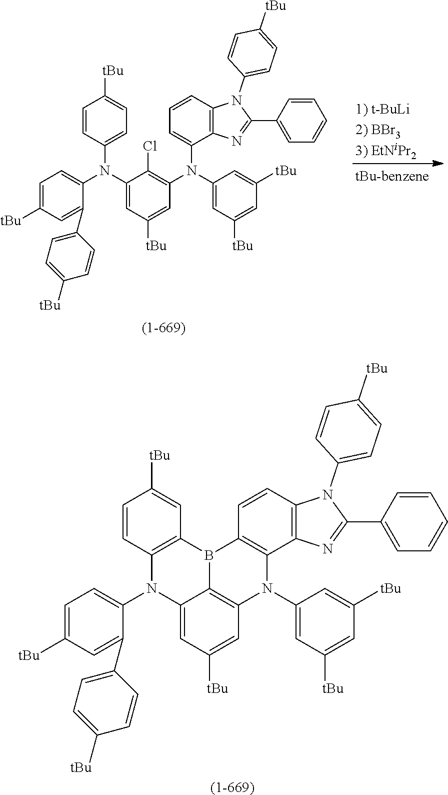 [SMILES: CC(C)(C)c1ccc(-c2cc(C(C)(C)C)ccc2N(c2ccc(C(C)(C)C)cc2)c2cc(C(C)(C)C)cc(N(c3cc(C(C)(C)C)cc(C(C)(C)C)c3)c3cccc4c3nc(-c3ccccc3)n4-c3ccc(C(C)(C)C)cc3)c2Cl)cc1 ; "(1-669)" ; CC(C)(C)c1ccc(-c2cc(C(C)(C)C)ccc2N2c3ccc(C(C)(C)C)cc3B3c4ccc5c(nc(-c6ccccc6)n5-c5ccc(C(C)(C)C)cc5)c4N(c4cc(C(C)(C)C)cc(C(C)(C)C)c4)c4cc(C(C)(C)C)cc2c43)cc1 ; "(1-669)"]

The synthesis was performed in a similar manner to that of Synthesis Example (1). MALDI-TOF-MS(M+H)=1081.73

Other compounds of the invention can be synthesized by appropriately changing a raw material compound by a. method according to the Synthesis Examples described above.

<Evaluation methods of Fundamental Properties>

### Preparation of Samples

When evaluating the absorption characteristics and the emission characteristics (fluorescence and phosphorescence) of a compound to be evaluated, there may be a case where a compound to be evaluated is dissolved in a solvent and evaluated in a solvent, and a case where the compound is evaluated in a thin film state. Further, in evaluation in the form of a thin film, two cases may be employed depending on the mode of using a compound to be evaluated in an organic EL element, that is, a target compound alone is formed into a thin film in one case, or a target compound is dispersed in an appropriate matrix material to form a thin film in another case. Here, a thin film obtained by vapor-depositing only a compound to be evaluated is referred to as a “single film”, and a thin film obtained by coating and drying a coating liquid containing a compound to be evaluated and a matrix material is referred to as a “coating film”

As a matrix material, commercially-available PMMA (polymethyl methacrylate) can be used. In this embodiment, a PMMA and a compound to he evaluated are dissolved in toluene, and then a thin film is formed on a transparent support substrate (10 mm×10 mm) made of quartz by a spin-coating method to prepare a sample.

In addition, a thin film sample when the matrix material is a host compo d is prepared as follows.

A transparent support substrate made of quartz (10 mm×10 mm×1.0 mm) iis fixed to a substrate holder of a commercially available vapor deposition apparatus (manufactured by Choshu Industry Co., Ltd.). After mounting a molybdenum deposition boat containing a host compound and a molybdenum deposition boat containing a dopant material, the vacuum chamber is reduced to 5×10⁻⁴ Pa. Next, both the deposition boat with a host compound therein and the deposition boat with a dopant material therein were heated at the same time and co-deposited to form a film having an appropriate thickness, thereby providing a mixed thin film (sample) of the host compound and the dopant material. Here, the deposition rate is controlled according to the set mass ratio of the host compound and the dopant material.

### Evaluation of Absorption Characteristics and Emission Characteristics

Using a UV-visible light-IR spectrophotometer (UV-2600, by Shimadzu Corporation), the absorption spectrum of the sample is measured. For measurement of the fluorescent spectrum or the phosphorescent spectrum of the sample, a fluorospectrophotometer (F-7000, by Hitachi High-Tech Corporation) is used.

In measurement of the fluorescent spectrum, the sample is excited at an appropriate excitation wavelength at room temperature to measure the photoluminescence thereof. In measurement of the phosphorescent spectrum, the sample is immersed in a liquid nitrogen (temperature 77 K) using the accompanying cooling unit. For observing the phosphorescent spectrum, the lag time from excitation light irradiation to measurement start is regulated using an optical chopper. The sample is excited at an appropriate excitation wavelength to measure the photoluminescence thereof.

Further, using an absolute PL quantum yield measuring device (C9920-02G, by Hamamatsu Photonics KK), the photoluminescence quantum yield (PLQY) is measured.

Next, the evaluation of basic physical properties of the polycyclic aromatic compound of the present invention will be described.

### Evaluation of Fluorescence Lifetime (Delayed Fluorescence)

Using a fluorescence lifetime measuring device (C11367-01, by Hamamatsu Photonics KK), the fluorescence lifetime was measured at 300 K. Specifically, a light-emitting component having a fast fluorescence lifetime and a light-emitting component having a slow fluorescence lifetime were observed at a maximum light emission wavelength to be measured at a suitable excitation wavelength. In fluorescence lifetime measurement at room temperature for an ordinary organic EL material that emits fluorescence, a slow light emission component in which a phosphorescence-derived triplet component may participate owing to deactivation of the triplet component by heat is observed little. In the case where a slow light emission component is observed in a target compound, this indicates that the delayed fluorescence was observed by transfer of triplet energy having a long excitation lifetime to singlet energy by thermal activation.

### Calculation of Energy Gap (Eg)

From the long wavelength end A (nm) of the absorption spectrum obtained according to the above-mentioned method, Eg=1240/A is calculated.

### Measurement of Ionization Potential (Ip)

The transparent support substrate (28 mm×26 mm×0.7 mm) deposited ITO (indium-tin oxide) is fixed to the substrate holder of a commercially available vapor deposition apparatus (manufactured by Choshu Industry Co., Ltd.), after mounting the molybdenum deposition boat containing the target compound, the vacuum chamber is reduced to 5×10⁻⁴ Pa. Next, the deposition boat is heated to evaporate the target compound, thereby forming a single film (Neat film) of the target compound.

Using the obtained single film as a sample, the ionization potential of the target compound is measured using a photoelectron spectrometer (Sumitomo Heavy Industries, Ltd., PYS-201).

### Calculation of Electron Affinity (Ea)

The electron affinity can he estimated from the difference between the ionization potential measured by the above method and the energy gap calculated by the above method.

### Measurement of Excited Singlet Energy Levels E(S,Sh) and Excited Triplet Energy Levels E(T,Sh)

For a single film of a. target compound formed on a glass substrate, a fluorescence spectrum is observed with the second absorption peak from the long wavelength side of the absorption spectrum as the excitation light at 77K, and an excited singlet energy level E(S, Sh) is obtained from a shoulder on the short wavelength side of the peak of the fluorescence spectrum.

In a single film of the target compound formed on the glass substrate, a phosphorescence spectrum is observed with the second absorption peak from the long wavelength side of the absorption spectrum as the excitation light at 77K, and an excited triplet energy level E(T, Sh) is obtained from a shoulder on the short wavelength side of the peak of the phosphorescence spectrum.

### <Evaluation of Organic Elements>

As described above, since the present compound is characterized by an appropriate energy gap (Eg), a high triplet exciting energy (E_{T}), and a small ΔE_{ST}, it can be expected to be applied to, for example, a light-emitting layer and a charge-transporting layer, and in particular, it can be expected to be applied to a light-emitting layer.

### Evaluation Items and Methods

Evaluation items include driving voltage (V), emission wavelength (nm), CIE chromaticity (x, y), external quantum efficiency (%), maximum wavelength of emission spectrum (nm) and full width at half maximum (nm), etc. As these evaluation items, values at an appropriate light emission luminance can be used.

The quantum efficiency of a light emitting element includes internal quantum efficiency and external quantum efficiency. The internal quantum efficiency represents a proportion at which external energy injected as electrons (or holes) into the luminescent layer of the light emitting element is converted into photons in a pure manner. On the other hand, the external quantum efficiency is calculated based on an amount of photons emitted to an outside of the light emitting element. The photons generated in the luminescent layer are continuously partly absorbed or reflected inside the light emitting element and are not emitted to the outside of the light emitting element, and therefore the external quantum efficiency becomes lower than the internal quantum efficiency.

A method of measuring spectral radiance (emission spectrum) and the external quantum efficiency is as described below. Luminescence of a device was produced by applying a voltage by using a voltage/current generator R6144 made by Advantest Corporation, A spectral radiance in a visible light region was measured from a direction perpendicular to the luminescent surface by using a spectroradiometer SR-3AR made by Topcon Technohouse Corporation. A numerical value obtained by dividing a measured spectral radiance value of each wavelength component under assumption that the luminescent surface is a completely diffusing surface by wavelength energy and multiplying the resulting value with is the number of photons at each wavelength. Next, the number of photons in the whole wavelength region observed was integrated, and the resulting value was taken as the total number of photons emitted from the device. A numerical value obtained by dividing an applied current value by an elementary charge was taken as the number of carriers injected into the device. Then, a numerical value obtained by dividing the total number of photons emitted from the device by the number of carriers injected into the device is the external quantum efficiency. Further, the half-width of the emission spectrum is determined as the width between the upper and lower wavelengths at which the intensity becomes 50% using the maximum emission wavelength as the center.

Next, production and evaluation of an organic EL element using the polycyclic aromatic compound of the present invention will be described.

### Structure of Organic EL Element

Using the polycyclic aromatic compound of the present invention, an organic EL element of the following element configuration A and element configuration B was manufactured.

### [Element Configuration A]

The materials of the layers in the organic EL elements of Examples A-1 to A-15 and Comparative Examples 1 to 3 are shown in Table 1 below

TABLE 1

| | Hole | Hole | Hole | Hole | | | Electron | Electron | |
|---|---|---|---|---|---|---|---|---|---|
| | injection | injection | transport | transport | Light-emitting layer | | transport | transport | Cathode |
| | layer 1 | layer 2 | layer 1 | layer 2 | (25 nm) | | layer 1 | layer 2 | 1 nm/ |
| | (40 nm) | (5 nm) | (45 nm) | (10 nm) | Hose | Dopant | (5 nm) | (25 nm) | 100 nm |
| Example | HI | HAT- | HT-1 | HT-2 | BH | Compound | ET-1 | ET-2 + | LiF/A1 |
| A-1 | | CN | | | | (1-1) | | Liq | |
| Example | HI | HAT- | HT-1 | HT-2 | BH | Compound | ET-1 | ET-2 + | LiF/A1 |
| A-2 | | CN | | | | (1-340) | | Liq | |
| Example | HI | HAT- | HT-1 | HT-2 | BH | Compound | ET-1 | ET-2 + | LiF/A1 |
| A-3 | | CN | | | | (1-20) | | Liq | |
| Example | HI | HAT- | HT-1 | HT-2 | BH | Compound | ET-1 | ET-2 + | LiF/A1 |
| A-4 | | CN | | | | (1-48) | | Liq | |
| Example | HI | HAT- | HT-1 | HT-2 | BH | Compound | ET-1 | ET-2 + | LiF/A1 |
| A-5 | | CN | | | | (1-52) | | Liq | |
| Example | HI | HAT- | HT-1 | HT-2 | BH | Compound | ET-1 | ET-2 + | LiF/A1 |
| A-6 | | CN | | | | (1-85) | | Liq | |
| Example | HI | HAT- | HT-1 | HT-2 | BH | Compound | ET-1 | ET-2 + | LiF/A1 |
| A-7 | | CN | | | | (1-131) | | Liq | |
| Example | HI | HAT- | HT-1 | HT-2 | BH | Compound | ET-1 | ET-2 + | LiF/A1 |
| A-8 | | CN | | | | (1-422) | | Liq | |
| Example | HI | HAT- | HT-1 | HT-2 | BH | Compound | ET-1 | ET-2 + | LiF/A1 |
| A-9 | | CN | | | | (1-445) | | Liq | |
| Example | HI | HAT- | HT-1 | HT-2 | BH | Compound | ET-1 | ET-2 + | LiF/A1 |
| A-10 | | CN | | | | (1-580) | | Liq | |
| Example | HI | HAT- | HT-1 | HT-2 | BH | Compound | ET-1 | ET-2 + | LiF/A1 |
| A-11 | | CN | | | | (1-660) | | Liq | |
| Example | HI | HAT- | HT-1 | HT-2 | BH | Compound | ET-1 | ET-2 + | LiF/A1 |
| A-12 | | CN | | | | (1-635) | | Liq | |
| Example | HI | HAT- | HT-1 | HT-2 | BH | Compound | ET-1 | ET-2 + | LiF/A1 |
| A-13 | | CN | | | | (1-667) | | Liq | |
| Example | HI | HAT- | HT-1 | HT-2 | BH | Compound | ET-1 | ET-2 + | LiF/A1 |
| A-14 | | CN | | | | (1-668) | | Liq | |
| Example | HI | HAT- | HT-1 | HT-2 | BH | Compound | ET-1 | ET-2 + | LiF/A1 |
| A- 15 | | CN | | | | (1-669) | | Liq | |
| Comparative | HI | HAT- | HT-1 | HT-2 | BH | Comparative | ET-1 | ET-2 + | LiF/A1 |
| Example | | CN | | | | Compound | | Liq | |
| 1 | | | | | | (1) | | | |
| Comparative | HI | HAT- | HT-1 | HT-2 | BH | Comparative | ET-1 | ET-2 + | LiF/A1 |
| Example | | CN | | | | Compound | | Liq | |
| 2 | | | | | | (2) | | | |
| Comparative | HI | HAT- | HT-1 | HT-2 | BH | Comparative | ET-1 | ET-2 + | LiF/A1 |
| Example | | CN | | | | Compound | | Liq | |
| 3 | | | | | | (3) | | | |

In Table 1, “HI” is N⁴, N^{4′}-diphenyl-N⁴, N^{4′}-bis(9-phenyl-9H-carbazol-3-y1)-[1,1′-biphenyl]-4,4′-diamine, “HAT-CN” is 1,4,5,8,9,12-hexaazatriphenylenehexacarbonitrile, “HT-1” is N-(|1,1′-biphenyl]-4-yl-9,9-dimethyl-N-[4-(9-phenyl-9H-carbazol-3-yl)phenyl]-9H-fluorene-2-amine and “HT-2” is N,N-bis(4-dibenzo[b,d]furan-4)-yl)-[1,1′;4′,1”-terphenyl]-4-amine, “BH” is 2-(10-phenylanthracene-9-yl)dibenzo[b,d]furan, “ET-1” is 9,9′-[(5-(6-(1,1′-biphenyl)-4-yl)-2-phenylpyrimidine-4-yl)-1,3-phenylene]bis(9H-carbazole) and “ET-2” is 2-ethyl-1-(4-(10-phenylanthracene-9-yl)phenyl)-1H-benzo[d]imidazole. Chemical tructures thereof together with the structures of “Liq”. Comparative compound (1) (a compound described in WO 2015/102118), Comparative compound (2) (a compound described in WO 2019/164331) and Comparative compound (3) (a compound described in WO 2020/251049) are shown below.

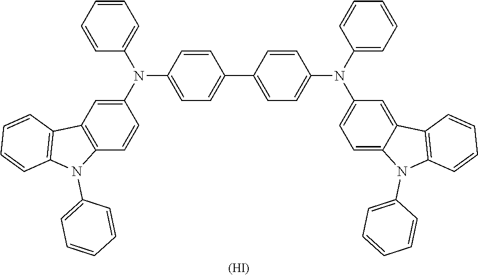 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "(HI)"]

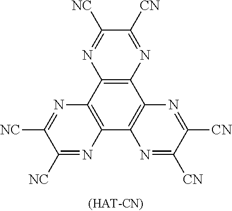 [SMILES: N#Cc1nc2c3nc(C#N)c(C#N)nc3c3nc(C#N)c(C#N)nc3c2nc1C#N]

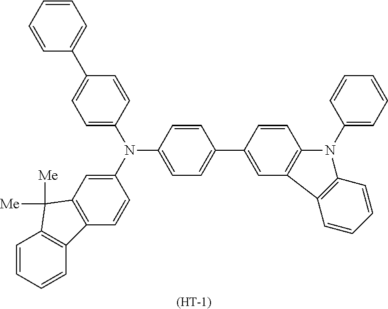 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; "(HT-1)"]

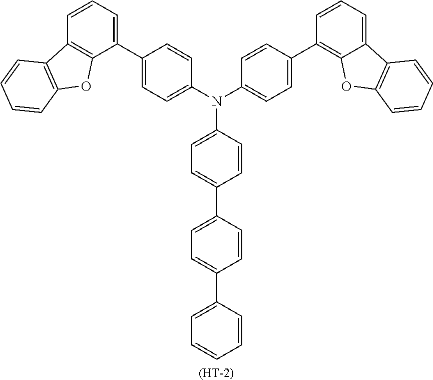

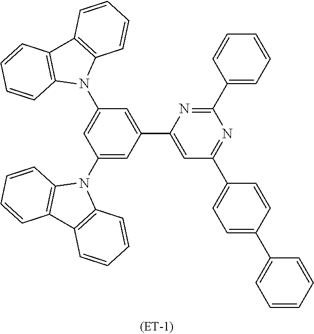 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

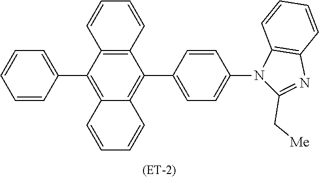 [SMILES: CCc1nc2ccccc2n1-c1ccc(-c2c3ccccc3c(-c3ccccc3)c3ccccc23)cc1]

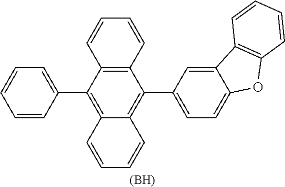

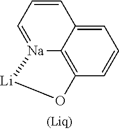

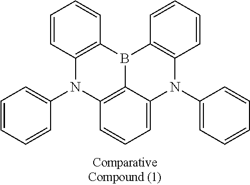 [SMILES: c1ccc(N2c3ccccc3B3c4ccccc4N(c4ccccc4)c4cccc2c43)cc1]

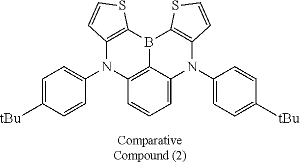 [SMILES: CC(C)(C)c1ccc(N2c3ccsc3B3c4sccc4N(c4ccc(C(C)(C)C)cc4)c4cccc2c43)cc1]

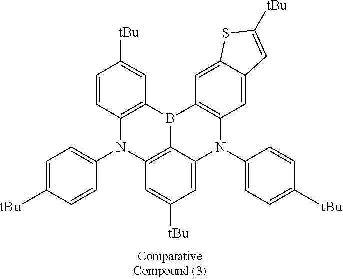 [SMILES: CC(C)(C)c1ccc(N2c3ccc(C(C)(C)C)cc3B3c4cc5sc(C(C)(C)C)cc5cc4N(c4ccc(C(C)(C)C)cc4)c4cc(C(C)(C)C)cc2c43)cc1]

### Example A-1

A 26 mm×28 mm×0.7 mm glass substrate (manufactured by Optoscience Co., Ltd.) obtained by polishing an ITO film formed to a thickness of 180 nm to a thickness of 150 nm by sputtering is used as a transparent supporting substrate, The transparent support substrate was fixed to a substrate holder of a commercially available vapor deposition apparatus (manufactured by Showa Vacuum Co., Ltd.), molybdenum deposition boats containing HI, HAT-CN, HT-1, HT-2, BH, Compound (1-1), ET-1 and ET-2, respectively, an aluminum nitride deposition boat containing Liq, LiF and aluminum were mounted.

Each layer as described below is formed sequentially on the ITO film of the transparent supporting substrate. The vacuum chamber was depressurized to 5×10⁻⁴ Pa, a deposition was performed by first heating HI to a film thickness of 40 nm, then a deposition was performed by heating HAT-CN to a film thickness of 5 nm, then a deposition was performed by heating HT-1 to a film thickness of 45 nm, and then a deposition was performed by heating HT-2 to a film thickness of 10 nm to form a four-layered hole layer, Next, a deposition was performed by simultaneously heating BH and Compound (1-1) to form a light-emitting layer to a film thickness of 25 nm. The deposition rate was adjusted so that the mass ratio of BH to Compound (1-1) was approximately 97:3 Further, a deposition was performed by heating ETI to a film thickness of 5 nm, and then a deposition was performed by simultaneously heating ET-2 and Liq to a film thickness of 25 nm to form an electronic layer composed of two layers. A deposition rate was adjusted to be approximately 50:50 in a mass ratio of ET-2 to Liq. The deposition rate for each layer was 0.01 to 1 nm/sec. Thereafter, a deposition was performed by heating LiF at a deposition rate of 0.01 to 0.1 nm/sec to a film thickness of inm, and then a deposition was performed by heating aluminum to a film thickness of 100 nm to form a cathode, thereby obtaining an organic EL element.

### Examples A-2 to A-15, Comparative Examples 1 to 3

An organic EL element was obtained in the same manner as that in Example A-1, except that the compounds described in Table I were used instead of Compound (1-1),

### Evaluation Items and Methods

Evaluation items include driving voltage (V), emission wavelength (nm), CIE chromaticity (x, y), external quantum efficiency (%), maximum wavelength of the emission spectrum (nm) and full width at half maximum (nm), etc. As these evaluation items, values at the time of 1000 cd/m² light emission can be used, for example.

The quantum efficiency of a light-emitting element includes internal quantum efficiency and external quantum efficiency. The internal quantum efficiency represents a proportion at which external energy injected as electrons (or holes) into the light-emitting layer of the light-emitting element is converted into photons in a pure manner. On the other hand, the external quantum efficiency is calculated based on the amount of this photon emitted to the outside of the light-emitting element. The photons generated in the light-emitting layer, a portion of which is absorbed or continues to be reflected inside the light-emitting element, are not emitted to the outside, the external quantum efficiency is thus lower than the internal quantum efficiency.

Measurement methods of spectral radiance (emission spectrum) and external quantum efficiency are as follows. A voltage/current generator R6144 manufactured by Advantest Corporation is used to apply a voltage at which the luminance of the element becomes 1000 cd/m² to cause the element to emit light. The spectral radiance is measured in the visible-light range from perpendicular to the emitting surface using a spectroradiometer SR-3AR manufactured by TOPCON. A numerical value obtained by dividing a measured spectral radiance value of each wavelength component under assumption that the luminescent surface is a completely diffusing surface by wavelength energy and multiplying the resulting value with it is the number of photons at each wavelength. Then, the number of photons in the entire wavelength region observed is integrated to obtain the total number of photons emitted from the element. A numerical value obtained by dividing an applied current value by an elementary charge was taken as the number of carriers injected into the element. Then, a numerical value obtained by dividing the total number of photons emitted from the element by the number of carriers injected into the element is the external quantum efficiency. Further, the half-width of the emission spectrum is determined as the width between the upper and lower wavelengths at which the intensity becomes 50% using the maximum emission wavelength as the center.

For the organic EL elements of Examples A-1 to A-15 and Comparative Examples 1 to 3, DC voltages were applied with the ITO electrode as an anode and LiF/aluminum electrode as a cathode, the properties of the organic EL elements during 1000 cd/m² light emission were measured, and the time for which luminance of 90% or more of the initial luminance was maintained was measured,

Results are shown in Table 2.

TABLE 2

| | time 90% | | |
|---|---|---|---|
| | or more of | | external |
| | initial luminance | Voltage | quantum |
| | maintained(hr) | (V) | efficiency (%) |
| Example A-1 | 168 | 3.72 | 6.98 |
| Example A-2 | 222 | 3.95 | 7.39 |
| Example A-3 | 236 | 3.92 | 7.21 |
| Example A-4 | 195 | 4.01 | 7.30 |
| Example A-5 | 225 | 4.12 | 7.06 |
| Example A-6 | 230 | 4.15 | 6.89 |
| Example A-7 | 219 | 3.97 | 7.15 |
| Example A-8 | 223 | 4.12 | 7.23 |
| Example A-9 | 241 | 4.01 | 7.01 |
| Example A-10 | 230 | 4.00 | 7.08 |
| Example A-11 | 221 | 3.97 | 7.46 |
| Example A-12 | 235 | 4.12 | 7.50 |
| Example A-13 | 219 | 3.96 | 7.11 |
| Example A-14 | 201 | 3.88 | 7.21 |
| Example A-15 | 225 | 3.90 | 7.69 |
| Comparative Example 1 | 104 | 4.02 | 5.94 |
| Comparative Example 2 | 118 | 4.21 | 5.49 |
| Comparative Example 3 | 99 | 4.29 | 5.69 |

### [Element Configuration B]

The material composition of each layer in the organic EL element of Example B-1 is shown in Table 3 below.

TABLE 3

| | Hole | Hole | Light- | | | | Electron | |
|---|---|---|---|---|---|---|---|---|
| | injection | transport | blocking | Electron transport layer (30 nm) | | | transport | Cathode |
| | layer | layer | layer | | Assisting | Emitting | layer | (1 nm/ |
| | (40 nm) | (15 nm) | (20 nm) | Host | Dopant | Dopant | (30 nm) | 100 nm) |
| Example | NPD | TcTa | mCP | mCBP | Compound | Compound | TSPO1 | LiF/Al |
| B-1 | | | | | (2PXZ-TAZ) | (1-1) | | |

In Table 3, “NPD” is N,N′-diphenyl-N,N′-dinaphthyl-4,4′-diaminobiphenyl, “TcTa” is
4,4′,4′-tris(N-carbazolyl)triphenylamine, “mCP” is 1,3-bis(N-carbazolyl)benzene, “mCBP” is
3,3′-bis(N-carbazolyl)-1,1′-biphenyl, “TSPO1” is diphenyl[4-(triphenylsilyl)phenyl]phosphine
oxide, and “2PXZ-TAZ” is 10,10′-((4-phenyl-4H-1,2,4-triazole-3,5-
diyl)bis(4,1)phenylene))bis(10H-phenoxazine). The chemical structures are shown below.

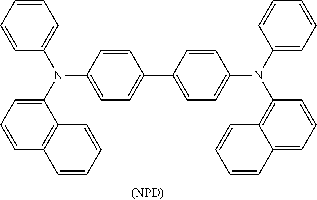

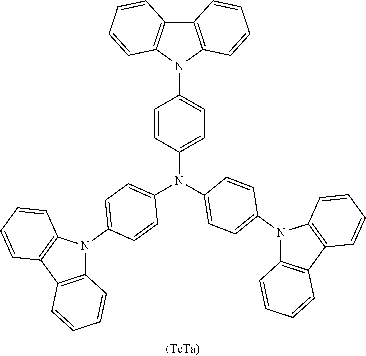 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; "(TcTa)"]

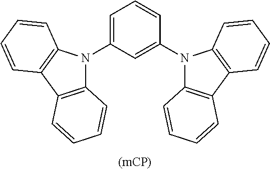

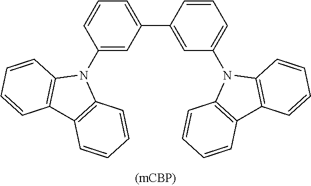 [SMILES: c1cc(-c2cccc(-n3c4ccccc4c4ccccc43)c2)cc(-n2c3ccccc3c3ccccc32)c1]

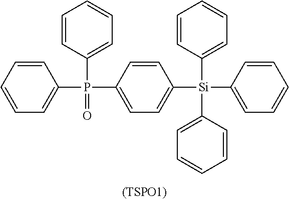 [SMILES: O=P(c1ccccc1)(c1ccccc1)c1ccc([Si](c2ccccc2)(c2ccccc2)c2ccccc2)cc1 ; "(TSPO1)"]

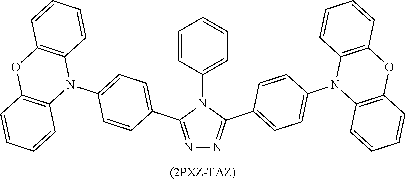 [SMILES: c1ccc(-n2c(-c3ccc(N4c5ccccc5Oc5ccccc54)cc3)nnc2-c2ccc(N3c4ccccc4Oc4ccccc43)cc2)cc1]

### Example B-

### Element Configuration B: Element in which the Host Compound is mCBP, the Assisting Dopant is 2PXZ-TAZ, and the Emitting Dopant is Compound (1-1))

A glass substrate having a size of 26 mm×28 mm×0.7 mm prepared by forming a film of ITO having a thickness of 200 nm by sputtering and polishing the ITO film to 50 nm (manufactured by Opto Science, Inc.) is used as a transparent supporting substrate. The transparent support substrate was fixed to a substrate holder of a commercially available deposition apparatus (manufactured by Choshu Industry Co., Ltd.), tantalum deposition boats each containing NPD, mCP, mCBP. 2PXZ-TAZ, Compound (1-1), and TSPO1 respectively, and aluminum nitride deposition boat containing LiF and aluminum were mounted.

The following layers were sequentially formed on the ITO film of the transparent supporting substrate. The vacuum chamber was depressurized to 5×10⁻⁴ Pa, a deposition was performed by heating NPD to a thickness of 40 nm, and then TcTa to a thickness of 15 nm to form a two-layered hole injecting and transporting layer. Next, a deposition was performed by heating mCP to a thickness of 15 nm to form an electron blocking layer. Next, a co-deposition was performed by simultaneously heating mCBP as a host, 2PXZ-TAZ as an assisting dopant, and compound (1-1) as an emitting dopant to form a light-emitting layer by co-evaporation to a thickness of 20 nm. The deposition rate was adjusted so that the mass ratios of the host, assisting dopant and emitting dopant were approximately 90 to 9 to 1. Next, a deposition was performed by heating TSPO1 to a thickness of 30 nm to form an electron-transporting layer. The deposition rate of each of the above layers was 0.01 to 1 nm/sec. Thereafter, a deposition was performed by heating LiF at a deposition rate of 0.01 to 0.1 nm/sec to a film thickness of 1 nm, and then a deposition was performed by heating aluminum to a film thickness of 100 nm to form a cathode, thereby obtaining an organic EL element. At this time, the deposition rate of aluminum was adjusted to be 1 nm to 10 nm/sec.

For the element of Example B-1, DC voltages were applied with the ITO electrode as an anode and LiF/aluminum electrode as a cathode, and the properties of the element during 100 cd/m² light emission were measured, and the external quantum efficiency was 23.2%.

Element configuration A is an element configuration, characterized in that the time for maintaining the luminance at a high luminance is long, whereas the Element configuration B is an element configuration, characterized in that it is possible to obtain a high external quantum efficiency.

### REFERENCE SIGNS LIST

100 Organic electroluminescent element
101 Substrate
102 Anode
103 Hole Injection Layer
104 Hole Transport Layer
105 Light-Ernihing Layer
106 Electron Transport Layer
107 Electron Injection Layer
108 Cathode

1. A polycyclic aromatic compound hawing a structure consisting of one or two or more of structural units represented by Formula (1): 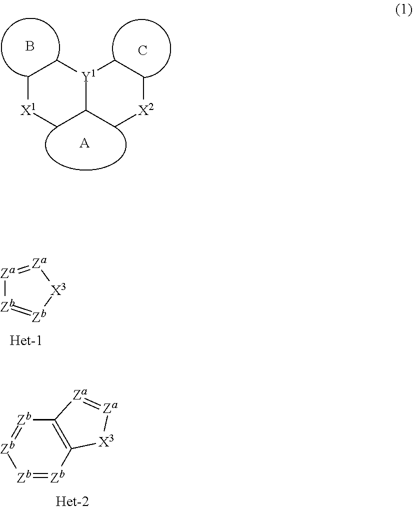
wherein:
A ring, B ring, and C ring are each independently an optionally substituted aryl ring or an optionally substituted heteroaryl ring, and at least one ring selected from the group consisting of A ring, B ring and C ring in the structure is a ring represented by Formula (Het-1) or Formula. (He-2), provided that the A ring is not a ring represented by Formula (Het-1);
Y¹ is B, P, P═O, P═S, Al, Ga, As, Si—R, or Ge—R, R in Si—R and Ge—R is a substituted or unsubstituted aryl, a substituted or unsubstituted heteroaryl, a substituted or unsubstituted or a substituted or unsubstituted cycloalkyl;
X¹ and X² are each independently >O, >N—R, >C(—R₂, >Si(—R)₂, >S, or >Se, wherein R in >N—R is hydrogen, a substituted or unsubstituted aryl, a substituted or unsubstituted heteroaryl, a substituted or unsubstituted alkyl, or a substituted or unsubstituted cycloalkyl, and R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl, two R's in >C(—R)₂ and two R's in >Si(—R)₂ may be bonded to each other to form a ring, wherein R in >N—R, >C(—R)₂ and >Si(—R)₂ may be bonded to A and/or B rings, or A and/or C rings;
in formula (Het-1) and formula (Het-2),
X³ is >O, >N—R, >C(—R₂, >S, or >Se, wherein R in >N—R is hydrogen, a substituted or unsubstituted aryl, a substituted or unsubstituted heteroaryl, a substituted or unsubstituted alkyl, a substituted or unsubstituted cycloalkyl, R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl, and one of Z^{a} is N and the other is N or C—R^{Z};
in Formula (H-Tet-1),
Z^{b}s are carbons directly bonded to Y¹ and X¹, or Y¹ and X²:
in Formula (Het-2),
any two or three consecutive Z^{b}s are carbons that directly bonded to Y¹, and X¹ and/or X² in Formula (1),
the remaining Z^{b}s are each independently N or C—R^{Z}, or
Z^{b}═Z^{b} may be >O, >N—R, >C—(R)₂, >Si(—R)₂, >S, or >Se, wherein R in >N—R and R's in C—(R)₂ and >Si(—R)₂ are each independently hydrogen, a substituted or unsubstituted aryl, a substituted or unsubstituted heteroaryl, a substituted or unsubstituted alkyl, a substituted. or unsubstituted cycloalkyl, and two R's in >C(—R)₂ and >Si(—R)₂ may be bonded to each other to form a ring, R^{Z} is hydrogen or a substituent;
in Formula (Het-2),
two adjacent R^{Z}s may be bonded to each other to form a ring, and the ring formed may be substituted;
at least one of aryl ring or heteroaryl ring in the structure may be fused with at least one cycloalkane, at least one hydrogen in the cycloalkane may be substituted, and at least one —CH₂— in the cycloalkane may be replaced with —O—; and
at least one hydrogen in the structure may be substituted with cyano a halogen, or deuterium.

2. The polycyclic aromatic compound according to claim 1, wherein at least one ring selected from the group consisting of B ring and C ring in the structure is a ring represented by Formula (Het-1).

3. The polycyclic aromatic compound according to claim 2, wherein Y¹ is B.

4. The polycyclic aromatic compound according to claim 3, wherein one of X¹ and X² is >N—R and the other is >O, S, >N—R, or >C(—R)₂.

5. The polycyclic aromatic compo d according to claim 3, wherein X¹ and X² are each independently >N—R.

6. The polycyclic aromatic compound according to claim 2, wherein the structural unit represented by Formula (1) is a structural unit represented by Formula (1-a), Formula (1-b), Formula (1-i), or Formula (1-j): 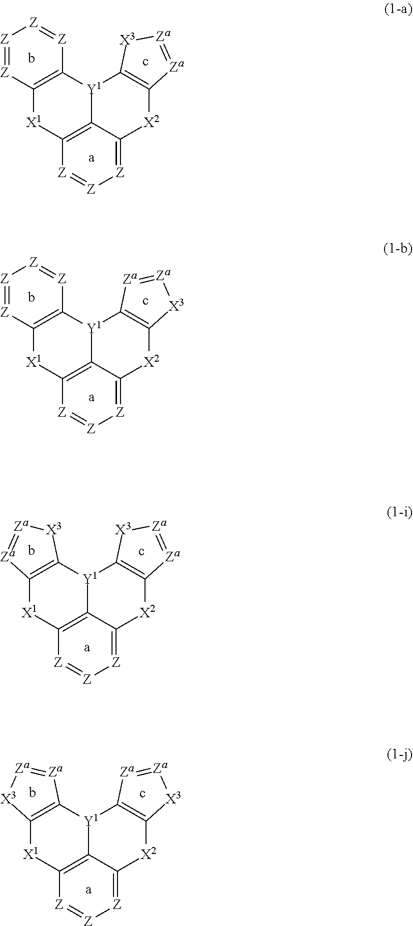
wherein:
Z^{a} and Z are each independently N or C—R^{Z}, provided that at least one of the two Z^{a} constituting one ring is N,
each R^{Z} is hydrogen, an aryl, a heteroaryl, a diarylamino, a diheteroarylamino, an arylheteroarylamino, a diarylboryl (the two aryls may be bonded via single bond or a linking group), an alkyl, a cycloalkyl, an alkoxy, an aryloxy, or a substituted silyl, wherein at least one hydrogen in these may be replaced with an aryl, a heteroaryl, an alkyl, or a cycloalkyl, two adjacent R^{Z}′s may be bonded to each other to form an aryl ring or a heteroryl ring, wherein the aryl ring and the heteroryl ring formed may each be substituted with an aryl, a heteroaryl, a diarylamino, a diheteroarylamino, an arylheteroarylamino, a diarylboryl (the two aryl may be bonded via a single bond or linking group), an alkyl, a cycloalkyl, an alkoxy, an aryloxy, or a substituted silyl, wherein at least one hydrogen in these may be replaced with an aryl, a heteroaryl, an alkyl, or a cycloalkyl,
Z═Z may each independently be >O, >N—R, >C—(R)₂, >Si(—R)₂, >S, or >Se, wherein R in >N—R and R's in >C—(R)₂ and >Si(—R)₂ are independently hydrogen, a substituted or unsubstituted aryl, a substituted or unsubstituted heteroaryl, a substituted or unsubstituted alkyl or a substituted or unsubstituted cycloalkyl, the two R's in C(—R)₂ and Si(—R)₂ may be bonded to each other to form a ring;
X³ is >O, >N—R, >C(—R)₂, >S, or >Se, wherein R in >N—R is hydrogen, a substituted or unsubstituted aryl, a substituted or unsubstituted heteroxyl, a substituted or unsubstituted alkyl, a substituted or unsubstituted cycloalkyl, and R's in >C(—R)₂ are each independently hydrogen, a substituted or unsubstituted aryl, a substituted or unsubstituted heteroaryl, a substituted or unsubstituted alkyl, or a substituted or unsubstituted cycloalkyl;
Y¹ is B, P, P═O, P═S, Ga, As, Si—R, or Ge—R, wherein R in Si—R and Ge—R is a substituted or unsubstituted aryl, a substituted or unsubstituted heteroaryl, a substituted or unsubstituted alkyl, or a substituted or unsubstituted cycloalkyl;
X¹ and X² are each independently >O, >N—R, >C(—R)₂, >Si(—R)₂, >S, or >Se, wherein R in >N—R is hydrogen, a substituted or unsubstituted aryl, a substituted or unsubstituted heteroaryl, a substituted or unsubstituted alkyl, or a substituted or unsubstituted cycloalkyl, and R's in >C(—R)₂ and >Si(—R)₂ are each independently hydrogen, a substituted or unsubstituted aryl, a substituted or unsubstituted heteroaryl, a substituted or unsubstituted alkyl, or a substituted or unsubstituted cycloalkyl, the two R's >C(—R)₂, and >Si(—R)₂ may be bonded to each other to form a ring, and R in >N—R, >C(—R)₂, and >Si(—R)₂ may be bonded to one or two of R^{z} in Z as C—R^{z} by a linking group or single bond;
at least one of aryl ring or heteroaryl ring in the structure may be fused with at least one cycloalkane, at least one hydrogen in the cycloalkane may be substituted, and at least one —CH₂— in the cycloalkane may be replaced with —O—; and
at least one hydrogen in the structure may be replaced with cyano, a halogen, or deuterium.

7. The polycyclic aromatic compound according to claim 6, wherein Y¹ is B, and X¹ and X² are each independently >N—R.

8. The polycyclic aromatic compound according to claim 6, which is represented by any one of the following formulas; 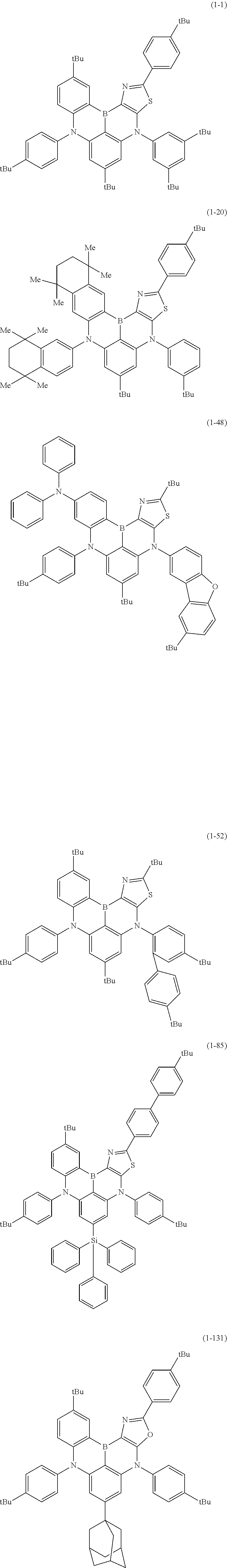 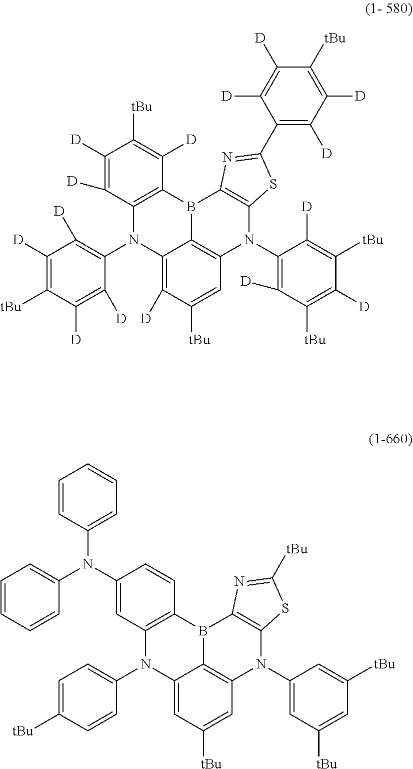
wherein Me is methyl, tBu is t-butyl, and D is deuterium.

9. The polycyclic aromatic compound according to claim 1, wherein at least one ring selected from the group consisting of A ring, B ring, and C ring in the structure is a ring represented by Formula (Het-2).

10. The polycyclic aromatic compound according to claim 9, wherein Y¹ is B.

11. The polycyclic aromatic compound according to claim 10, wherein one of X¹ and X² is >N—R and the other is >O, S, >N—R, or >C(—R)₂.

12. The polycyclic aromatic compound according to claim 10, wherein X¹ and X² are each independently >N—R.

13. The polycyclic aromatic compound according to claim 9, wherein the structural unit represented by Formula (1) is any one of Formula (1-c), Formula (1-d), Formula (1-e), Formula (1-f), Formula (1-g), Formula (1-h), Formula (1-k), Formula (1-l), Formula (1-m), or Formula (1-o); 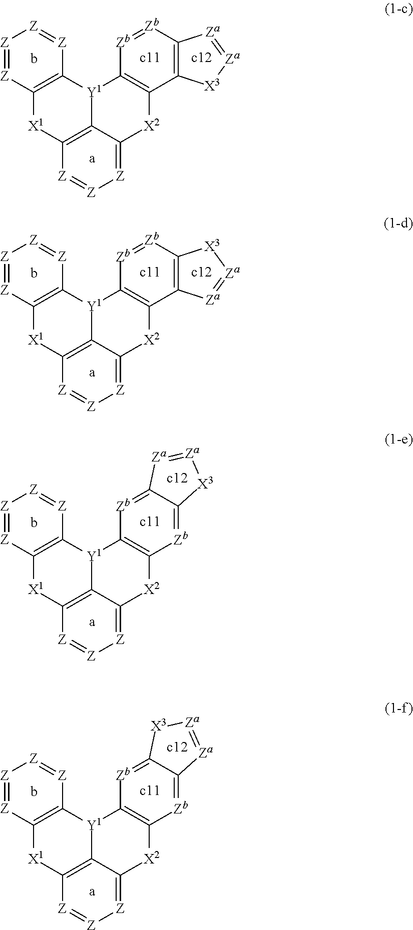 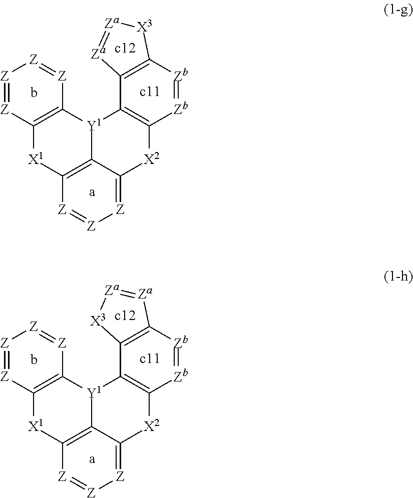 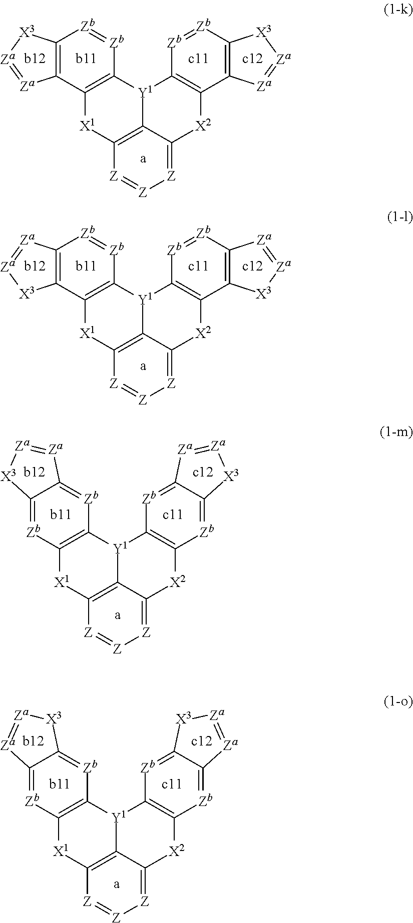
wherein:
Z^{a}, Z^{b} and Z are each independently N or C—R^{Z}, provided that at least one of the two Z^{a} is N, each R^{Z} is independently hydrogen, an aryl, a heteroaryl, a diarylamino, a diheteroarylamino, an arylheteroarylamino, a diarylboryl (the two aryls may be bonded via single bond or a linking group), an alkyl, a cycloalkyl, an alkoxy, an aryloxy, or a substituted silyl, wherein at least one hydrogen in these may be replaced with an aryl, a heteroaryl, an alkyl, or a cycloalkyl, two adjacent R^{z}'s may be bonded to each other to form an aryl ring or a heteroryl ring, wherein the aryl ring and heteroryl ring formed may each be substituted with an aryl, a heteroaryl, a diarylamino, a diheteroarylamino, arylheteroarylamino, a diarylboryl (two aryls may be bonded via a single bond or a linking group), an alkyl, a cycloalkyl, alkoxy, an aryloxy, or a substituted silyl, wherein at least one hydrogen in these may be replaced with an aryl, a heteroaryl, an alkyl, or a cycloalkyl,
Z^{b}═Z^{b} may be >O, >N—R, >C—(R)₂, >Si(—R)₂>S, or >Se, wherein R in >N—R and R's in >C—(R)₂ and >Si(—R)₂ are each independently hydrogen, a substituted or unsubstituted aryl, a substituted or unsubstituted heteroaryl, a substituted or unsubstituted alkyl, or a substituted or unsubstituted cycloalkyl, and two R's in >C(—R)₂ and >Si(—R)₂ may be bonded to each other to form a ring, Z═Z may each independently he >O, >N—R, >C—(R)₂, >Si(—R)₂, >S, or >Se, wherein R in >N—R and R's in >C—(R)₂ and >Si(—R)₂ are each independently hydrogen, a substituted or unsubstituted aryl, a substituted or unsubstituted heteroaryl, a substituted or unsubstituted alkyl, a substituted or unsubstituted cycloalkyl, and the two R's in C(—R)₂ and >Si(—R)₂ may be bonded to each other to form a ring;
X³ is >O, >N—R, >C(—R)₂, >S, or >Se, wherein R in >N—R is hydrogen, a substituted or unsubstituted aryl, a substituted or unsubstituted heteroaryl, a substituted or unsubstituted a substituted air unsubstituted cycloalkyl, and R's in >C(—R)₂ are each independently hydrogen, a substituted or unsubstituted aryl, a substituted or unsubstituted heteroaryl, a. substituted or unsubstituted alkyl, or a substituted or unsubstituted cycloalkyl;
Y¹ is B, P, P═O, P═S, Al, Ga, As, Si—R, or Ge—R, wherein R in Si—R and Ge—R is a substituted or unsubstituted aryl, a substituted or unsubstituted heteroaryl, a substituted or unsubstituted or a substituted or unsubstituted cycloalkyl;
X¹ and X² are independently >O, >N—R, >C(—R)₂, >Si(—R)₂, >S, or >Se, wherein R in >N—R is hydrogen, a substituted or unsubstituted aryl, a substituted or unsubstituted heteroaryl, a substituted or unsubstituted alkyl, a substituted or unsubstituted cycloalkyl, R's in >C(—R)₂ and >Si(—R)₂ are each independently hydrogen, a substituted or unsubstituted aryl, a substituted or unsubstituted heteroaryl, a substituted or unsubstituted alkyl, a substituted or unsubstituted cycloalkyl, the two R's in >C(—R)₂ and >Si(—R)₂ may be bonded to each other to form a ring, and R in >N—R, >C(—R)₂, >Si(—R)₂ may be bonded to one or two of R^{z} in Z as C—R^{z} by a linking group or single bond;
at least one of aryl ring or heteroaryl ring in the structure may be fused with at least one cycloalkane, at least one hydrogen in the cycloalkane may be substituted, at least one —CH₂— in the cycloalkane may be replaced with —O—; and
at least one hydrogen in the structure may be replaced with cyano, a halogen, or deuterium.

14. The polycyclic aromatic compound according to claim 13, wherein Y¹ is B, and X¹ and X² are each independently >N—R.

15. The polycyclic aromatic compound according to claim 13, which is represented by any one of the following formulas; 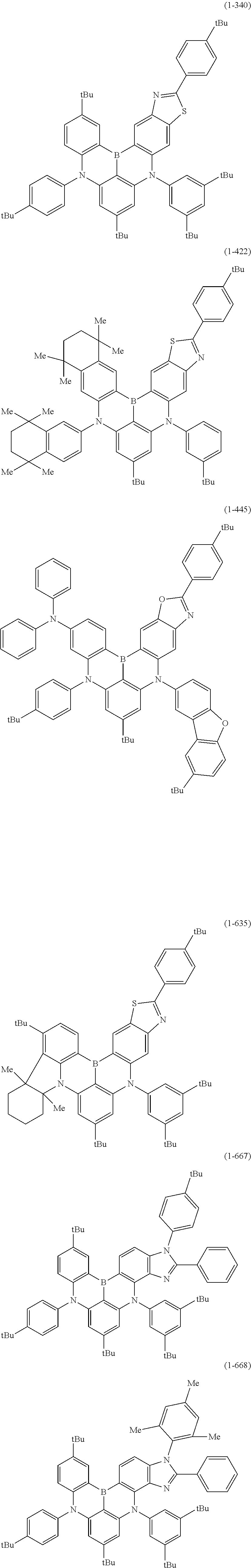 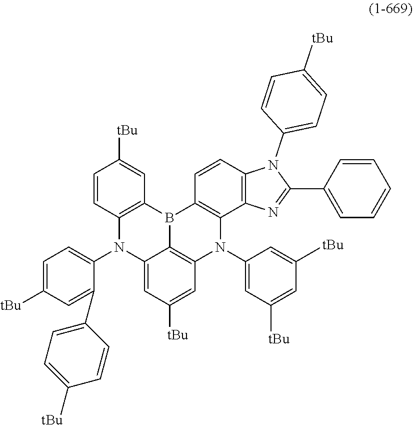
wherein Me is methyl, and tBu is t-butyl.

16. A material for an organic device, comprising the polycyclic aromatic compound according to claim 1.

17. An organic electroluminescent element, comprising a pair of electrodes consisting of an anode and a cathode, and a light emitting layer disposed between the pair of electrodes, wherein the light-emitting layer comprises the polycyclic aromatic compound according to claim 1.

18. The organic electroluminescent element according to claim 17, wherein the light emitting layer comprises a host and the polycyclic aromatic compound as a dopant.

19. The organic electroluminescent element according to claim 18, wherein the host is an anthracene-based compound, a fluoreno-based compound, or a dibenzocrysene-based compound.

20. A display device or a lighting device, comprising the organic electroluminescent element according to claim 11.
